(19) United States
(12) Patent Application Publication
(10) Pub. No.: US 2026/0118767 A1
(43) Pub. Date: Apr. 30, 2026

(54) REVERSE PATTERNING PROCESS

(71) Applicant: SHIN-ETSU CHEMICAL CO., LTD., Tokyo (JP)

(72) Inventors: Shun KIKUCHI, Joetsu-shi (JP); Satoshi Kusama, Joetsu-shi (JP); Kousuke Ohyama, Joetsu-shi (JP); Ryo Nishikawa, Joetsu-shi (JP); Masaki Ohashi, Joetsu-shi (JP)

(73) Assignee: SHIN-ETSU CHEMICAL CO., LTD., Tokyo (JP)

(21) Appl. No.: 19/364,506

(22) Filed: Oct. 21, 2025

(30) Foreign Application Priority Data
Oct. 25, 2024 (JP) 2024-188557

(51) Int. Cl. G03F 7/11; G03F 7/075

(52) U.S. Cl. CPC G03F 7/11; G03F 7/0757

(57) ABSTRACT

A patterning process for forming a pattern, including the steps of: (i) forming a resist pattern on a support using a resist film obtained from a resist composition containing a hypervalent iodine compound, a carboxy group-containing compound, and a solvent; (ii) applying a material for forming a reversed pattern onto the support having the resist pattern formed to form a coating film for pattern-reversing; and (iii) removing the resist pattern by etching to form a reversed pattern. The patterning process can be applied to photolithography using a high-energy beam, particularly to electron beam (EB) lithography and an extreme ultraviolet ray (EUV), and in which a resist pattern is formed by using a non-chemically amplified resist composition having excellent sensitivity and an excellent resolution limit and the pattern is reversed by using a material for forming a reversed pattern that has high etching resistance.

### TECHNICAL FIELD

The present invention relates to a reverse patterning process.

### BACKGROUND ART

With the expansion of the IoT market, further demands are being placed on LSI for higher integration density, faster speeds, and lower power consumption, resulting in rapid miniaturization of its patterning rules. In particular, logic devices drive the miniaturization. As the advanced miniaturization technology, devices of 10-nm node are manufactured in a mass scale by the double, triple, or quadro-patterning version of immersion ArF lithography. Furthermore, a study of 7-nm node devices by the next-generation extreme ultraviolet ray (EUV) lithography of 13.5 nm wavelength has been started.

As the miniaturization advances, image blurs due to acid diffusion are regarded as a problem (Non Patent Document 1). In order to ensure resolution of fine patterns with a critical dimension of 45 nm or less, it is proposed that not only the enhancement of dissolution contrast, which has been proposed previously, but also controlling the acid diffusion is important (Non Patent Document 2). However, sensitivity and contrast of chemically amplified resist compositions are enhanced by the acid diffusion. Accordingly, an attempt to minimize the acid diffusion to the limits by lowering temperature of post-exposure baking (PEB) or shortening the PEB time lowers the sensitivity and the contrast markedly.

It is effective to control the acid diffusion by adding an acid generator that generates a bulky acid. Accordingly, it has been proposed to copolymerize a polymer with an acid generator in the form of an onium salt having polymerizable olefin. In patterning resist films with a critical dimension of 16 nm or less, however, it is considered that patterning is impossible with chemically amplified resist compositions in view of the acid diffusion. Therefore, it is desired to develop a non-chemically amplified resist composition.

Examples of materials for the non-chemically amplified resist composition include polymethyl methacrylate (PMMA). PMMA is a positive-type resist material whose solubility in an organic solvent developer increases due to decreased molecular weight caused by scission of the main chain by EUV irradiation.

Hydrogensilsesquioxane (HSQ) is a negative-type resist material that turns insoluble in an alkaline developer through crosslinking by a condensation reaction of silanol generated by EUV irradiation. Calixarene substituted with chlorine also functions as a negative-type resist material. These negative-type resist materials have a small molecular size prior to crosslinking and are free from causing blurs due to acid diffusion, and therefore, exhibit smaller edge roughness and very high resolution. Accordingly, such materials have been used as a pattern transfer material to show a resolution limit of an exposure apparatus. These materials, however, are insufficient in sensitivity, and further improvement is required.

The small number of photons in EUV exposure is a factor that causes difficulties in developing a material for EUV lithography. The energy of EUV is much higher than that of an ArF excimer laser beam, and the number of photons in EUV exposure is 1/14 of that of ArF exposure. Furthermore, the size of the pattern formed by EUV exposure is half of that by ArF exposure or less. Therefore, EUV exposure is easily affected by variation in the number of photons. The variation in the number of photons in a radiation light region of extremely short wavelengths is a physical phenomenon of shot noise, and it is impossible to eliminate the influence of the variation. Therefore, so-called probability theory (stochastics) is attracting attention. The influence of the shot noise cannot be eliminated, but how to reduce this influence is under discussion. The influence of the shot noise not only increases the critical dimension uniformity (CDU) but also is observed to cause a phenomenon of blocking a hole at a probability of one to several millions. When a hole gets blocked, conduction failure occurs and a transistor does not function, and the performance of the entire device is adversely affected. Considering sensitivity in practical terms, resist compositions that mainly contain PMMA or HSQ are greatly affected by stochastics, and cannot achieve the desired resolution performance.

The introduction of an element that greatly absorbs EUV light is attracting attention as a means for reducing the influence of the shot noise on the side of the resist. Patent Document 1 proposes a chemically amplified resist composition containing an iodine atom that greatly absorbs EUV light. As mentioned above, however, the chemically amplified resist composition cannot achieve excellent resolution performance in EUV lithography in which the critical dimension is expected to be increasingly miniaturized. In particular, in line and space patterns, as the pattern dimensions become smaller, the incidence of pattern collapse and disconnection increases significantly, and therefore reducing these occurrences leads to an improvement in the resolution limit.

Patent Document 2 proposes a negative-type resist composition using a tin compound. Because this composition contains tin, which has high absorption of EUV light, as its main component, it improves stochastics and can achieve high sensitivity and high resolution. However, this type of metal resist has many issues, such as insufficient solubility in a resist solvent, storage stability, and defects due to etching residues.

### CITATION LIST

### Patent Literature

Patent Document 1: JP2018-5224A
Patent Document 2: JP2021-503482A

### Non Patent Literature

Non Patent Document 1: SPIE Vol. 5039 p 1(2003)
Non Patent Document 2: SPIE Vol. 6520 p 65203L-1 (2007)

### SUMMARY OF INVENTION

### Technical Problem

The present invention was made in view of the above circumstances and has for its object to provide a patterning process that can be applied to photolithography using a high-energy beam, particularly to electron beam (EB) lithography and an extreme ultraviolet ray (EUV), and in which a resist pattern is formed by using a non-chemically amplified resist composition having excellent sensitivity and an excellent resolution limit and the pattern is reversed by using a material for forming a reversed pattern that has high etching resistance.

### Solution to Problem

To solve the problems above, the present invention provides a patterning process for forming a pattern, comprising the steps of:
(i) forming a resist pattern on a support using a resist film obtained from a resist composition comprising a hypervalent iodine compound, a carboxy group-containing compound, and a solvent;
(ii) applying a material for forming a reversed pattern onto the support having the resist pattern formed to form a coating film for pattern-reversing; and
(iii) removing the resist pattern by etching to form a reversed pattern.

Such a patterning process can be applied to photolithography using a high-energy beam, particularly to electron beam (EB) lithography and an extreme ultraviolet ray (EUV) lithography, forms a resist pattern by using a non-chemically amplified resist composition having excellent sensitivity and an excellent resolution limit, and reverses the pattern by using a material for forming a reversed pattern that has high etching resistance.

Further, in the inventive patterning process, one or more kinds selected from hypervalent iodine compounds represented by the following formulae (1) to (10) are preferably used as the hypervalent iodine compound,

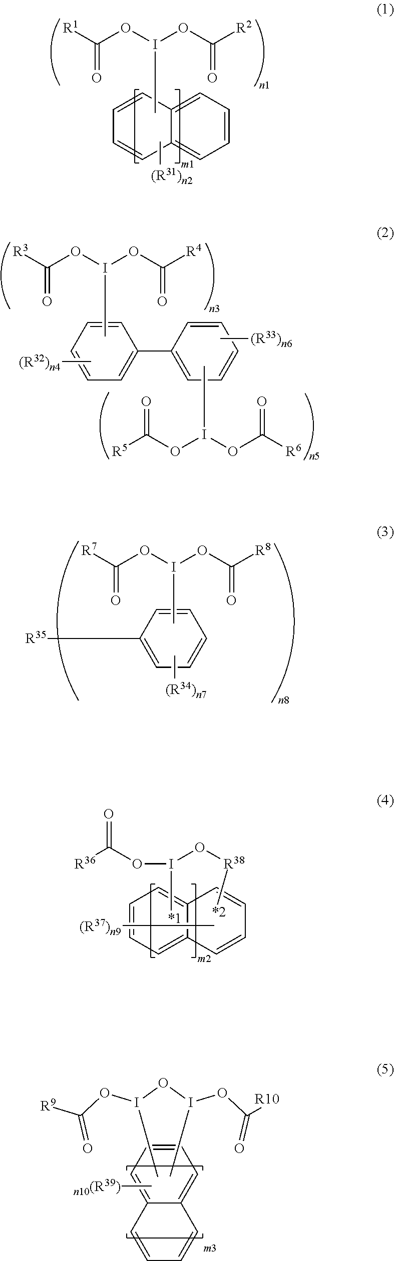

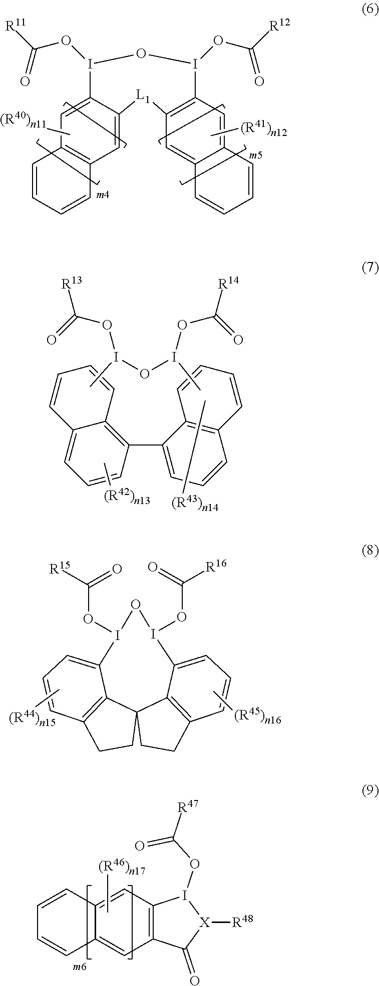

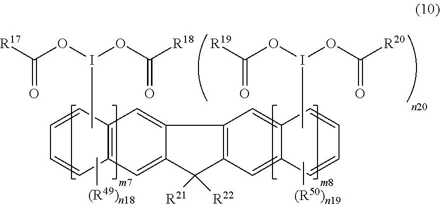

wherein m1 represents 0, 1, or 2, when m1 is 0, n1 represents 1, 2, or 3, n2 represents 0, 1, 2, 3, 4, or 5, and 1≤n1+n2≤6 is satisfied, when m1 is 1, n1 represents 1, 2, or 3, n2 represents 0, 1, 2, 3, 4, 5, 6, or 7, and 1≤n1+n2≤8 is satisfied, and when m1 is 2, n1 represents 1, 2, or 3, n2 represents 0, 1, 2, 3, 4, 5, 6, 7, 8, or 9, and 1≤n1+n2≤10 is satisfied;
n3 represents 1 or 2, n4 represents 0, 1, 2, 3, or 4, and 1≤n3+n4≤5 is satisfied; n5 represents 1 or 2, n6 represents 0, 1, 2, 3, or 4, and 1≤n5+n6≤5 is satisfied;
n7 represents 0, 1, 2, 3, or 4; n8 represents 1, 2, 3, or 4;
m2 represents 0, 1, or 2, when m2 is 0, n9 represents 0, 1, 2, 3, or 4, when m2 is 1, n9 is 0, 1, 2, 3, 4, 5, or 6, and when m2 is 2, n9 is 0, 1, 2, 3, 4, 5, 6, 7, or 8;
m3 represents 0, 1, or 2, when m3 is 0, n10 is 0, 1, 2, 3, or 4, when m3 is 1, n10 is 0, 1, 2, 3, 4, 5, or 6, and when m3 is 2, n10 is 0, 1, 2, 3, 4, 5, 6, 7, or 8;
m4 represents 0 or 1, when m4 is 0, n11 represents 0, 1, 2, 3, or 4, and when m4 is 1, n11 represents 0, 1, 2, 3, 4, 5, or 6;
m5 represents 0 or 1, when m5 is 0, n12 represents 0, 1, 2, 3, or 4, and when m5 is 1, n12 represents 0, 1, 2, 3, 4, 5, or 6;
n13 and n14 represent 0, 1, 2, 3, 4, 5, or 6;
n15 and n16 represent 0, 1, 2, or 3;
m6 represents 0, 1, or 2, when m6 is 0, n17 represents 0, 1, 2, 3, or 4, when m6 is 1, n17 represents 0, 1, 2, 3, 4, 5, or 6, and when m6 is 2, n17 represents 0, 1, 2, 3, 4, 5, 6, 6, 7, or 8;
m7 represents 0, 1, or 2, when m7 is 0, n18 represents 0, 1, 2, or 3, when m7 is 1, n18 represents 0, 1, 2, 3, 4, or 5, and when m7 is 2, n18 represents 0, 1, 2, 3, 4, 5, 6, or 7;
m8 represents 0, 1, or 2, when m8 is 0, n19 represents 0, 1, 2, or 3, and n20 represents 0 or 1, when m8 is 1, n19 represents 0, 1, 2, 3, 4, or 5, and n20 is 0 or 1, and when m8 is 2, n19 represents 0, 1, 2, 3, 4, 5, 6, or 7, and n20 represents 0 or 1;
R¹ to R²² each independently represent a halogen atom or a hydrocarbyl group having 1 to 10 carbon atoms and optionally having a heteroatom, R²¹ and R²² may be bonded to each other to form a ring together with the carbon atoms to which they are bonded and the atoms between the carbon atoms to which they are bonded;
R³¹ to R³⁴, R³⁷, R³⁹ to R⁴⁶, R⁴⁹, and R⁵⁰ each independently represent a halogen atom or a hydrocarbyl group having 1 to 40 carbon atoms and optionally having a heteroatom, when n2 is 2 or more, R³¹s may be identical to or different from each other, and a plurality of R³¹s may be bonded to each other to form a ring together with the carbon atoms of the aromatic ring to which they are bonded, when n4 is 2 or more, R³²s may be identical to or different from each other, and a plurality of R³²s may be bonded to each other to form a ring together with the carbon atoms of the aromatic ring to which they are bonded, when n6 is 2 or more, R³³s may be identical to or different from each other, and a plurality of R³³s may be bonded to each other to form a ring together with the carbon atoms of the aromatic ring to which they are bonded, when n7 is 2 or more, R³⁴s may be identical to or different from each other, and a plurality of R³⁴s may be bonded to each other to form a ring together with the carbon atoms of the aromatic ring to which they are bonded, when n9 is 2 or more, R³⁷s may be identical to or different from each other, and a plurality of R³⁷s may be bonded to each other to form a ring together with the carbon atoms of the aromatic ring to which they are bonded, when n10 is 2 or more, R³¹s may be identical to or different from each other, and a plurality of R³⁹s may be bonded to each other to form a ring together with the carbon atoms of the aromatic ring to which they are bonded, when n11 is 2 or more, R⁴⁰s may be identical to or different from each other, and a plurality of R⁴⁰s may be bonded to each other to form a ring together with the carbon atoms of the aromatic ring to which they are bonded, when n12 is 2 or more, R⁴¹s may be identical to or different from each other, and a plurality of R⁴¹s may be bonded to each other to form a ring together with the carbon atoms of the aromatic ring to which they are bonded, when n13 is 2 or more, R⁴²s may be identical to or different from each other, and a plurality of R⁴²s may be bonded to each other to form a ring together with the carbon atoms of the aromatic ring to which they are bonded, when n14 is 2 or more, R⁴³s may be identical to or different from each other, and a plurality of R⁴³s may be bonded to each other to form a ring together with the carbon atoms of the aromatic ring to which they are bonded, when n15 is 2 or more, R⁴⁴s may be identical to or different from each other, and a plurality of R⁴⁴s may be bonded to each other to form a ring together with the carbon atoms of the aromatic ring to which they are bonded, when n16 is 2 or more, R⁴⁵s may be identical to or different from each other, and a plurality of R⁴⁵s may be bonded to each other to form a ring together with the carbon atoms of the aromatic ring to which they are bonded, when n17 is 2 or more, R⁴⁶s may be identical to or different from each other, and a plurality of R⁴⁶s may be bonded to each other to form a ring together with the carbon atoms of the aromatic ring to which they are bonded, when n18 is 2 or more, R⁴⁹s may be identical to or different from each other, and a plurality of R⁴⁹s may be bonded to each other to form a ring together with the carbon atoms of the aromatic ring to which they are bonded, and when n19 is 2 or more, R⁵⁰s may be identical to or different from each other, and a plurality of R⁵⁰s may be bonded to each other to form a ring together with the carbon atoms of the aromatic ring to which they are bonded;
R³⁵ represents an (n8)-valent hydrocarbon group having 1 to 40 carbon atoms or an (n8)-valent heterocyclic group having 2 to 40 carbon atoms, when n8 is 2, R³⁵ may be an ether bond, a carbonyl group, an azo group, a thioether bond, a carbonate bond, a carbamate bond, a sulfinyl group, a sulfonyl group, or a thioketone bond, part or all of the hydrogen atoms of the (n8)-valent hydrocarbon group or the (n8)-valent heterocyclic group may be substituted with a group having a heteroatom, part of the —CH₂— groups of the (n8)-valent hydrocarbon group may be substituted with a group having a heteroatom, and R³⁴ and R³⁵ may be bonded to each other to form a ring together with the carbon atoms to which they are bonded and the atoms between the carbon atoms to which they are bonded;
R³⁶ represents a halogen atom or a hydrocarbyl group having 1 to 10 carbon atoms and optionally having a heteroatom;
R³⁸ represents a carbonyl group or a hydrocarbylene group having 1 to 10 carbon atoms and optionally having a heteroatom;
*1 and *2 represent attachment points to carbon atoms of the aromatic ring in the formula, and *1 and *2 are bonded to adjacent carbon atoms of the aromatic ring;
L₁ represents no bond, a single bond, —O—, —S—, —NH—, or —CH₂—;
R⁴⁷ each independently represents a halogen atom or a hydrocarbyl group having 1 to 10 carbon atoms and optionally having a heteroatom;
“X” represents a nitrogen atom or a sulfur atom, and when it is a nitrogen atom, it may have R⁴⁸; and
R⁴⁸ represents a hydrogen atom, a halogen atom, or a hydrocarbyl group having 1 to 20 carbon atoms and optionally having a heteroatom.

By using a resist composition containing such a hypervalent iodine compound, it is suitable because it is possible to form a resist pattern and reverse the pattern using a material for forming a reversed pattern having high etching resistance.

Further, as the carboxy group-containing compound, a carboxy group-containing polymer having a repeating unit represented by the following general formula (11) or a carboxylic acid compound represented by the following general formula (12) is preferably used,

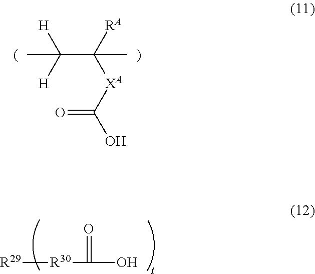

wherein R^{A} represents a hydrogen atom, a halogen atom, a methyl group, or a trifluoromethyl group;
X^{A} represents a single bond, a phenylene group, a naphthylene group, or *—C(═O)—O—X^{A1}—, wherein X^{A1} is a saturated hydrocarbylene group having 1 to 10 carbon atoms, a phenylene group, or a naphthylene group, the saturated hydrocarbylene group may have a hydroxy group, an ether bond, an ester bond, or a lactone ring, and “*” represents an attachment point to a carbon atom in the main chain;
“t” represents 1, 2, 3, or 4;
R²⁹ represents a t-valent hydrocarbon group having 1 to 40 carbon atoms or a t-valent heterocyclic group having 2 to 40 carbon atoms, when “t” is 2, R²⁹ may be an ether bond, a carbonyl group, an azo group, a thioether bond, a carbonate bond, a carbamate bond, a sulfinyl group, or a sulfonyl group, part or all of the hydrogen atoms of the t-valent hydrocarbon group or the t-valent heterocyclic group may be substituted with a group having a heteroatom, and part of the —CH₂— groups of the t-valent hydrocarbon group may be substituted with a group having a heteroatom;
and R³⁰ represents a single bond or a hydrocarbylene group having 1 to 10 carbon atoms, part or all of the hydrogen atoms of the hydrocarbylene group may be substituted with a group having a heteroatom, part of the —CH₂— of the hydrocarbylene group may be substituted with a group having a heteroatom, and when “t” is 2 to 4, R³⁰s may be identical to or different from each other.

In the inventive patterning process, it is preferable to use the resist composition containing such a carboxy group-containing compound.

Further, a resist underlayer film can be formed between the support and the resist film.

The inventive patterning process can be used for a multilayer resist method in which a resist underlayer film is formed.

A material for forming a silicon-containing reversed pattern containing a thermally crosslinkable polysiloxane having any one or more of repeating units represented by the following formulae (13) to (15) is preferably used as the material for forming a reversed pattern,

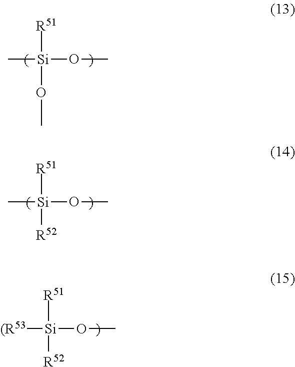

wherein R⁵¹, R⁵² and R⁵³ represent a monovalent organic group having 1 to 30 carbon atoms, which may be identical to or different from each other.

By using those containing such a thermally crosslinkable polysiloxane, it is possible to achieve a suitable filling property in a fine resist pattern and a high etching selection ratio to a resist pattern, and a pattern shape formed on a support after etching a resist pattern becomes suitable one that has excellent rectangularity of the cross-section.

A material containing an organic solvent that does not dissolve the resist pattern is preferably used as the material for forming a silicon-containing reversed pattern.

As the material for forming a silicon-containing reversed pattern, it is preferable to use the material containing such an organic solvent.

The inventive patterning process can comprise the steps of: exposing the resist film by an i-line, a KrF excimer laser beam, an ArF excimer laser beam, an electron beam, or an extreme ultraviolet ray; and developing the exposed resist film with a developer.

By including such steps, the inventive patterning process can form a fine pattern with high etching resistance.

### Advantageous Effects of Invention

As described above, the inventive patterning process is extremely effective to form a fine pattern with high etching resistance, especially in lithography using an i-line, a KrF excimer laser beam, an ArF excimer laser beam, EB, or EUV.

### DESCRIPTION OF EMBODIMENTS

As a result of their diligent study to achieve the objects above, the inventors found that reversing a resist pattern obtained from a resist composition mainly composed of a specific hypervalent iodine compound and a specific carboxy group-containing compound by using material for forming a reversed pattern with high etching resistance is extremely effective for forming a fine pattern with high etching resistance, and have completed the present invention.

That is, the present invention is a patterning process for forming a pattern, comprising the steps of:
(i) forming a resist pattern on a support using a resist film obtained from a resist composition comprising a hypervalent iodine compound, a carboxy group-containing compound, and a solvent;
(ii) applying a material for forming a reversed pattern onto the support having the resist pattern formed to form a coating film for pattern-reversing; and
(iii) removing the resist pattern by etching to form a reversed pattern.

Hereinafter, the present invention will be described in detail, but is not limited thereto.

### [Material for Forming Reversed Pattern]

Examples of the inventive material for forming a reversed pattern include a material for forming a reversed pattern containing only organic material, a material for forming a reversed pattern containing metal material, and a material for forming a reversed pattern containing silicon.

As the inventive material for forming a reversed pattern, in view of an etching selection ratio to a resist obtained from a resist compound mainly composed of a specific hypervalent iodine compound and a specific carboxy group-containing compound, it is more preferable to use a material for forming a silicon-containing reversed pattern especially.

### [Material for Forming Reversed Pattern Containing Only Organic Material]

The material for forming a reversed pattern containing only an organic solvent used in the present invention is not particularly limited as long as it is a material for forming a reversed pattern composition that can fill in spaces between patterns after forming the patterns of a resist material, is a material composition for forming a reversed pattern composed of that does not dissolve the resist pattern, and is an organic material that can be used as a resist underlayer film material. For example, it is possible to use material for forming an organic underlayer film described in JP7209588B2, JP7540961B2, and 7472011B2, and the like, but are not limited thereto.

### [Material for Forming Reversed Pattern Containing Metal Material]

The material for forming a reversed pattern containing metal material used in the present invention is not particularly limited as long as it is a composition containing metal material that can fill in spaces between patterns after forming the patterns of a resist material, is a material composition for forming a reversed pattern composed of what does not dissolve the resist pattern, and can be used as a resist underlayer film material. For example, it is possible to use metal-containing material for forming an underlayer film described in JP2024-091495A and JP2024-041705A, and the like, but are not limited thereto.

### [Material for Forming Silicon-Containing Reversed Pattern]

As the material for forming a reversed pattern used in the present invention, it is preferable to use a material for forming a silicon-containing reversed pattern, which contains a thermally crosslinkable polysiloxane containing one or more repeating units represented by the following general formulae (13) to (15). This allows for good filling property into a fine resist pattern, makes it possible to achieve a high etching selection ratio to a resist pattern, and a pattern shape formed on a substrate after etching the resist pattern is suitable with excellent cross-sectional rectangularity, etc.

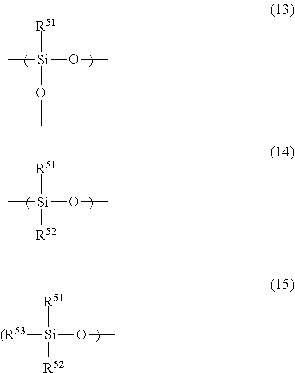

In the formulae, R⁵¹, R⁵² and R⁵³ represent a monovalent organic group having 1 to 30 carbon atoms, which may be identical to or different from each other.

In the formulae, R⁵¹, R⁵² and R⁵³ represent a monovalent organic group having 1 to 30 carbon atoms, which may be identical to or different from each other. R⁵¹ and R⁵² are preferably saturated or unsaturated organic groups having 1 to 20 carbon atoms and optionally having a substituent. Examples of the organic group include substituted or unsubstituted linear, branched, or cyclic alkyl groups having 1 to 20 carbon atoms, substituted or unsubstituted linear, branched, or cyclic alkenyl groups having 2 to 20 carbon atoms, and substituted or unsubstituted aryl groups having 6 to 20 carbon atoms. Specific examples thereof include a methyl group, an ethyl group, an n-propyl group, an i-propyl group, an n-butyl group, an i-butyl group, a sec-butyl group, a t-butyl group, an n-pentyl group, an n-hexyl group; a vinyl group, an allyl group, a propenyl group; a phenyl group, and a tolyl group.

Examples of other organic groups represented by R⁵¹, R⁵², and R⁵³ include organic groups having one or more of a carbon-oxygen single bond or a carbon-oxygen double bond. Specific examples thereof include organic groups having one or more groups selected from the group consisting of an ether bond, an ester bond, an alkoxy group, a hydroxy group, etc. Examples thereof include groups represented by the following general formula (Sm—R).

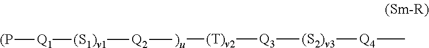

In the general formula (Sm—R), “P” represents a hydrogen atom, a cyclic ether group, a hydroxy group, an alkoxy group having 1 to 4 carbon atoms, an alkylcarbonyloxy group having 2 to 6 carbon atoms, or an alkylcarbonyl group having 2 to 6 carbons. Q₁, Q₂, Q₃, and Q₄ each independently represent —C_{q}H_{(2q-p)}Pₚ—, wherein “P” represents same as defined above, “p” represents an integer of 0 to 3, and “q” represents an integer of 0 to 10, note that q=0 means a single bond. “u” represents an integer of 0 to 3. S₁ and S₂ each independently represent —O—, —CO—, —OCO—, —COO—, or —OCOO—. v1, v2, and v3 each independently represent 0 or 1. “T” represents a divalent group composed of a divalent atom except for carbon, an aliphatic ring, an aromatic ring, or a hetero ring.

As “T”, examples of the aliphatic ring, the aromatic ring, or the hetero ring, each optionally having a heteroatom, such as an oxygen atom, will be described below. In “T”, positions at which Q₂ and Q₃ are bonded are not particularly limited, and can be appropriately selected with considering reactivity due to a steric factor, availability of a commercial reagent to be used for the reaction, etc.

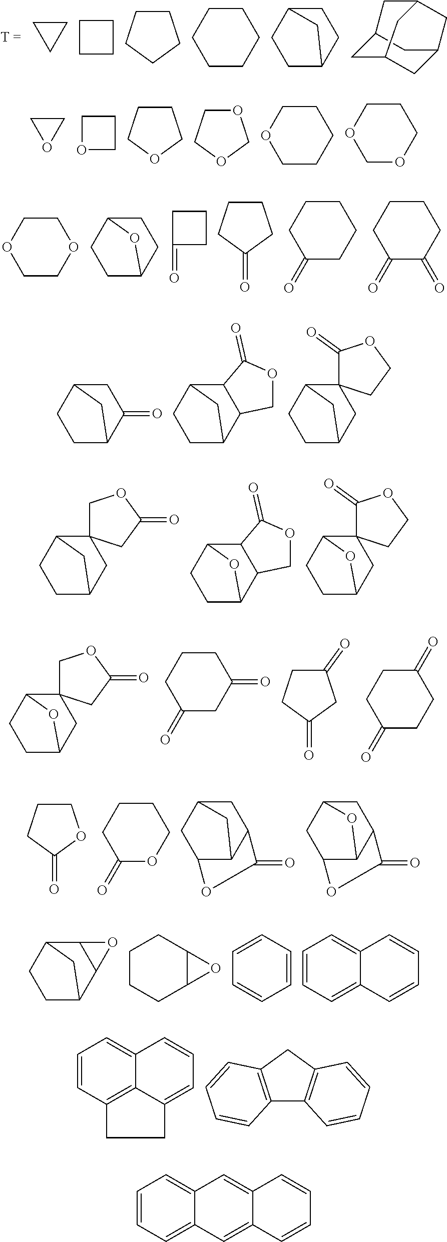

Preferable examples of the organic group having one or more of a carbon-oxygen single bond or a carbon-oxygen double bond in the general formula (Sm—R) include the following groups. In the following formulae, “(Si)” is shown to indicate an attachment point to Si.

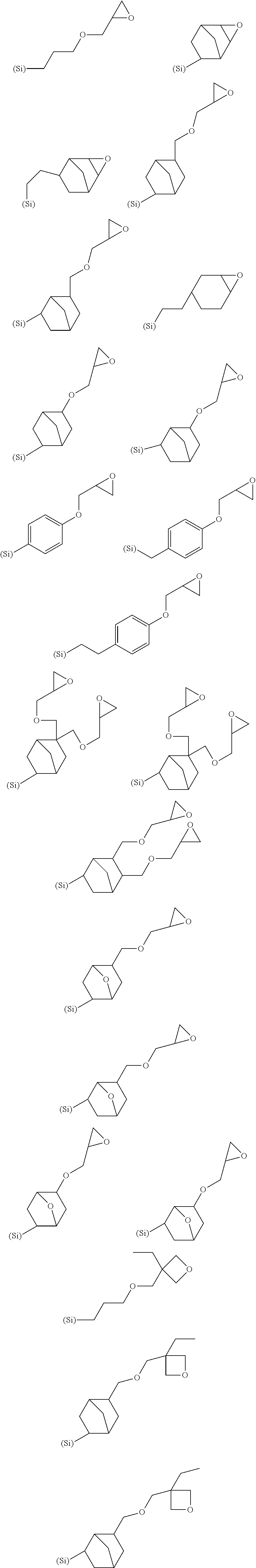

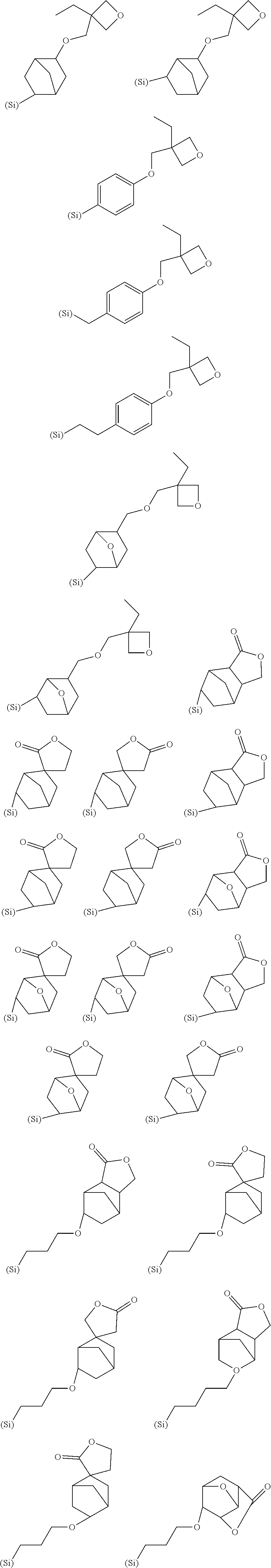

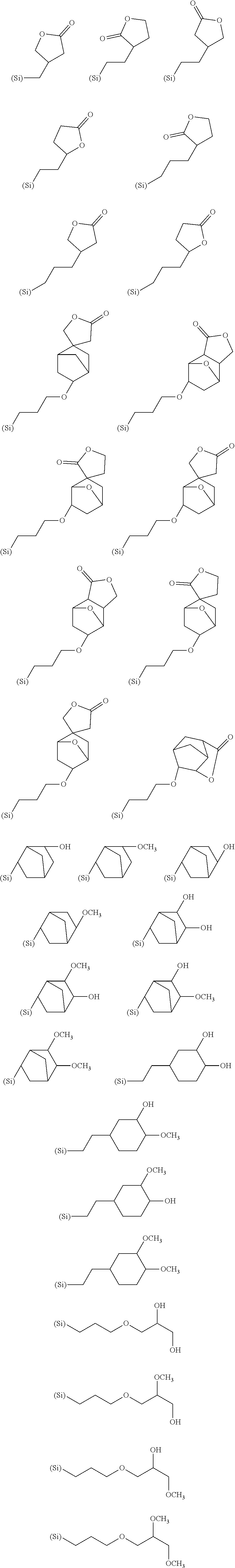

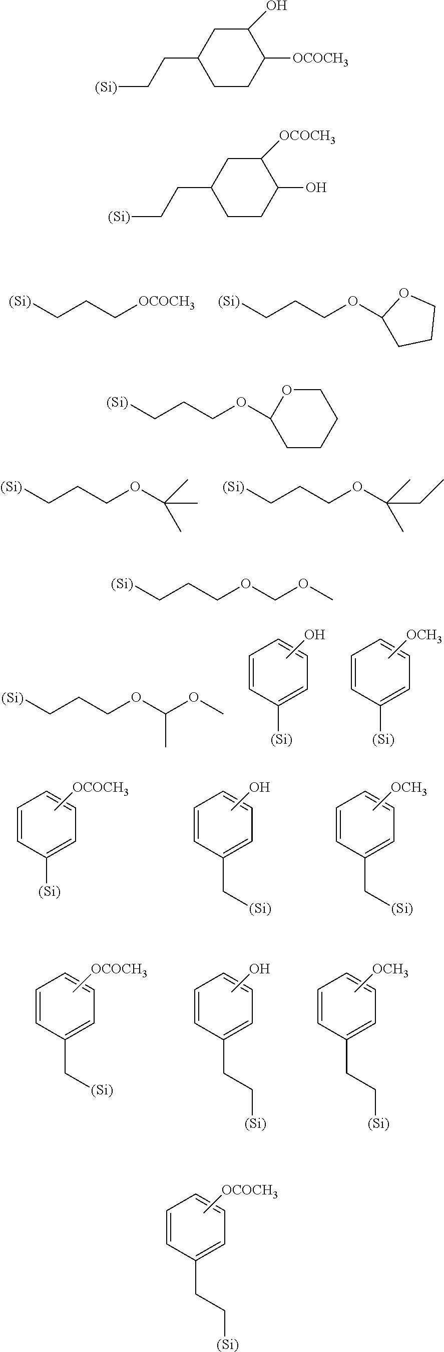

As examples of the organic group of R⁵¹, R⁵², and R⁵³, organic groups having a silicon-silicon bond can also be used. Specific examples thereof include the following groups.

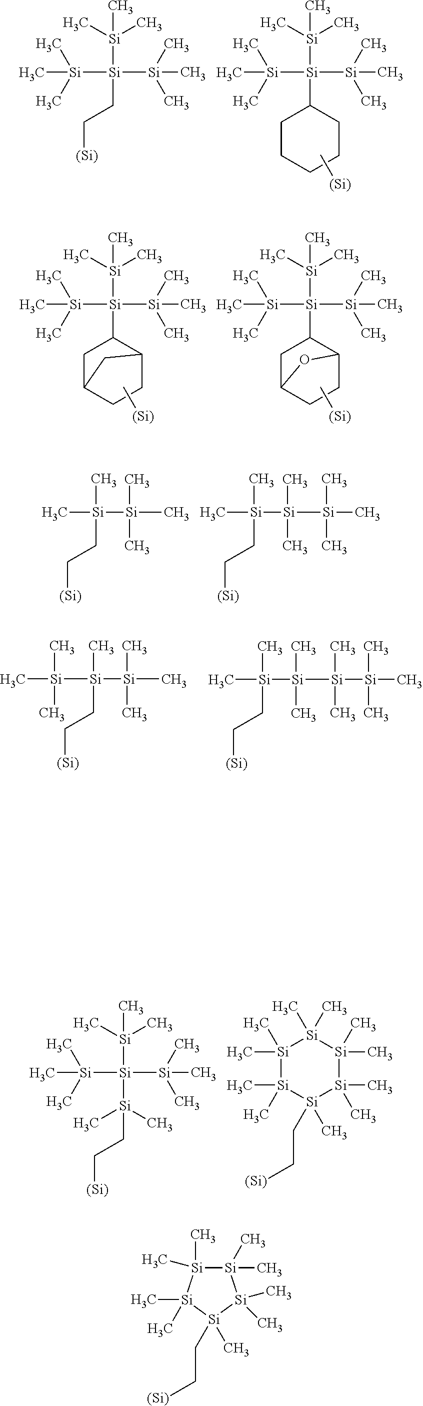

Furthermore, as examples of the organic group of R⁵¹, R⁵², and R⁵³, organic groups having a fluorine atom can also be used. Specific examples thereof include organic groups obtained from a silicon compound described in paragraph [0059] to [0065] in JP2012-53253 A.

The material for forming a silicon-containing reversed pattern used in the present invention may be a silsesquioxane.

### [Synthesis Method of Thermally Crosslinkable Polysiloxane (Material)]

The thermally crosslinkable polysiloxanes in the general formulae (13) to (15) can be manufactured, for example, by hydrolytically condensing the following hydrolyzable monomers (Sm).

In the above hydrolysable monomer (Sm) to be used for the synthesis, one, two, or three of chlorine, bromine, iodine, an acetoxy group, a methoxy group, an ethoxy group, a propoxy group, or a butoxy group are bonded as the hydrolysable group on the silicon represented by “(Si)” in the above partial structures.

Specific examples of the hydrolysable monomer (Sm) include tetramethoxysilane, tetraethoxysilane, tetrapropoxysilane, tetraisopropoxysilane, trimethoxysilane, triethoxysilane, tripropoxysilane, triisopropoxysilane, methyltrimethoxysilane, methyltriethoxysilane, methyltripropoxysilane, methyltriisopropoxysilane, ethyltrimethoxysilane, ethyltriethoxysilane, ethyltripropoxysilane, ethyltriisopropoxysilane, vinyltrimethoxysilane, vinyltriethoxysilane, vinyltripropoxysilane, vinyltriisopropoxysilane, propyltrimethoxyxilane, propyltriethoxysilane, propyltripropoxysilane, propyltriisopropoxysilane, isopropyltrimethoxyxilane, isopropyltriethoxysilane, isopropyltripropoxysilane, isopropyltriisopropoxysilane, butyltrimethoxysilane, butyltriethoxysilane, butyltripropoxysilane, butyltriisopropoxysilane, isobutyltrimethoxysilane, isobutyltriethoxysilane, isobutyltripropoxysilane, isobutyltriisopropoxysilane, sec-butyltrimethoxyxilane, sec-butyltriethoxysilane, sec-butyltripropoxysilane, sec-butyltriisopropoxysilane, t-butyltrimethoxyxilane, t-butyltriethoxysilane, t-butyltripropoxysilane, t-butyltriisopropoxysilane, allyltrimethoxysilane, allyltriethoxysilane, allyltrippropoxysilane, allyltriisopropoxysilane, cyclopropyltrimethoxysilane, cyclopropyltriethoxysilane, cyclopropyltripropoxysilane, cyclopropyltriisopropoxysilane, cyclobutyltrimethoxysilane, cyclobutyltriethoxysilane, cyclobutyltripropoxysilane, cyclobutyltriisopropoxysilane, cyclopentyltrimethoxysilane, cyclopentyltriethoxysilane, cyclopentyltripropoxysilane, cycloprentyltriisopropoxysilane, cyclohexyltrimethoxysilane, cyclohexyltriethoxysilane, cyclohexyltripropoxysilane, cyclohexyltriisopropoxysilane, cyclohexenyltrimethoxysilane, cyclohexenyltriethoxysilane, cyclohexenyltripropoxysilane, cyclohexenyltriisopropoxysilane, cyclohexenylethyltrimethoxysilane, cyclohexenylethyltriethoxysilane, cyclohexenylethyltripropoxysilane, cyclohexenylethyltriisopropoxysilane, cyclooctyltrimethoxysilane, cyclooctyltriethoxysilane, cyclooctyltripropoxysilane, cyclooctyltriisopropoxysilane, cyclopentadienylpropyltrimethoxysilane, cyclopentadienylpropyltriethoxysilane, cyclopentadienylpropyltripropoxysilane, cyclopentadienylpropyltriisopropoxysilane, bicycloheptenyltrimethoxysilane, bicycloheptenyltriethoxysilane, bicycloheptenyltripropoxysilane, bicycloheptenyltriisopropoxysilane, bicycloheptyltrimethoxysilane, bicycloheptyltriethoxysilane, bicycloheptyltripropoxysilane, bicycloheptyltriisopropoxysilane, adamantyltrimethoxysilane, adamantyltriethoxysilane, adamantyltripropoxysilane, adamantyltriisopropoxysilane, phenyltrimethoxysilane, phenyltriethoxysilane, phenyltrippropoxysilane, phenyltriisopropoxysilane, benzyltrimethoxysilane, benzyltriethoxysilane, benzyltrippropoxysilane, benzyltriisopropoxysilane, anisyltrimethoxysilane, anisyltriethoxysilane, anisyltrippropoxysilane, anisyltriisopropoxysilane, tolyltrimethoxysilane, tolyltriethoxysilane, tolyltripropoxysilane, tolyltriisopropoxysilane, phenethyltrimethoxysilane, phenethyltriethoxysilane, phenethyltripropoxysilane, phenethyltriisopropoxysilane, naphthyltrimethoxysilane, naphthyltriethoxysilane, naphthyltripropoxysilane, naphthyltriisopropoxysilane dimethyldimethoxysilane, dimethyldiethoxysilane, methylethyldimethoxysilane, methylethyldiethoxysilane, dimethyldipropoxysilane, dimethyldiisopropoxysilane, diethyldimethoxysilane, diethyldiethoxysilane, diehtyldipropoxysilane, diethyldiisopropoxysilane, dipropyldimethoxysilane, dipropyldiethoxysilane, dipropyldipropoxysilane, dipropyldiisopropoxysilane, diisopropyldimethoxysilane, diisopropyldiethoxysilane, diisopropyldipropoxysilane, diisopropyldiisopropoxysilane, dibutyldimethoxysilane, dibutyldiethoxysilane, dibutyldipropoxysilane, dibutyldiisopropoxysilane, di-sec-butyldimethoxysilane, di-sec-butyldiethoxysilane, di-sec-butyldipropoxysilane, di-sec-butyldiisopropoxysilane, di-t-butyldimethoxysilane, di-t-butyldiethoxysilane, di-t-butyldipropoxysilane, di-t-butyldiisopropoxysilane, dicyclopropyldimethoxysilane, dicyclopropyldiethoxysilane, dicyclopropyldipropoxysilane, dicyclopropyldiisopropoxysilane, dicyclobutyldimethoxysilane, dicyclobutyldiethoxysilane, dicyclobutyldipropoxysilane, dicyclobutyldiisopropoxysilane, dicyclopentyldimethoxysilane, dicyclopentyldiethoxysilane, dicyclopentyldipropoxysilane, dicyclopentyldiisopropoxysilane, dicyclohexyldimethoxysilane, dicyclohexyldiethoxysilane, dicyclohexyldipropoxysilane, dicyclohexyldiisopropoxysilane, dicyclohexenyldimethoxysilane, dicyclohexenyldiethoxysilane, dicyclohexenyldipropoxysilane, dicyclohexenyldiisopropoxysilane, dicyclohexenylethyldimethoxysilane, dicyclohexenylethyldiethoxysilane, dicyclohexenylethyldipropoxysilane, dicyclohexenylethyldiisopropoxysilane, dicyclooctyldimethoxysilane, dicyclooctyldiethoxysilane, dicyclooctyldipropoxysilane, dicyclooctyldiisopropoxysilane, dicyclopentadienylpropyldimethoxysilane, dicyclopentadienylpropyldiethoxysilane, dicyclopentadienylpropyldipropoxysilane, dicyclopentadienylpropyldiisopropoxysilane, bis(bicycloheptenyl)dimethoxysilane, bis(bicycloheptenyl)diethoxysilane, bis(bicycloheptenyl)dipropoxysilane, bis(bicycloheptenyl)diisopropoxysilane, bis(bicycloheptyl)dimethoxysilane, bis(bicycloheptyl)diethoxysilane, bis(bicycloheptyl)dipropoxysilane, bis(bicycloheptyl)diisopropoxysilane, diadamantyldimethoxysilane, diadamantyldiethoxysilane, diadamantyldipropoxysilane, diadamantyldiisopropoxysilane, diphenyldimethoxysilane, diphenyldiethoxysilane, methylphenyldimethoxysilane, methylphenyldiethoxysilane, diphenyldipropoxysilane, diphenyldiisopropoxysilane, trimethylmethoxysilane, trimethylethoxysilane, dimethylethylmethoxysilane, dimethylethylethoxysilane, dimethylphenylmethoxysilane, dimethylphenylethoxysilane, dimethylbenzylmethoxysilane, dimethylbenzylethoxysilane, dimethylphenethylmethoxysilane, and dimethylphenethylethoxysilane.

Preferable examples of the above compounds include tetramethoxysilane, tetraethoxysilane, methyltrimethoxysilane, methyltriethoxysilane, ethyltrimethoxysilane, ethyltriethoxysilane, vinyltrimethoxysilane, vinyltriethoxysilane, propyltrimethoxysilane, propyltriethoxysilane, isopropyltrimethoxysilane, isopropyltriethoxysilane, butyltrimethoxysilane, butyltriethoxysilane, isobutyltrimethoxysilane, isobutyltriethoxysilane, allyltrimethoxysilane, allyltriethoxysilane, cyclopentyltrimethoxysilane, cyclopentyltriethoxysilane, cyclohexyltrimethoxysilane, cyclohexyltriethoxysilane, cyclohexenyltrimethoxysilane, cyclohexenyltriethoxysilane, phenyltrimethoxysilane, phenyltriethoxysilane, benzyltrimethoxysilane, benzyltriethoxysilane, phenethyltrimethoxysilane, phenethyltriethoxysilane, dimethyldimethoxysilane, dimethyldiethoxysilane, diethyldimethoxysilane, diethyldiethoxysilane, methylethyldimethoxysilane, methylethyldiethoxysilane, dipropyldimethoxysilane, dibutyldimethoxysilane, methylphenyldimethoxysilane, methylphenyldiethoxysilane, trimethylmethoxysilane, dimethylethylmethoxysilane, dimethylphenylmethoxysilane, dimethylbenzylmethoxysilane, and dimethylphenethylmethoxysilane.

### [Synthesis Method of Thermally Crosslinkable Polysiloxane (Reaction)]

### (Synthetic Method 1: Acid Catalyst)

The thermally crosslinkable polysiloxane to be used in the present invention can be manufactured by hydrolytically condensing a mixture of one or more kinds of the hydrolysable monomer (Sm) in the presence of an acid catalyst.

Examples of the acid catalyst used in this case include: organic acids, such as formic acid, acetic acid, oxalic acid, maleic acid, methanesulfonic acid, benzenesulfonic acid, and toluenesulfonic acid; and hydrofluoric acid, hydrochloric acid, hydrobromic acid, sulfuric acid, nitric acid, perchloric acid, and phosphoric acid. A use amount of the catalyst is preferably 1×10⁻⁶ to 10 mol, more preferably 1×10⁻⁵ to 5 mol, and further preferably 1×10⁻⁴ to 1 mol, relative to 1 mol of the monomer.

An amount of water added for obtaining the thermally crosslinkable polysiloxane by hydrolytically condensing these monomers is preferably 0.01 to 100 mol, more preferably 0.05 to 50 mol, and further preferably 0.1 to 30 mol, relative to 1 mol of the hydrolysable substituent bonded to the monomer. When the amount is 100 mol or less, an apparatus used for the reaction may be small, which is economical. When the amount is 0.01 mol or more, the reaction proceeds sufficiently.

As the procedure, the monomer is added into an aqueous solution of the catalyst to initiate the hydrolytic condensation reaction. In this case, an organic solvent may be added into the aqueous solution of the catalyst, the monomer may be diluted in advance with an organic solvent, or both of them may be performed. The reaction temperature is preferably 0 to 100° C., and more preferably 5 to 80° C. A preferable method is retaining the temperature at 5 to 80° C. during dropwise addition of the monomer, and then aging at 20 to 80° C.

Preferable organic solvents that can be added into the aqueous solution of the catalyst or that can dilute the monomer include methanol, ethanol, 1-propanol, 2-propanol, 1-butanol, 2-butanol, 2-methyl-1-propanol, ethylene glycol, propylene glycol, acetone, acetonitrile, tetrahydrofuran, toluene, hexane, acetic acid, methyl ethyl ketone, methyl isobutyl ketone, cyclohexanone, methyl amyl ketone, butanediol monomethyl ether, propylene glycol monomethyl ether, ethylene glycol monomethyl ether, butanediol monoethyl ether, propylene glycol monoethyl ether, ethylene glycol monoethyl ether, ethylene glycol monopropyl ether, propylene glycol dimethyl ether, diethylene glycol dimethyl ether, propylene glycol monomethyl ether acetate, propylene glycol monoethyl ether acetate, ethyl pyruvate, butyl acetate, methyl 3-methoxypropionate, ethyl 3-ethoxypropionate, tert-butyl acetate, tert-butyl propionate, propylene glycol mono-t-butyl ether acetate, γ-butyrolactone, and a mixture thereof.

Preferable solvents among these are water-soluble solvents. Examples thereof include: alcohols such as methanol, ethanol, 1-propanol, and 2-propanol; polyhydric alcohols such as ethylene glycol and propylene glycol; polyhydric alcohol condensate derivatives, such as butanediol monomethyl ether, propylene glycol monomethyl ether, ethylene glycol monomethyl ether, butanediol monoethyl ether, propylene glycol monoethyl ether, ethylene glycol monoethyl ether, butanediol monopropyl ether, propylene glycol monopropyl ether, and ethylene glycol monopropyl ether; acetone; acetonitrile; and tetrahydrofuran. Particularly preferable solvents among these have a boiling point of 100° C. or lower.

An amount of the used organic solvent is preferably 0 to 1,000 m1, and particularly preferably 0 to 500 m1 relative to 1 mol of the monomer. When the amount of the used organic solvent is smaller, a reaction vessel may be smaller, which is economical.

Thereafter, a neutralization reaction of the catalyst is performed as necessary to obtain an aqueous solution of the reaction mixture. In this case, an amount of an alkaline substance that can be used for the neutralization is preferably 0.1 to 2 equivalents relative to the used acid as the catalyst. This alkaline substance may be any substance as long as it exhibits alkalinity in water.

Subsequently, a byproduct such as an alcohol generated by the hydrolytic condensation reaction is preferably removed from the aqueous solution of the reaction mixture under a reduced pressure, etc. In this case, a temperature at which the aqueous solution of the reaction mixture is heated is preferably 0 to 100° C., more preferably 10 to 90° C., and further preferably 15 to 80° C., depending on types of the added organic solvent and the alcohol generated in the reaction. A pressure reducing degree in this case is preferably the atmospheric pressure or lower, more preferably 80 kPa or lower as an absolute pressure, and further preferably 50 kPa or lower as an absolute pressure, which varies depending on types of the organic solvent and the alcohol to be removed, a ventilation apparatus, a condensation apparatus, and the heating temperature. Although the amount of the removed alcohol in this case is difficult to be accurately determined, approximately 80 mass % or more of the generated alcohol, etc. is desirably removed.

Then, the acid catalyst used for the hydrolytic condensation may be removed from the aqueous solution of the reaction mixture. As a method for removing the acid catalyst, water and the solution of the thermally crosslinkable polysiloxane are mixed, and the thermally crosslinkable polysiloxane is extracted with an organic solvent. The organic solvent used in this case is preferably an organic solvent that can dissolve the thermally crosslinkable polysiloxane and that forms separated two layers when mixed with water. Examples thereof include methanol, ethanol, 1-propanol, 2-propanol, 1-butanol, 2-butanol, 2-methyl-1-propanol, acetone, tetrahydrofuran, toluene, hexane, ethyl acetate, cyclohexanone, methyl amyl ketone, butanediol monomethyl ether, propylene glycol monomethyl ether, ethylene glycol monomethyl ether, butanediol monoethyl ether, propylene glycol monoethyl ether, ethylene glycol monoethyl ether, butanediol monopropyl ether, propylene glycol monopropyl ether, ethylene glycol monopropyl ether, propylene glycol dimethyl ether, diethylene glycol dimethyl ether, propylene glycol monomethyl ether acetate, propylene glycol monoethyl ether acetate, ethyl pyruvate, butyl acetate, methyl 3-methoxypropionate, ethyl 3-ethoxypropionate, t-butyl acetate, t-butyl propionate, propylene glycol mono-t-butyl ether acetate, γ-butyrolactone, methyl isobutyl ketone, cyclopentyl methyl ether, and a mixture thereof.

Furthermore, a mixture of a water-soluble organic solvent and a water-hardly-soluble organic solvent can also be used. Examples of preferable mixtures include a methanol-ethyl acetate mixture, an ethanol-ethyl acetate mixture, a 1-propanol-ethyl acetate mixture, a 2-propanol-ethyl acetate mixture, a butanediol monomethyl ether-ethyl acetate mixture, a propylene glycol monomethyl ether-ethyl acetate mixture, an ethylene glycol monomethyl ether-ethyl acetate mixture, a butanediol monoethyl ether-ethyl acetate mixture, a propylene glycol monoethyl ether-ethyl acetate mixture, an ethylene glycol monoethyl ether-ethyl acetate mixture, a butanediol monopropyl ether-ethyl acetate mixture, a propylene glycol monopropyl ether-ethyl acetate mixture, an ethylene glycol monopropyl ether-ethyl acetate mixture, a methanol-methyl isobutyl ketone mixture, an ethanol-methyl isobutyl ketone mixture, a 1-propanol-methyl isobutyl ketone mixture, a 2-propanol-methyl isobutyl ketone mixture, a propylene glycol monomethyl ether-methyl isobutyl ketone mixture, an ethylene glycol monomethyl ether-methyl isobutyl ketone mixture, a propylene glycol monoethyl ether-methyl isobutyl ketone mixture, an ethylene glycol monoethyl ether-methyl isobutyl ketone mixture, a propylene glycol monopropyl ether-methyl isobutyl ketone mixture, an ethylene glycol monopropyl ether-methyl isobutyl ketone mixture, a methanol-cyclopentyl methyl ether mixture, an ethanol-cyclopentyl methyl ether mixture, a 1-propanol-cyclopentyl methyl ether mixture, a 2-propanol-cyclopentyl methyl ether mixture, a propylene glycol monomethyl ether-cyclopentyl methyl ether mixture, an ethylene glycol monomethyl ether-cyclopentyl methyl ether mixture, a propylene glycol monoethyl ether-cyclopentyl methyl ether mixture, an ethylene glycol monoethyl ether-cyclopentyl methyl ether mixture, a propylene glycol monopropyl ether-cyclopentyl methyl ether mixture, an ethylene glycol monopropyl ether-cyclopentyl methyl ether mixture, a methanol-propylene glycol methyl ether acetate mixture, an ethanol-propylene glycol methyl ether acetate mixture, a 1-propanol-propylene glycol methyl ether acetate mixture, a 2-propanol-propylene glycol methyl ether acetate mixture, a propylene glycol monomethyl ether-propylene glycol methyl ether acetate mixture, an ethylene glycol monomethyl ether-propylene glycol methyl ether acetate mixture, a propylene glycol monoethyl ether-propylene glycol methyl ether acetate mixture, an ethylene glycol monoethyl ether-propylene glycol methyl ether acetate mixture, a propylene glycol monopropyl ether-propylene glycol methyl ether acetate mixture, and an ethylene glycol monopropyl ether-propylene glycol methyl ether acetate mixture. However, the combination is not limited thereto.

A mixing ratio between the water-soluble organic solvent and the water-hardly-soluble organic solvent may be appropriately selected, and is preferably 0.1 to 1,000 parts by mass, more preferably 1 to 500 parts by mass, and further preferably 2 to 100 parts by mass of the water-soluble organic solvent, relative to 100 parts by mass of the water-hardly-soluble organic solvent.

Subsequently, the reaction mixture may be washed with neutral water. As this water, so-called deionized water or ultrapure water may be used. The amount of this water is preferably 0.01 to 100 L, more preferably 0.05 to 50 L, and further preferably 0.1 to 5 L relative to 1 L of the solution of the thermally crosslinkable polysiloxane. In this washing method, the both may be added into one vessel, and the mixture is stirred and left to stand to separate the aqueous layer. The number of the washings is one or more times, and preferably one to approximately five, because even ten or more washings do not yield an effect commensurate with that number of washings.

Examples of another method for removing the acid catalyst include: a method with an ion-exchange resin; and a method of neutralization with an epoxy compound, such as ethylene oxide and propylene oxide, and then removing the neutralized product. These methods may be appropriately selected according to the acid catalyst used for the reaction.

The washing procedure with water in this case may allow a part of the thermally crosslinkable polysiloxane to escape into the aqueous layer and may yield an effect substantially same as a fractioning procedure. Thus, the number of washing with water and the amount of washing water may be appropriately selected with considering the effect of removing the catalyst and the effect of fractioning.

In any of the solution of the thermally crosslinkable polysiloxane with an acid catalyst remained and the solution of the thermally crosslinkable polysiloxane with an acid catalyst removed, a final solvent is added thereto and solvent exchange is performed under a reduced pressure to obtain a desired solution of the thermally crosslinkable polysiloxane. The temperature of the solvent exchange in this case is preferably 0 to 100° C., more preferably 10 to 90° C., and further preferably 15 to 80° C., depending on types of the reaction solvent and extraction solvent to be removed. A pressure reducing degree in this case is preferably the atmospheric pressure or lower, more preferably 80 kPa or lower as an absolute pressure, and further preferably 50 kPa or lower as an absolute pressure, which differs depending on a type of the extraction solvent to be removed, a ventilation apparatus, a condensation apparatus, and the heating temperature.

In this case, the thermally crosslinkable polysiloxane may be destabilized by exchanging the solvent. This destabilization is caused by compatibility between the final solvent and the thermally crosslinkable polysiloxane. To prevent this destabilization, a monovalent or polyvalent alcohol having a cyclic ether as a substituent described in paragraphs (0181) to (0182) in JP2009-126940A may be added as a stabilizer. The amount of the stabilizer to be added is preferably 0 to 25 parts by mass, more preferably 0 to 15 parts by mass, and further preferably 0 to 5 parts by mass, relative to 100 parts by mass of the thermally crosslinkable polysiloxane in the solution before the solvent exchange. When the stabilizer is added, the amount is preferably 0.5 parts by mass or more. As necessary, the monovalent or polyvalent alcohol having a cyclic ether as a substituent is added into the solution before the solvent exchange, and then the solvent exchange procedure is performed.

The thermally crosslinkable polysiloxane is preferably maintained as a solution state at an appropriate concentration. The concentration in this case is preferably 0.1 to 20 mass %. At such a concentration, no further condensation reaction occurs, so that the state does not change to a state where it cannot be redissolved in the organic solvent. Moreover, the amount of solvent is reduced, which is economical and preferable.

The preferred final solvent to be added to the solution of the thermally crosslinkable polysiloxane is an organic solvent that does not dissolve a resist film. The resist used in the present invention contains a hypervalent iodine compound, a carboxylic acid compound, and a solvent. After film formation, the carboxylic acid compound and the hypervalent iodine undergo a ligand exchange reaction, making the resist insoluble in general organic solvents. Therefore, the final solvent to be added to the solution of the thermally crosslinkable polysiloxane is not particularly limited as long as it is a general organic solvent, and examples thereof include the following solvents.

Butanediol monomethyl ether, propylene glycol monomethyl ether, ethylene glycol monomethyl ether, butanediol monoethyl ether, propylene glycol monoethyl ether, ethylene glycol monoethyl ether, butanediol monopropyl ether, propylene glycol monopropyl ether, ethylene glycol monopropyl ether, diacetone alcohol, 2-octanone, 2-nonanone, 2-heptanone, 3-heptanone, 4-heptanone, 2-hexanone, 3-hexanone, diisobutyl ketone, 5-methyl-2-hexanone, methylcyclohexanone, acetophenone, methylacetophenone, isopropyl alcohol, isoamyl alcohol, n-butanol, tert-butyl alcohol, tert-pentyl alcohol, n-pentanol, cyclohexanol, formic acid, acetic acid, propionic acid, propyl acetate, butyl acetate, isobutyl acetate, pentyl acetate, butenyl acetate, isopentyl acetate, cyclohexyl acetate, 4-tert-butylcyclohexyl acetate, octyl acetate, isobornyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, ethyl phenylacetate, benzyl formate, phenylethyl formate, methyl 3-phenylpropionate, benzyl propionate, 2-phenylethyl acetate, 2-propanol, 3-methoxybutanol, 3-methyl-3-methoxybutanol, 1-methoxy-2-propanol, 1-ethoxy-2-propanol, 3-methyl-1-butanol, diacetone alcohol, 4-methyl-2-pentanol, 3-methylcyclohexanol, 3,5,5-trimethylhexyl alcohol, 2,6-dimethyl-4-heptanol, anisole, ε-caprolactone, toluene, hexane, ethyl acetate, cyclohexanone, methyl amyl ketone, propylene glycol dimethyl ether, diethylene glycol dimethyl ether, propylene glycol monomethyl ether acetate, propylene glycol monoethyl ether acetate, ethyl pyruvate, methyl 3-methoxypropionate, ethyl 3-ethoxypropionate, t-butyl propionate, propylene glycol mono t-butyl ether acetate, γ-butyrolactone, methyl isobutyl ketone, cyclopentyl methyl ether. One kind of these solvents may be used, or two or more kinds thereof may be used in mixture.

As another reaction procedure using the acid catalyst, water or a water-containing organic solvent is added into the monomer or an organic solution of the monomer to initiate the hydrolysis reaction. In this case, the catalyst may be added into the monomer or the organic solution of the monomer, or may be added in advance into the water or the water-containing organic solvent. The reaction temperature is preferably 0 to 100° C., and more preferably 10 to 80° C. A preferable method is heating during dropwise addition of the water at 10 to 50° C., and then raising the temperature to 20 to 80° C. to age the reaction mixture.

When being used, the organic solvent is preferably water-soluble. Examples thereof include polyhydric alcohol condensate derivatives, such as methanol, ethanol, 1-propanol, 2-propanol, 1-butanol, 2-butanol, 2-methyl-1-propanol, acetone, tetrahydrofuran, acetonitrile, butanediol monomethyl ether, propylene glycol monomethyl ether, ethylene glycol monomethyl ether, butanediol monoethyl ether, propylene glycol monoethyl ether, ethylene glycol monoethyl ether, butanediol monopropyl ether, propylene glycol monopropyl ether, ethylene glycol monopropyl ether, propylene glycol dimethyl ether, diethylene glycol dimethyl ether, propylene glycol monomethyl ether acetate, propylene glycol monoethyl ether acetate, propylene glycol monopropyl ether acetate, and a mixture thereof.

An amount of the used organic solvent is preferably 0 to 1,000 m1, and particularly preferably 0 to 500 m1 relative to 1 mol of the monomer. The less the amount of the organic solvent is used, the smaller the reaction vessel is, and the more economical it becomes. The obtained aqueous solution of the reaction mixture can be after-treated in the same manner as the above method to obtain the thermally crosslinkable polysiloxane.

### (Synthetic Method 2: Alkali Catalyst)

The thermally crosslinkable polysiloxane (Sx) may also be manufactured by hydrolytically condensing a mixture of one or two or more types of the hydrolysable monomer (Sm) in the presence of an alkali catalyst. Examples of the alkali catalyst used in this case include methylamine, ethylamine, propylamine, butylamine, ethylenediamine, hexamethylenediamine, dimethylamine, diethylamine, ethylmethylamine, trimethylamine, triethylamine, tripropylamine, tributylamine, cyclohexylamine, dicyclohexylamine, monoethanolamine, diethanolamine, dimethylmonoethanolamine, monomethyldiethanolamine, triethanolamine, diazabicyclooctane, diazabicyclononene, diazabicycloundecene, hexamethylenetetramine, aniline, N,N-dimethylaniline, pyridine, N,N-dimethylaminopyridine, pyrrole, piperazine, pyrrolidine, piperidine, picoline, tetramethylammonium hydroxide, choline hydroxide, tetrapropylammonium hydroxide, tetrabutylammonium hydroxide, ammonia, lithium hydroxide, sodium hydroxide, potassium hydroxide, barium hydroxide, and calcium hydroxide. The amount of the used catalyst is preferably 1×10⁻⁶ to 10 mol, more preferably 10⁻⁵ to 5 mol, and further preferably 1×10⁻⁴ to 1 mol, relative to 1 mol of the monomer.

An amount of water added for obtaining the thermally crosslinkable polysiloxane from the monomer via the hydrolytic condensation is preferably 0.1 to 50 mol relative to 1 mol of the hydrolysable substituent bonded to the monomer. When the amount is 50 mol or less, an apparatus used for the reaction may be small, which is economical. When the amount is 0.01 mol or more, the reaction proceeds sufficiently.

As the procedure, the monomer is added into an aqueous solution of the catalyst to initiate the hydrolytic condensation reaction. In this case, an organic solvent may be added into the aqueous solution of the catalyst, the monomer may be diluted in advance with an organic solvent, or both of them may be performed. The reaction temperature is preferably 0 to 100° C., and more preferably 5 to 80° C. A preferable method is retaining the temperature at 5 to 80° C. during dropwise addition of the monomer, and then aging at 20 to 80° C.

Preferably used organic solvents that can be added into the aqueous solution of the alkali catalyst or that can dilute the monomer are the organic solvents same as those exemplified as the organic solvent that can be added into the aqueous solution of the acid catalyst. An amount of the used organic solvent is preferably 0 to 1,000 m1 relative to 1 mol of the monomer for the economical reaction.

Thereafter, a neutralization reaction of the catalyst is performed as necessary to obtain an aqueous solution of the reaction mixture. In this case, an amount of an acidic substance that can be used for the neutralization is preferably 0.1 to 2 equivalents relative to the alkaline substance used as the catalyst. This acidic substance may be any substance as long as it exhibits acidity in water.

Subsequently, a byproduct such as an alcohol generated by the hydrolytic condensation reaction is preferably removed from the aqueous solution of the reaction mixture under a reduced pressure, etc. In this case, a temperature at which the aqueous solution of the reaction mixture is heated is preferably 0 to 100° C., more preferably 10 to 90° C., and further preferably 15 to 80° C., depending on types of the added organic solvent and alcohol generated in the reaction. A pressure reducing degree in this case is preferably the atmospheric pressure or lower, more preferably 80 kPa or lower as an absolute pressure, and further preferably 50 kPa or lower as an absolute pressure, which differs depending on types of the organic solvent and alcohol to be removed, a ventilation apparatus, a condensation apparatus, and the heating temperature. Although the amount of the removed alcohol in this case is difficult to be accurately determined, approximately 80 mass % or more of the generated alcohol is desirably removed.

Then, to remove the catalyst used for the hydrolytic condensation, the thermally crosslinkable polysiloxane is extracted with an organic solvent. The organic solvent used in this case is preferably an organic solvent that can dissolve the thermally crosslinkable polysiloxane and that forms separated two layers when mixed with water. Examples thereof include methanol, ethanol, 1-propanol, 2-propanol, 1-butanol, 2-butanol, 2-methyl-1-propanol, acetone, tetrahydrofuran, toluene, hexane, ethyl acetate, cyclohexanone, methyl amyl ketone, propylene glycol monomethyl ether, ethylene glycol monomethyl ether, propylene glycol monoethyl ether, ethylene glycol monoethyl ether, propylene glycol monopropyl ether, ethylene glycol monopropyl ether, propylene glycol dimethyl ether, diethylene glycol dimethyl ether, propylene glycol monomethyl ether acetate, propylene glycol monoethyl ether acetate, ethyl pyruvate, butyl acetate, methyl 3-methoxypropionate, ethyl 3-ethoxypropionate, tert-butyl acetate, tert-butyl propionate, propylene glycol mono-t-butyl ether acetate, γ-butyrolactone, methyl isobutyl ketone, cyclopentyl methyl ether, and a mixture thereof.

Further, a mixture of a water-soluble organic solvent and a water-hardly-soluble organic solvent can also be used.

Specific examples of the organic solvent used for removing the alkali catalyst include: the above specifically exemplified organic solvents used for removing the acid catalyst; and organic solvents same as the mixture of the water-soluble organic solvent and the water-hardly soluble organic solvent.

A mixing ratio between the water-soluble organic solvent and the water-hardly-soluble organic solvent is appropriately selected, and is preferably 0.1 to 1,000 parts by mass, more preferably 1 to 500 parts by mass, and further preferably 2 to 100 parts by mass of the water-soluble organic solvent, relative to 100 parts by mass of the water-hardly-soluble organic solvent.

Subsequently, the reaction mixture is washed with neutral water. As this water, so-called deionized water or ultrapure water is typically used. The amount of this water is preferably 0.01 to 100 L, more preferably 0.05 to 50 L, and further preferably 0.1 to 5 L, relative to 1 L of the solution of the thermally crosslinkable polysiloxane. In this washing method, the both are added into one vessel, and the mixture is stirred and left to stand to separate the aqueous layer. The number of the washings is one or more times, and preferably one to approximately five, because even ten or more washings do not yield an effect commensurate with that number of washings.

Into the washed solution of the thermally crosslinkable polysiloxane, a final solvent is added, and solvent exchange is performed under a reduced pressure to obtain a solution of the desired thermally crosslinkable polysiloxane. The temperature of the solvent exchange in this case is preferably 0 to 100° C., more preferably 10 to 90° C., and further preferably 15 to 80° C., depending on the type of the extraction solvent to be removed. A pressure reducing degree in this case is preferably the atmospheric pressure or lower, more preferably 80 kPa or lower as an absolute pressure, and further preferably 50 kPa or lower as an absolute pressure, which differs depending on a type of the extraction solvent to be removed, a ventilation apparatus, a condensation apparatus, and the heating temperature.

The preferred final solvent to be added to the solution of the thermally crosslinkable polysiloxane is an organic solvent that does not dissolve the resist film. The resist used in the present invention is a resist composition containing a hypervalent iodine compound, a carboxylic acid compound, and a solvent. After film formation, the carboxylic acid compound and the hypervalent iodine undergo a ligand exchange reaction, making the resist insoluble in general organic solvents. Therefore, the final solvent to be added to the solution of the thermally crosslinkable polysiloxane is not particularly limited as long as it is a general organic solvent, and examples thereof include the following solvents.

Butanediol monomethyl ether, propylene glycol monomethyl ether, ethylene glycol monomethyl ether, butanediol monoethyl ether, propylene glycol monoethyl ether, ethylene glycol monoethyl ether, butanediol monopropyl ether, propylene glycol monopropyl ether, ethylene glycol monopropyl ether, diacetone alcohol, 2-octanone, 2-nonanone, 2-heptanone, 3-heptanone, 4-heptanone, 2-hexanone, 3-hexanone, diisobutyl ketone, 5-methyl-2-hexanone, methylcyclohexanone, acetophenone, methylacetophenone, isopropyl alcohol, isoamyl alcohol, n-butanol, tert-butyl alcohol, tert-pentyl alcohol, n-pentanol, cyclohexanol, formic acid, acetic acid, propionic acid, propyl acetate, butyl acetate, isobutyl acetate, pentyl acetate, butenyl acetate, isopentyl acetate, cyclohexyl acetate, 4-tert-butylcyclohexyl acetate, octyl acetate, isobornyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, ethyl phenylacetate, benzyl formate, phenylethyl formate, methyl 3-phenylpropionate, benzyl propionate, 2-phenylethyl acetate, 2-propanol, 3-methoxybutanol, 3-methyl-3-methoxybutanol, 1-methoxy-2-propanol, 1-ethoxy-2-propanol, 3-methyl-1-butanol, diacetone alcohol, 4-methyl-2-pentanol, 3-methylcyclohexanol, 3,5,5-trimethylhexyl alcohol, 2,6-dimethyl-4-heptanol, toluene, anisole, s-caprolactone, toluene, hexane, ethyl acetate, cyclohexanone, methyl amyl ketone, propylene glycol dimethyl ether, diethylene glycol dimethyl ether, propylene glycol monomethyl ether acetate, propylene glycol monoethyl ether acetate, ethyl pyruvate, methyl 3-methoxypropionate, ethyl 3-ethoxypropionate, t-butyl propionate, propylene glycol mono t-butyl ether acetate, γ-butyrolactone, methyl isobutyl ketone, cyclopentyl methyl ether. One kind of these solvents may be used, or two or more kinds thereof may be used in mixture.

As another reaction procedure using the alkali catalyst, water or a water-containing organic solvent is added into the monomer or an organic solution of the monomer to initiate the hydrolysis reaction. In this case, the catalyst may be added into the monomer or the organic solution of the monomer, or may be added in advance into the water or the water-containing organic solvent. The reaction temperature is preferably 0 to 100° C., and more preferably 10 to 80° C. A preferable method is heating at 10 to 50° C. during dropwise addition of the water, and then raising the temperature to 20 to 80° C. to age the reaction mixture.

The usable organic solvent as the organic solution of the monomer or the water-containing organic solvent is preferably water-soluble. Examples thereof include polyhydric alcohol condensate derivatives, such as methanol, ethanol, 1-propanol, 2-propanol, 1-butanol, 2-butanol, 2-methyl-1-propanol, acetone, tetrahydrofuran, acetonitrile, propylene glycol monomethyl ether, ethylene glycol monomethyl ether, propylene glycol monoethyl ether, ethylene glycol monoethyl ether, propylene glycol monopropyl ether, ethylene glycol monopropyl ether, propylene glycol dimethyl ether, diethylene glycol dimethyl ether, propylene glycol monomethyl ether acetate, propylene glycol monoethyl ether acetate, propylene glycol monopropyl ether acetate, and a mixture thereof.

A molecular weight of the thermally crosslinkable polysiloxane obtained by the above synthetic method 1 or 2 can be regulated by not only selecting the monomer but also controlling the reaction condition of the polymerization. When the weight-average molecular weight is 100,000 or less, no foreign matter or coating unevenness occurs. Therefore, the thermally crosslinkable polysiloxane to be used has preferably a weight-average molecular weight of 100,000 or less, more preferably 200 to 50,000, and further preferably 300 to 30,000. Note that data regarding the above weight-average molecular weight indicate the molecular weight, in terms of polystyrene, determined by gel permeation chromatography (GPC) using tetrahydrofuran as an eluent solvent, using RI as a detector, and using polystyrene as a standard substance.

The thermally crosslinkable polysiloxane used in the present invention has different physical properties depending on types of the acid or alkali catalyst used in the hydrolytic condensation and the reaction condition. Thus, the catalyst and the reaction condition can be appropriately selected according to target performance of the material for forming a silicon-containing reversed pattern.

Further, a polysiloxane derivative manufactured using a mixture of one or two or more kinds of the hydrolysable monomer (Sm) and a hydrolysable metal compound represented by the following general formula (Mm) under the condition using the acid or the alkali catalyst may be used as a component of the material composition for forming a silicon-containing reversed pattern.

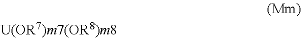

In the formula (Mm), R⁷ and R⁸ each independently represent an organic group having 1 to 30 carbon atoms; m7+m8 is same as a valence number determined by a type of U, “m7” and “m8” represent an integer of 0 or more; and “U” represents an atom belonging to the III-group, IV-group, or V-group in the periodic table except for carbon and silicon.

Examples of the hydrolysable metal compound represented by the above formula (Mm) used in this case include the following. When “U” is boron, examples of the hydrolysable metal compound represented by the general formula (Mm) include, boron methoxide, boron ethoxide, boron propoxide, boron butoxide, boron amyloxide, boron hexyloxide, boron cyclopentoxide, boron cyclohexyloxide, boron allyloxide, boron phenoxide, boron methoxyethoxide, boric acid, and boron oxide.

When “U” is aluminum, examples of the hydrolysable metal compound represented by the general formula (Mm) include, aluminum methoxide, aluminum ethoxide, aluminum propoxide, aluminum butoxide, aluminum amyloxide, aluminum hexyloxide, aluminum cyclopentoxide, aluminum cyclohexyloxide, aluminum allyloxide, aluminum phenoxide, aluminum methoxyethoxide, aluminum ethoxyethoxide, aluminum dipropoxy(ethyl acetoacetate), aluminum dibutoxy(ethyl acetoacetate), aluminum propoxy bis(ethyl acetoacetate), aluminum butoxy bis(ethyl acetoacetate), aluminum 2,4-pentanedionate, and aluminum 2,2,6,6-tetramethyl-3,5-heptanedionate.

When “U” is gallium, examples of the hydrolysable metal compound represented by the general formula (Mm) include, gallium methoxide, gallium ethoxide, gallium propoxide, gallium butoxide, gallium amyloxide, gallium hexyloxide, gallium cyclopentoxide, gallium cyclohexyloxide, gallium allyloxide, gallium phenoxide, gallium methoxyethoxide, gallium ethoxyethoxide, gallium dipropoxy(ethyl acetoacetate), gallium dibutoxy(ethyl acetoacetate), gallium propoxy bis(ethyl acetoacetate), gallium butoxy bis(ethyl acetoacetate), gallium 2,4-pentanedionate, and gallium 2,2,6,6-tetramethyl-3,5-heptanedionate.

When “U” is yttrium, examples of the hydrolysable metal compound represented by the general formula (Mm) include, yttrium methoxide, yttrium ethoxide, yttrium propoxide, yttrium butoxide, yttrium amyloxide, yttrium hexyloxide, yttrium cyclopentoxide, yttrium cyclohexyloxide, yttrium allyloxide, yttrium phenoxide, yttrium methoxyethoxide, yttrium ethoxyethoxide, yttrium dipropoxy(ethyl acetoacetate), yttrium dibutoxy(ethyl acetoacetate), yttrium propoxy bis(ethyl acetoacetate), yttrium butoxy bis(ethyl acetoacetate), yttrium 2,4-pentanedionate, and yttrium 2,2,6,6-tetramethyl-3,5-heptanedionate.

When “U” is germanium, examples of the hydrolysable metal compound represented by the general formula (Mm) include, germanium methoxide, germanium ethoxide, germanium propoxide, germanium butoxide, germanium amyloxide, germanium hexyloxide, germanium cyclopentoxide, germanium cyclohexyloxide, germanium allyloxide, germanium phenoxide, germanium methoxyethoxide, and germanium ethoxyethoxide.

When “U” is titanium, examples of the hydrolysable metal compound represented by the general formula (Mm) include, titanium methoxide, titanium ethoxide, titanium propoxide, titanium butoxide, titanium amyloxide, titanium hexyloxide, titanium cyclopentoxide, titanium cyclohexyloxide, titanium allyloxide, titanium phenoxide, titanium methoxyethoxide, titanium ethoxyethoxide, titanium dipropoxy bis(ethyl acetoacetate), titanium dibutoxy bis(ethyl acetoacetate), titanium dipropoxy bis(2,4-pentanedionate), and titanium dibutoxy bis(2,4-pentanedionate).

When “U” is hafnium, examples of the hydrolysable metal compound represented by the general formula (Mm) include, hafnium methoxide, hafnium ethoxide, hafnium propoxide, hafnium butoxide, hafnium amyloxide, hafnium hexyloxide, hafnium cyclopentoxide, hafnium cyclohexyloxide, hafnium allyloxide, hafnium phenoxide, hafnium methoxyethoxide, hafnium ethoxyethoxide, hafnium dipropoxy bis(ethyl acetoacetate), hafnium dibutoxy bis(ethyl acetoacetate), hafnium dipropoxy bis(2,4-pentanedionate), and hafnium dibutoxy bis(2,4-pentanedionate).

When “U” is tin, examples of the hydrolysable metal compound represented by the general formula (Mm) include, methoxy tin, ethoxy tin, propoxy tin, butoxy tin, phenoxy tin, methoxyethoxy tin, ethoxyethoxy tin, tin 2,4-pentanedionate, and tin 2,2,6,6-tetramethyl-3,5-heptanedionate.

When “U” is arsenic, examples of the hydrolysable metal compound represented by the general formula (Mm) include, methoxy arsenic, ethoxy arsenic, propoxy arsenic, butoxy arsenic, and phenoxy arsenic.

When “U” is antimony, examples of the hydrolysable metal compound represented by the general formula (Mm) include, methoxy antimony, ethoxy antimony, propoxy antimony, butoxy antimony, phenoxy antimony, antimony acetate, and antimony propionate.

When “U” is niobium, e examples of the hydrolysable metal compound represented by the general formula (Mm) include, methoxy niobium, ethoxy niobium, propoxy niobium, butoxy niobium, and phenoxy niobium.

When “U” is tantalum, examples of the hydrolysable metal compound represented by the general formula (Mm) include, methoxy tantalum, ethoxy tantalum, propoxy tantalum, butoxy tantalum, and phenoxy tantalum.

When “U” is bismuth, examples of the hydrolysable metal compound represented by the general formula (Mm) include, methoxy bismuth, ethoxy bismuth, propoxy bismuth, butoxy bismuth, and phenoxy bismuth.

When “U” is phosphorus, e examples of the hydrolysable metal compound represented by the general formula (Mm) include, trimethyl phosphate, triethyl phosphate, tripropyl phosphate, trimethyl phosphite, triethyl phosphite, tripropyl phosphite, and diphosphorous pentaoxide.

When “U” is vanadium, examples of the hydrolysable metal compound represented by the general formula (Mm) include vanadium oxide bis(2,4-pentanedionate), vanadium 2,4-pentanedionate, vanadium tributoxide oxide, and vanadium tripropoxide oxide.

When “U” is zirconium, examples of the hydrolysable metal compound represented by the general formula (Mm) include, methoxy zirconium, ethoxy zirconium, propoxy zirconium, butoxy zirconium, phenoxy zirconium, zirconium dibutoxide bis(2,4-pentanedionate), and zirconium dipropoxide bis(2,2,6,6-tetramethyl-3,5-heptanedionate).

### [Blending Amount of Thermally Crosslinkable Polysiloxane]

In the material composition for forming a silicon-containing reversed pattern to be used in the present invention, the blending amount of the thermally crosslinkable polysiloxane is preferably, for example, 0.1 to 10 mass % relative to that of the solvent.

### [Crosslinking Catalyst for Polymerizing Siloxane]

The material composition for forming a silicon-containing reversed pattern to be used in the present invention can contain a compound represented by the following general formula (Xc) in addition to the thermally crosslinkable polysiloxane. Hereinafter, this compound may also be referred to as a crosslinking catalyst for polymerizing siloxane or simply a crosslinking catalyst.

In the present invention, the crosslinking catalyst for polymerizing siloxane may be a sulfonium salt, an iodonium salt, a phosphonium salt, an ammonium salt, polysiloxane having any of these as part of its structure, or an alkali metal salt.

Examples of the crosslinking catalyst for polymerizing siloxane (Xc) include compounds represented by the following general formula (Xc0).

LₐH_{b}A (Xc0)

In the formula, “L” represents lithium, sodium, potassium, rubidium, cesium, sulfonium, iodonium, phosphonium, or ammonium; “A” represents a non-nucleophilic counter ion; and “a” represents an integer of 1 or more, “b” represents 0 or an integer of 1 or more, and a+b represents a valence number of the non-nucleophilic counter ion.

Specific examples of (Xc0) include a sulfonium salt represented by the following general formula (Xc-1), an iodonium salt represented by the following general formula (Xc-2), a phosphonium salt represented by the following general formula (Xc-3), an ammonium salt represented by the following general formula (Xc-4), and an alkali metal salt.

The sulfonium salt (Xc-1), the iodonium salt (Xc-2), and the phosphonium salt (Xc-3) are exemplified as follows.

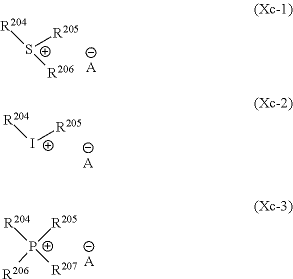

The ammonium salt (Xc-4) is exemplified as follows.

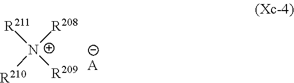

In the formulae (Xc-1) to (Xc-4), R²⁰⁴, R²⁰⁵, R²⁰⁶, and R²⁰⁷ each represent: a linear, branched, or cyclic alkyl, alkenyl, oxoalkyl, or oxoalkenyl group, each having 1 to 12 carbon atoms; a substituted or unsubstituted aryl group having 6 to 20 carbon atoms; or an aralkyl or aryloxoalkyl group having 7 to 12 carbon atoms. Part or all of hydrogen atoms of these groups may be substituted with an alkoxy group, etc. R²⁰⁵ and R²⁰⁶ may form a ring. When forming the ring, each of R²⁰⁵ and R²⁰⁶ represents an alkylene group having 1 to 6 carbon atoms. “A⁻” represents the non-nucleophilic counter ion. R²⁰⁸, R²⁰⁹, R²¹⁰, and R²¹¹ are same as R²⁰⁴, R²⁰⁵, R²⁰⁶, and R²⁰⁷, but may be a hydrogen atom. R²⁰⁸ and R²⁰⁹, or R²⁰⁸, R²⁰⁹, and R²¹⁰ may form a ring. When forming the ring, R²⁰⁸ and R²⁰⁹, or R²⁰⁸, R²⁰⁹, and R²¹⁰ represent an alkylene group having 3 to 10 carbon atoms.

R²⁰⁴, R²⁰⁵, R²⁰⁶, R²⁰⁷, R²⁰⁸, R²⁰⁹, R²¹⁰, and R²¹¹ may be identical to or different from each other. Specific examples of the alkyl group include a methyl group, an ethyl group, a propyl group, an isopropyl group, an n-butyl group, a sec-butyl group, a tert-butyl group, a pentyl group, a hexyl group, a heptyl group, an octyl group, a cyclopentyl group, a cyclohexyl group, a cycloheptyl group, a cyclopropylmethyl group, a 4-methylcyclohexyl group, a cyclohexylmethyl group, a norbornyl group, and an adamantyl group. Examples of the alkenyl group include a vinyl group, an allyl group, a propenyl group, a butenyl group, a hexenyl group, and a cyclohexenyl group. Examples of the oxoalkyl group include a 2-oxocyclopentyl group, a 2-oxocyclohexyl group, a 2-oxopropyl group, a 2-cyclopentyl-2-oxoethyl group, a 2-cyclohexyl-2-oxoethyl group, and a 2-(4-methylcyclohexyl)-2-oxoethyl group. Examples of the oxoalkenyl group include a 2-oxocyclopentene group and a 2-oxocyclohexene group. Examples of the aryl group include a phenyl group and a naphthyl group; alkoxyphenyl groups such as a p-methoxyphenyl group, a m-methoxyphenyl group, an o-methoxyphenyl group, an ethoxyphenyl group, a p-tert-butoxyphenyl group, and a m-tert-butoxyphenyl group; alkylphenyl groups such as a 2-methylphenyl group, a 3-methylphenyl group, a 4-methylphenyl group, an ethylphenyl group, a 4-tert-butylphenyl group, a 4-butylphenyl group, and a dimethylphenyl group; alkylnaphthyl groups such as a methylnaphthyl group and an ethylnaphthyl group; alkoxynaphthyl groups such as a methoxynaphthyl group and an ethoxynaphthyl group; dialkylnaphthyl groups such as a dimethylnaphthyl group and a diethylnaphthyl group; dialkoxynaphthyl groups such as a dimethoxynaphthyl group and a diethoxynaphthyl group. Examples of the aralkyl groups include a benzyl group, a phenylethyl group, and a phenethyl group. Examples of the aryloxoalkyl group include 2-aryl-2-oxoethyl groups such as a 2-phenyl-2-oxoethyl group, a 2-(1-naphthyl)-2-oxoethyl group, and a 2-(2-naphthyl)-2-oxoethyl group.

Examples of the non-nucleophilic counter ion “A⁻” include monovalent ions such as a hydroxide ion, a formate ion, an acetate ion, a propionate ion, a butanoate ion, a pentanoate ion, a hexanoate ion, heptanoate ion, an octanoate ion, a nonanoate ion, a decanoate ion, an oleate ion, a stearate ion, a linoleate ion, a linolenate ion, a benzoate ion, a phthalate ion, an isophthalate ion, a terephthalate ion, a salicylate ion, a trifluoroacetate ion, a monochloroacetate ion, a dichloroacetate ion, a trichloroacetate ion, a fluoride ion, a chloride ion, a bromide ion, an iodide ion, a nitrate ion, a nitrite ion, a chlorate ion, a bromate ion, a methanesulfonate ion, a paratoluenesulfonate ion, and a monomethylsulfate ion; and also include monovalent or divalent ions such as an oxalate ion, a malonate ion, a methylmalonate ion, an ethylmalonate ion, a propylmalonate ion, a butylmalonate ion, a dimethylmalonate ion, a diethylmalonate ion, a succinate ion, a methylsuccinate ion, a glutarate ion, an adipate ion, an itaconate ion, a maleate ion, a fumarate ion, a citraconate ion, a citrate ion, a carbonate ion, and a sulfate ion.

Examples of the alkali metal salt include monovalent salts such as hydroxide salts, formate salts, acetate salts, propionate salts, butanoate salts, pentanoate salts, hexanoate salts, heptanoate salts, octanoate salts, nonanoate salts, decanoate salts, oleate salts, stearate salts, linoleate salts, linolenate salts, benzoate salts, phthalate salts, isophthalate salts, terephthalate salts, salicylate salts, trifluoroacetate salts, monochloroacetate salts, dichloroacetate salts, and trichloroacetate salts; and monovalent or divalent salts such as oxalate salts, malonate salts, methylmalonate salts, ethylmalonate salts, propylmalonate salts, butylmalonate salts, dimethylmalonate salts, diethylmalonate salts, succinate salts, methylsuccinate salts, glutarate salts, adipate salts, itaconate salts, maleate salts, fumarate salts, citraconate salts, citrate salts, and carbonate salts, each of which is any salt of lithium, sodium, and potassium.

### (Sulfonium Salt (Xc-1))

Specific examples of the sulfonium salt (Xc-1) include a triphenylsulfonium formate, a triphenylsulfonium acetate, a triphenylsulfonium propionate, a triphenylsulfonium butanoate, a triphenylsulfonium benzoate, a triphenylsulfonium phthalate, a triphenylsulfonium isophthalate, a triphenylsulfonium terephthalate, a triphenylsulfonium salicylate, a triphenylsulfonium trifluoromethanesulfonate, a triphenylsulfonium trifluoroacetate, a triphenylsulfonium monochloroacetate, triphenylsulfonium dichloroacetate, a triphenylsulfonium trichloroacetate, a triphenylsulfonium hydroxide, a triphenylsulfonium nitrate, a triphenylsulfonium chloride, a triphenylsulfonium bromide, a triphenylsulfonium oxalate, a triphenylsulfonium malonate, a triphenylsulfonium methylmalonate, a triphenylsulfonium ethylmalonate, a triphenylsulfonium a propylmalonate, a triphenylsulfonium butylmalonate, a triphenylsulfonium dimethylmalonate, a triphenylsulfonium diethylmalonate, a triphenylsulfonium succinate, a triphenylsulfonium methylsuccinate, a triphenylsulfonium glutarate, a triphenylsulfonium adipate, a triphenylsulfonium itaconate, a triphenylsulfonium maleate, a triphenylsulfonium fumarate, a triphenylsulfonium citraconate, a triphenylsulfonium citrate, a triphenylsulfonium carbonate, a bistriphenylsulfonium oxalate, a bistriphenylsulfonium maleate, a bistriphenylsulfonium fumarate, a bistriphenylsulfonium citraconate, a bistriphenylsulfonium citrate, and a bistriphenylsulfonium carbonate.

### (Iodonium Salt (Xc-2))

Specific examples of the iodonium salt (Xc-2) include a diphenyliodonium formate, a diphenyliodonium acetate, a diphenyliodonium propionate, a diphenyliodonium butanoate, a diphenyliodonium benzoate, diphenyliodonium phthalate, a diphenyliodonium isophthalate, a diphenyliodonium terephthalate, a diphenyliodonium salicylate, a diphenyliodonium trifluoromethanesulfonate, a diphenyliodonium trifluoroacetate, a diphenyliodonium monochloroacetate, a diphenyliodonium dichloroacetate, a diphenyliodonium trichloroacetate, a diphenyliodonium hydroxide, a diphenyliodonium nitrate, a diphenyliodonium chloride, a diphenyliodonium bromide, a diphenyliodonium iodide, a diphenyliodonium oxalate, a diphenyliodonium maleate, a diphenyliodonium fumarate, a diphenyliodonium citraconate, a diphenyliodonium citrate, a diphenyliodonium carbonate, a bisdiphenyliodonium oxalate, a bisdiphenyliodonium maleate, a bisdiphenyliodonium fumarate, a bisdiphenyliodonium citraconate, a bisdiphenyliodonium citrate, and a bisdiphenyliodonium carbonate.

### (Phosphonium Salt (Xc-3))

Specific examples of the phosphonium salt (Xc-3) include a tetraethylphosphonium formate, a tetraethylphosphonium acetate, a tetraethylphosphonium propionate, a tetraethylphosphonium butanoate, a tetraethylphosphonium benzoate, a tetraethylphosphonium phthalate, a tetraethylphosphonium isophthalate, a tetraethylphosphonium terephthalate, a tetraethylphosphonium salicylate, a tetraethylphosphonium trifluoromethanesulfonate, a tetraethylphosphonium trifluoroacetate, a tetraethylphosphonium monochloroacetate, a tetraethylphosphonium dichloroacetate, a tetraethylphosphonium trichloroacetate, a tetraethylphosphonium hydroxide, a tetraethylphosphonium nitrate, a tetraethylphosphonium chloride, a tetraethylphosphonium bromide, a tetraethylphosphonium iodide, a tetraethylphosphonium oxalate, a tetraethylphosphonium maleate, a tetraethylphosphonium fumarate, a tetraethylphosphonium citraconate, a tetraethylphosphonium citrate, a tetraethylphosphonium carbonate, a bistetraethylphosphonium oxalate, a bistetraethylphosphonium maleate, a bistetraethylphosphonium fumarate, a bistetraethylphosphonium citraconate, a bistetraethylphosphonium citrate, a bistetraethylphosphonium carbonate, a tetraphenylphosphonium formate, a tetraphenylphosphonium acetate, a tetraphenylphosphonium propionate, a tetraphenylphosphonium butanoate, a tetraphenylphosphonium benzoate, a tetraphenylphosphonium phthalate, a tetraphenylphosphonium isophthalate, a tetraphenylphosphonium terephthalate, a tetraphenylphosphonium salicylate, a tetraphenylphosphonium trifluoromethanesulfonate, a tetraphenylphosphonium trifluoroacetate, a tetraphenylphosphonium monochloroacetate, a tetraphenylphosphonium dichloroacetate, a tetraphenylphosphonium trichloroacetate, a tetraphenylphosphonium hydroxide, a tetraphenylphosphonium nitrate, a tetraphenylphosphonium chloride, a tetraphenylphosphonium bromide, a tetraphenylphosphonium iodide, a tetraphenylphosphonium oxalate, a tetraphenylphosphonium maleate, a tetraphenylphosphonium fumarate, a tetraphenylphosphonium citraconate, a tetraphenylphosphonium citrate, a tetraphenylphosphonium carbonate, a bistetraphenylphosphonium oxalate, a bistetraphenylphosphonium maleate, a bistetraphenylphosphonium fumarate, a bistetraphenylphosphonium citraconate, a bistetraphenylphosphonium citrate, and a bistetraphenylphosphonium carbonate.

### (Ammonium Salt (Xc-4))

On the other hand, specific examples of the ammonium salt (Xc-4) include tetramethylammonium formate, tetramethylammonium acetate, tetramethylammonium propionate, tetramethylammonium butanoate, tetramethylammonium benzoate, tetramethylammonium phthalate, tetramethylammonium isophthalate, tetramethylammonium terephthalate, tetramethylammonium salicylate, tetramethylammonium trifluoromethanesulfonate, tetramethylammonium trifluoroacetate, tetramethylammonium monochloroacetate, tetramethylammonium dichloroacetate, tetramethylammonium trichloroacetate, tetramethylammonium hydroxide, tetramethylammonium nitrate, tetramethylammonium chloride, tetramethylammonium bromide, tetramethylammonium iodide, tetramethylammonium monomethylsulfate, tetramethylammonium oxalate, tetramethylammonium malonate, tetramethylammonium maleate, tetramethylammonium fumarate, tetramethylammonium citraconate, tetramethylammonium citrate, tetramethylammonium carbonate, bistetramethylammonium oxalate, bistetramethylammonium malonate, bistetramethylammonium maleate, bistetramethylammonium fumarate, bistetramethylammonium citraconate, bistetramethylammonium citrate, bistetramethylammonium carbonate, tetraethylammonium formate, tetraethylammonium acetate, tetraethylammonium propionate, tetraethylammonium butanoate, tetraethylammonium benzoate, tetraethylammonium phthalate, tetraethylammonium isophthalate, tetraethylammonium terephthalate, tetraethylammonium salicylate, tetraethylammonium trifluoromethanesulfonate, tetraethylammonium trifluoroacetate, tetraethylammonium monochloroacetate, tetraethylammonium dichloroacetate, tetraethylammonium trichloroacetate, tetraethylammonium hydroxide, tetraethylammonium nitrate, tetraethylammonium chloride, tetraethylammonium bromide, tetraethylammonium iodide, tetraethylammonium monomethylsulfate, tetraethylammonium oxalate, tetraethylammonium malonate, tetraethylammonium maleate, tetraethylammonium fumarate, tetraethylammonium citraconate, tetraethylammonium citrate, tetraethylammonium carbonate, bistetraethylammonium oxalate, bistetraethylammonium malonate, bistetraethylammonium maleate, bistetraethylammonium fumarate, bistetraethylammonium citraconate, bistetraethylammonium citrate, bistetraethylammonium carbonate, tetrapropylammonium formate, tetrapropylammonium acetate, tetrapropylammonium propionate, tetrapropylammonium butanoate, tetrapropylammonium benzoate, tetrapropylammonium phthalate, tetrapropylammonium isophthalate, tetrapropylammonium terephthalate, tetrapropylammonium salicylate, tetrapropylammonium trifluoromethanesulfonate, tetrapropylammonium trifluoroacetate, tetrapropylammonium monochloroacetate, tetrapropylammonium dichloroacetate, tetrapropylammonium trichloroacetate, tetrapropylammonium hydroxide, tetrapropylammonium nitrate, tetrapropylammonium chloride, tetrapropylammonium bromide, tetrapropylammonium iodide, tetrapropylammonium monomethylsulfate, tetrapropylammonium oxalate, tetrapropylammonium malonate, tetrapropylammonium malonate, tetrapropylammonium maleate, tetrapropylammonium fumarate, tetrapropylammonium citraconate, tetrapropylammonium citrate, tetrapropylammonium carbonate, bistetrapropylammonium oxalate, bistetrapropylammonium maleate, bistetrapropylammonium fumarate, bistetrapropylammonium citraconate, bistetrapropylammonium citrate, bistetrapropylammonium carbonate, tetrabutylammonium formate, tetrabutylammonium acetate, tetrabutylammonium propionate, tetrabutylammonium butanoate, tetrabutylammonium benzoate, tetrabutylammonium phthalate, tetrabutylammonium isophthalate, tetrabutylammonium terephthalate, tetrabutylammonium salicylate, tetrabutylammonium trifluoromethanesulfonate, tetrabutylammonium trifluoroacetate, tetrabutylammonium monochloroacetate, tetrabutylammonium dichloroacetate, tetrabutylammonium trichloroacetate, tetrabutylammonium hydroxide, tetrabutylammonium nitrate, tetrabutylammonium chloride, tetrabutylammonium bromide, tetrabutylammonium iodide, tetrabutylammonium methanesulfonate, tetrabutylammonium monomethylsulfate, tetrabutylammonium oxalate, tetrabutylammonium malonate, tetrabutylammonium maleate, tetrabutylammonium fumarate, tetrabutylammonium citraconate, tetrabutylammonium citrate, tetrabutylammonium carbonate, bistetrabutylammonium oxalate, bistetrabutylammonium malonate, bistetrabutylammonium maleate, bistetrabutylammonium fumarate, bistetrabutylammonium citraconate, bistetrabutylammonium citrate, bistetrabutylammonium carbonate, trimethylphenylammonium formate, trimethylphenylammonium acetate, trimethylphenylammonium propionate, trimethylphenylammonium butanoate, trimethylphenylammonium benzoate, trimethylphenylammonium phthalate, trimethylphenylammonium isophthalate, trimethylphenylammonium terephthalate, trimethylphenylammonium salicylate, trimethylphenylammonium trifluoromethanesulfonate, trimethylphenylammonium trifluoroacetate, trimethylphenylammonium monochloroacetate, trimethylphenylammonium dichloroacetate, trimethylphenylammonium trichloroacetate, trimethylphenylammonium hydroxide, trimethylphenylammonium nitrate, trimethylphenylammonium chloride, trimethylphenylammonium bromide, trimethylphenylammonium iodide, trimethylphenylammonium methanesulfonate, trimethylphenylammonium monomethylsulfate, trimethylphenylammonium oxalate, trimethylphenylammonium malonate, trimethylphenylammonium maleate, trimethylphenylammonium fumarate, trimethylphenylammonium citraconate, trimethylphenylammonium citrate, trimethylphenylammonium carbonate, bistrimethylphenylammonium oxalate, bistrimethylphenylammonium malonate, bistrimethylphenylammonium maleate, bistrimethylphenylammonium fumarate, bistrimethylphenylammonium citraconate, bistrimethylphenylammonium citrate, bistrimethylphenylammonium carbonate, triethylphenylammonium formate, triethylphenylammonium acetate, triethylphenylammonium propionate, triethylphenylammonium butanoate, triethylphenylammonium benzoate, triethylphenylammonium phthalate, triethylphenylammonium isophthalate, triethylphenylammonium terephthalate, triethylphenylammonium salicylate, triethylphenylammonium trifluoromethanesulfonate, triethylphenylammonium trifluoroacetate, triethylphenylammonium monochloroacetate, triethylphenylammonium dichloroacetate, triethylphenylammonium trichloroacetate, triethylphenylammonium hydroxide, triethylphenylammonium nitrate, triethylphenylammonium chloride, triethylphenylammonium bromide, triethylphenylammonium iodide, triethylphenylammonium methanesulfonate, triethylphenylammonium monomethylsulfate, triethylphenylammonium oxalate, triethylphenylammonium malonate, triethylphenylammonium maleate, triethylphenylammonium fumarate, triethylphenylammonium citraconate, triethylphenylammonium citrate, triethylphenylammonium carbonate, bistriethylphenylammonium oxalate, bistriethylphenylammonium malonate, bistriethylphenylammonium maleate, bistriethylphenylammonium fumarate, bistriethylphenylammonium citraconate, bistriethylphenylammonium citrate, bistriethylphenylammonium carbonate, benzyldimethylphenylammonium formate, benzyldimethylphenylammonium acetate, benzyldimethylphenylammonium propionate, benzyldimethylphenylammonium butanoate, benzyldimethylphenylammonium benzoate, benzyldimethylphenylammonium phthalate, benzyldimethylphenylammonium isophthalate, benzyldimethylphenylammonium terephthalate, benzyldimethylphenylammonium salicylate, benzyldimethylphenylammonium trifluoromethanesulfonate, benzyldimethylphenylammonium trifluoroacetate, benzyldimethylphenylammonium monochloroacetate, benzyldimethylphenylammonium dichloroacetate, benzyldimethylphenylammonium trichloroacetate, benzyldimethylphenylammonium hydroxide, benzyldimethylphenylammonium nitrate, benzyldimethylphenylammonium chloride, benzyldimethylphenylammonium bromide, benzyldimethylphenylammonium iodide, benzyldimethylphenylammonium methanesulfonate benzyldimethylphenylammonium monomethylsulfate, benzyldimethylphenylammonium oxalate, benzyldimethylphenylammonium malonate, benzyldimethylphenylammonium maleate, benzyldimethylphenylammonium fumarate, benzyldimethylphenylammonium citraconate, benzyldimethylphenylammonium citrate, benzyldimethylphenylammonium carbonate, bisbenzyldimethylphenylammonium oxalate, bisbenzyldimethylphenylammonium malonate, bisbenzyldimethylphenylammonium maleate, bisbenzyldimethylphenylammonium fumarate, bisbenzyldimethylphenylammonium citraconate, bisbenzyldimethylphenylammonium citrate, and bisbenzyldimethylphenylammonium carbonate.

(Alkaline metal Salt)

Examples of the alkaline metal salt include lithium formate, a lithium acetate, a lithium propionate, a lithium butanoate, a lithium benzoate, a lithium phthalate, a lithium isophthalate, a lithium terephthalate, a lithium salicylate, a lithium trifluoromethanesulfonate, a lithium trifluoroacetate, a lithium monochloroacetate, a lithium dichloroacetate, a lithium trichloroacetate, a lithium hydroxide, a lithium nitrate, a lithium chloride, a lithium bromide, a lithium iodide, a lithium methanesulfonate, a lithium hydrogen oxalate, a lithium hydrogen malonate, a lithium hydrogen maleate, a lithium hydrogen fumarate, a lithium hydrogen citraconate, a lithium hydrogen citrate, a lithium hydrogen carbonate, a lithium oxalate, a lithium malonate, a lithium maleate, a lithium fumarate, a lithium citraconate, a lithium citrate, a lithium carbonate, a sodium formate, a sodium acetate, a sodium propionate, a sodium butanoate, a sodium benzoate, a sodium phthalate, a sodium isophthalate, a sodium terephthalate, a sodium salicylate, a sodium trifluoromethanesulfonate, a sodium trifluoroacetate, a sodium monochloroacetate, a sodium dichloroacetate, a sodium trichloroacetate, a sodium hydroxide, a sodium nitrate, a sodium chloride, a sodium bromide, a sodium iodide, a sodium methanesulfonate, a sodium hydrogen oxalate, a sodium hydrogen malonate, a sodium hydrogen maleate, a sodium hydrogen fumarate, a sodium hydrogen citraconate, a sodium hydrogen citrate, a sodium hydrogen carbonate, a sodium oxalate, a sodium malonate, a sodium maleate, a sodium fumarate, a sodium citraconate, a sodium citrate, a sodium carbonate, a potassium formate, a potassium acetate, a potassium propionate, a potassium butanoate, a potassium benzoate, a potassium phthalate, a potassium isophthalate, a potassium terephthalate, a potassium salicylate, a potassium trifluoromethanesulfonate, a potassium trifluoroacetate, a potassium monochloroacetate, a potassium dichloroacetate, a potassium trichloroacetate, a potassium hydroxide, a potassium nitrate, a potassium chloride, a potassium bromide, a potassium iodide, a potassium methanesulfonate, a potassium hydrogen oxalate, a potassium hydrogen malonate, a potassium hydrogen maleate, a potassium hydrogen fumarate, a potassium hydrogen citraconate, a potassium hydrogen citrate, a potassium hydrogen carbonate, a potassium oxalate, a potassium malonate, a potassium maleate, a potassium fumarate, a potassium citraconate, a potassium citrate, and a potassium carbonate.

### [As Curing Catalyst (Xc), Thermosetting Polysiloxanes Having Ammonium Salts, Sulfonium Salts, Phosphonium Salts, or Iodonium Salts as Part of its Structure]

In the present invention, examples of the crosslinking catalyst (Xc) for polymerization include thermosetting polysiloxanes (Xc-10) having ammonium salts, sulfonium salts, phosphonium salts, or iodonium salts as part of its structure.

As a material to be used for manufacturing (Xc-10) to be used here, a compound represented by the following formula (Xm) can be used.

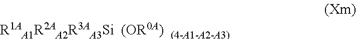

In the formula, R^{0A} represents a hydrocarbon group having 1 to 6 carbon atoms; at least one of R^{1A}, R^{2A}, and R^{3A} represents an organic group having an ammonium salt, a sulfonium salt, a phosphonium salt, or an iodonium salt, and the other(s) of R^{1A}, R^{2A}, and R^{3A} represent a hydrogen atom or a monovalent organic group having 1 to 30 carbon atoms; and A1, A2, and A3 each represent 0 or 1, satisfying 1≤A1+A2+A3≤3.

Here, examples of R^{0A} in OR^{0A} include a methyl group, an ethyl group, an n-propyl group, an iso-propyl group, an n-butyl group, an iso-butyl group, a sec-butyl group, a tert-butyl group, an n-pentyl group, a cyclopentyl group, an n-hexyl group, a cyclohexyl group, and a phenyl group.

### (Hydrolysable Silicon Compound Having Sulfonium Salt as Partial Structure (Xm-1))

As Xm, examples of a hydrolysable silicon compound having a sulfonium salt as a partial structure includes a compound represented by the following general formula (Xm-1).

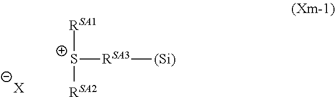

In the formula, R^{SA1} and R^{SA2} each represent a linear, branched, or cyclic alkyl, alkenyl, oxoalkyl, or oxoalkenyl group having 1 to 20 carbon atoms, a substituted or unsubstituted aryl group having 6 to 20 carbon atoms, or an aralkyl or aryloxyalkyl group having 7 to 20 carbon atoms; part or all of hydrogen atoms of these groups are optionally substituted with an alkoxy group, an amino group, an alkylamino group, a halogen atom, or the like; R^{SA1} and R^{SA2} may form a ring together with a sulfur atom bonded to R^{SA1} and R^{SA2}, when the ring is formed, R^{SA1} and R^{SA2} each represent an alkylene group having 1 to 6 carbon atoms. R^{SA3} represents a linear, branched, or cyclic alkylene or alkenylene group having 1 to 20 carbon atoms, or a substituted or unsubstituted arylene or aralkylene group having 6 to 20 carbon atoms; part or all of hydrogen atoms of these groups are optionally substituted with an alkoxy group, an amino group, an alkylamino group, or the like. R^{SA1}, R^{SA2}, and R^{SA3} may have an oxygen atom or a nitrogen atom in the middle of the chain or the ring.

Note that in the above general formula (Xm-1), “(Si)” was shown to indicate an attachment point to an Si atom.

In the formula (Xm-1), examples of “X⁻” include a hydroxide ion, formate ion, an acetate ion, a propionate ion, a butanoate ion, a pentanoate ion, a hexanoate ion, heptanoate ion, an octanoate ion, a nonanoate ion, a decanoate ion, an oleate ion, a stearate ion, a linoleate ion, a linolenate ion, a benzoate ion, a p-methylbenzoate ion, a p-t-butylbenzoate ion, a phthalate ion, an isophthalate ion, a terephthalate ion, a salicylate ion, a trifluoroacetate ion, a monochloroacetate ion, a dichloroacetate ion, a trichloroacetate ion, a nitrate ion, a chlorate ion, a perchlorate ion, a bromate ion, an iodate ion, an oxalate ion, a malonate ion, a methylmalonate ion, an ethylmalonate ion, a propylmalonate ion, a butylmalonate ion, a dimethylmalonate ion, a diethylmalonate ion, a succinate ion, a methylsuccinate ion, a glutarate ion, an adipate ion, an itaconate ion, a maleate ion, a fumarate ion, a citraconate ion, a citrate ion, and a carbonate ion.

Specific examples of the cation moiety of the compound represented by the above general formula (Xm-1) include the following ions. (“X⁻” is the same as defined above.)

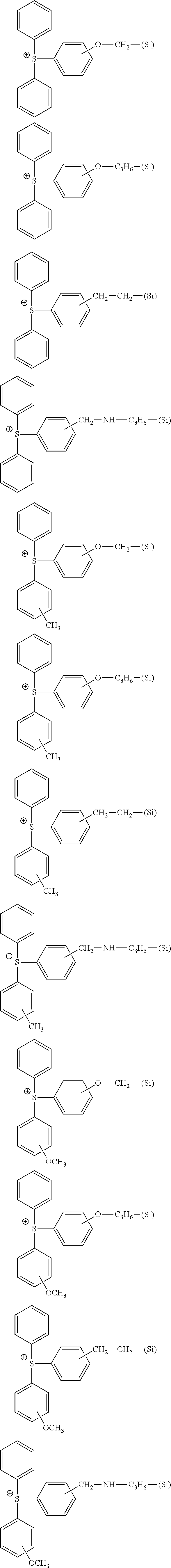

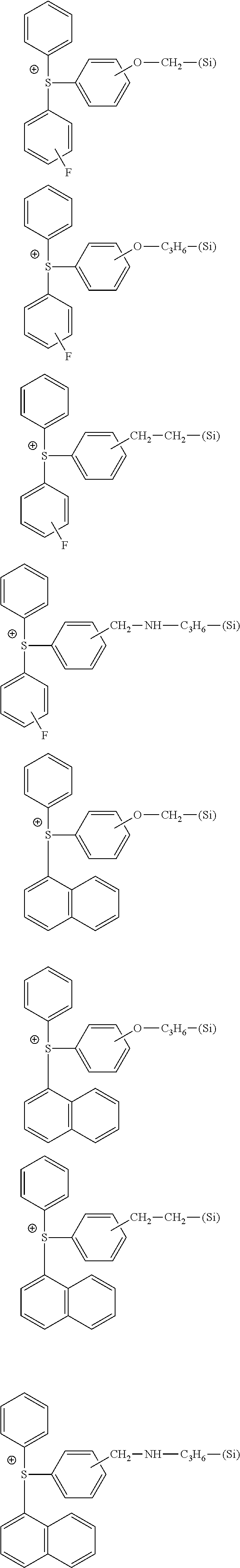

### (Hydrolysable Silicon Compound (Xm-2) Having Iodonium Salt as Partial Structure)

Examples of a hydrolysable silicon compound having the iodonium salt as a partial structure include compounds represented by the following general formula (Xm-2).

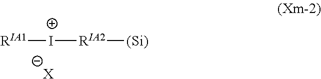

In the formula, R^{AA1} represents a linear, branched, or cyclic alkyl, alkenyl, oxoalkyl, or oxoalkenyl group having 1 to 20 carbon atoms, a substituted or unsubstituted aryl group having 6 to 20 carbon atoms, or an aralkyl or aryloxoalkyl group having 7 to 20 carbon atoms; part or all of hydrogen atoms of these groups are optionally substituted with an alkoxy group, an amino group, an alkylamino group, a halogen atom, or the like; R^{IA1} and R^{IA2} may form a ring together with the nitrogen atom to which they are bonded, and when they form the ring, R^{IA1} and R^{IA2} each represent an alkylene group having 1 to 6 carbon atoms; and R^{IA2} represents a linear, branched, or cyclic alkylene or alkenylene group having 1 to 20 carbon atoms, or a substituted or unsubstituted arylene group or aralkylene group having 6 to 20 carbon atoms; part or all of hydrogen atoms of these groups are optionally substituted with an alkoxy group, an amino group, an alkylamino group, or the like; and R^{IA1} may have an oxygen atom or a nitrogen atom in the middle of the chain or the ring.

Note that in the above general formula (Xm-2), “(Si)” was shown to indicate an attachment point to an Si atom. “X⁻” is the same as defined in (Xm-1) above.

Specific examples of the cation moiety of the compound represented by the above general formula (Xm-2) include the following ions (“X⁻” is the same as defined above).

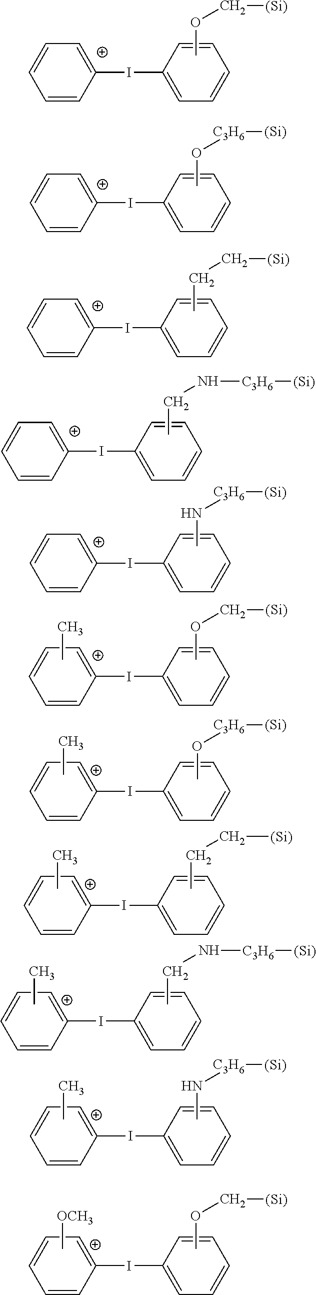

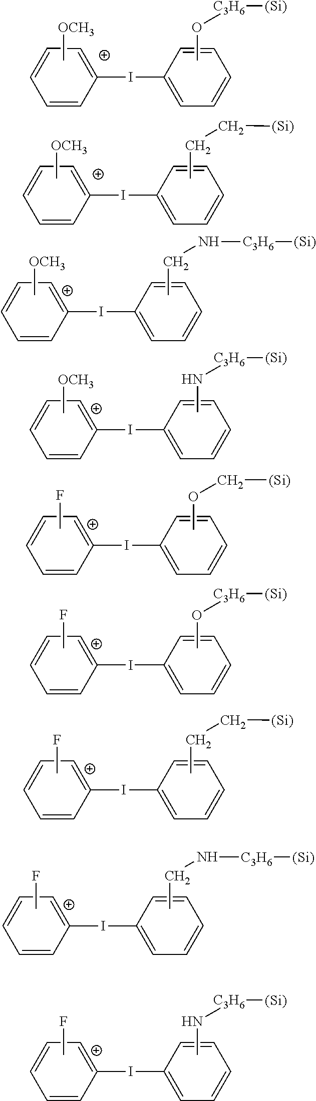

### (Hydrolysable Silicon Compound (Xm-3) Having Phosphonium Salt as Partial Structure)

Examples of the hydrolysable silicon compound having a phosphonium salt as a part of the structure include the following general formula (Xm-3).

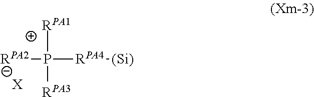

In the formula, R^{PA1}, R^{PA2}, and R^{PA3} each represent a linear, branched, or cyclic alkyl, alkenyl, oxoalkyl, or oxoalkenyl group having 1 to 20 carbon atoms, a substituted or unsubstituted aryl group having 6 to 20 carbon atoms, or an aralkyl group or aryloxoalkyl group having 7 to 20 carbon atoms. Part or all of hydrogen atoms of these groups are optionally substituted with an alkoxy group, an amino group, an alkylamino group, a halogen atom, etc. R^{PA1} and R^{PA2} optionally form a ring together with the phosphorus atom to which R^{PA1} and R^{PA2} are bonded, and when forming the ring, R^{PA1} and R^{PA2} each represent an alkylene group having 1 to 6 carbon atoms. R^{PA4} represents a linear, branched, or cyclic alkylene or alkenylene group having 1 to 20 carbon atoms, or a substituted or unsubstituted arylene or aralkylene group having 6 to 20 carbon atoms. Part or all of hydrogen atoms of these groups are optionally substituted with an alkoxy group, an amino group, an alkylamino group, etc. R^{PA1} to R^{PA4} may have an oxygen atom or a nitrogen atom in the middle of the chain or the ring.

In the formula (Xm-3), “(Si)” is shown to represent an attachment point to Si. “X⁻” represents the same as exemplified in the above formula (Xm-1).

Specific examples of the cation moiety of the compound represented by the general formula (Xm-3) include the following ions (“X⁻” is the same as defined above).

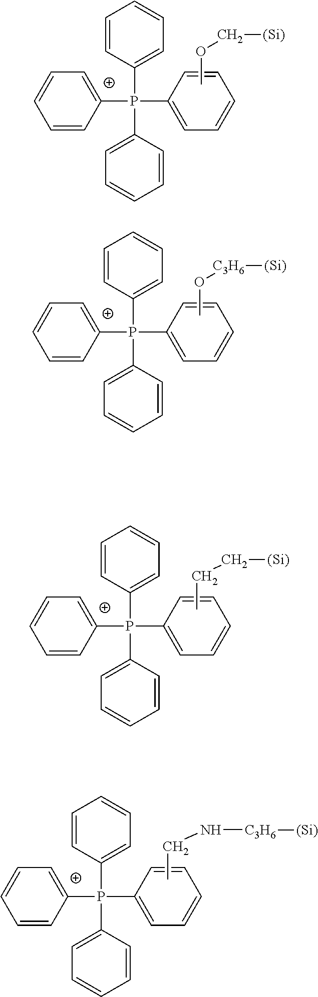

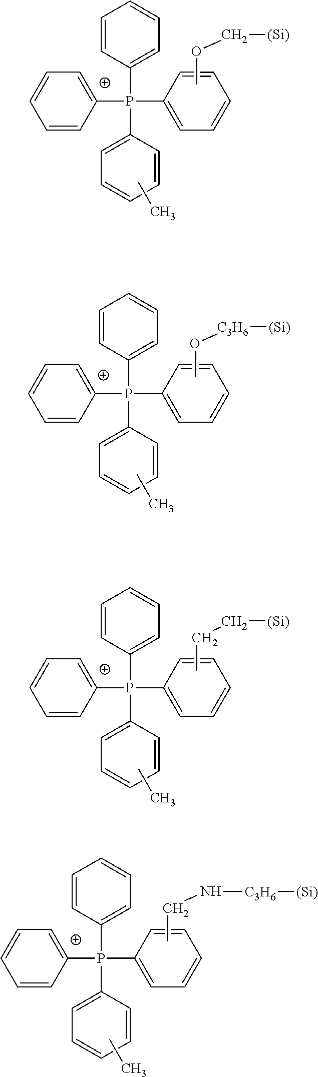

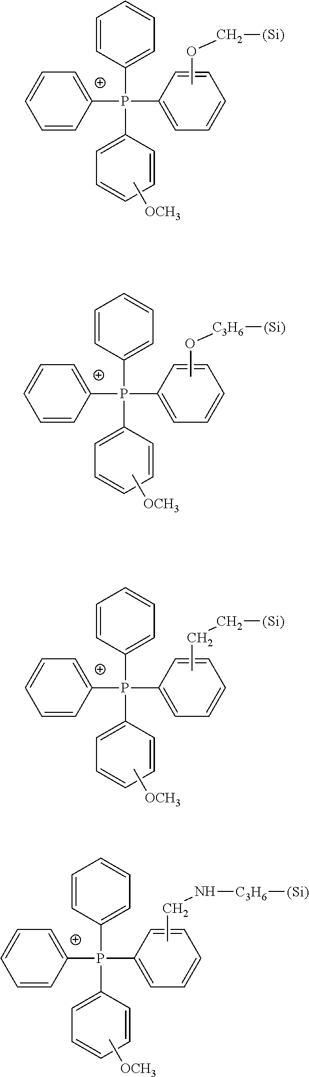

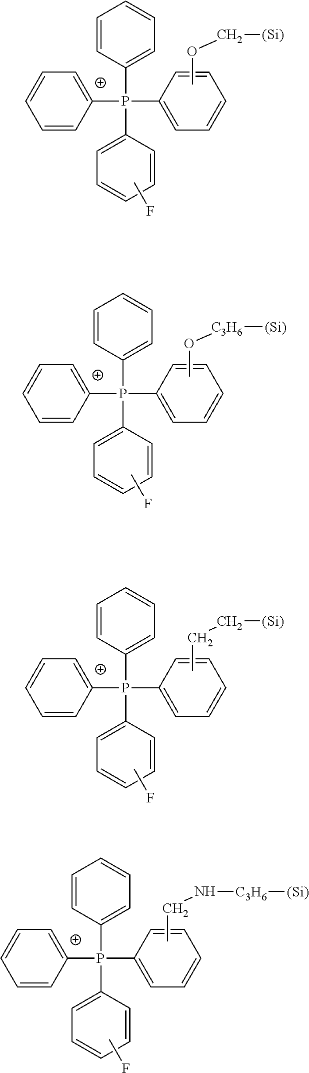

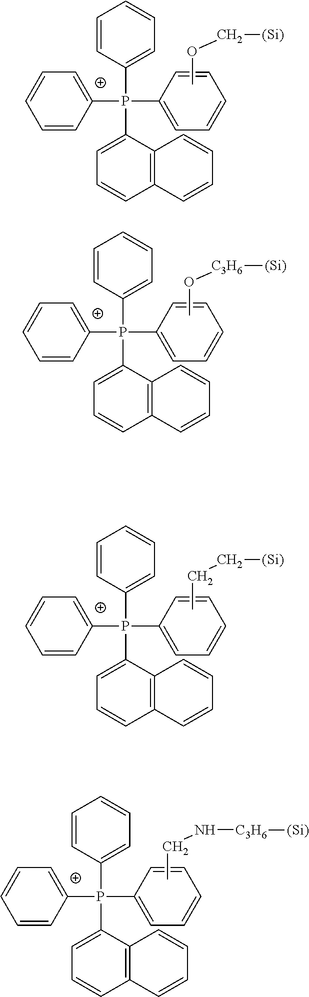

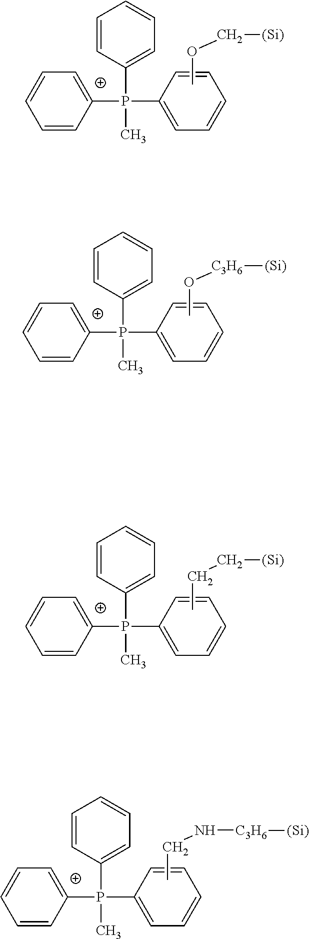

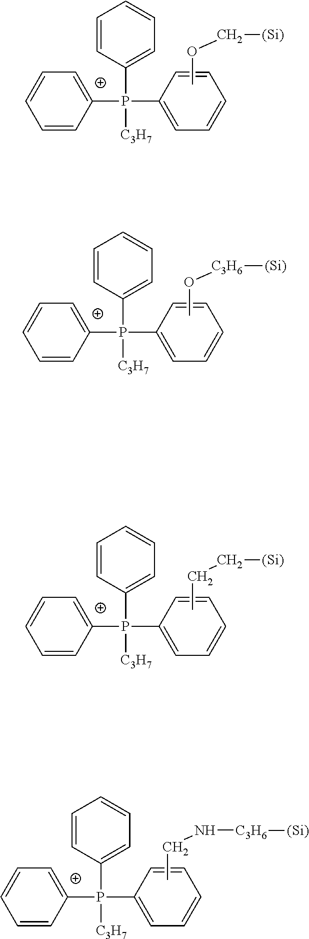

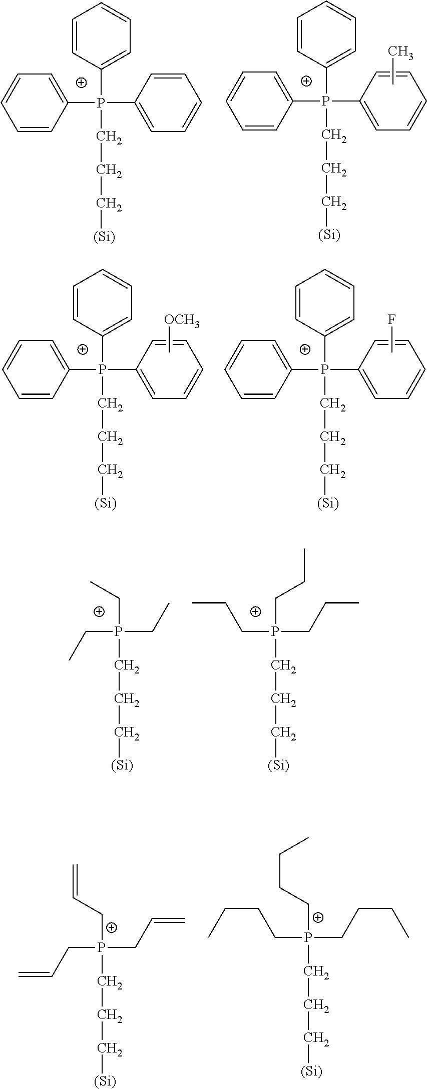

### (Hydrolysable Silicon Compound (Xm-4) Having Ammonium Salt as Part of Structure)

Examples of the hydrolysable silicon compound having an ammonium salt as a part of the structure include the following general formula (Xm-4).

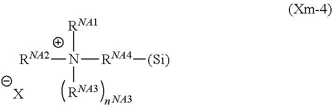

In the formula, R^{NA1}, R^{NA2}, and R^{NA3} each represent a hydrogen atom, a linear, branched, or cyclic alkyl group, an alkenyl group, an oxoalkyl group, or an oxoalkenyl group having 1 to 20 carbon atoms, a substituted or unsubstituted aryl group having 6 to 20 carbon atoms, or an aralkyl group or an aryloxyalkyl group having 7 to 20 carbon atoms. These groups represent a monovalent organic group in which part or all of hydrogen atoms of these groups are optionally substituted with an alkoxy group, an amino group, an alkylamino group, etc. R^{NA1} and R^{NA2} optionally form a ring together with the nitrogen atom to which R^{NA1} and R^{NA2} are bonded, and when forming the ring, R^{NA1} and R^{NA2} each represent an alkylene group having 1 to 6 carbon atoms, a nitrogen-containing cyclic hetero ring or heteroaromatic ring. R^{NA4} represents a linear, branched, or cyclic alkylene group or an alkenylene group having 1 to 23 carbon atoms, a substituted or unsubstituted arylene group having 6 to 29 carbon atoms. These groups represent a divalent organic group in which part or all of hydrogen atoms of these groups are optionally substituted with an alkoxy group, an amino group, an alkylamino group, etc. In a case where R^{NA1} and R^{NA2} or R^{NA1} and R^{NA4} form a cyclic structure and further have an unsaturated nitrogen, it satisfies n^{NA3}=0, and in the other case, it satisfies n^{NA3}=1.

In the formula (Xm-4), “(Si)” is shown to represent an attachment point to Si. “X⁻” represents the same as exemplified by the above formula (Xm-1).

Specific examples of the cation moiety of the compound represented by the general formula (Xm-4) include the following ions (“X⁻” is the same as defined above).

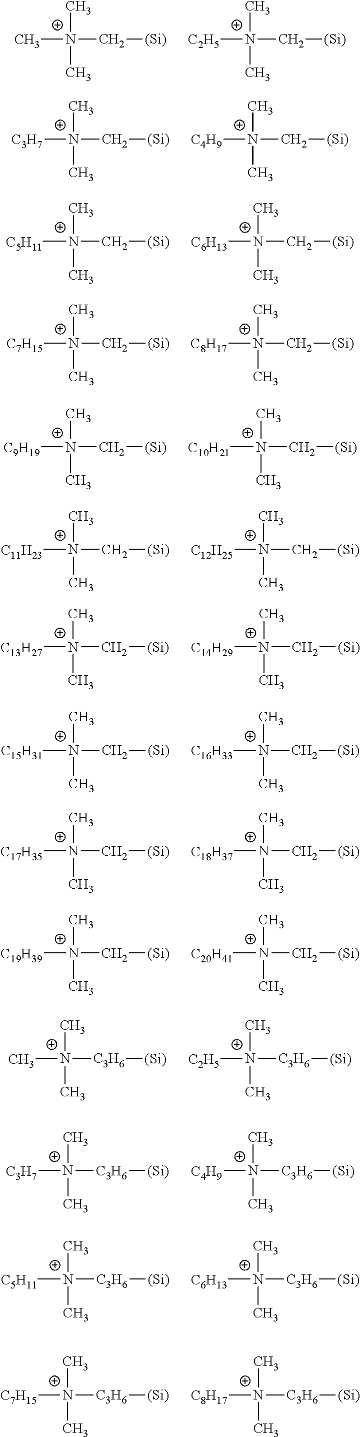

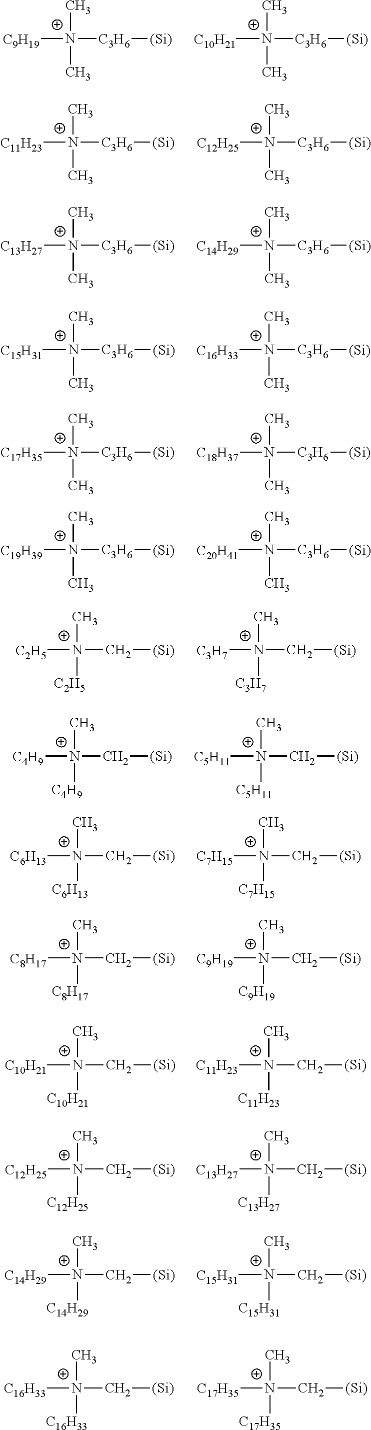

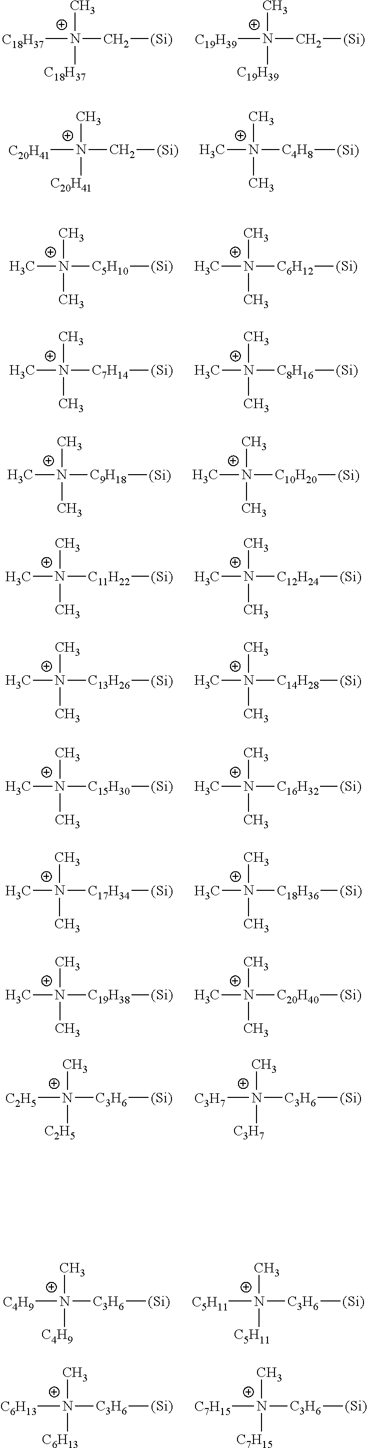

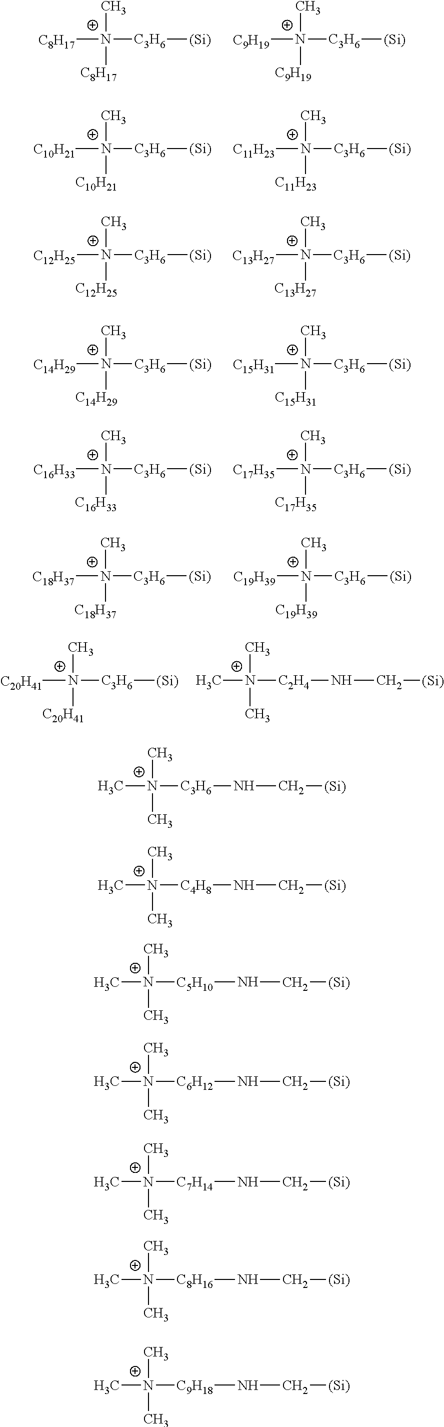

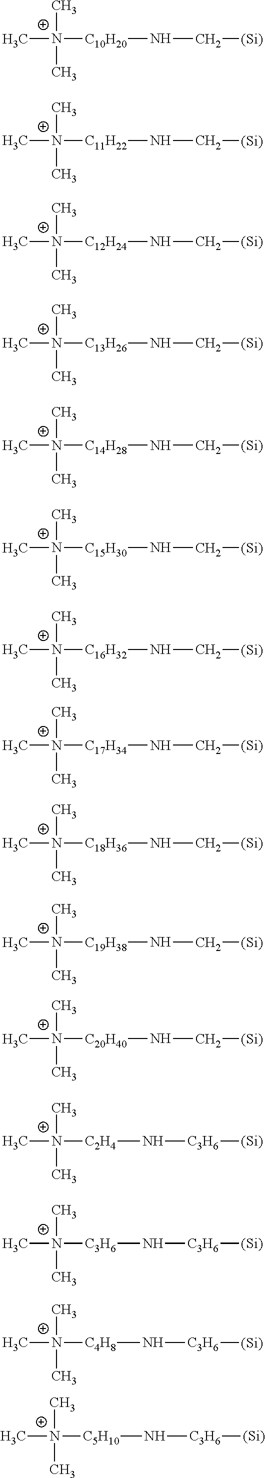

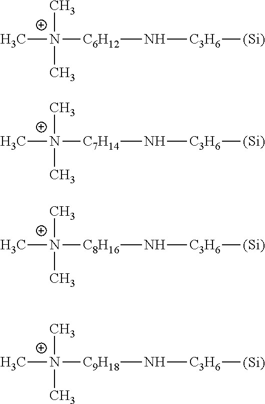

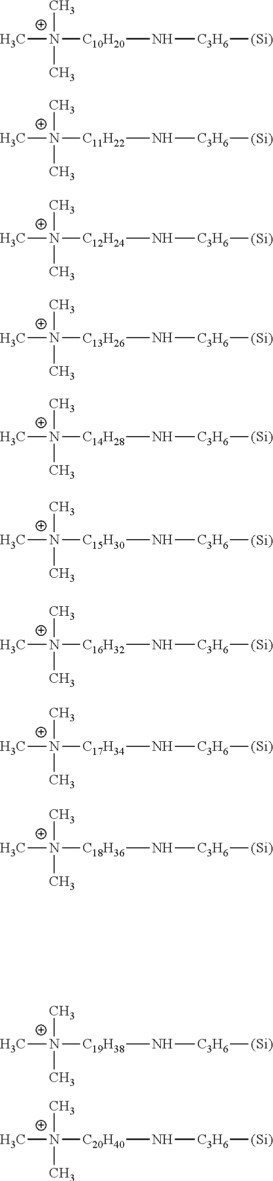

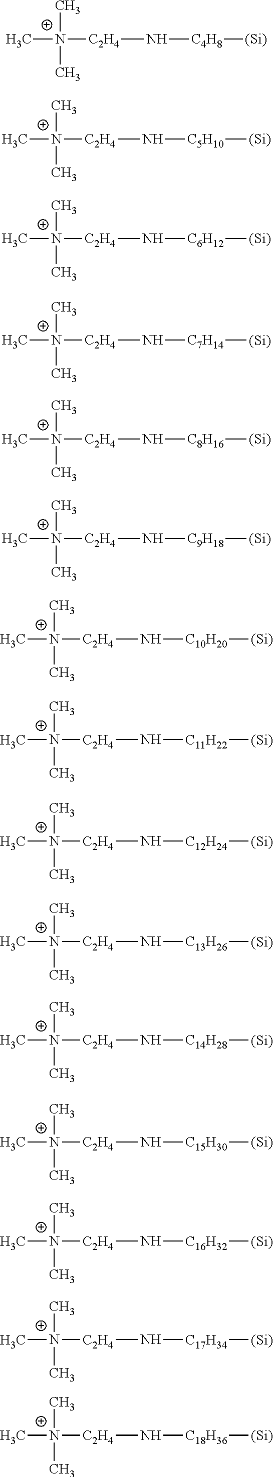

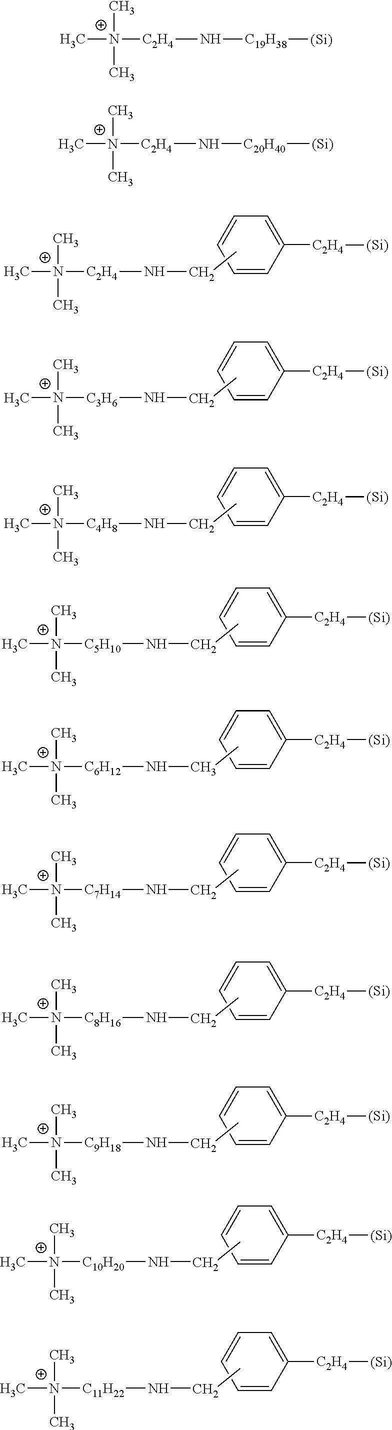

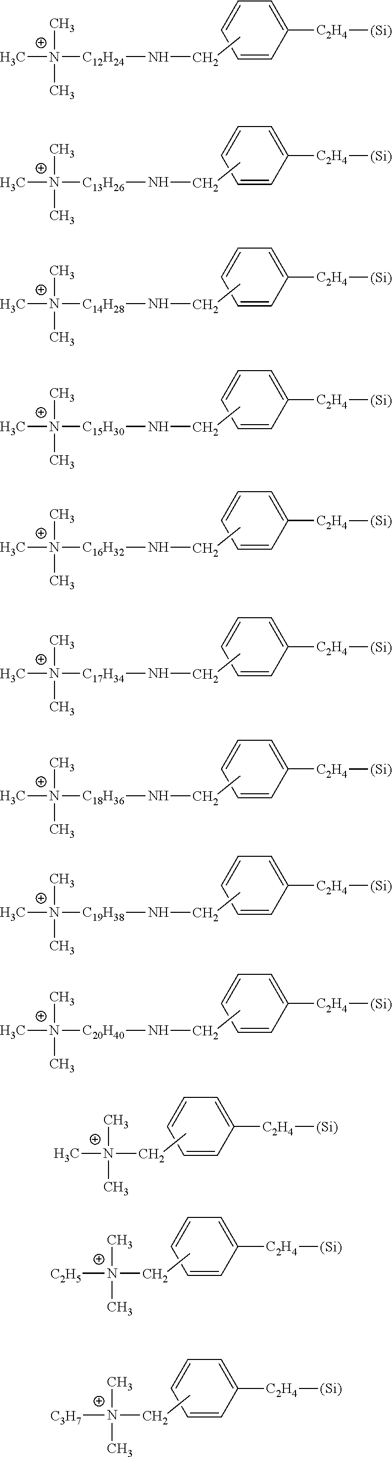

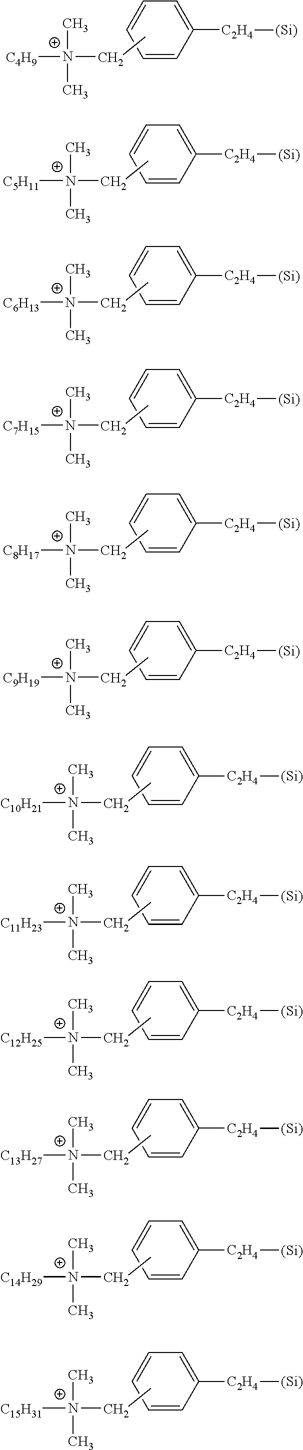

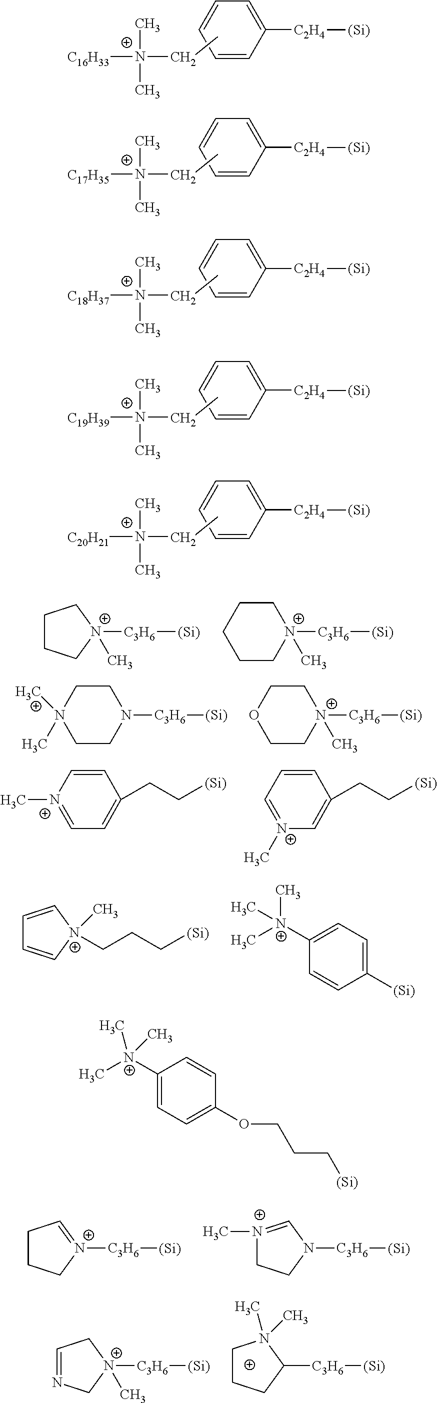

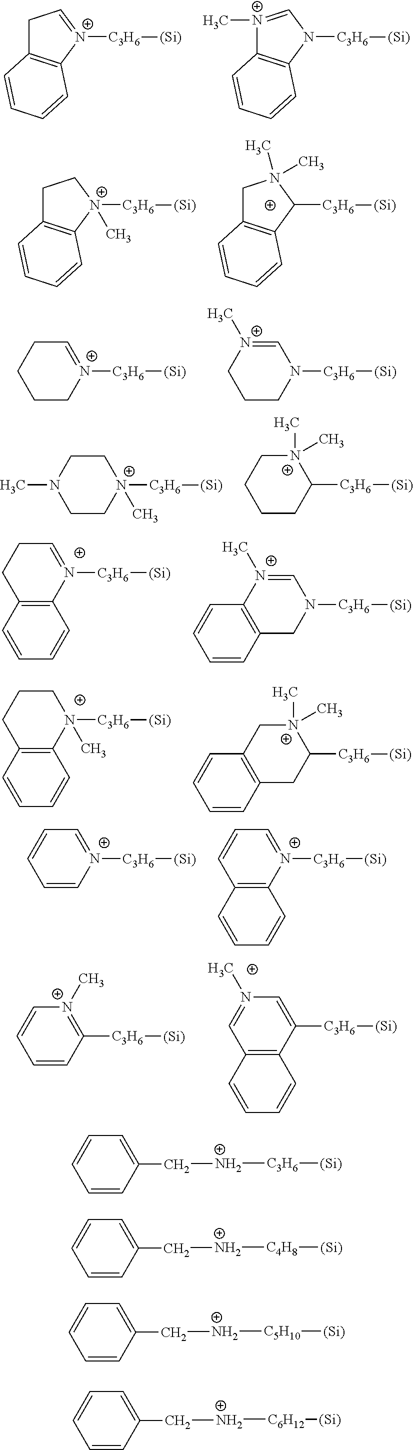

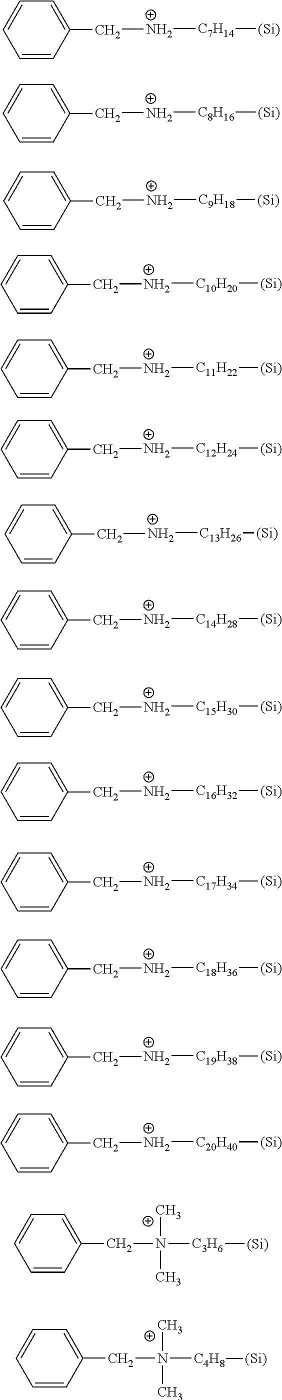

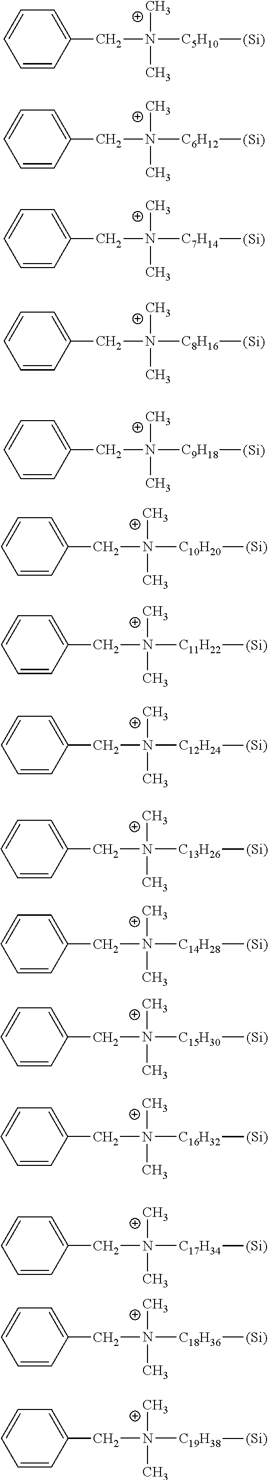

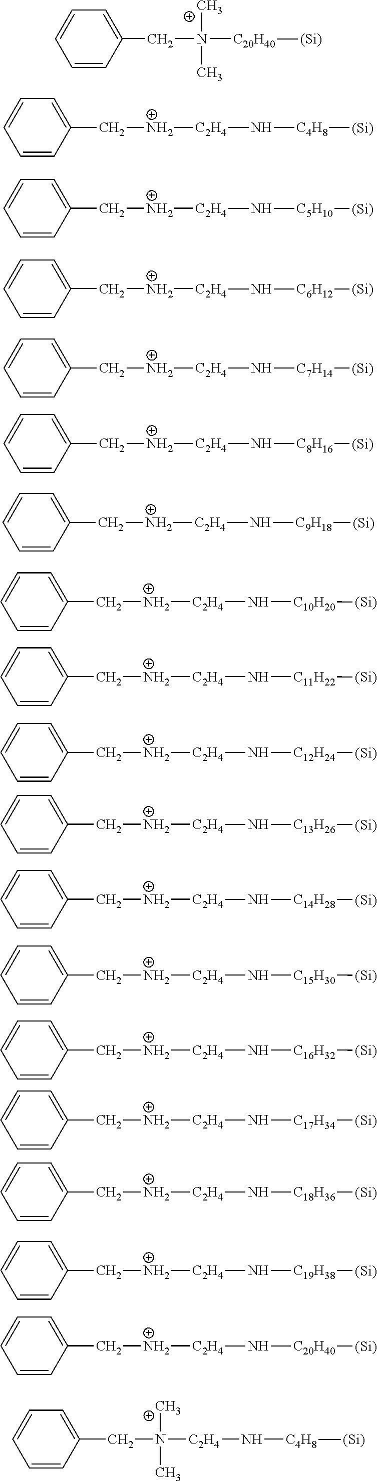

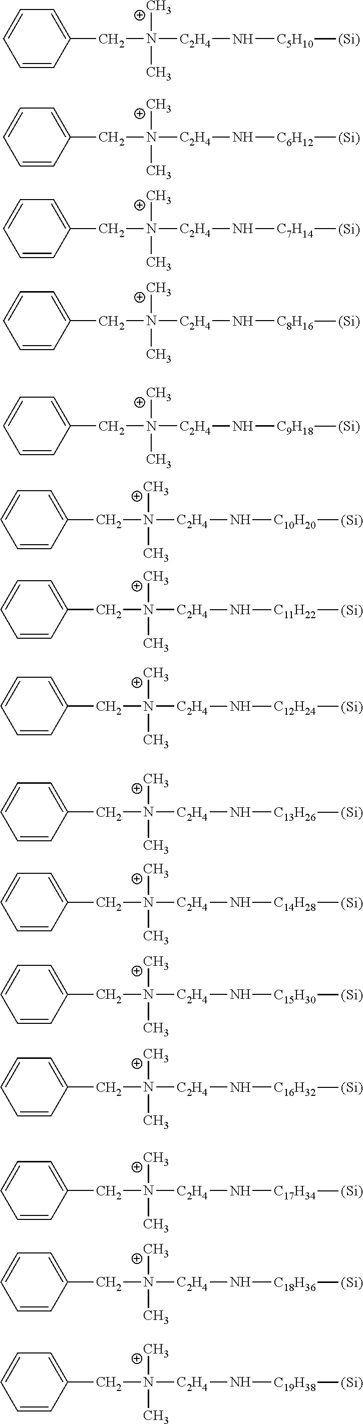

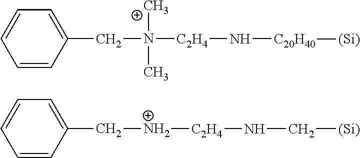

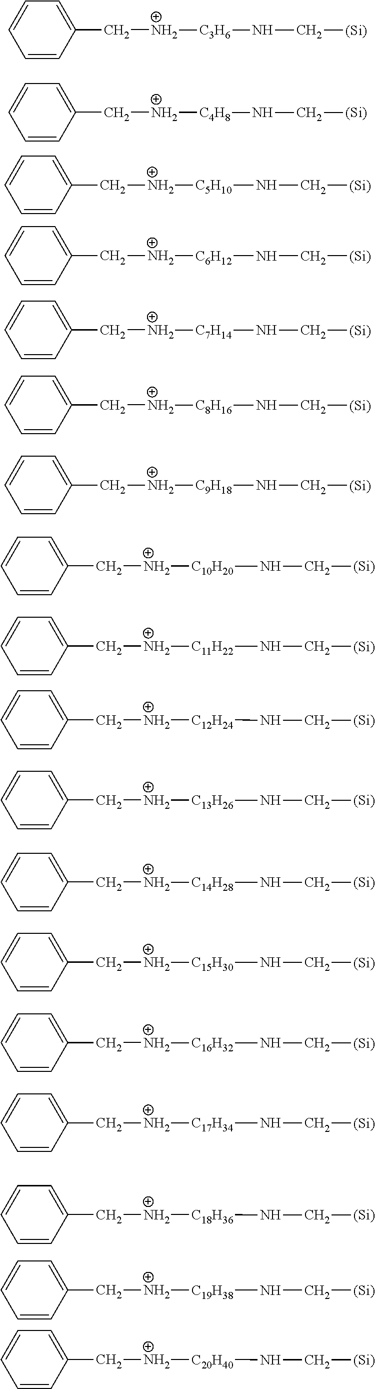

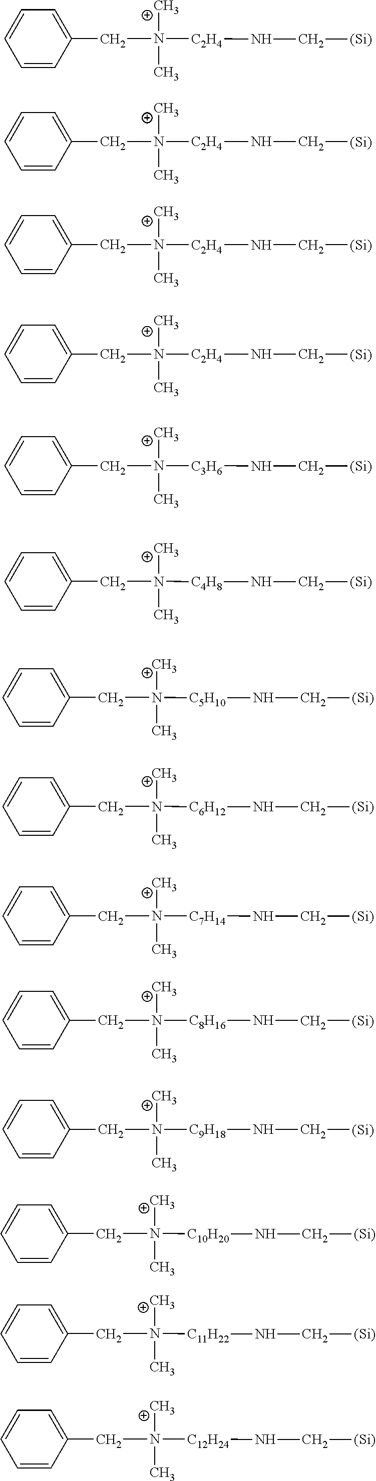

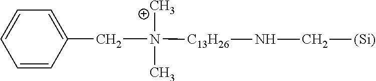

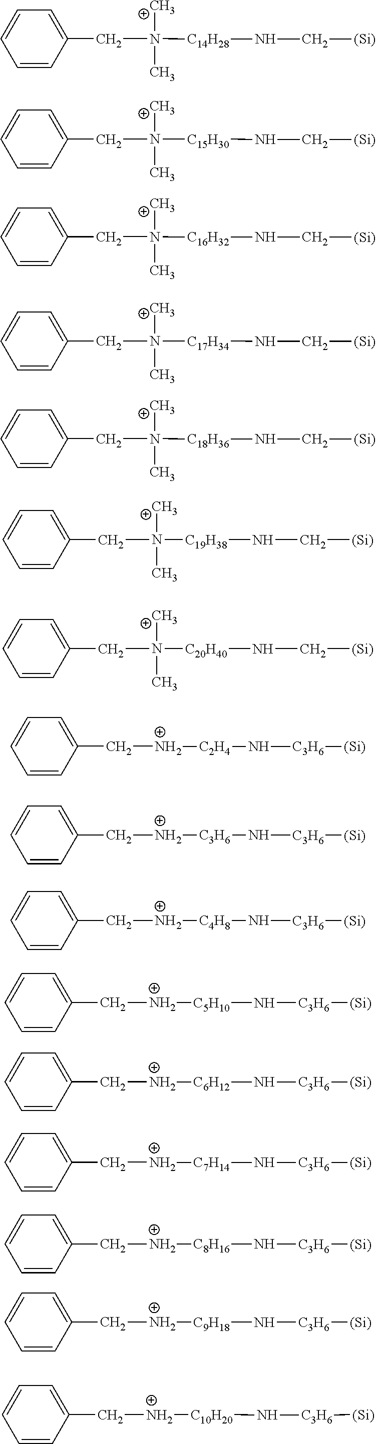

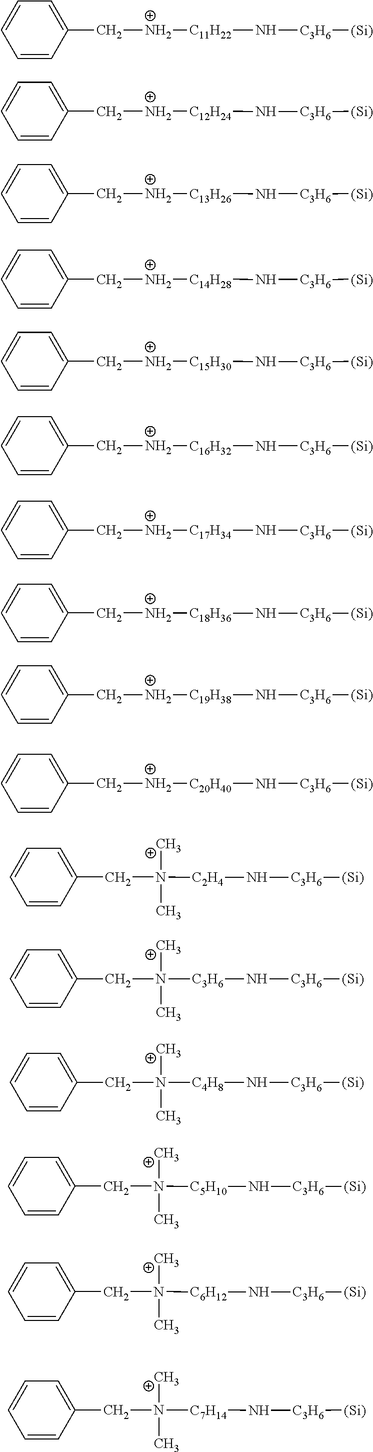

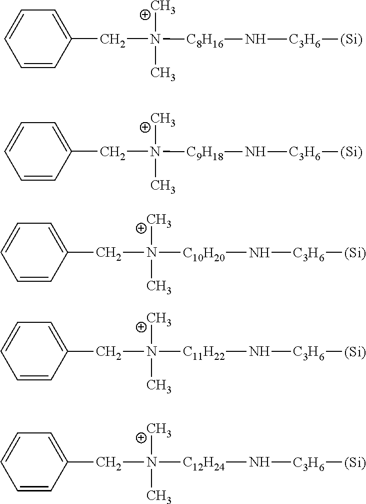

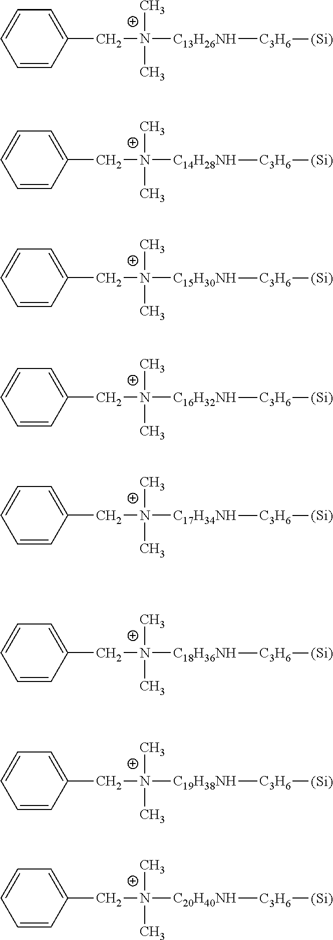

### (Organic Solvent)

The inventive material composition for forming a silicon-containing reversed pattern may contain a solvent. The solvent is preferably an organic solvent that does not dissolve the resist film. That is, the material to be used for forming a silicon-containing reversed pattern preferably contains an organic solvent that does not dissolve the resist pattern. The resist composition used in the present invention is a resist composition containing a hypervalent iodine compound, a carboxylic acid compound, and a solvent. After film formation, the carboxylic acid compound and the hypervalent iodine undergo a ligand exchange reaction, making the resist composition insoluble in general organic solvents. Therefore, the final solvent to be added to the thermally crosslinkable polysiloxane solution is not particularly limited as long as it is a general organic solvent, and examples thereof include the following solvents.

Butanediol monomethyl ether, propylene glycol monomethyl ether, ethylene glycol monomethyl ether, butanediol monoethyl ether, propylene glycol monoethyl ether, ethylene glycol monoethyl ether, butanediol monopropyl ether, propylene glycol monopropyl ether, ethylene glycol monopropyl ether, diacetone alcohol, 2-octanone, 2-nonanone, 2-heptanone, 3-heptanone, 4-heptanone, 2-hexanone, 3-hexanone, diisobutyl ketone, 5-methyl-2-hexanone, methylcyclohexanone, acetophenone, methylacetophenone, isopropyl alcohol, isoamyl alcohol, n-butanol, tert-butyl alcohol, tert-pentyl alcohol, n-pentanol, cyclohexanol, formic acid, acetic acid, propionic acid, propyl acetate, butyl acetate, isobutyl acetate, pentyl acetate, butenyl acetate, isopentyl acetate, cyclohexyl acetate, 4-tert-butylcyclohexyl acetate, octyl acetate, isobornyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, ethyl phenylacetate, benzyl formate, phenylethyl formate, methyl 3-phenylpropionate, benzyl propionate, 2-phenylethyl acetate, 2-propanol, 3-methoxybutanol, 3-methyl-3-methoxybutanol, 1-methoxy-2-propanol, 1-ethoxy-2-propanol, 3-methyl-1-butanol, diacetone alcohol, 4-methyl-2-pentanol, 3-methylcyclohexanol, 3,5,5-trimethylhexyl alcohol, 2,6-dimethyl-4-heptanol, toluene, anisole, ε-caprolactone, toluene, hexane, ethyl acetate, cyclohexanone, methyl amyl ketone, propylene glycol dimethyl ether, diethylene glycol dimethyl ether, propylene glycol monomethyl ether acetate, propylene glycol monoethyl ether acetate, ethyl pyruvate, methyl 3-methoxypropionate, ethyl 3-ethoxypropionate, t-butyl propionate, propylene glycol mono t-butyl ether acetate, γ-butyrolactone, methyl isobutyl ketone, and cyclopentyl methyl ether. One of these solvents may be used, or two or more kinds thereof may be used in mixture.

### (Water)

Water may be added to the material composition used in the present invention for forming a silicon-containing reversed pattern. When adding the water, the polysiloxane compounds in the composition are hydrated, thereby improving lithography performance. The water content in the solvent component of the inventive material composition for forming a silicon-containing reversed pattern is preferably more than 0 mass % and less than 50% by mass, more preferably 0.3 to 30 mass %, and further preferably 0.5 to 20 mass %. When the water content is less than 50 mass %, the silicon-containing resist film has good uniformity and does not repel.

The material composition for forming a silicon-containing reversed pattern preferably contains a crosslinking catalyst for polymerizing siloxane (Xc), an alcohol-based organic solvent, and water.

### (High-Boiling-Point Solvent)

Furthermore, if necessary, it is possible to add a high-boiling-point solvent having a boiling point of 180° C. or higher can be added to the material for forming a silicon-containing reversed pattern used in the present invention. Examples thereof include 1-octanol, 2-ethylhexanol, 1-nonanol, 1-decanol, 1-undecanol, ethylene glycol, 1,2-propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol, tripropylene glycol, glycerin, n-nonyl acetate, ethylene glycol monohexyl ether, ethylene glycol mono-2-ethylhexyl ether, ethylene glycol monophenyl ether, ethylene glycol monobenzyl ether, diethylene glycol monoethyl ether, diethylene glycol monoisopropyl ether, diethylene glycol mono-n-butyl ether, diethylene glycol monoisobutyl ether, diethylene glycol monohexyl ether, diethylene glycol monophenyl ether, diethylene glycol monobenzyl ether, diethylene glycol diethyl ether, diethylene glycol dibutyl ether, diethylene glycol butyl methyl ether, triethylene glycol dimethyl ether, triethylene glycol monomethyl ether, triethylene glycol n-butyl ether, triethylene glycol butyl methyl ether, tetraethylene glycol dimethyl ether, dipropylene glycol monomethyl ether, dipropylene glycol mono-n-propyl ether, dipropylene glycol mono-n-butyl ether, tripropylene glycol dimethyl ether, tripropylene glycol monomethyl ether, tripropylene glycol mono-n-propyl ether, tripropylene glycol mono-n-butyl ether, ethylene glycol monoethyl ether acetate, ethylene glycol monobutyl ether acetate, diethylene glycol monomethyl ether acetate, diethylene glycol monoethyl ether acetate, diethylene glycol monobutyl ether acetate, triacetin, propylene glycol diacetate, dipropylene glycol methyl n-propyl ether, dipropylene glycol methyl ether acetate, 1,4-butanediol diacetate, 1,3-butylene glycol diacetate, 1,6-hexanediol diacetate, triethylene glycol diacetate, γ-butyrolactone, methyl benzoate, ethyl benzoate, propyl benzoate, butyl benzoate, dihexyl malonate, diethyl succinate, dipropyl succinate, dibutyl succinate, dihexyl succinate, dimethyl adipate, diethyl adipate, and dibutyl adipate. One of these solvents may be used, or two or more thereof may be used in mixture. The amount of high-boiling-point solvent to be added is preferably 0 to 20 mass %, more preferably 0 to 10 mass %, based on the solvent component.

The total amount of solvent to be used including water is preferably 100 to 100,000 parts by mass, and particularly preferably 200 to 50,000 parts by mass, based on 100 parts by mass of the polysiloxane compound as the base polymer.

### [Other Component]

### (Organic Acid)

To improve the stability of the inventive material composition for forming a silicon-containing reversed pattern to be used in the present invention, it is preferable to add a monovalent, divalent, or more polyvalent organic acid having 1 to 30 carbon atoms. Examples of the acid added in this case include a formic acid, an acetic acid, a propionic acid, a butanoic acid, a pentanoic acid, a hexanoic acid, a heptanoic acid, an octanoic acid, a nonanoic acid, a decanoic acid, an oleic acid, a stearic acid, a linoleic acid, a linolenic acid, a benzoic acid, a phthalic acid, an isophthalic acid, a terephthalic acid, a salicylic acid, a trifluoroacetic acid, a monochloroacetic acid, a dichloroacetic acid, a trichloroacetic acid, an oxalic acid, a malonic acid, a methylmalonic acid, an ethylmalonic acid, a propylmalonic acid, a butylmalonic acid, a dimethylmalonic acid, a diethylmalonic acid, a succinic acid, a methylsuccinic acid, a glutaric acid, an adipic acid, an itaconic acid, a maleic acid, a fumaric acid, a citraconic acid, and a citric acid. An oxalic acid, a maleic acid, a formic acid, an acetic acid, a propionic acid, and a citric acid are particularly preferable. Moreover, a mixture of two or more kind of acids may be used to keep the stability. The amount of the organic acid to be added may be preferably 0.001 to 25 parts by mass, preferably 0.01 to 15 parts by mass, and further preferably 0.1 to 5 parts by mass, relative to 100 parts by mass of silicon contained in the composition.

### (Stabilizer)

Further, in the present invention, a stabilizer may be added to the material composition for forming a silicon-containing reversed pattern. As the stabilizer, a monohydric, dihydric, or more polyhydric alcohol having cyclic ether as a substituent can be added. Particularly, adding stabilizers disclosed in paragraphs [0181] to [0182] of JP2009-126940A can improve stability of the material composition for forming a silicon-containing reversed pattern. The blending amount of the stabilizer is preferably 0.001 to 50 parts by mass, more preferably 0.01 to 40 parts by mass relative to 100 parts by mass of the thermally crosslinkable polysiloxane.

### (Surfactant)

Further, in the present invention, a surfactant may be blended into the material composition for forming a silicon-containing reversed pattern as necessary. Specifically for such a surfactant, it is possible to add the materials disclosed in paragraph [0185] of JP2009-126940A. The blending amount of the surfactant is preferably 0 to 10 parts by mass, particularly preferably 0 to 5 parts by mass relative to 100 parts by mass of the thermally crosslinkable polysiloxane (Sx).

### [Resist Material]

Resist material to be used in the present invention will be described.

The resist material is obtained from a resist composition containing a predetermined hypervalent iodine compound, a carboxy group-containing compound, and a solvent.

### [Hypervalent Iodine Compound]

As the hypervalent iodine compound, it is preferable to use at least one selected from the hypervalent iodine compounds represented by the following general formulae (1) to (10).

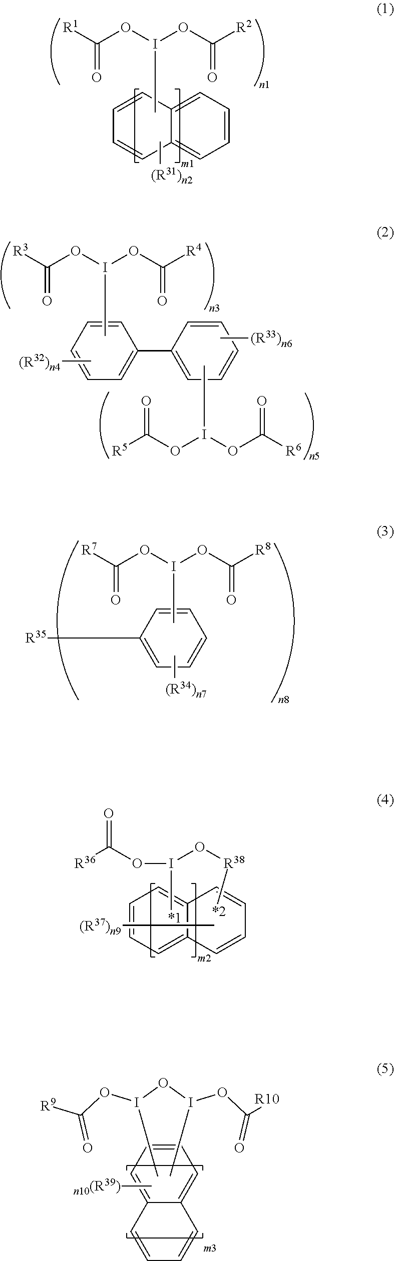

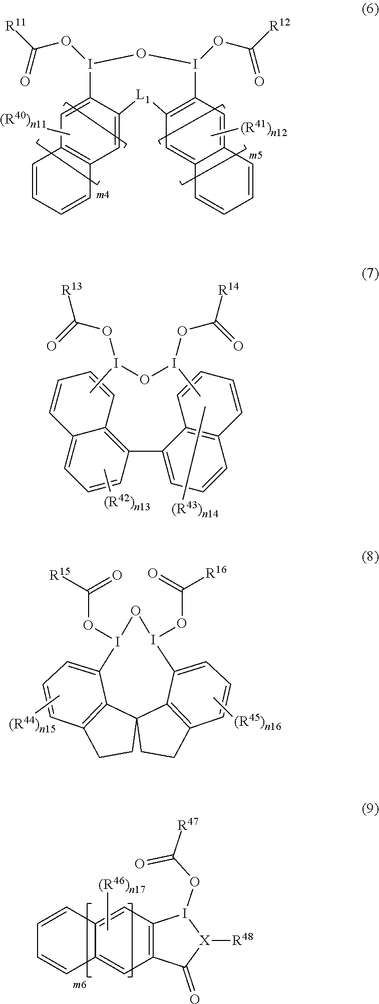

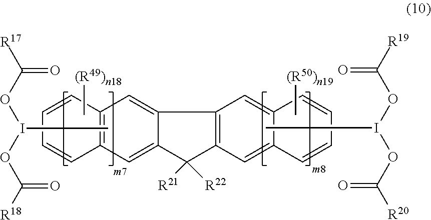

In the formulae, m1 represents 0, 1, or 2, when m1 is 0, n1 represents 1, 2, or 3, n2 represents 0, 1, 2, 3, 4, or 5, and 1≤n1+n2≤6 is satisfied, when m1 is 1, n1 represents 1, 2, or 3, n2 represents 0, 1, 2, 3, 4, 5, 6, or 7, and 1≤n1+n2≤8 is satisfied, and when m1 is 2, n1 represents 1, 2, or 3, n2 represents 0, 1, 2, 3, 4, 5, 6, 7, 8, or 9, and 1≤n1+n2≤10 is satisfied;
n3 represents 1 or 2, n4 represents 0, 1, 2, 3, or 4, and 1≤n3+n4≤5 is satisfied; n5 represents 1 or 2, n6 represents 0, 1, 2, 3, or 4, and 1≤n5+n6≤5 is satisfied;
n7 represents 0, 1, 2, 3, or 4; n8 represents 1, 2, 3, or 4;
m2 represents 0, 1, or 2, when m2 is 0, n9 represents 0, 1, 2, 3, or 4, when m2 is 1, n9 is 0, 1, 2, 3, 4, 5, or 6, and when m2 is 2, n9 is 0, 1, 2, 3, 4, 5, 6, 7, or 8;
m3 represents 0, 1, or 2, when m3 is 0, n10 is 0, 1, 2, 3, or 4, when m3 is 1, n10 is 0, 1, 2, 3, 4, 5, or 6, and when m3 is 2, n10 is 0, 1, 2, 3, 4, 5, 6, 7, or 8;
m4 represents 0 or 1, when m4 is 0, n11 represents 0, 1, 2, 3, or 4, and when m4 is 1, n11 represents 0, 1, 2, 3, 4, 5, or 6;
m5 represents 0 or 1, when m5 is 0, n12 represents 0, 1, 2, 3, or 4, and when m5 is 1, n12 represents 0, 1, 2, 3, 4, 5, or 6;
n13 and n14 represent 0, 1, 2, 3, 4, 5, or 6;
n15 and n16 represent 0, 1, 2, or 3;
m6 represents 0, 1, or 2, when m6 is 0, n17 represents 0, 1, 2, 3, or 4, when m6 is 1, n17 represents 0, 1, 2, 3, 4, 5, or 6, and when m6 is 2, n17 represents 0, 1, 2, 3, 4, 5, 6, 6, 7, or 8;
m7 represents 0, 1, or 2, when m7 is 0, n18 represents 0, 1, 2, or 3, when m7 is 1, n18 represents 0, 1, 2, 3, 4, or 5, and when m7 is 2, n18 represents 0, 1, 2, 3, 4, 5, 6, or 7;
m8 represents 0, 1, or 2, when m8 is 0, n19 represents 0, 1, 2, or 3, and n20 represents 0 or 1, when m8 is 1, n19 represents 0, 1, 2, 3, 4, or 5, and n20 is 0 or 1, and when m8 is 2, n19 represents 0, 1, 2, 3, 4, 5, 6, or 7, and n20 represents 0 or 1.

In the formulae (1) to (3), (5) to (8), and (10), R¹ to R²² each independently represent a halogen atom or a hydrocarbyl group having 1 to 10 carbon atoms and optionally having a heteroatom, R¹ and R², R³ and R⁴, R⁵ and R⁶, R⁷ and R¹, R⁹ and R¹⁰, R¹¹ and R¹², R¹³ and R¹⁴, R¹⁵ and R¹⁶, R¹⁷ and R¹⁸, R¹⁹ and R²⁰, or R²¹ and R²² may be bonded to each other to form a ring together with the carbon atoms to which they are bonded and the atoms between the carbon atoms to which they are bonded.

Examples of halogen atoms represented by R¹ to R²² include a fluorine atom, a chlorine atom, a bromine atom, and an iodine atom. The hydrocarbyl groups having 1 to 10 carbon atoms and represented by R¹ to R²² may be saturated or unsaturated, and may be linear, branched, or cyclic. Example of them include alkyl groups having 1 to 10 carbon atoms, such as a methyl group, an ethyl, propyl group, an isopropyl group, an n-butyl group, an isobutyl group, a sec-butyl group, a tert-butyl group, an n-pentyl group, a tert-pentyl group, an n-hexyl group, an n-octyl group, a 2-ethylhexyl group, an n-nonyl group, and an n-decyl groups; cyclic saturated hydrocarbyl groups having 3 to 10 carbon atoms, such as a cyclopentyl group, a cyclohexyl group, a cyclopentylmethyl group, a cyclopentylethyl, cyclopentylbutyl group, a cyclohexylmethyl, a cyclohexylethyl group, a cyclohexylbutyl, a norbornyl group, a tricyclo[5.2.1.0^{2,6}]decyl group, and an adamantyl group; alkenyl groups, such as a vinyl group and an allyl group; aryl groups having 6 to 10 carbon atoms, such as a phenyl group and a naphthyl group; and a group obtained by combining these. Part or all of the hydrogen atoms of the hydrocarbyl group may be substituted with a group containing a heteroatom, such as an oxygen atom, a sulfur atom, a nitrogen atom, or a halogen atom. Part of —CH2- in the hydrocarbyl group may be substituted with a group containing a heteroatom, such as an oxygen atom, a sulfur atom, or a nitrogen atom, and the resulting hydrocarbyl group may contain a hydroxy group, a cyano group, a halogen atom, a carbonyl group, an ether bond, a thioether bond, an ester bond, a sulfonate ester bond, a carbonate bond, a carbamate bond, a lactone ring, a sultone ring, a carboxylic acid anhydride (—C(═O)—O—C(═O)—), etc. R¹ to R²² are preferably a hydrocarbyl group having 1 to 4 carbon atoms.

In the formulae (1) to (10), R³¹ to R³⁴, R³⁷, R³⁹ to R⁴⁶, R⁴⁹, and R⁵⁰ each independently represent a halogen atom or a hydrocarbyl group having 1 to 40 carbon atoms and optionally having a heteroatom, when n2 is 2 or more, R³¹s may be identical to or different from each other, and a plurality of R³¹s may be bonded to each other to form a ring together with the carbon atoms of the aromatic ring to which they are bonded, when n4 is 2 or more, R³²s may be identical to or different from each other, and a plurality of R³²s may be bonded to each other to form a ring together with the carbon atoms of the aromatic ring to which they are bonded, when n6 is 2 or more, R³³s may be identical to or different from each other, and a plurality of R³³s may be bonded to each other to form a ring together with the carbon atoms of the aromatic ring to which they are bonded, when n7 is 2 or more, R³⁴s may be identical to or different from each other, and a plurality of R³⁴s may be bonded to each other to form a ring together with the carbon atoms of the aromatic ring to which they are bonded, when n9 is 2 or more, R³⁷s may be identical to or different from each other, and a plurality of R³⁷s may be bonded to each other to form a ring together with the carbon atoms of the aromatic ring to which they are bonded, when n10 is 2 or more, R³⁹s may be identical to or different from each other, and a plurality of R³⁹s may be bonded to each other to form a ring together with the carbon atoms of the aromatic ring to which they are bonded, when n11 is 2 or more, R⁴⁰s may be identical to or different from each other, and a plurality of R⁴⁰s may be bonded to each other to form a ring together with the carbon atoms of the aromatic ring to which they are bonded, when n12 is 2 or more, R⁴¹s may be identical to or different from each other, and a plurality of R⁴¹s may be bonded to each other to form a ring together with the carbon atoms of the aromatic ring to which they are bonded, when n13 is 2 or more, R⁴²s may be identical to or different from each other, and a plurality of R⁴²s may be bonded to each other to form a ring together with the carbon atoms of the aromatic ring to which they are bonded, when n14 is 2 or more, R⁴³s may be identical to or different from each other, and a plurality of R⁴³s may be bonded to each other to form a ring together with the carbon atoms of the aromatic ring to which they are bonded, when n15 is 2 or more, R⁴⁴s may be identical to or different from each other, and a plurality of R⁴⁴s may be bonded to each other to form a ring together with the carbon atoms of the aromatic ring to which they are bonded, when n16 is 2 or more, R⁴⁵s may be identical to or different from each other, and a plurality of R⁴⁵S may be bonded to each other to form a ring together with the carbon atoms of the aromatic ring to which they are bonded, when n17 is 2 or more, R⁴⁶s may be identical to or different from each other, and a plurality of R⁴⁶s may be bonded to each other to form a ring together with the carbon atoms of the aromatic ring to which they are bonded, when n18 is 2 or more, R⁴⁹s may be identical to or different from each other, and a plurality of R⁴⁹s may be bonded to each other to form a ring together with the carbon atoms of the aromatic ring to which they are bonded, and when n19 is 2 or more, R⁵⁰s may be identical to or different from each other, and a plurality of R⁵⁰s may be bonded to each other to form a ring together with the carbon atoms of the aromatic ring to which they are bonded.

The halogen atoms represented by R³¹ to R³⁴, R³⁷, R³⁹ to R⁴⁶, R⁴⁹, and R⁵⁰ include a fluorine atom, a chlorine atom, a bromine atom, and an iodine atom. The hydrocarbyl groups having 1 to 40 carbon atoms and represented by R³¹ to R³⁴, R³⁷, R³⁹ to R⁴⁶, R⁴⁹, and R⁵⁰ may be saturated or unsaturated, and may be linear, branched, or cyclic. Examples thereof include alkyl groups having 1 to 40 carbon atoms, such as a methyl group, an ethyl group, a propyl group, an isopropyl group, an n-butyl group, an isobutyl group, a sec-butyl group, a tert-butyl group, an n-pentyl group, a tert-pentyl group, an n-hexyl group, an n-octyl group, a 2-ethylhexyl group, an n-nonyl, and an n-decyl groups; cyclic saturated hydrocarbyl groups having 3 to 40 carbon atoms, such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decyl group, an adamantyl group, and an adamantylmethyl group; and aryl groups having 6 to 40 carbon atoms, such as a phenyl group, a naphthyl group, and an anthracenyl group. Part or all of the hydrogen atoms of the hydrocarbyl group may be substituted with a group containing a heteroatom, such as an oxygen atom, a sulfur atom, a nitrogen atom, or a halogen atom. Part of —CH2- in the hydrocarbyl group may be substituted with a group containing a heteroatom, such as an oxygen atom, a sulfur atom, or a nitrogen atom, and the resulting hydrocarbyl group may contain a hydroxy group, a cyano group, a halogen atom, a carbonyl group, an ether bond, a thioether bond, an ester bond, a sulfonate ester bond, a carbonate bond, a carbamate bond, a lactone ring, a sultone ring, a carboxylic acid anhydride (—C(═O)—O—C(═O)—), etc.

In the general formula (3), R³⁵ represents an (n8)-valent hydrocarbon group having 1 to 40 carbon atoms or an (n8)-valent heterocyclic group having 2 to 40 carbon atoms, when n8 is 2, R³⁵ may be an ether bond, a carbonyl group, an azo group, a thioether bond, a carbonate bond, a carbamate bond, a sulfinyl group, a sulfonyl group, or a thioketone bond, part or all of the hydrogen atoms of the (n8)-valent hydrocarbon group or the (n8)-valent heterocyclic group may be substituted with a group having a heteroatom, part of the —CH₂— groups of the (n8)-valent hydrocarbon group may be substituted with a group having a heteroatom, and R³⁴ and R³⁵ may be bonded to each other to form a ring together with the carbon atoms to which they are bonded and the atoms between the carbon atoms to which they are bonded.

The (n8)-valent hydrocarbon group represented by R³⁵ may be saturated or unsaturated, and may be linear, branched, or cyclic. The (n8)-valent hydrocarbon group is a group obtained by eliminating (n8) hydrogen atoms from a hydrocarbon. Examples of hydrocarbons include alkanes having 1 to 40 carbon atoms, alkenes having 2 to 40 carbon atoms, alkynes having 2 to 40 carbon atoms, cyclic saturated hydrocarbons having 3 to 40 carbon atoms, cyclic unsaturated hydrocarbons having 3 to 40 carbon atoms, and aromatic hydrocarbons having 6 to 40 carbon atoms.

Specific examples of the alkanes having 1 to 40 carbon atoms include methane, ethane, propane, butane, pentane, hexane, heptane, octane, nonane, decane, and structural isomers thereof.

Specific examples of the alkenes having 2 to 40 carbon atoms include ethylene, propylene, butene, pentene, hexene, heptene, octene, nonene, decene, and structural isomers thereof.

Specific examples of the alkyne having 2 to 40 carbon atoms include acetylene, propyne, butyne, pentyne, hexyne, heptyne, octyne, nonyne, decyne, and structural isomers thereof.

Specific examples of the cyclic saturated hydrocarbon having 3 to 40 carbon atoms include cyclopropane, cyclobutane, cyclohexane, cycloheptane, cyclooctane, adamantane, and norbornane.

Specific examples of the cyclic unsaturated hydrocarbon having 3 to 40 carbon atoms include cyclopropene, cyclobutene, cyclopentene, cyclohexene, cycloheptene, cyclooctene, and norbornene.

Specific examples of the aromatic hydrocarbon having 6 to 40 carbon atoms include benzene, naphthalene, and biphenyl.

The (n8)-valent heterocyclic group represented by R³⁵ is a group obtained by eliminating (n8) hydrogen atoms from a heterocyclic compound. Examples of the heterocyclic compound include furan, pyridine, pyrazole, and thiazolidine.

Part or all of the hydrogen atoms of the (n8)-valent hydrocarbon group or the (n8)-valent heterocyclic group represented by R³⁵ may be substituted with a group having a heteroatom, such as an oxygen atom, a sulfur atom, a nitrogen atom, or halogen atom, and the resulting (n8)-valent hydrocarbon group or (n8)-valent heterocyclic group may contain a hydroxy group, a cyano group, a fluorine atom, a chlorine atom, a bromine atom, iodine atom, or the like. Part of —CH2- constituting the (n8)-valent hydrocarbon group may be substituted with a group containing a heteroatom, such as an oxygen atom, a sulfur atom, or a nitrogen atom, and the resulting (n8)-valent hydrocarbon group may have a carbonyl group, an ether bond, a thioether bond, an ester bond, a sulfonate ester bond, a carbonate bond, a carbamate bond, a lactone ring, a sultone ring, a carboxylic acid anhydride (—C(═O)—O—C(═O)—), etc.

In the formula (4), R³⁶ represents a halogen atom or a hydrocarbyl group having 1 to 10 carbon atoms and optionally having a heteroatom. Specific examples of the halogen atom and the hydrocarbyl group represented by R³⁶ include the same as those exemplified as the halogen atom and the hydrocarbyl group represented by R¹ to R²², respectively.

In the general formula (4), R³⁸ represents a carbonyl group or a hydrocarbylene group having 1 to 10 carbon atoms and optionally having a heteroatom. The hydrocarbylene group having 1 to 10 carbon atoms may be saturated or unsaturated, and may be linear, branched, or cyclic. Specific examples thereof include: alkylene groups having 1 to 10 carbon atoms, such as a methanediyl group, an ethane-1,1-diyl group, an ethane-1,2-diyl group, a propane-1,1-diyl group, a propane-1,2-diyl group, a propane-1,3-diyl group, a propane-2,2-diyl group, a butane-2,3-diyl group, a butane-1,4-diyl group, a 2-methylpropane-1,2-diyl group, a pentane-1,5-diyl group, a hexane-1,6-diyl group, a heptane-1,7-diyl group, an octane-1,8-diyl group, a nonane-1,9-diyl group, and a decane-1,10-diyl group; cyclic saturated hydrocarbylene groups having 3 to 10 carbon atoms, such as a cyclopentanediyl group, a cyclohexanediyl group, a norbornanediyl group, an adamantanediyl group, and a tricyclo[5.2.1.0^{2,6}]decanediyl group; alkenylene groups having 2 to 10 carbon atoms, such as a vinylene group and a propynylene group; arylene groups having 6 to 10 carbon atoms, such as a phenylene group, a methylphenylene group, an ethylphenylene group, an n-propylphenylene group, an isopropylphenylene group, an n-butylphenylene group, and a naphthylene group; and groups obtained by combining these groups. Furthermore, part or all of the hydrogen atoms of the hydrocarbylene groups may be substituted with a group having a heteroatom, such as an oxygen atom, a sulfur atom, a nitrogen atom, or a halogen atom, and part of the —CH₂— of the hydrocarbylene groups may be substituted with a group having a heteroatom, such as an oxygen atom, a sulfur atom, or a nitrogen atom. The resulting hydrocarbylene groups may have a hydroxy group, a cyano group, a halogenated alkyl group, a halogen atom, a carbonyl group, an ether bond, a thioether bond, an ester bond, a sulfonic acid ester bond, a carbonate bond, a carbamate bond, a lactone ring, a sultone ring, a carboxylic acid anhydride (—C(═O)—O—C(═O)—), etc. As R³⁸, a carbonyl group, a hydrocarbylene group having 1 to 4 carbon atoms, or a fluorinated hydrocarbylene group having 1 to 4 carbon atoms is preferable.

In the general formula (4), *1 and *2 represent attachment points to a carbon atom of the aromatic ring in the formula, provided that *1 and *2 are bonded to adjacent carbon atoms of the aromatic ring. As combinations of such *1, *2, and m2, the seven cases shown below are possible.

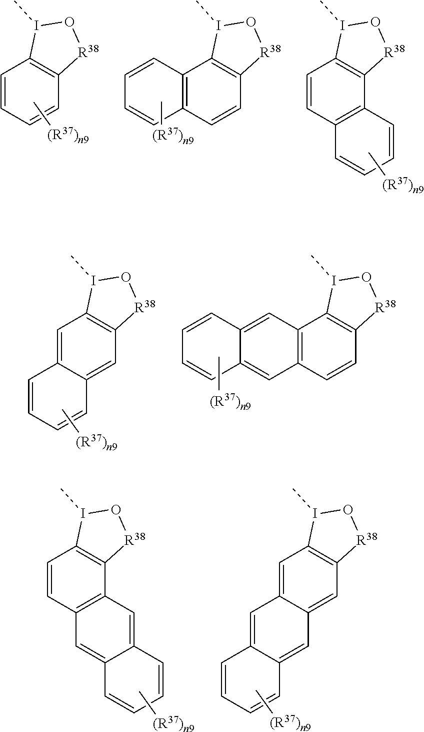

In the formulae, n9, R³⁷, and R³⁸ are as defined above. A dotted line represents an attachment point to R³⁶—C(═O)—O—.

L₁ represents no bond, a single bond, —O—, —S—, —NH—, or —CH₂—.

In the formula (9), R⁴⁷ represents a halogen atom or a hydrocarbyl group having 1 to 10 carbon atoms and optionally having a heteroatom. Specific examples of the halogen atom and the hydrocarbyl group represented by R⁴⁷ include the same as those exemplified as the halogen atom and the hydrocarbyl group represented by R¹ to R²², respectively.

In the formula (9), “X” represents a nitrogen atom or a sulfur atom, and when it is a nitrogen atom, it may have R⁴⁸. R⁴⁸ represents a hydrogen atom, a halogen atom, or a hydrocarbyl group having 1 to 20 carbon atoms and optionally having a heteroatom. Specific examples of the halogen atom and the hydrocarbyl group represented by R⁴⁸ include the same as those exemplified as the halogen atom and the hydrocarbyl group represented by R¹ to R²², respectively.

Specific examples of the hypervalent iodine compound represented by general formula (1) include the following, but are not limited thereto.

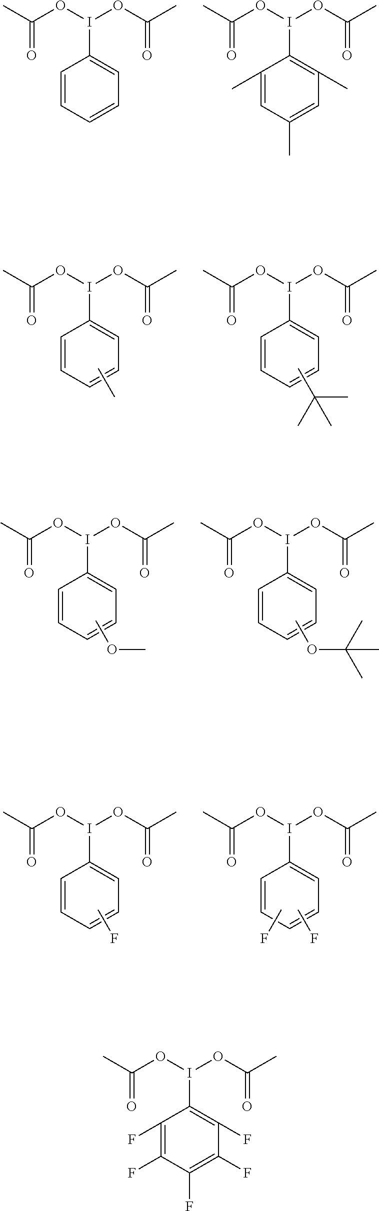

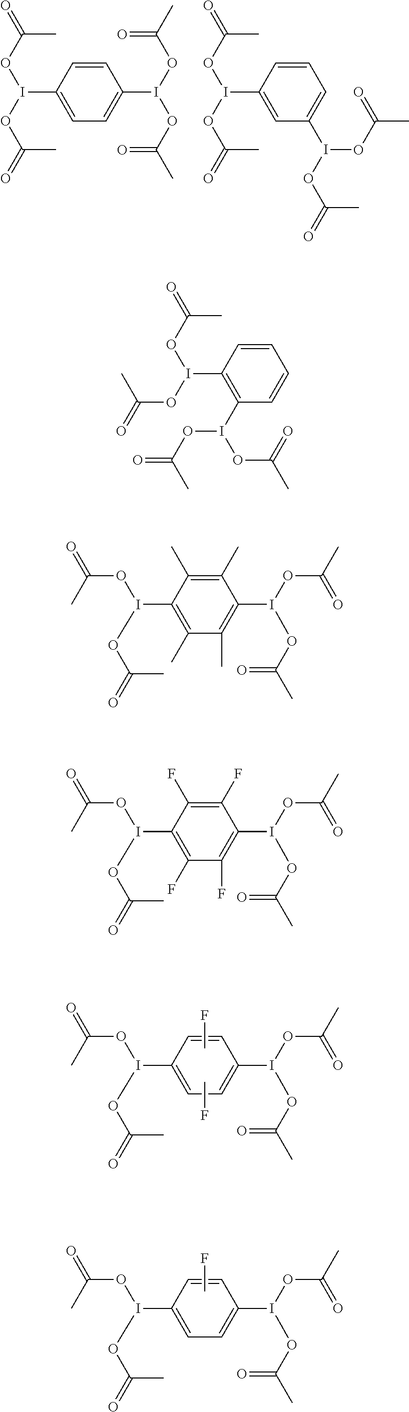

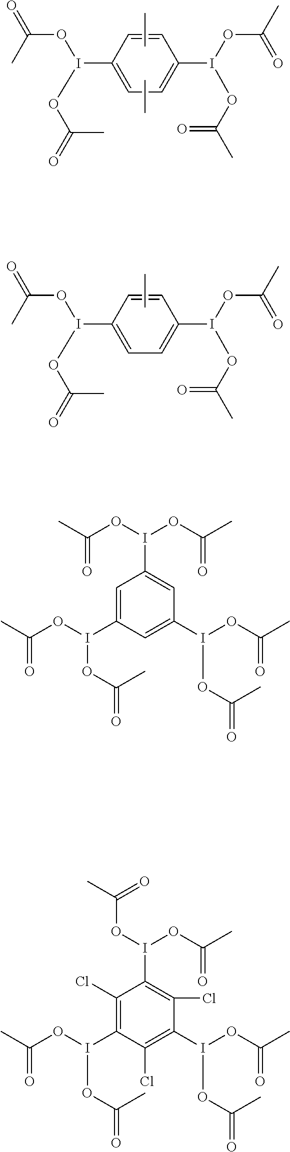

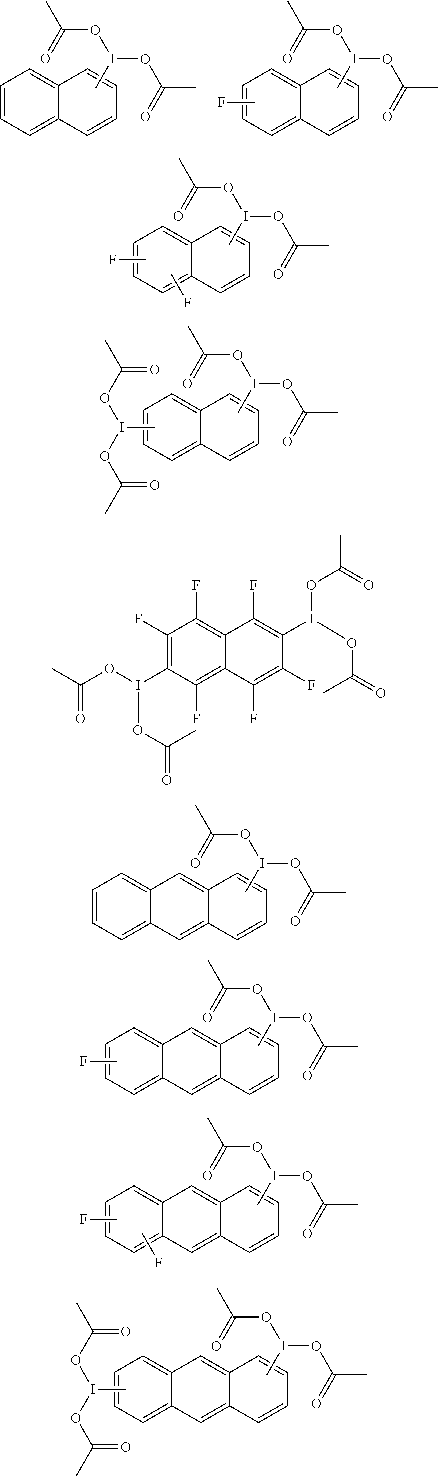

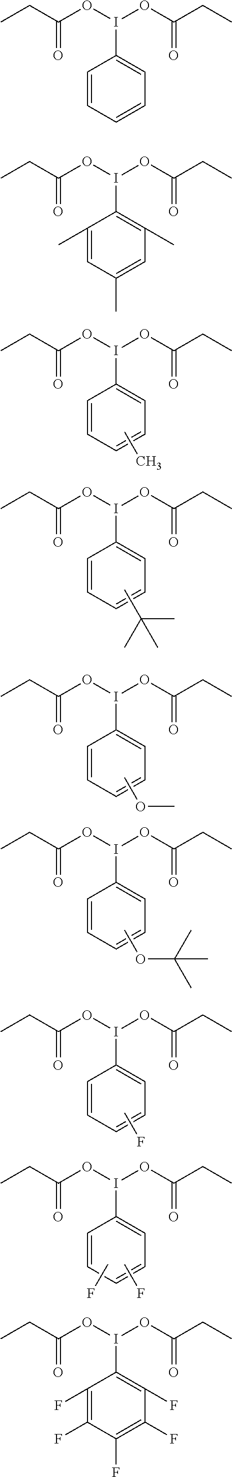

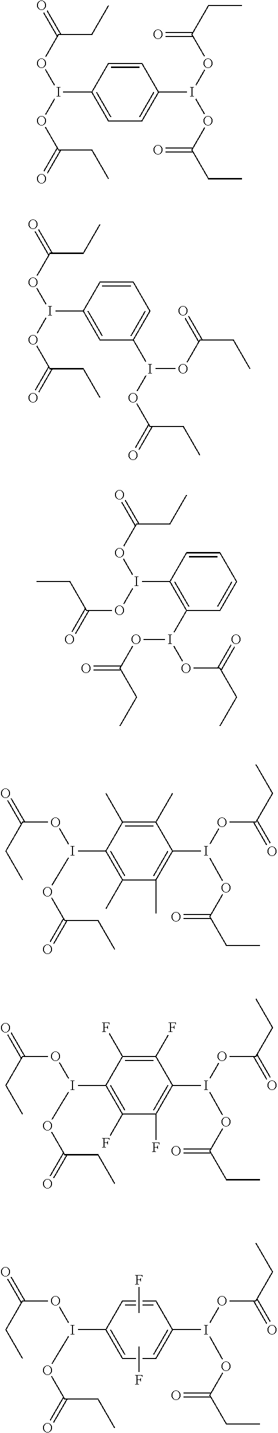

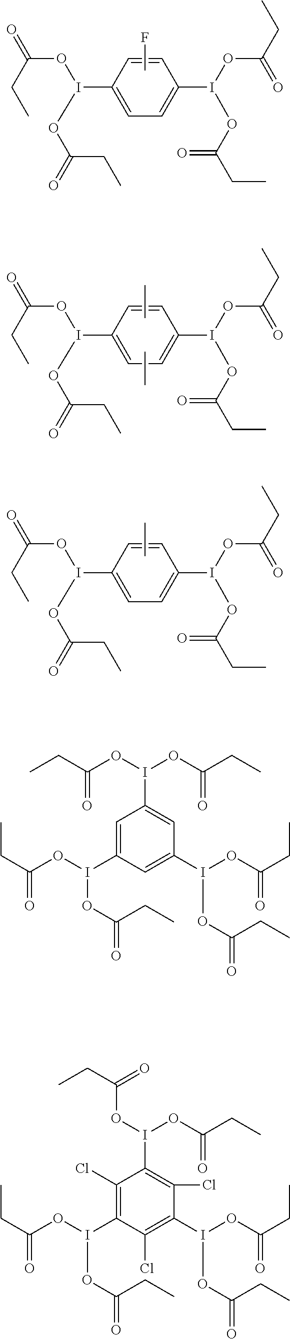

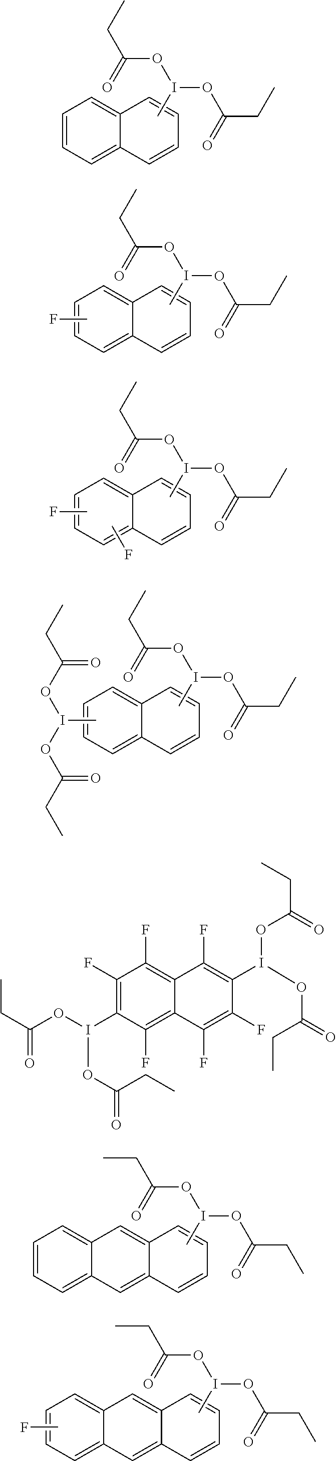

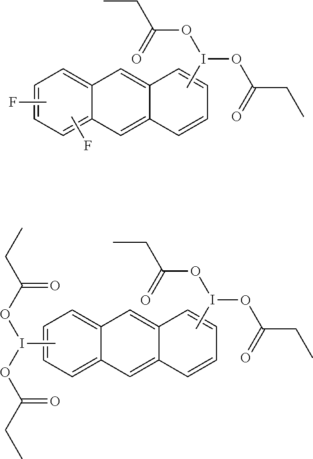

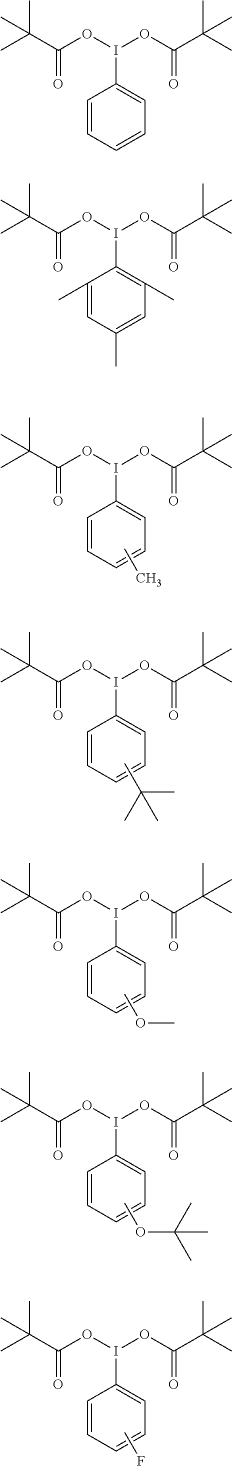

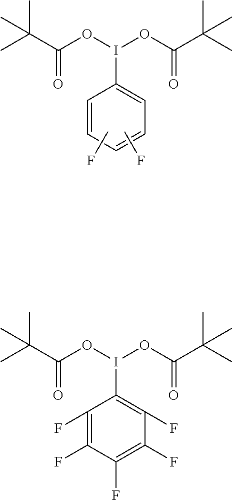

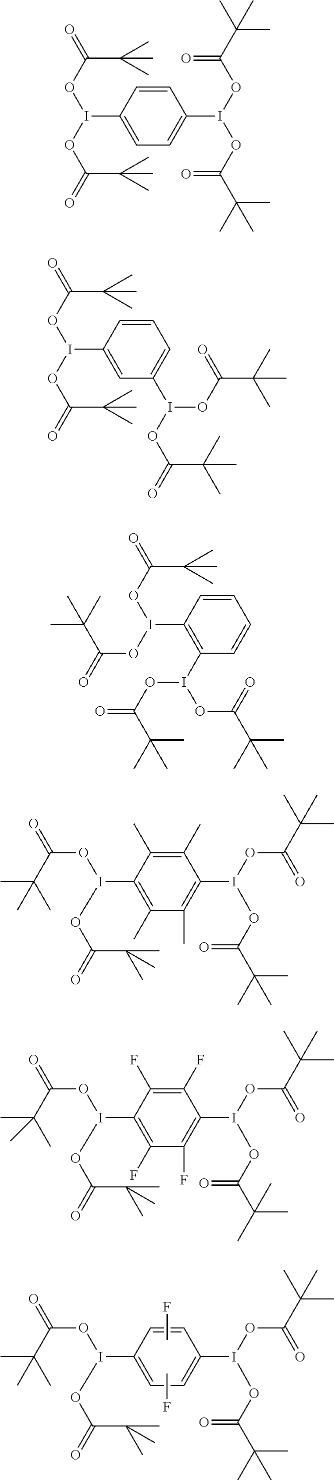

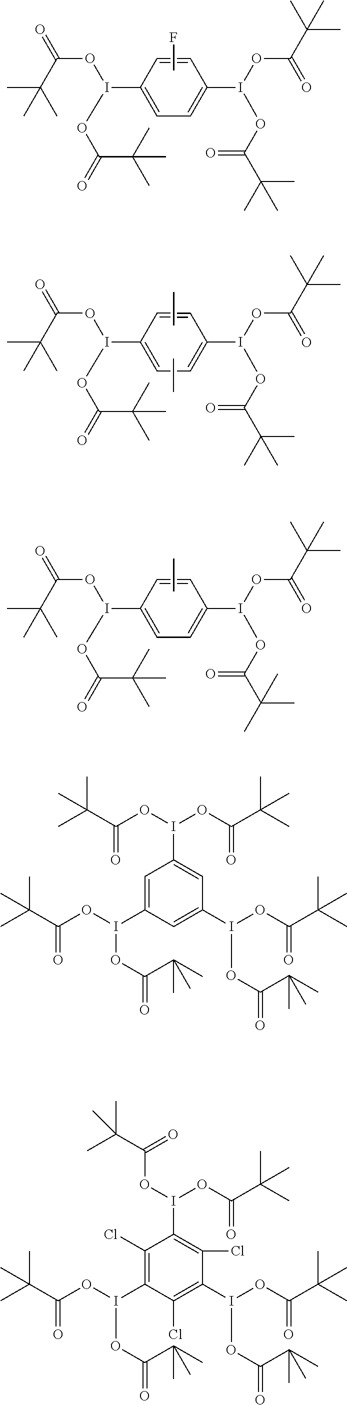

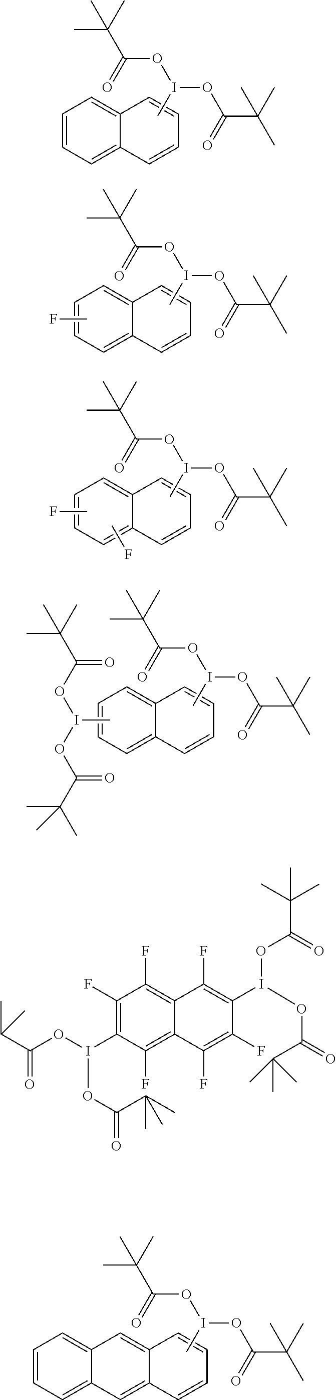

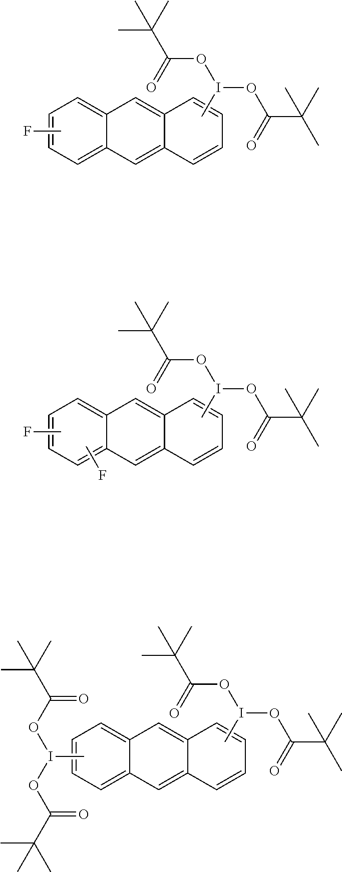

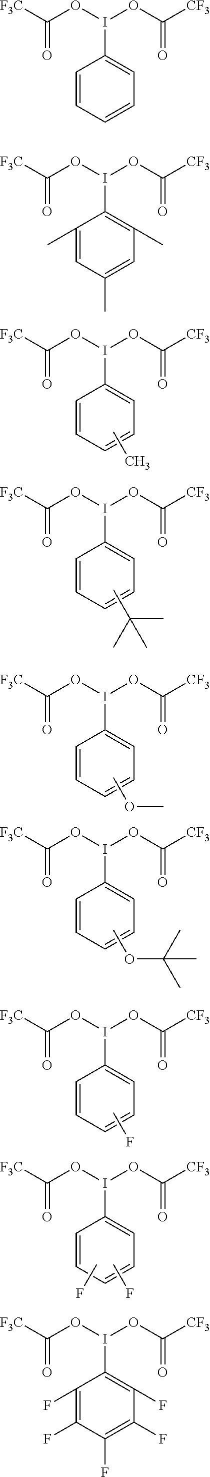

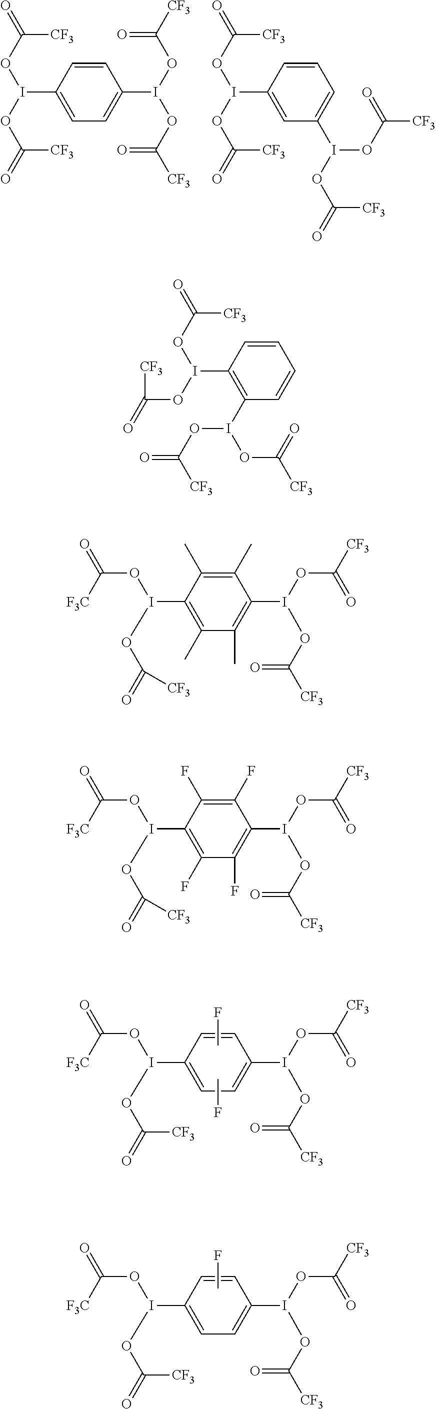

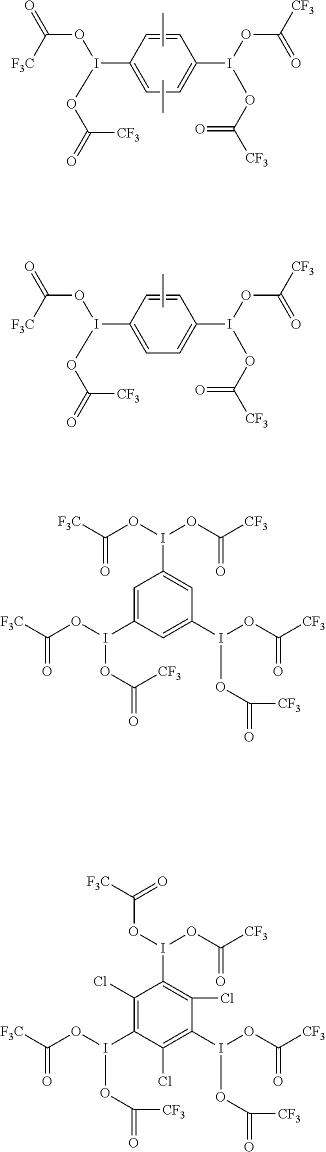

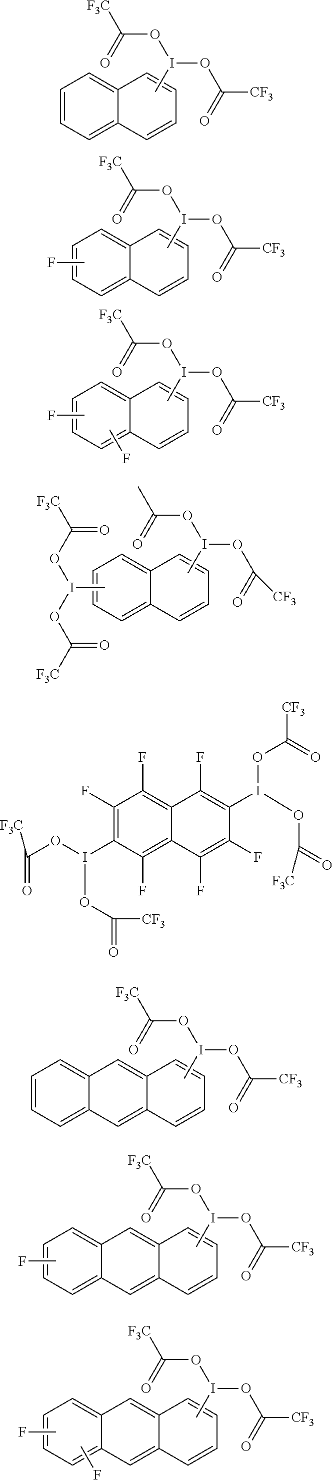

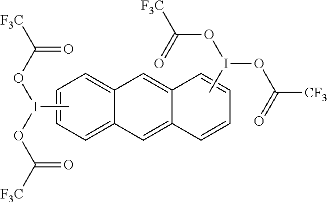

Specific examples of the hypervalent iodine compound represented by the general formula (2) include, but are not limited to, the following.

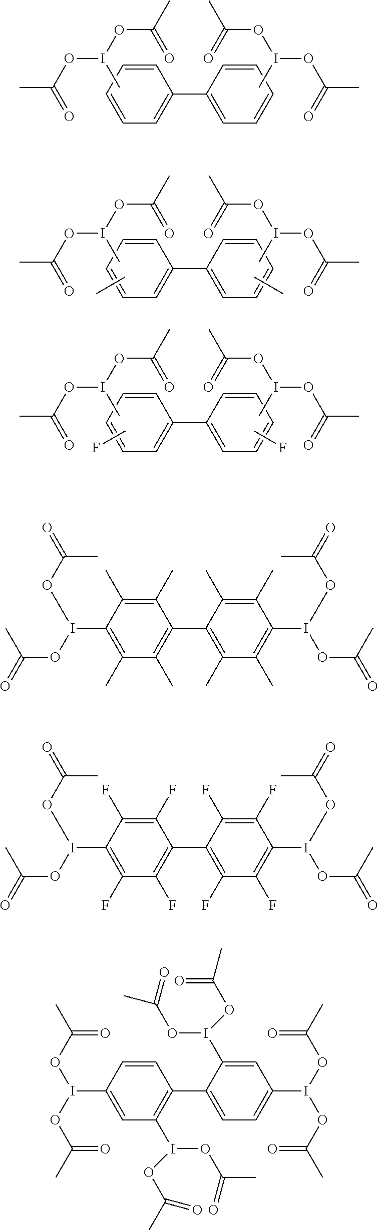

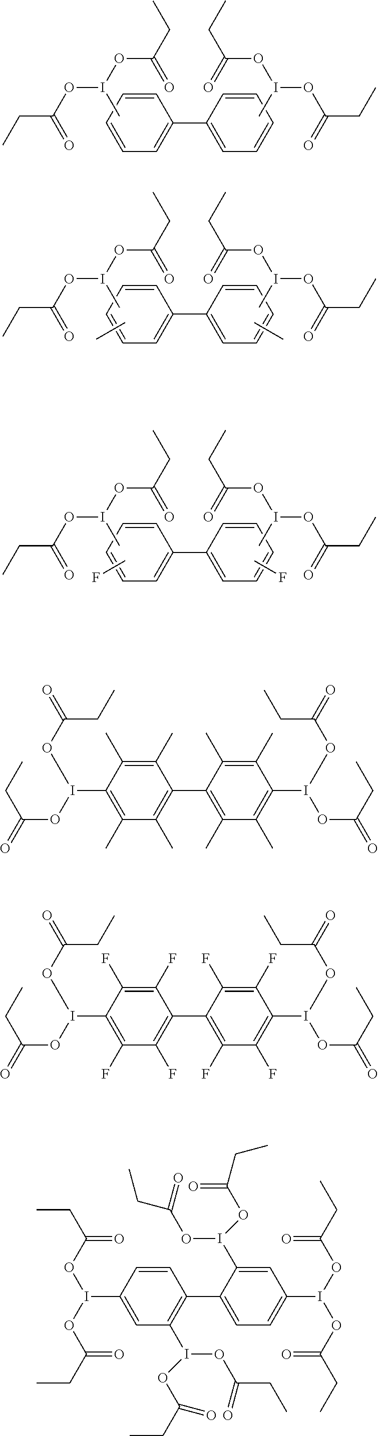

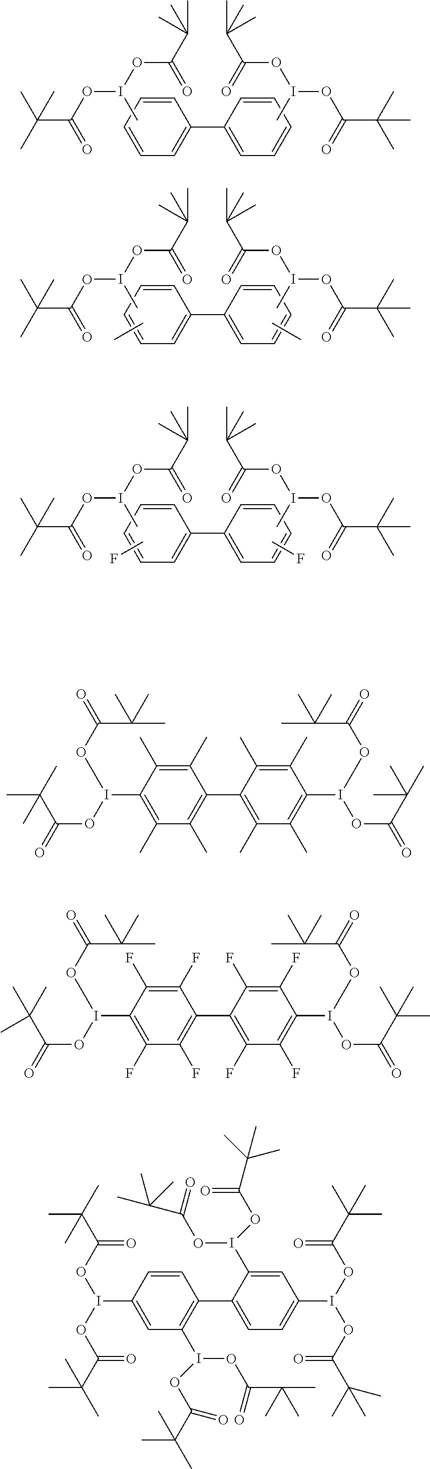

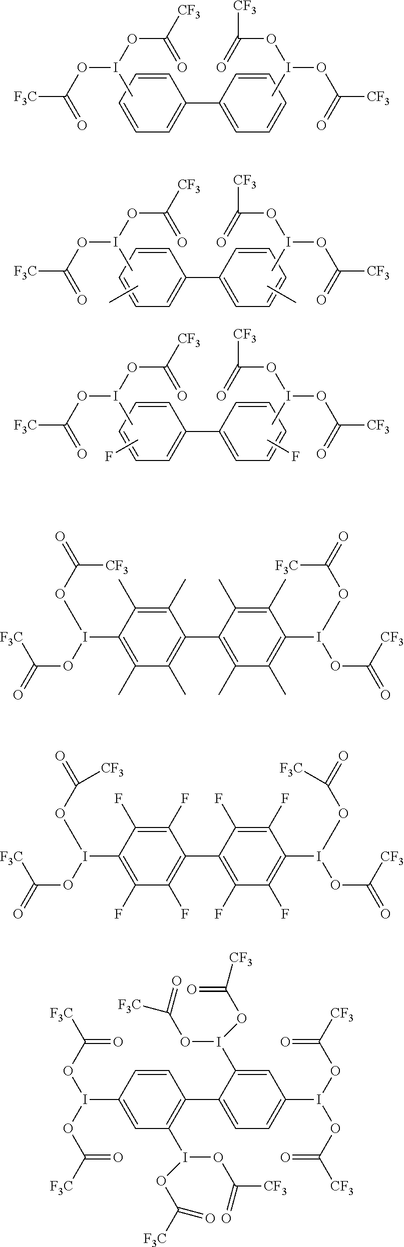

Specific examples of the hypervalent iodine compound represented by the general formula (3) include, but are not limited to, the following.

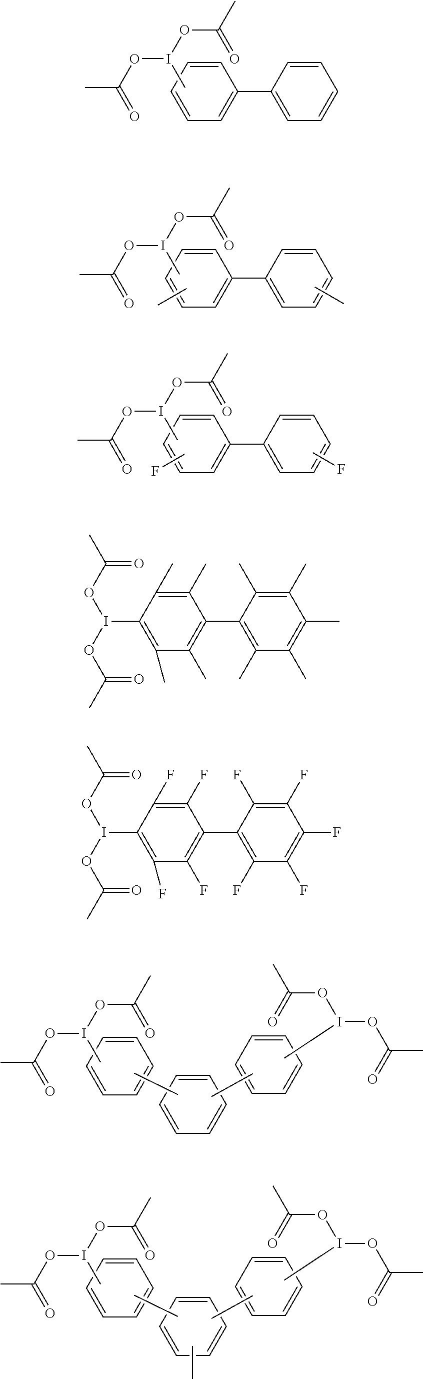

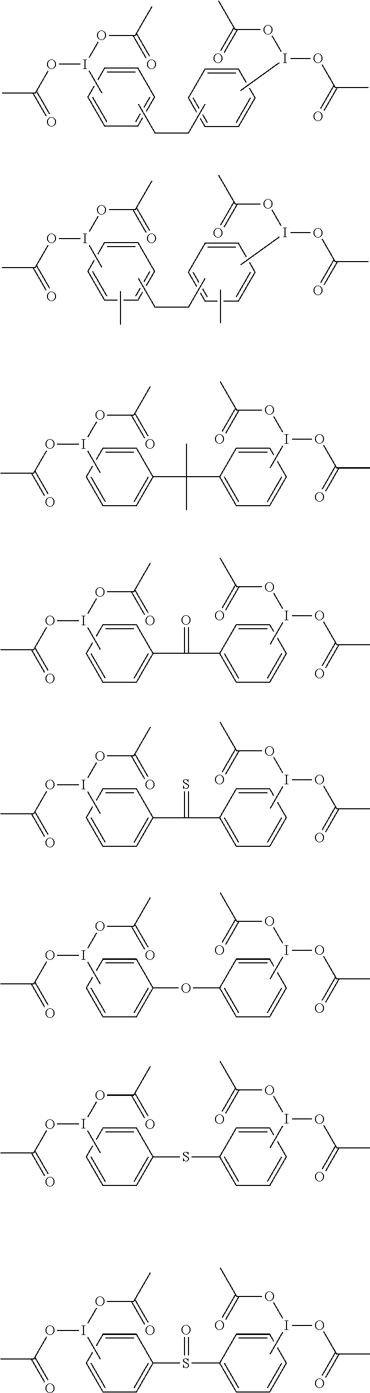

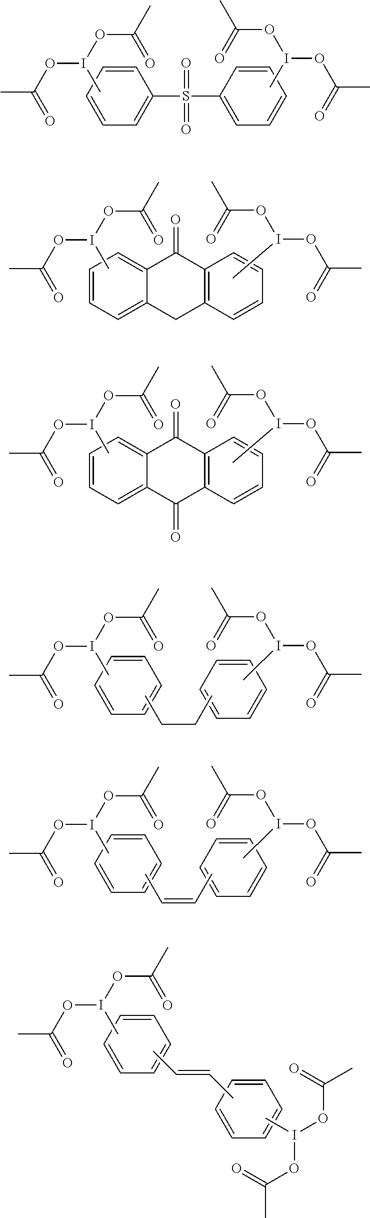

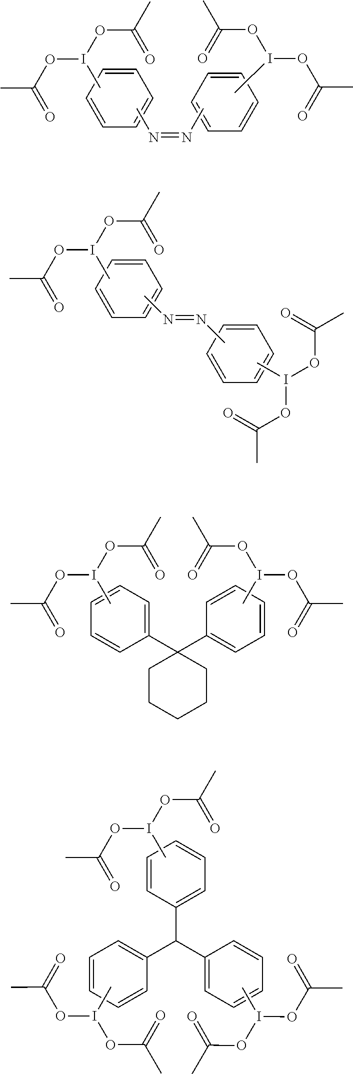

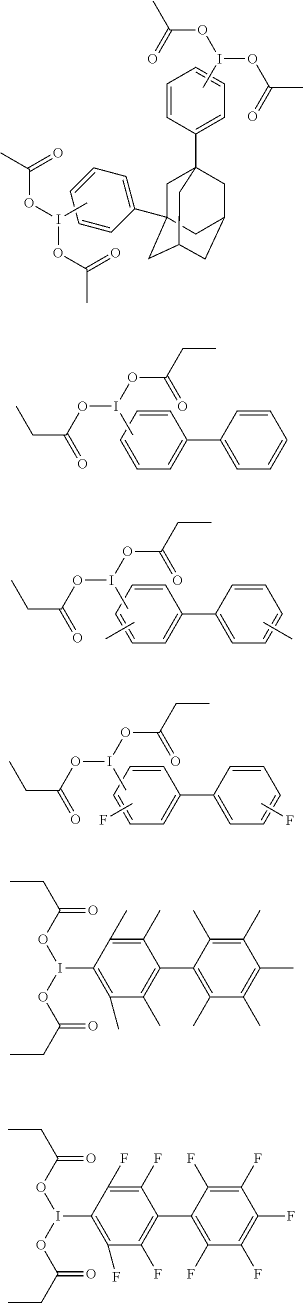

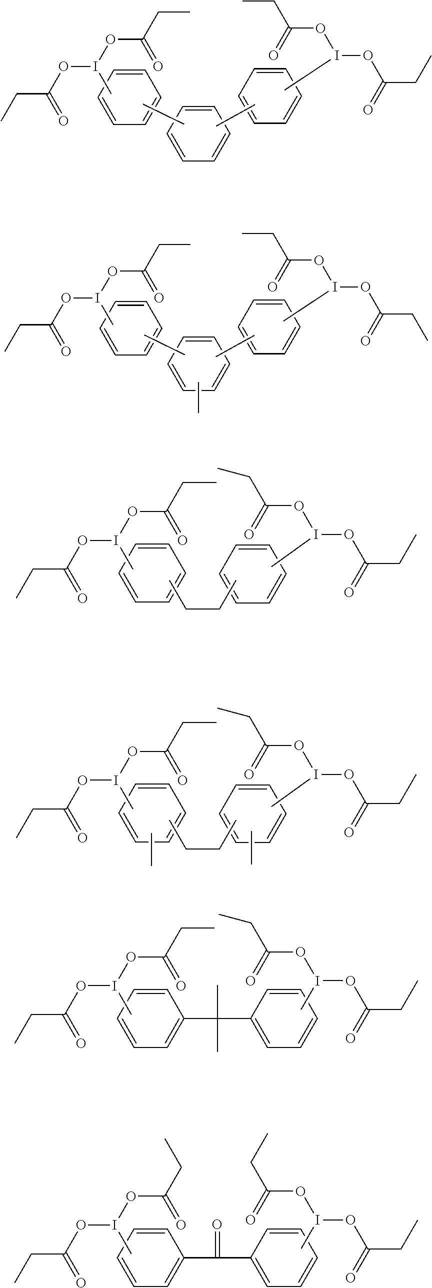

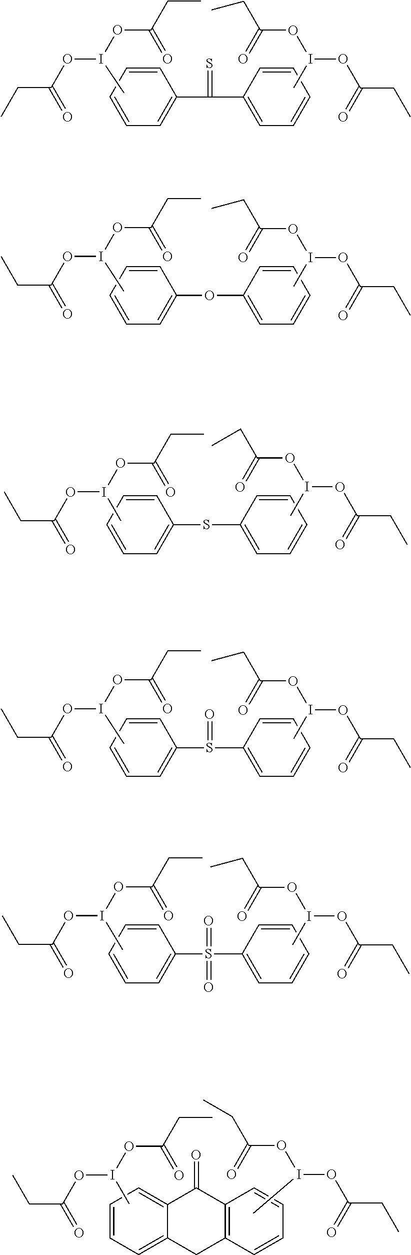

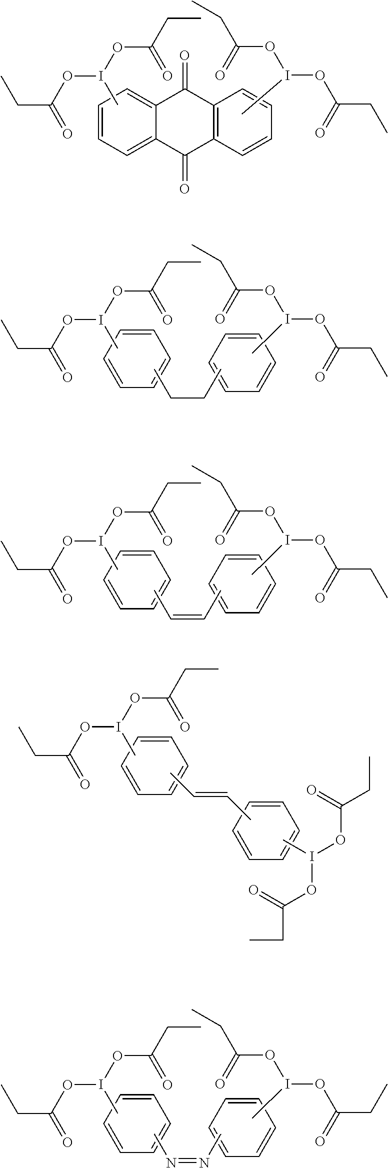

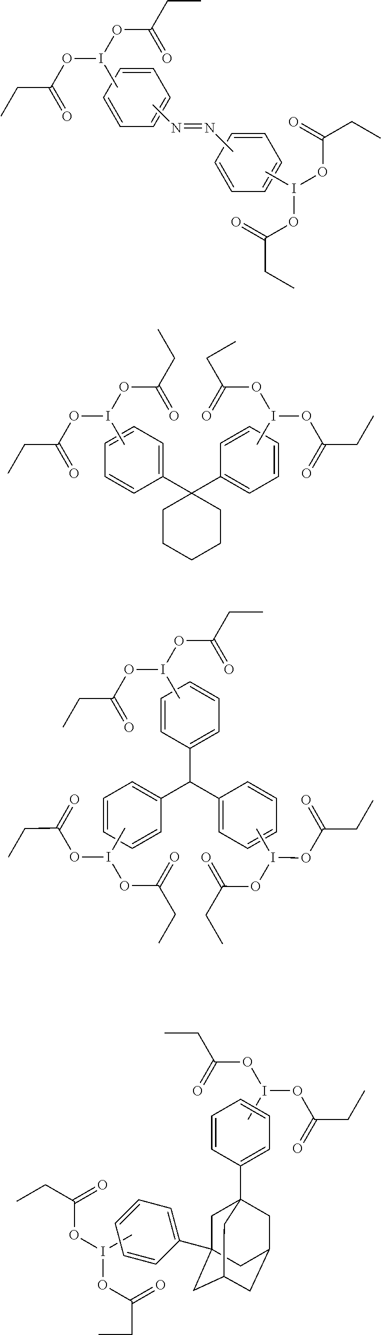

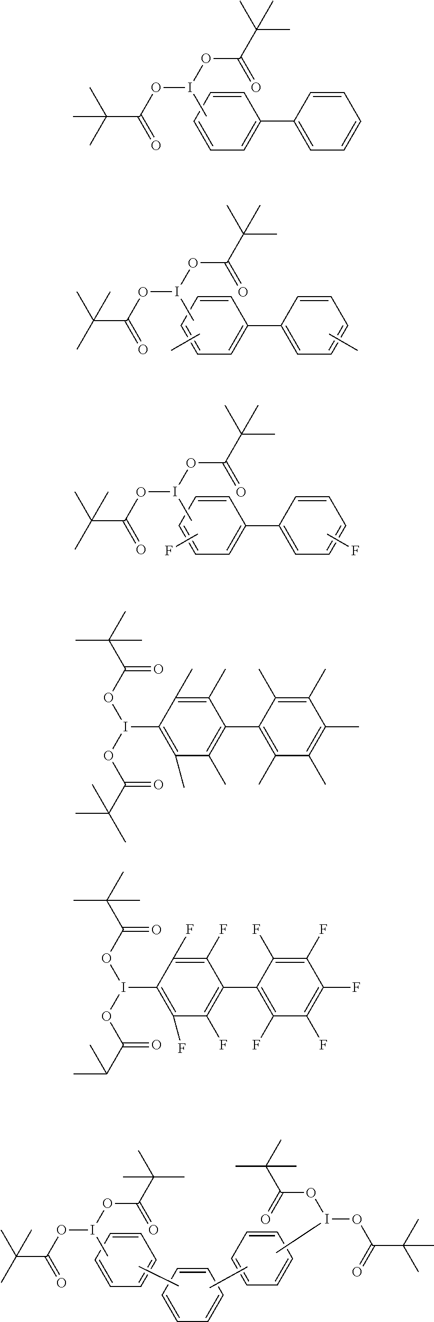

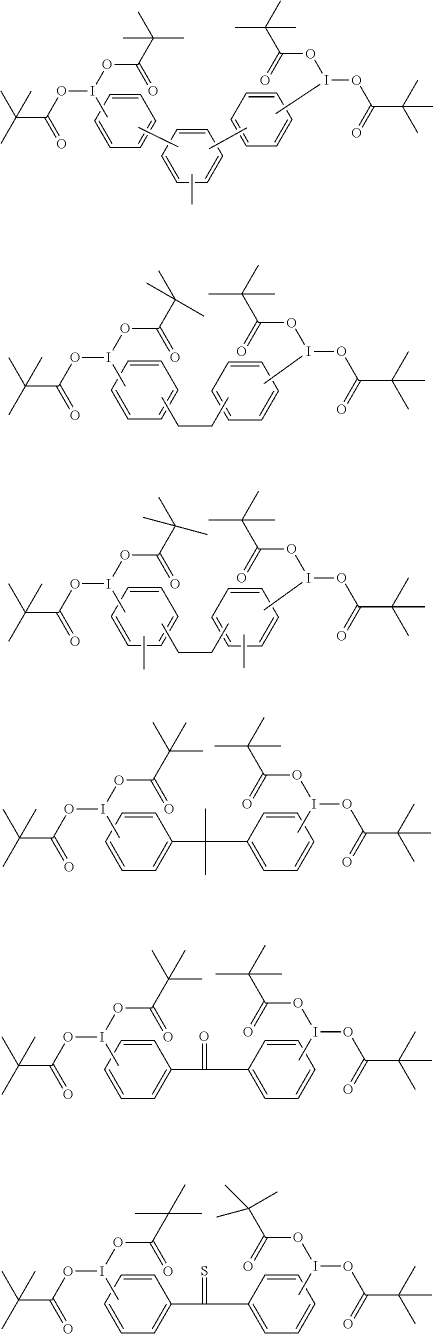

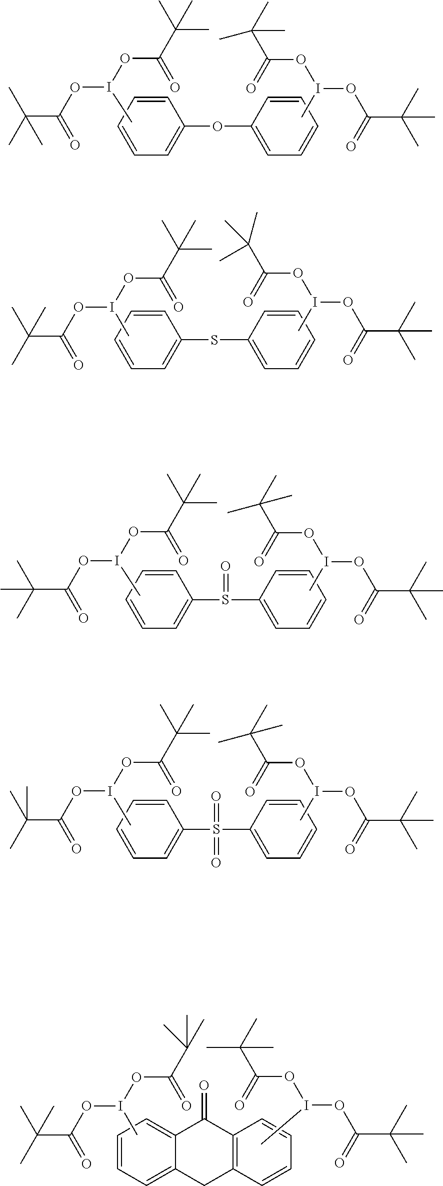

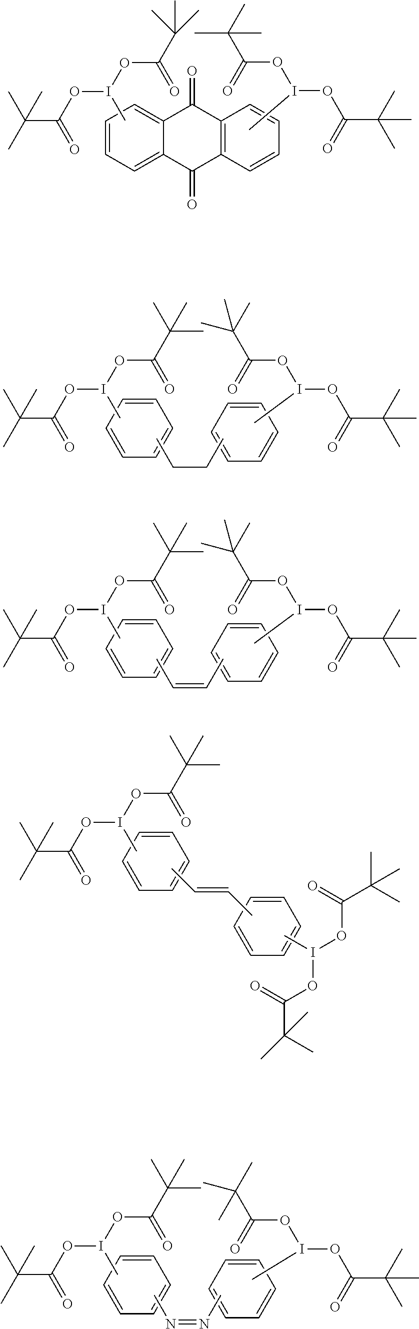

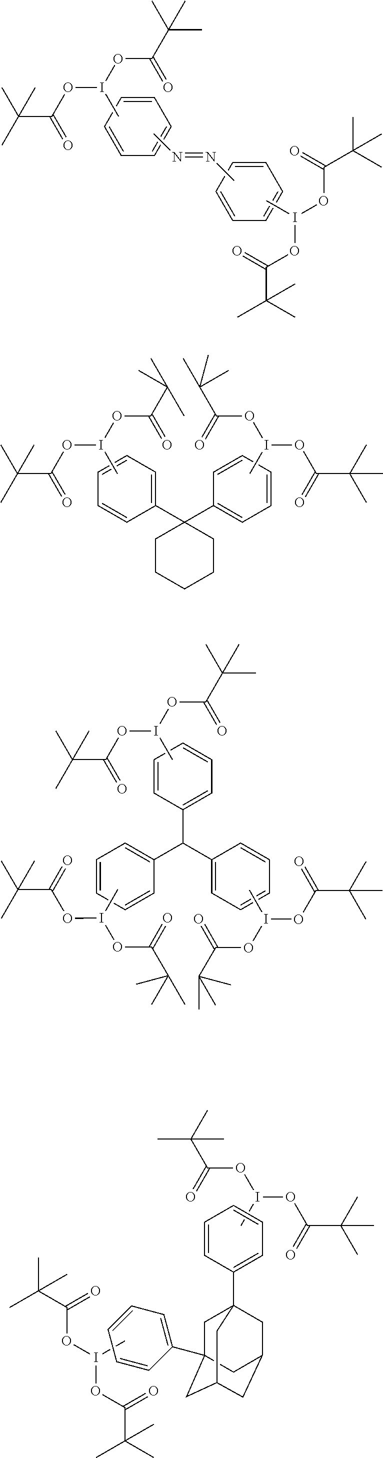

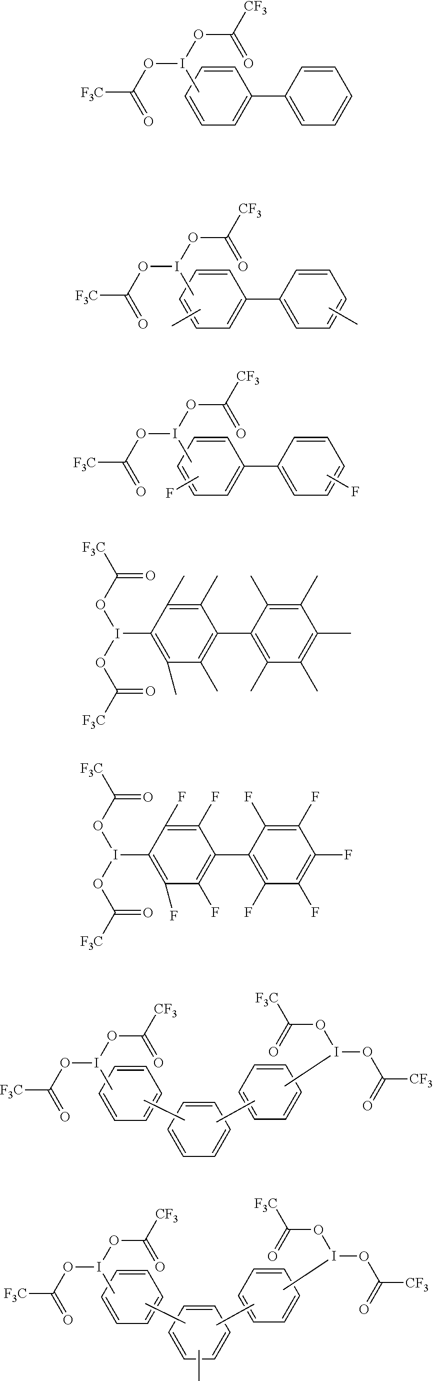

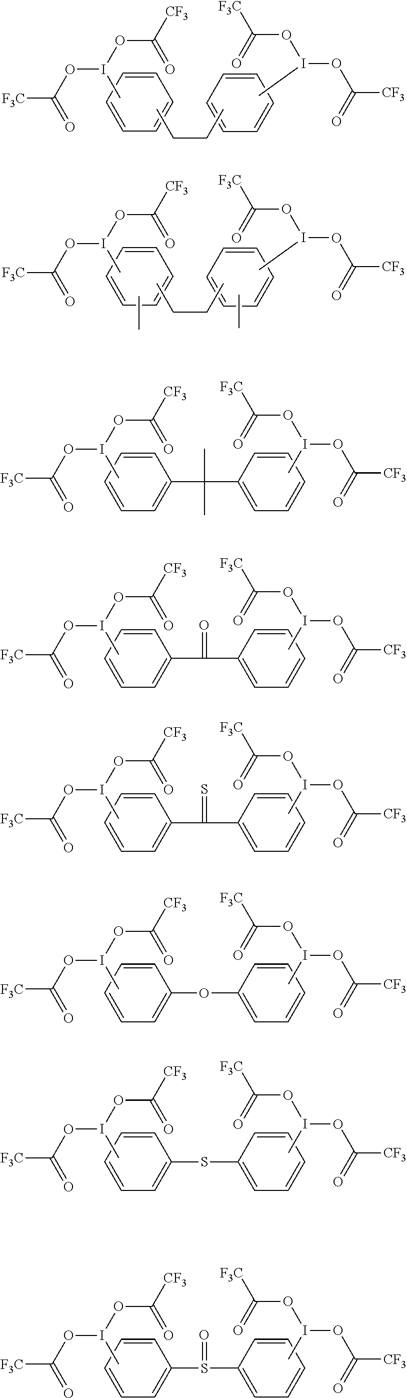

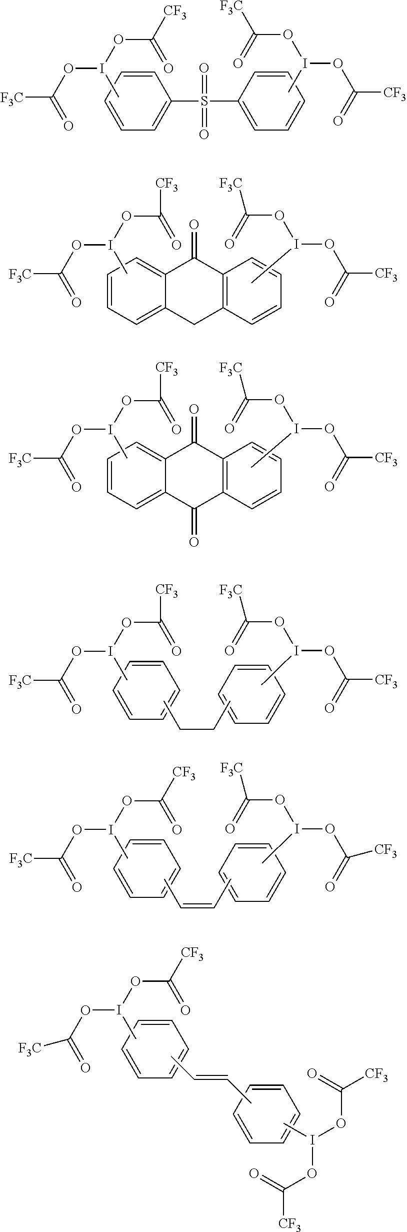

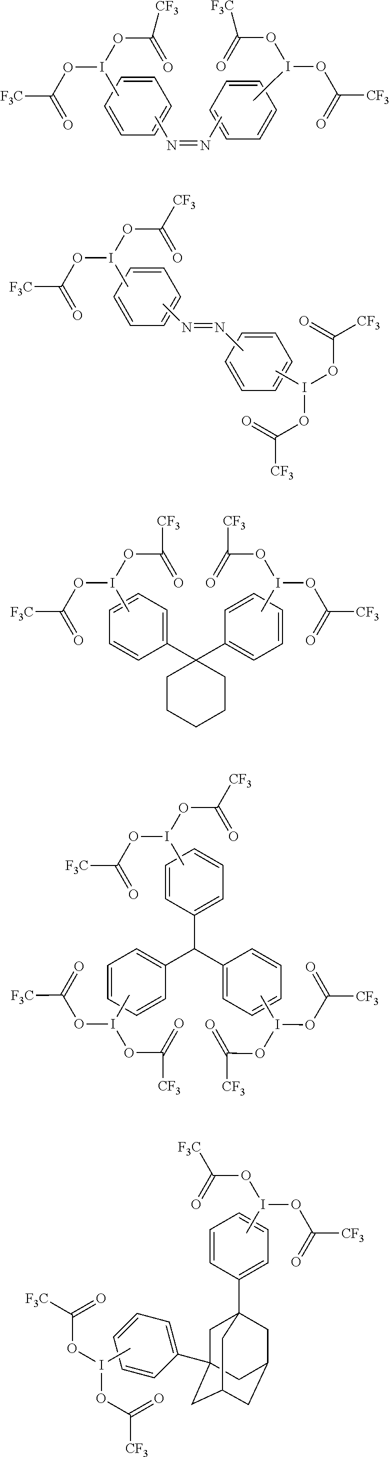

Specific examples of the hypervalent iodine compound represented by the general formula (4) include, but are not limited to, the following. In the following formulae, Me represents a methyl group.

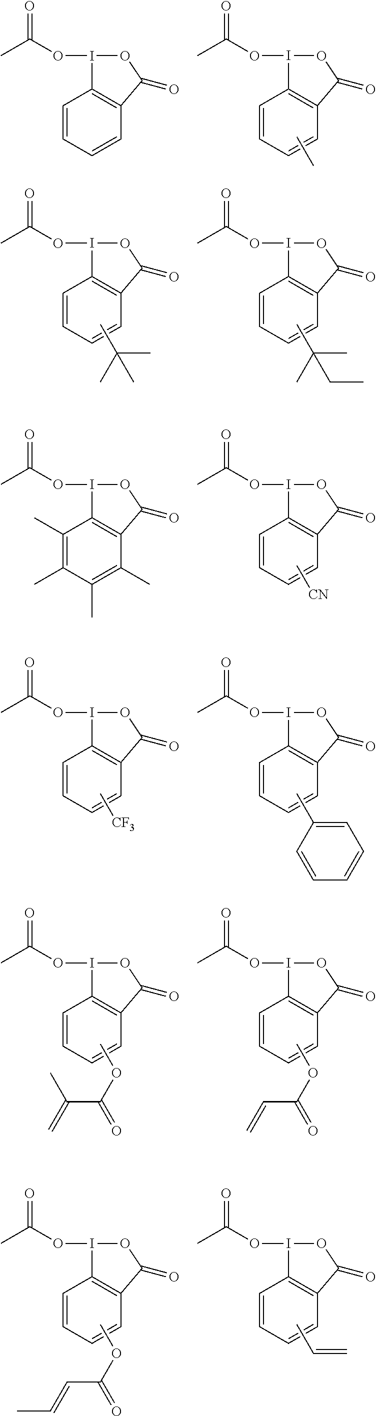

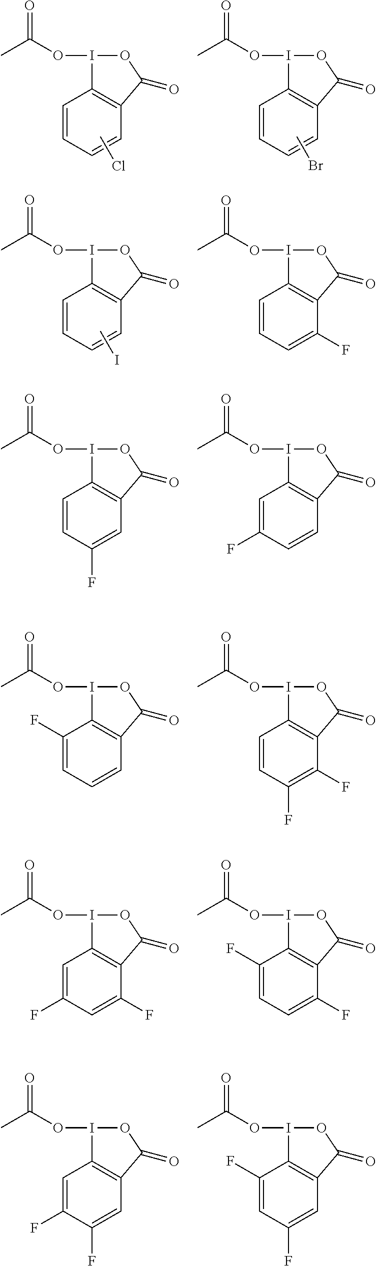

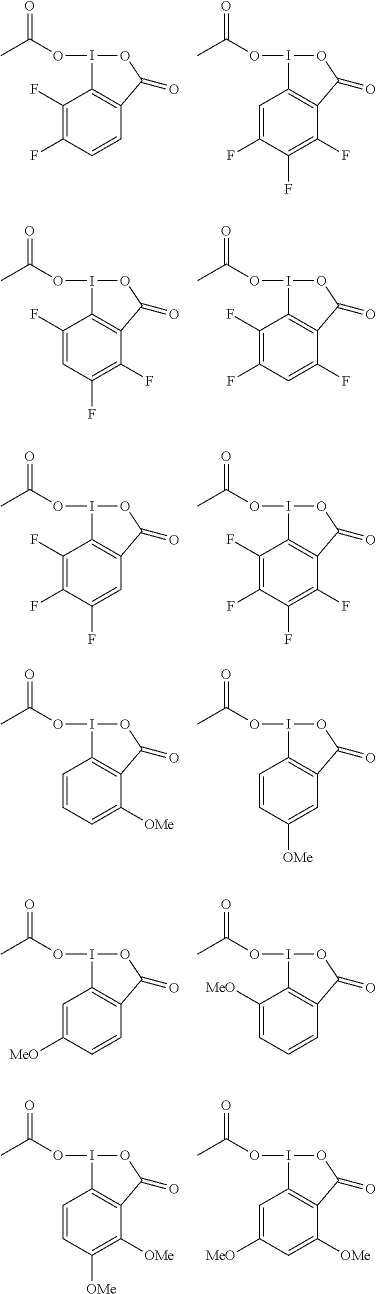

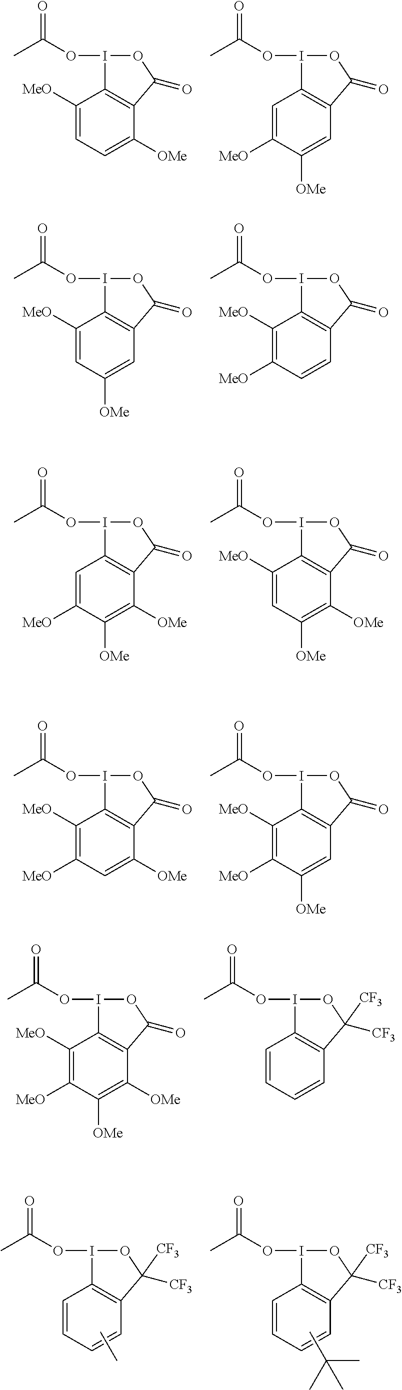

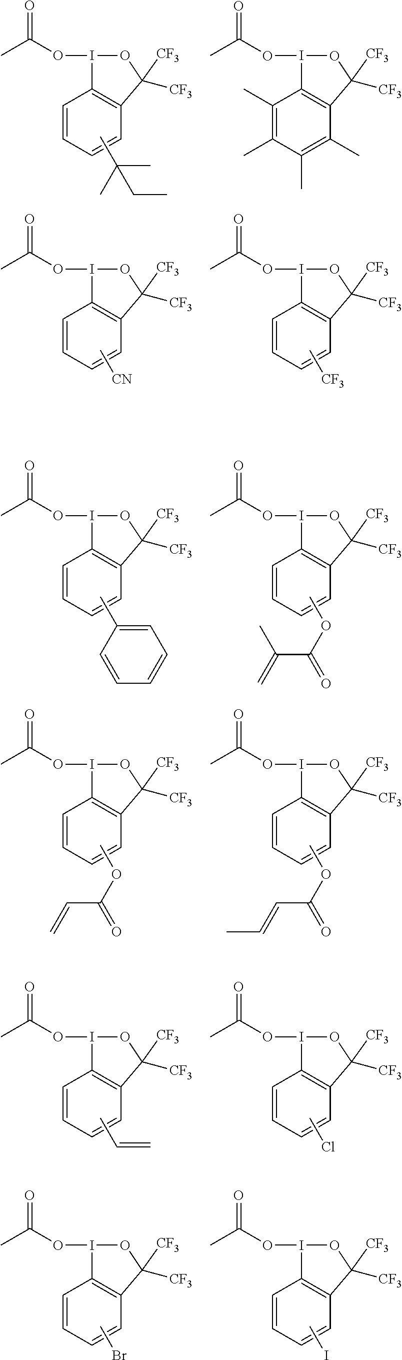

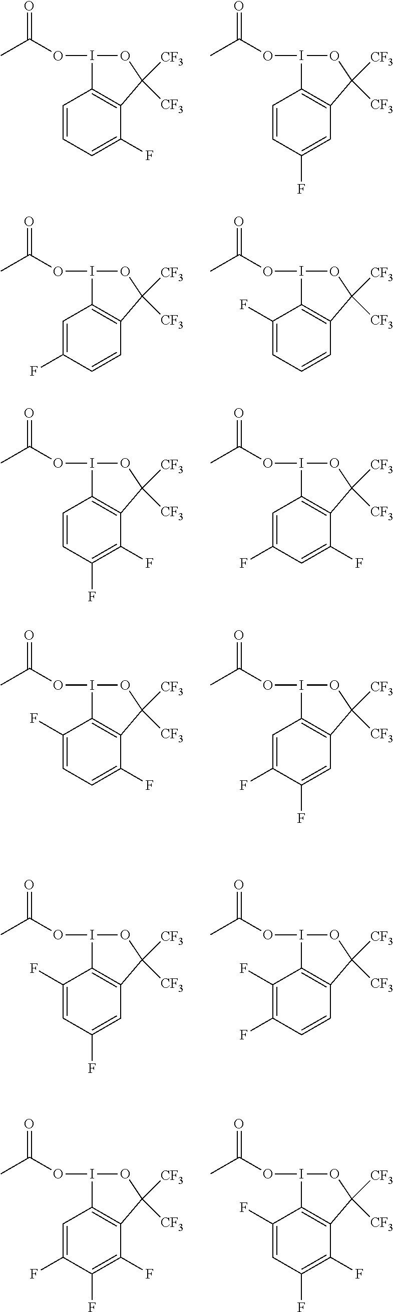

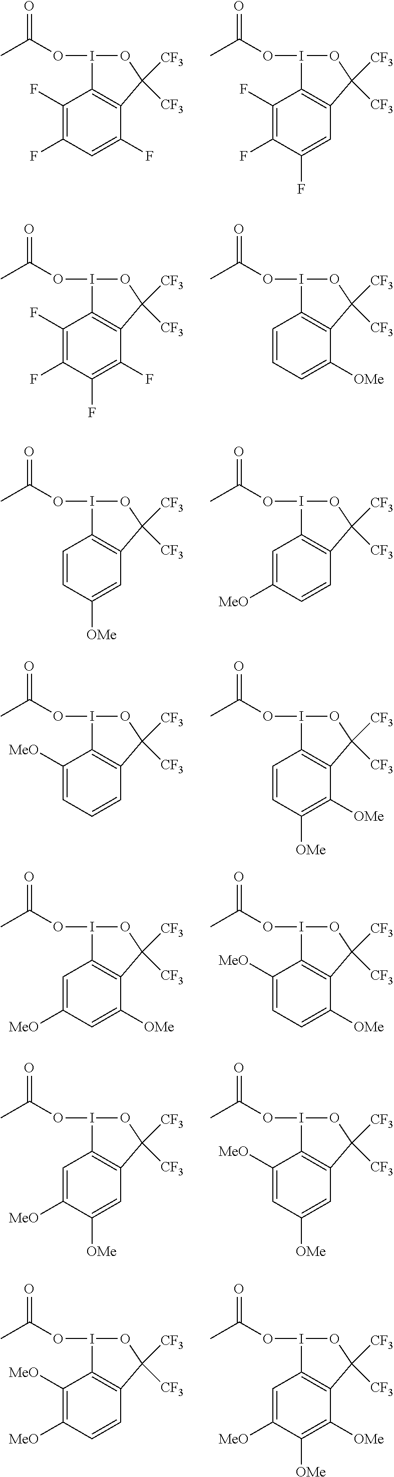

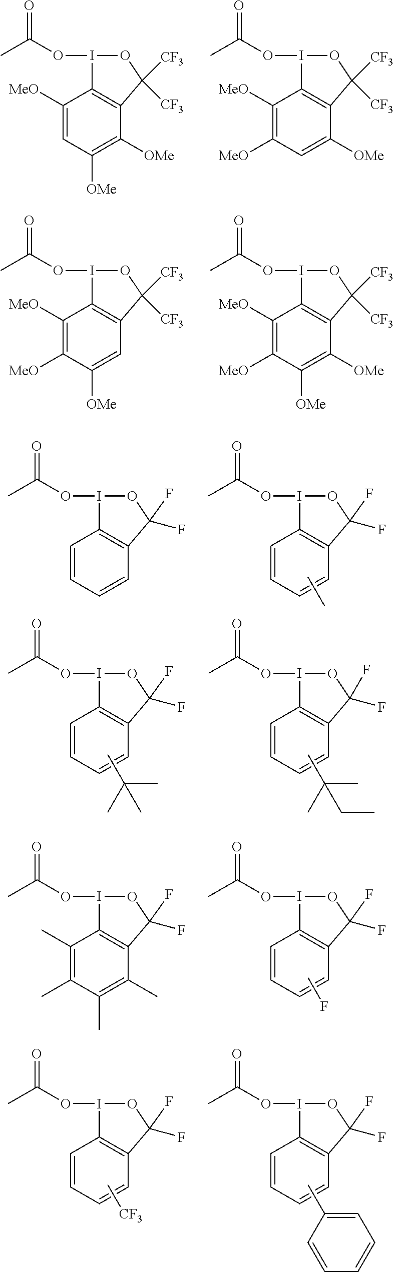

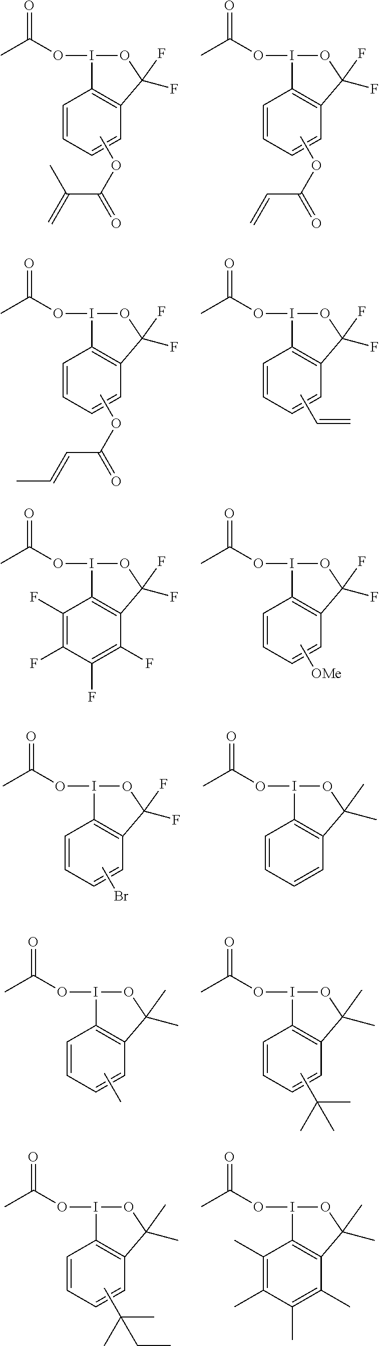

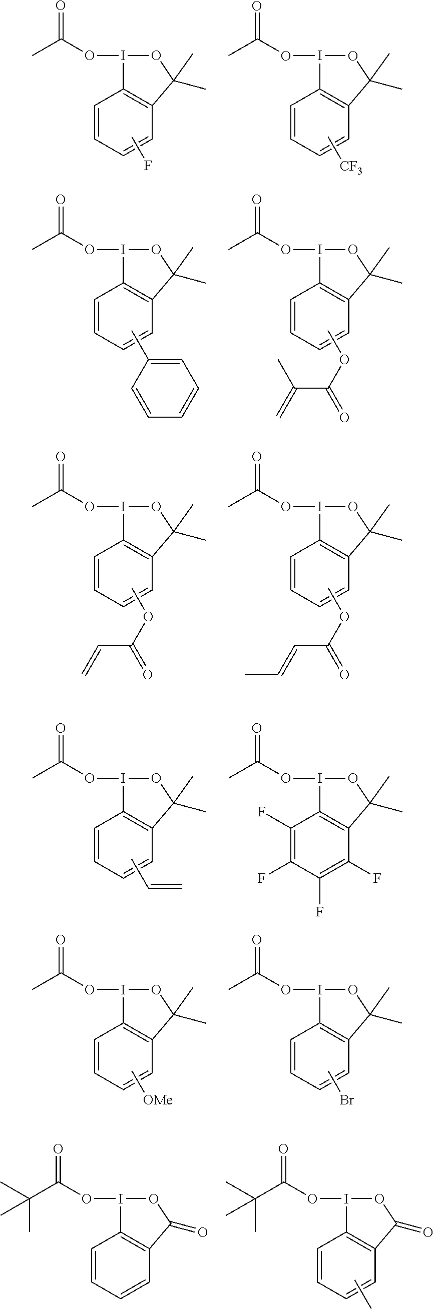

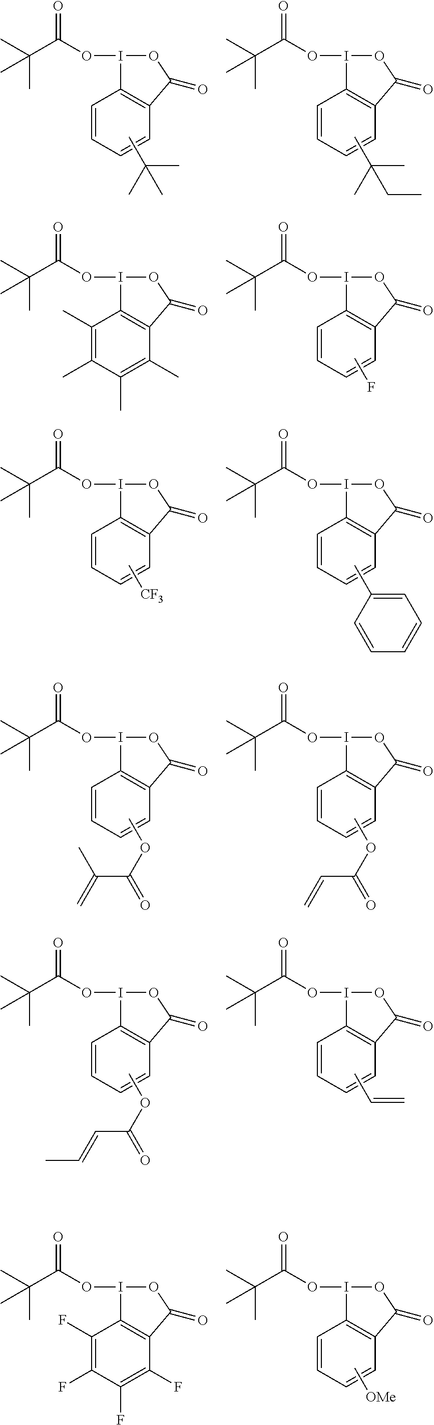

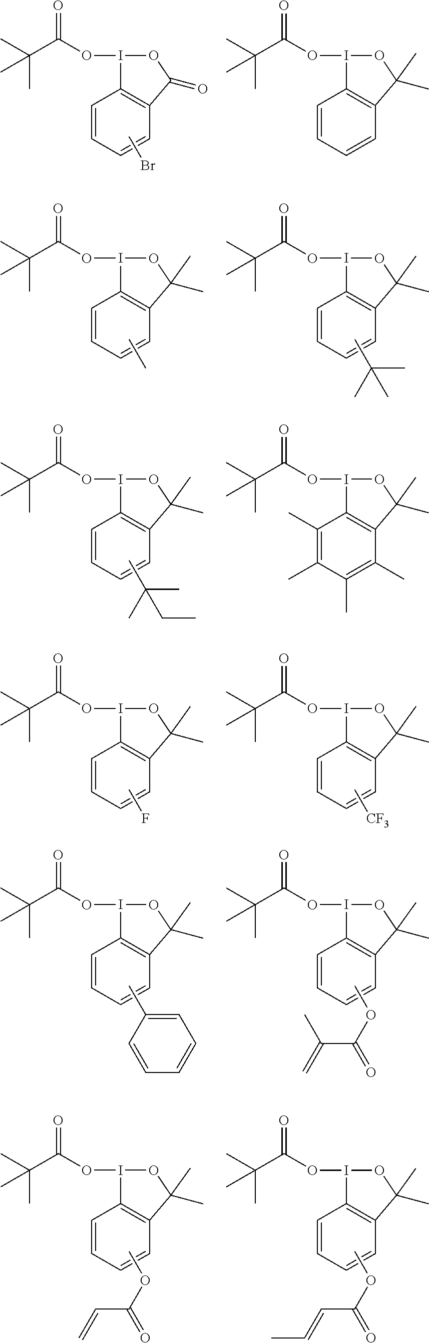

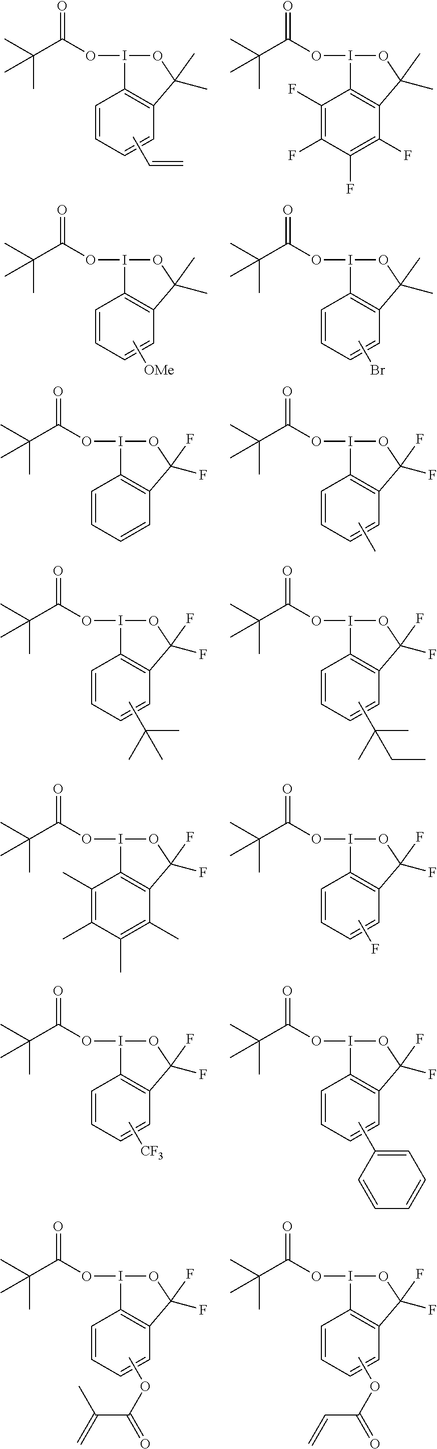

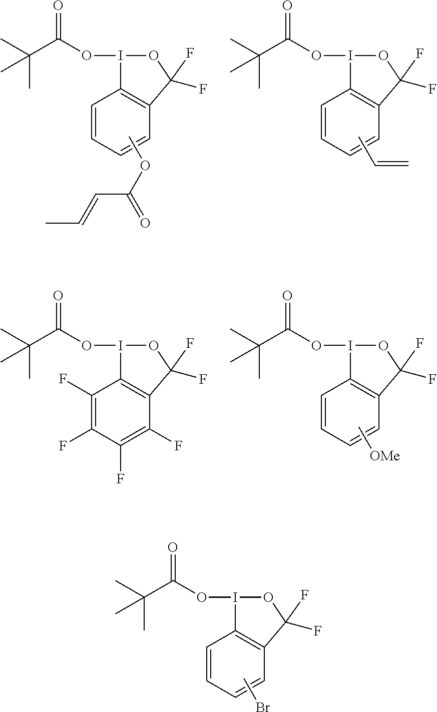

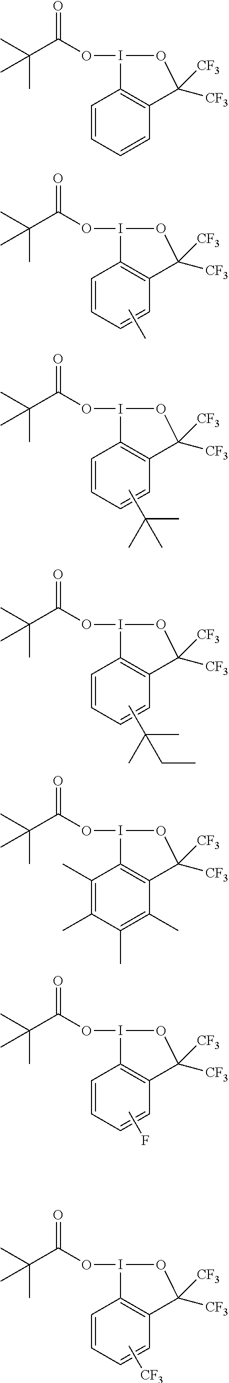

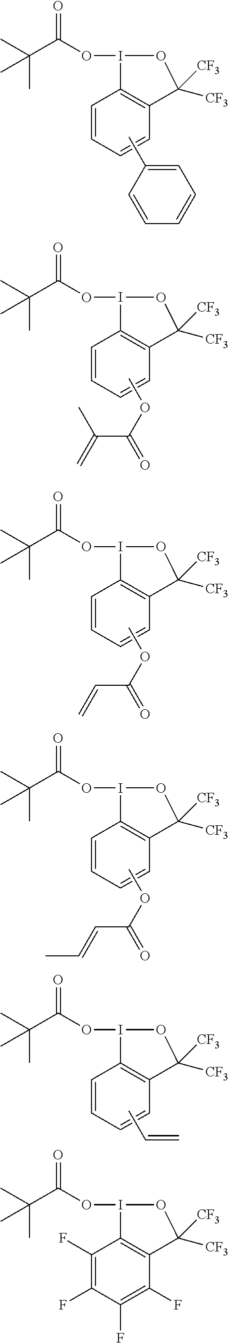

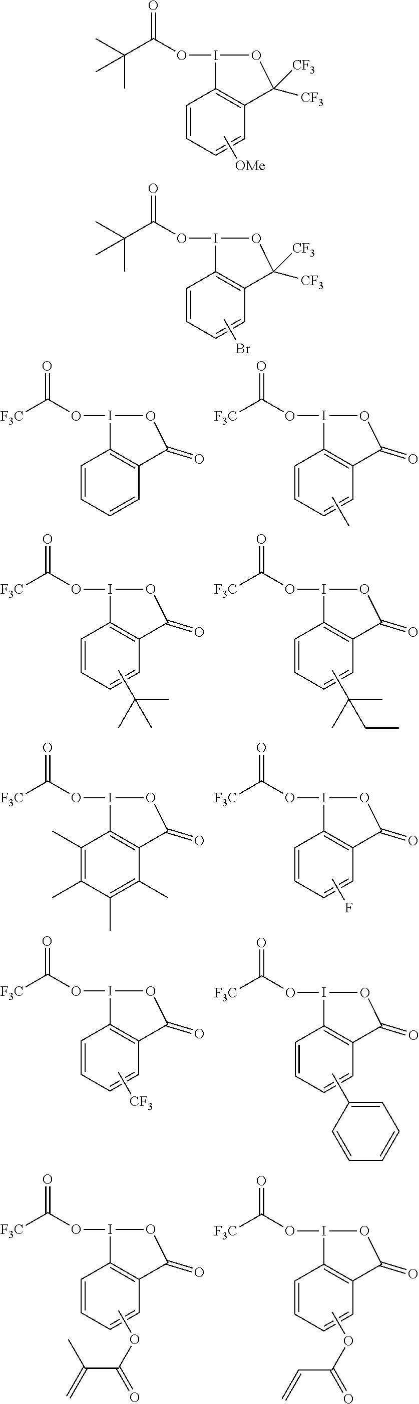

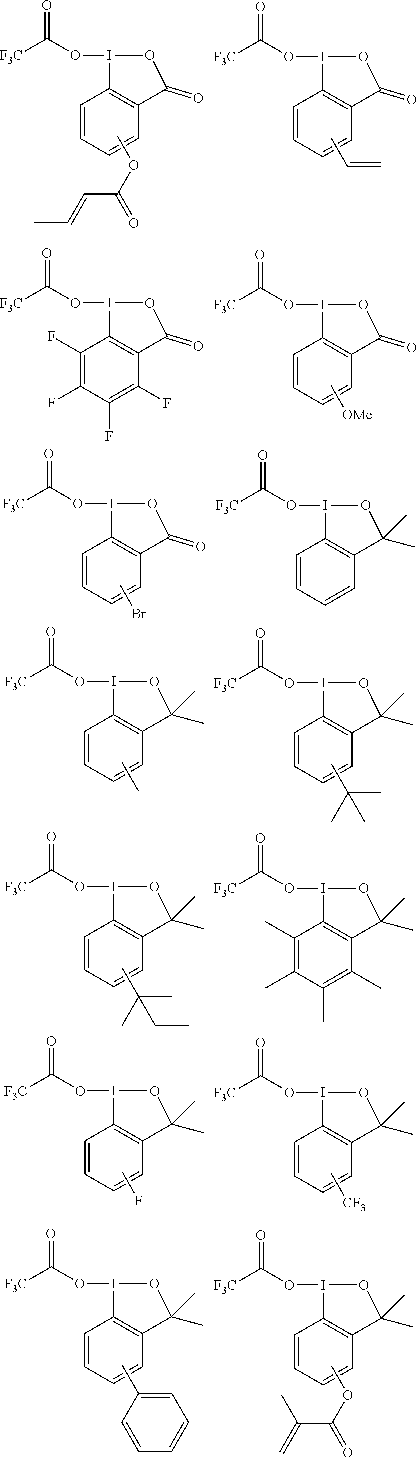

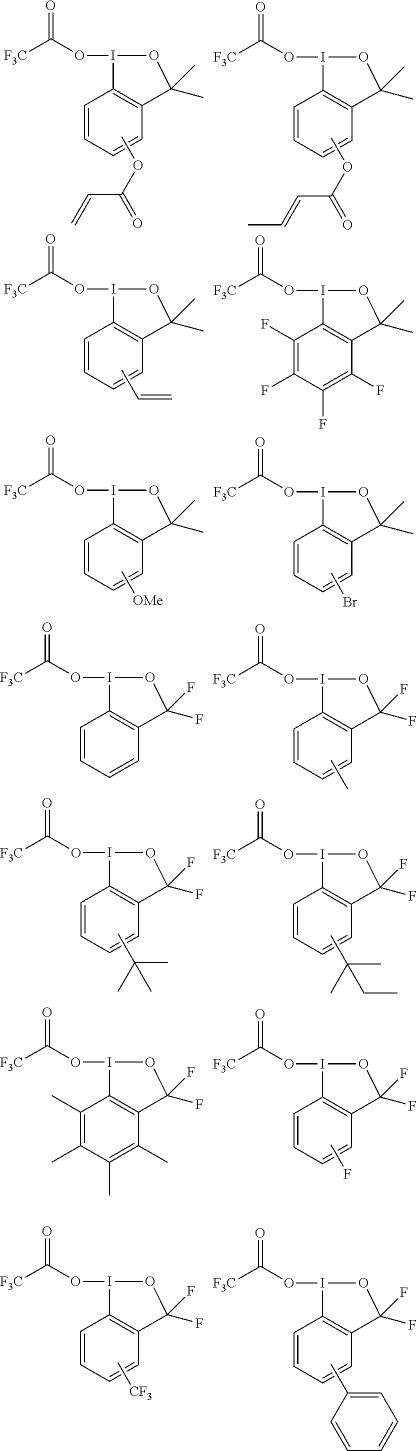

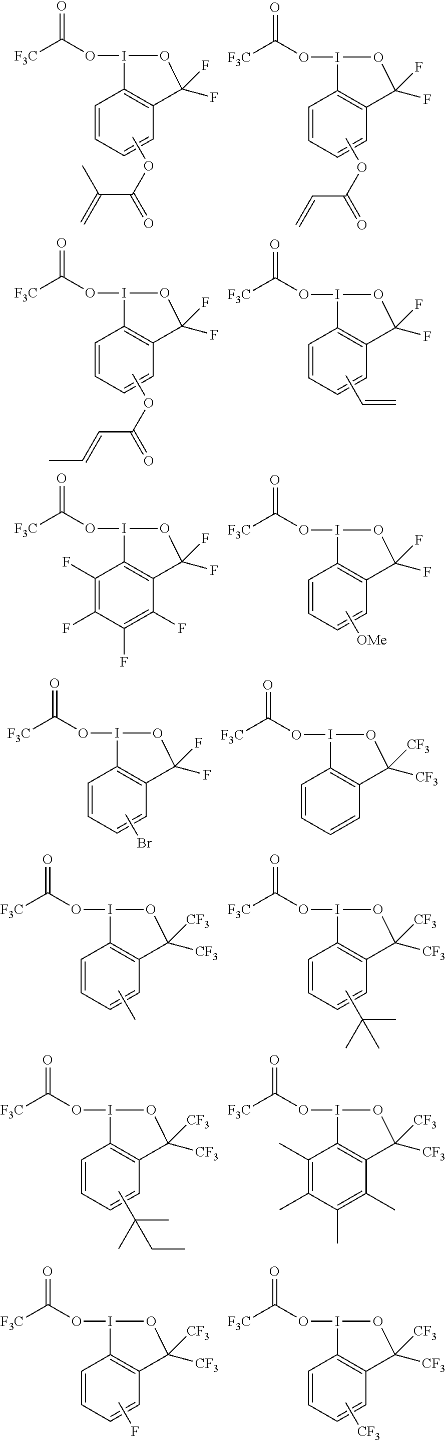

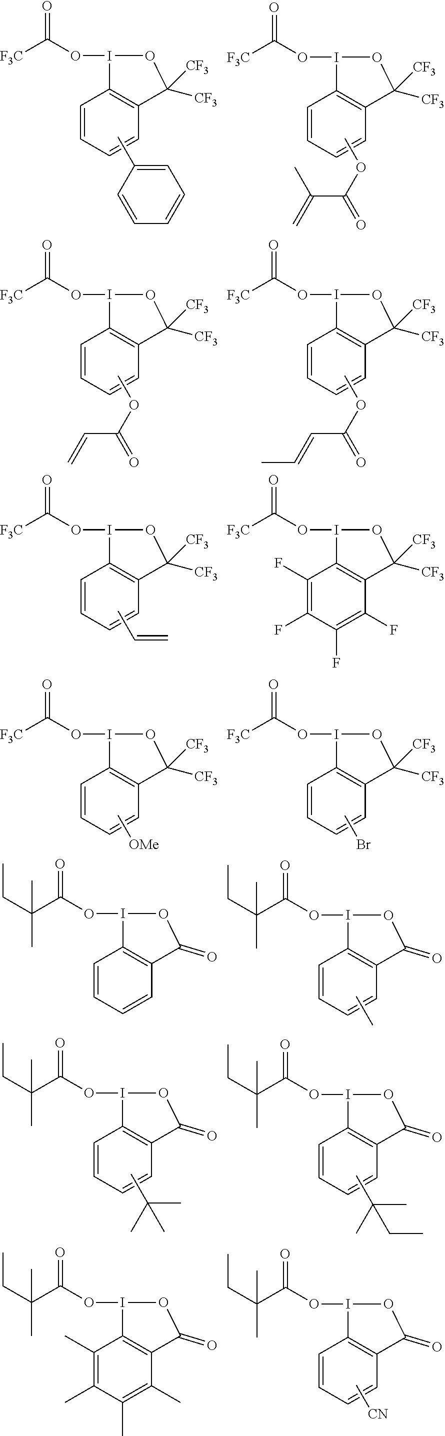

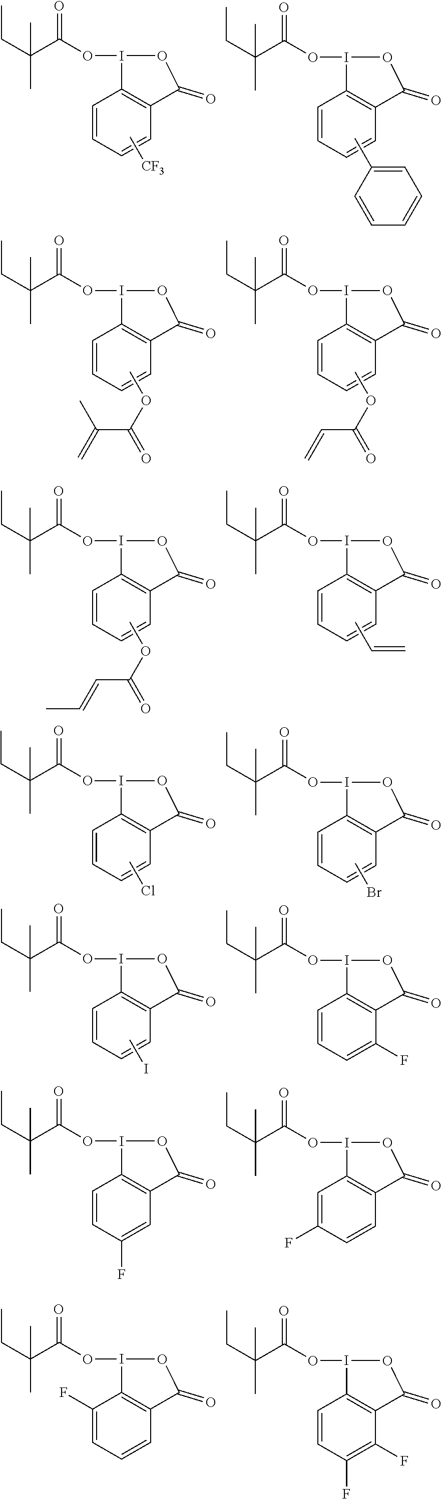

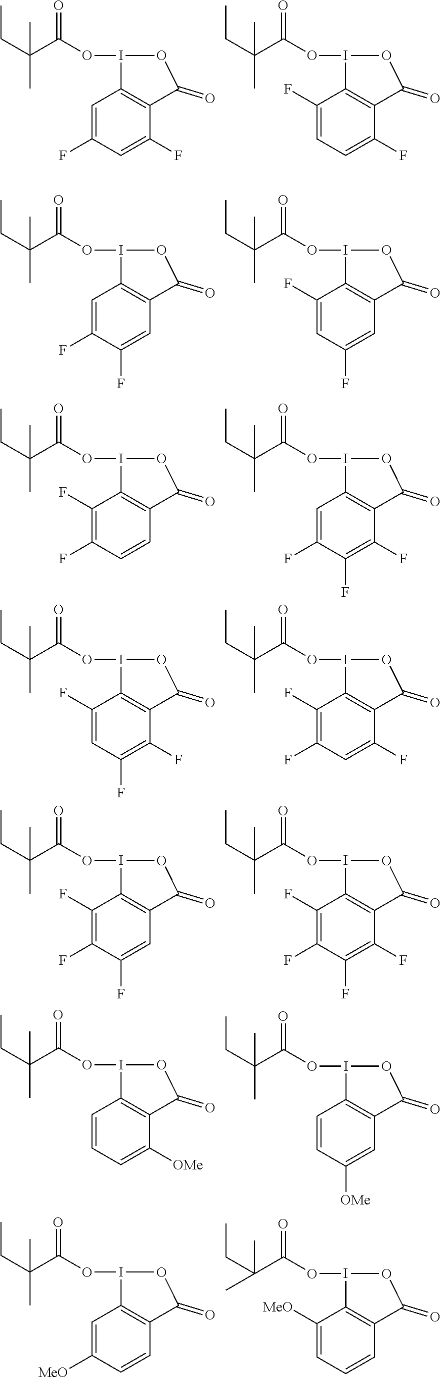

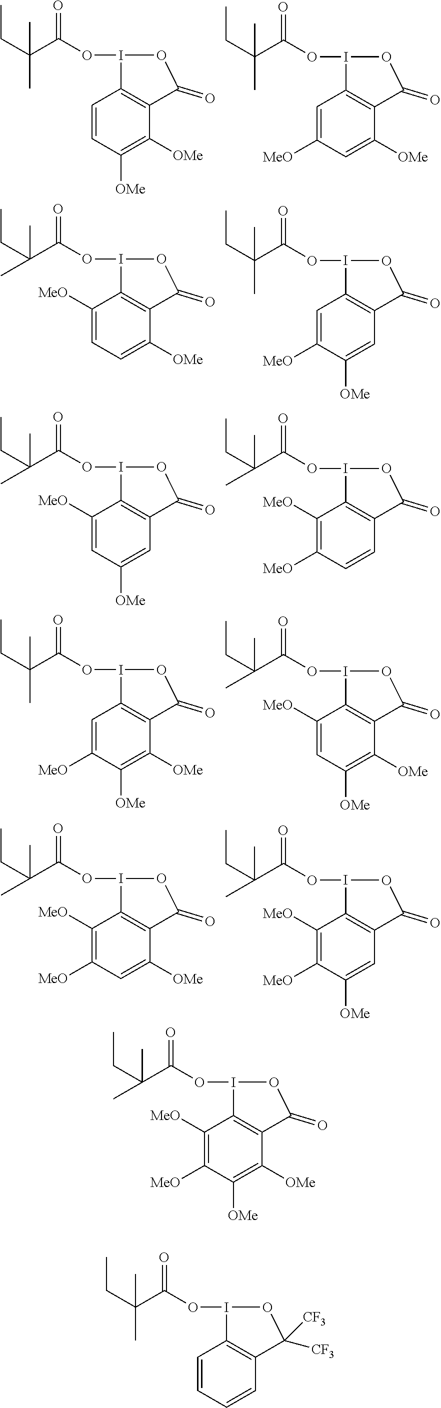

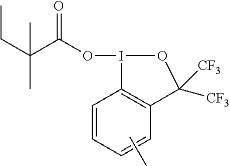

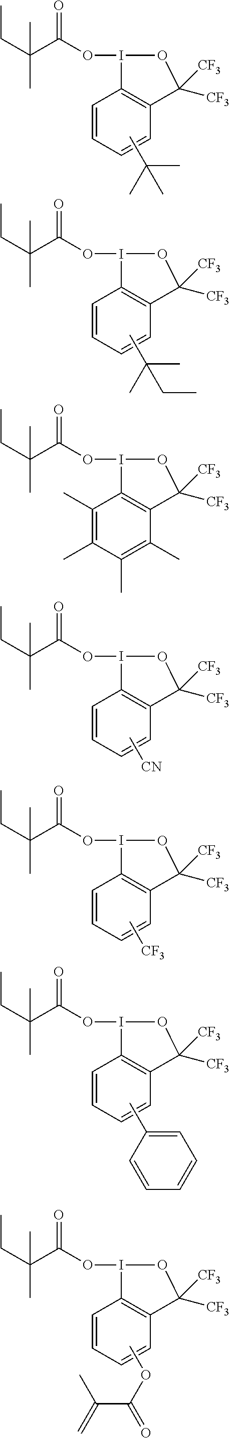

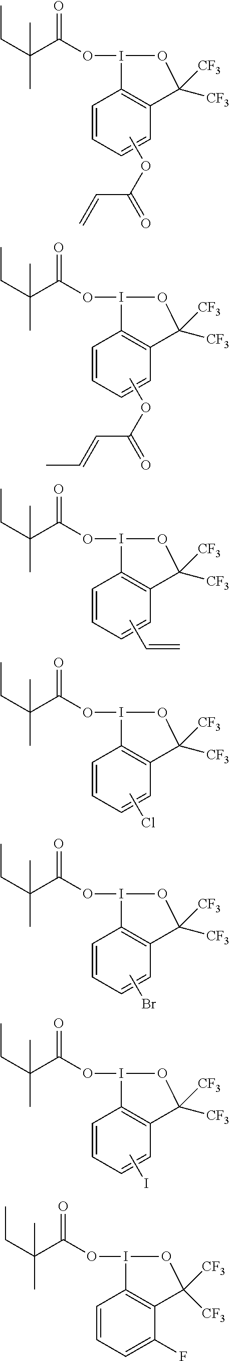

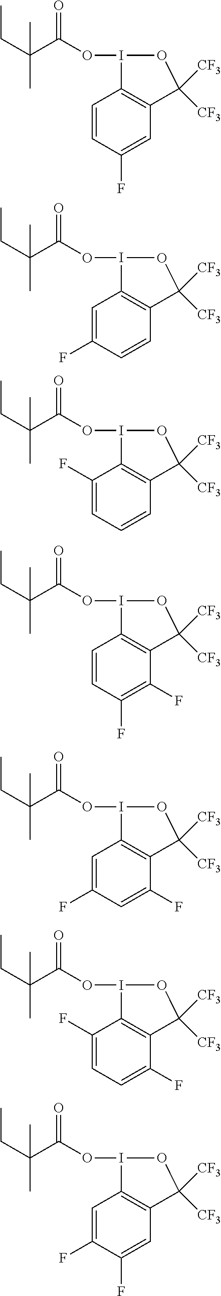

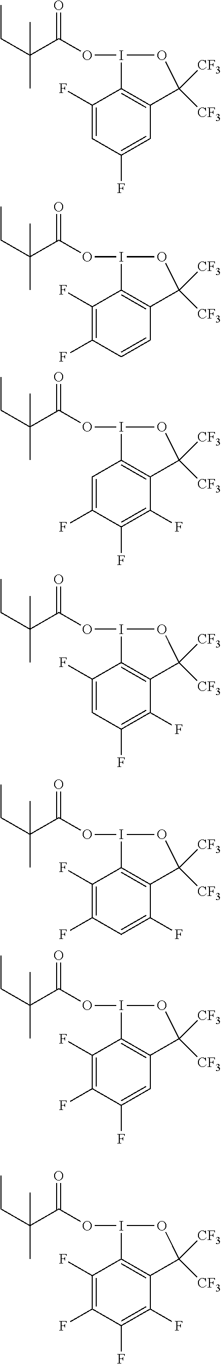

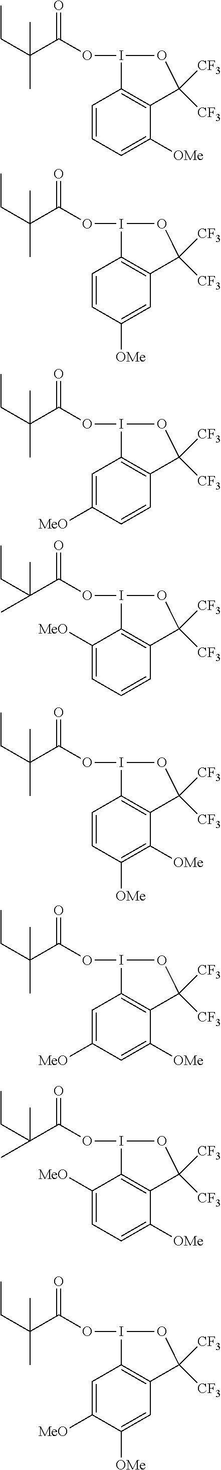

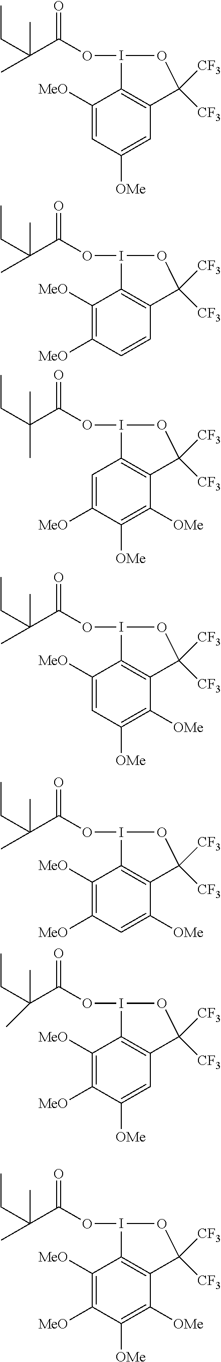

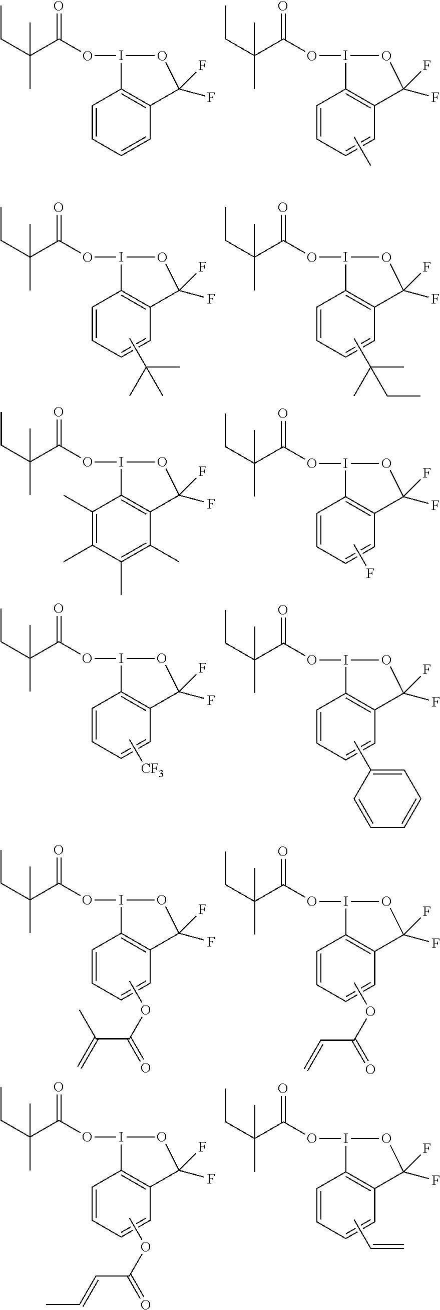

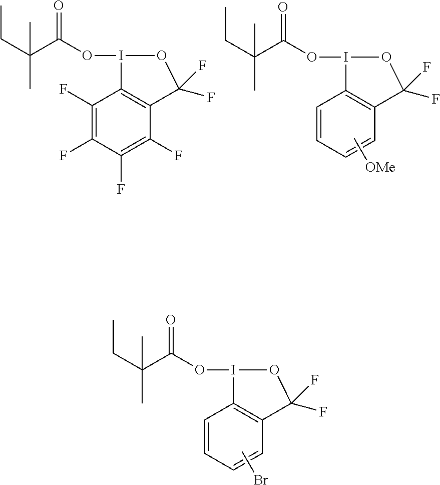

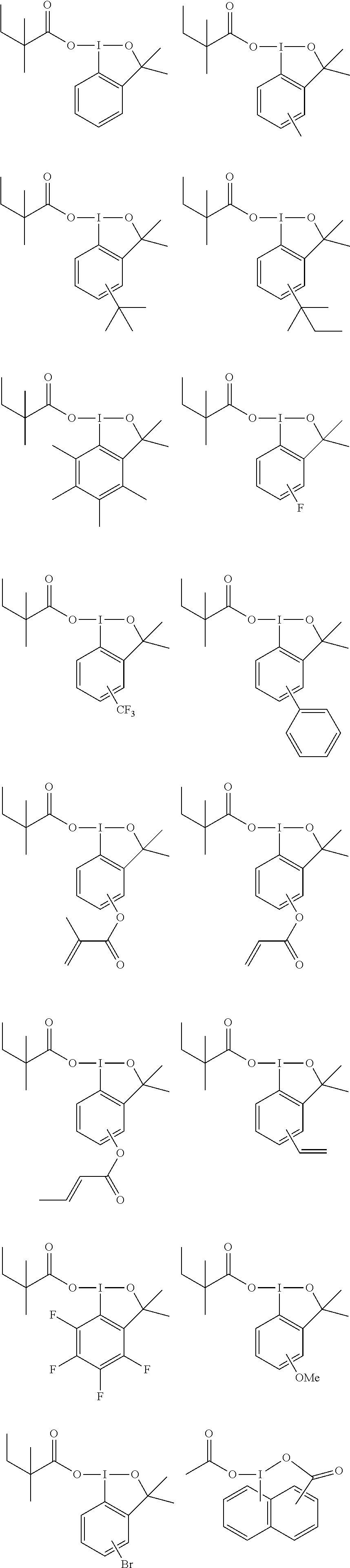

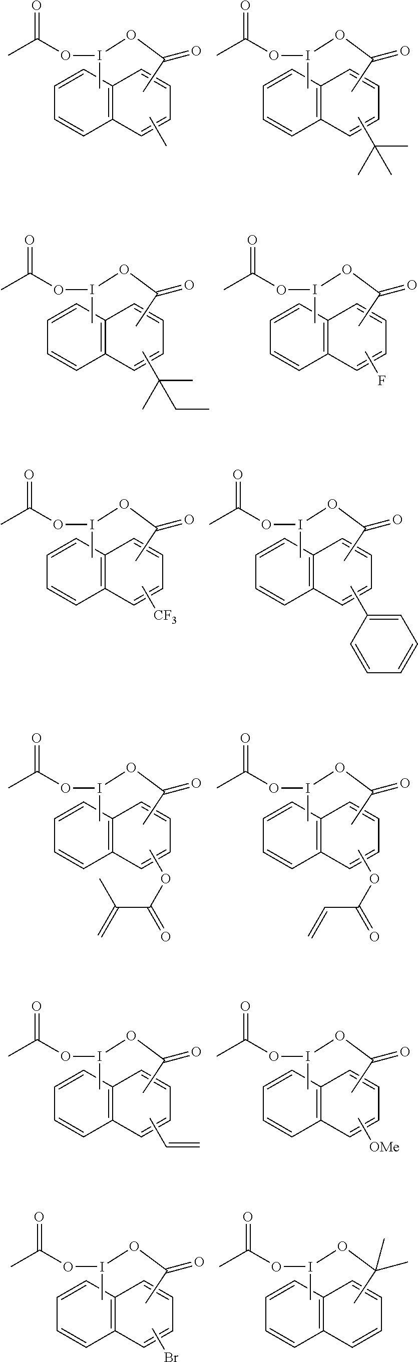

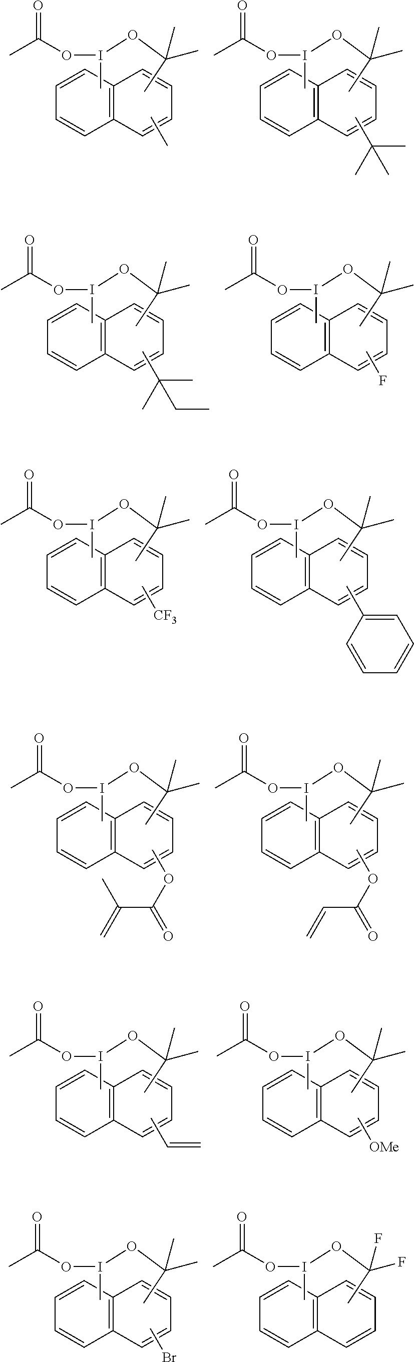

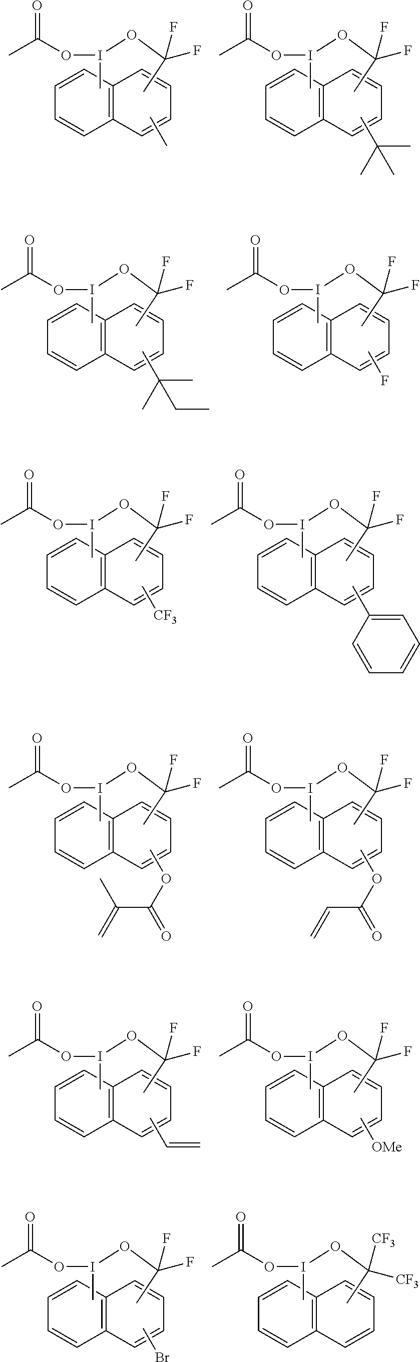

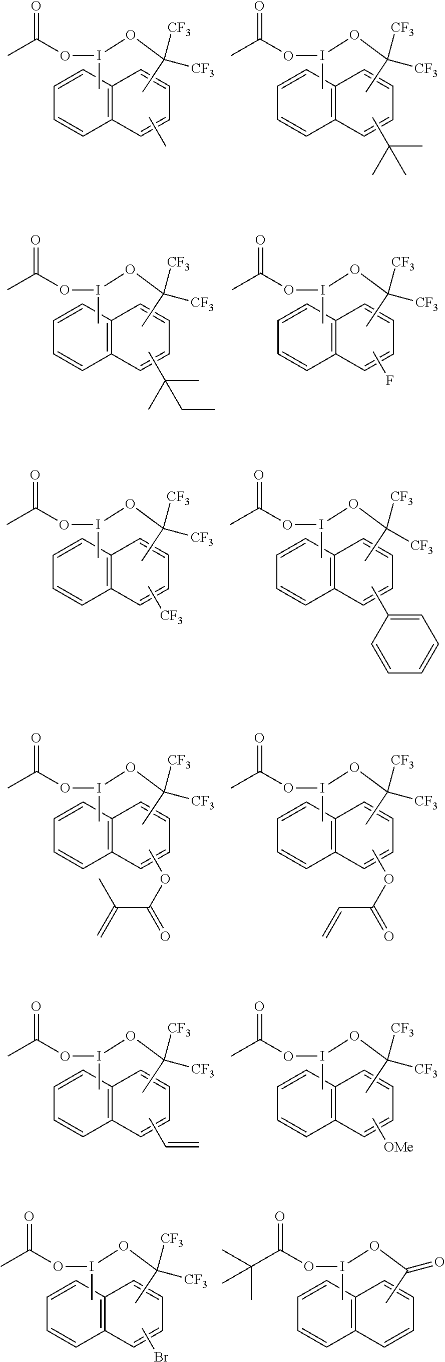

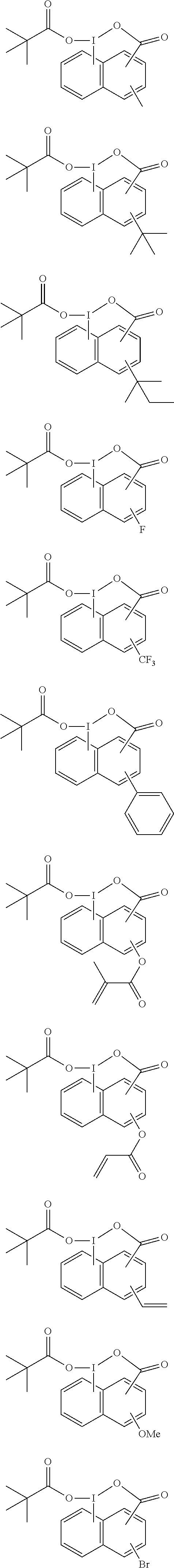

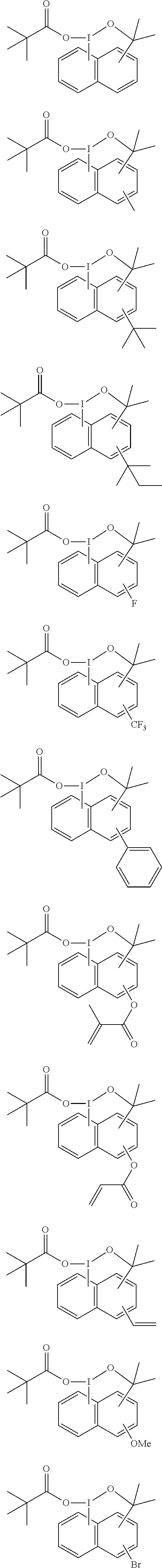

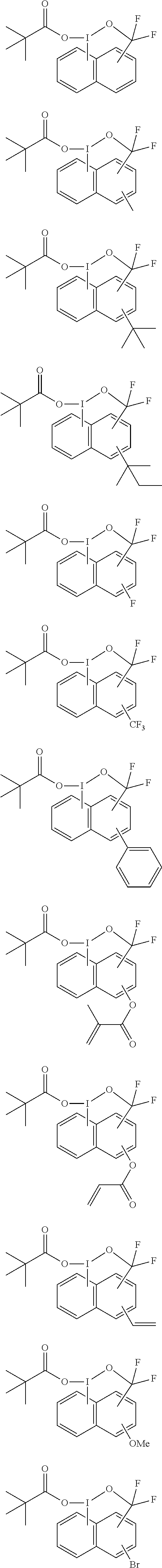

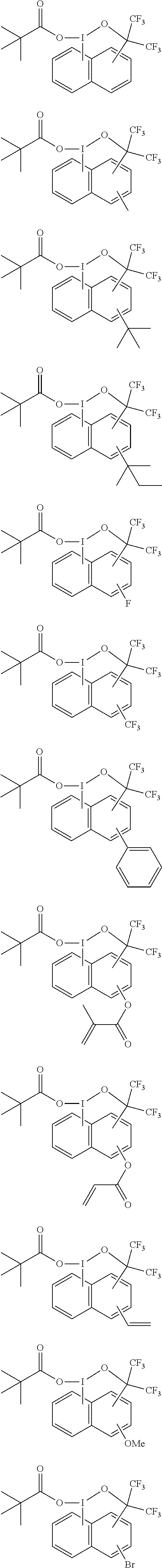

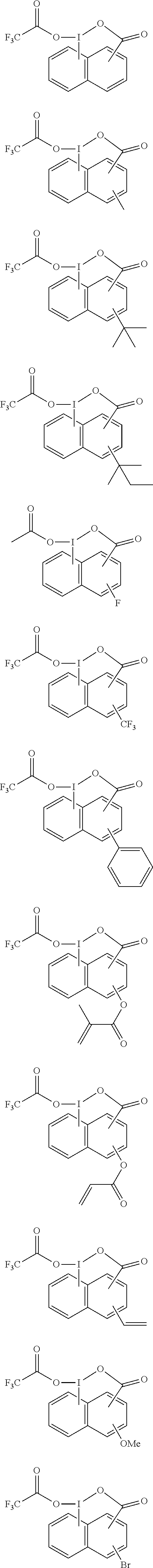

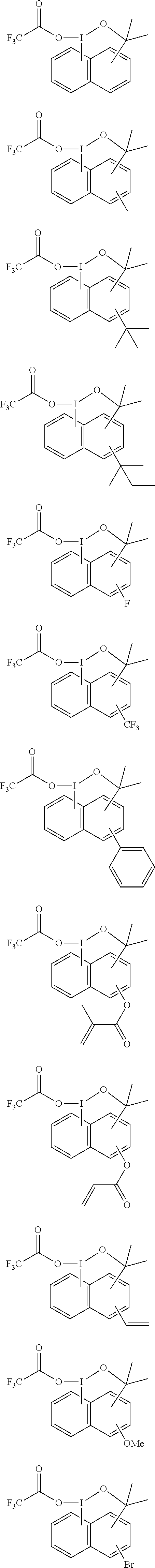

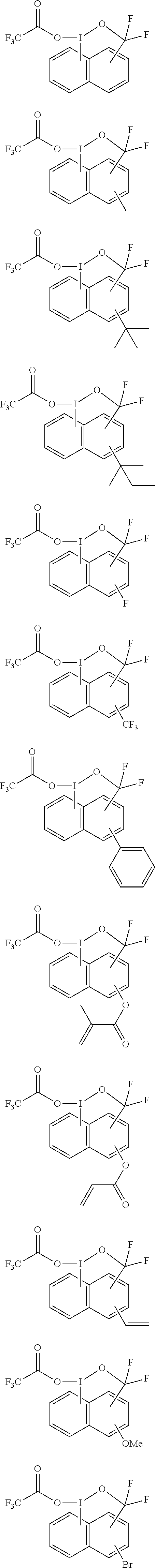

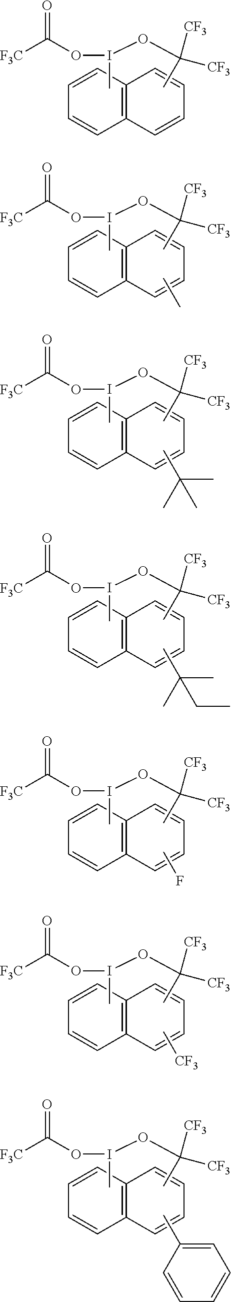

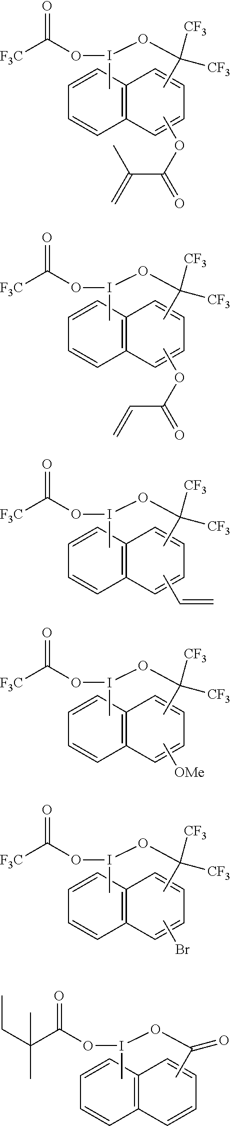

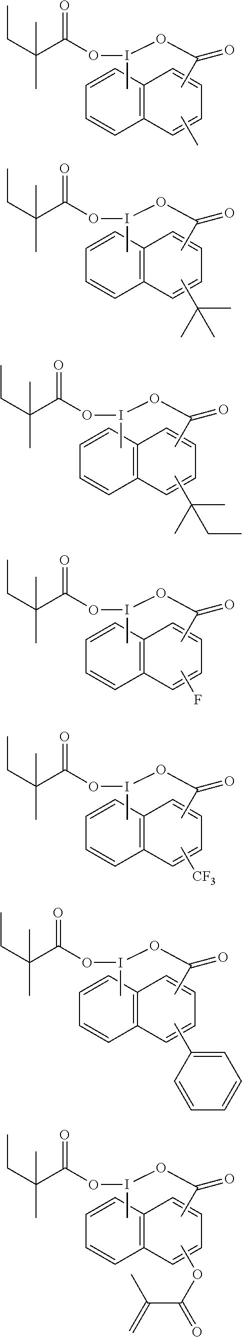

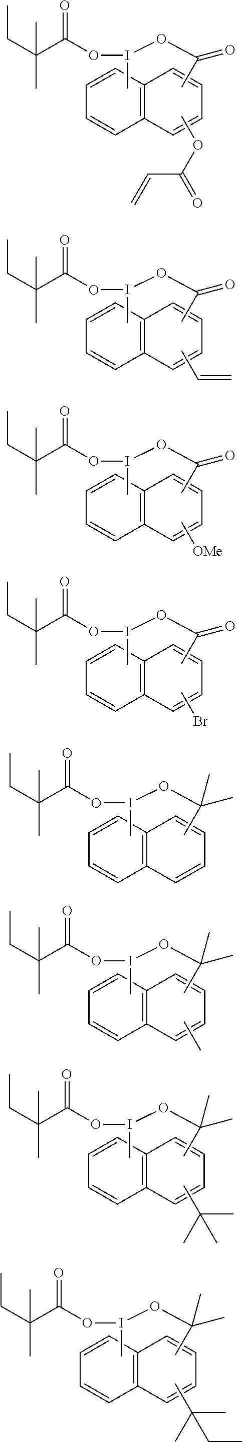

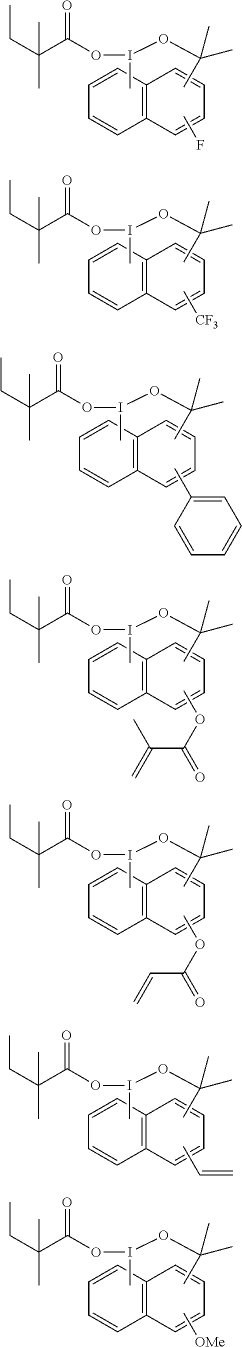

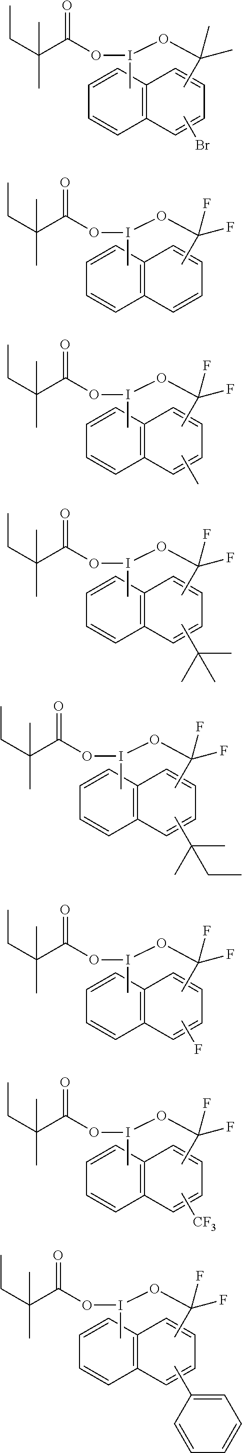

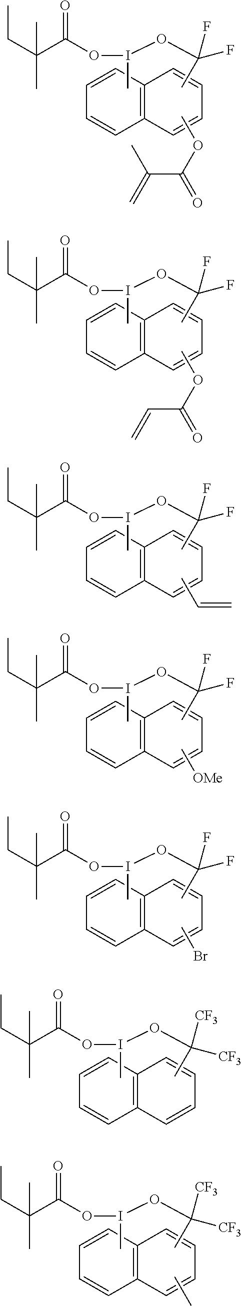

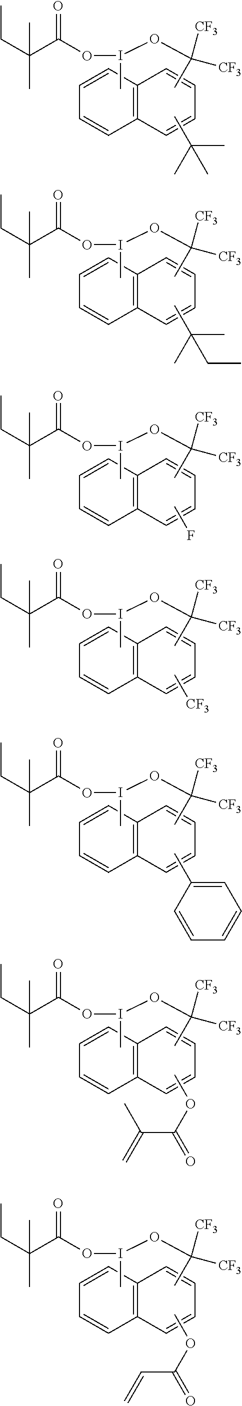

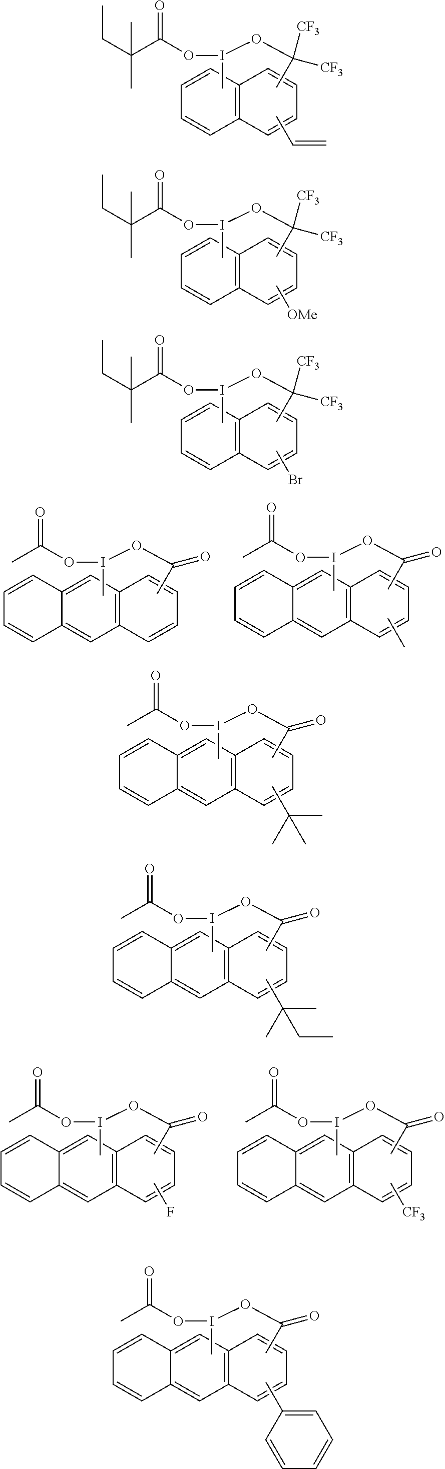

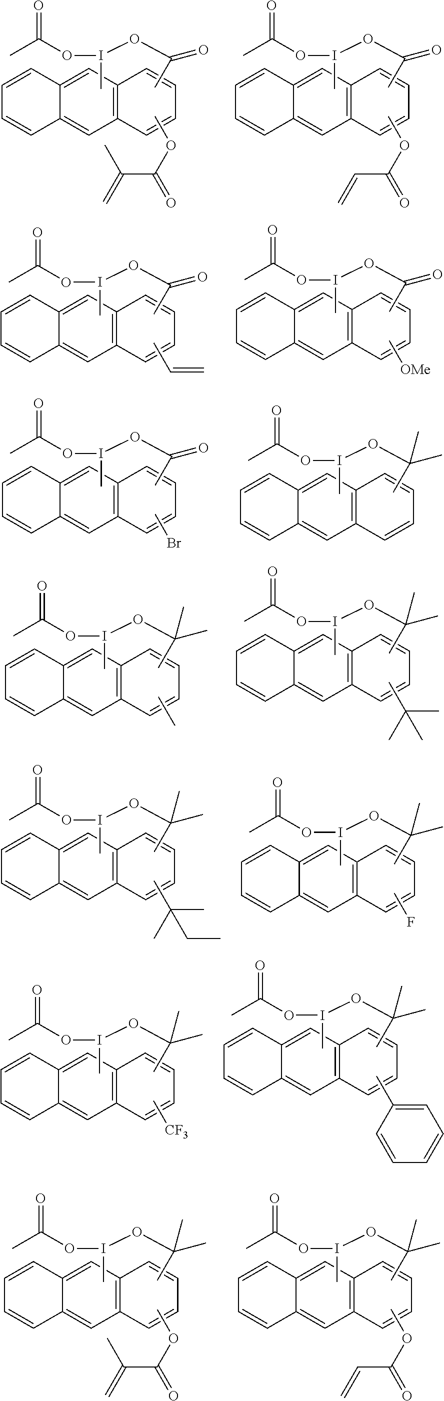

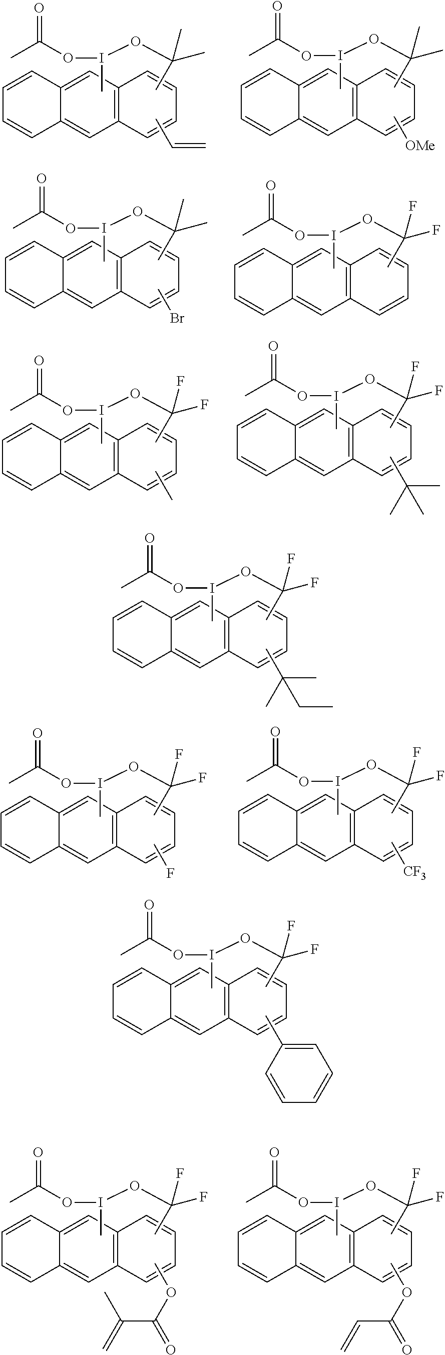

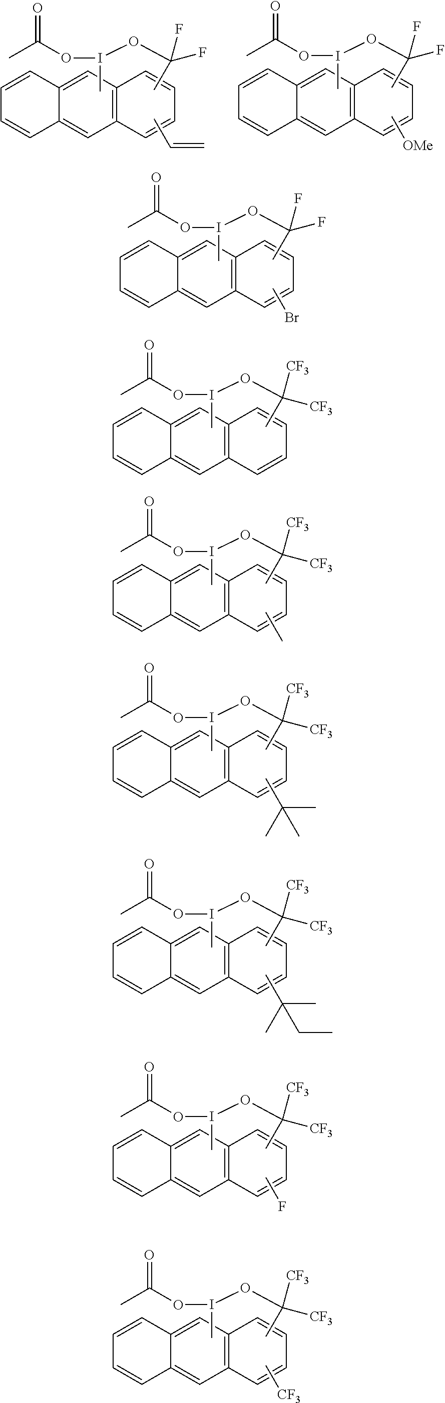

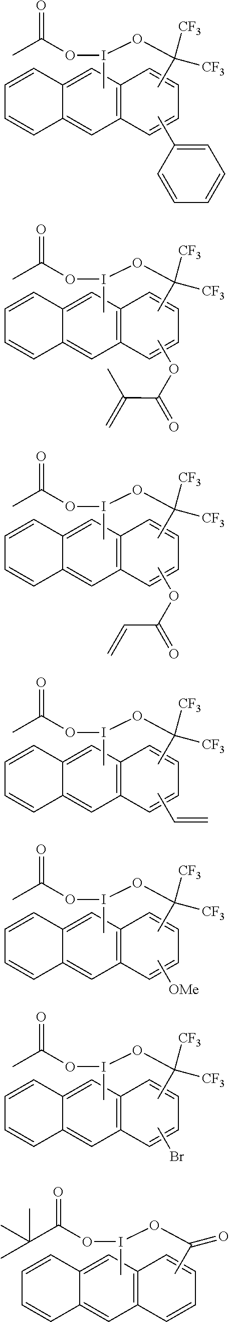

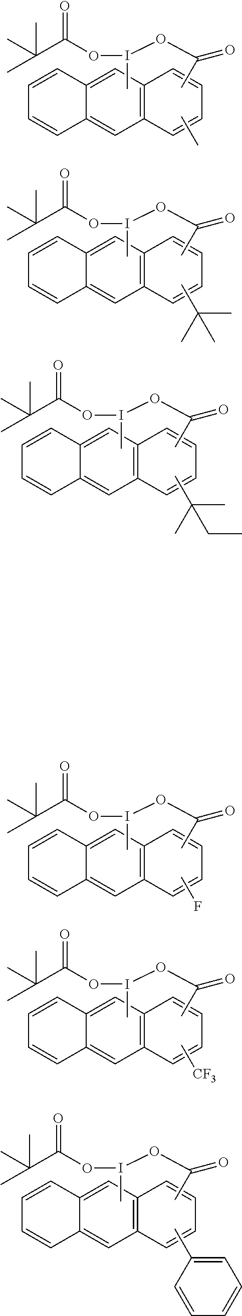

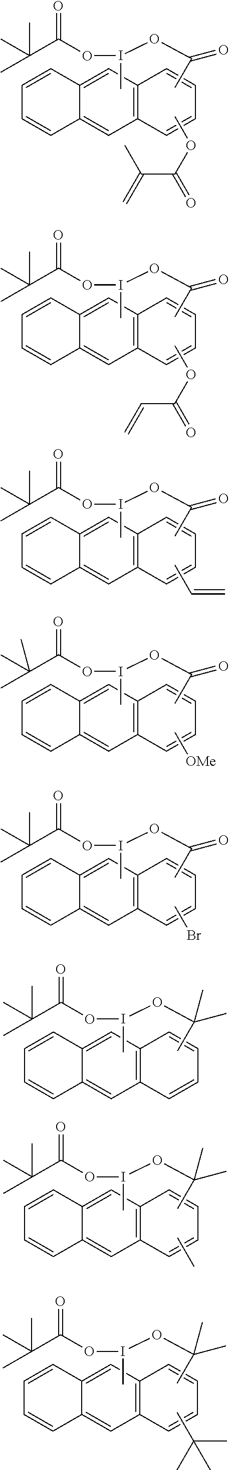

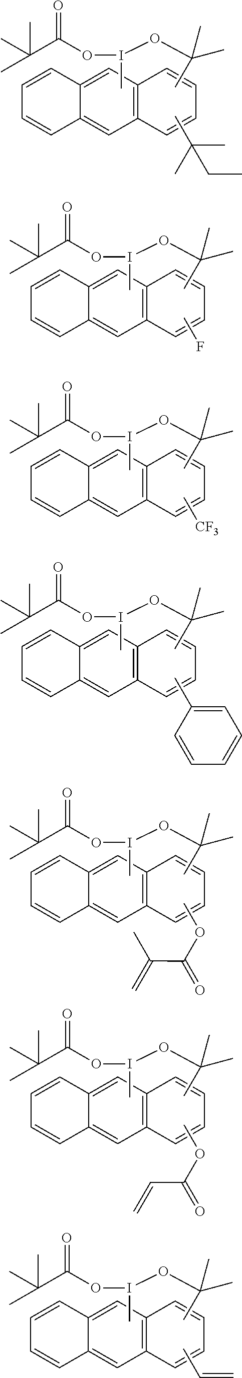

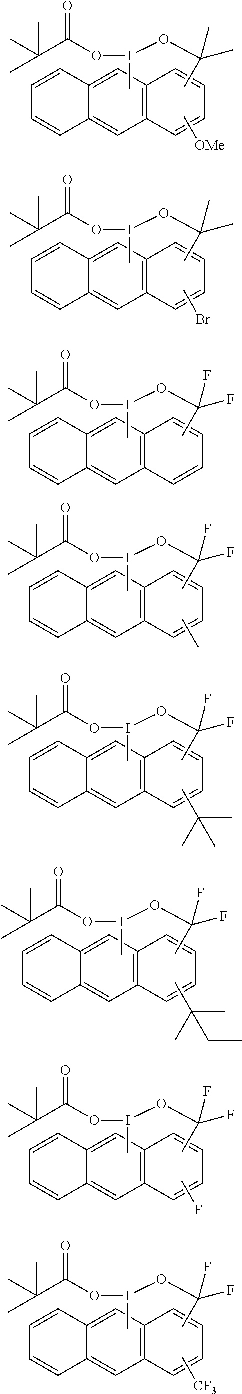

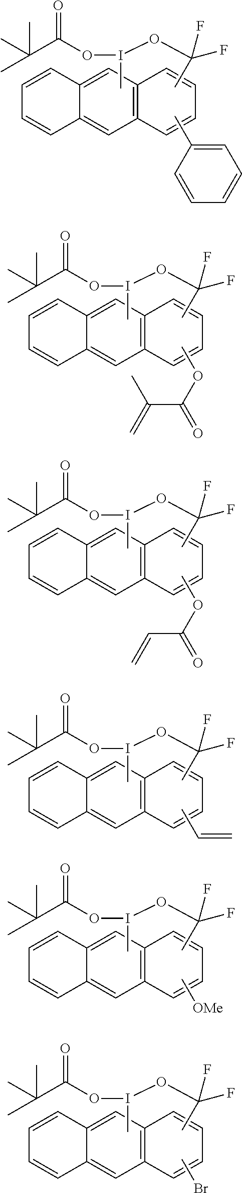

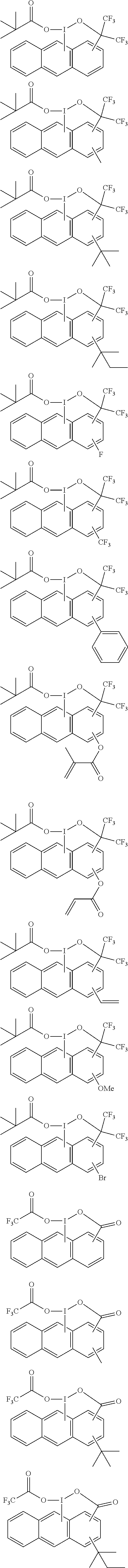

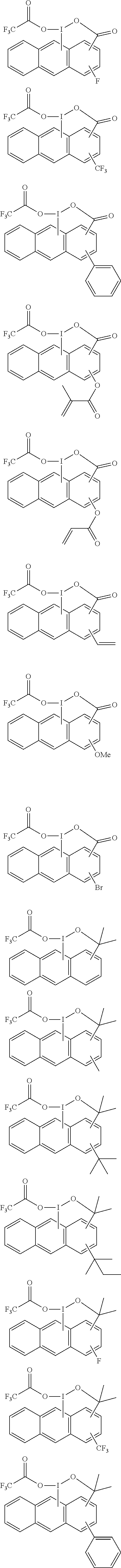

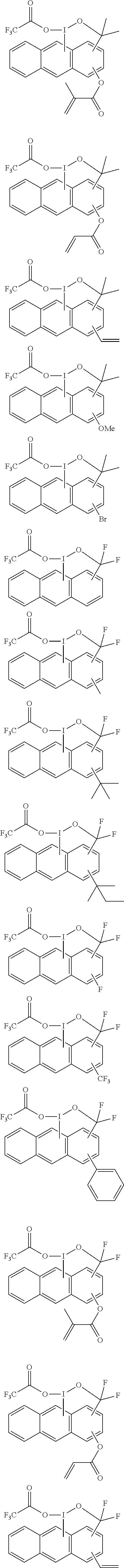

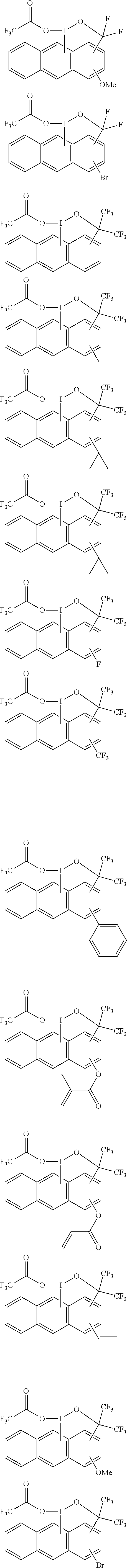

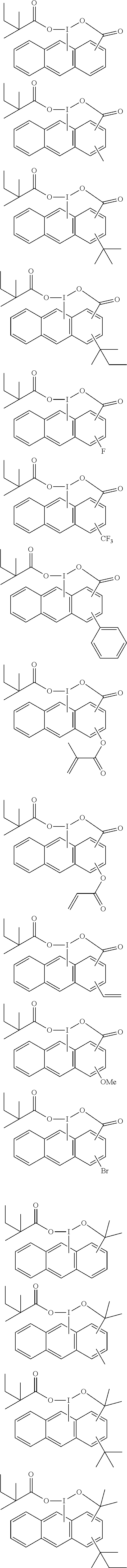

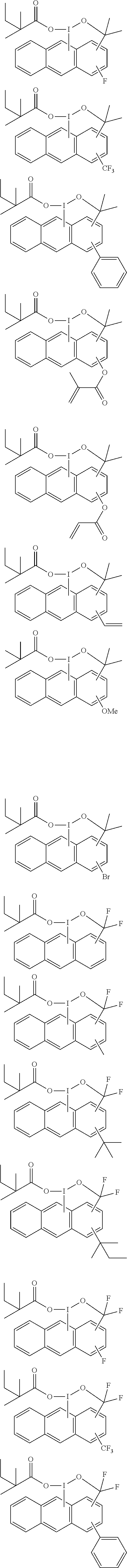

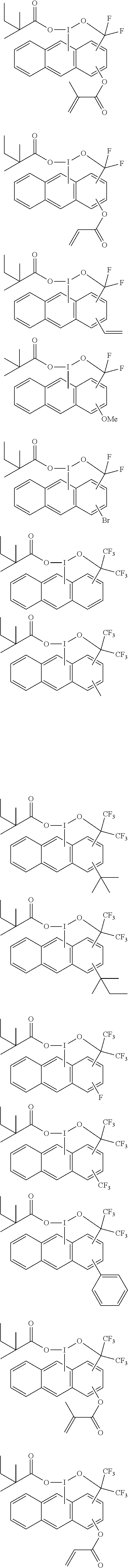

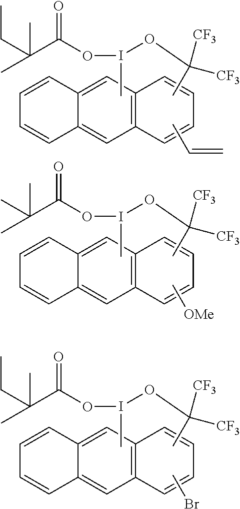

Specific examples of the hypervalent iodine compound represented by the general formula (5) include, but are not limited to, the following.

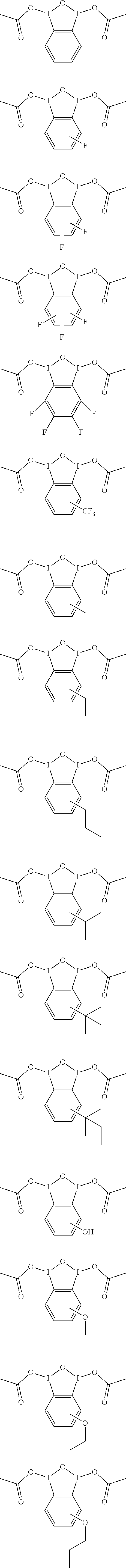

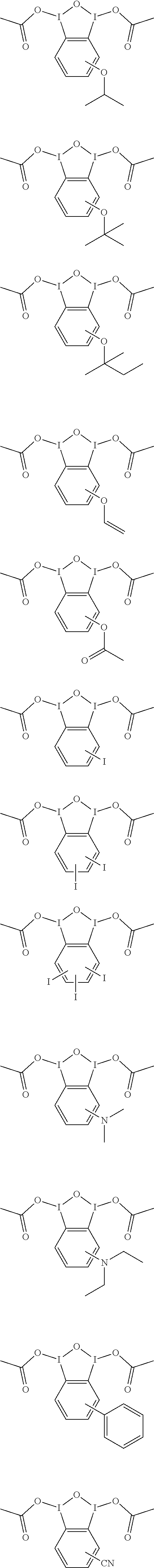

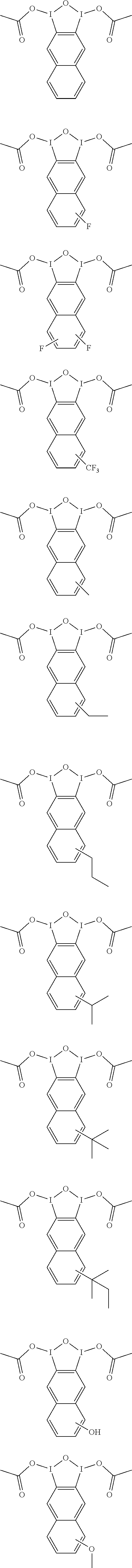

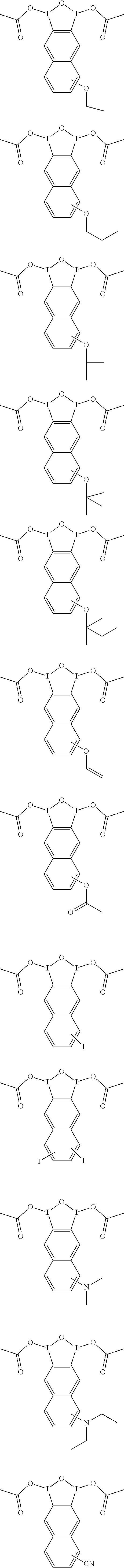

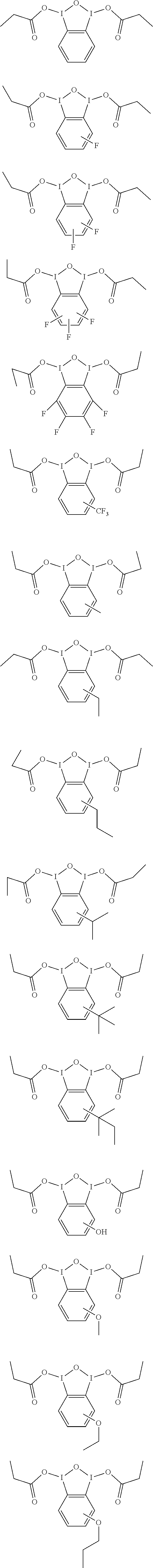

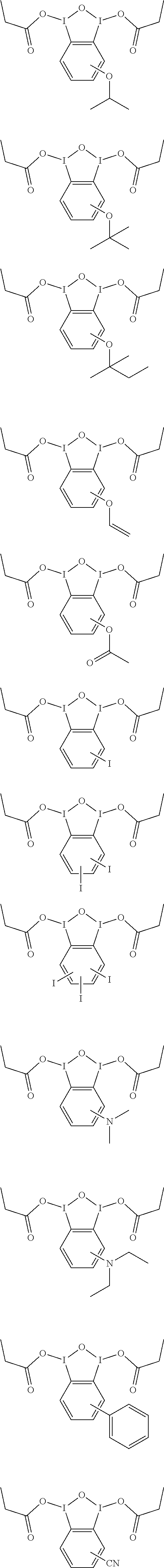

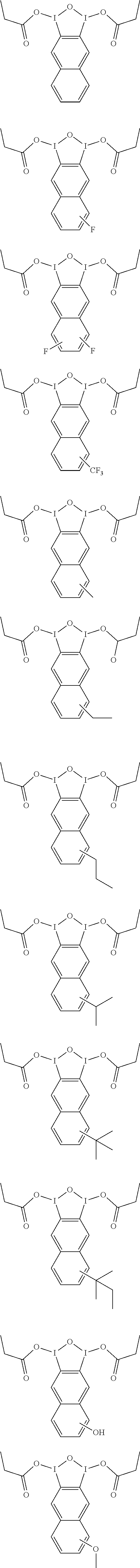

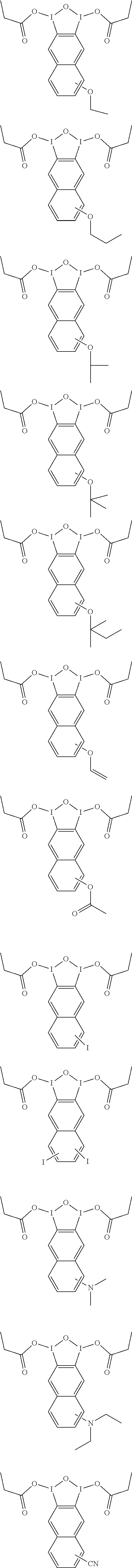

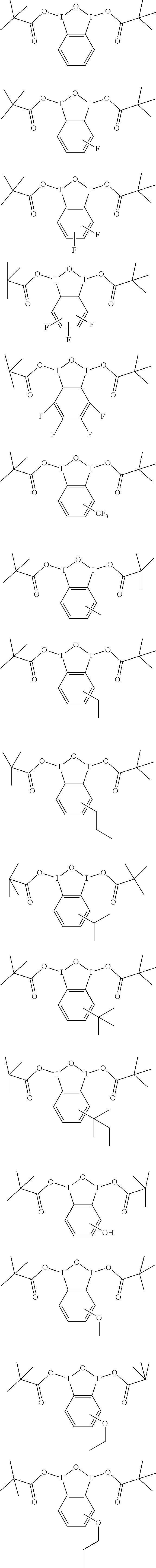

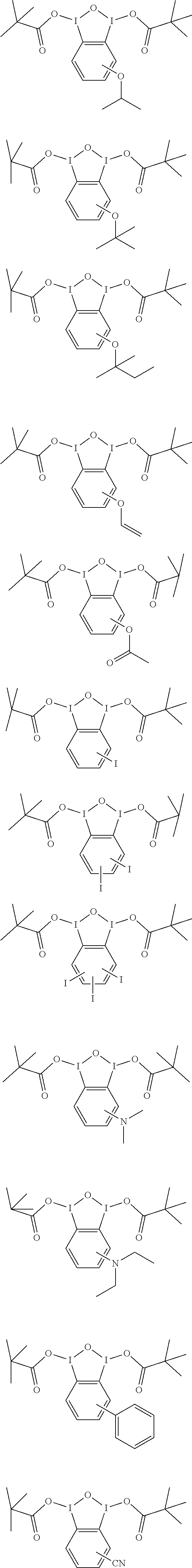

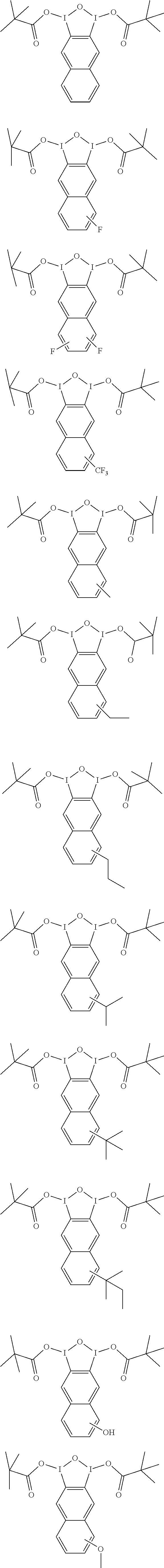

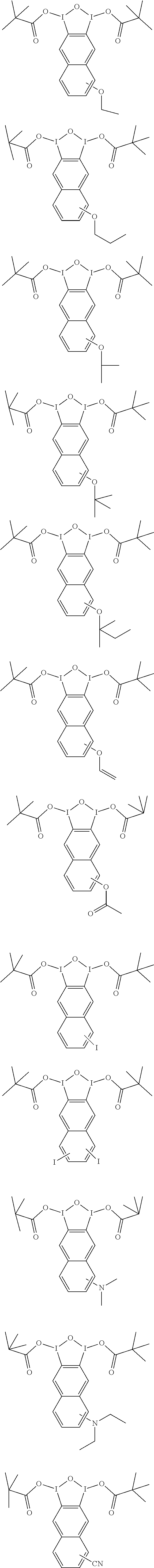

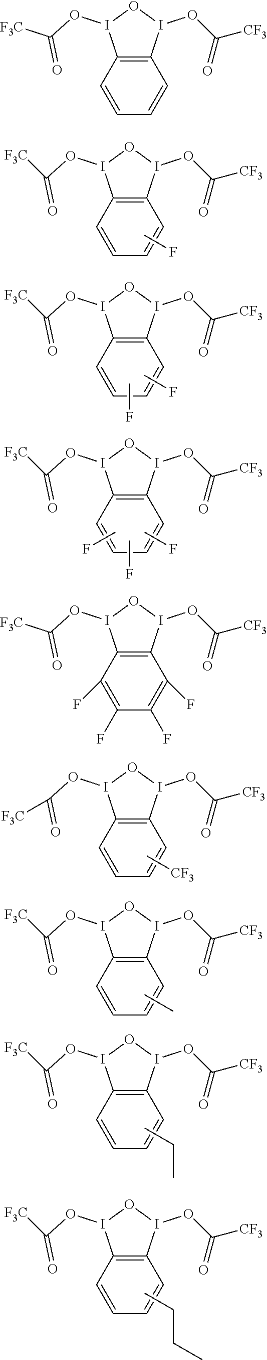

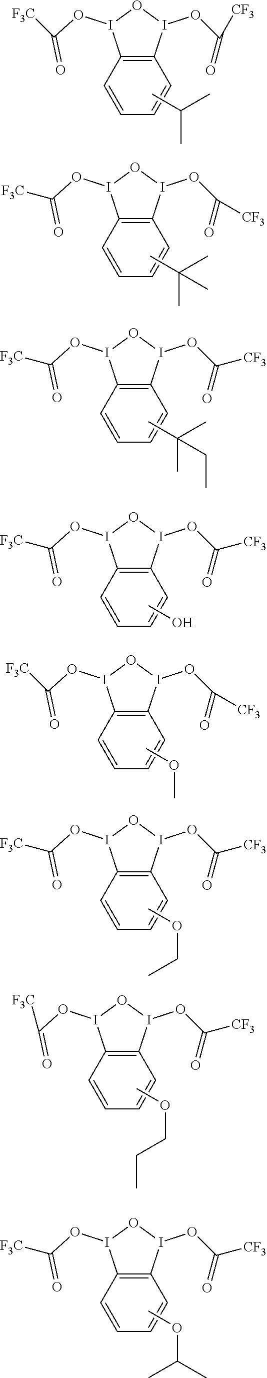

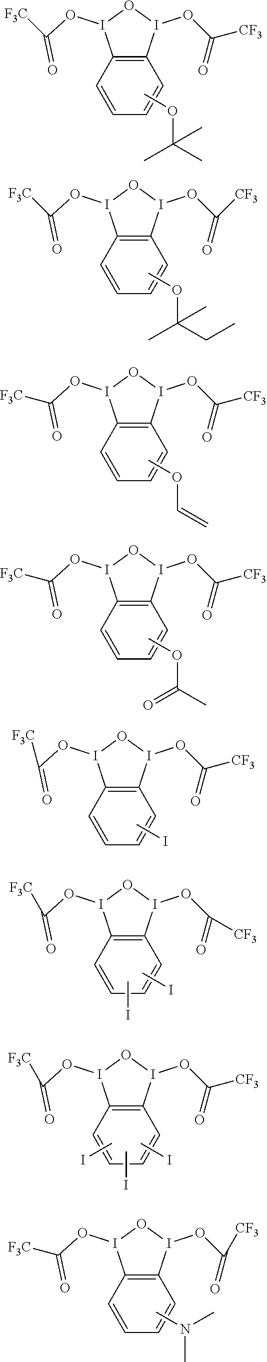

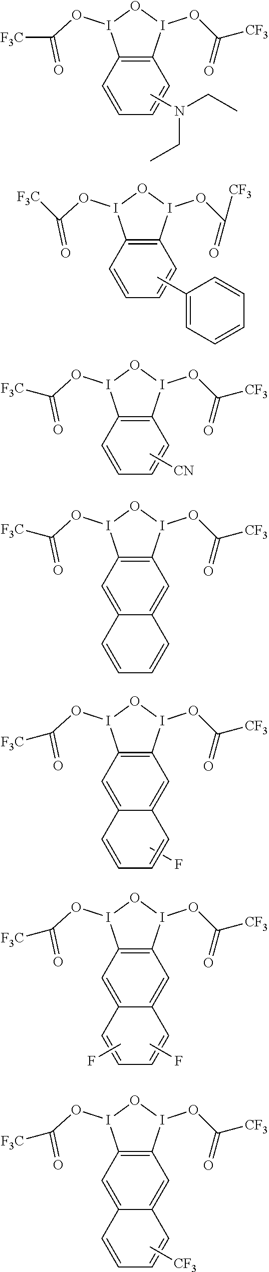

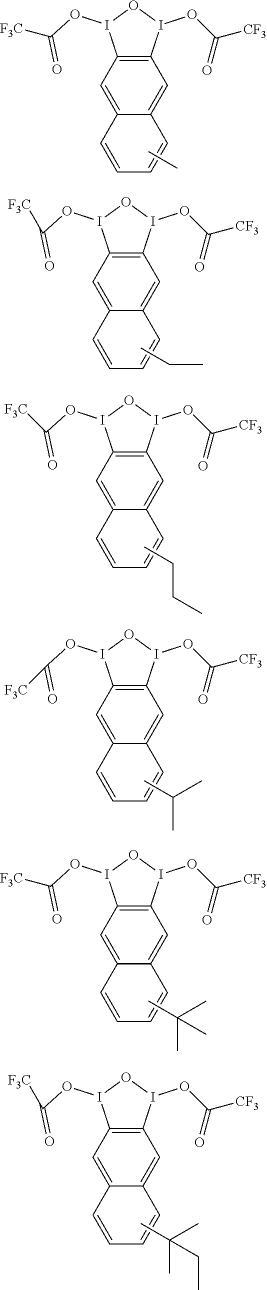

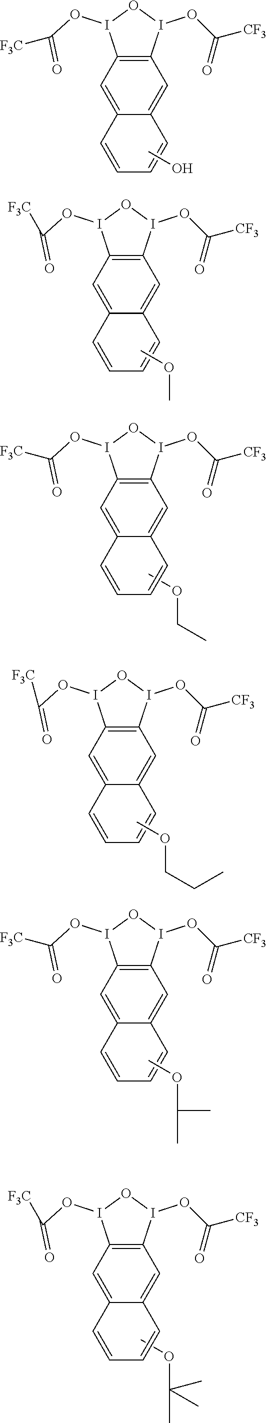

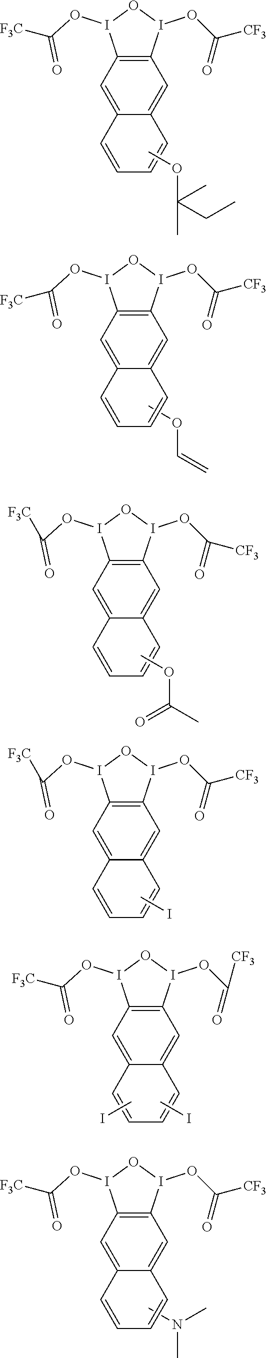

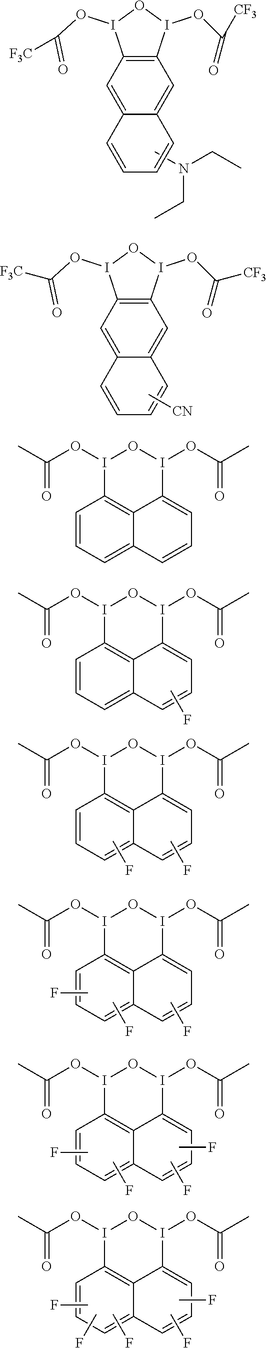

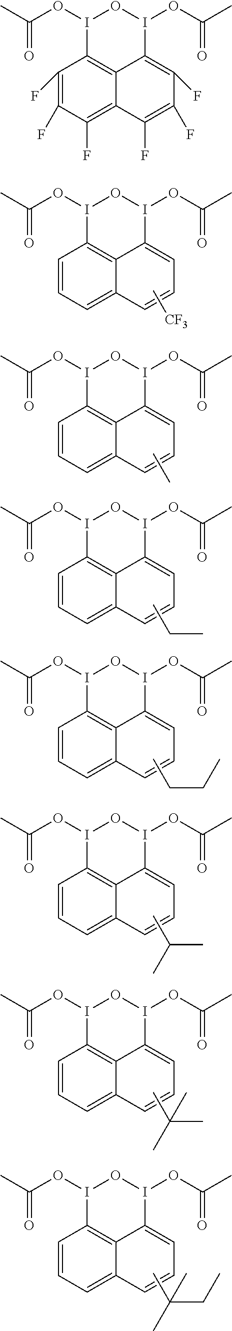

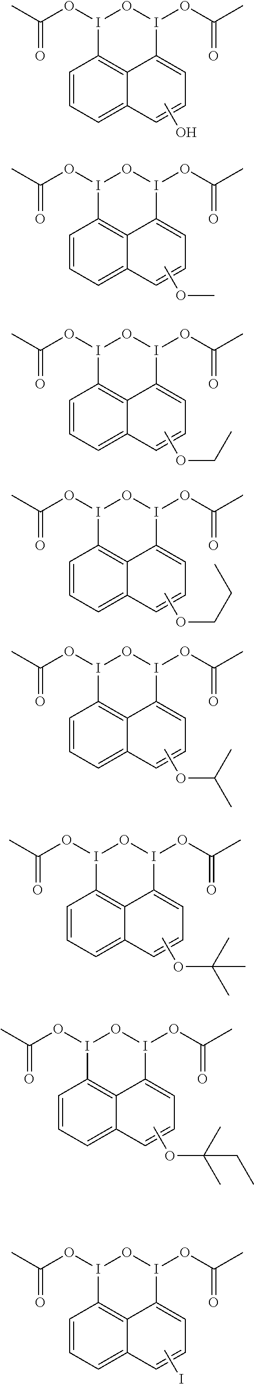

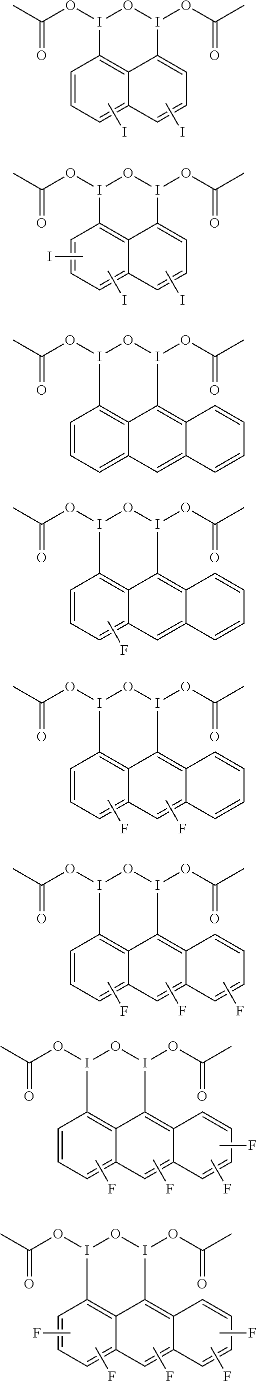

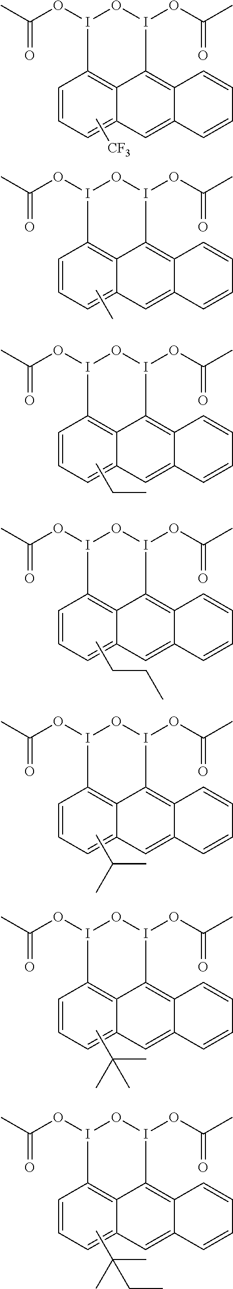

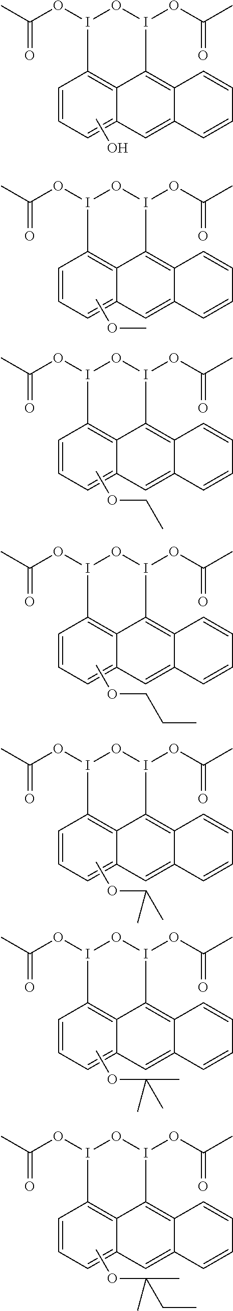

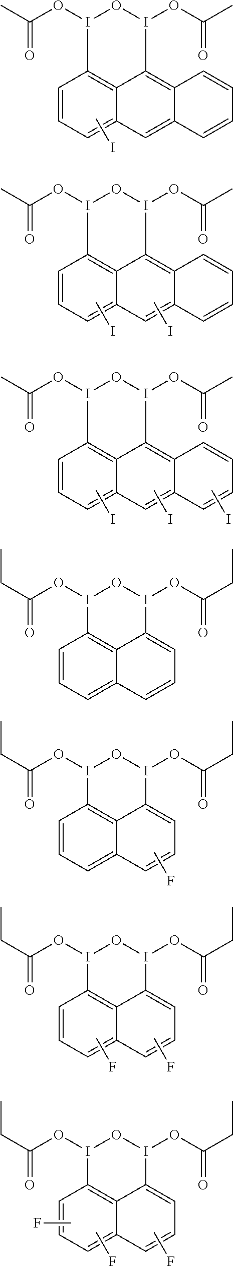

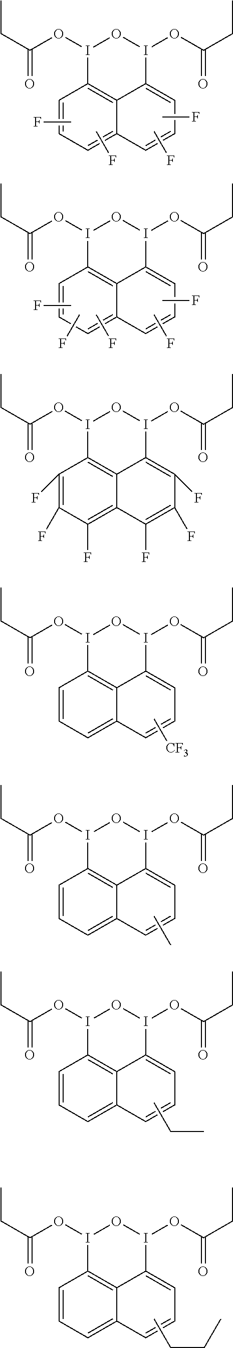

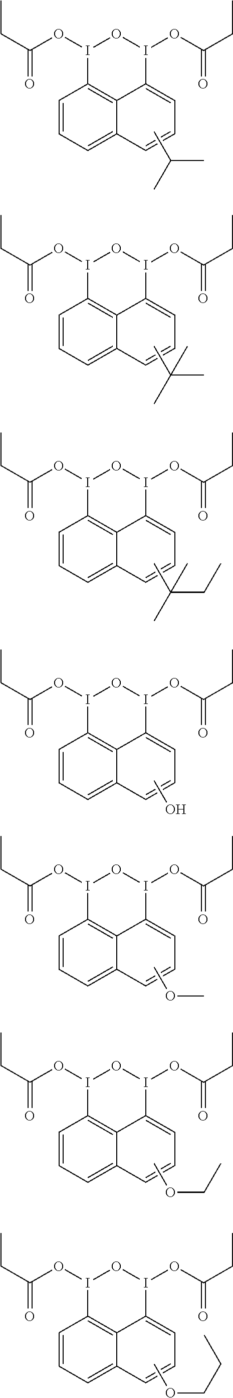

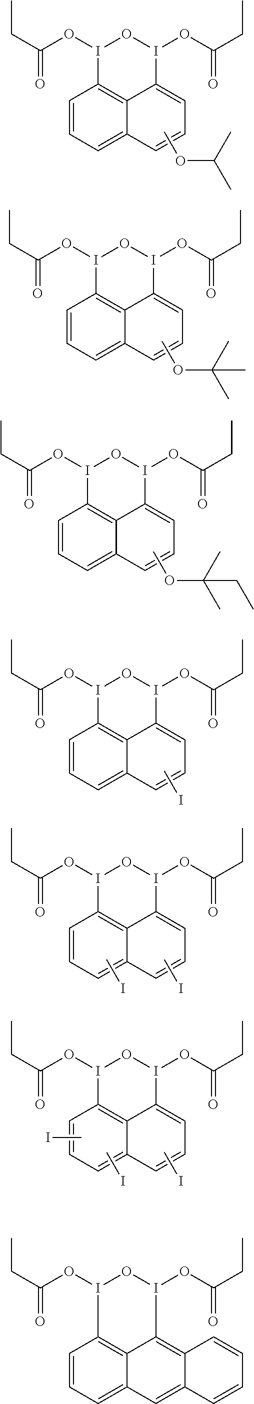

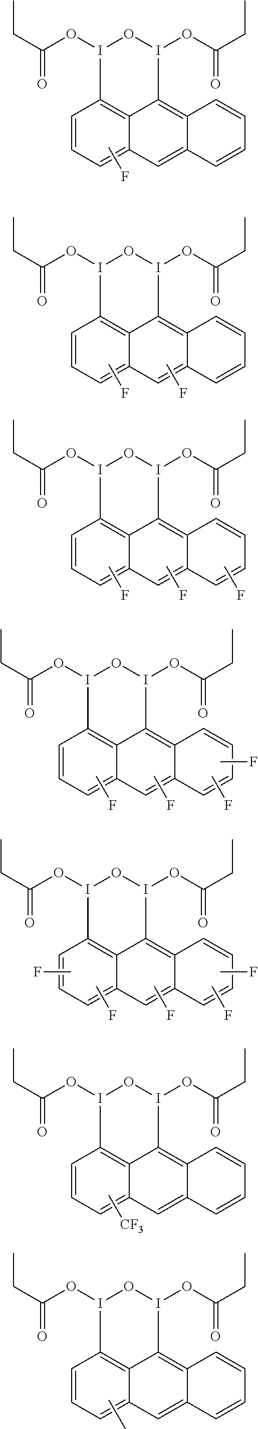

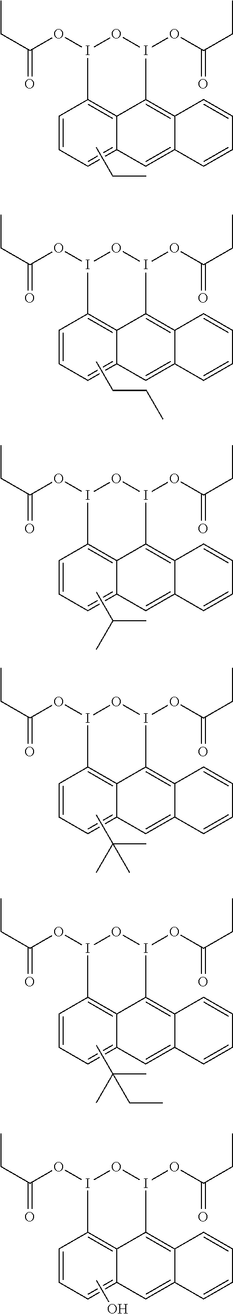

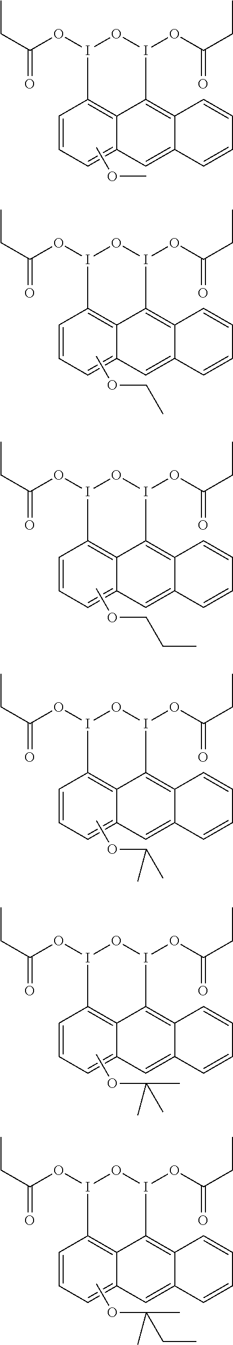

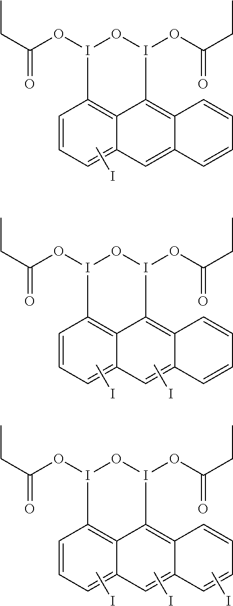

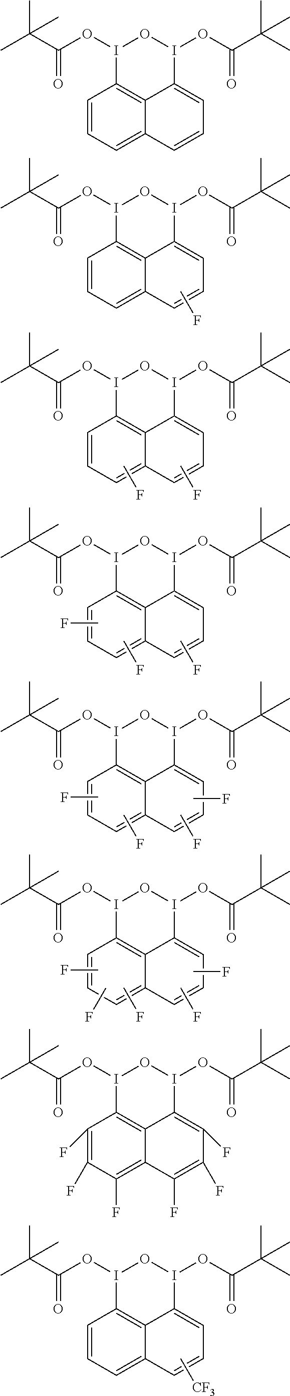

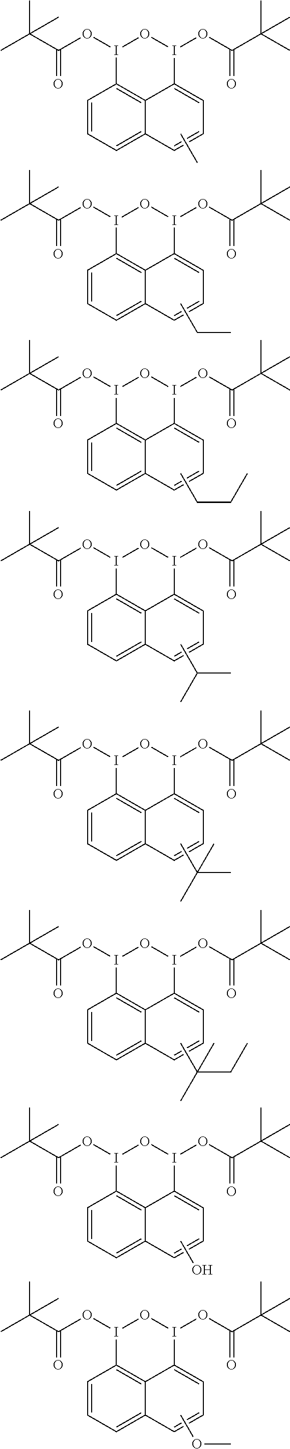

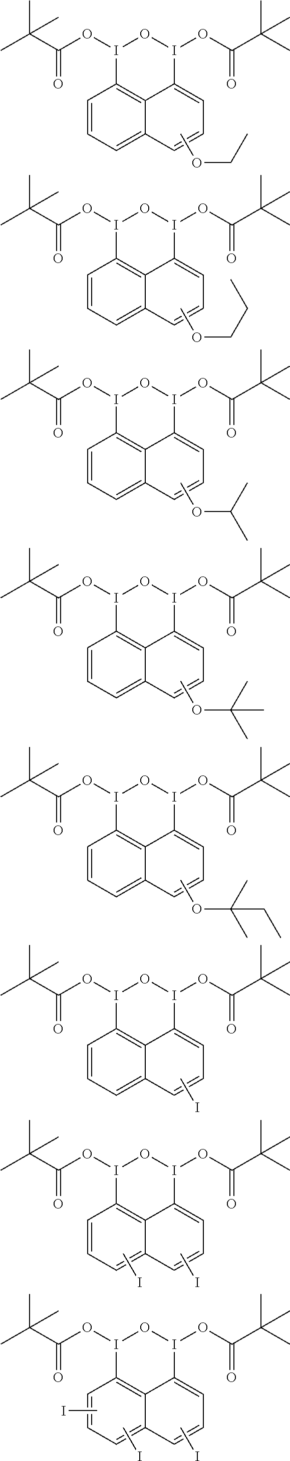

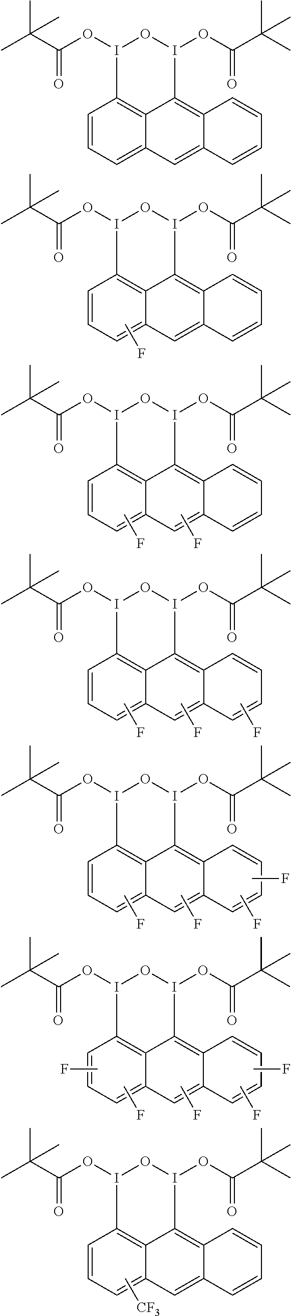

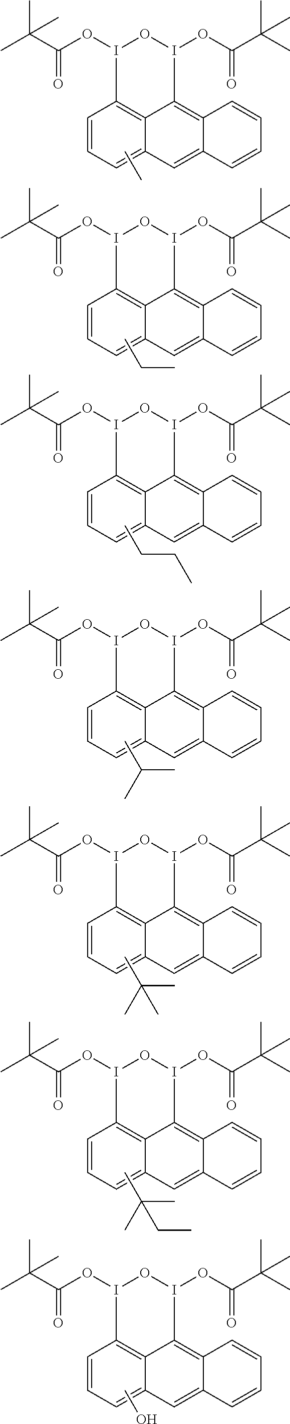

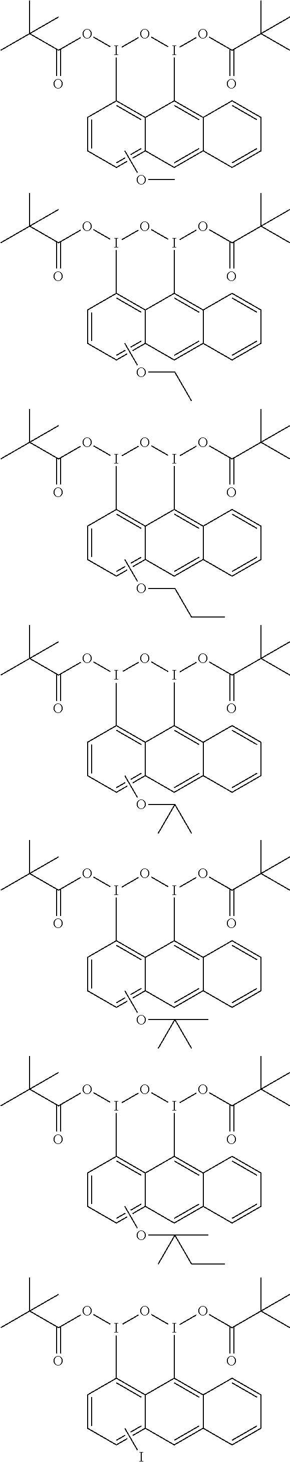

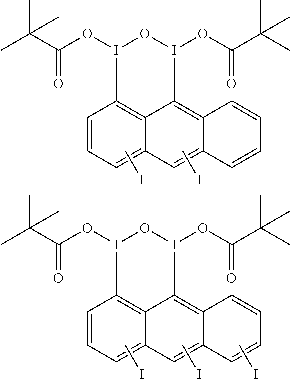

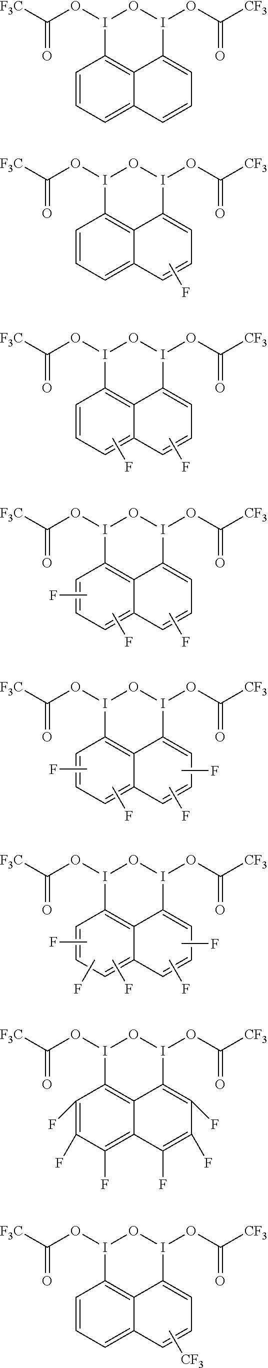

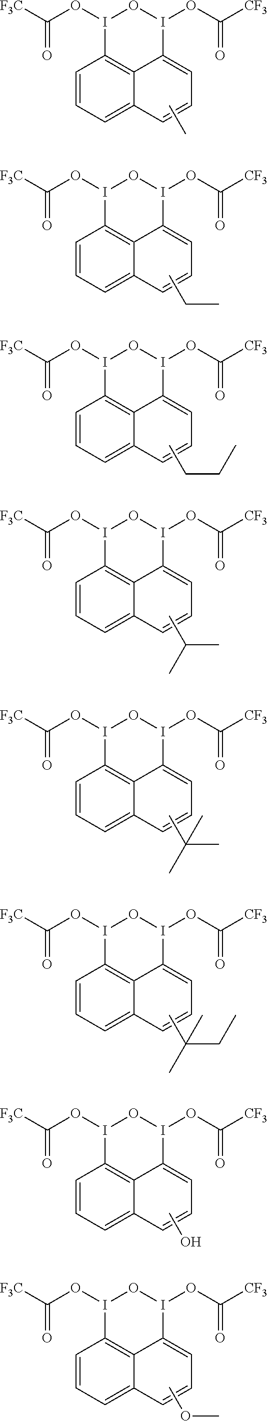

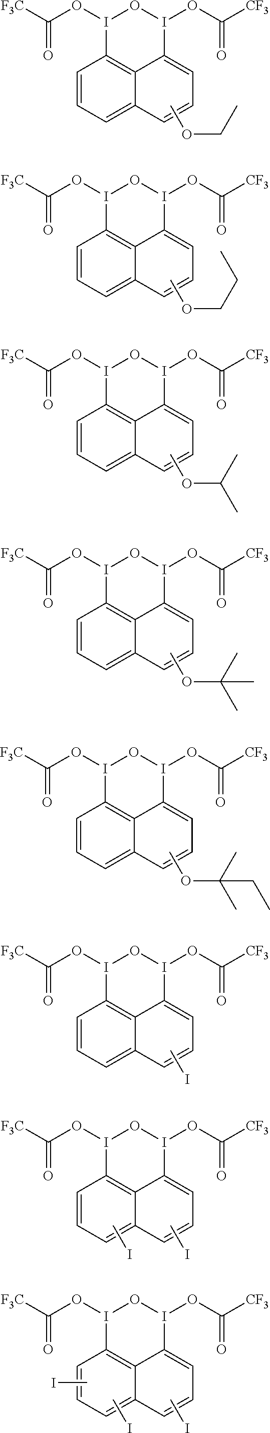

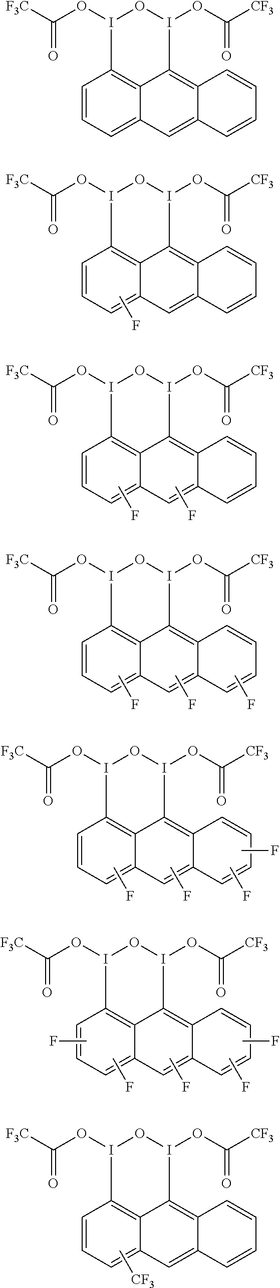

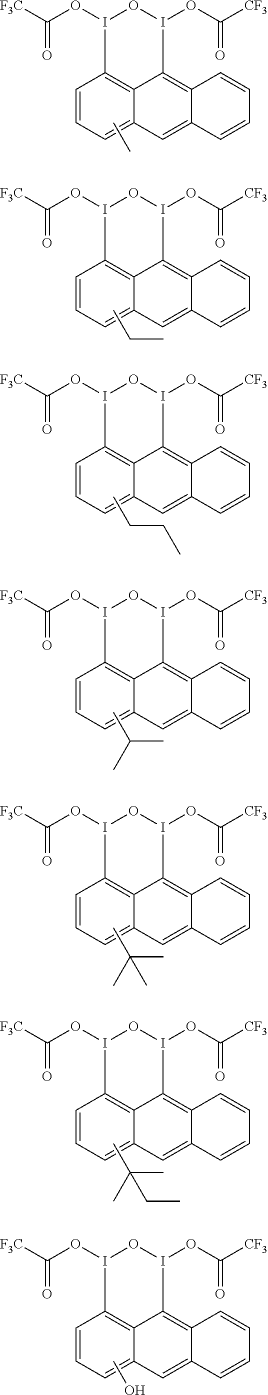

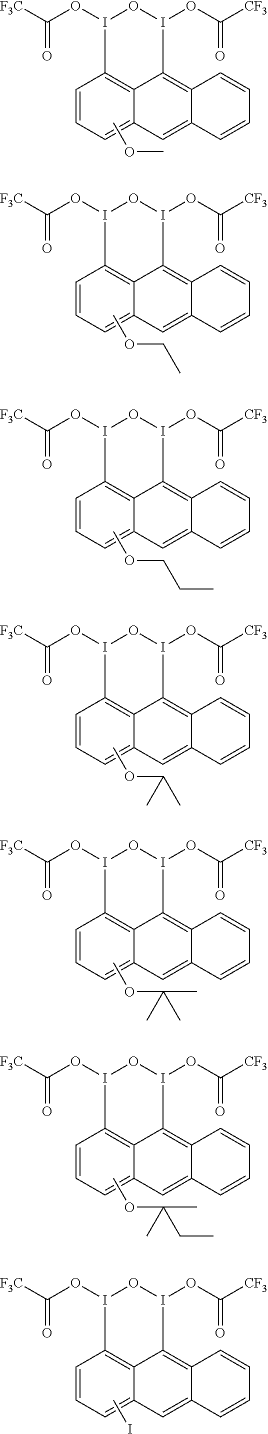

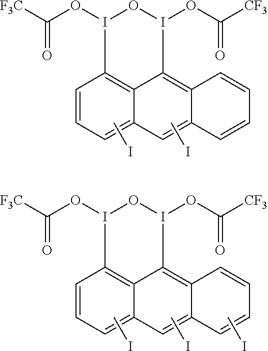

Specific examples of the hypervalent iodine compound represented by the general formula (6) include, but are not limited to, the following. In the following formulae, L₁ represents the same as defined above.

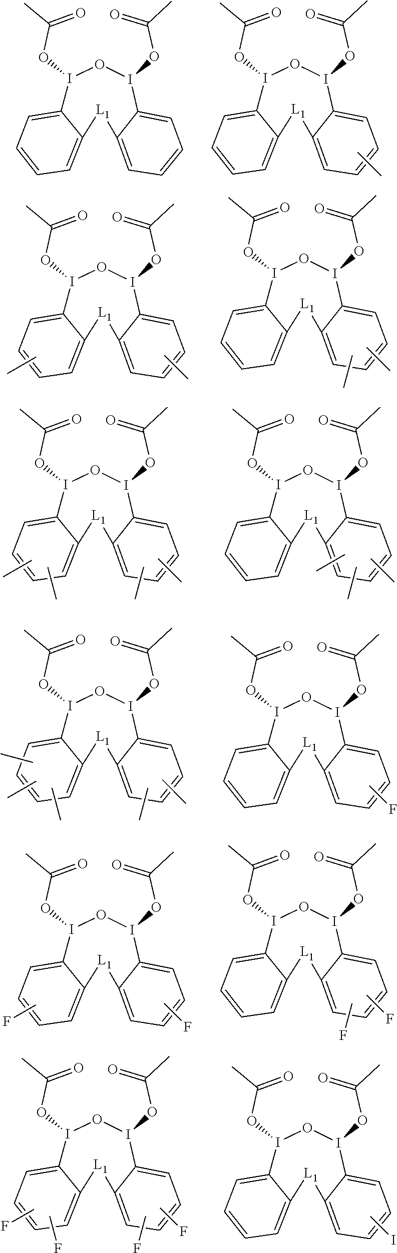

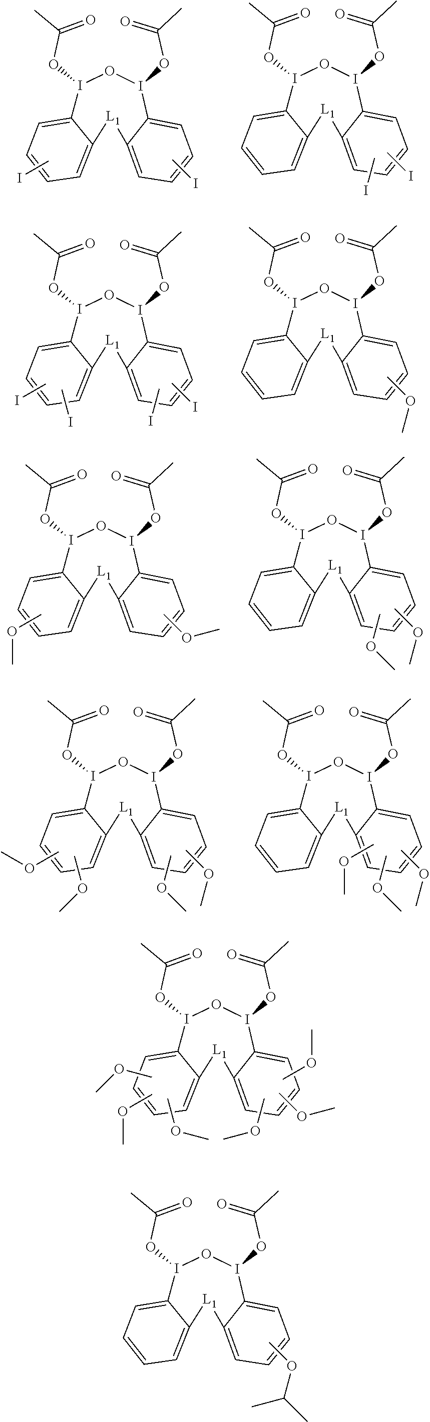

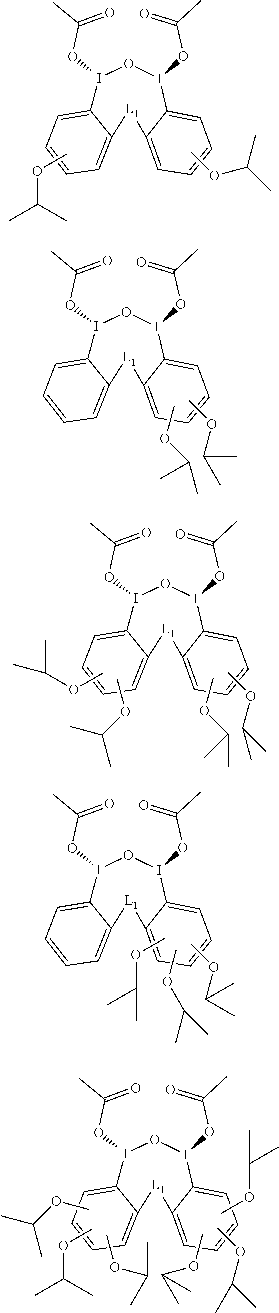

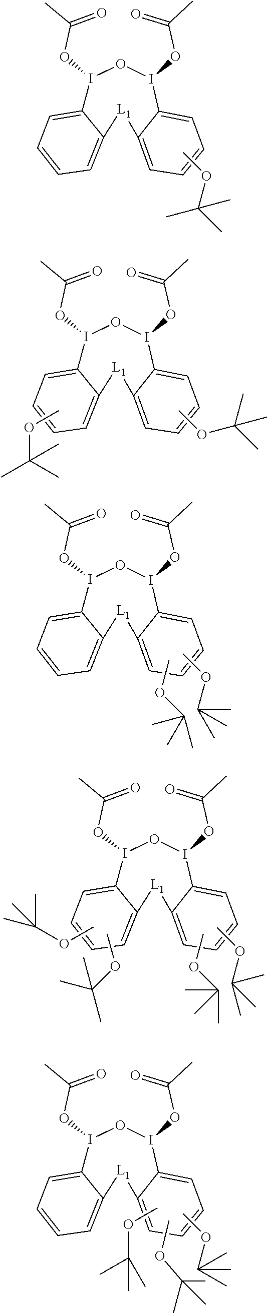

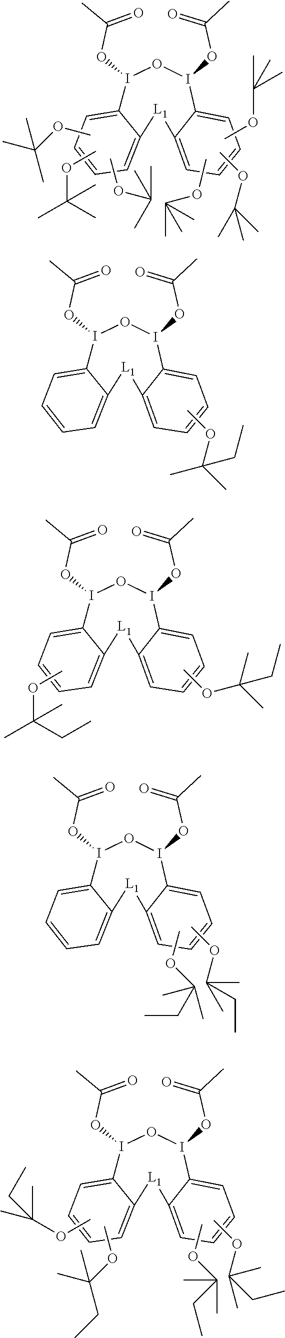

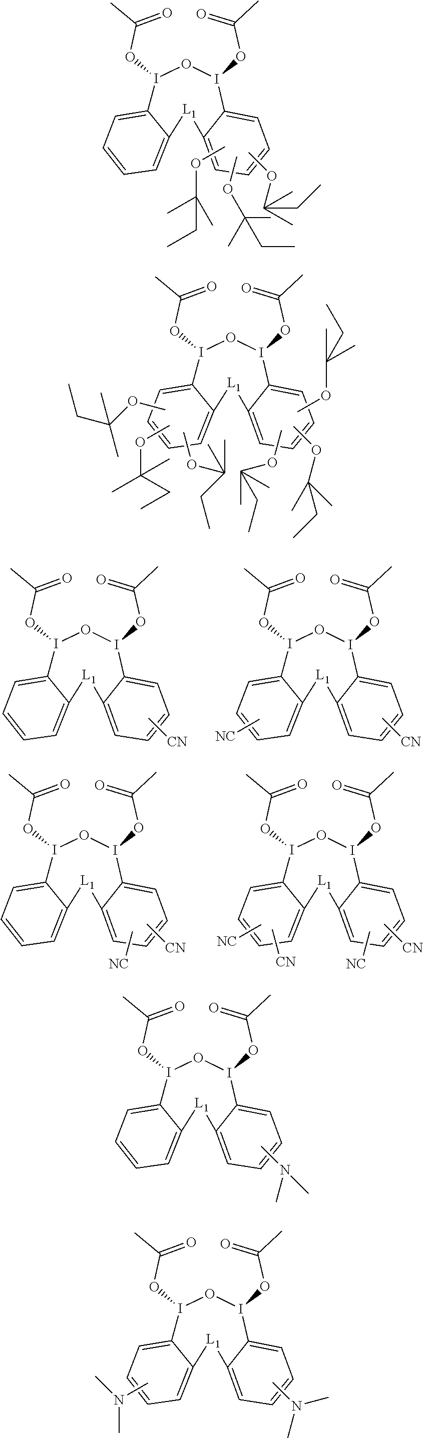

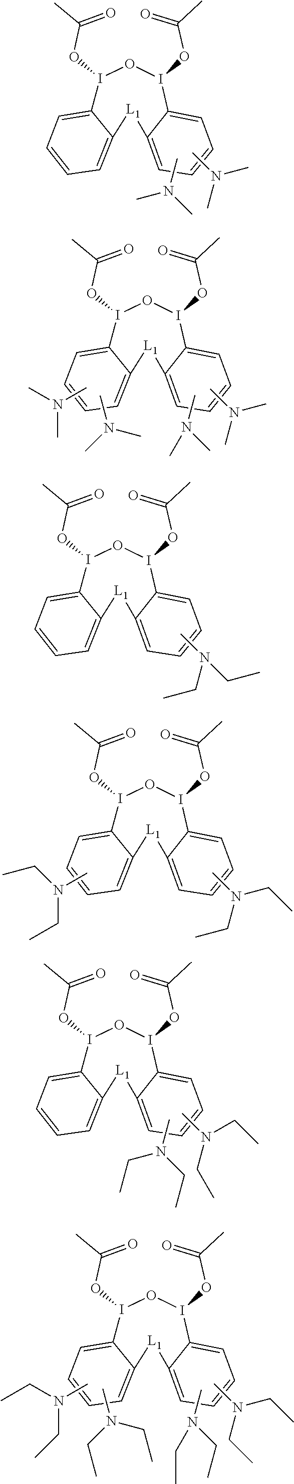

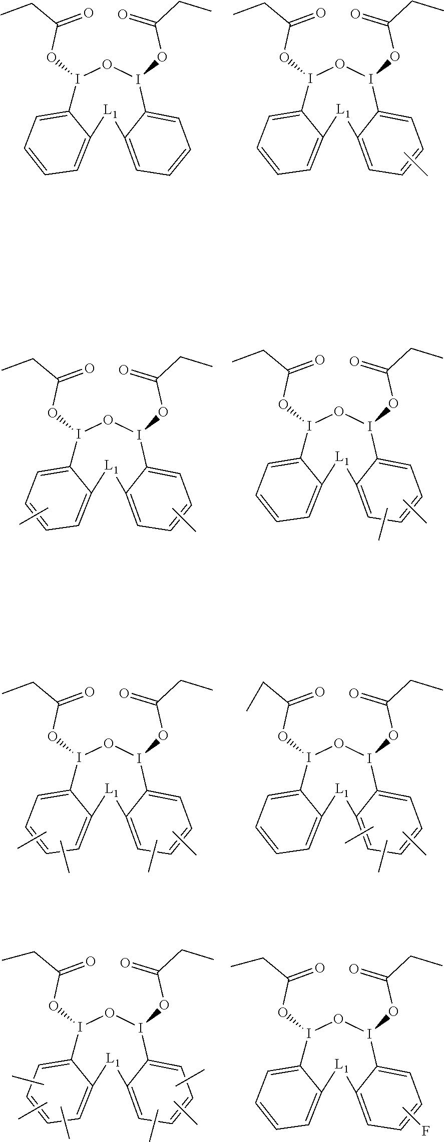

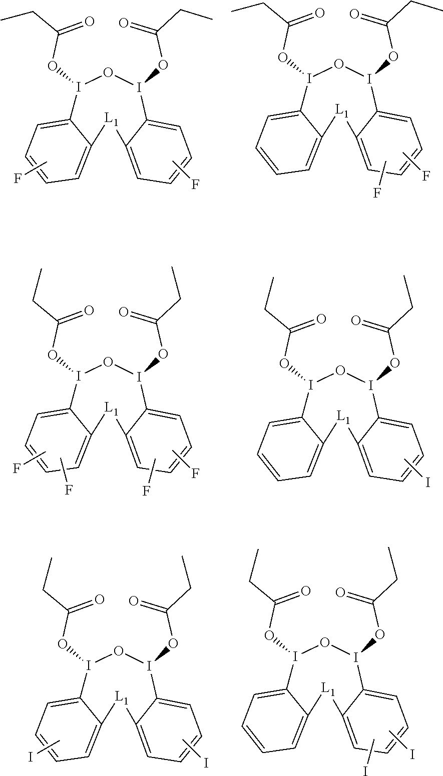

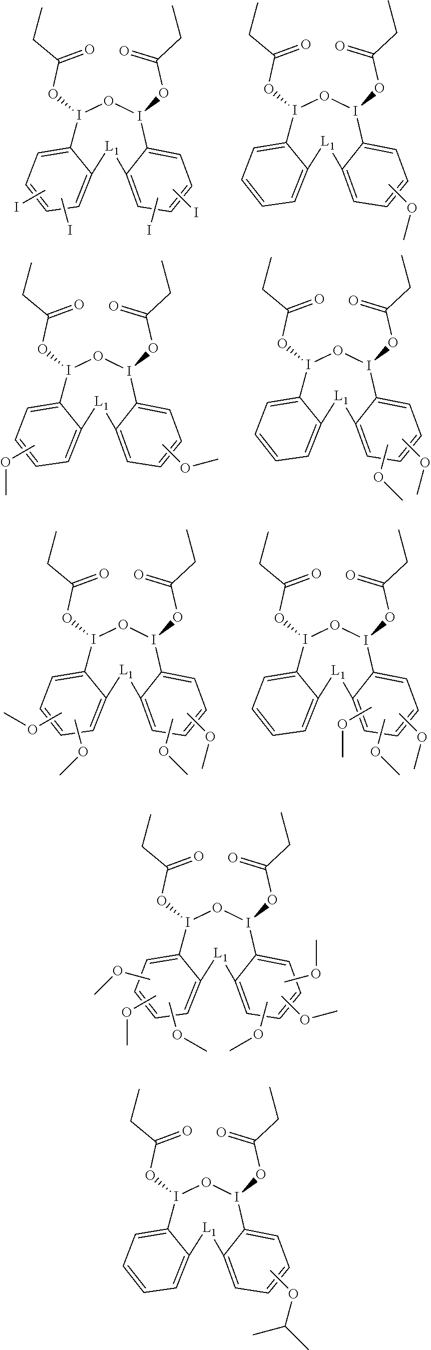

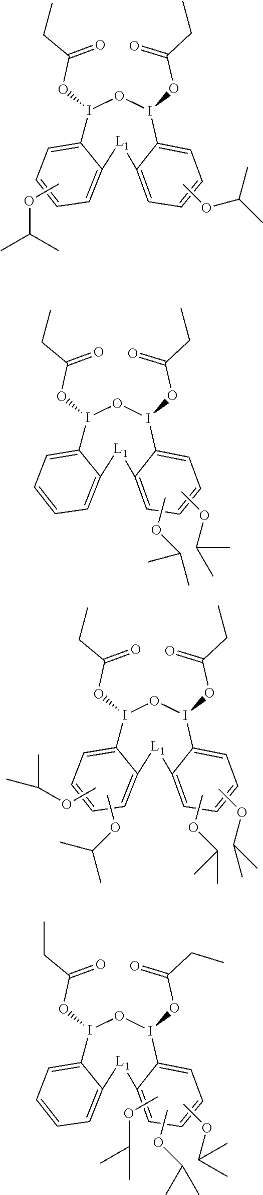

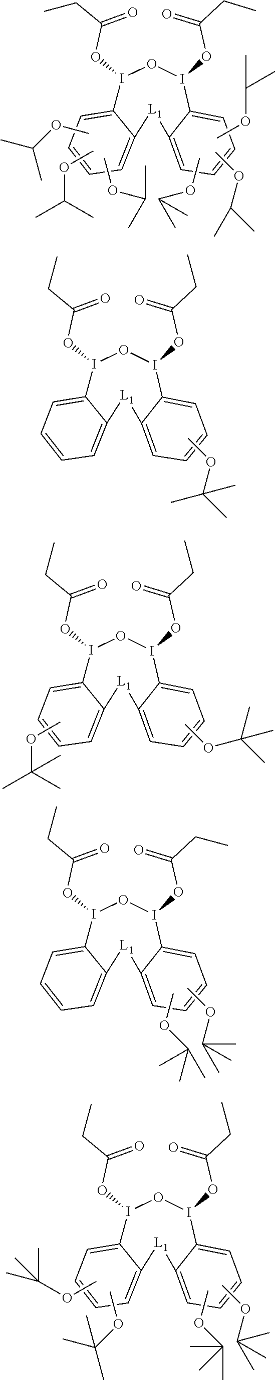

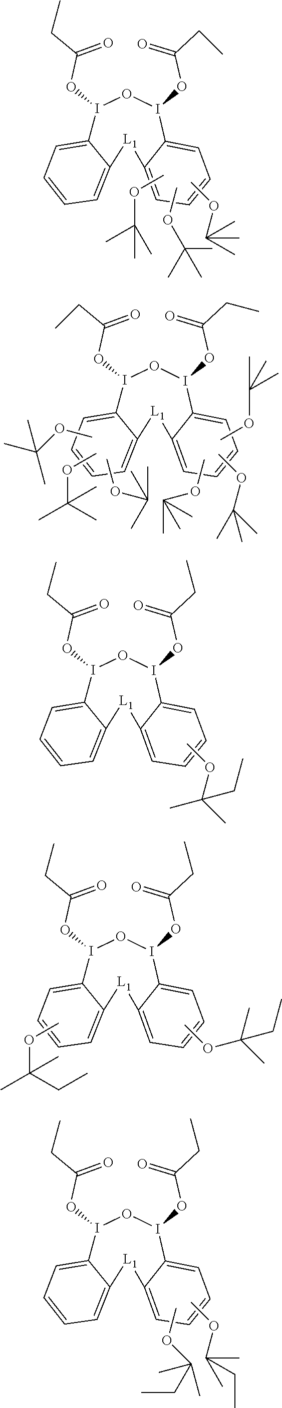

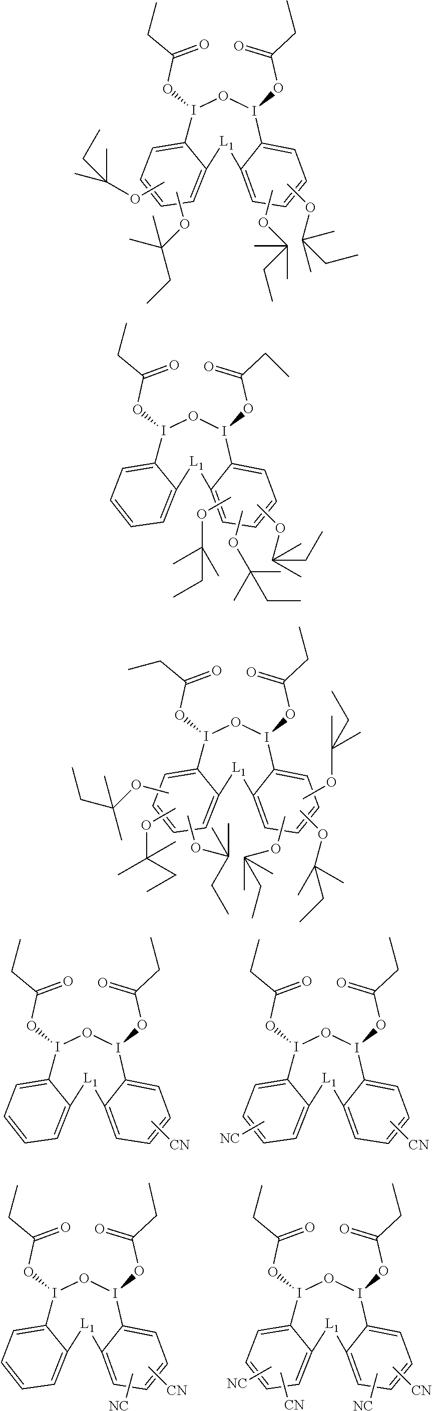

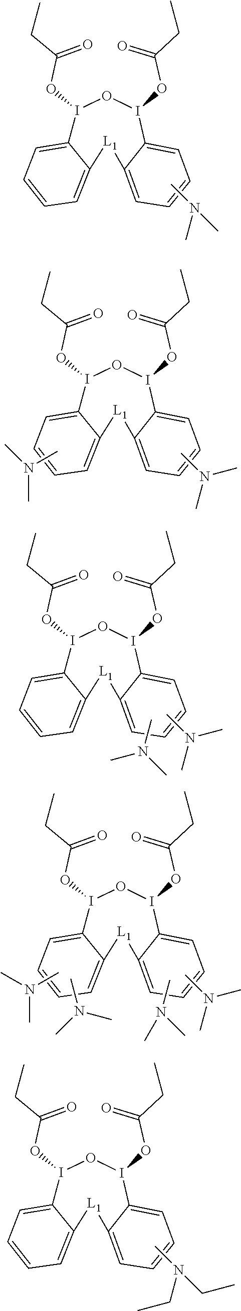

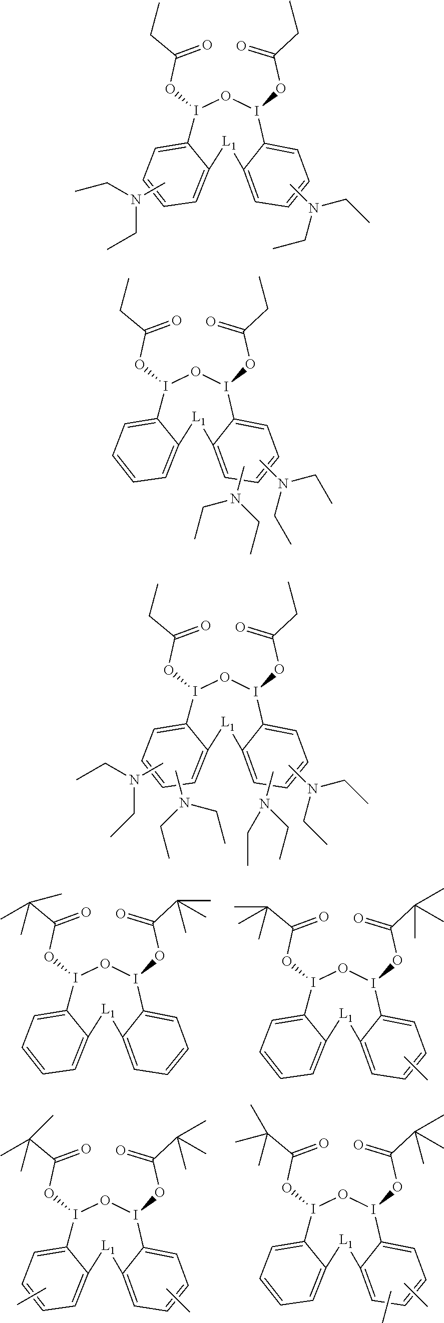

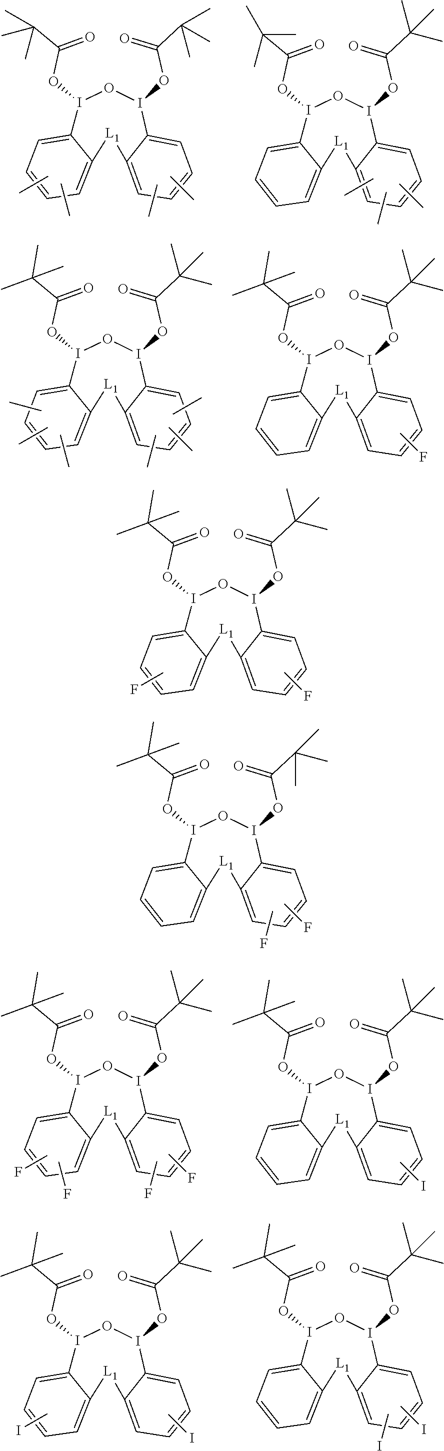

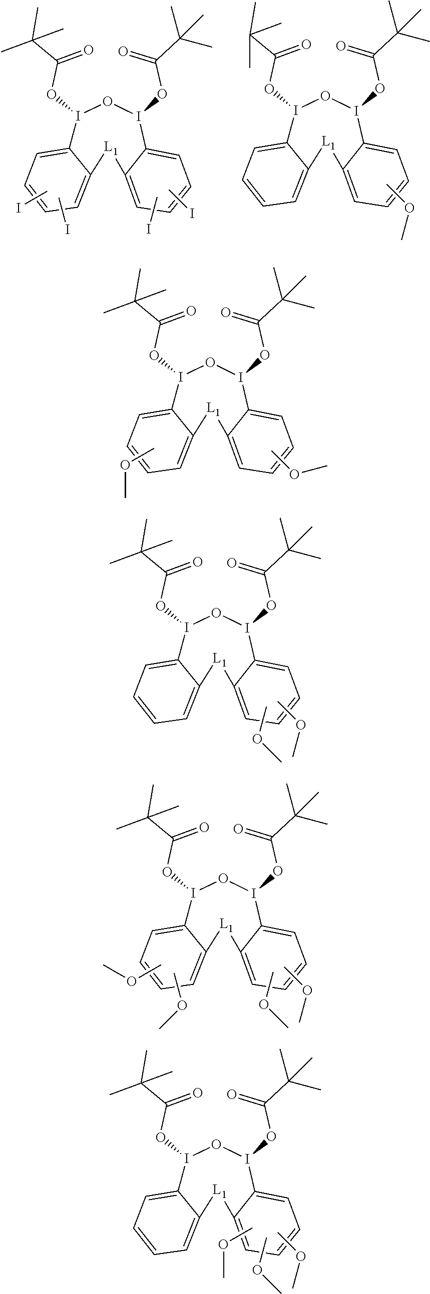

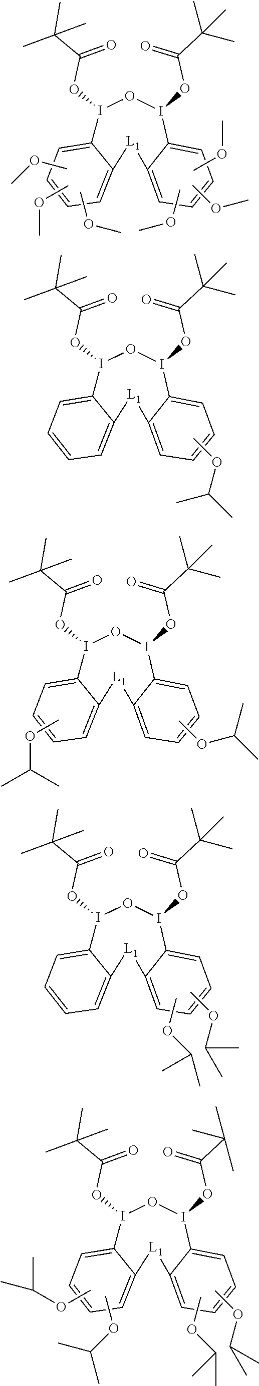

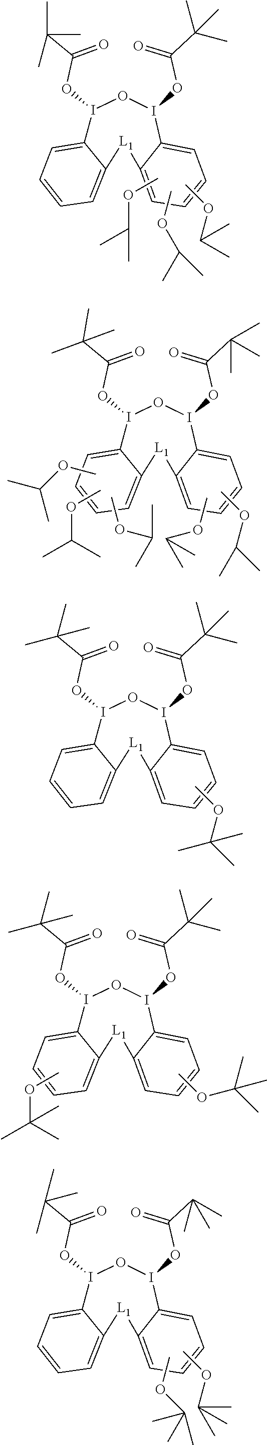

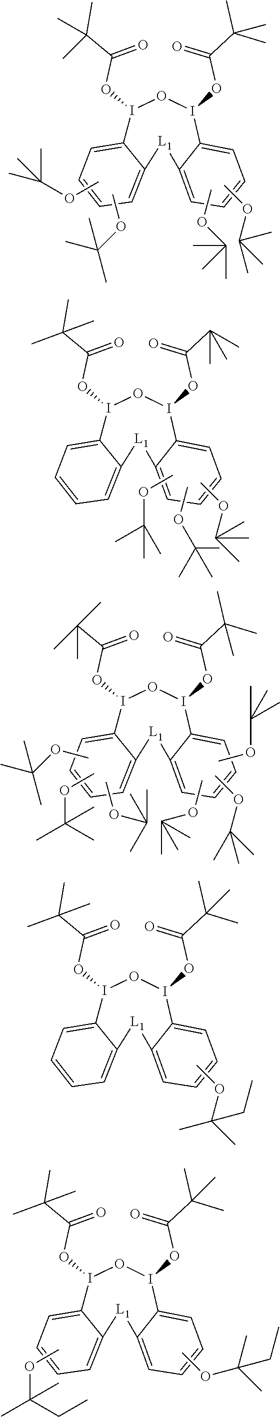

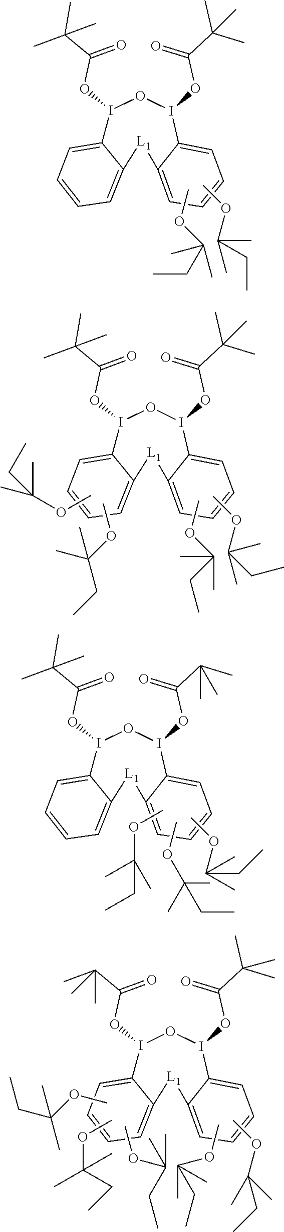

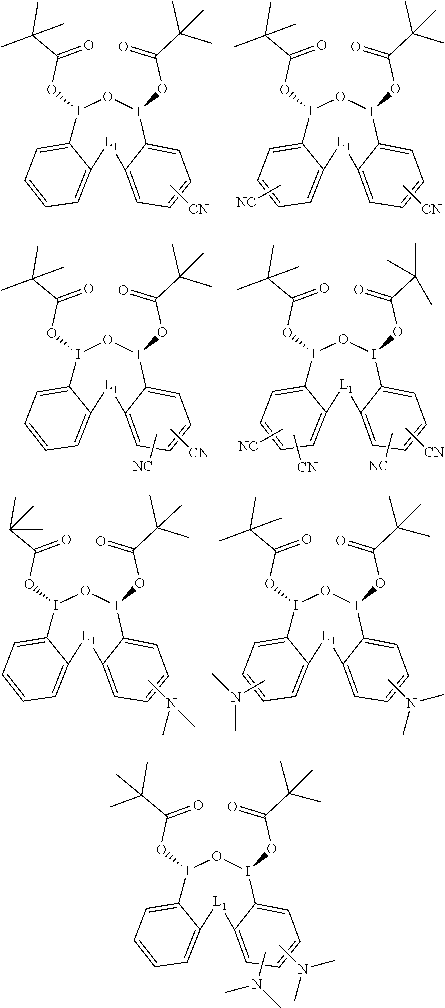

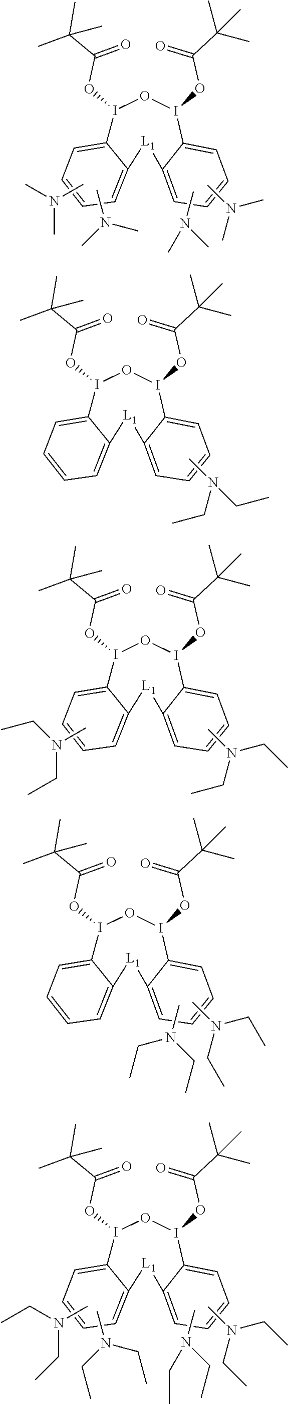

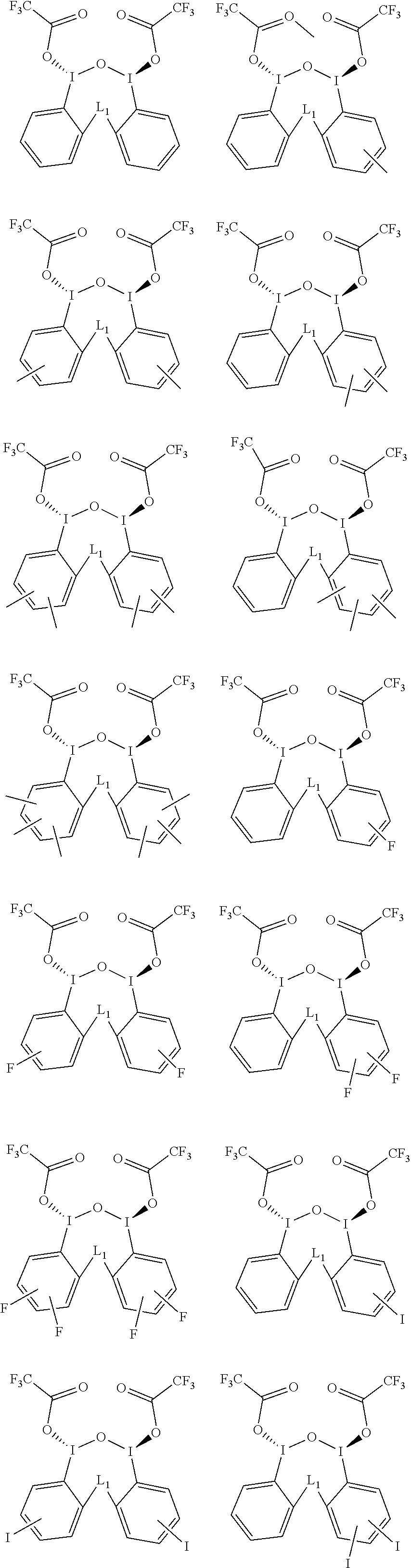

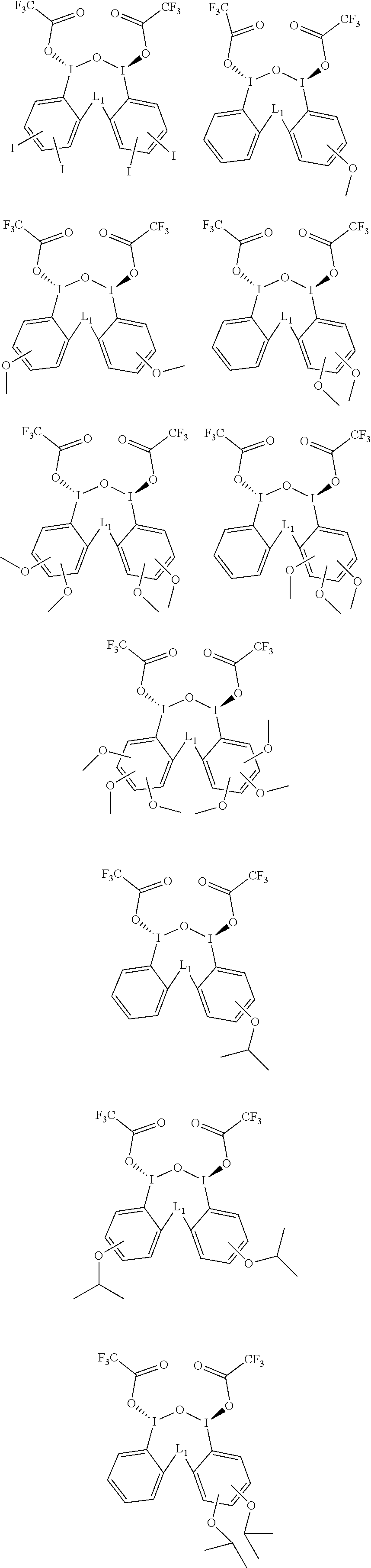

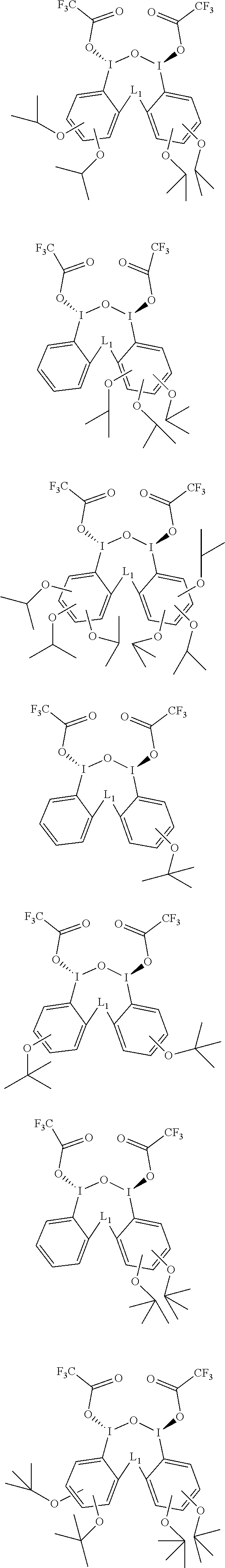

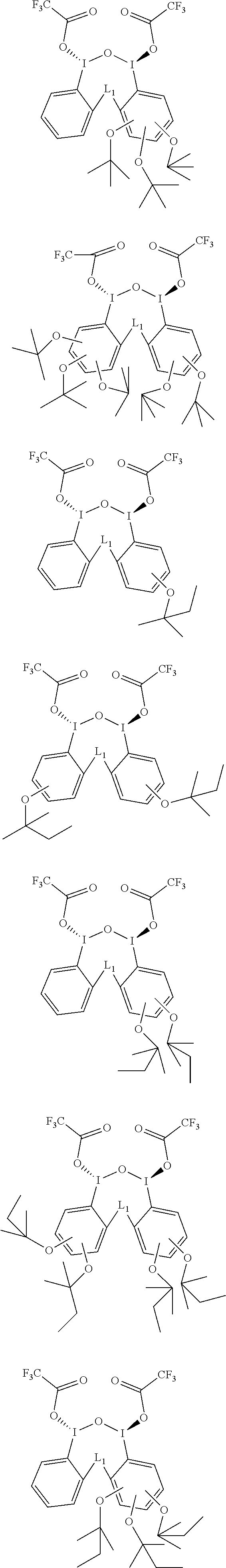

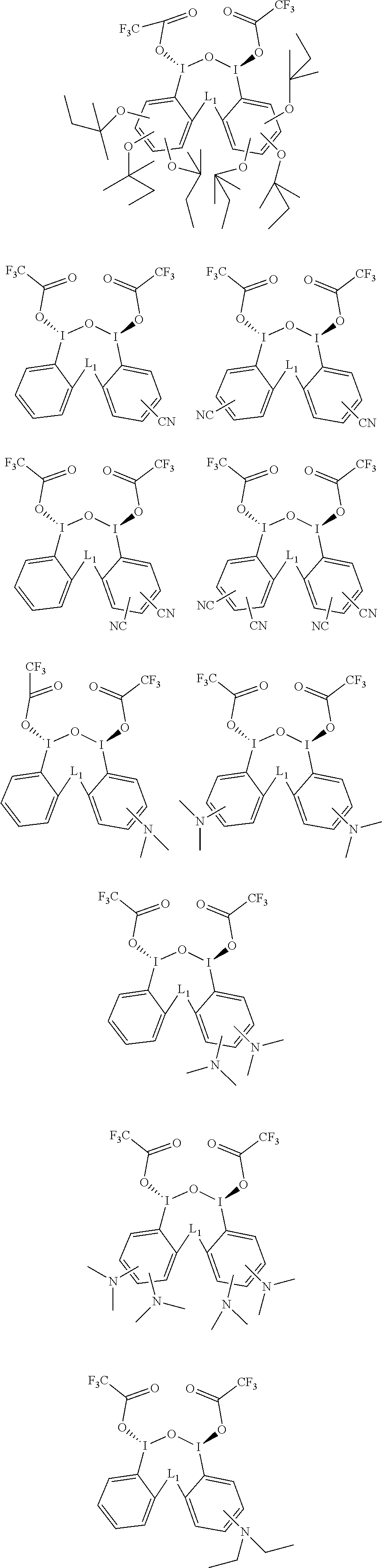

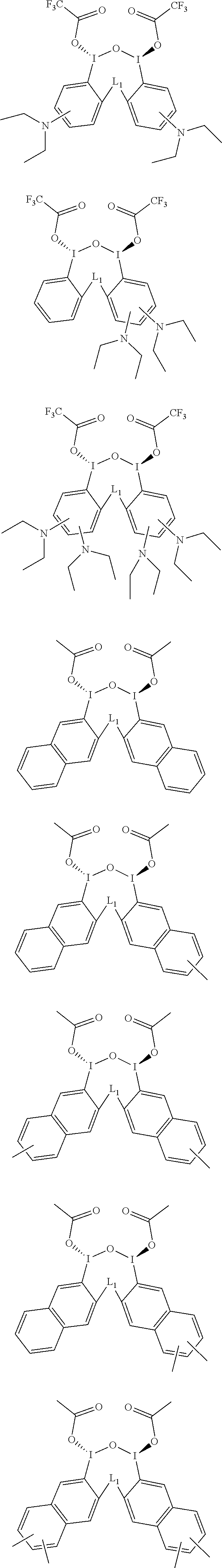

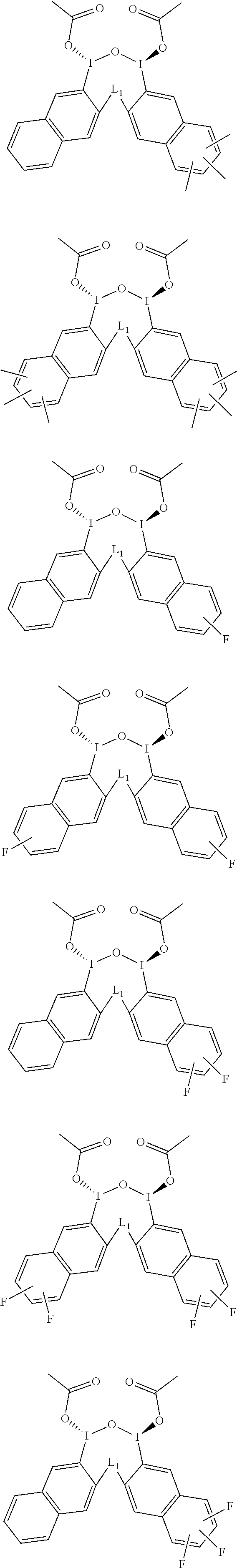

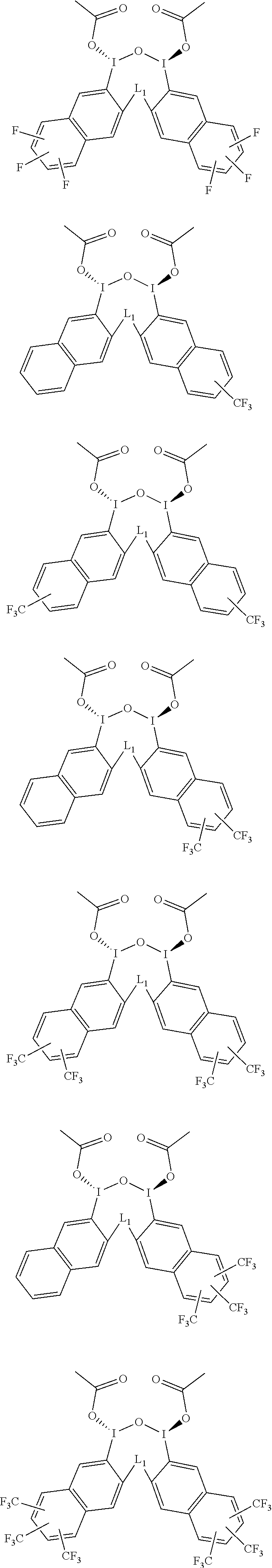

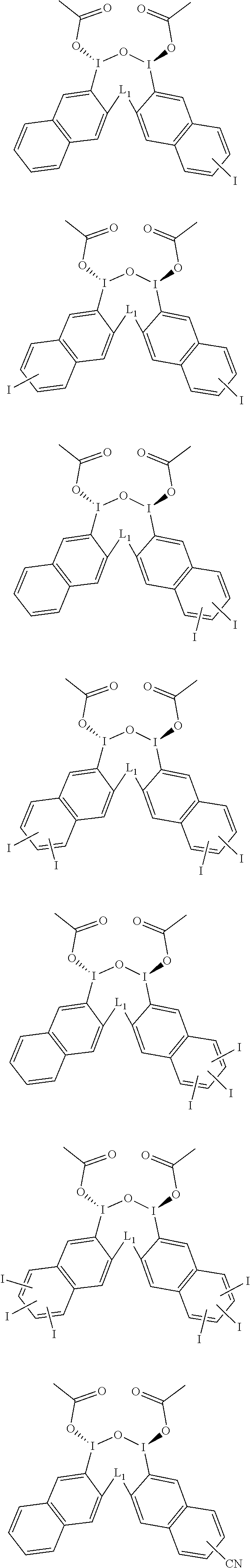

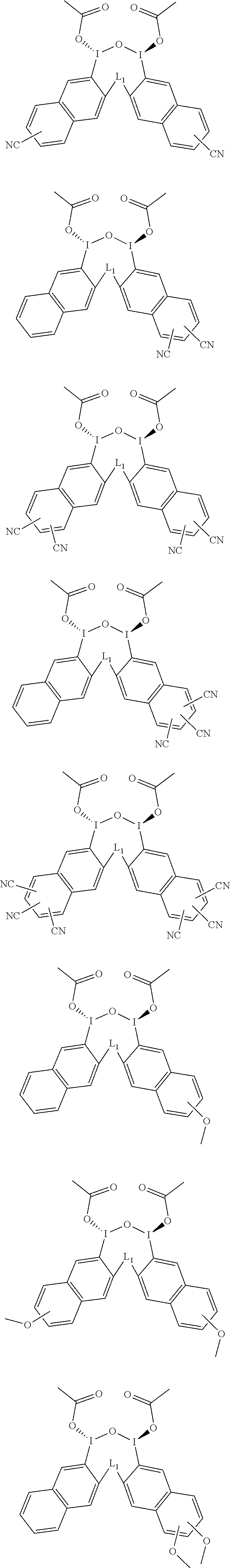

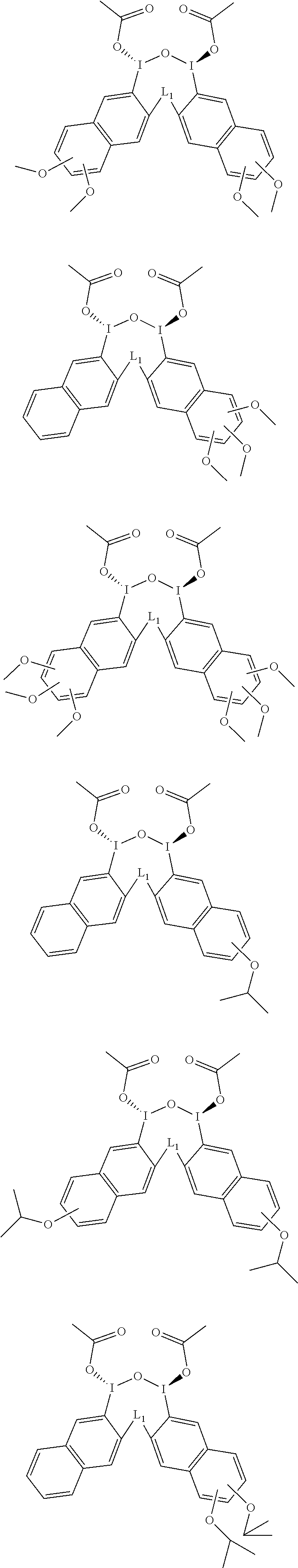

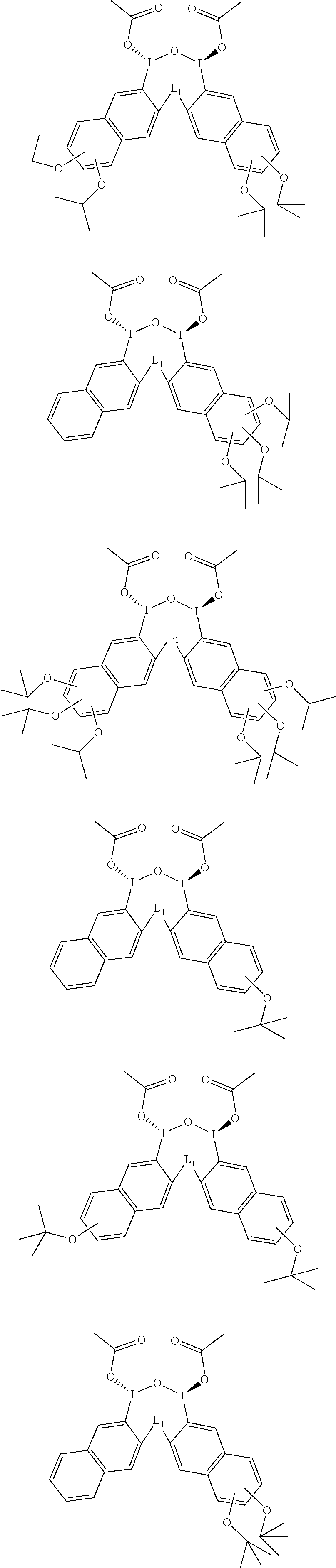

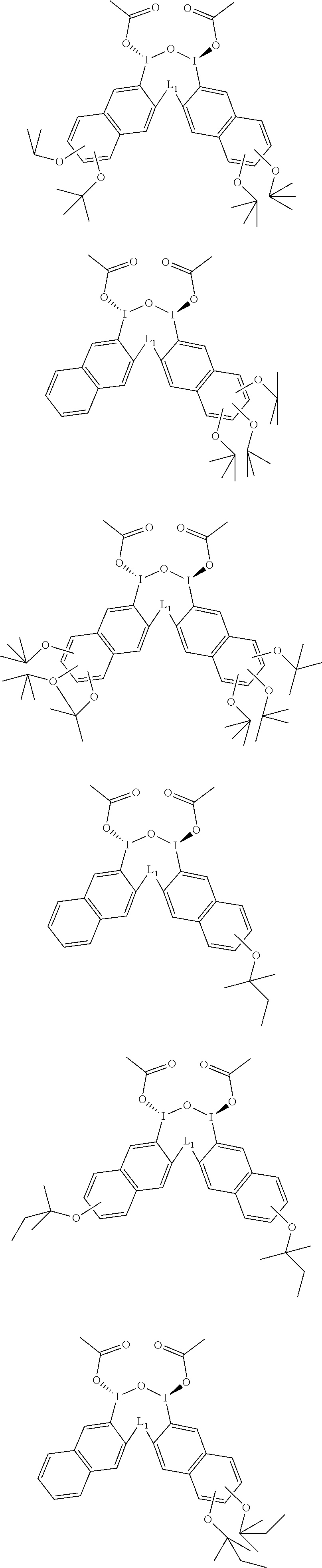

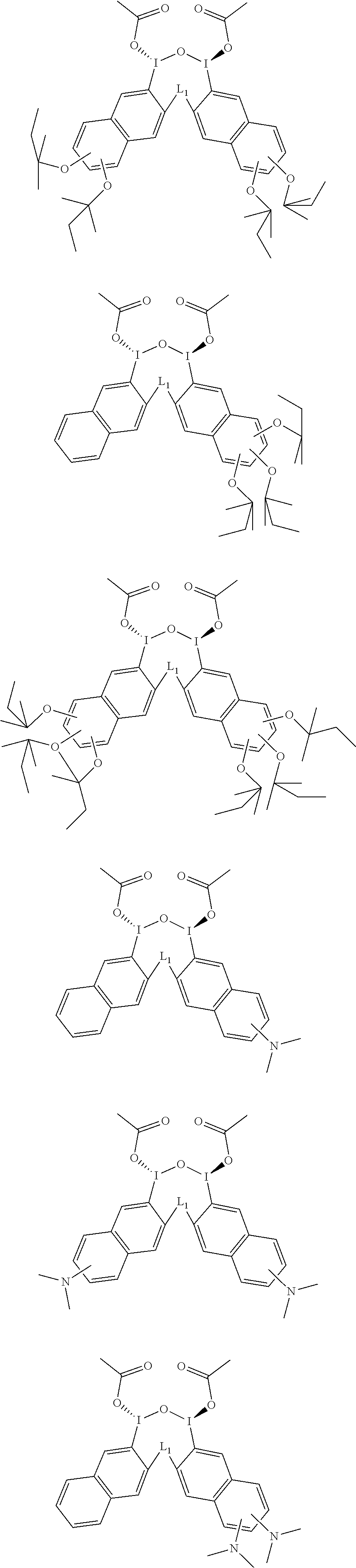

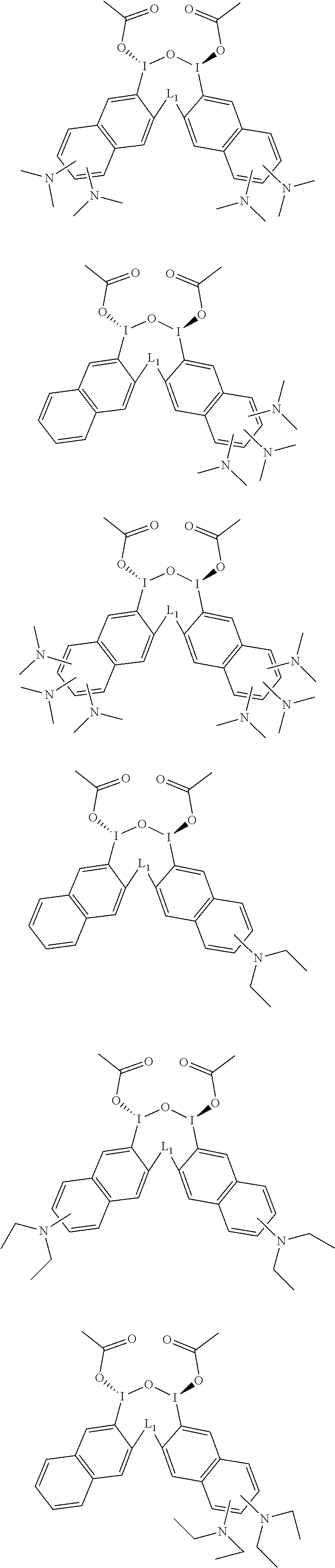

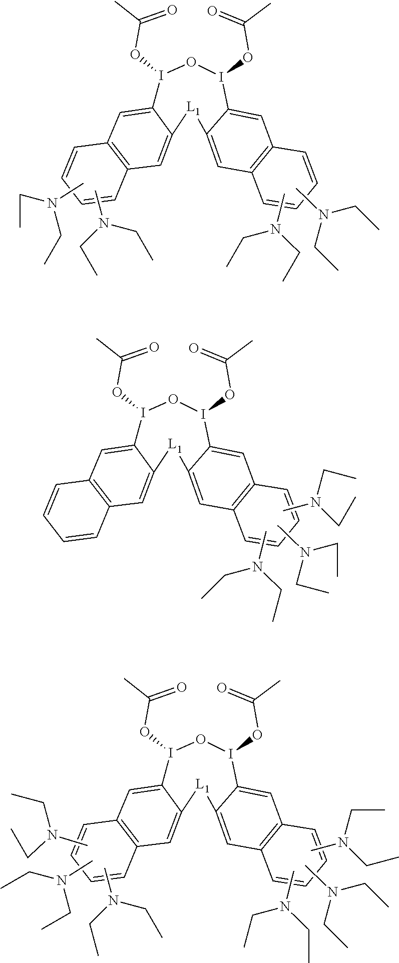

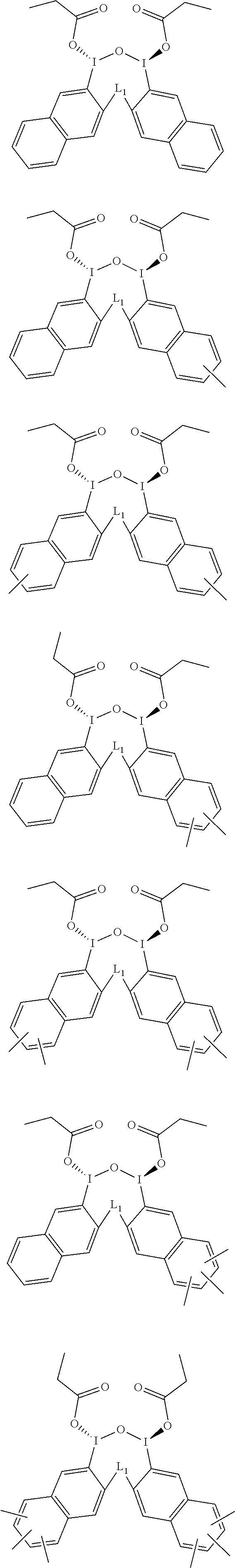

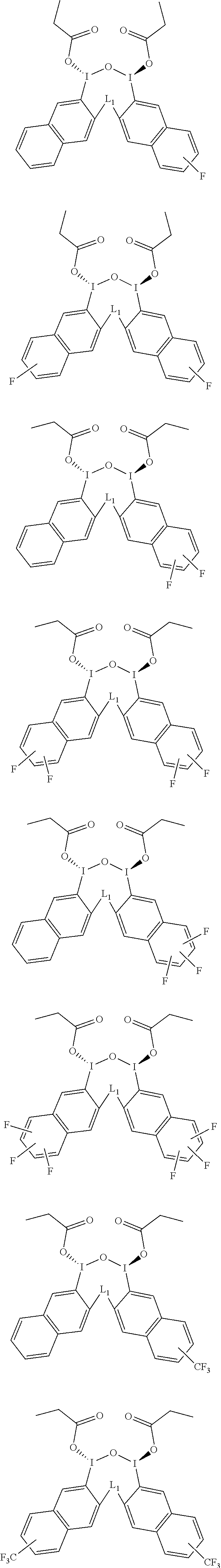

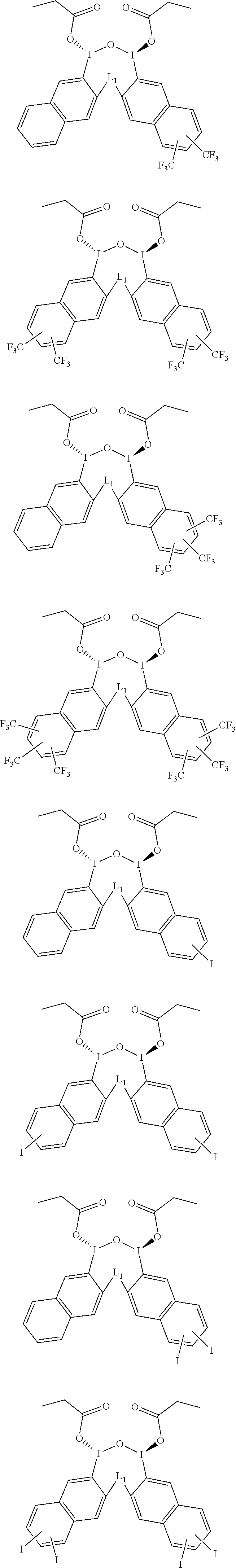

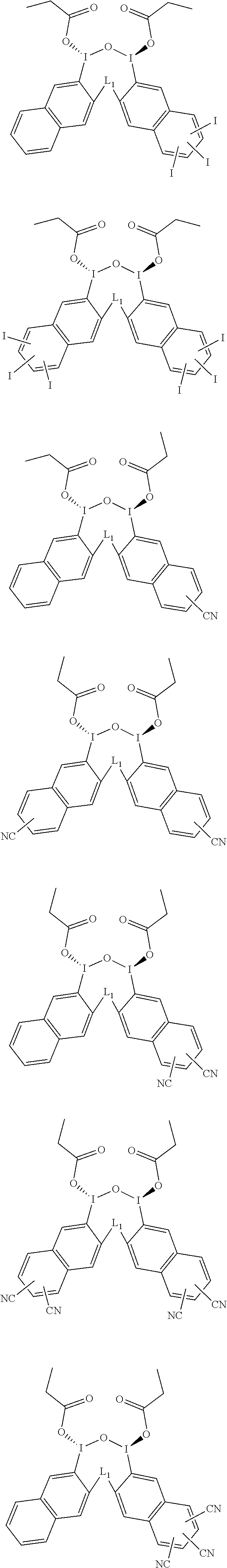

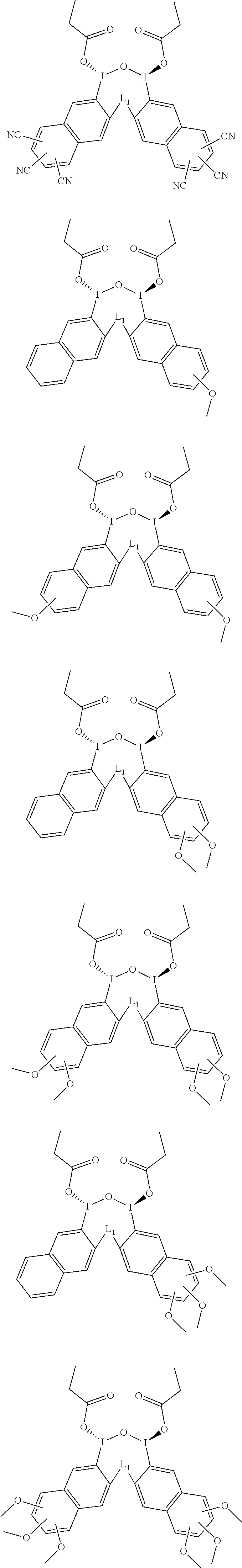

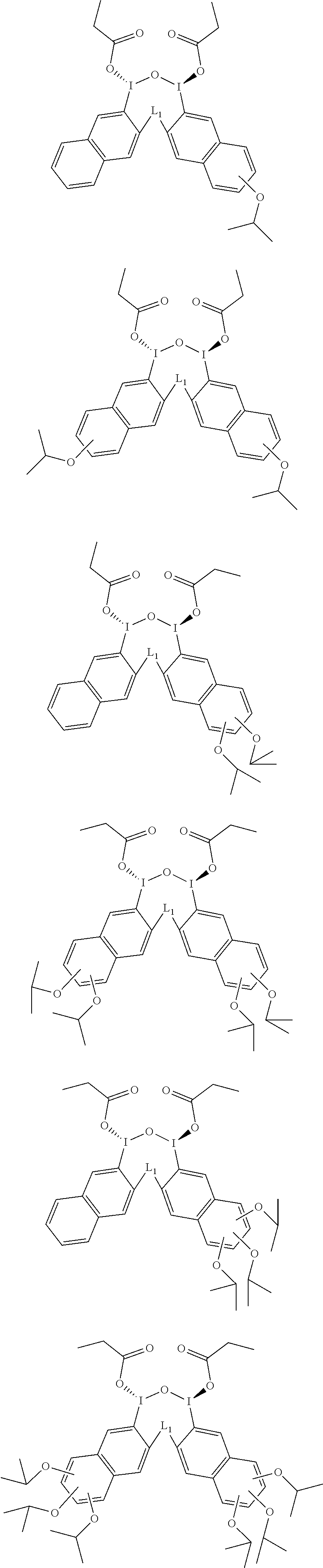

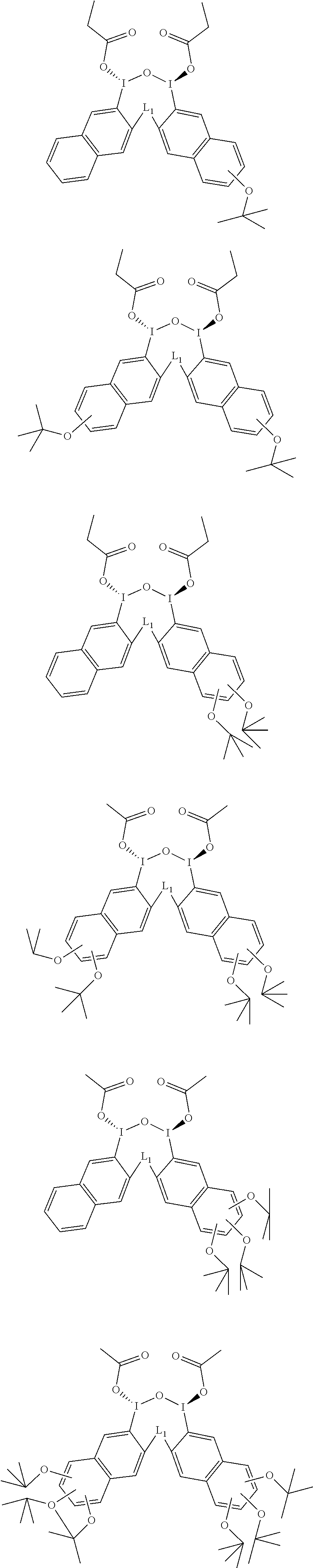

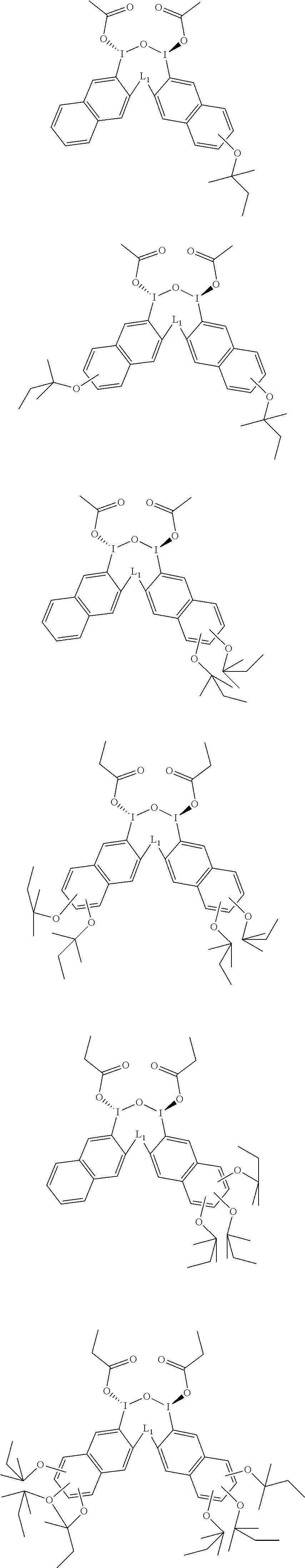

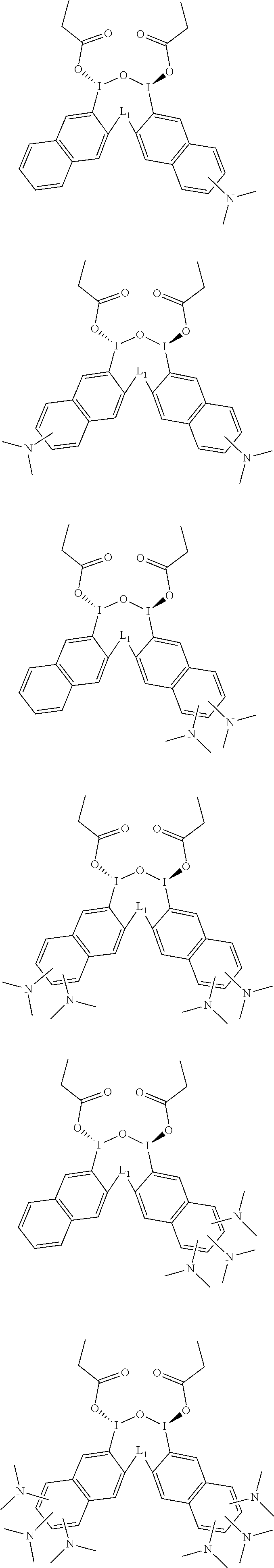

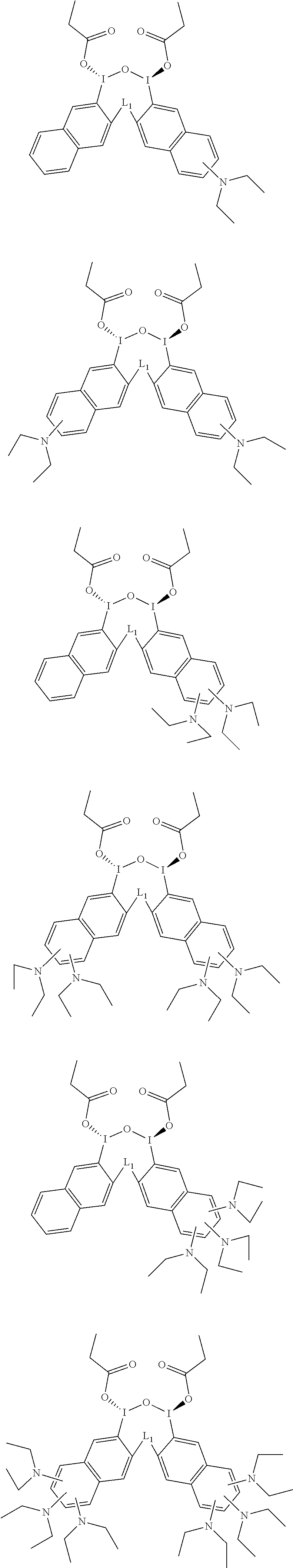

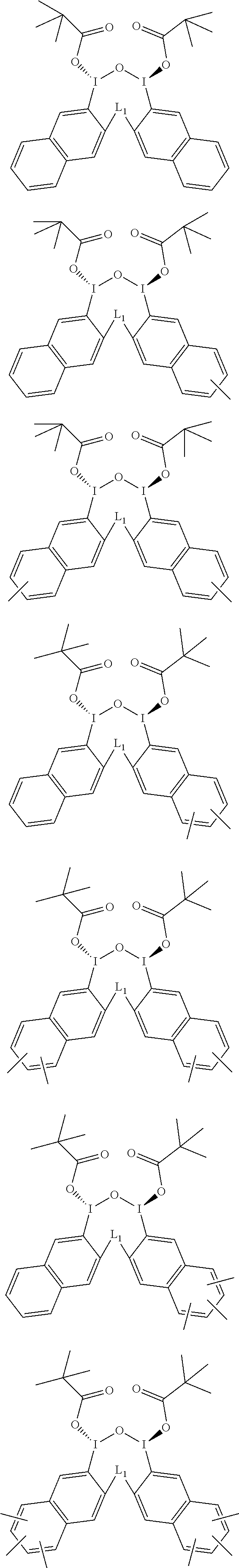

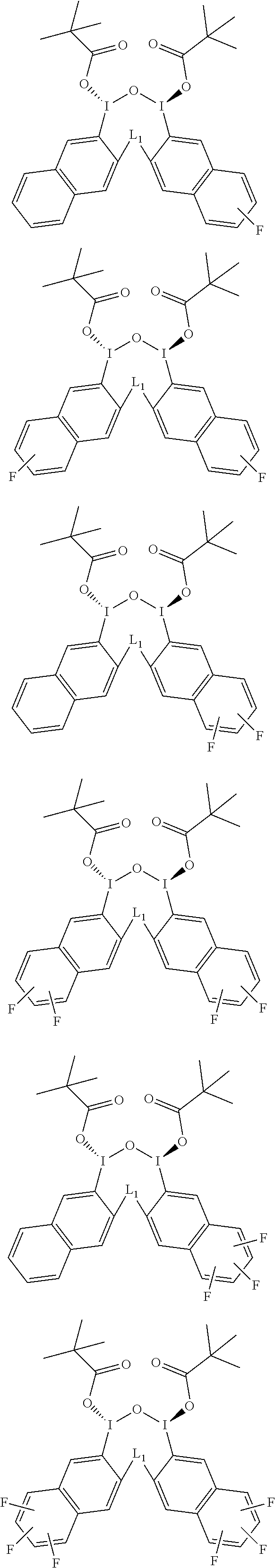

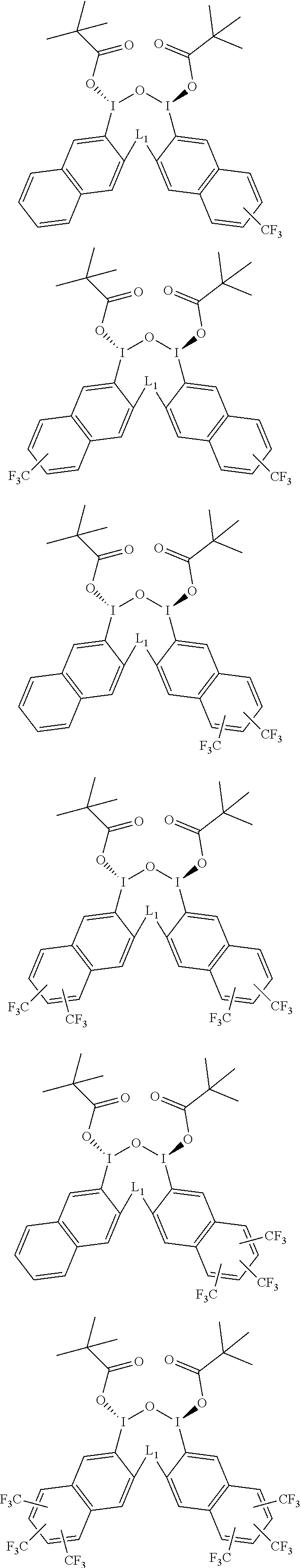

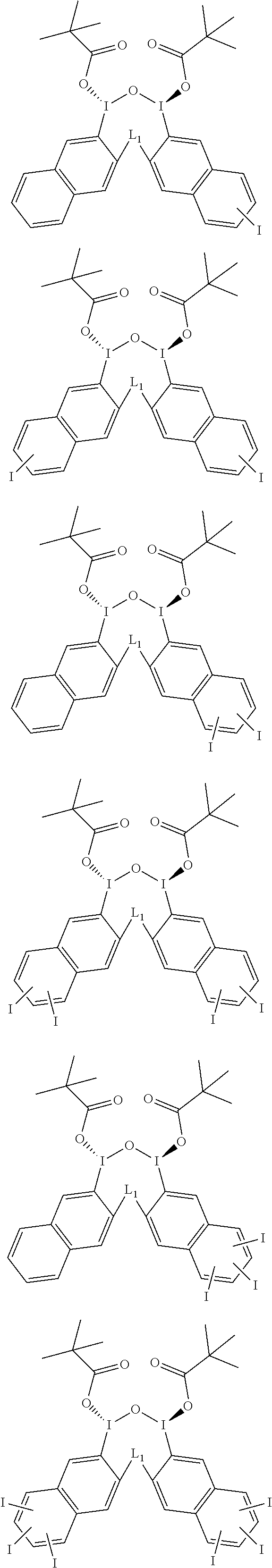

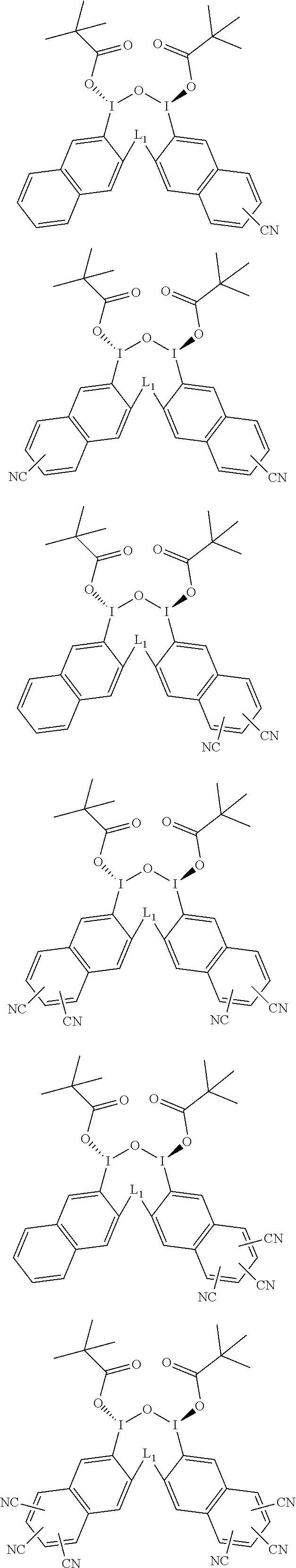

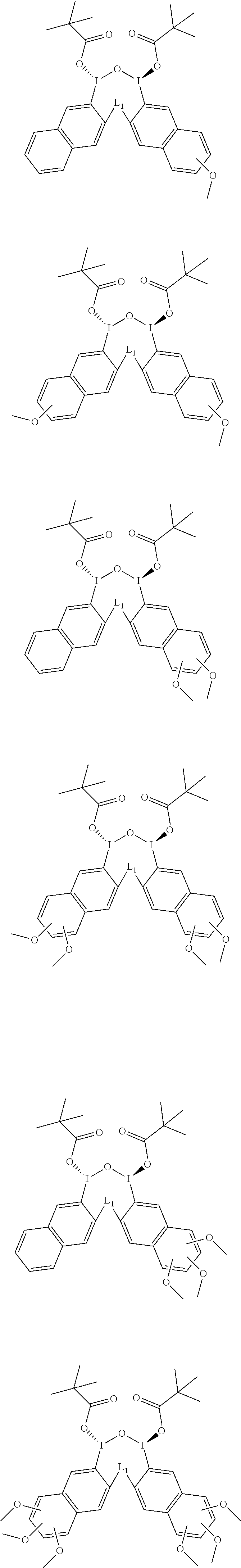

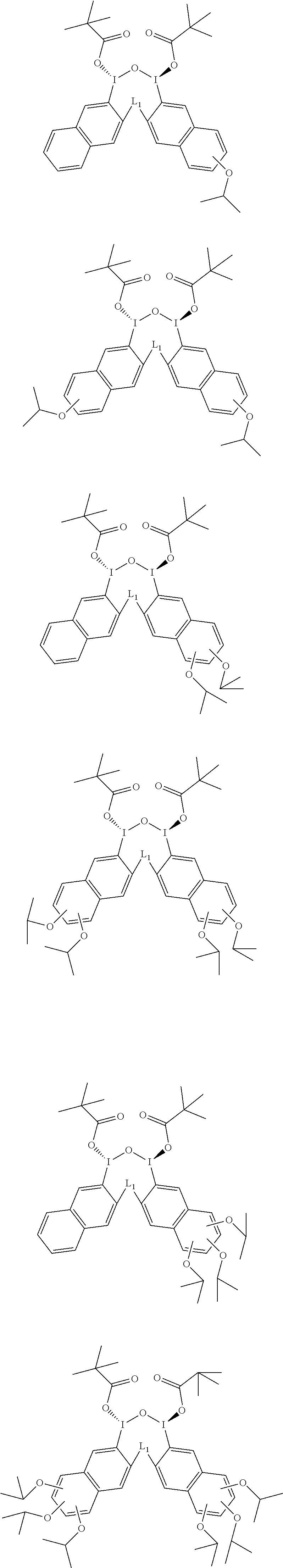

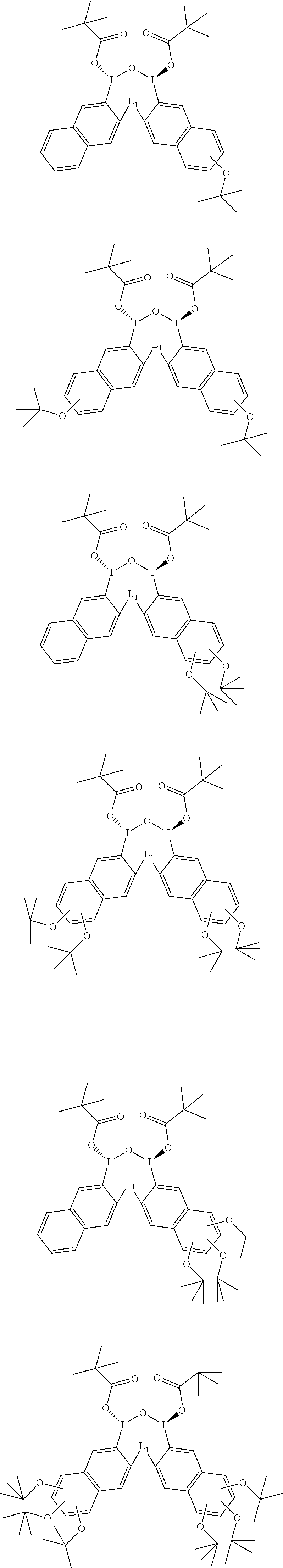

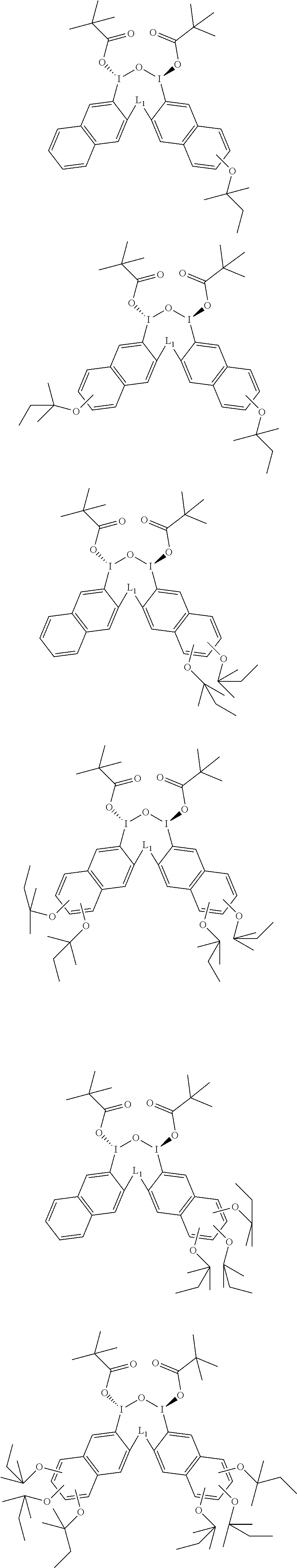

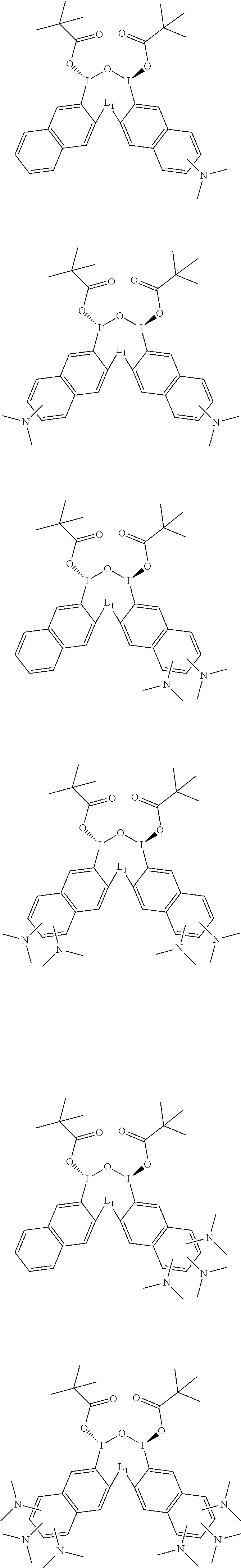

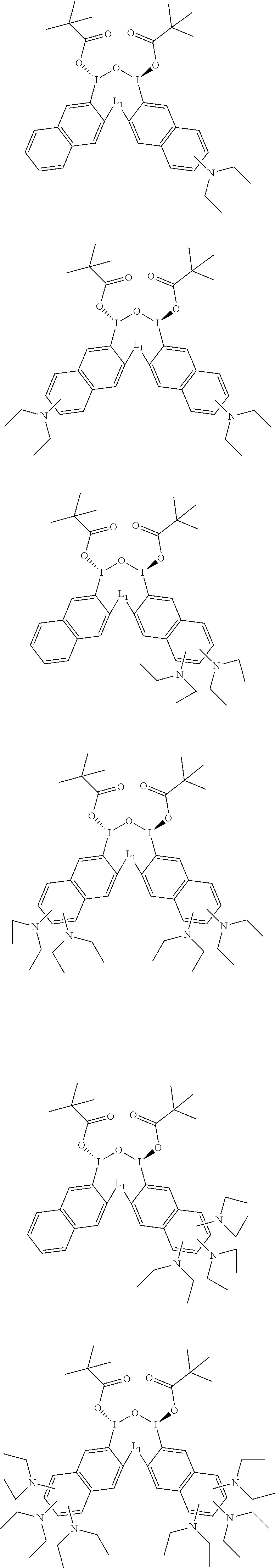

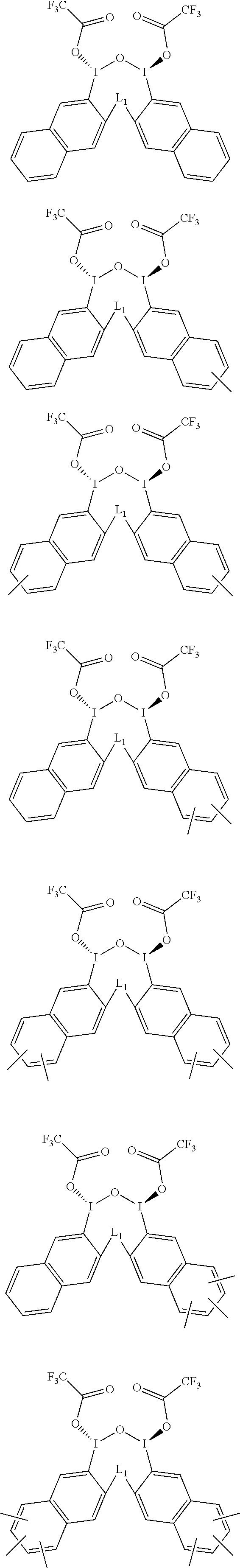

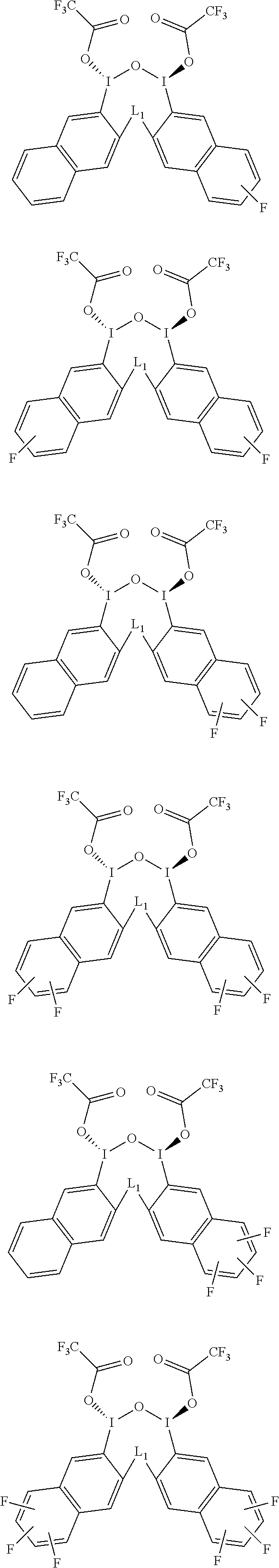

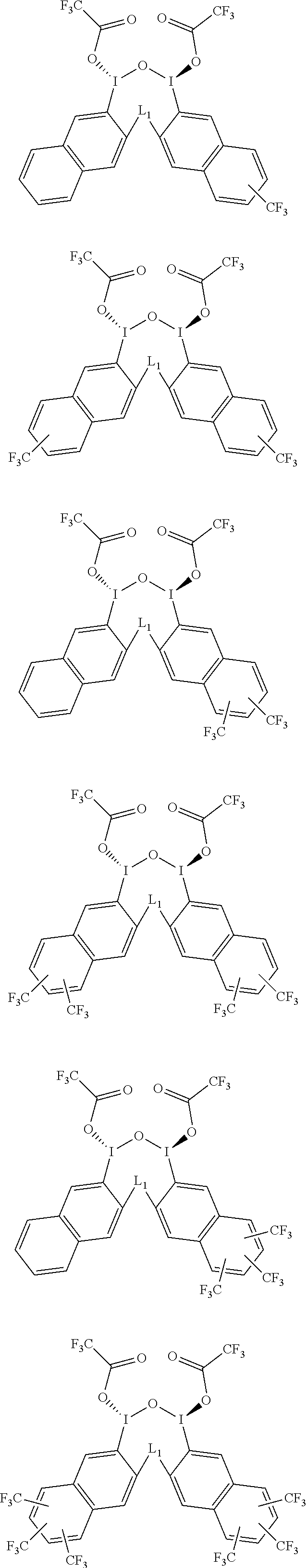

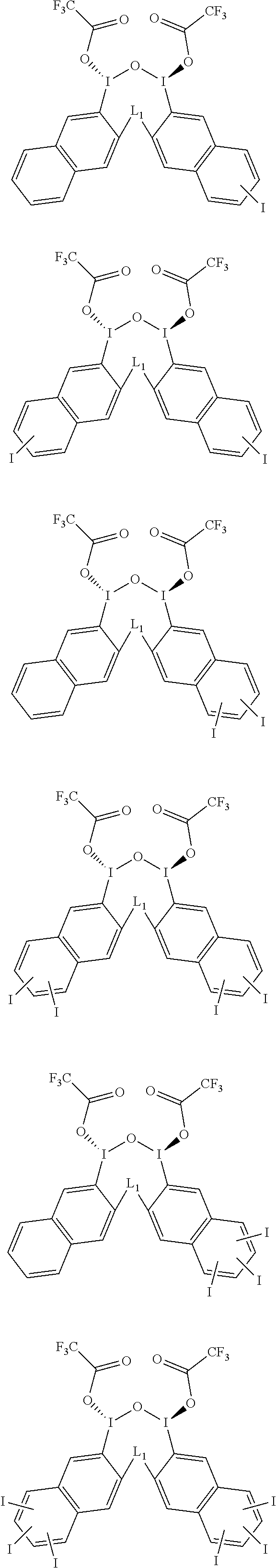

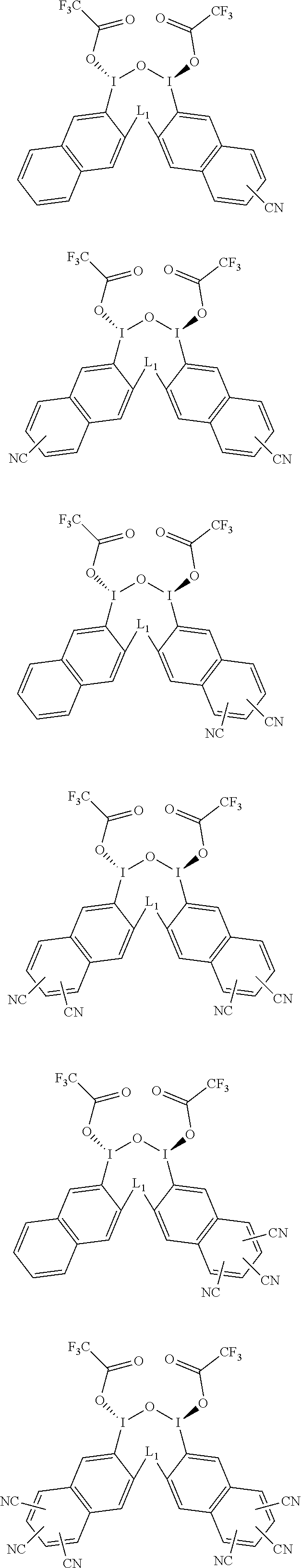

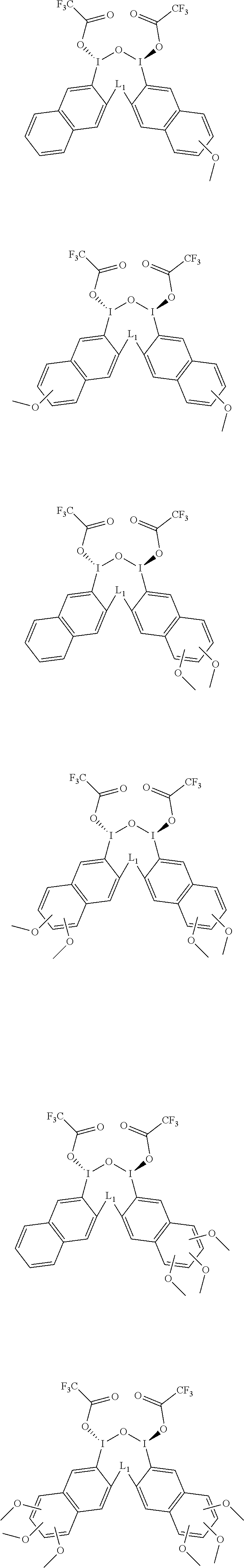

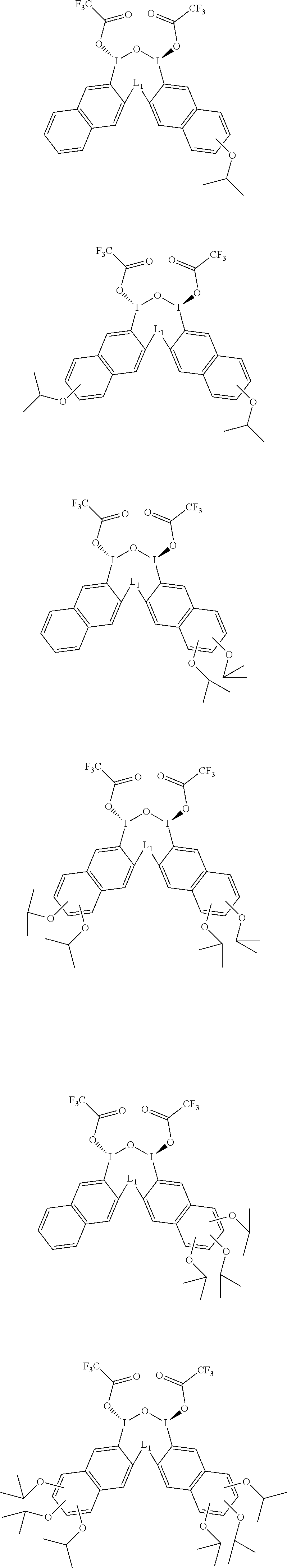

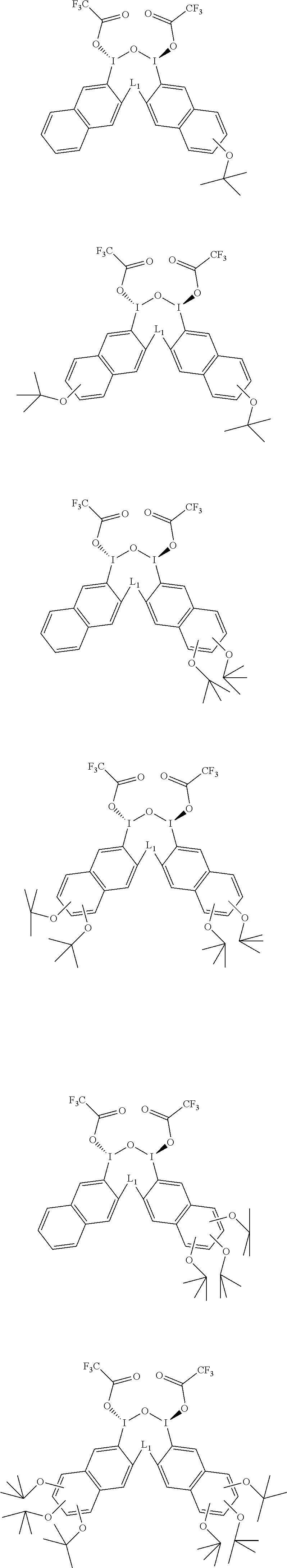

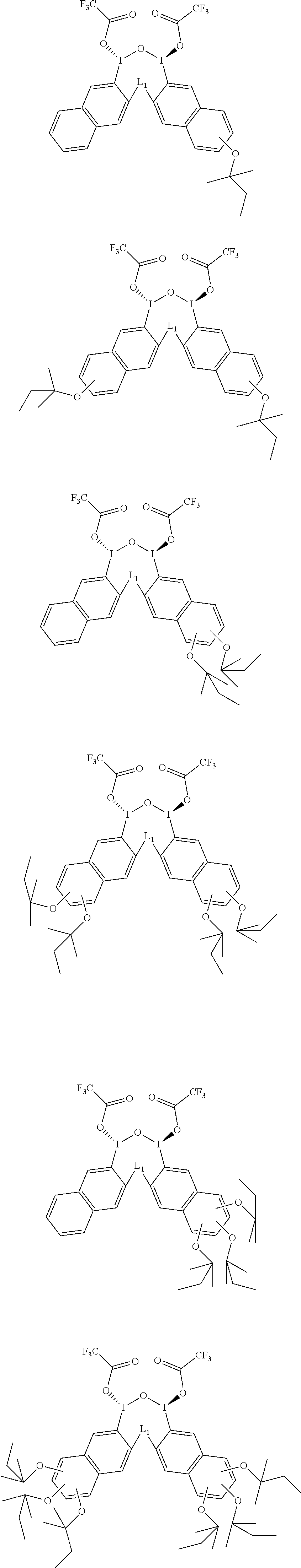

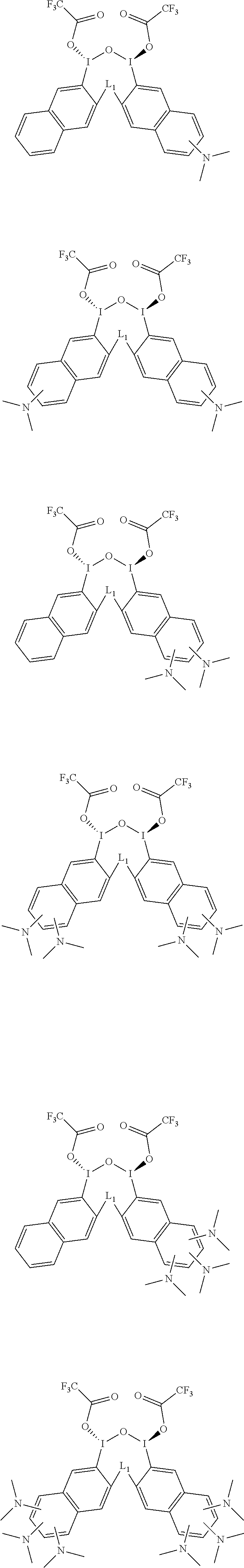

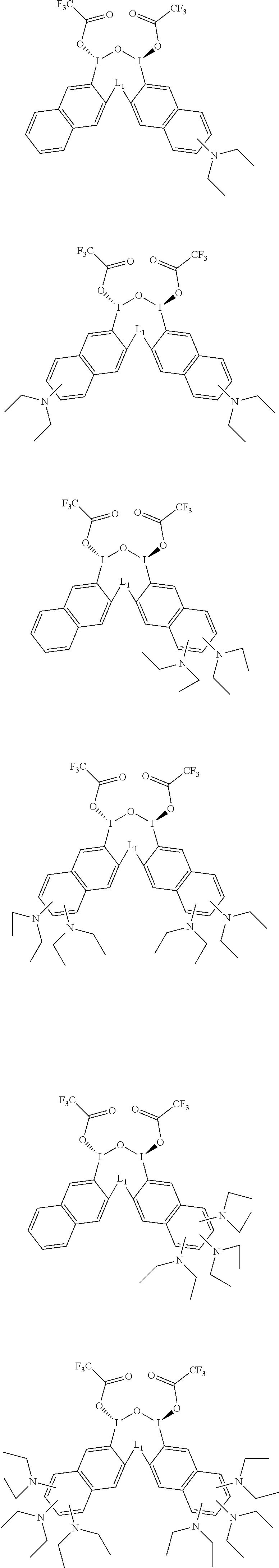

Specific examples of the hypervalent iodine compound represented by the general formula (7) include, but are not limited to, the following.

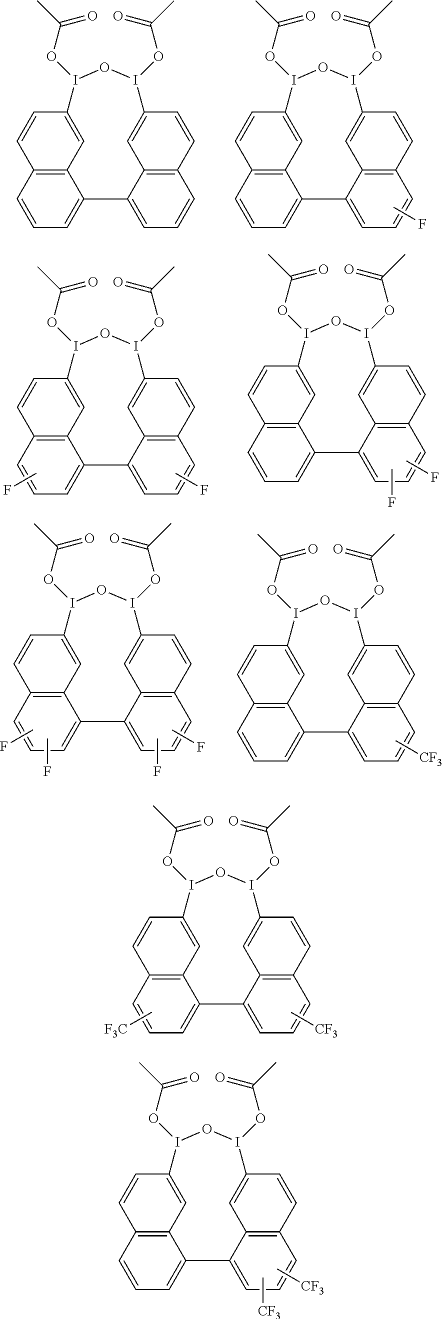

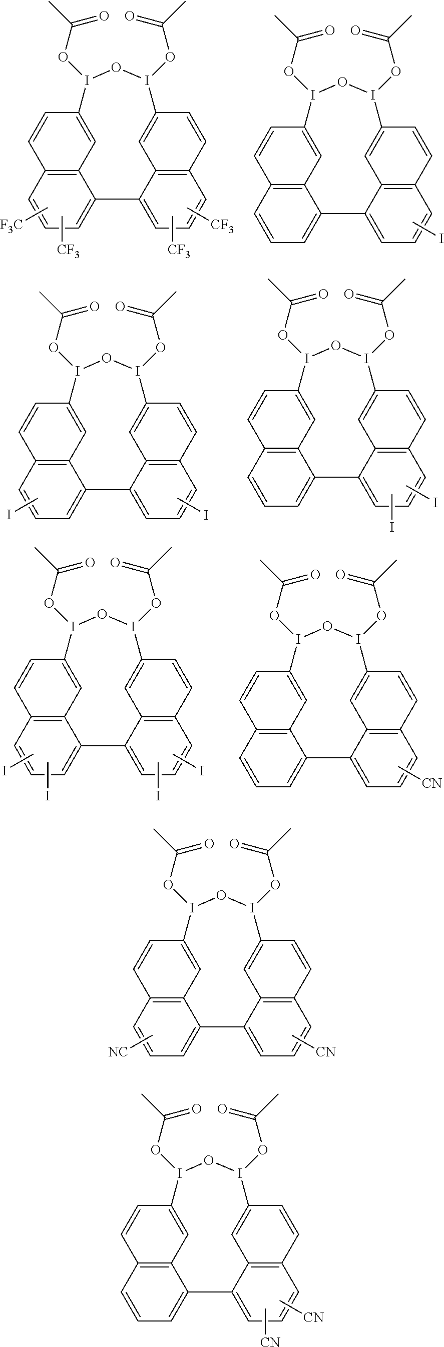

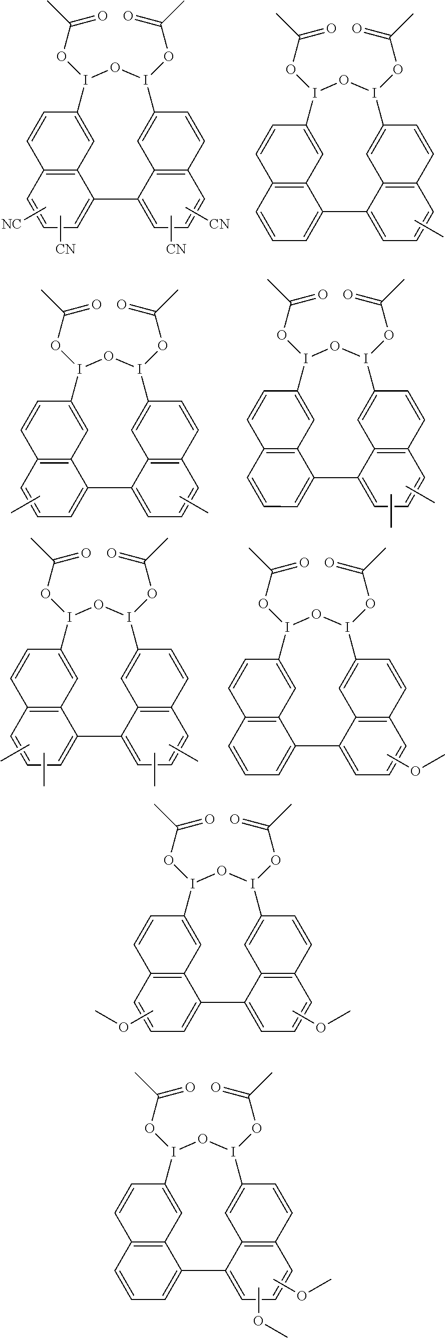

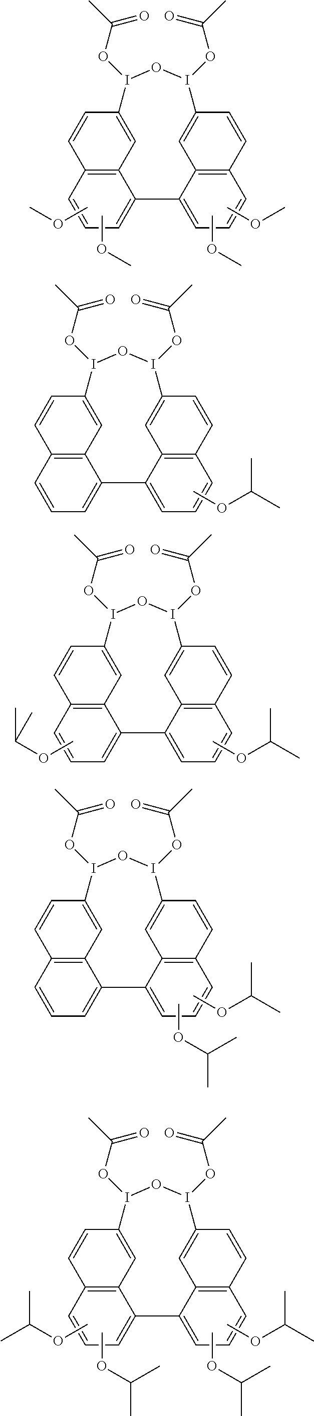

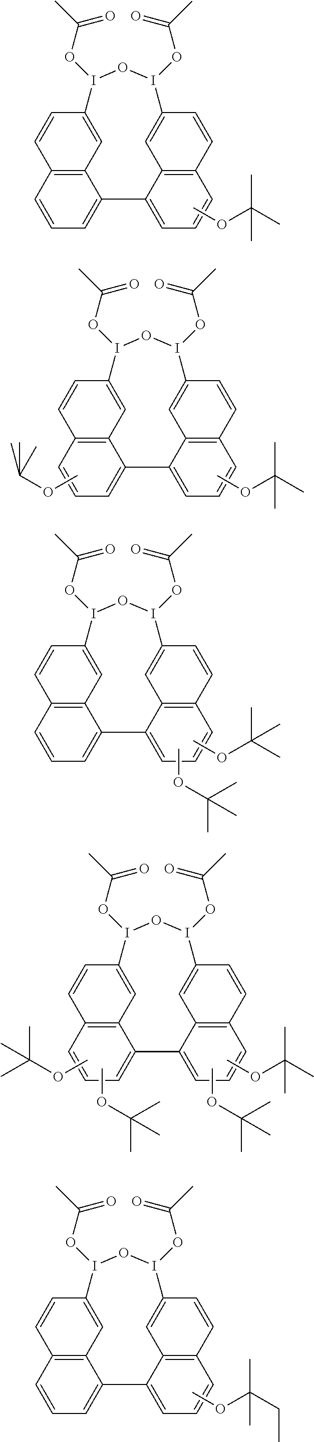

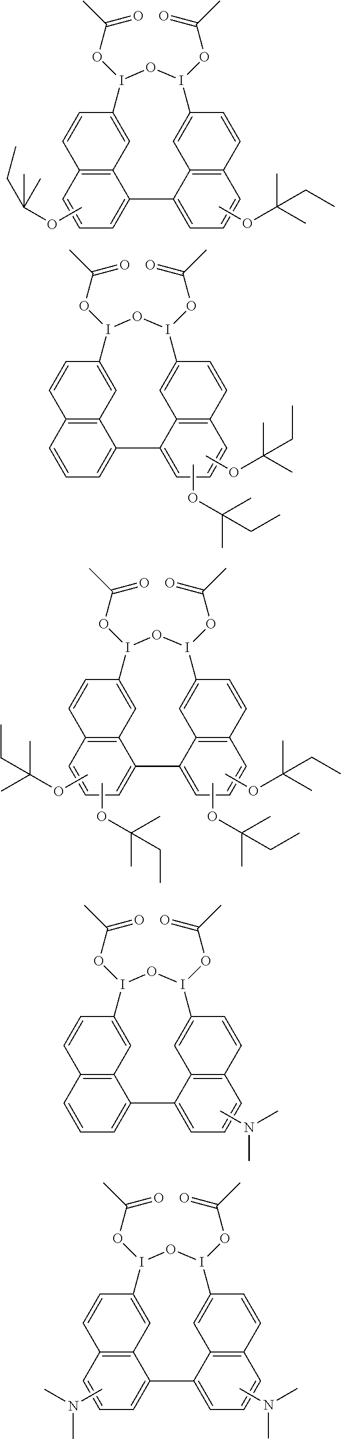

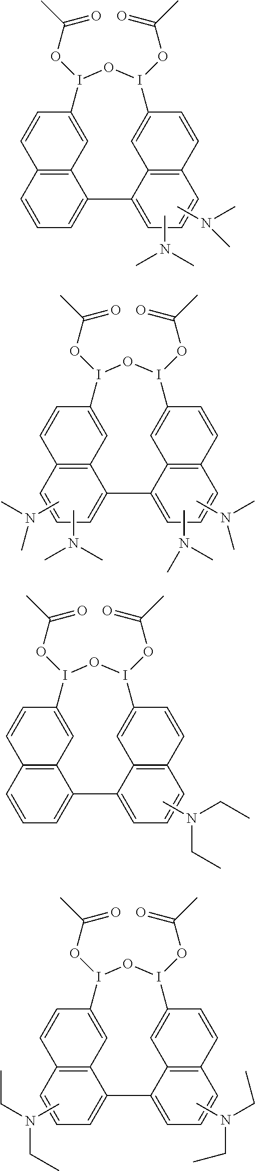

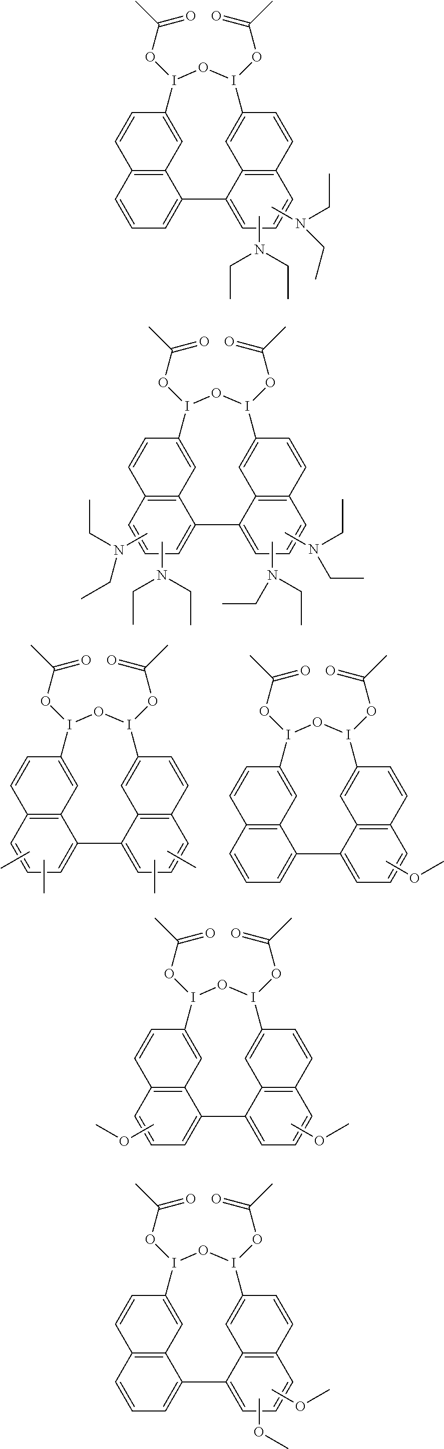

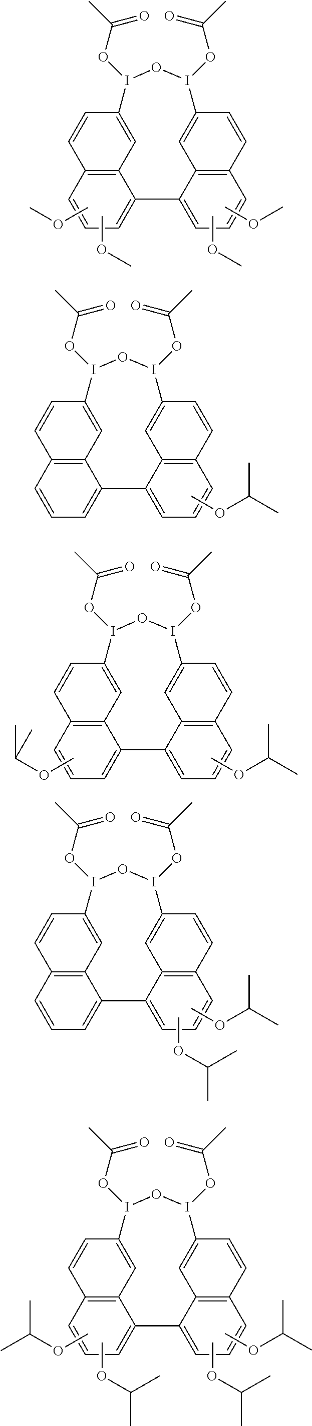

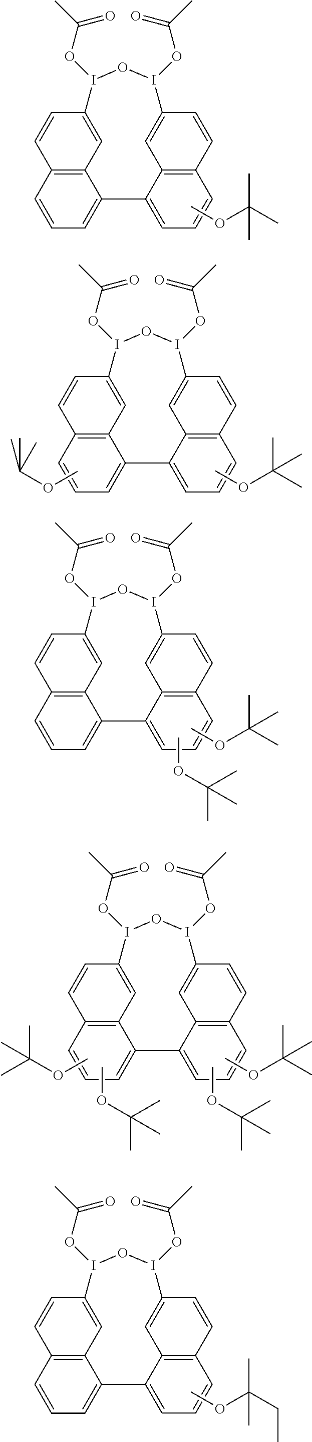

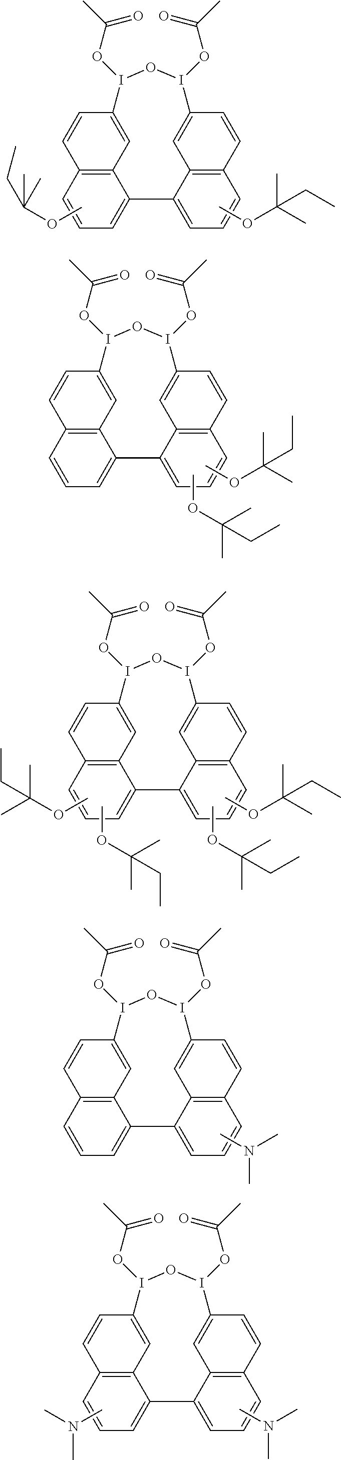

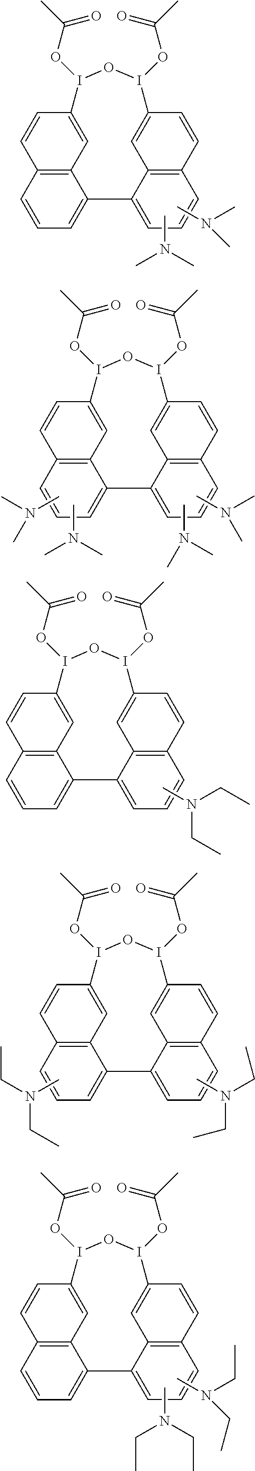

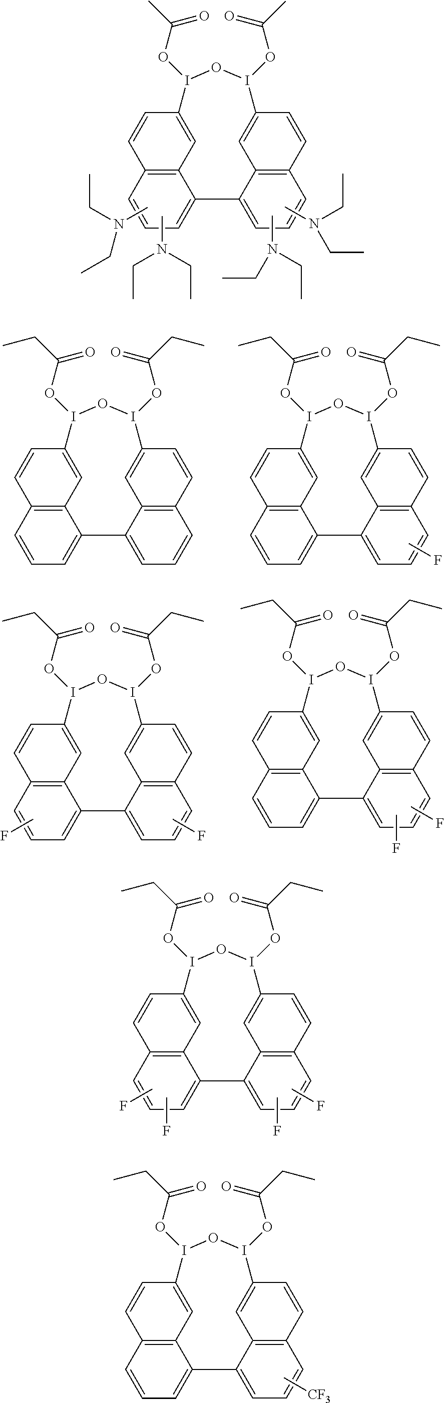

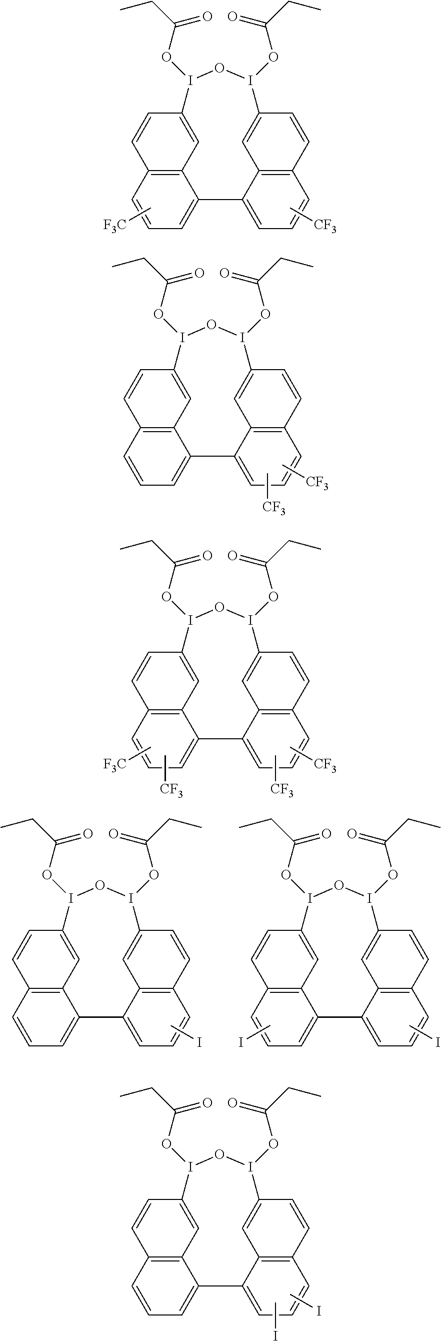

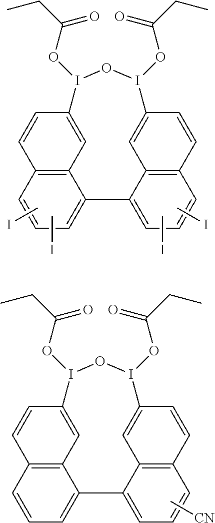

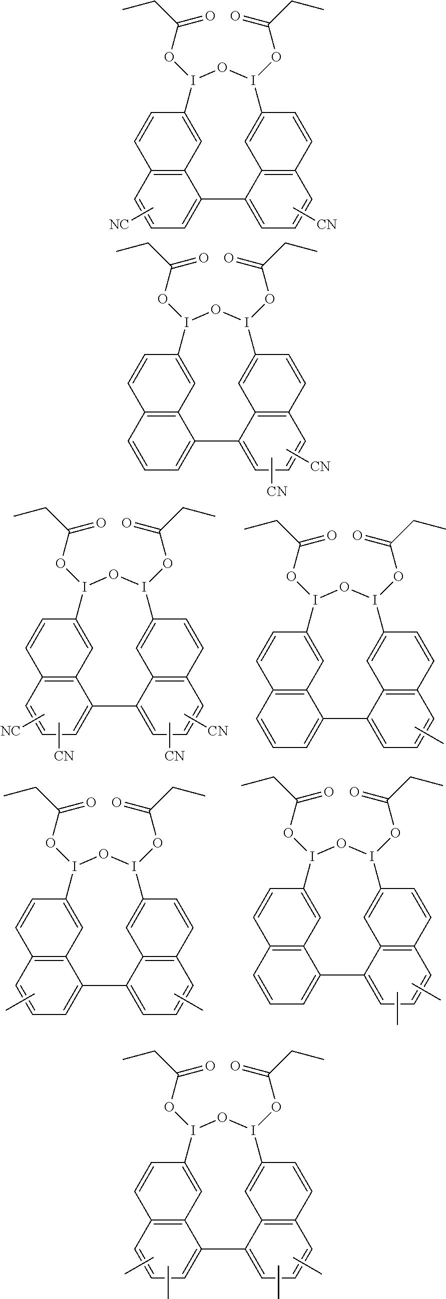

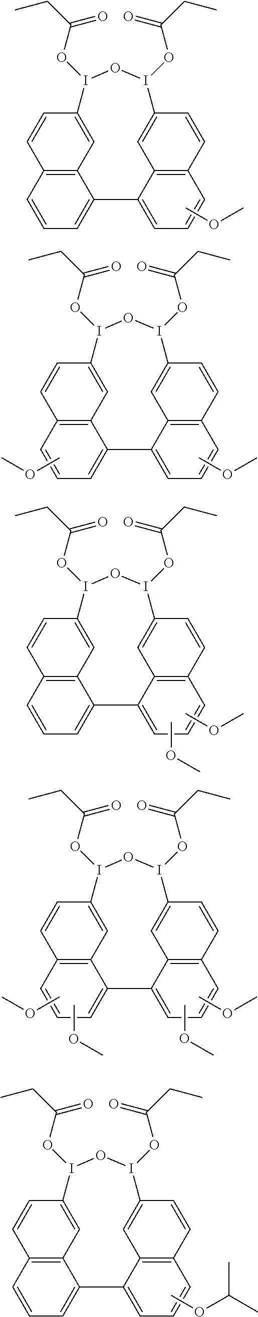

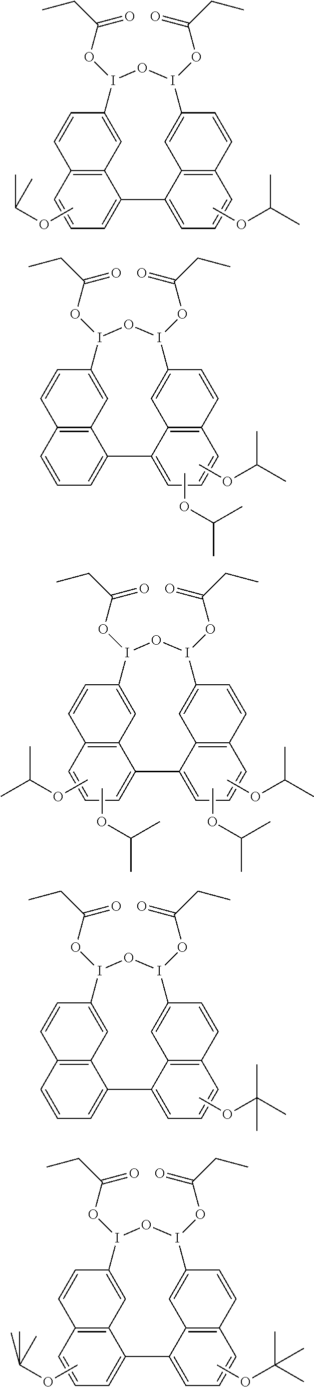

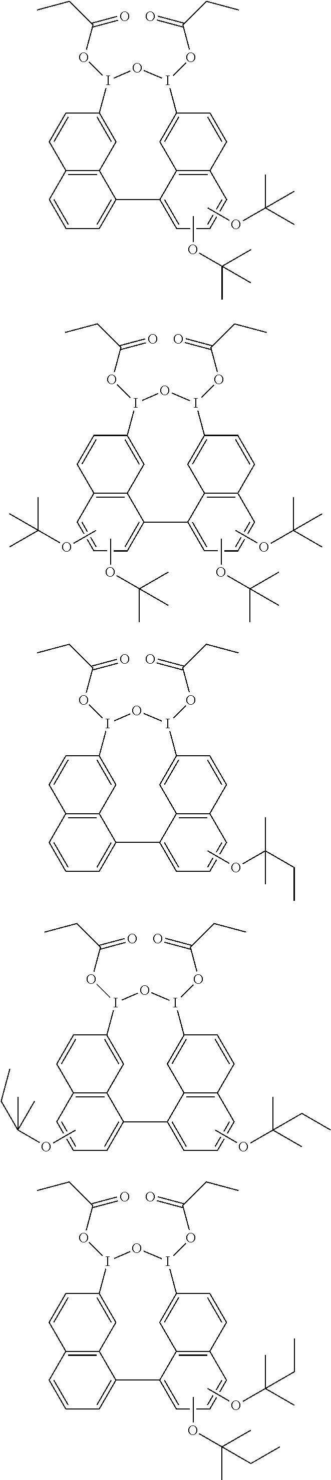

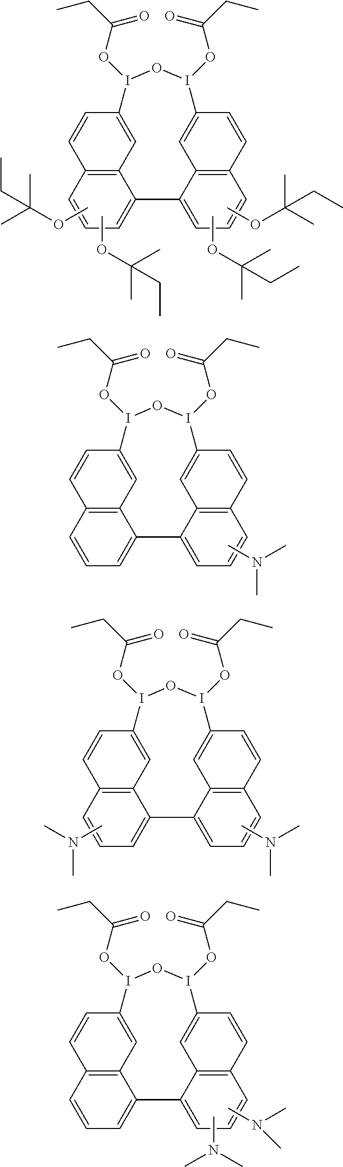

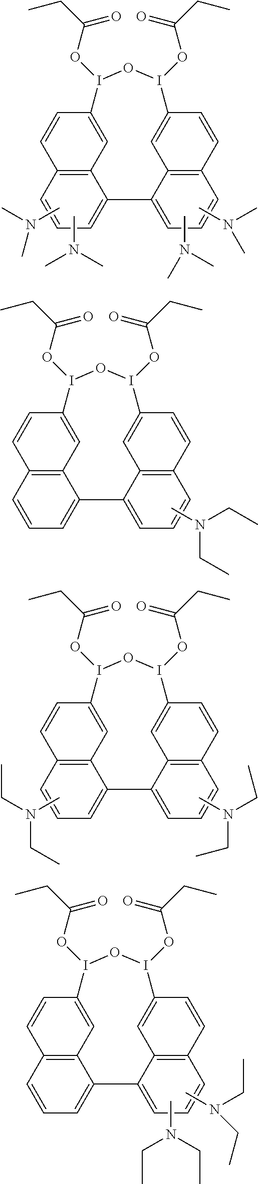

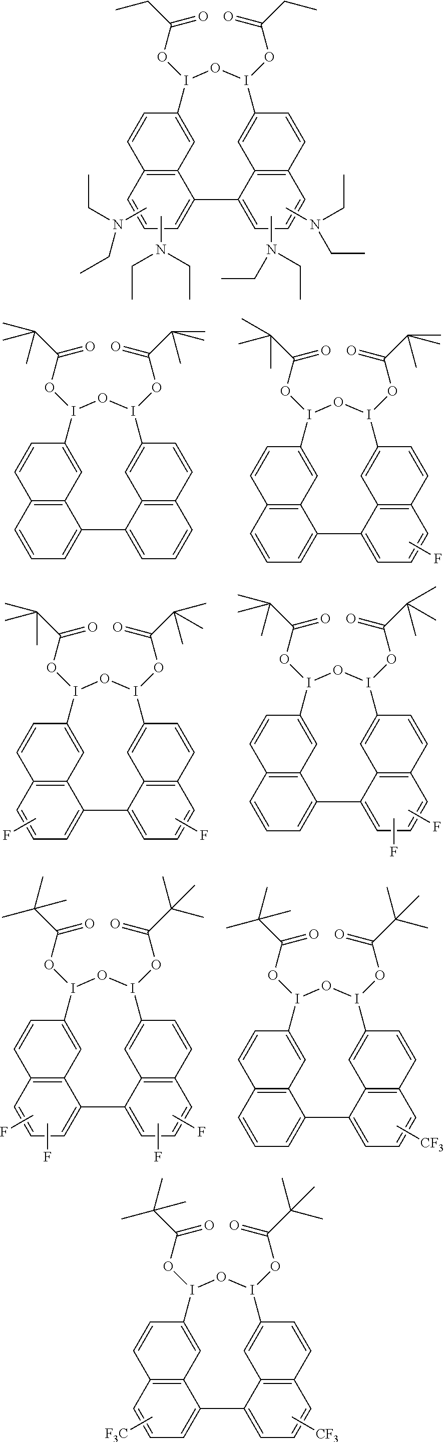

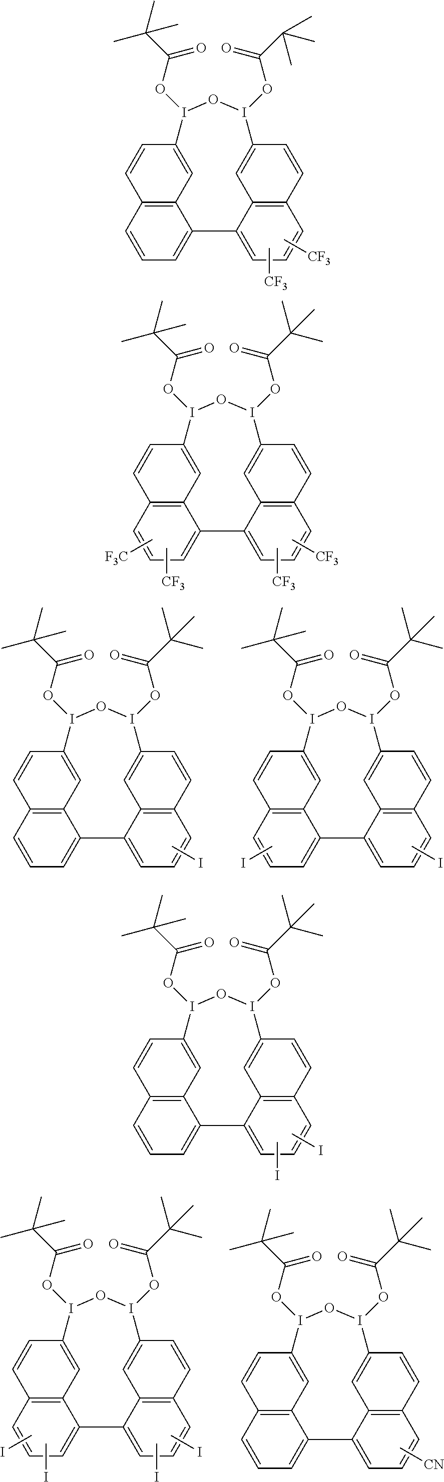

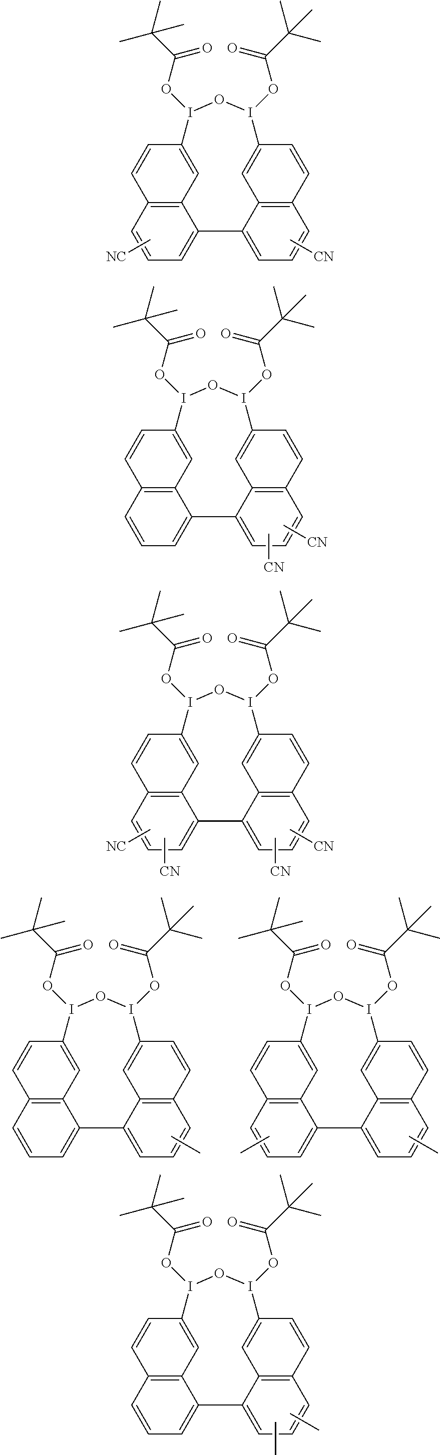

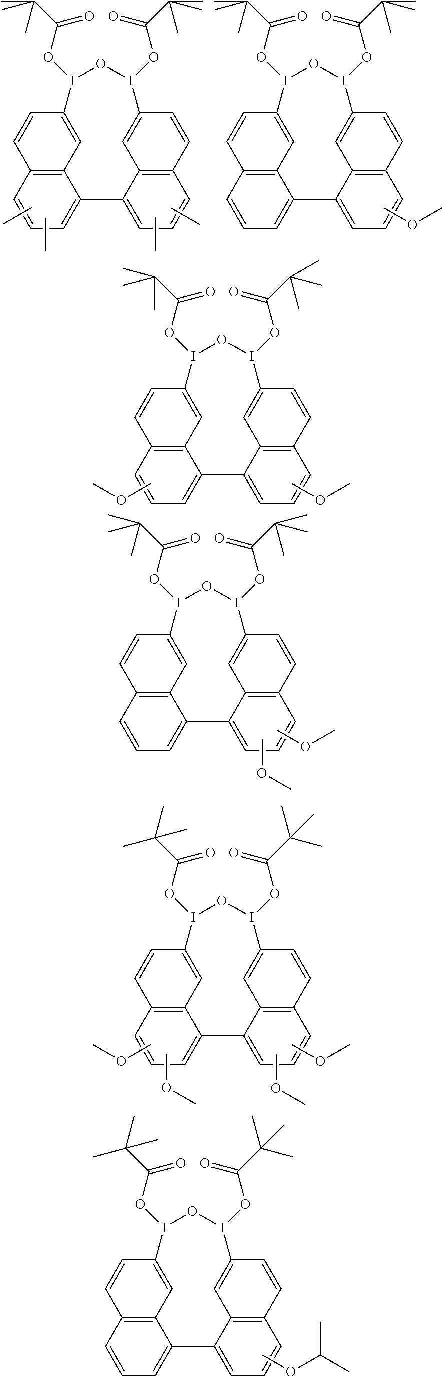

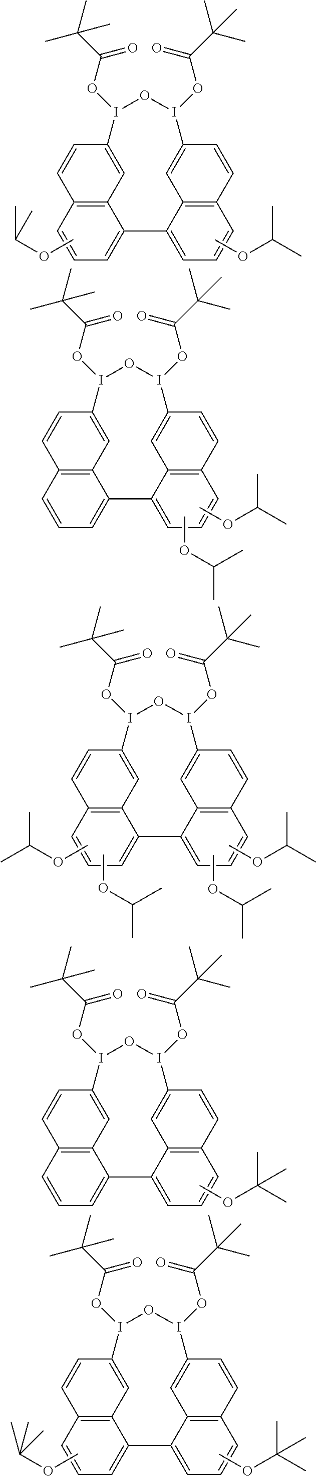

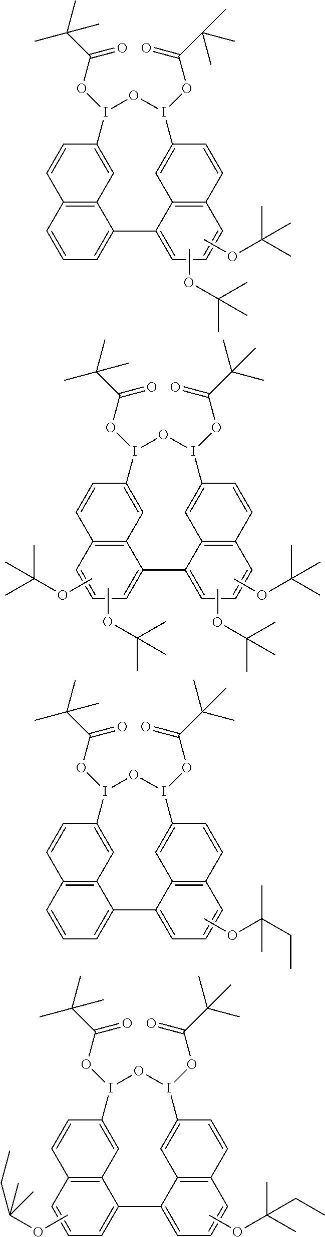

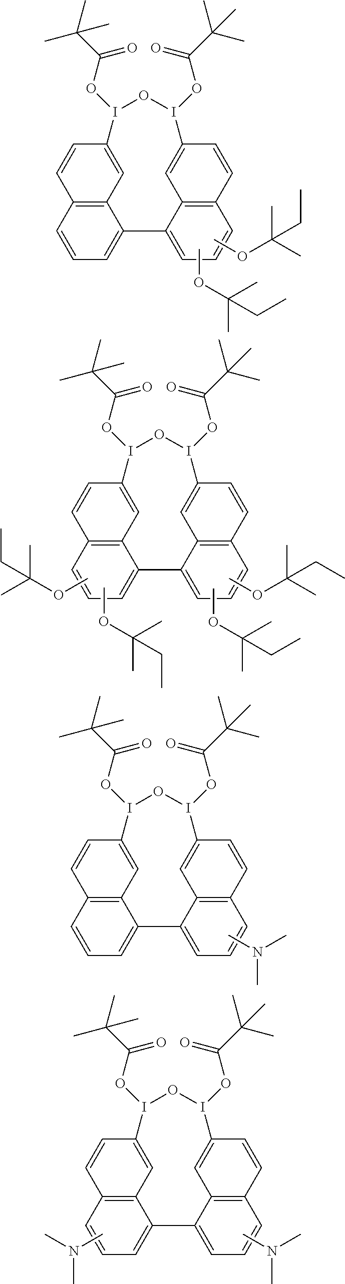

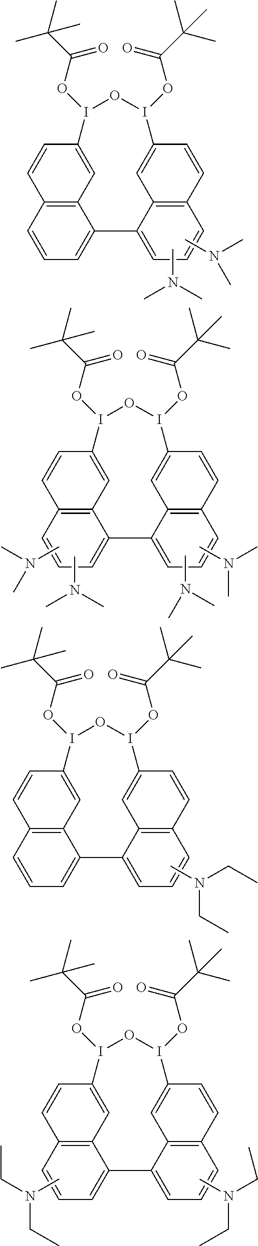

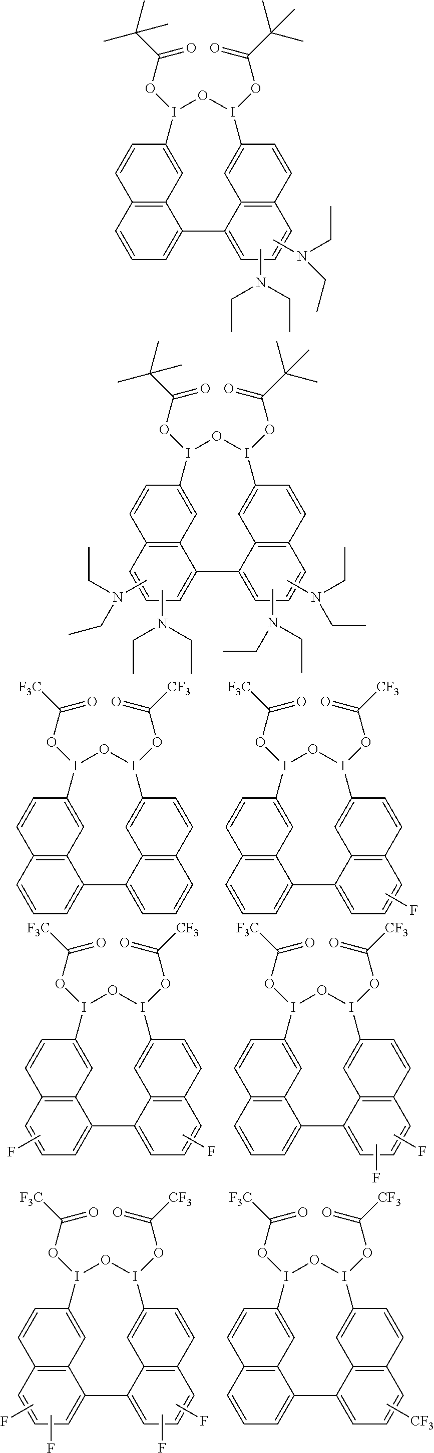

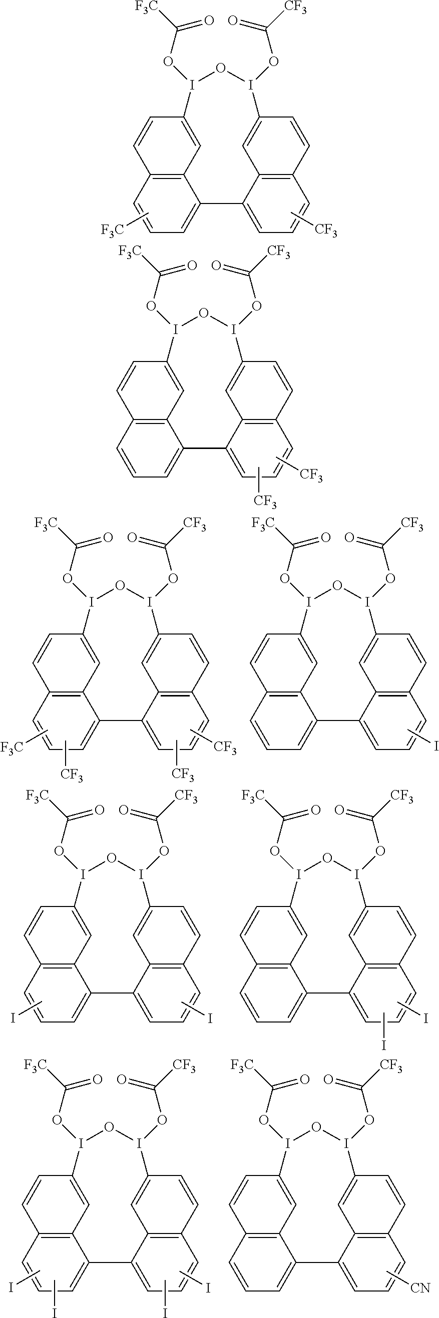

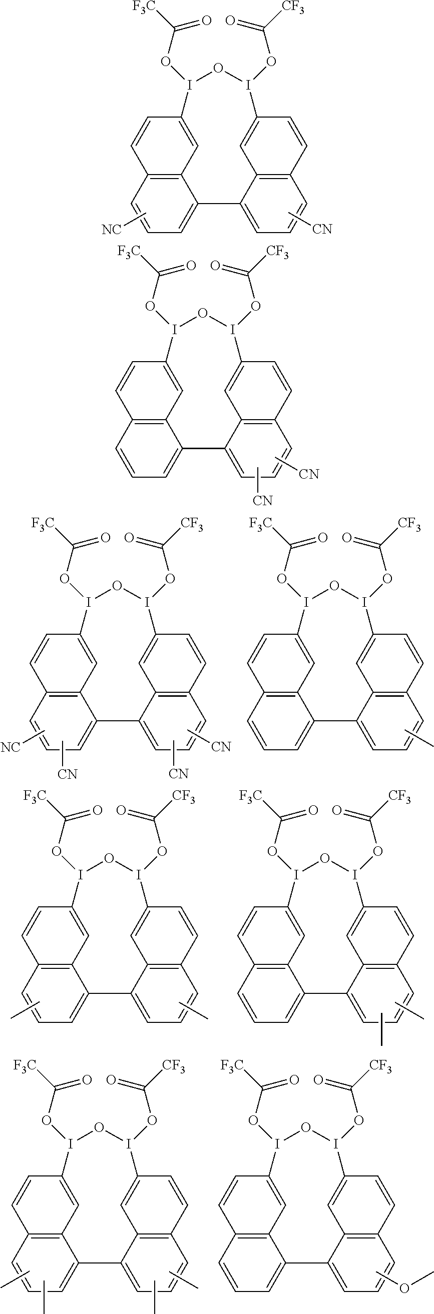

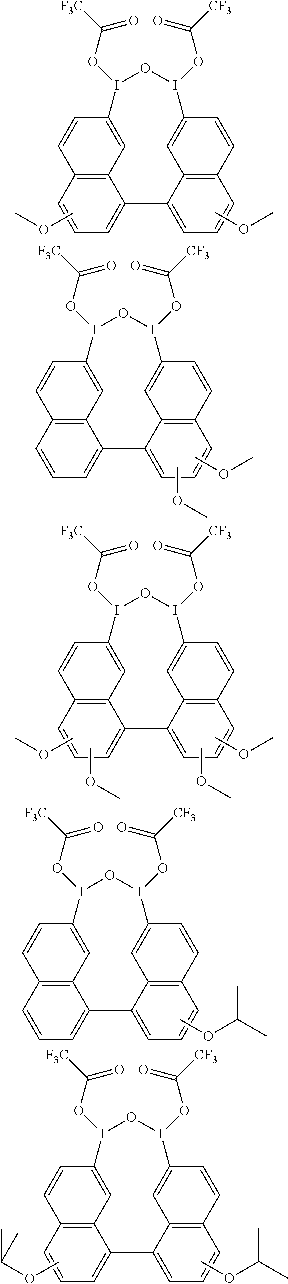

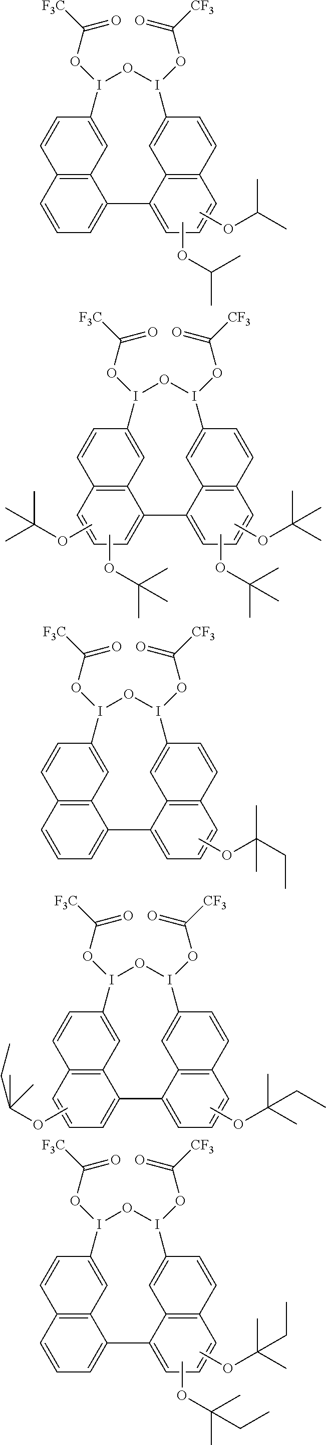

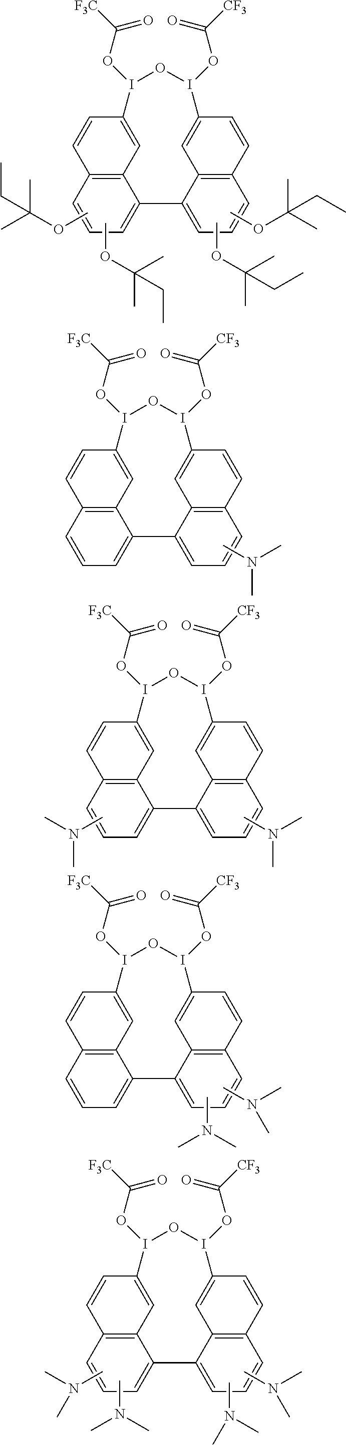

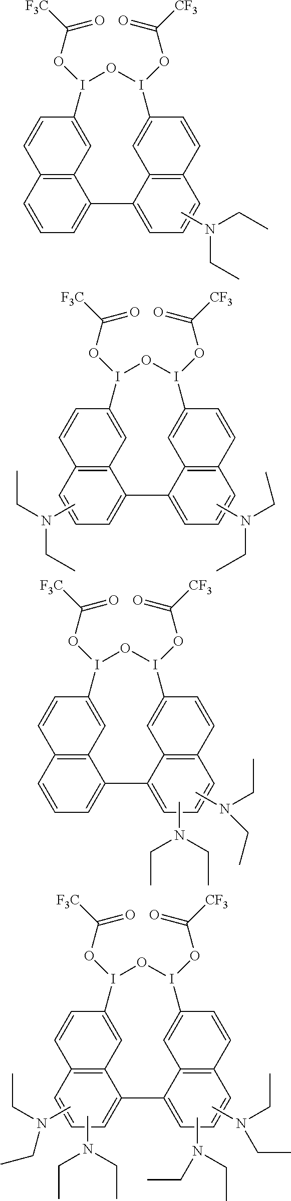

Specific examples of the hypervalent iodine compound represented by the general formula (8) include, but are not limited to, the following.

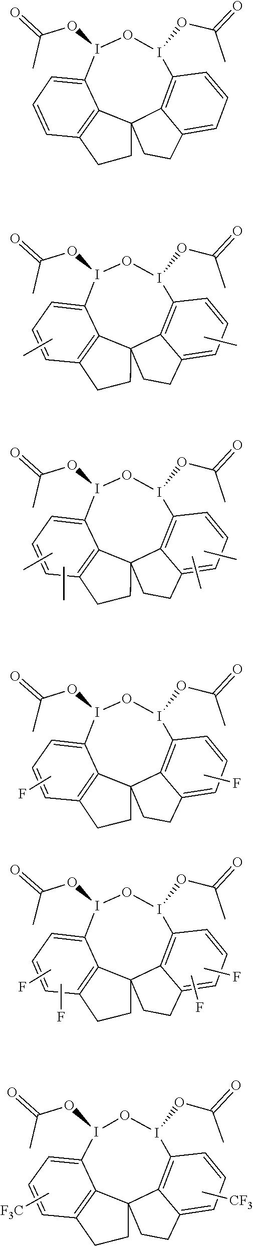

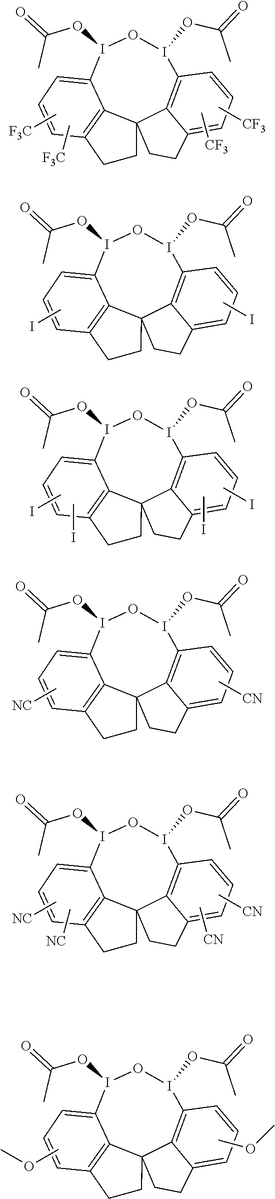

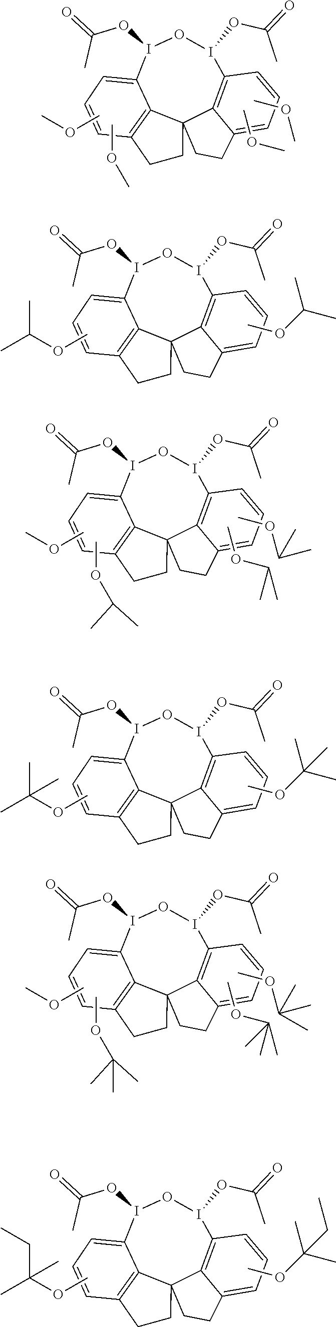

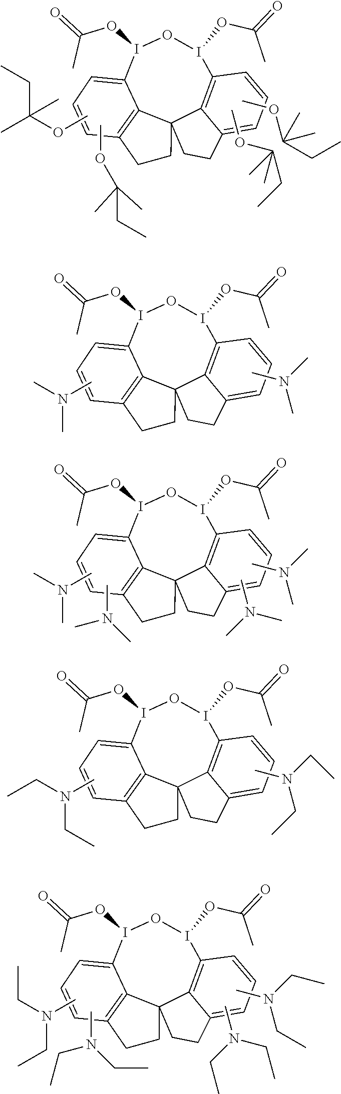

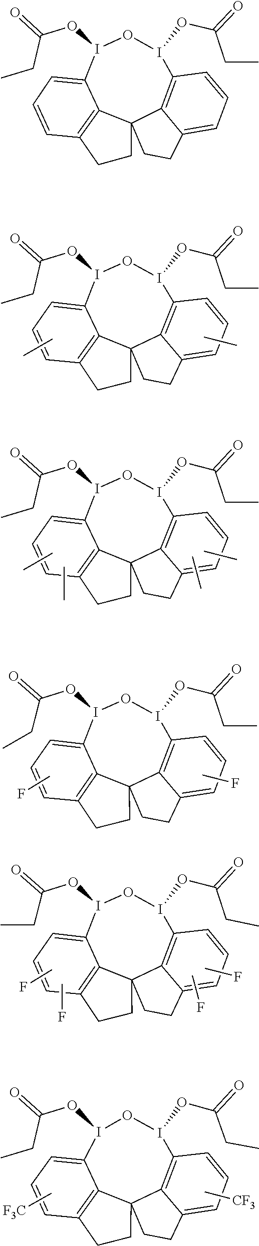

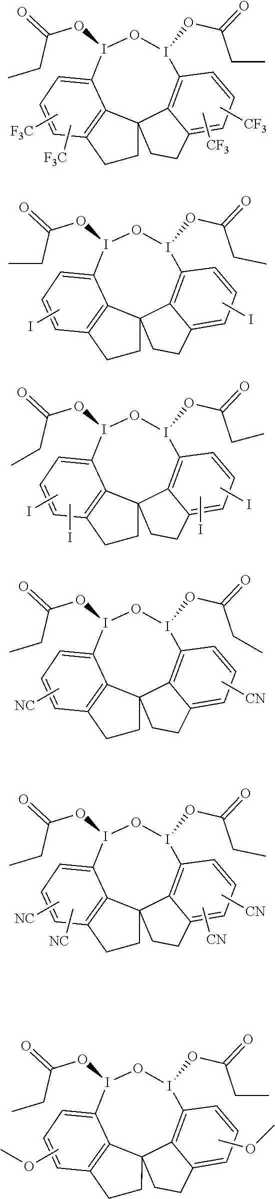

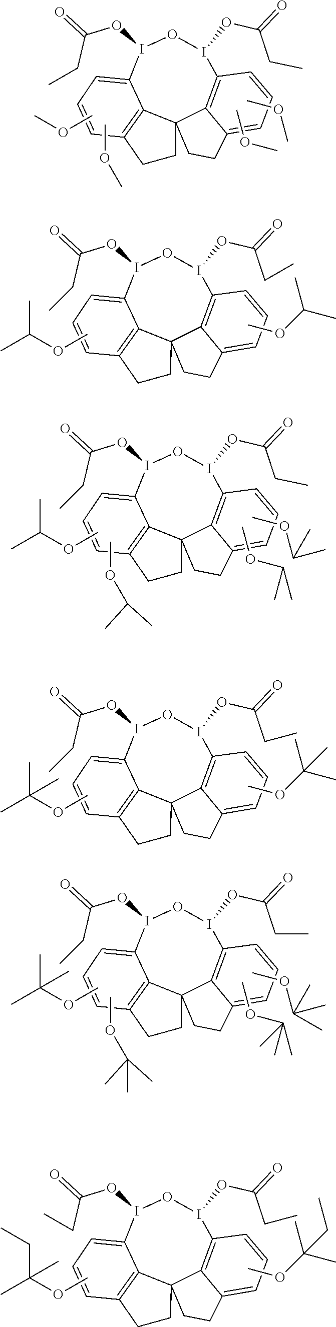

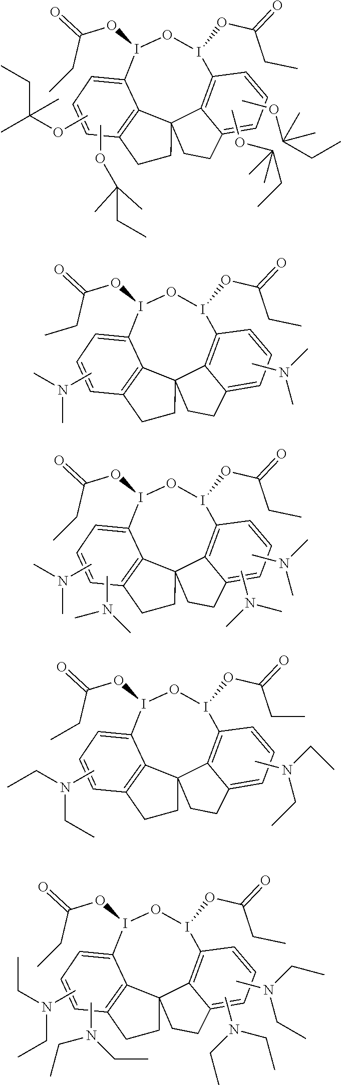

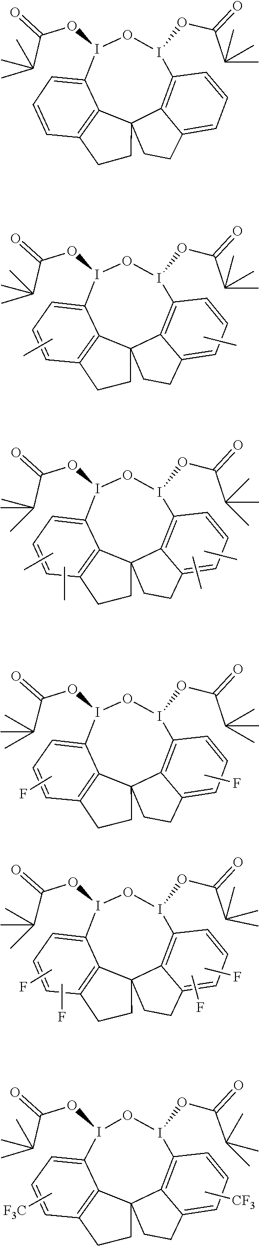

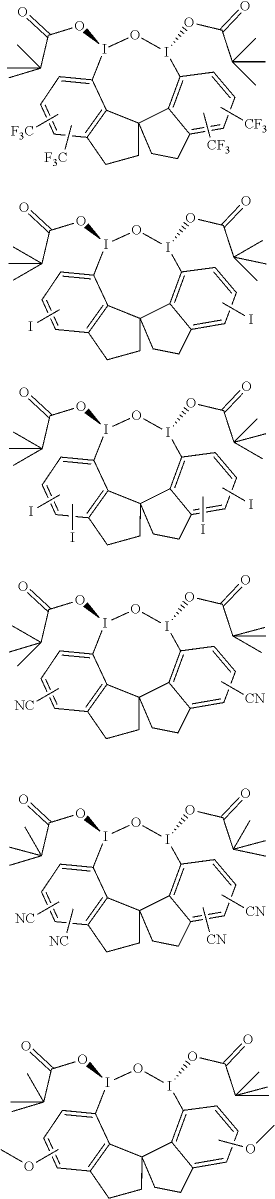

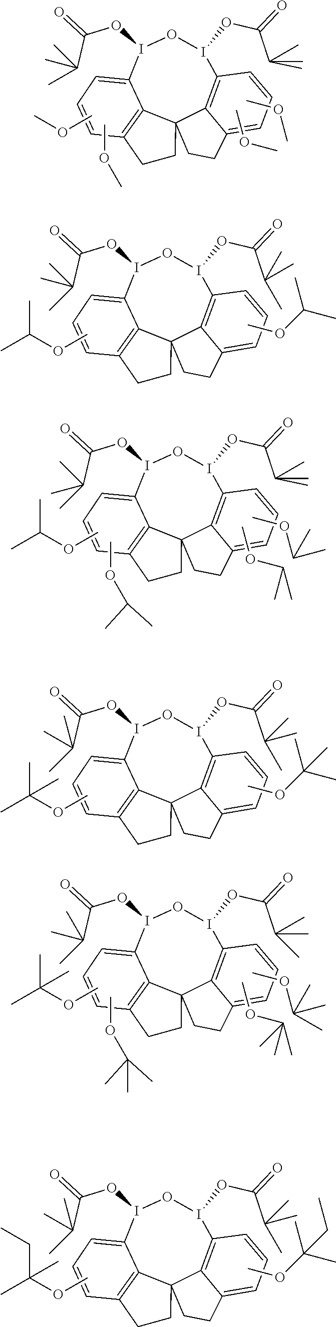

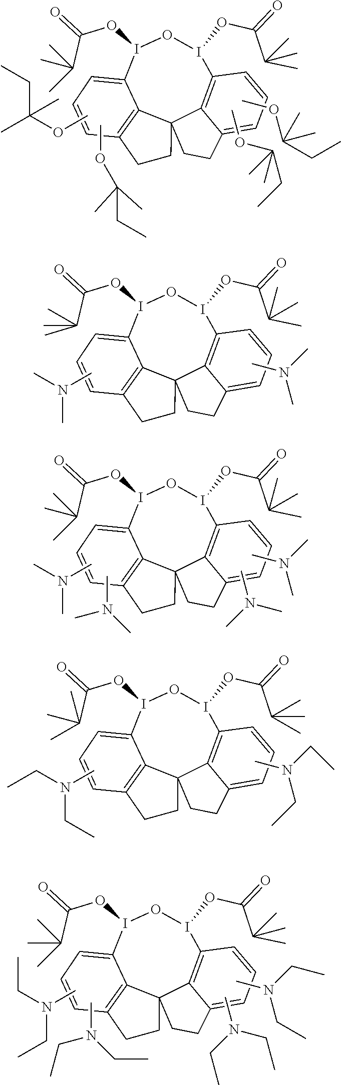

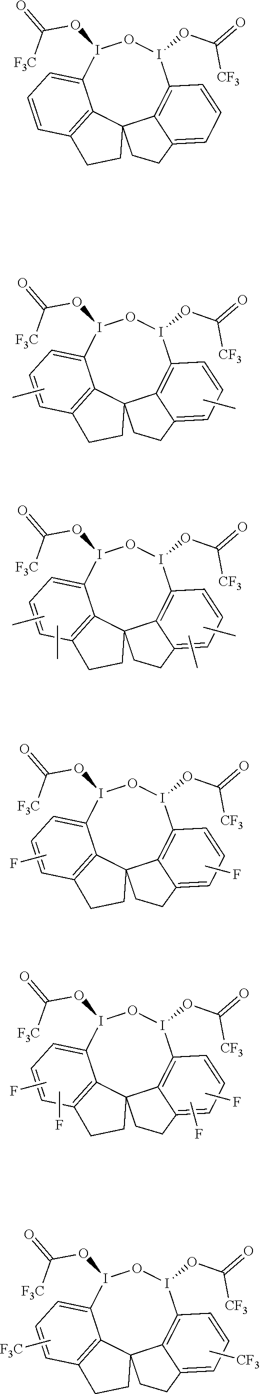

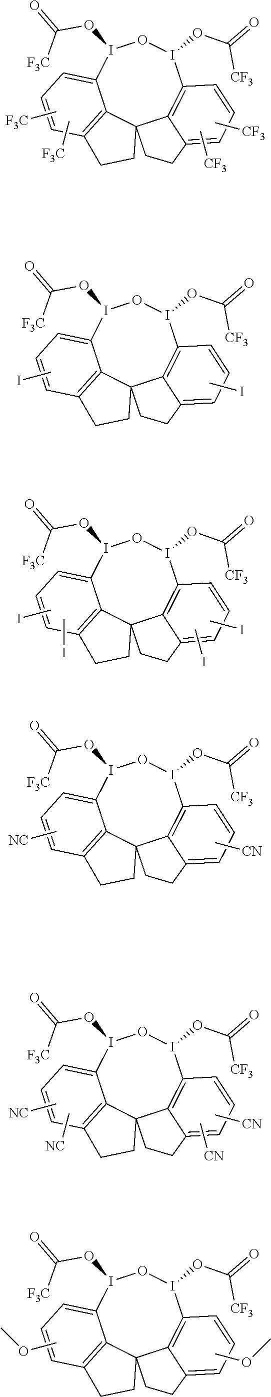

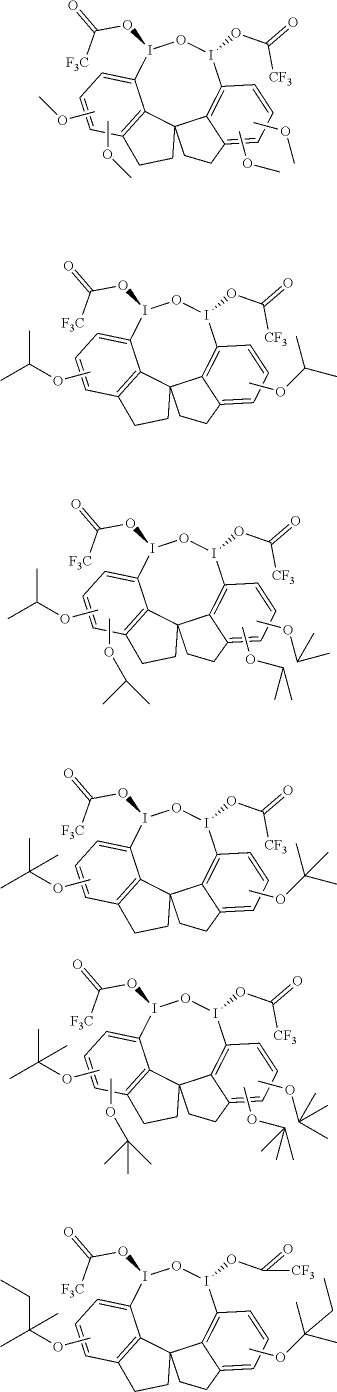

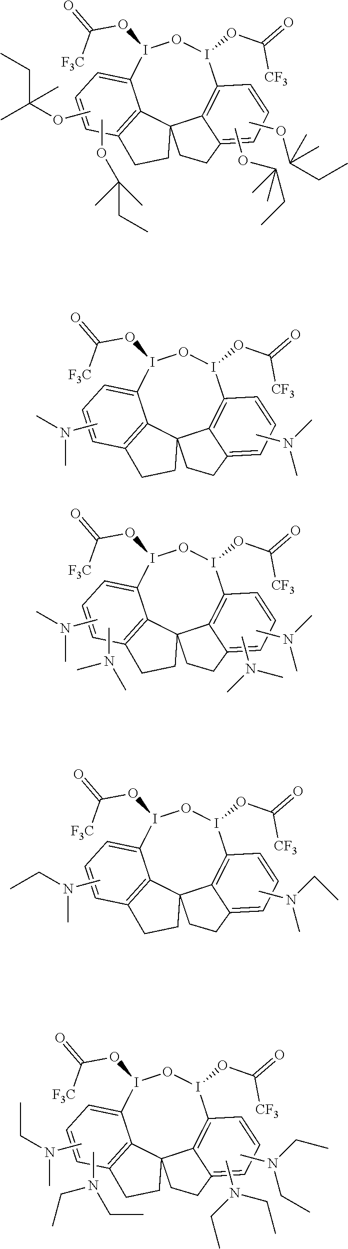

Specific examples of the hypervalent iodine compound represented by the general formula (9) include, but are not limited to, the following.

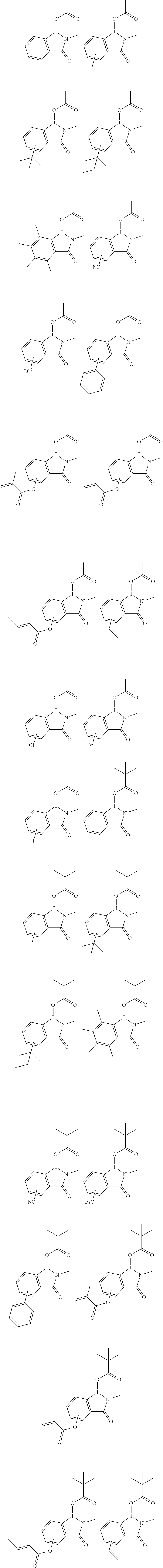

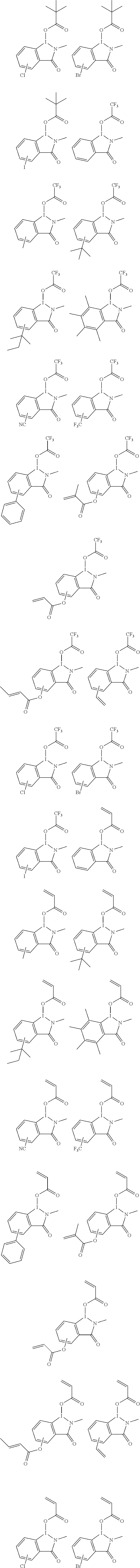

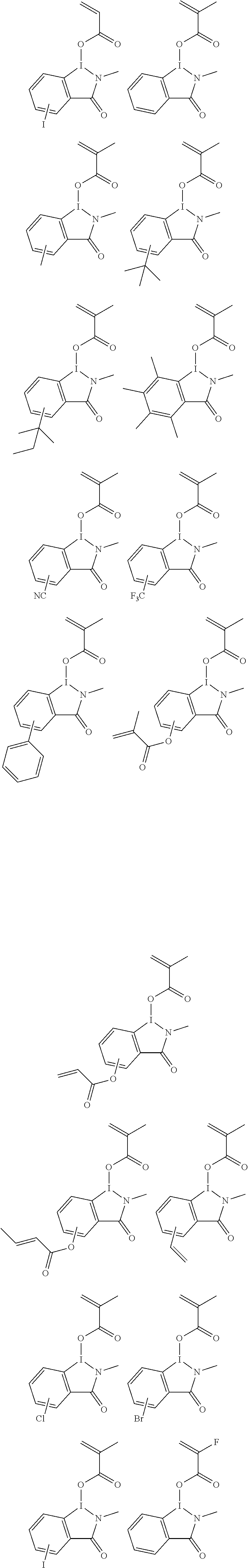

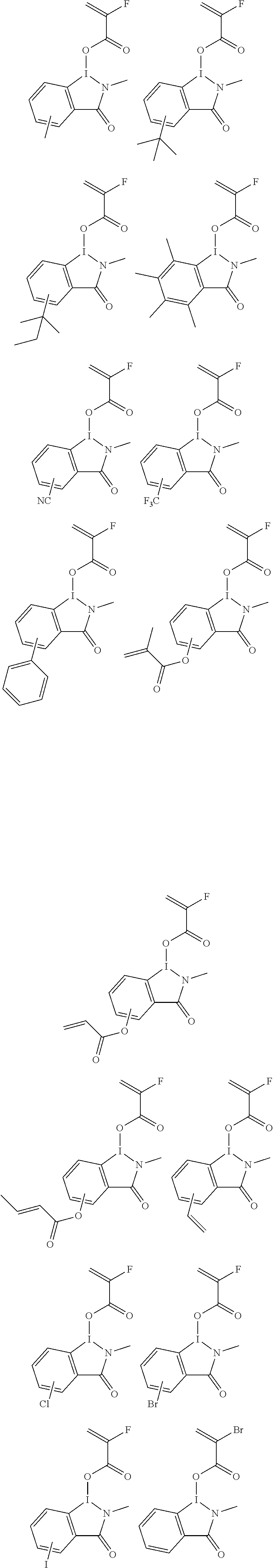

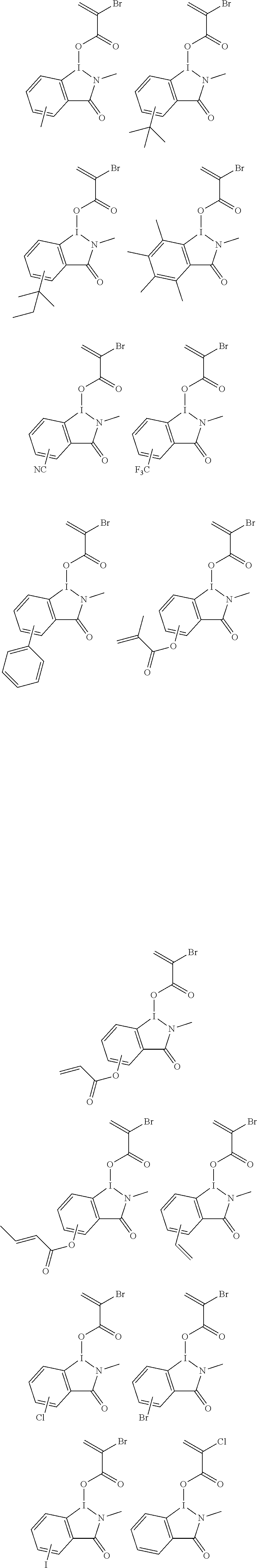

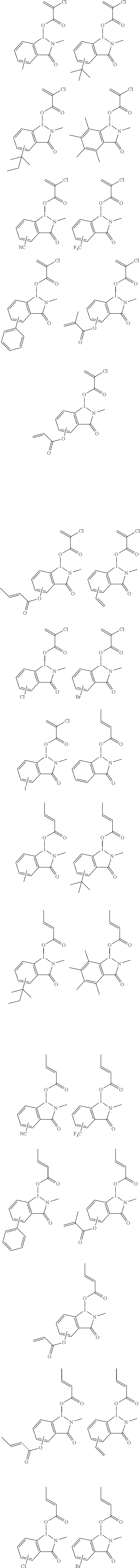

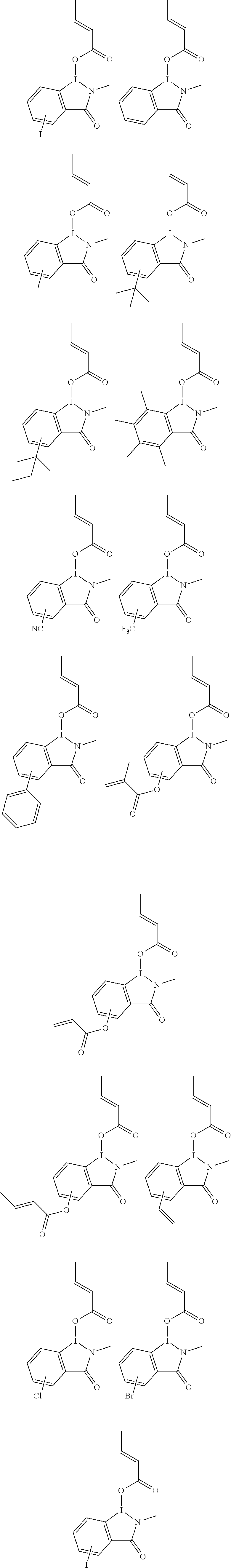

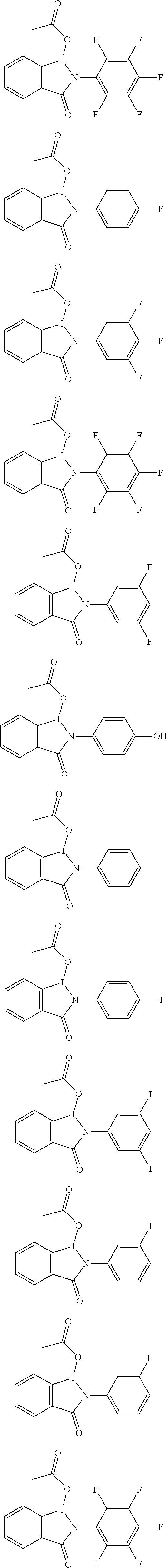

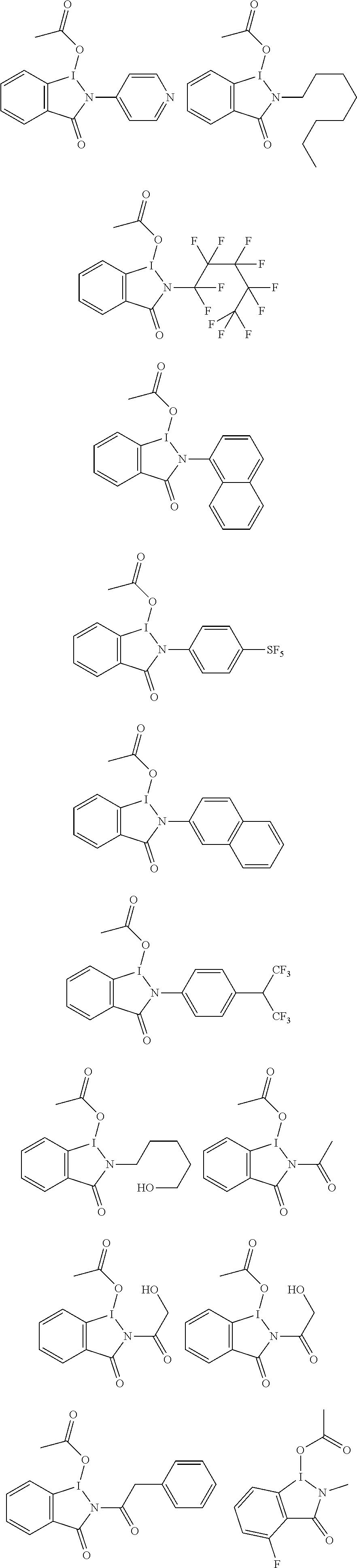

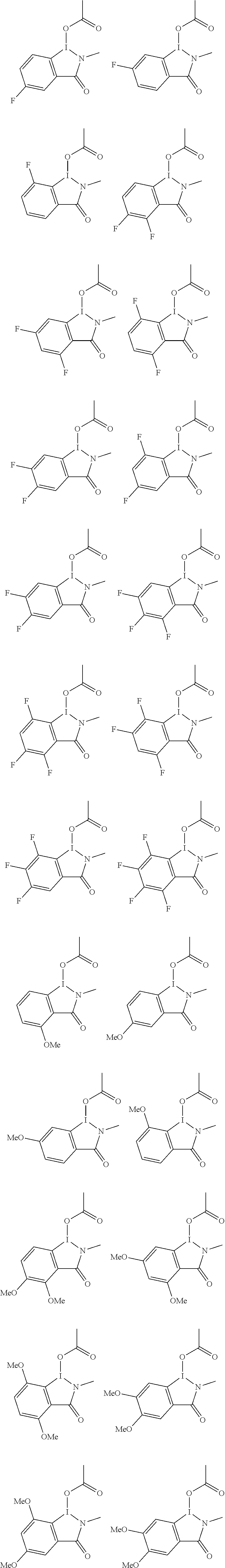

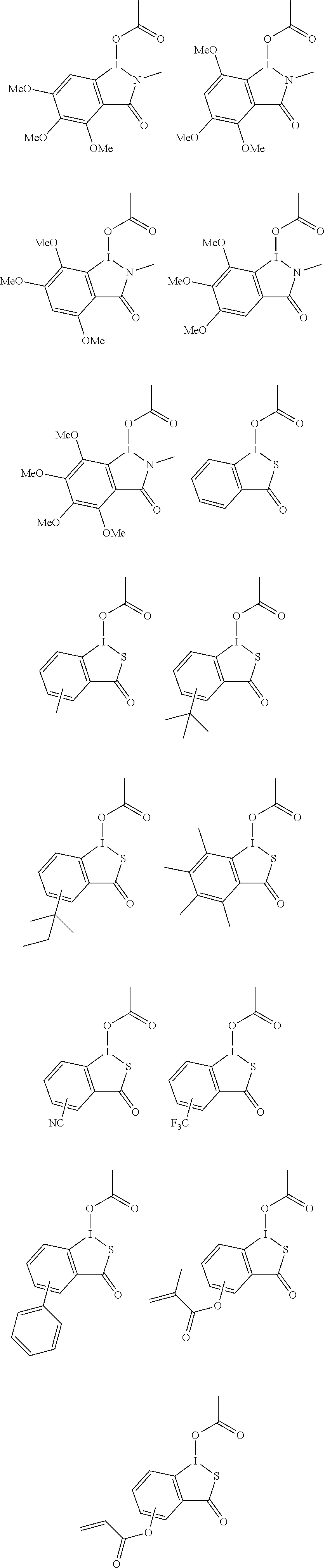

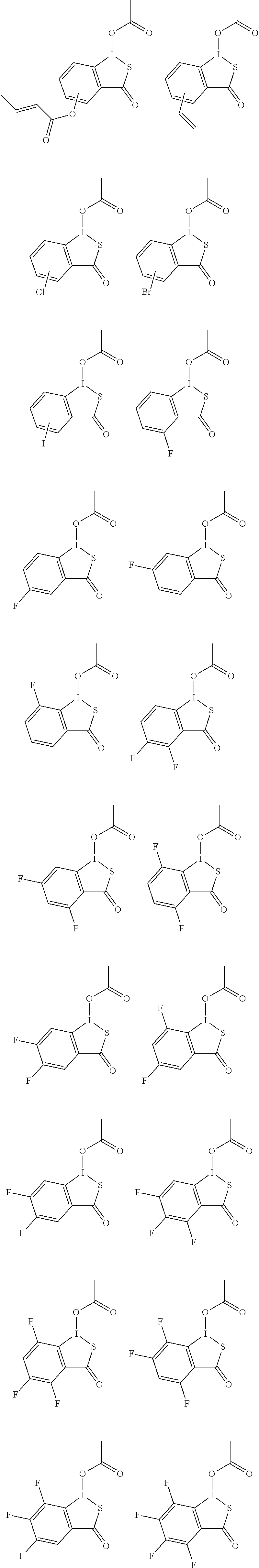

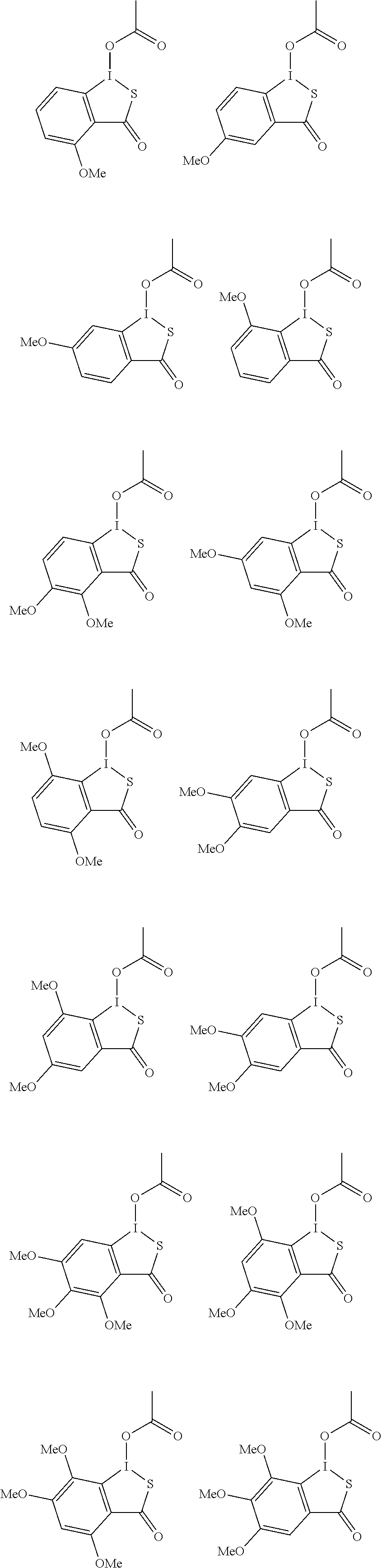

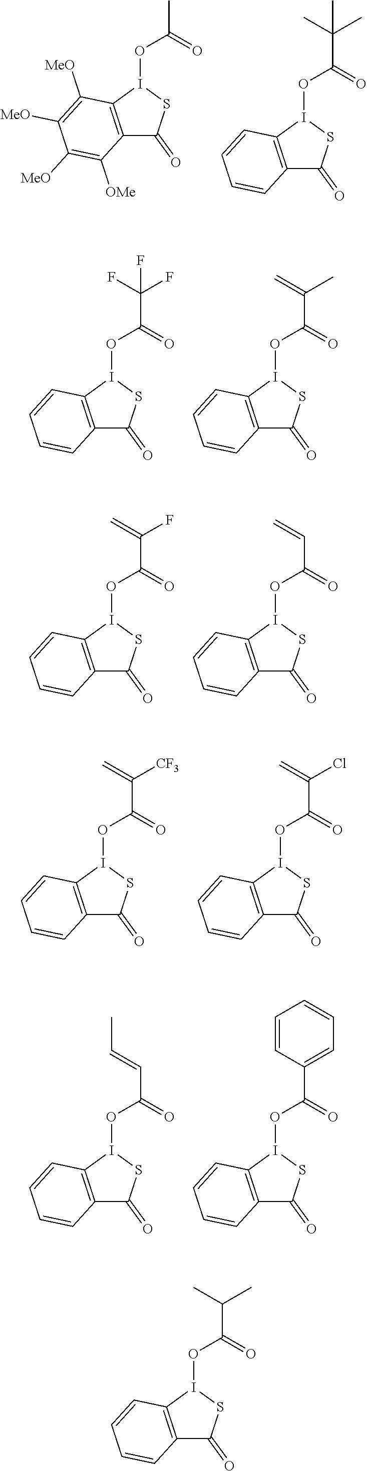

Specific examples of the hypervalent iodine compound represented by the general formula (10) include, but are not limited to, the following.

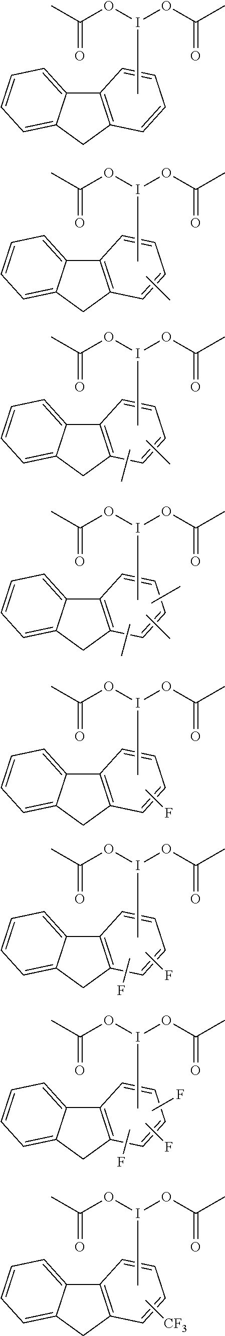

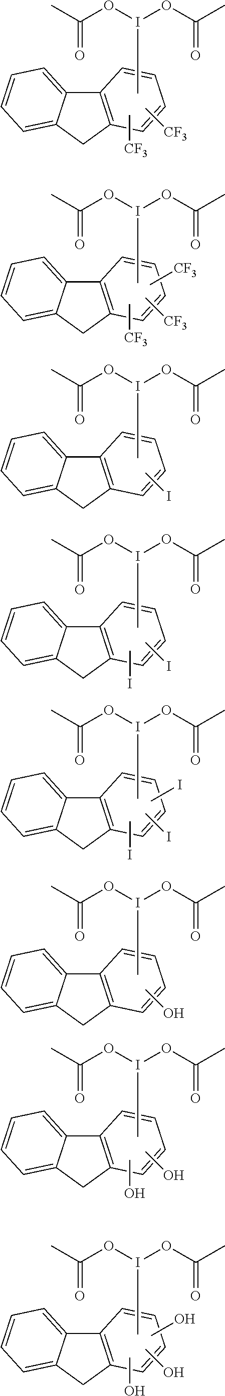

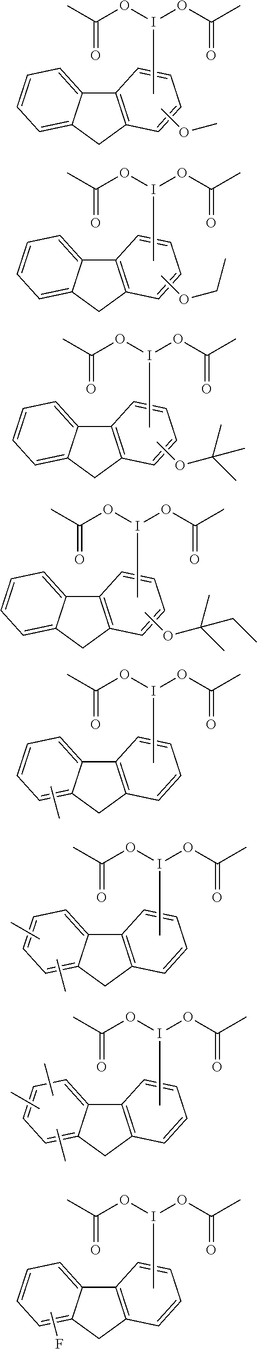

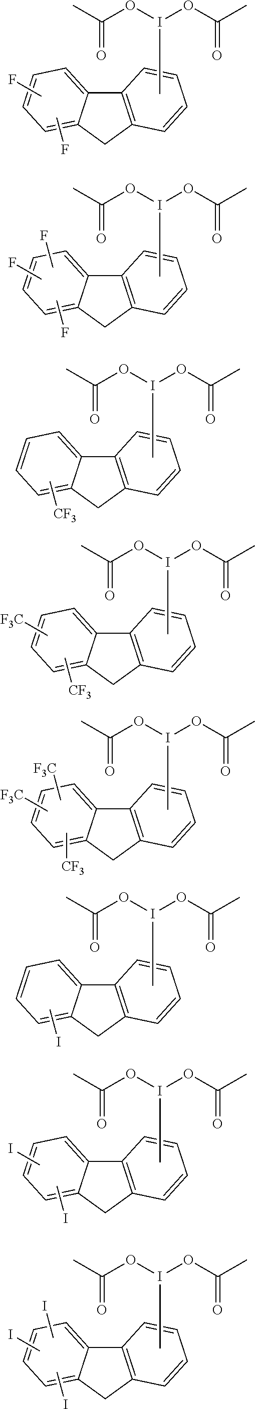

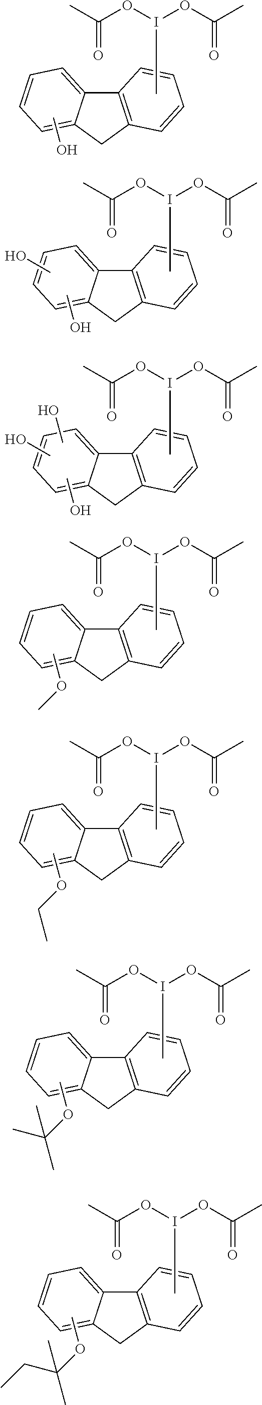

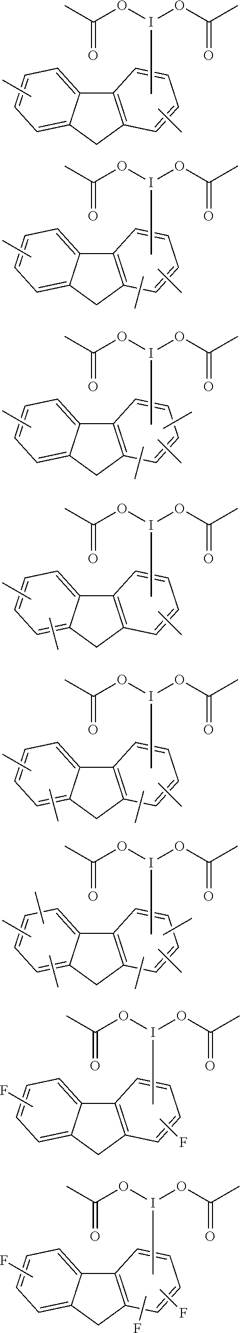

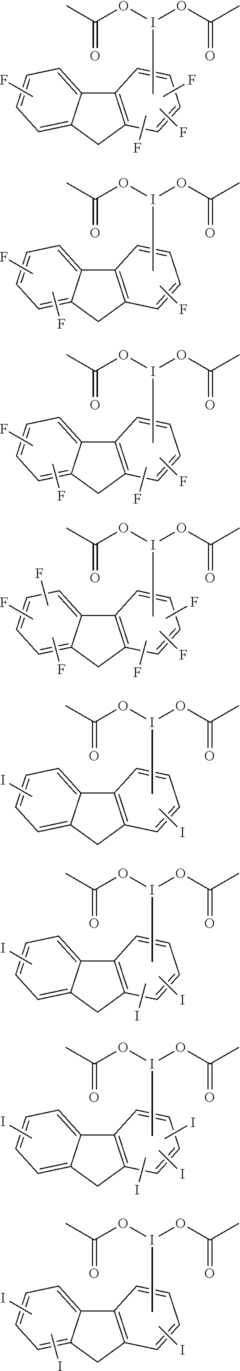

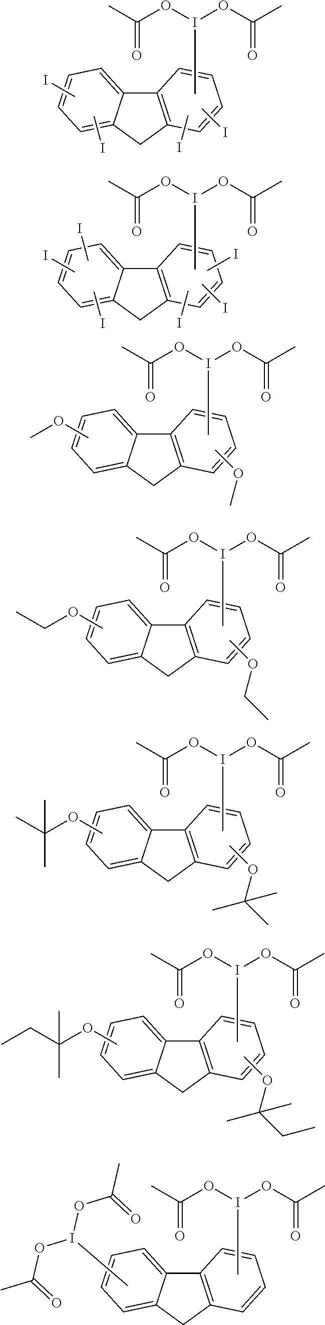

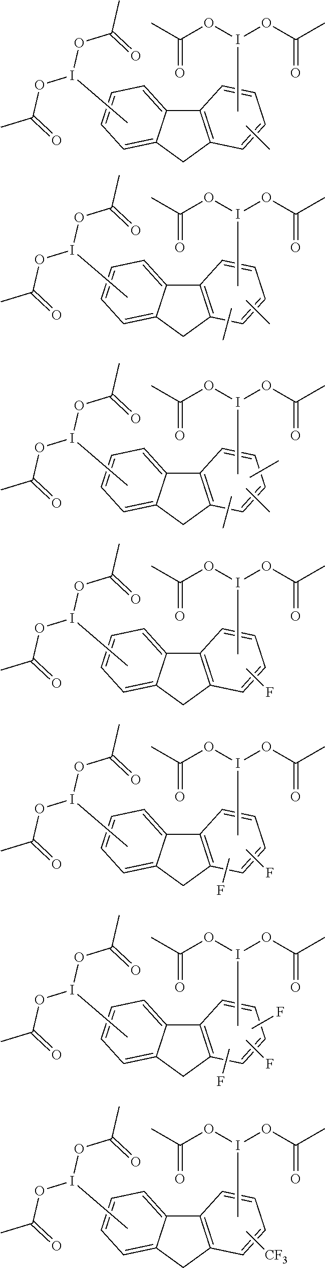

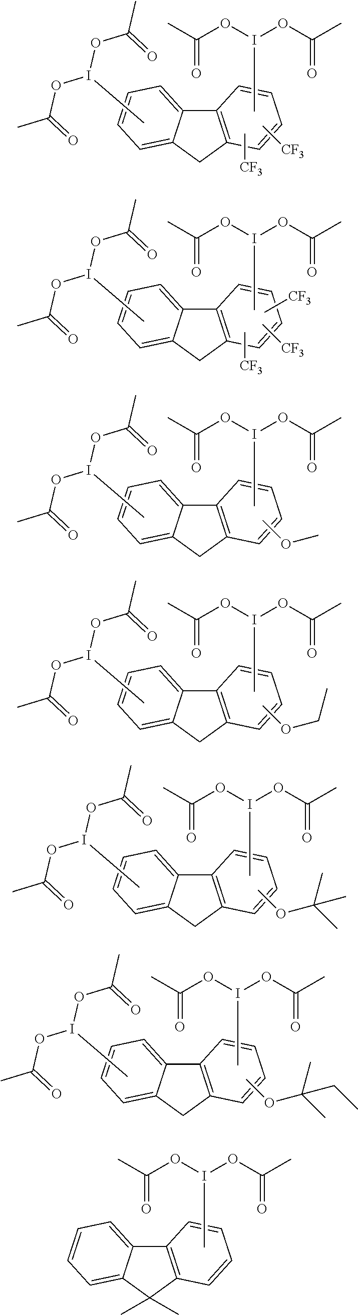

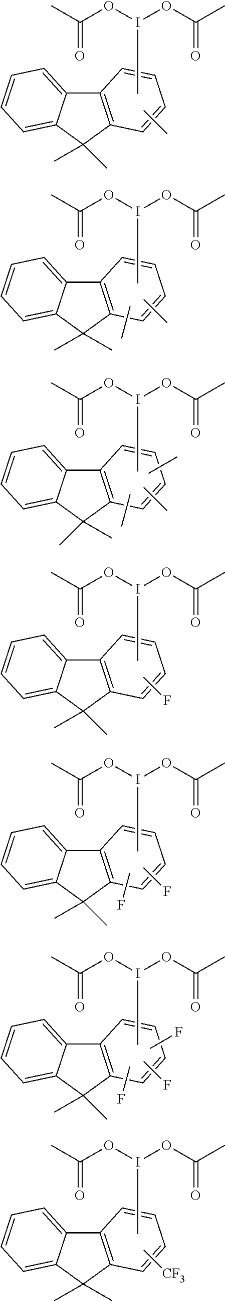

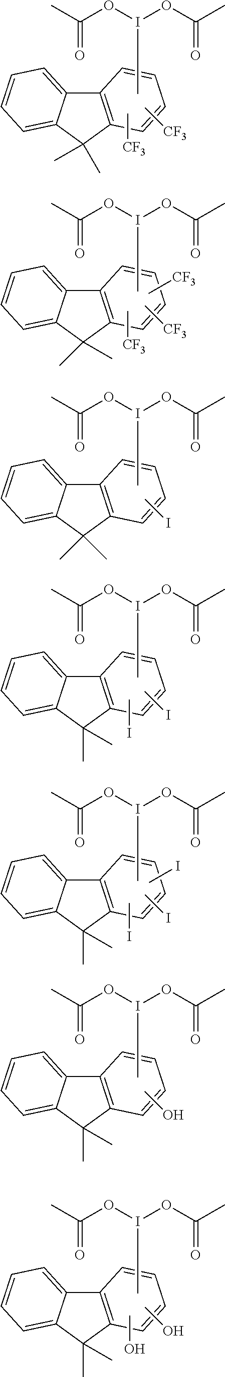

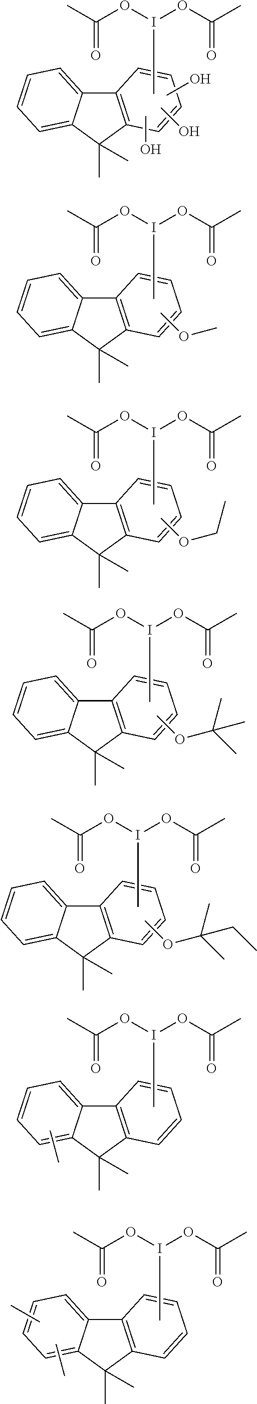

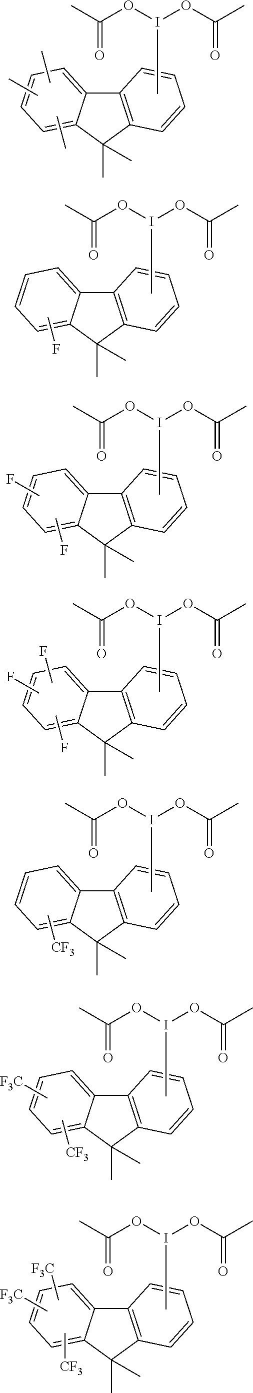

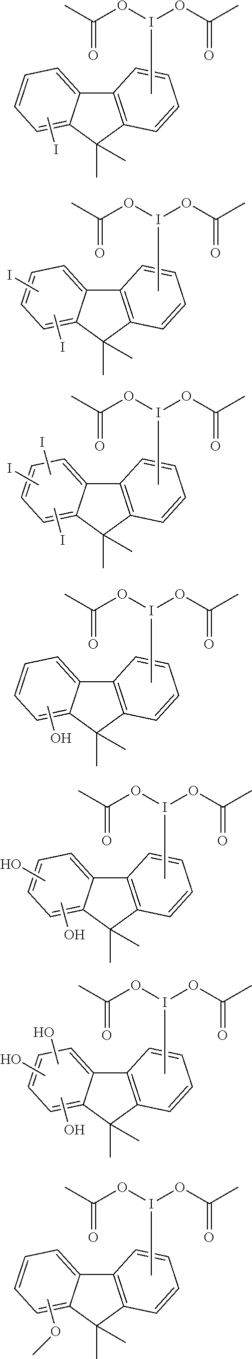

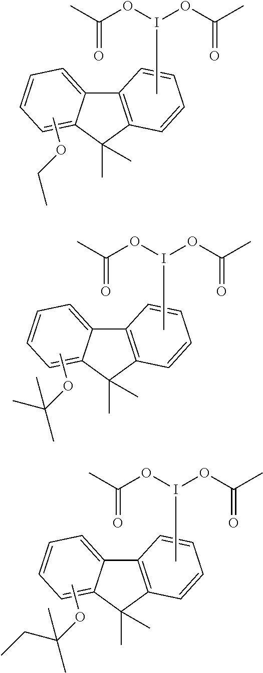

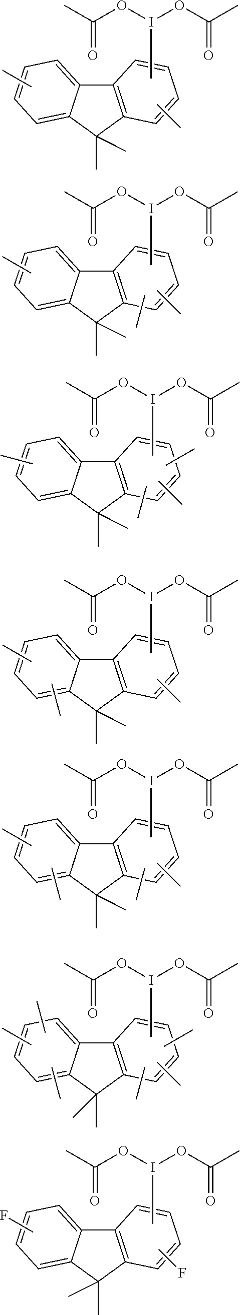

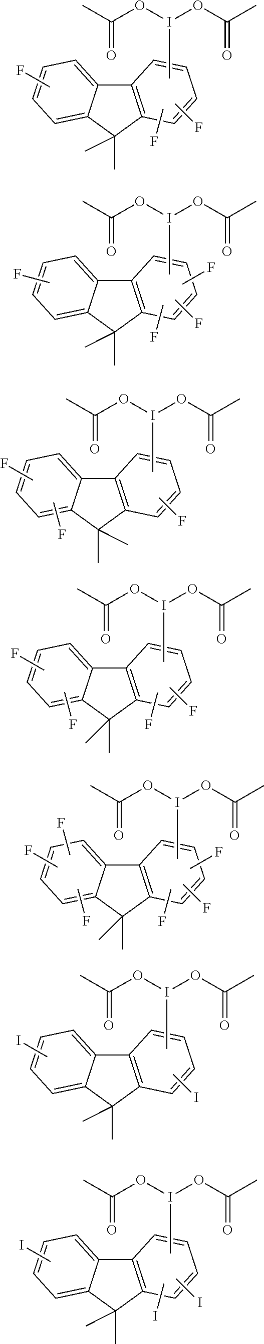

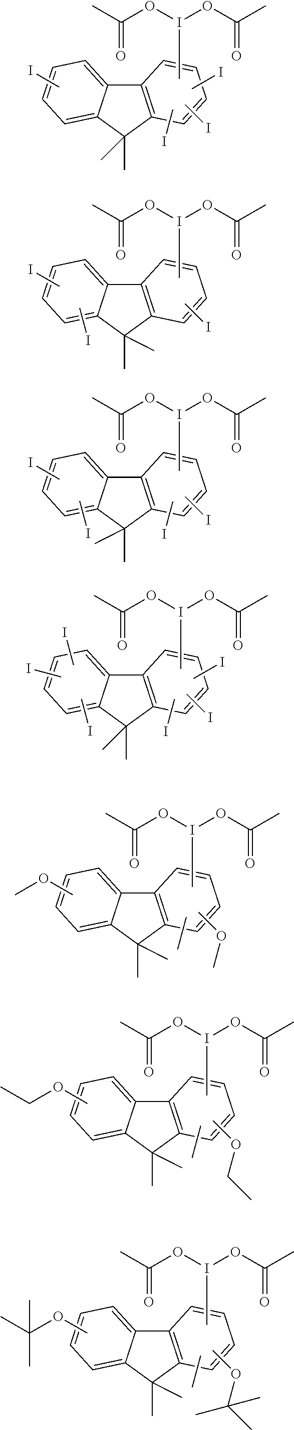

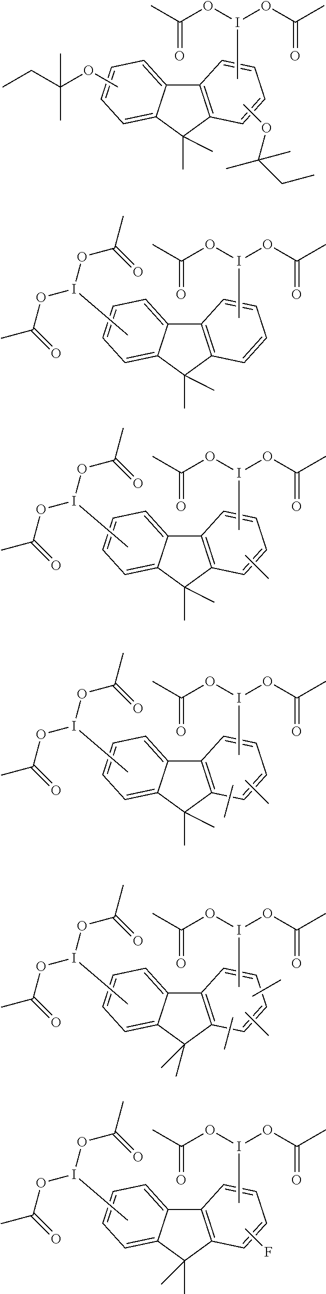

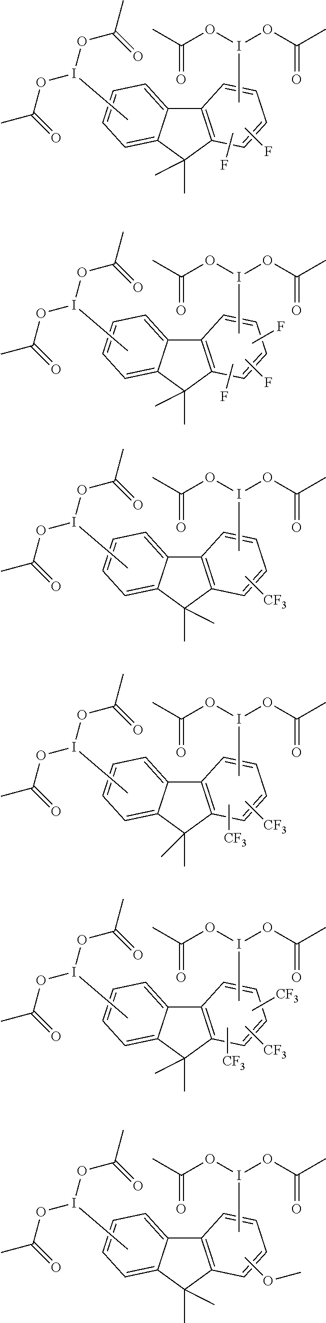

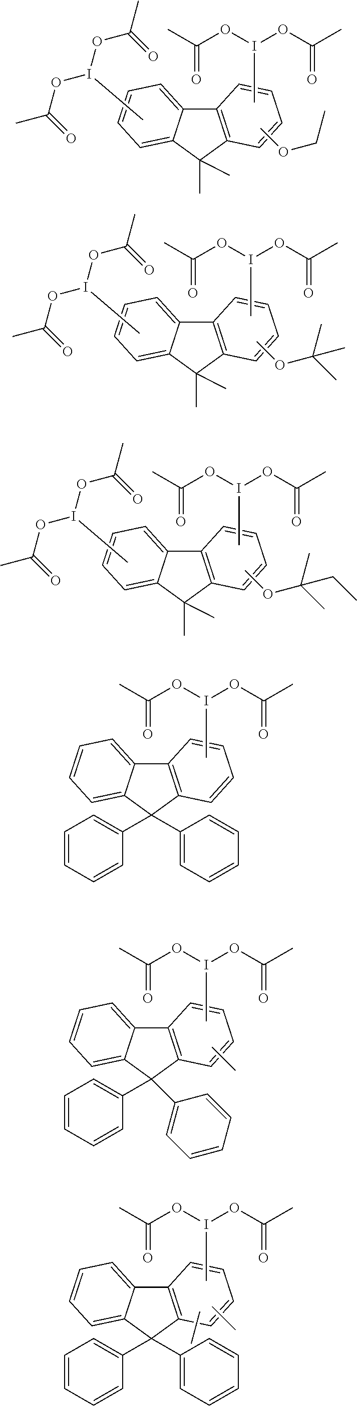

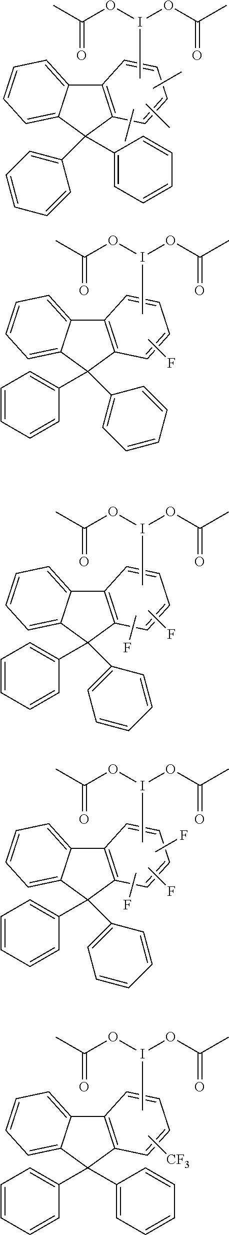

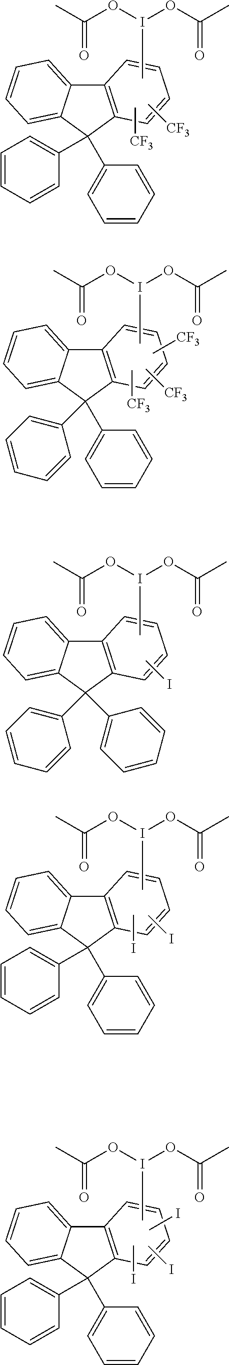

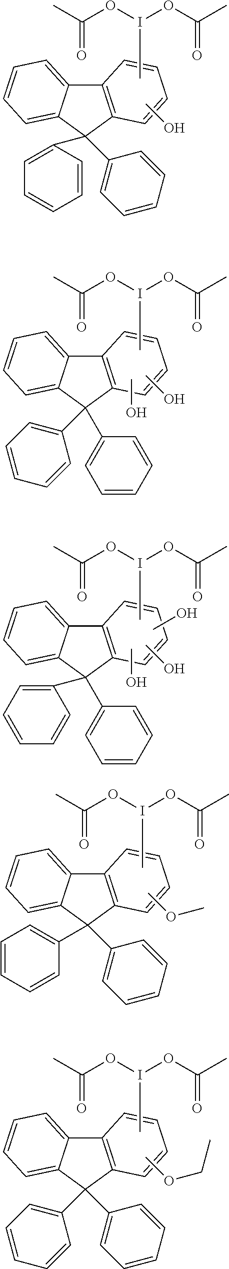

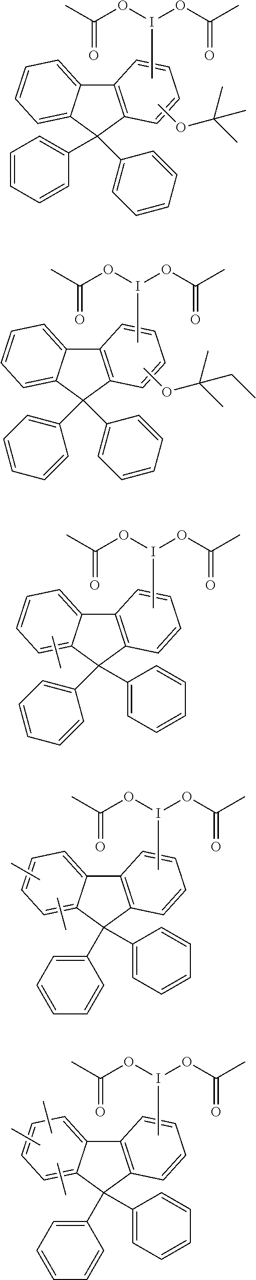

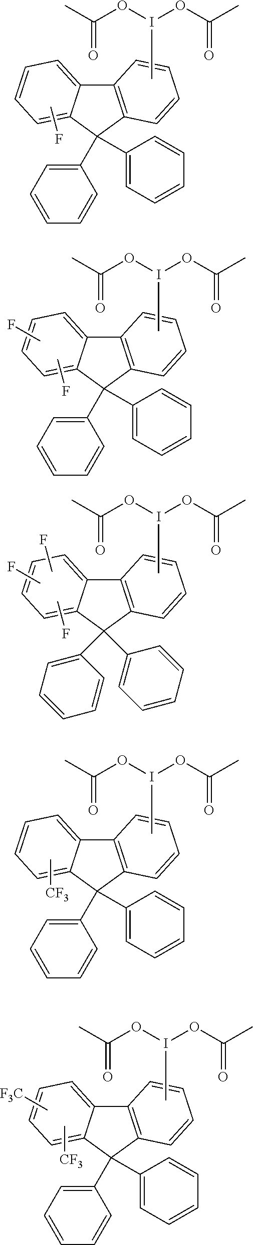

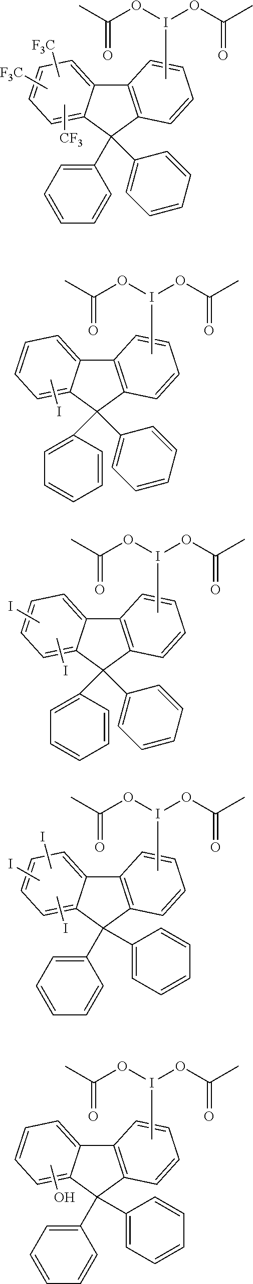

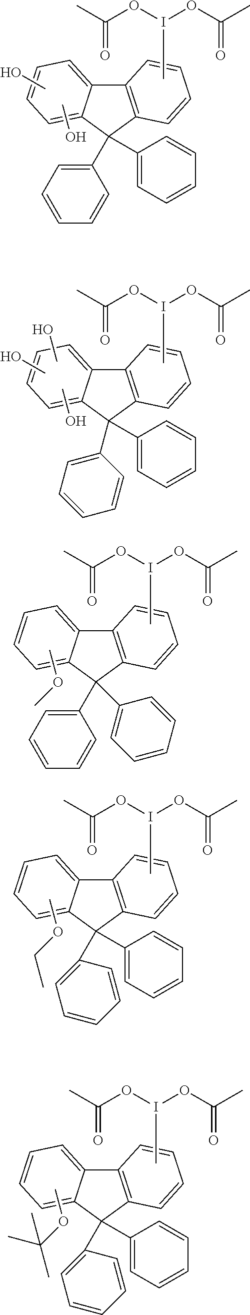

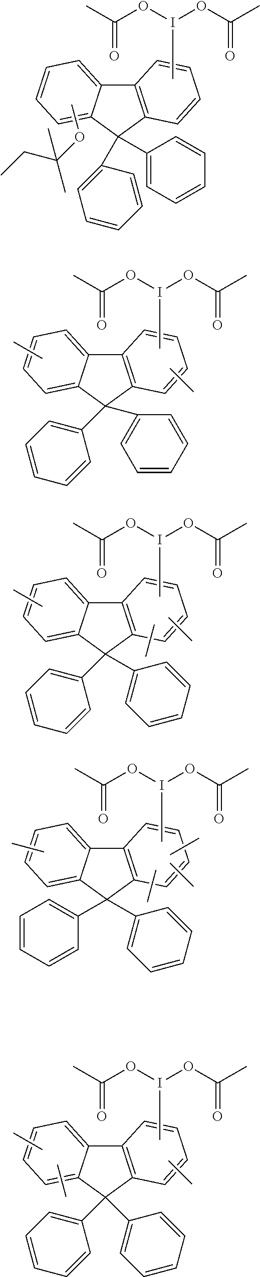

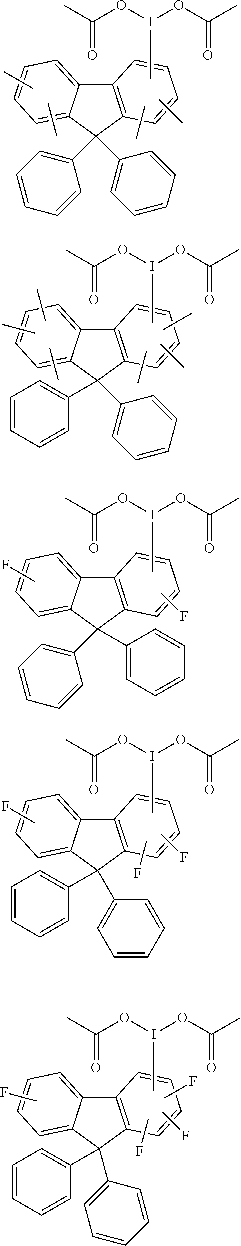

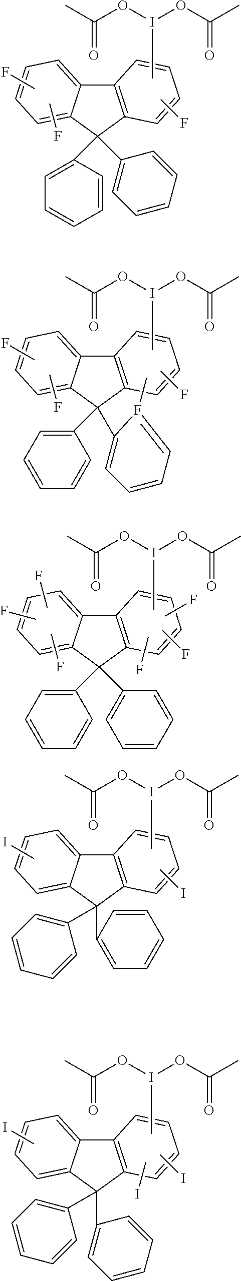

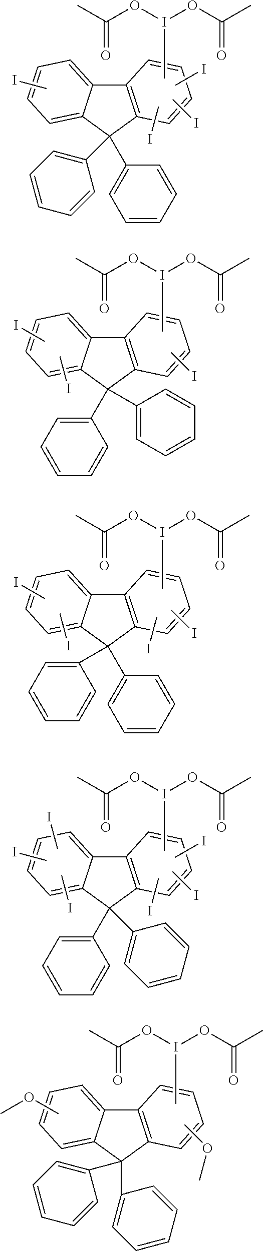

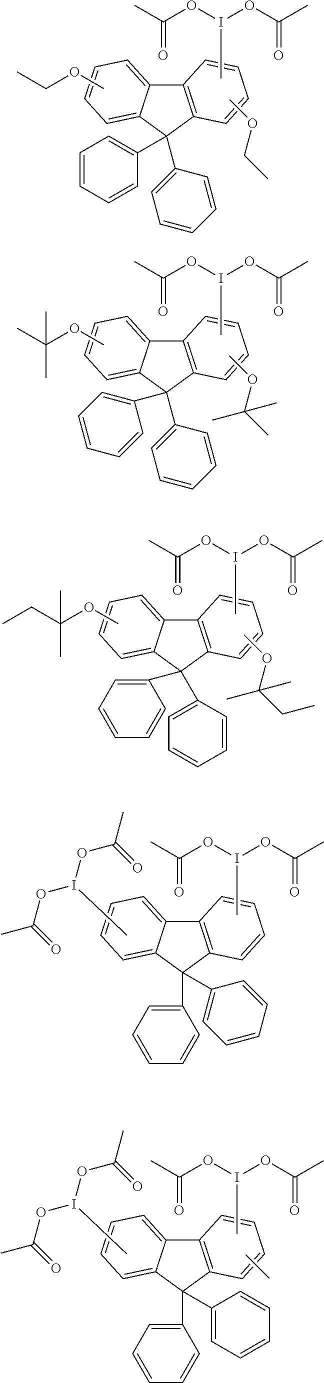

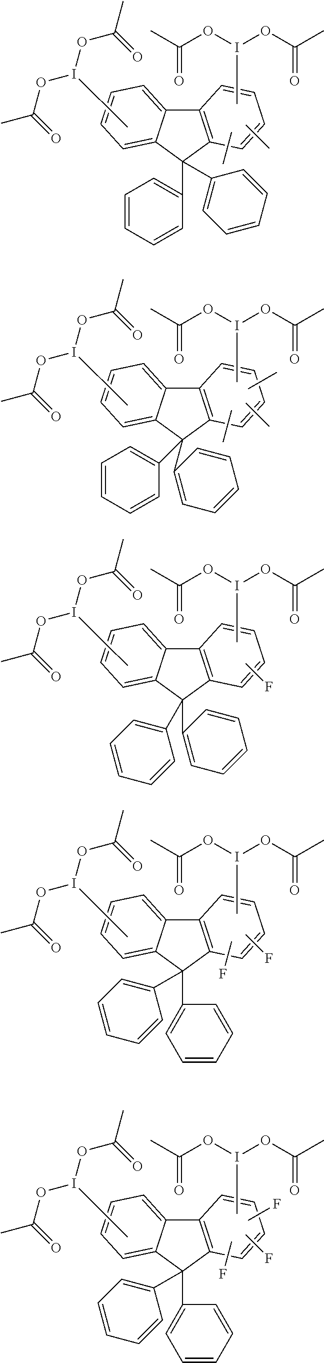

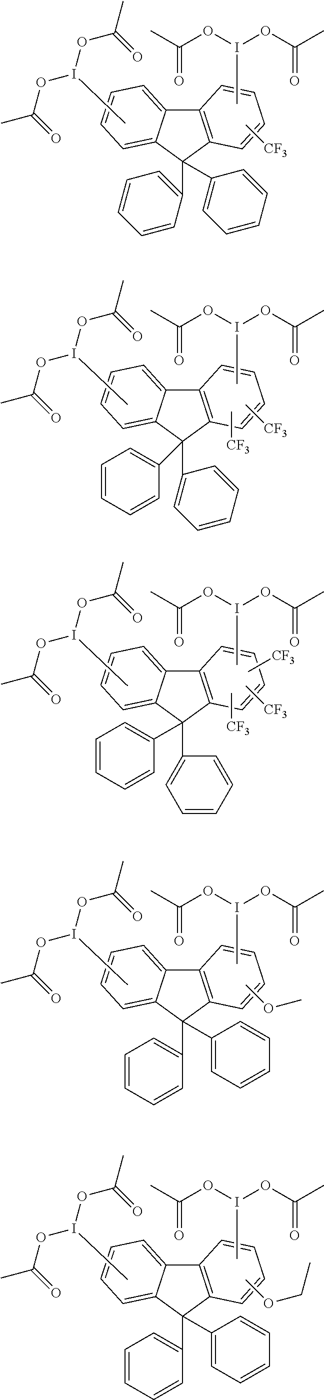

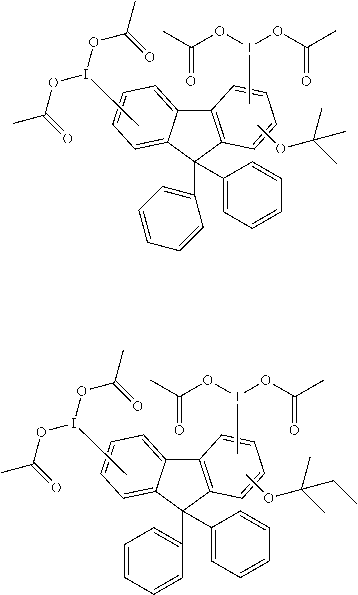

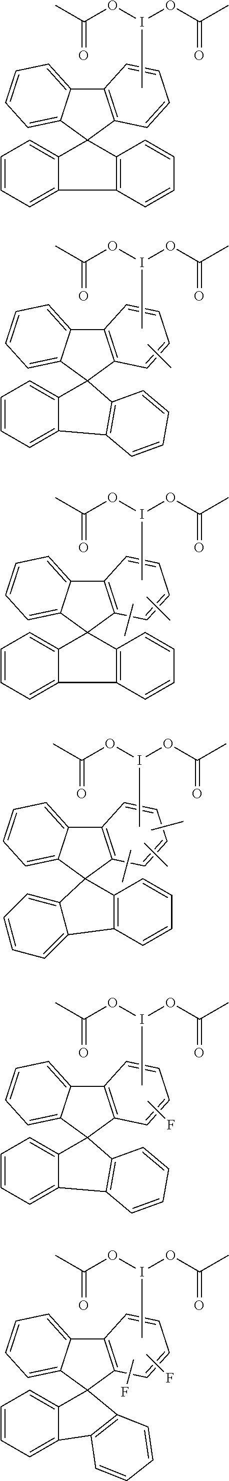

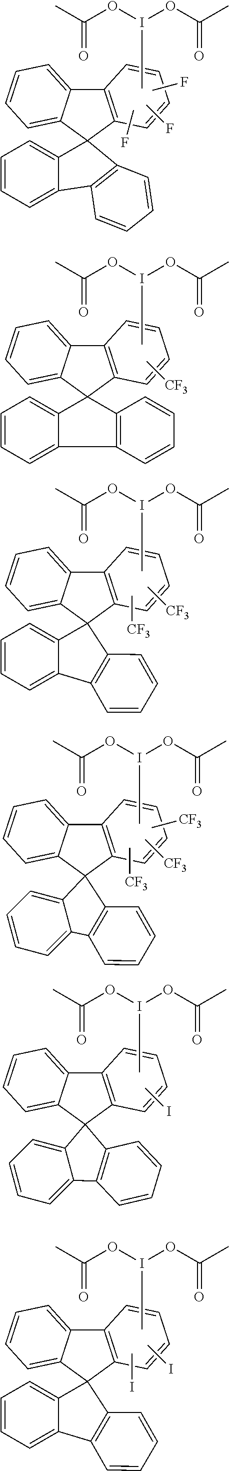

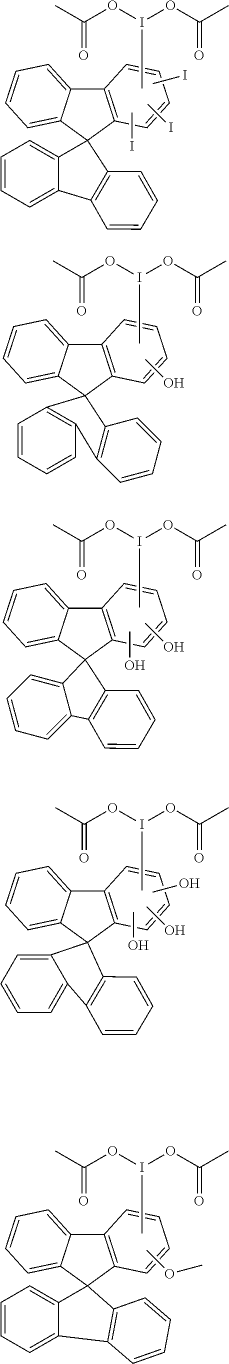

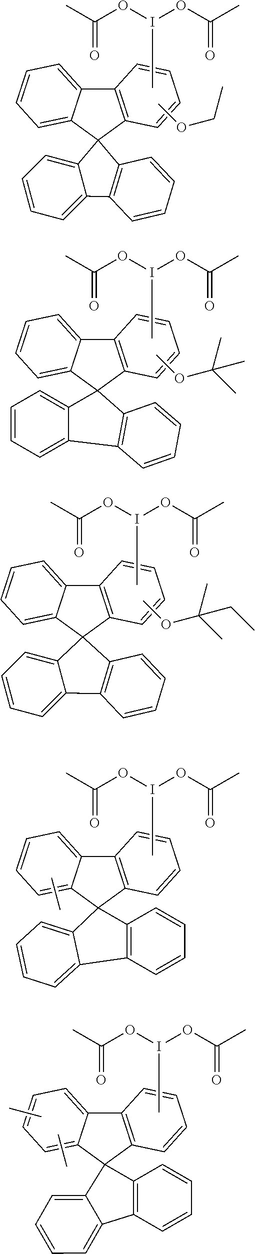

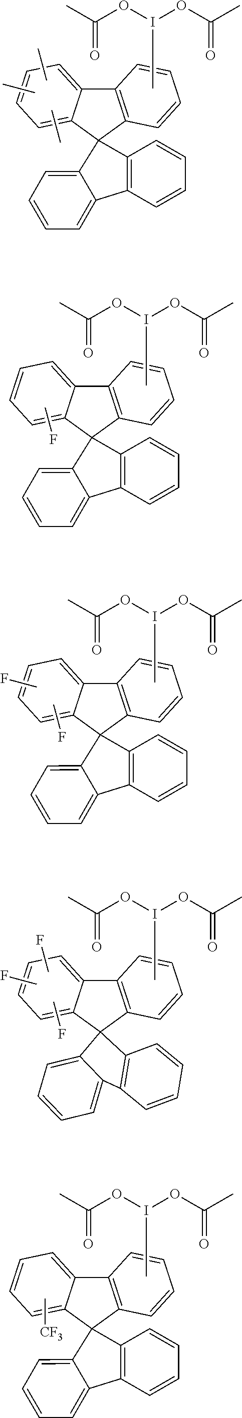

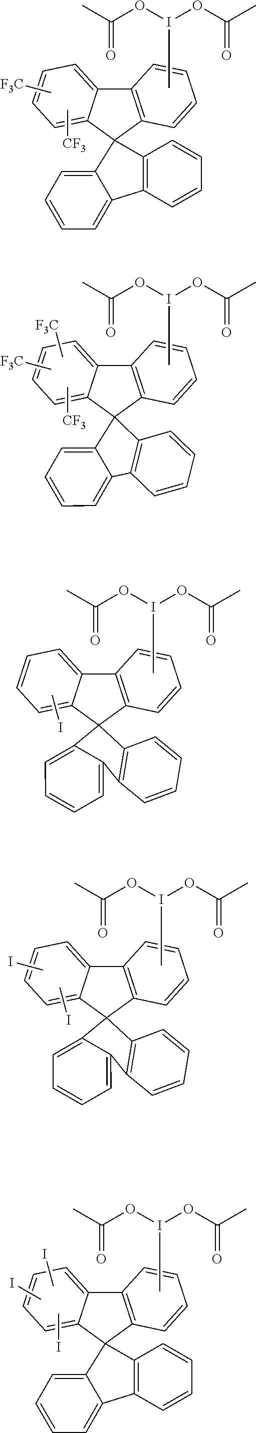

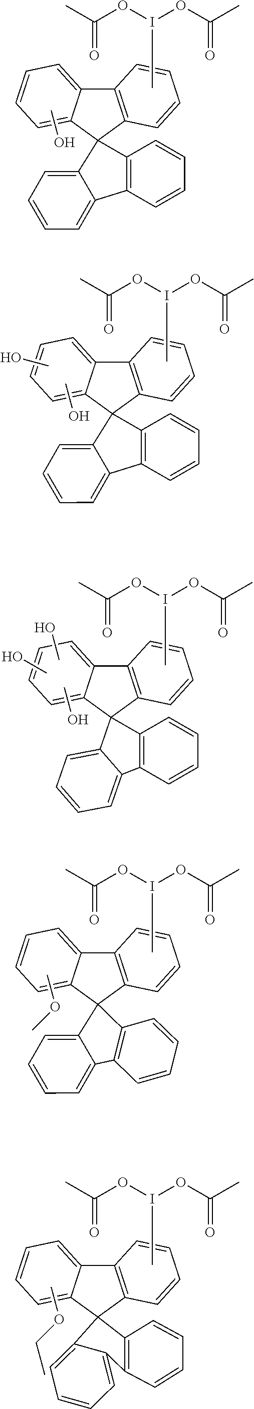

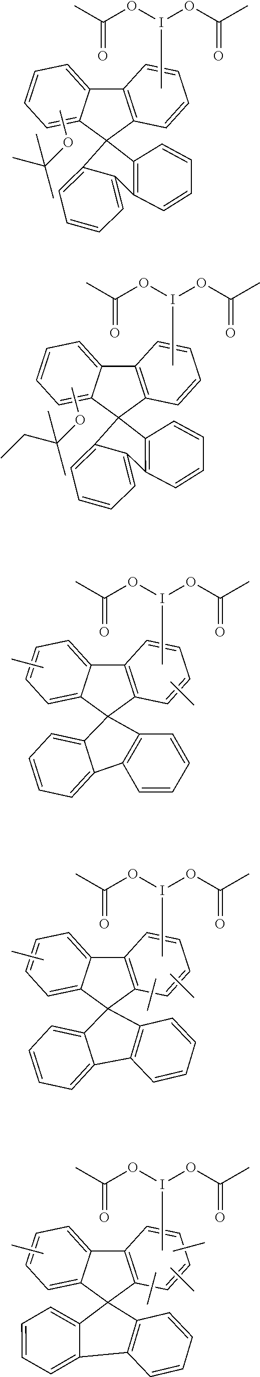

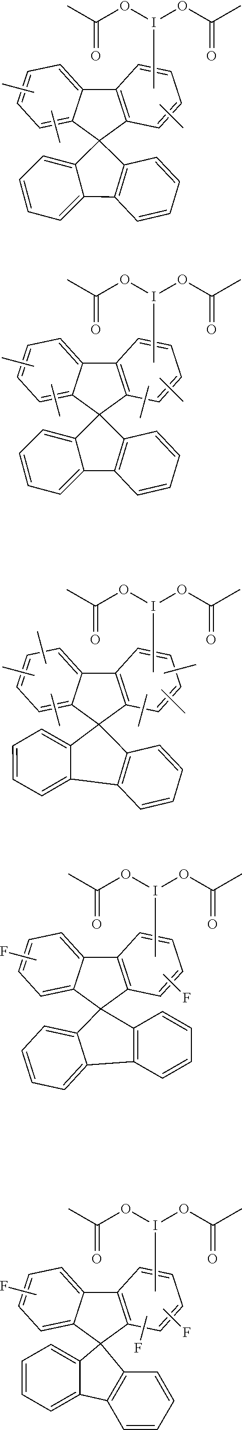

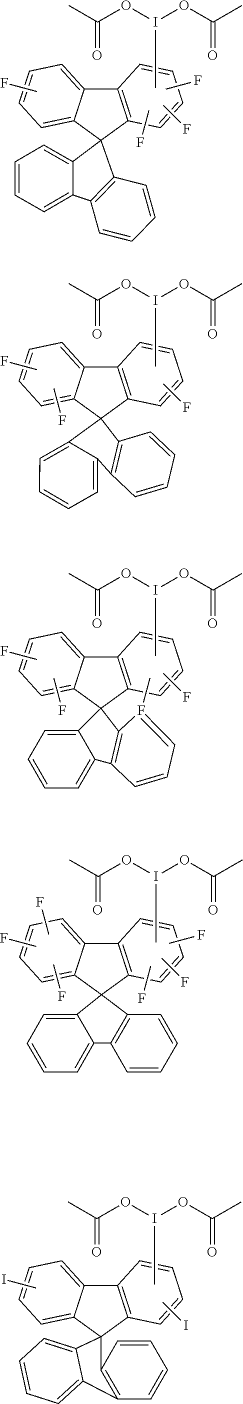

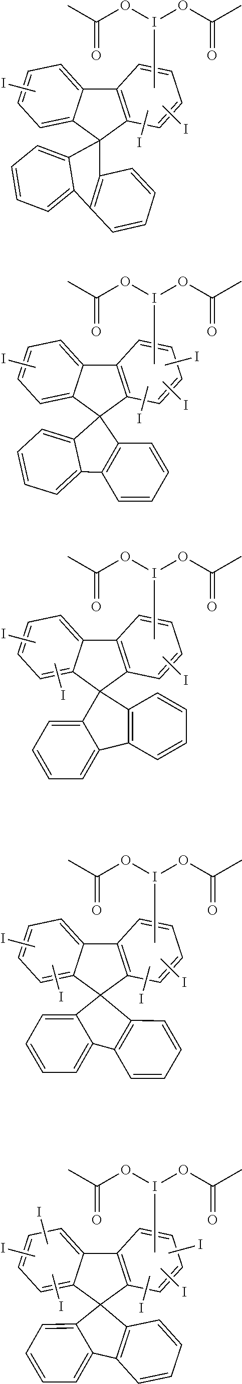

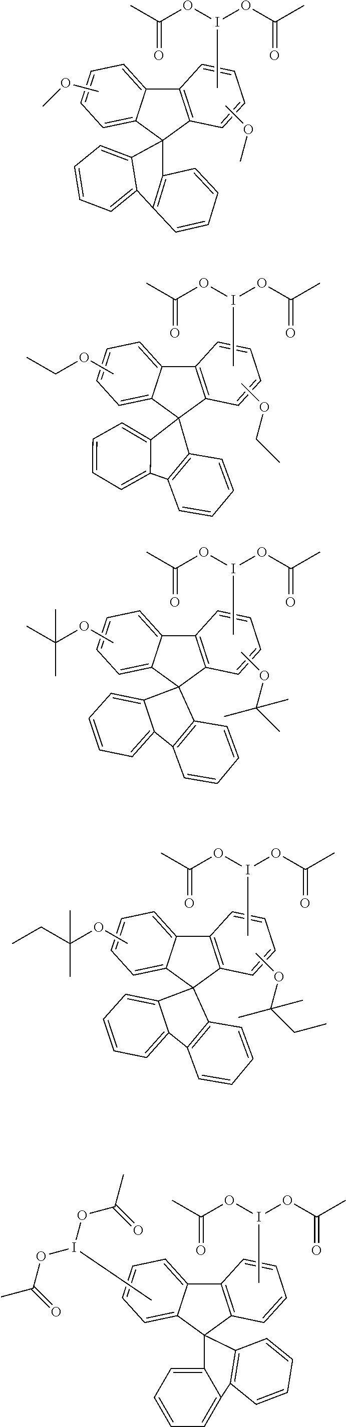

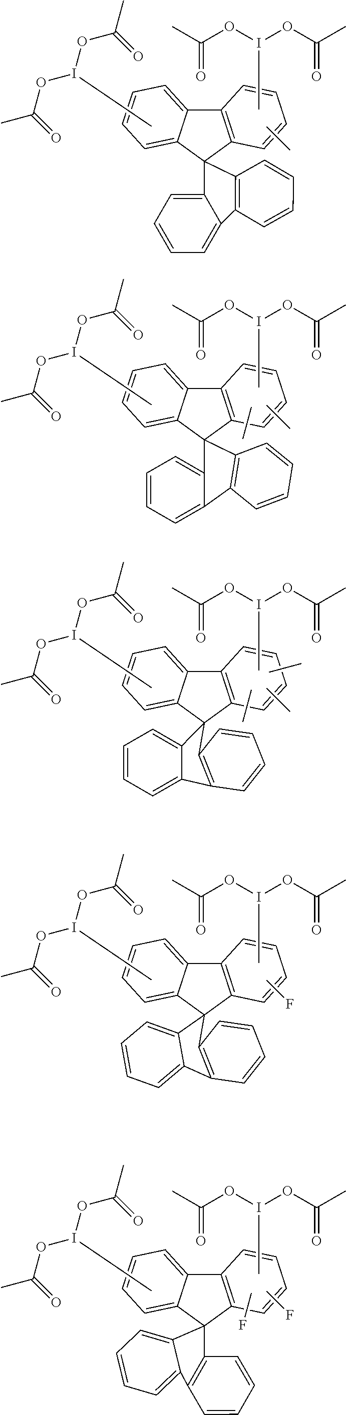

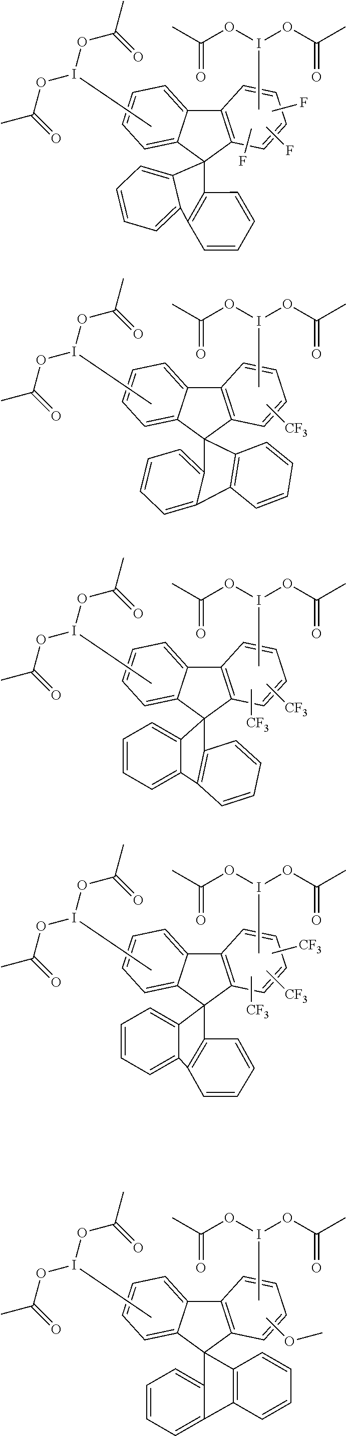

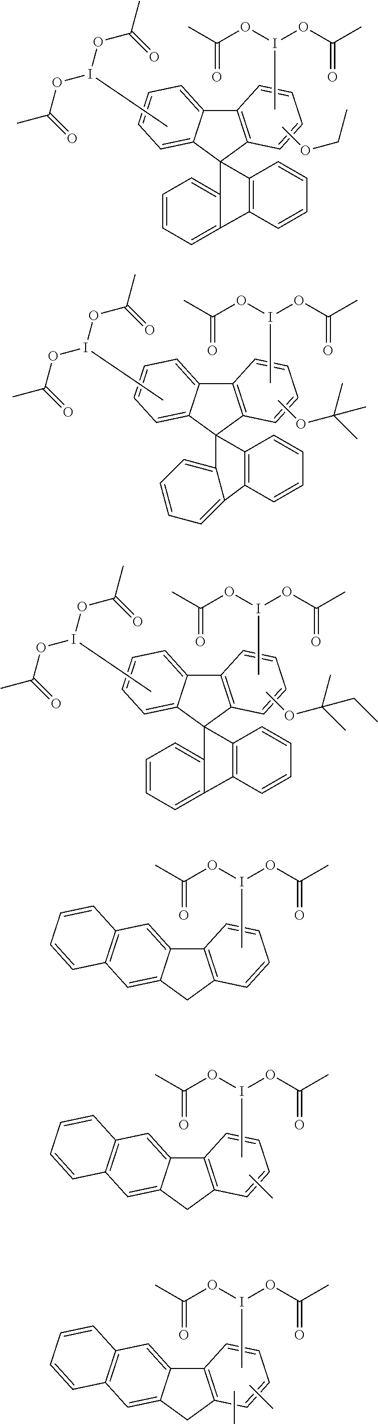

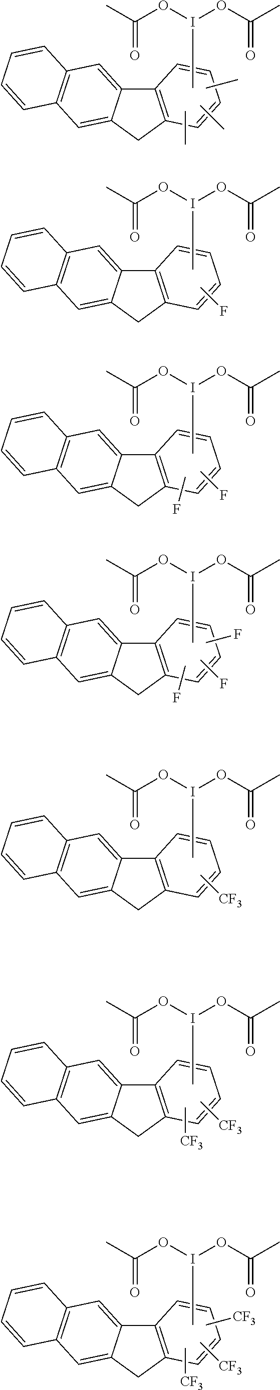

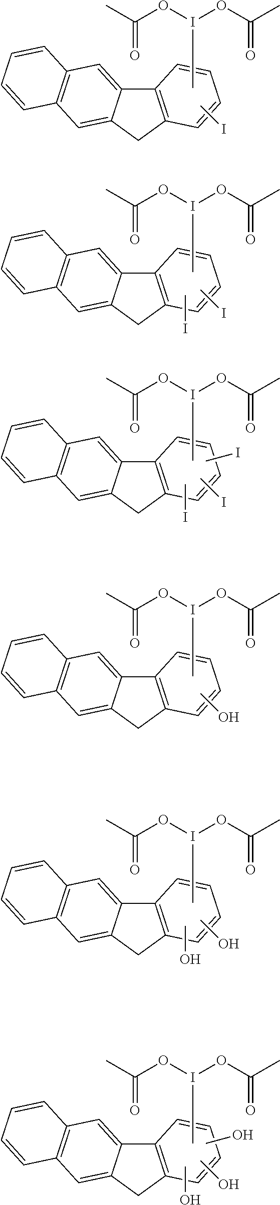

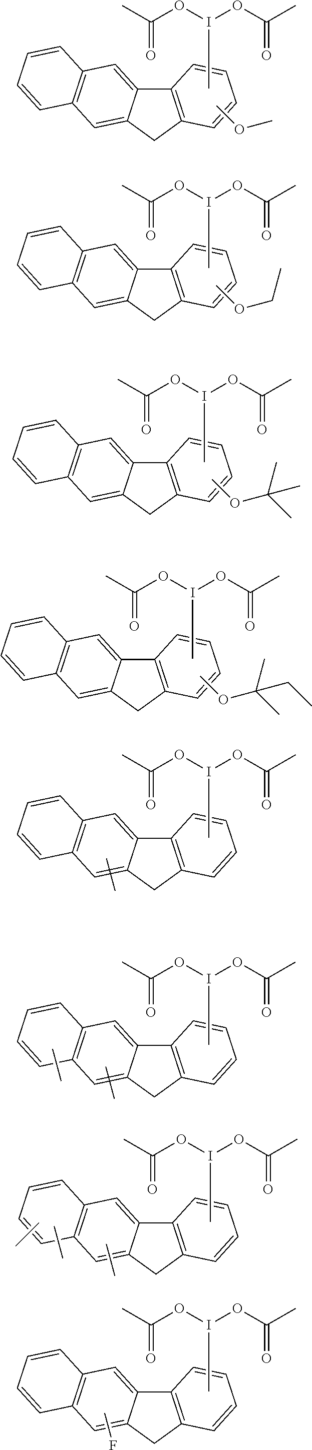

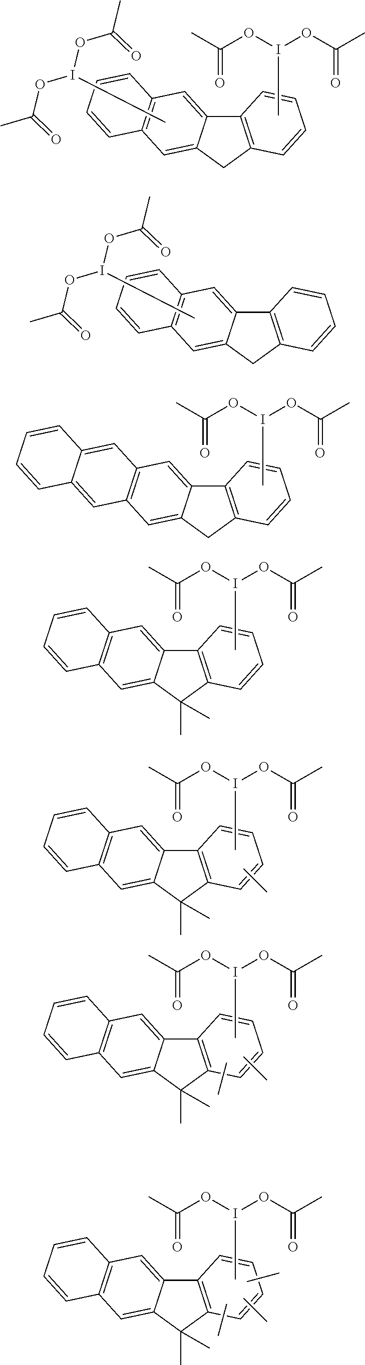

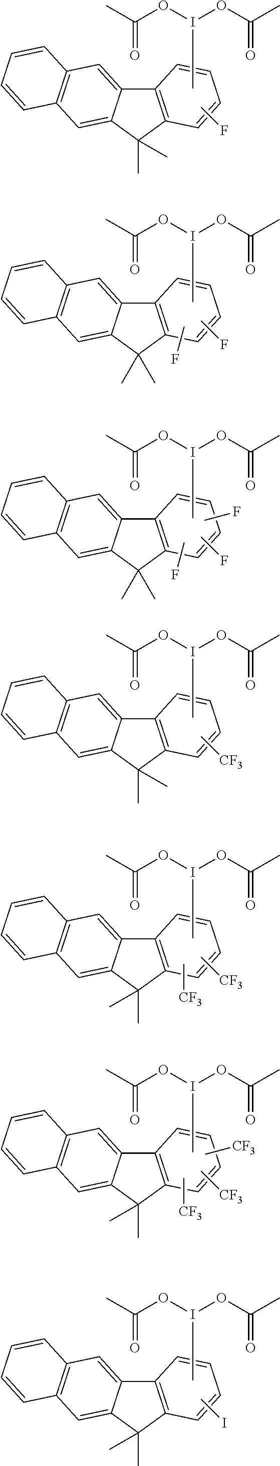

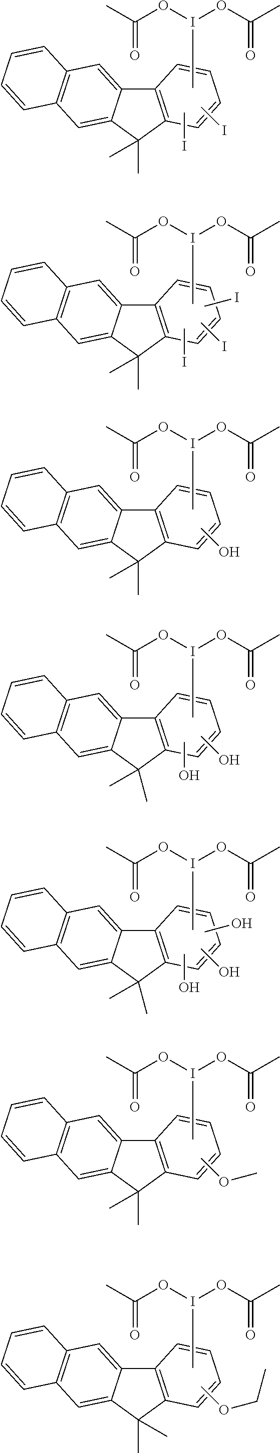

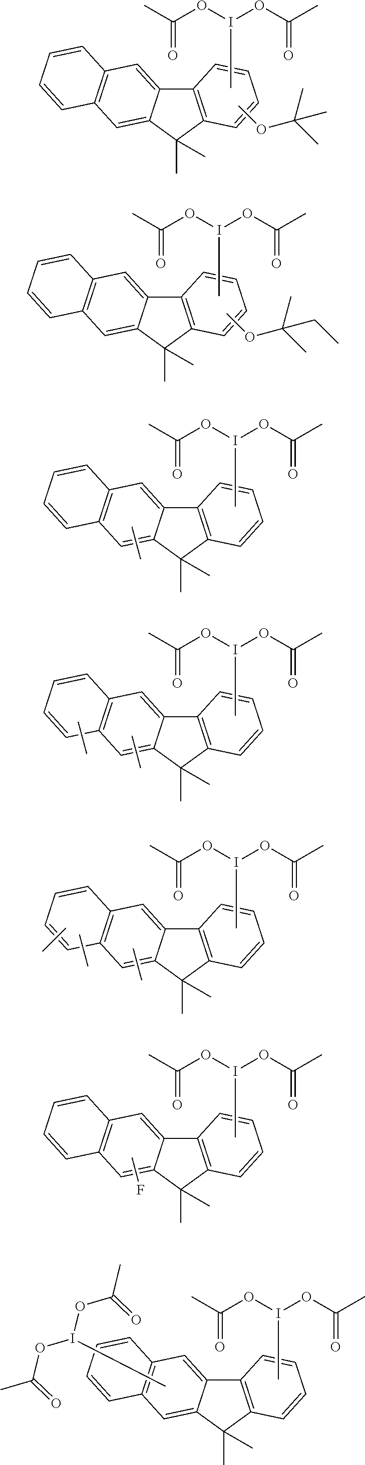

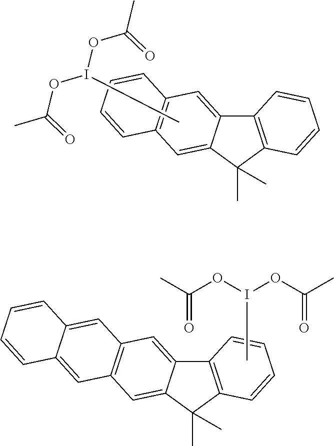

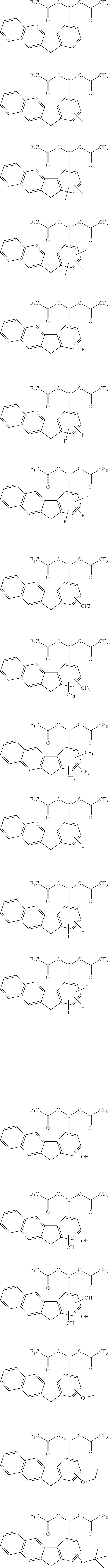

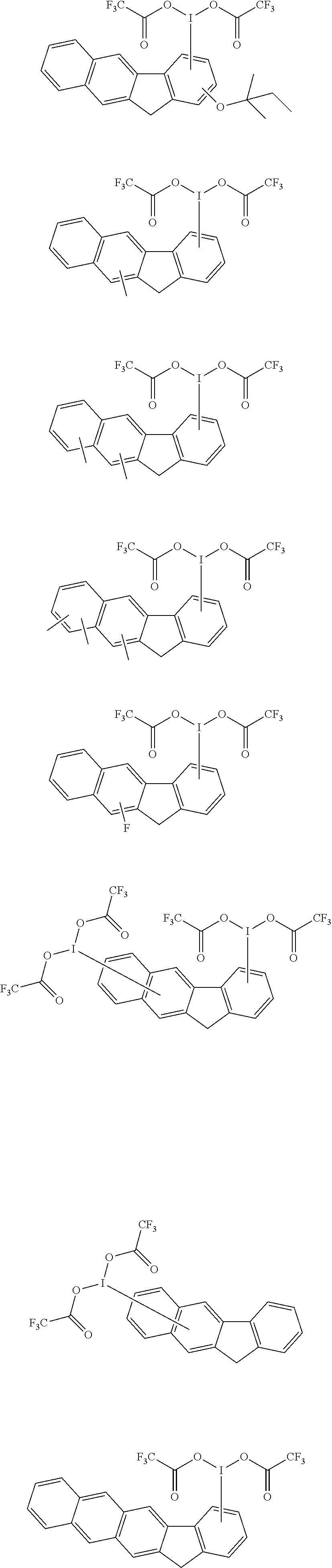

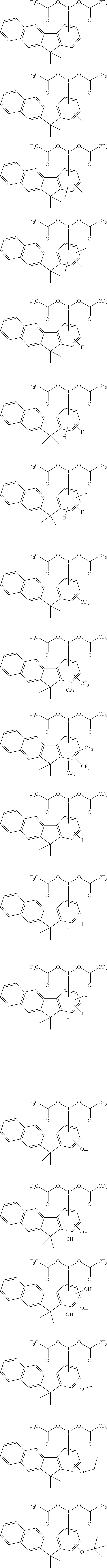

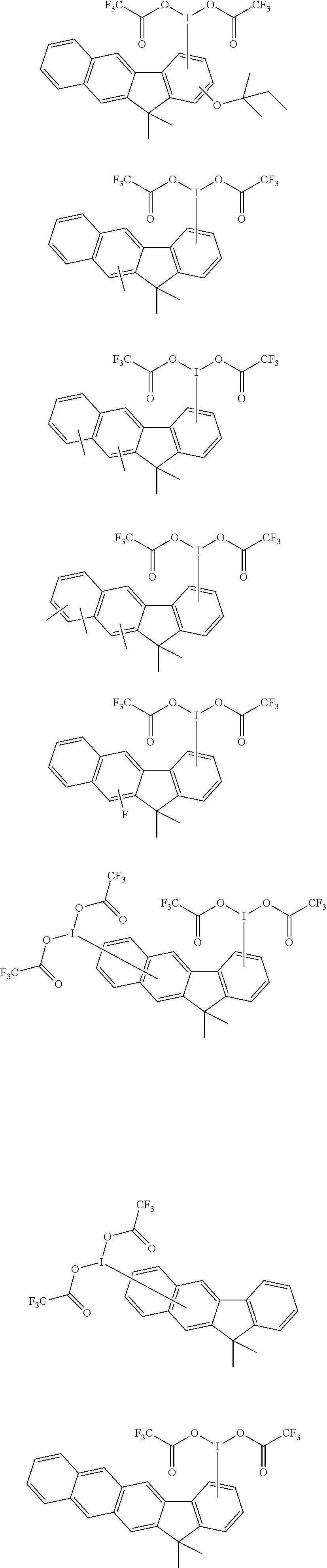

[chemical structure]

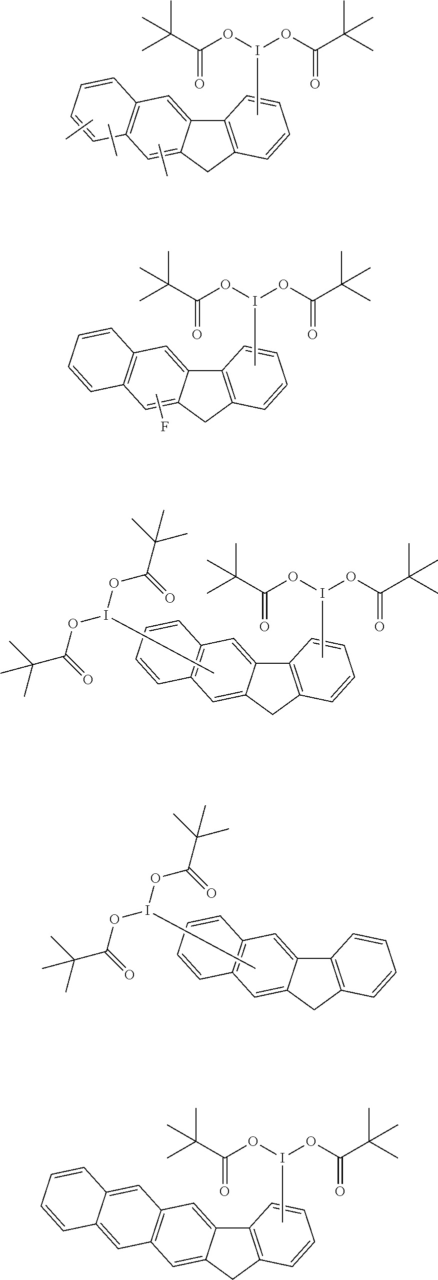

[chemical structure]

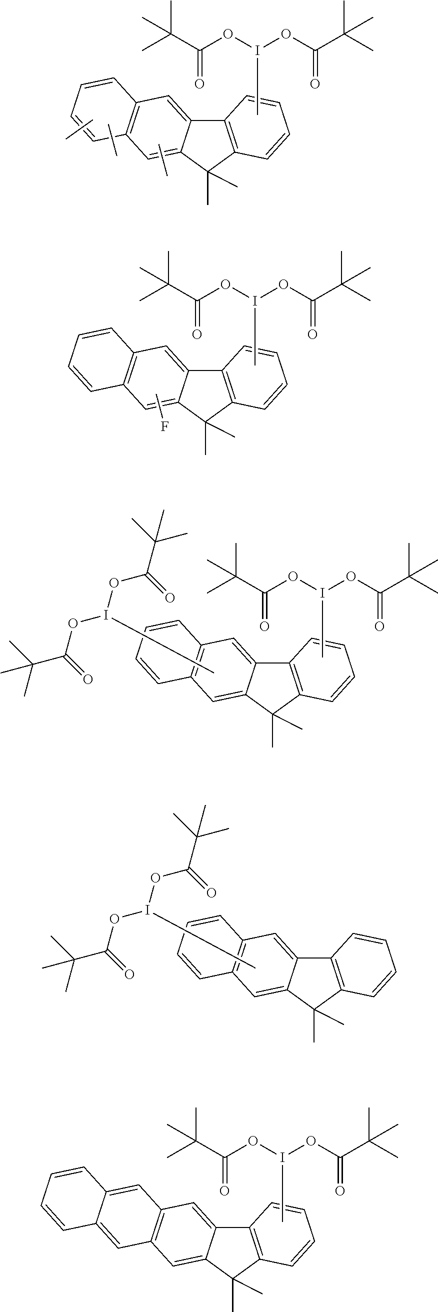

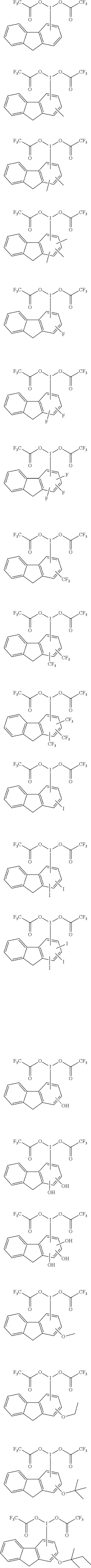

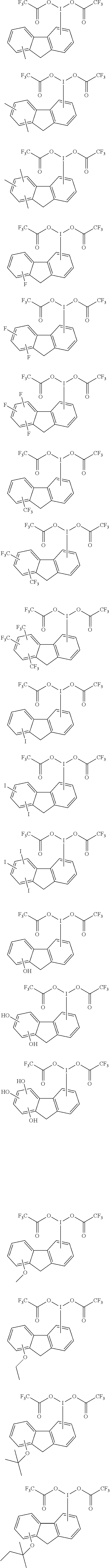

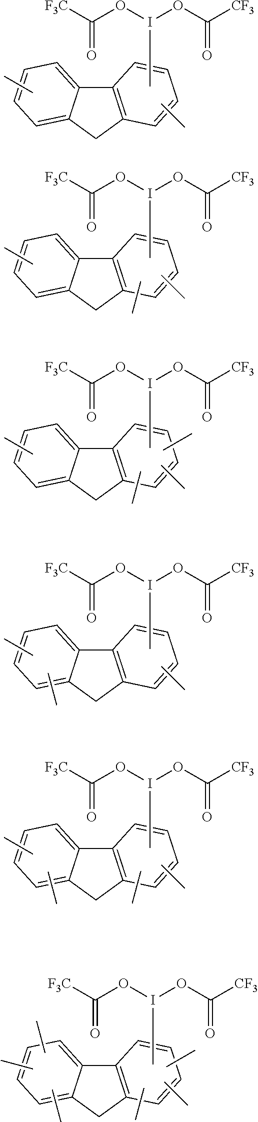

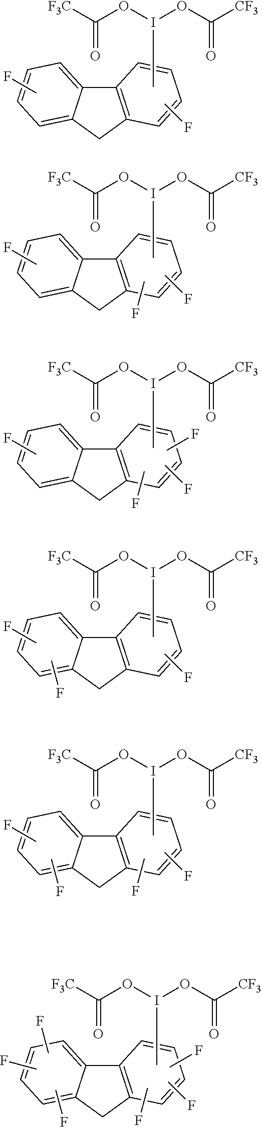

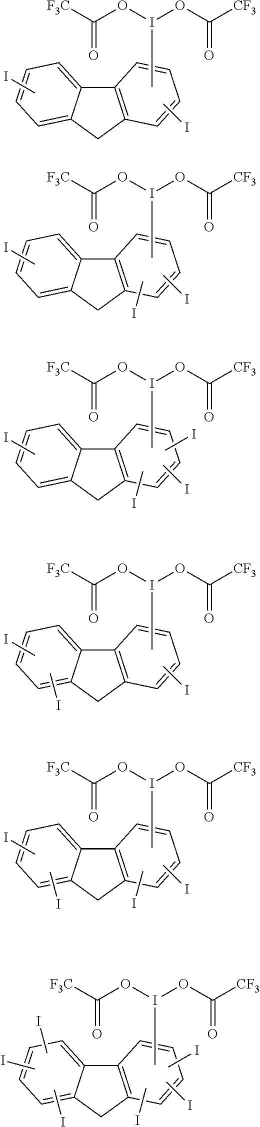

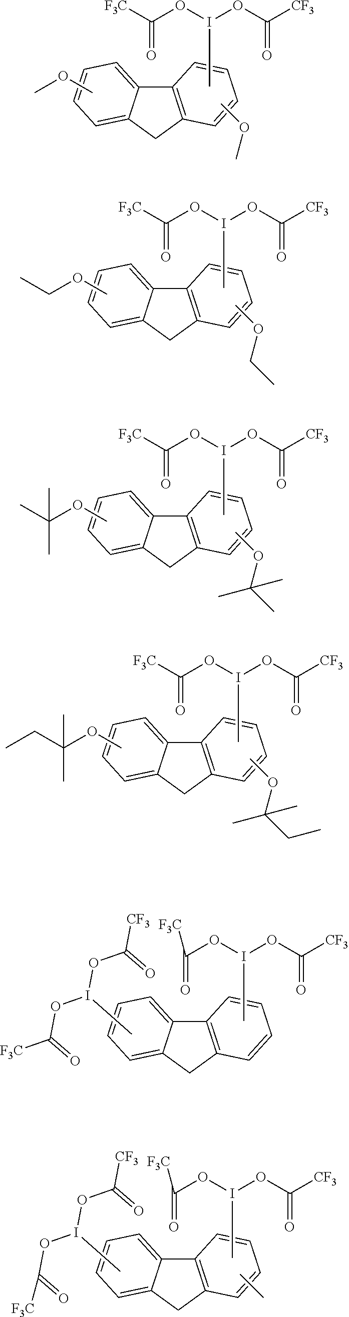

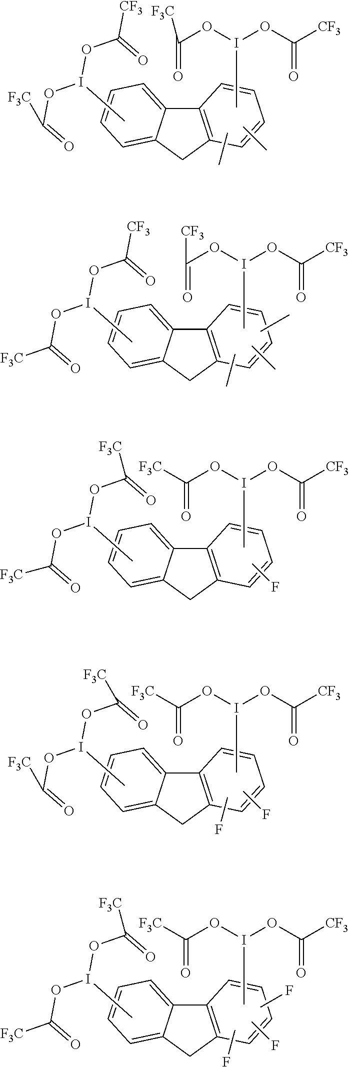

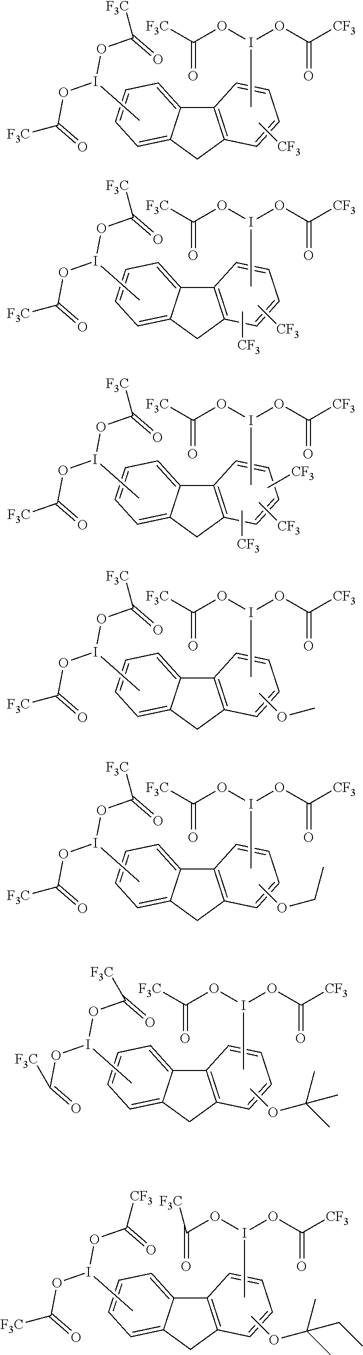

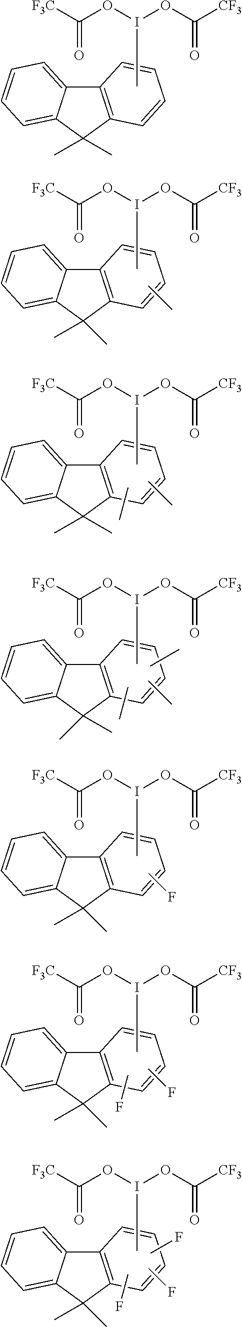

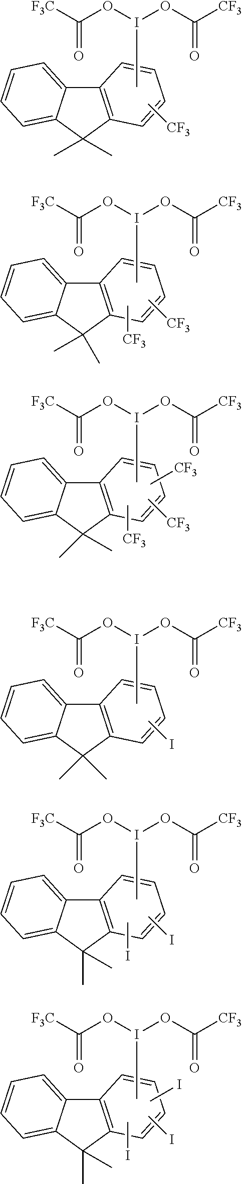

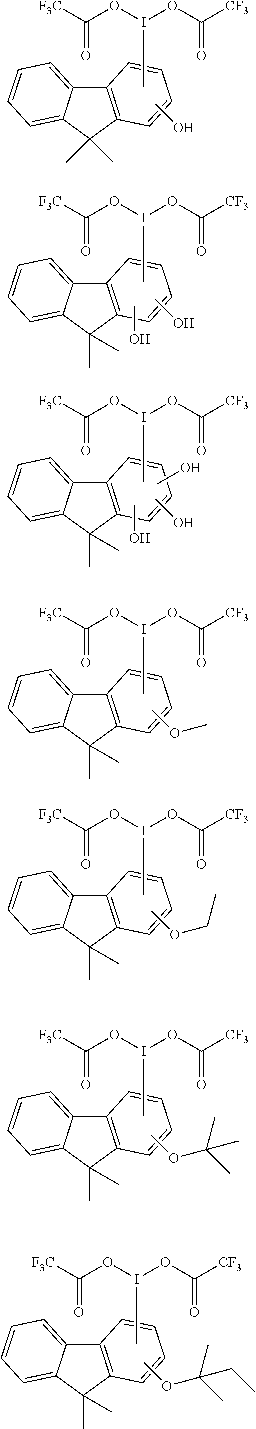

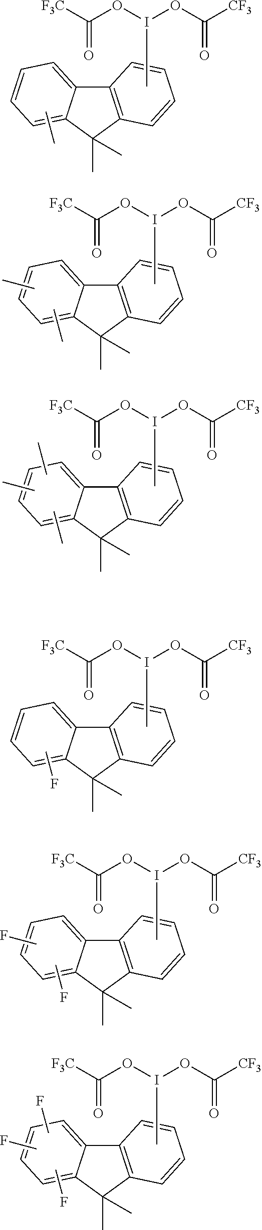

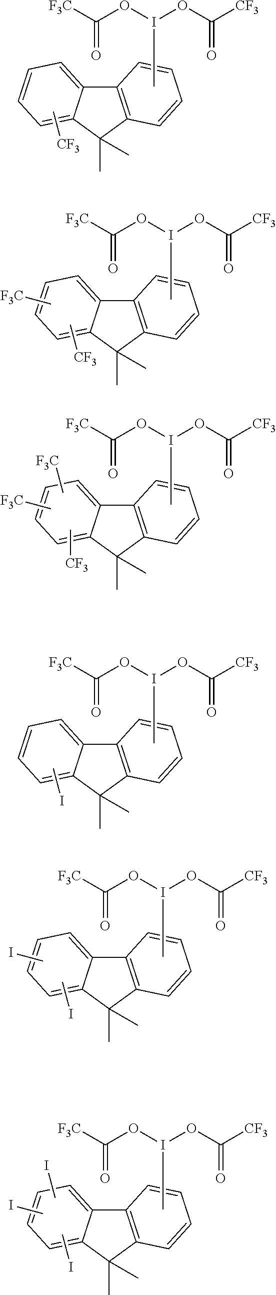

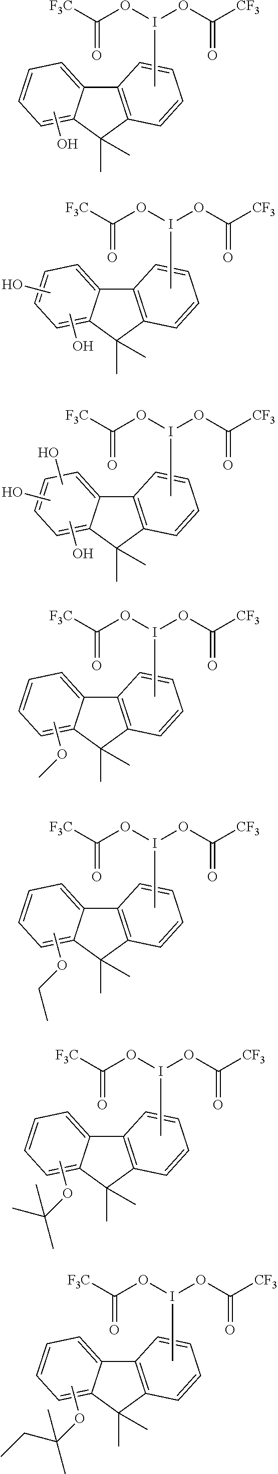

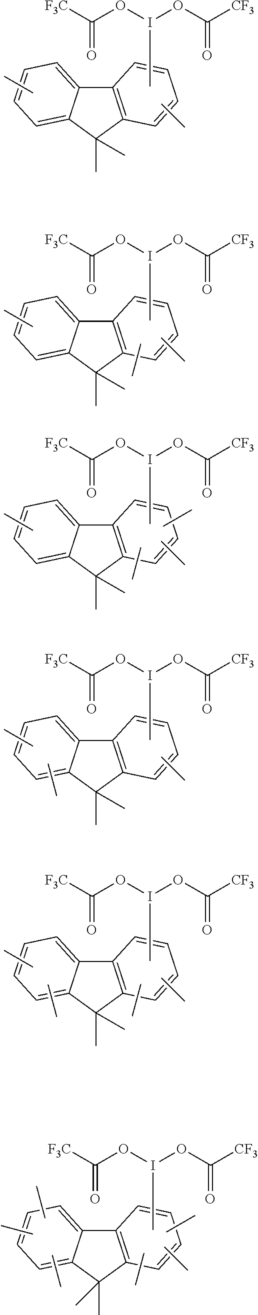

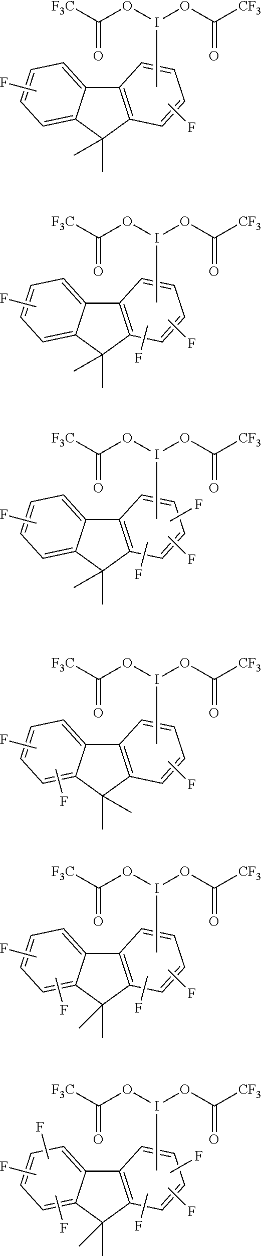

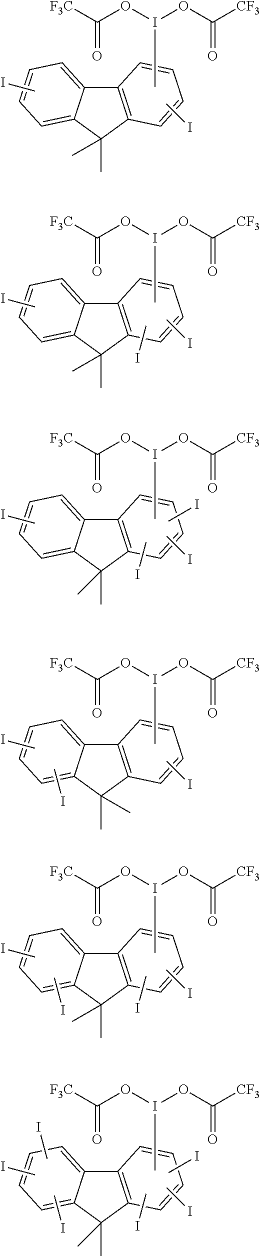

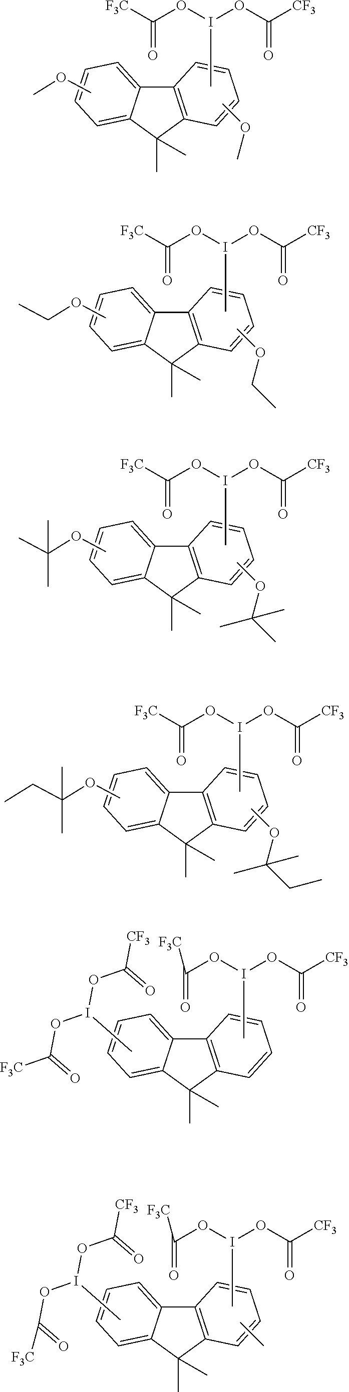

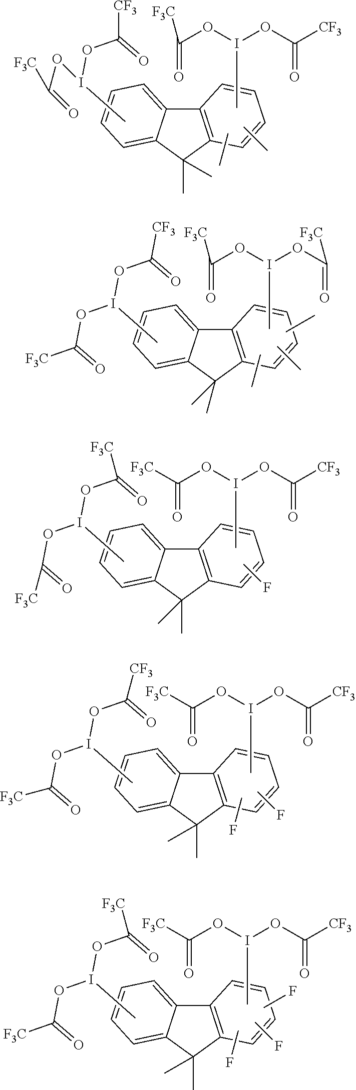

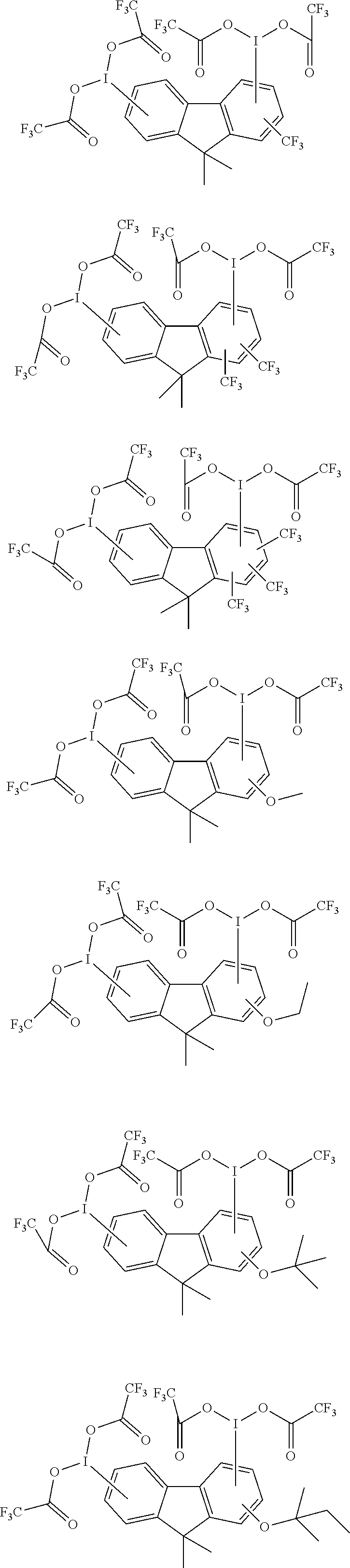

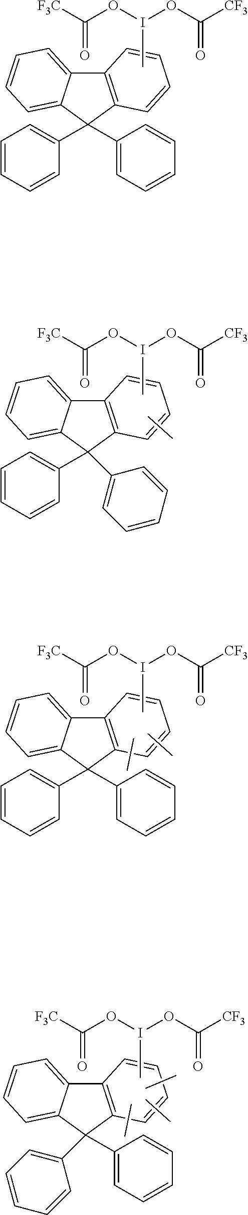

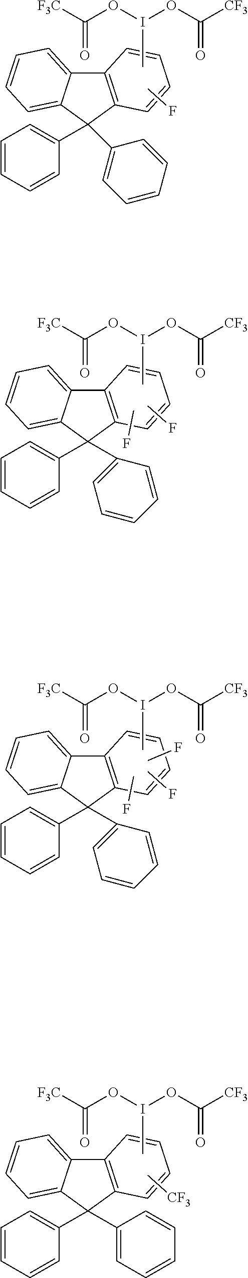

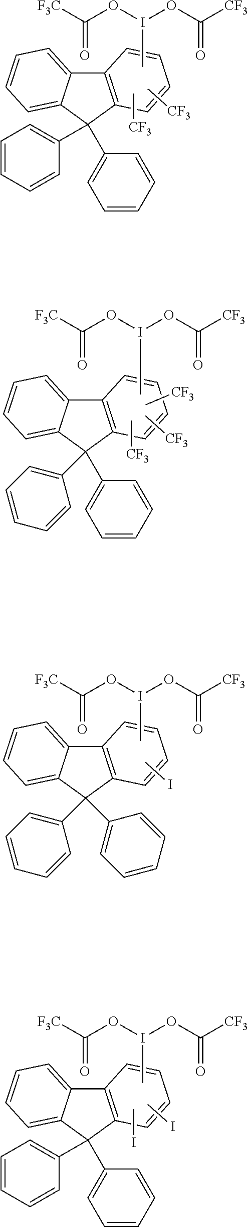

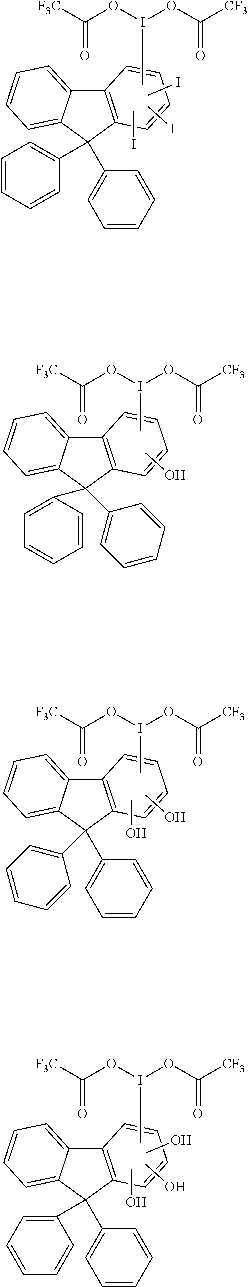

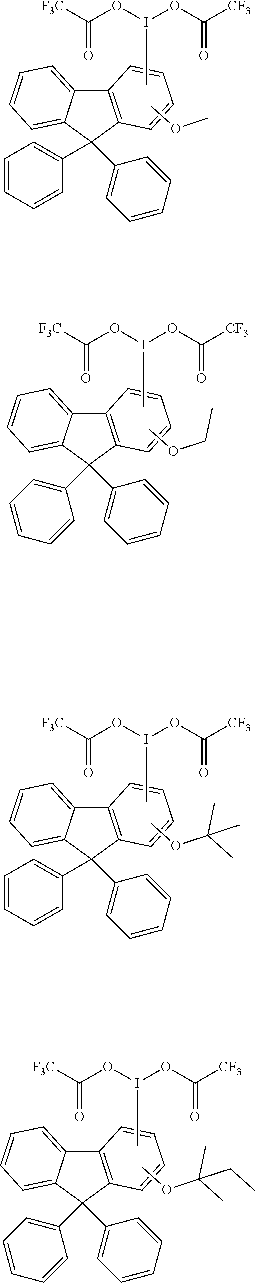

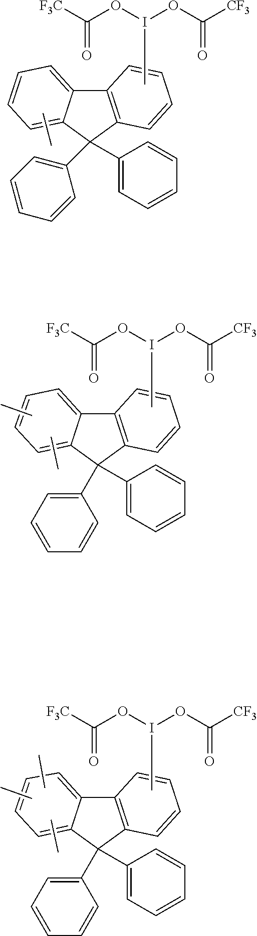

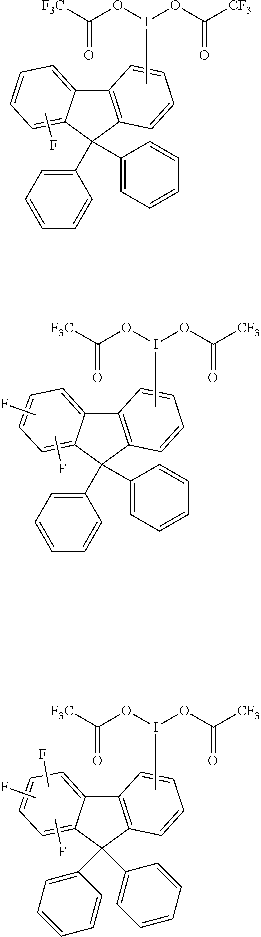

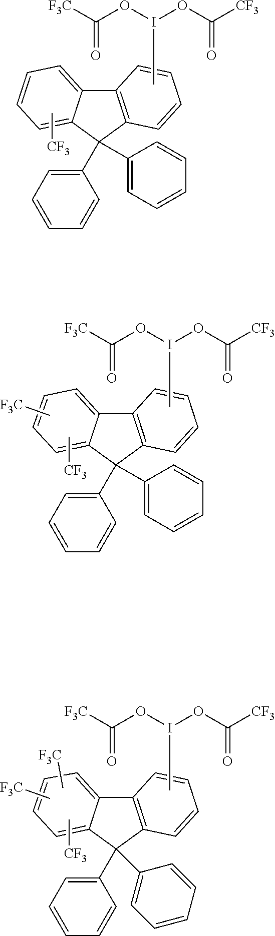

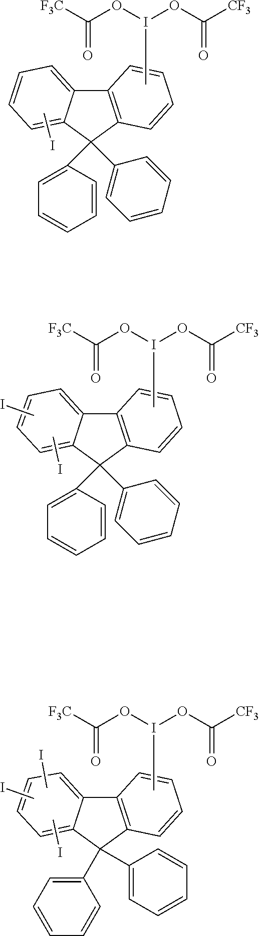

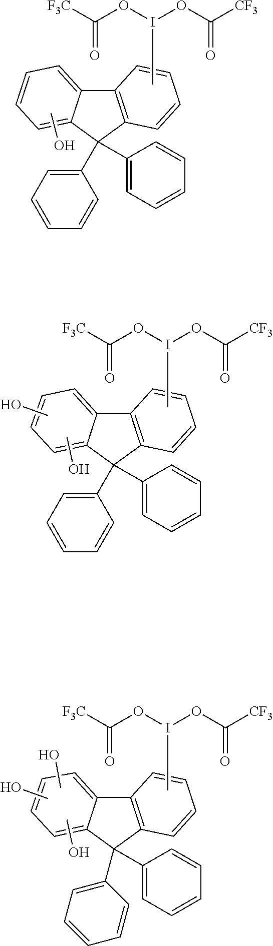

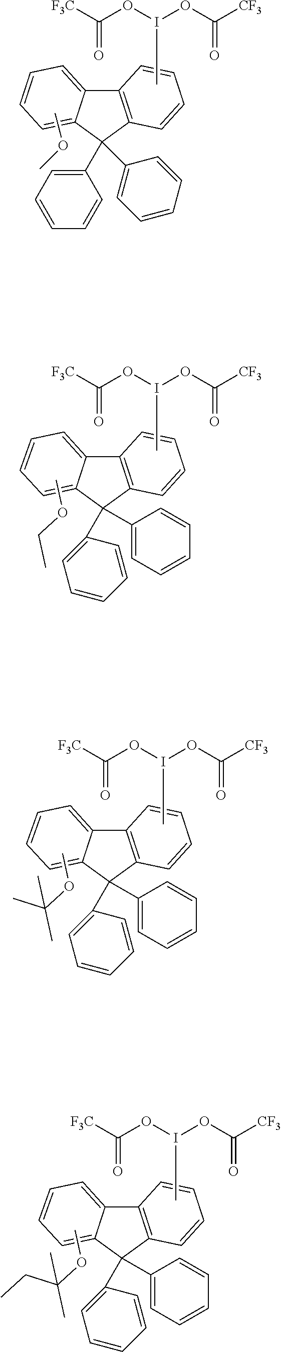

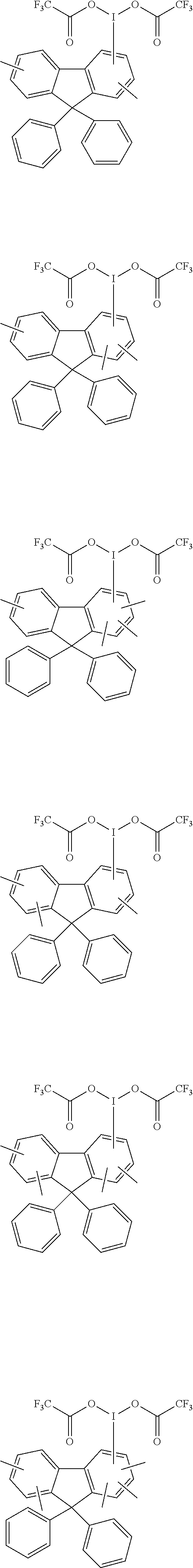

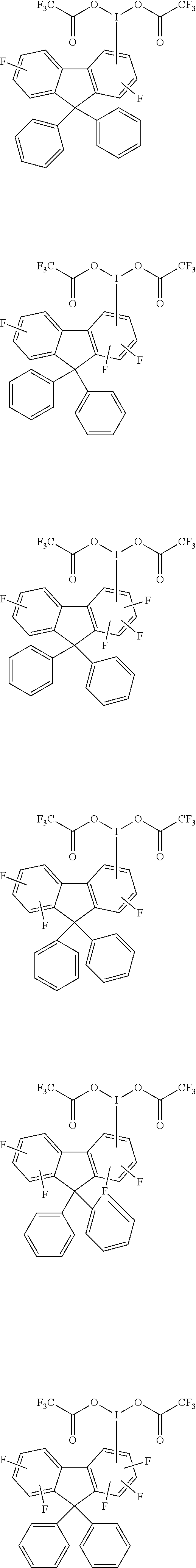

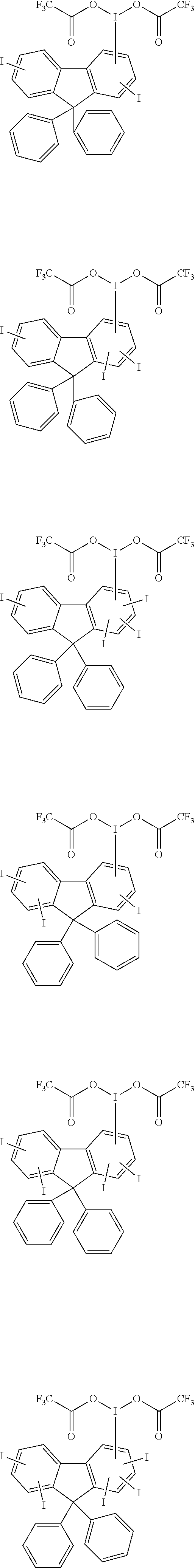

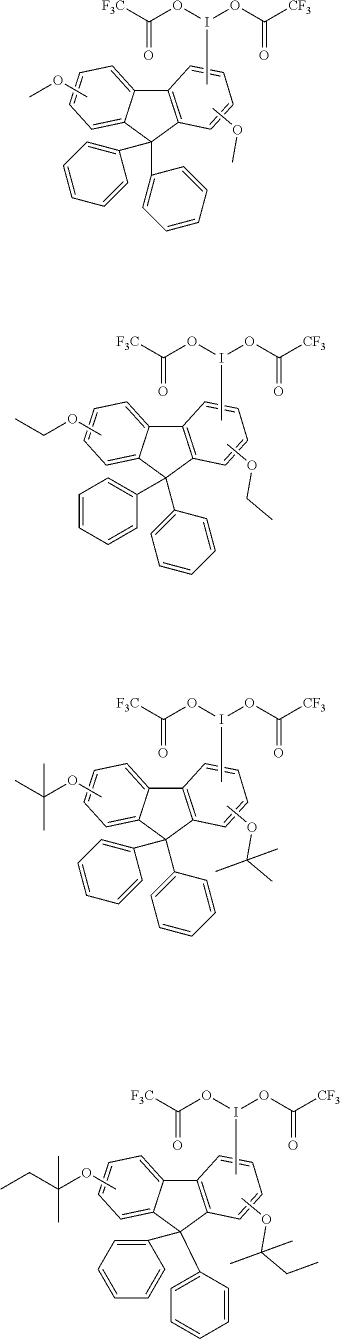

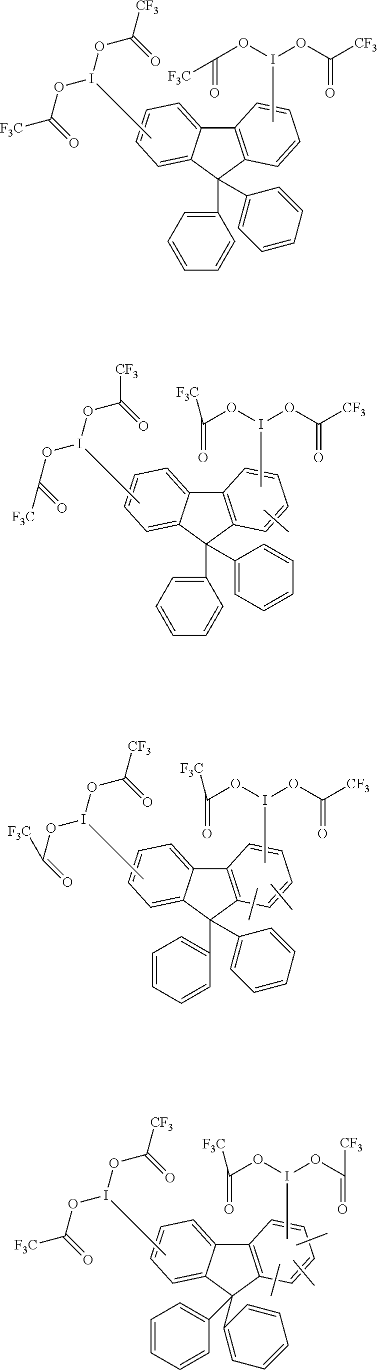

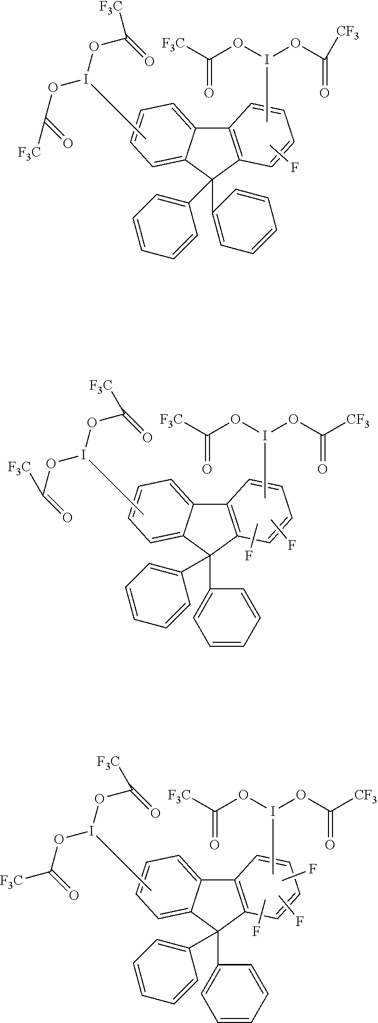

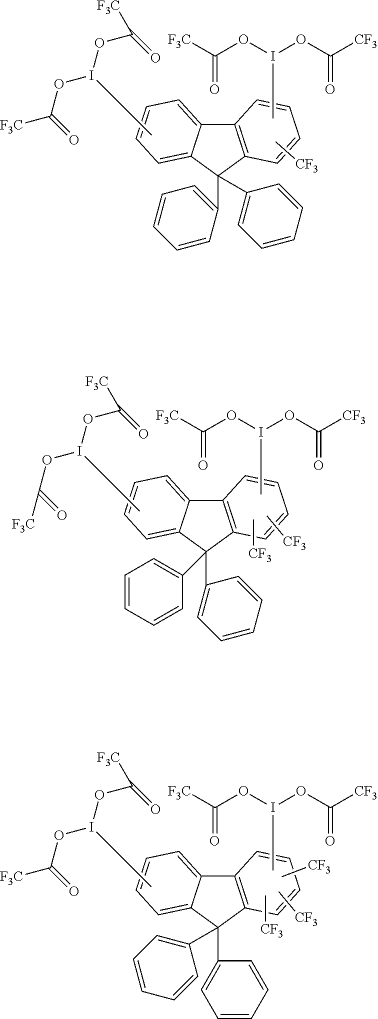

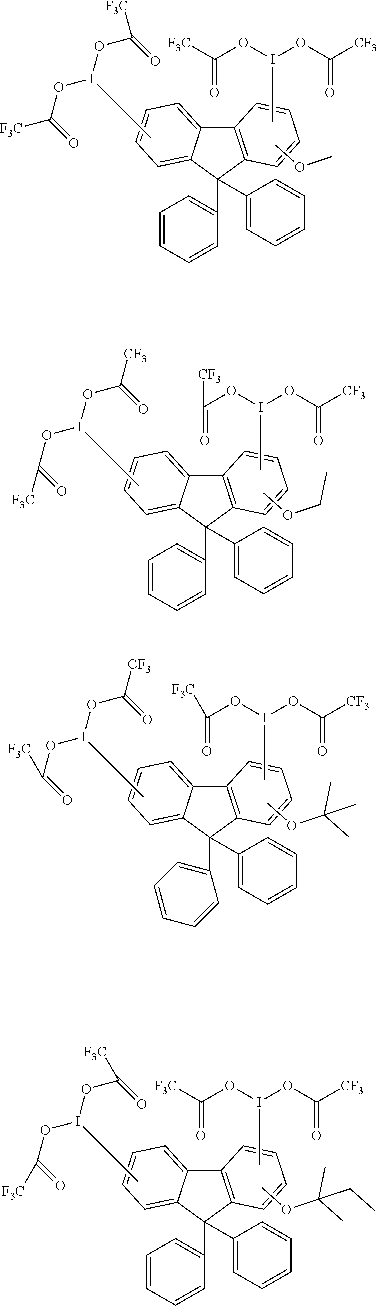

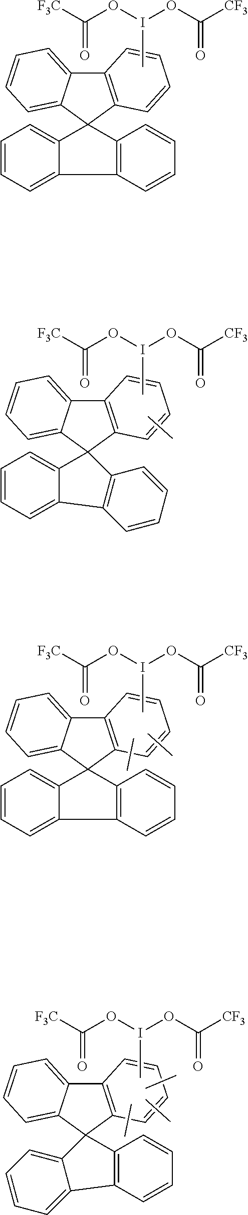

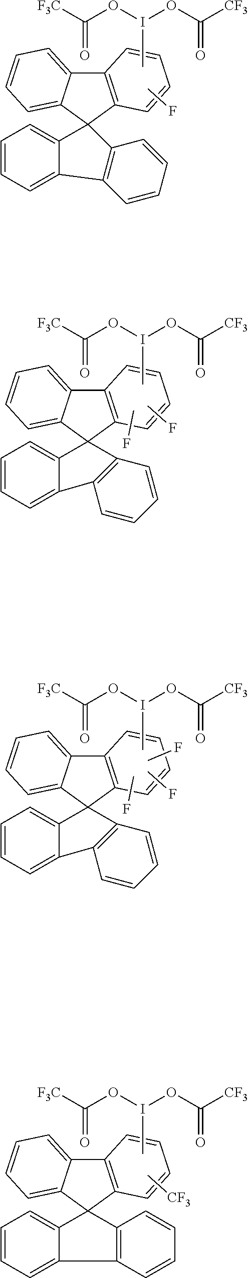

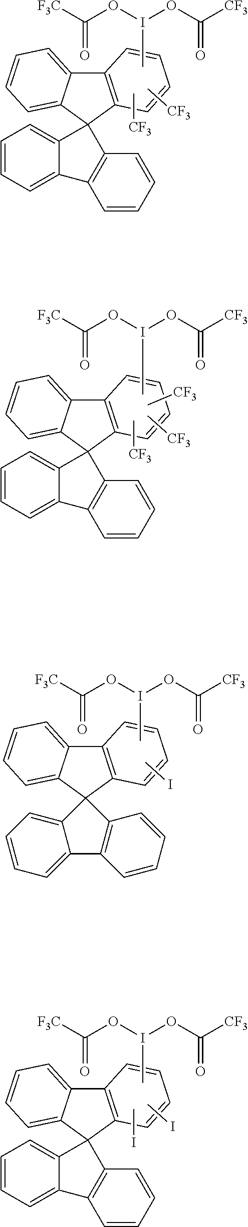

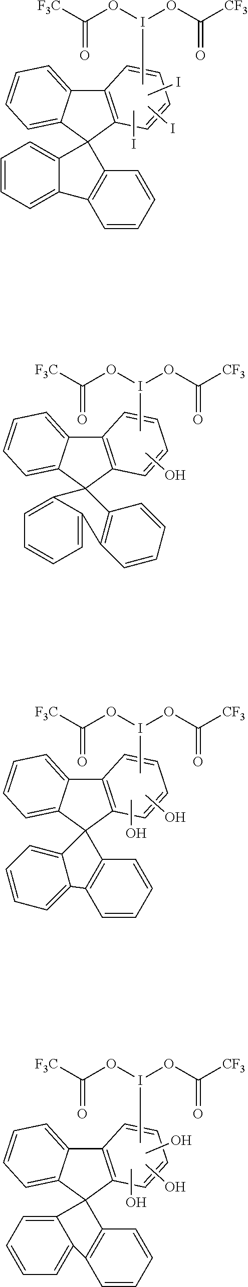

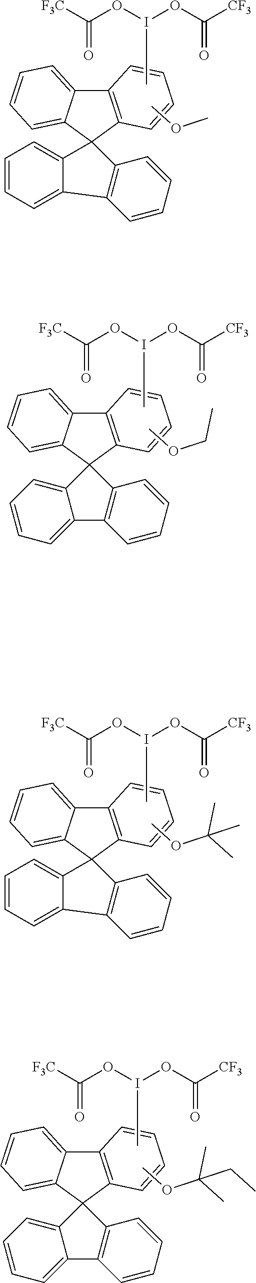

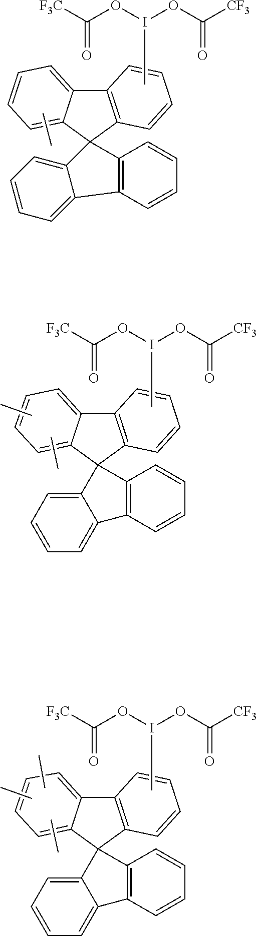

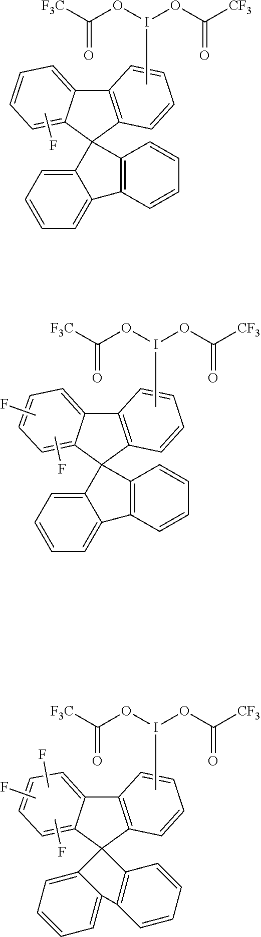

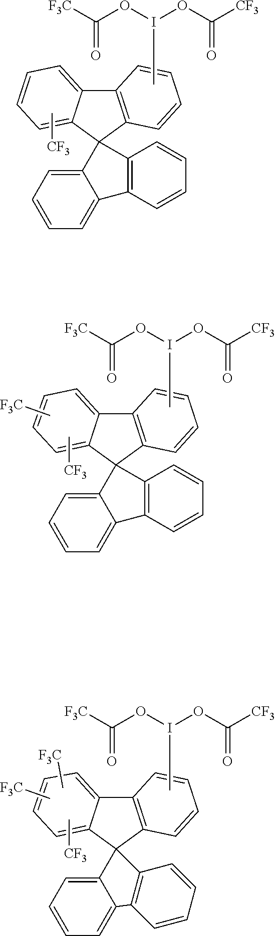

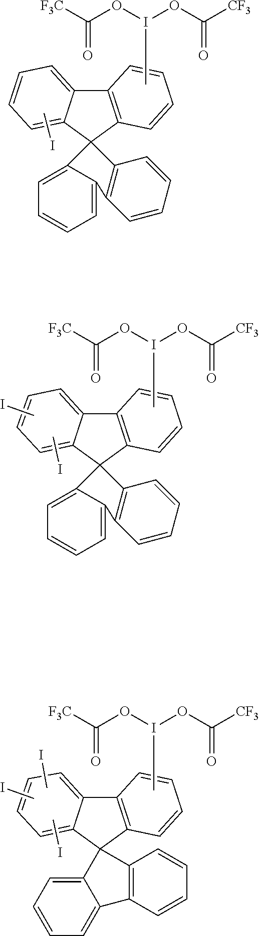

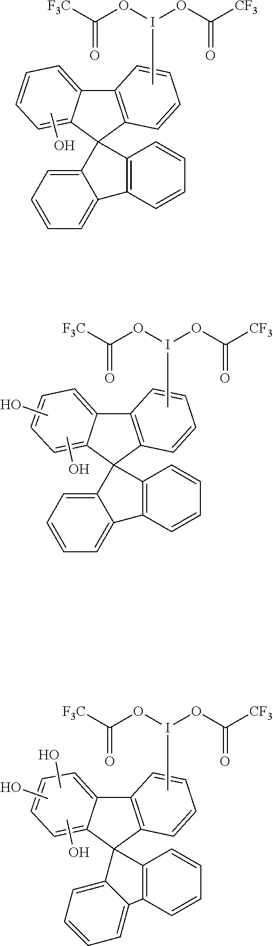

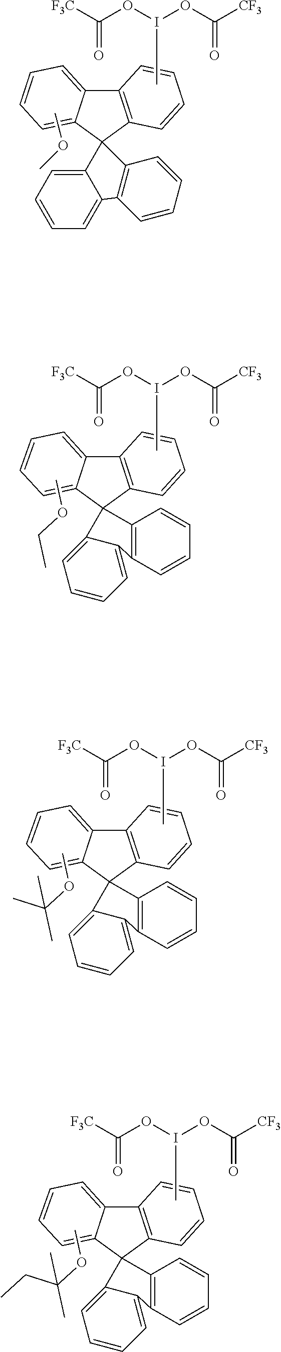

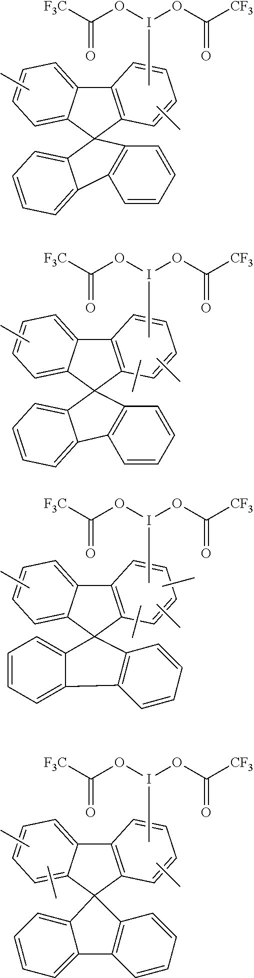

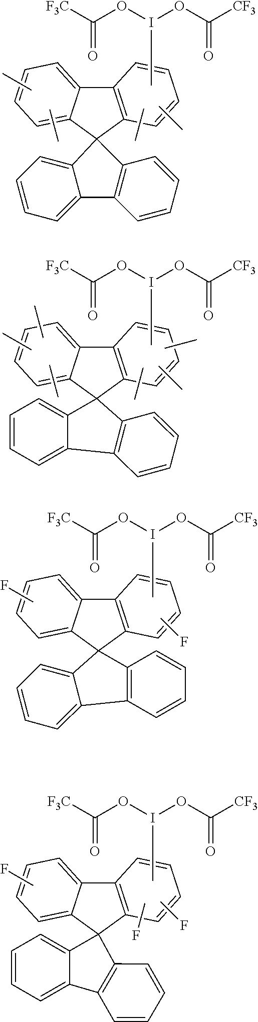

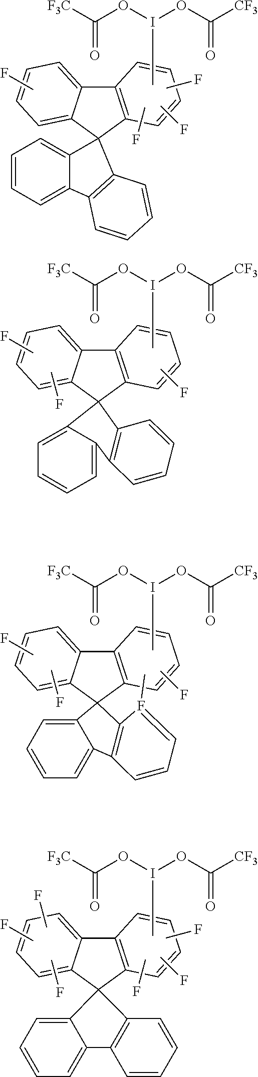

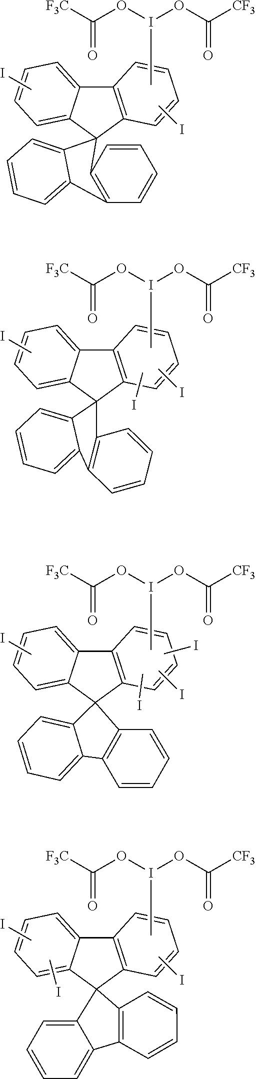

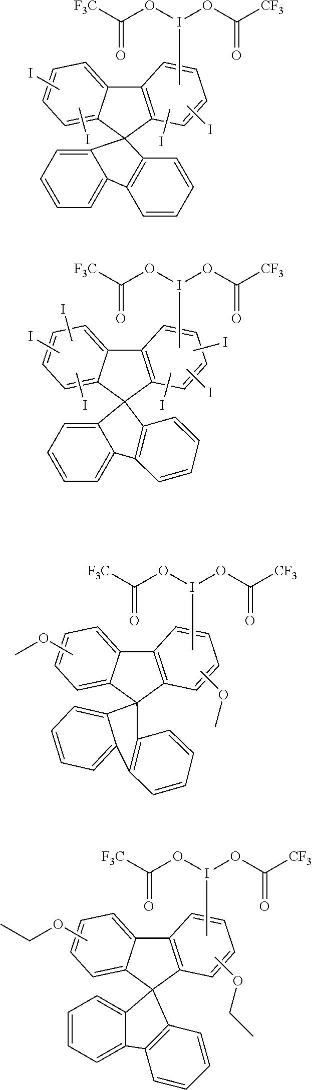

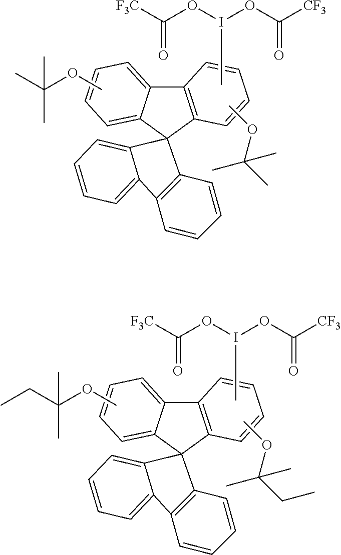

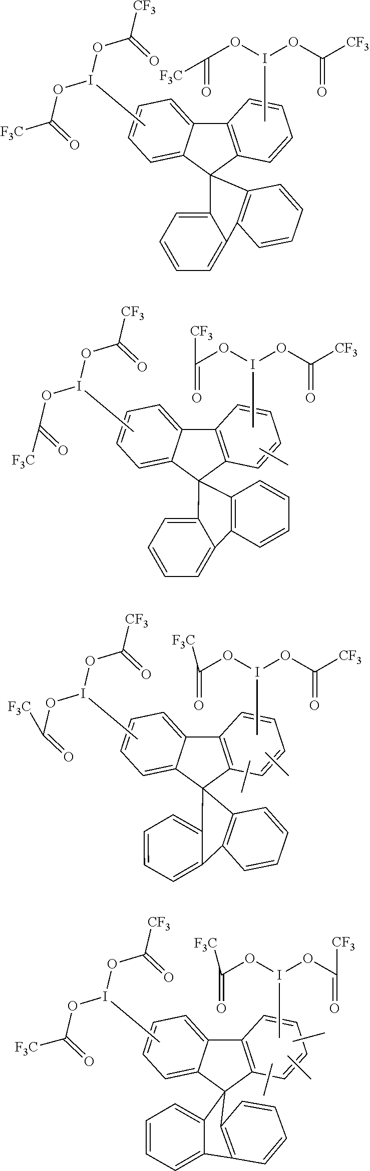

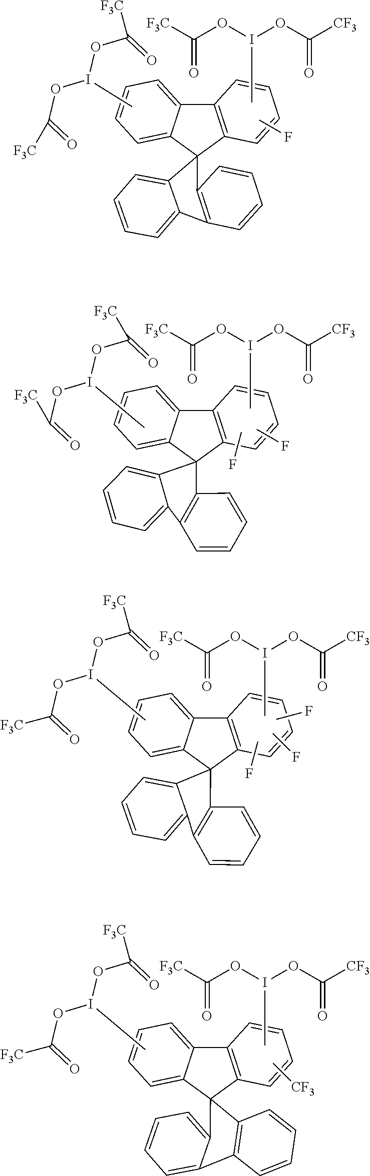

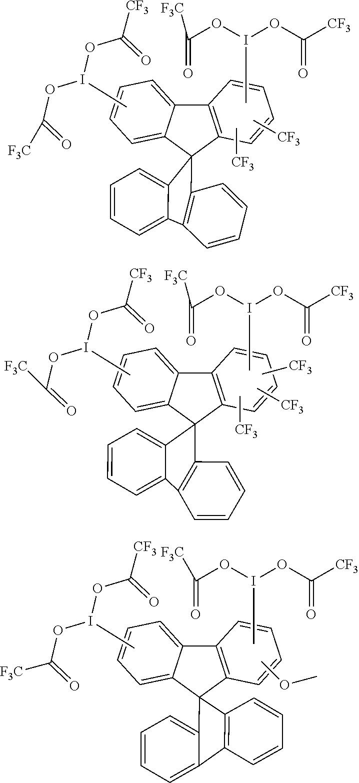

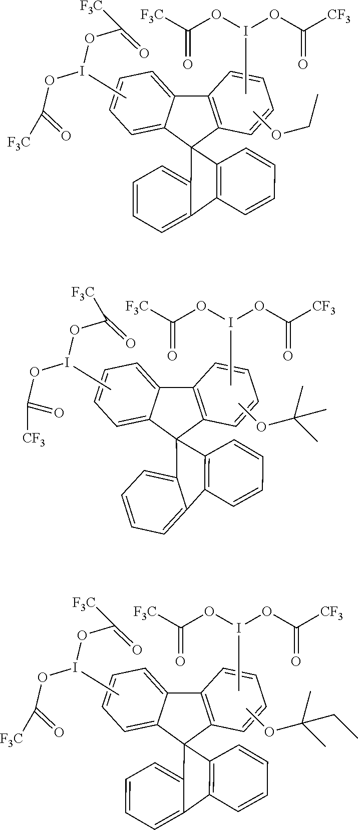

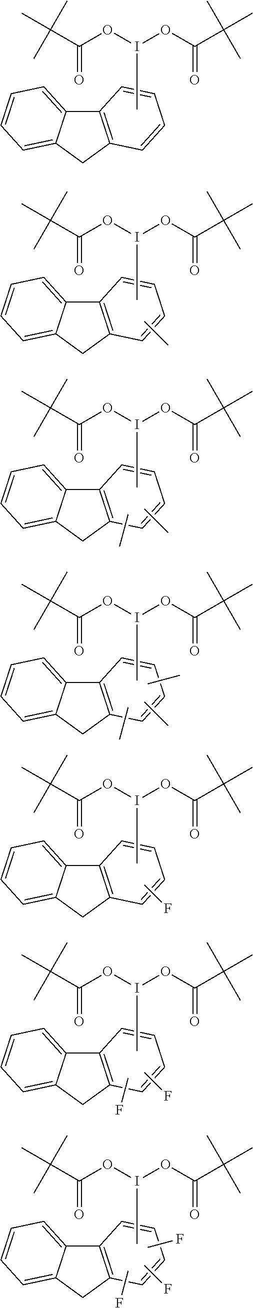

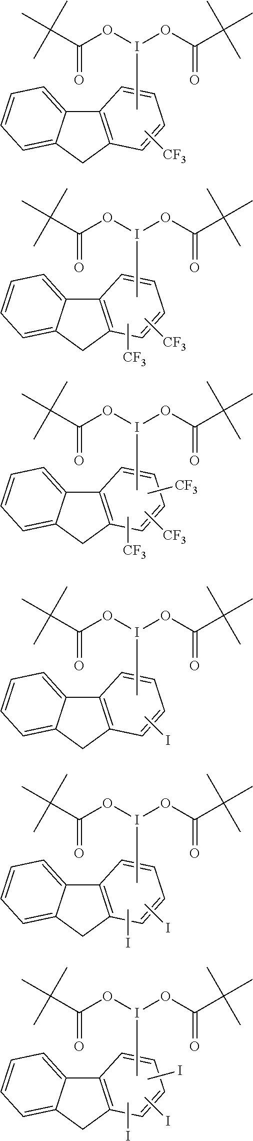

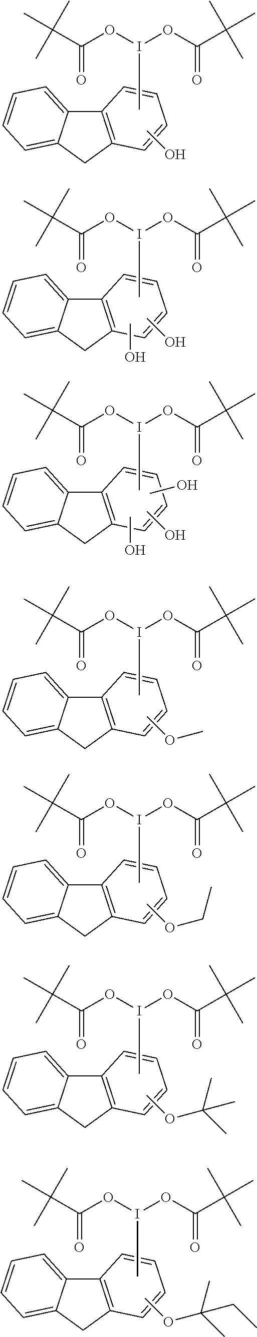

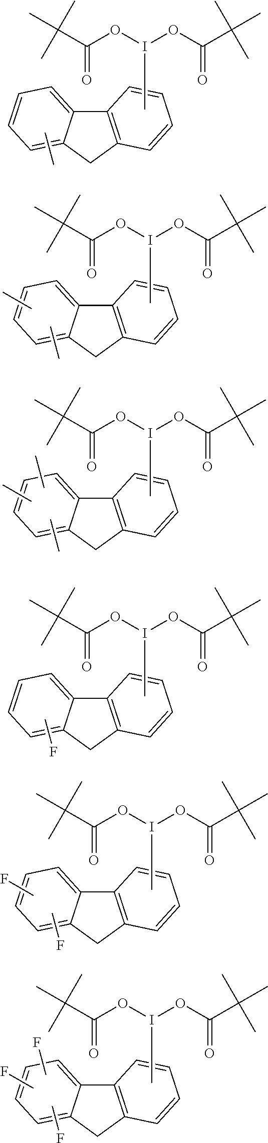

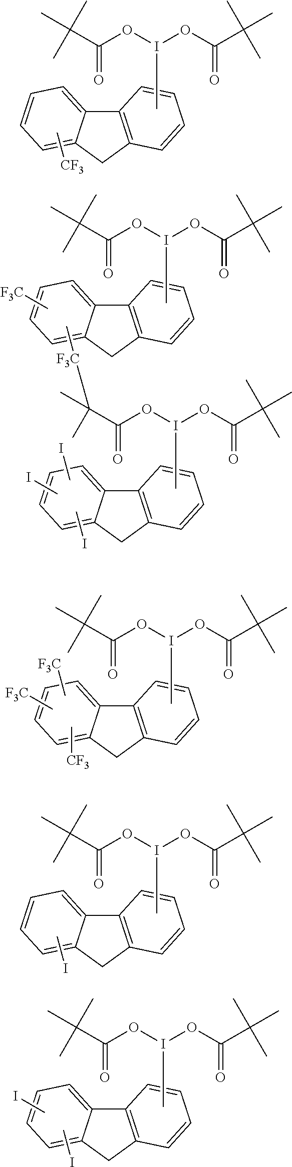

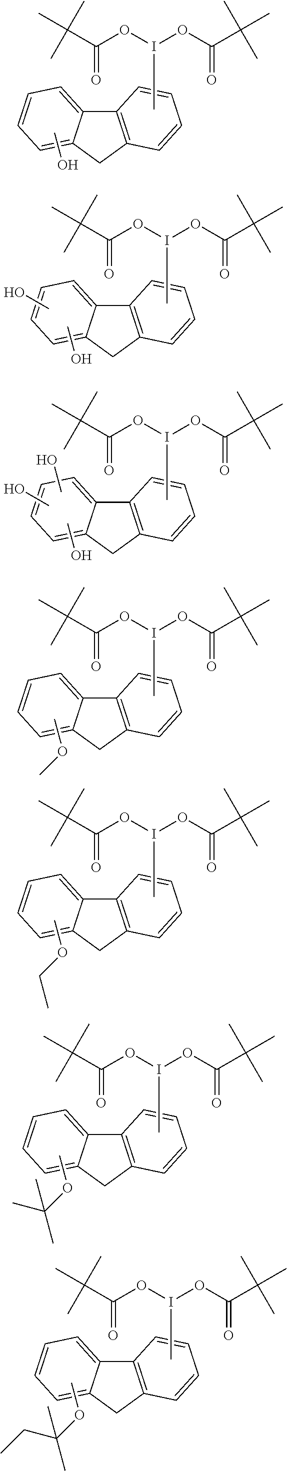

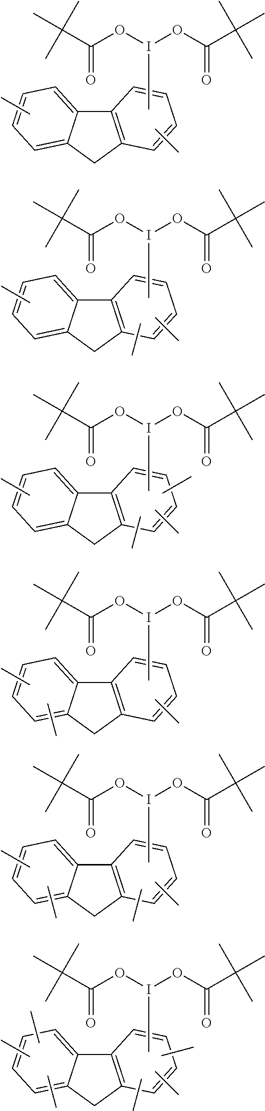

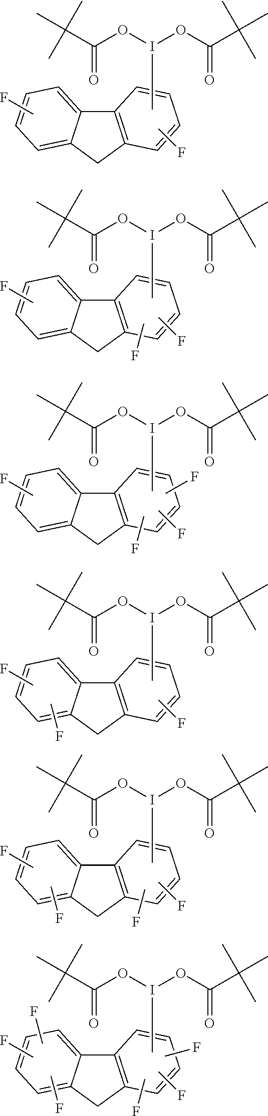

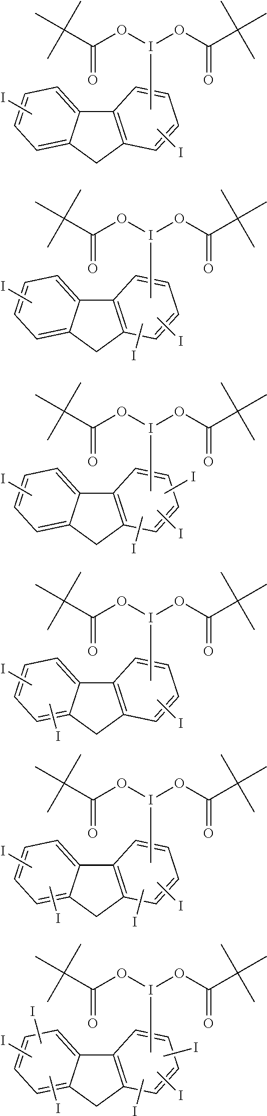

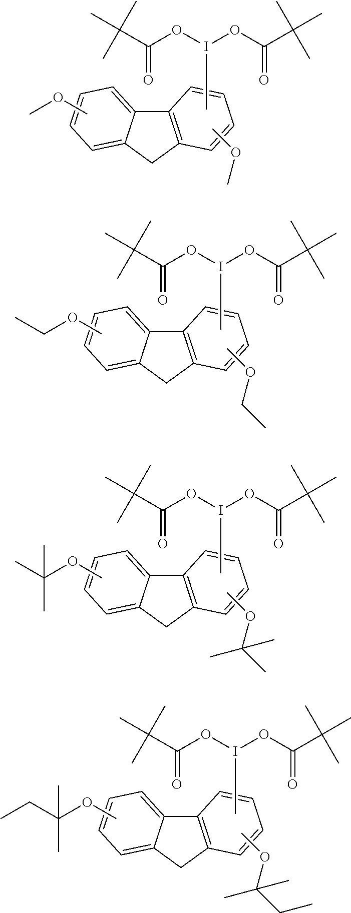

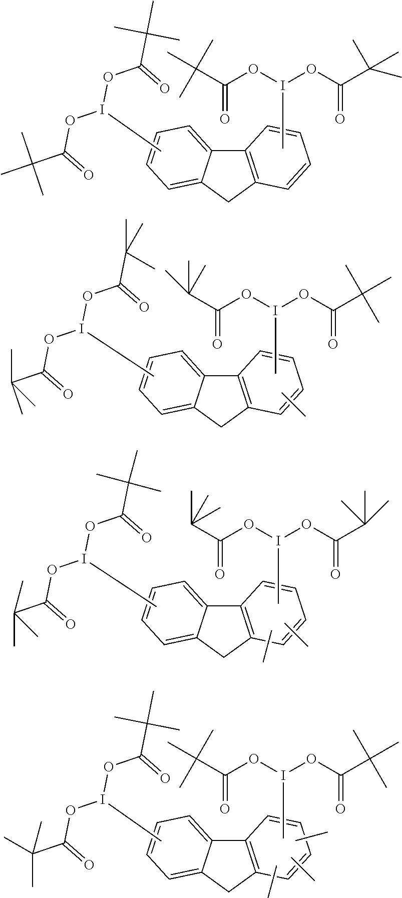

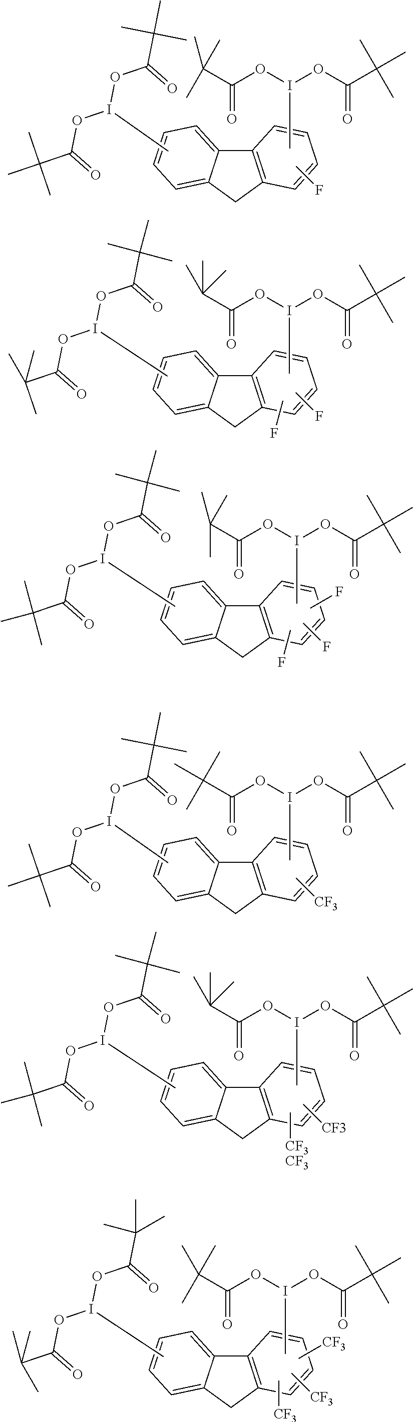

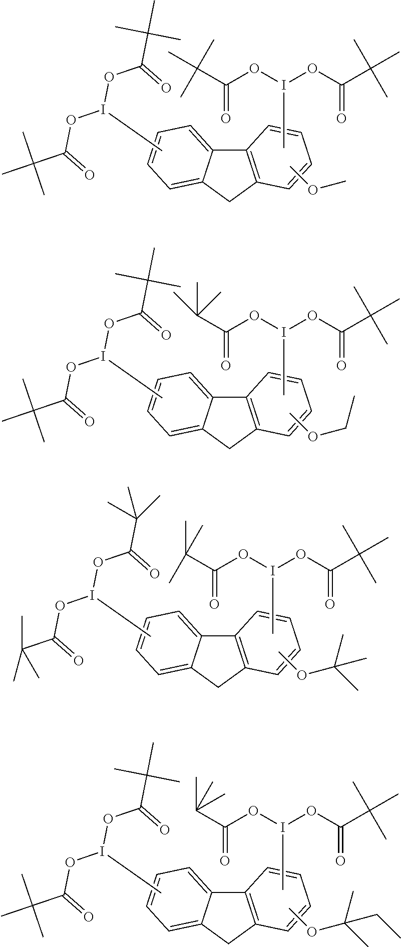

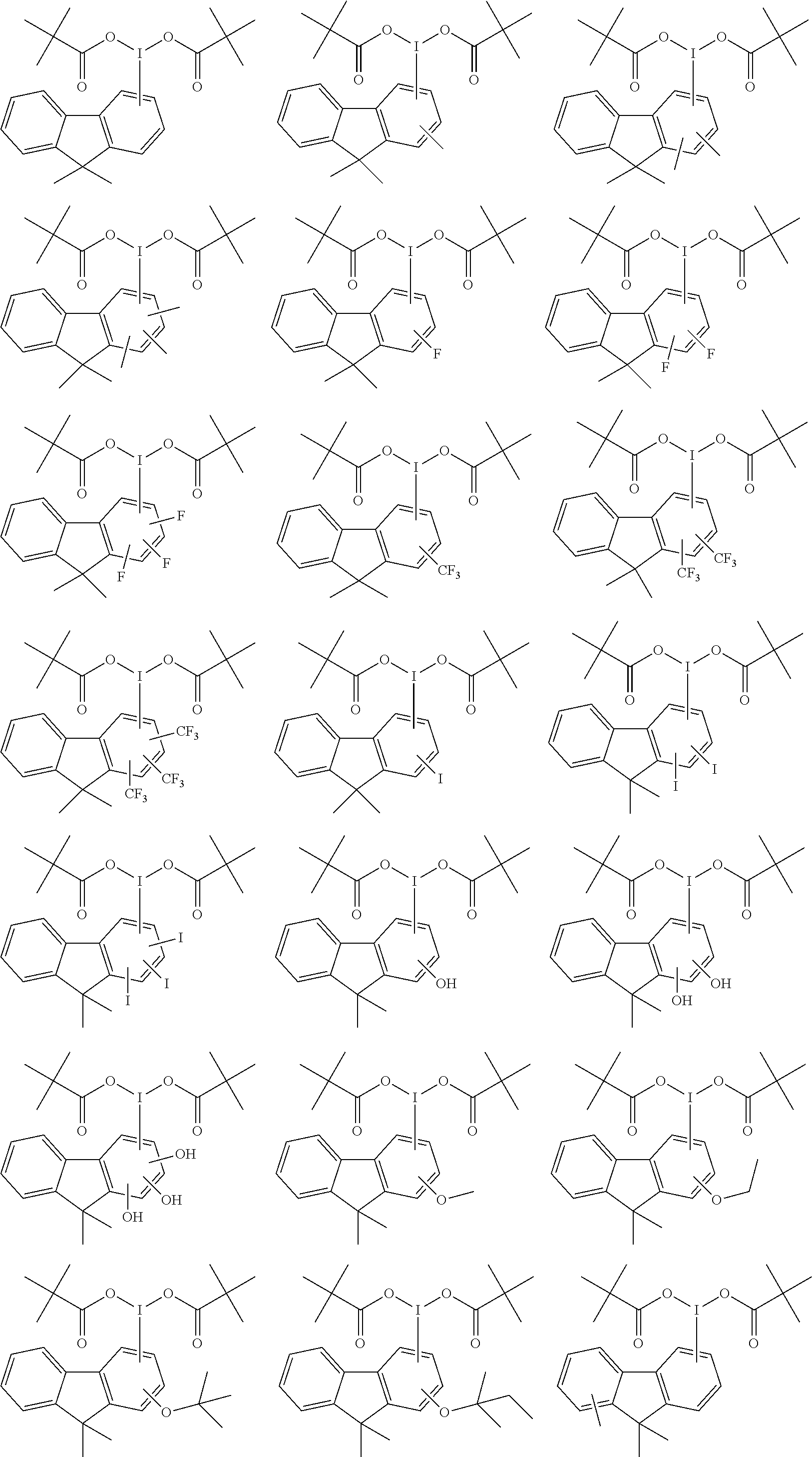

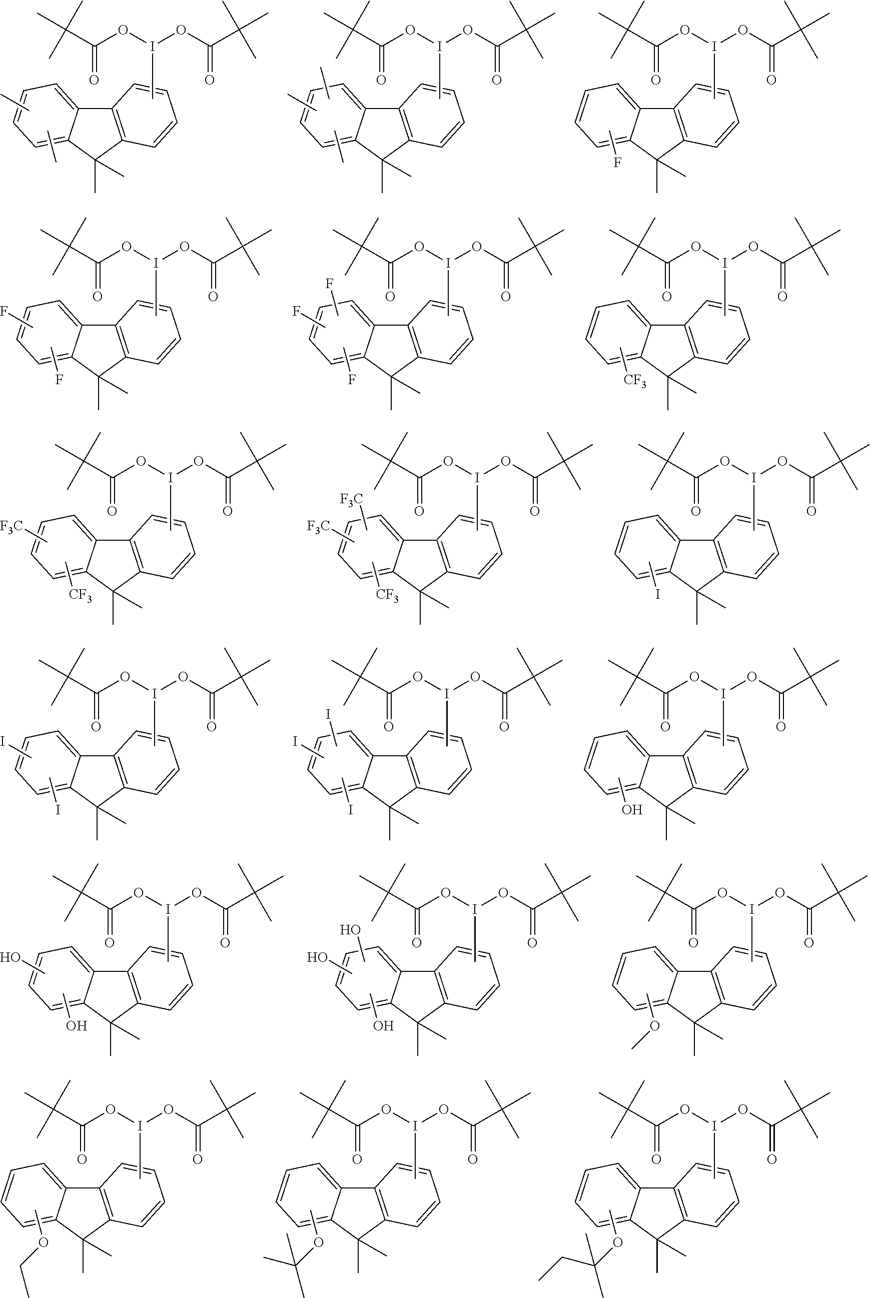

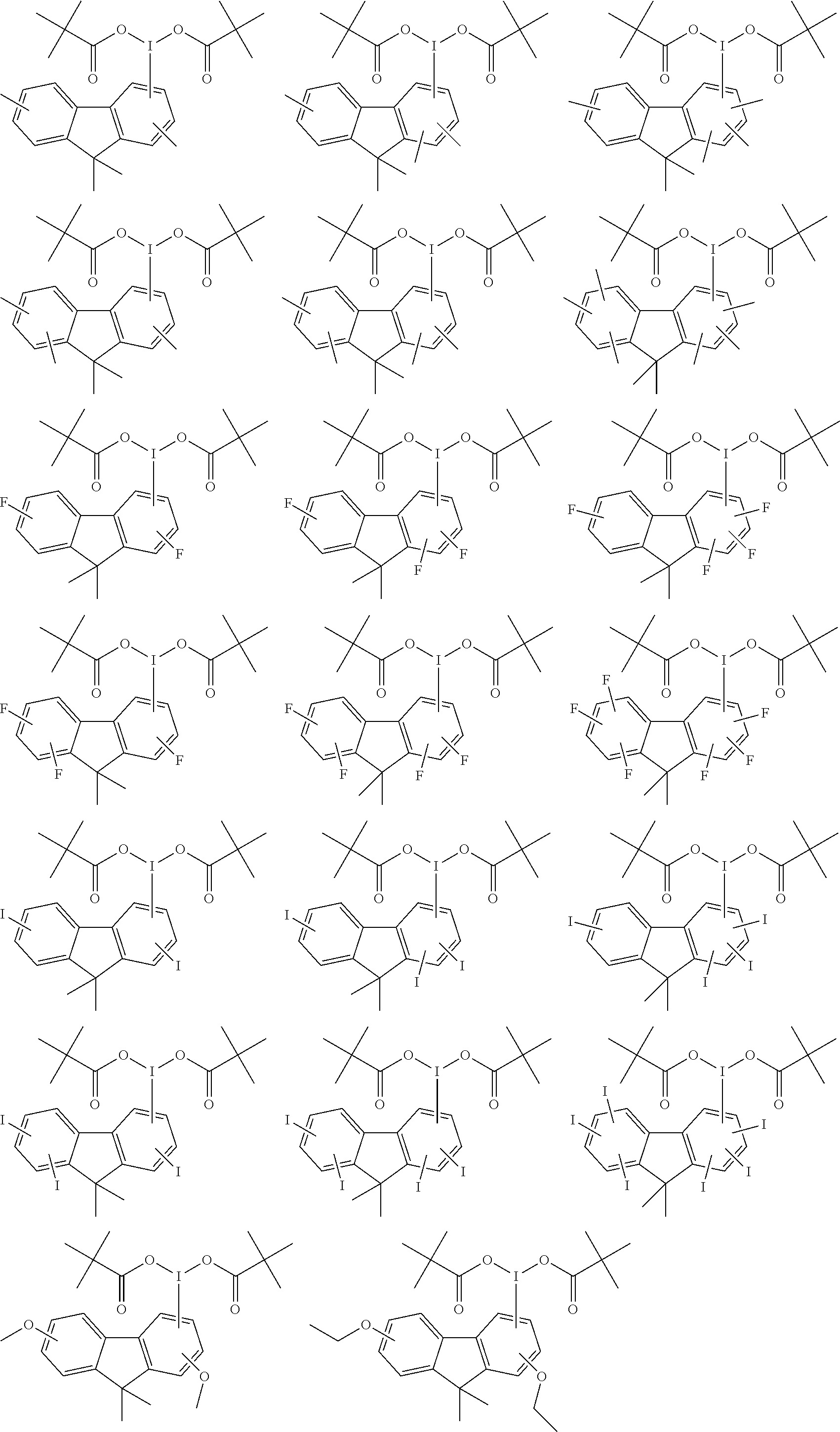

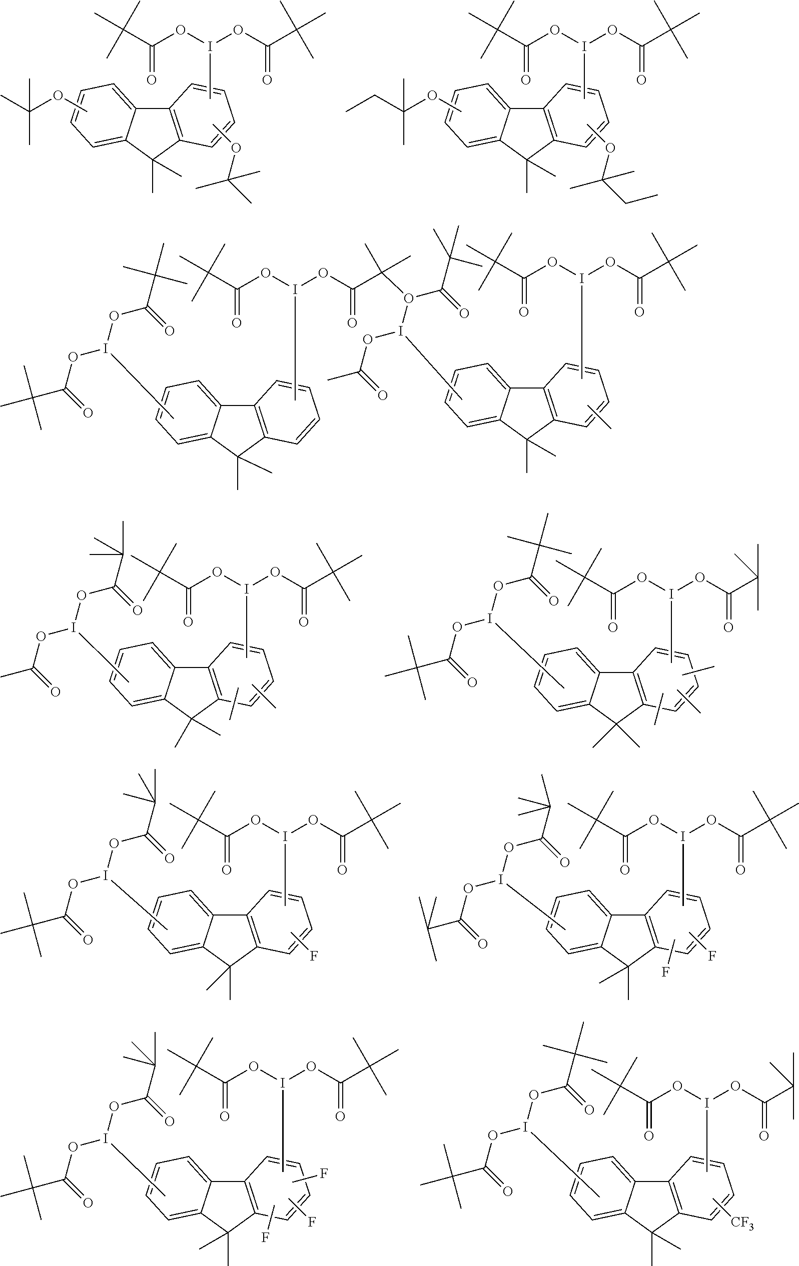

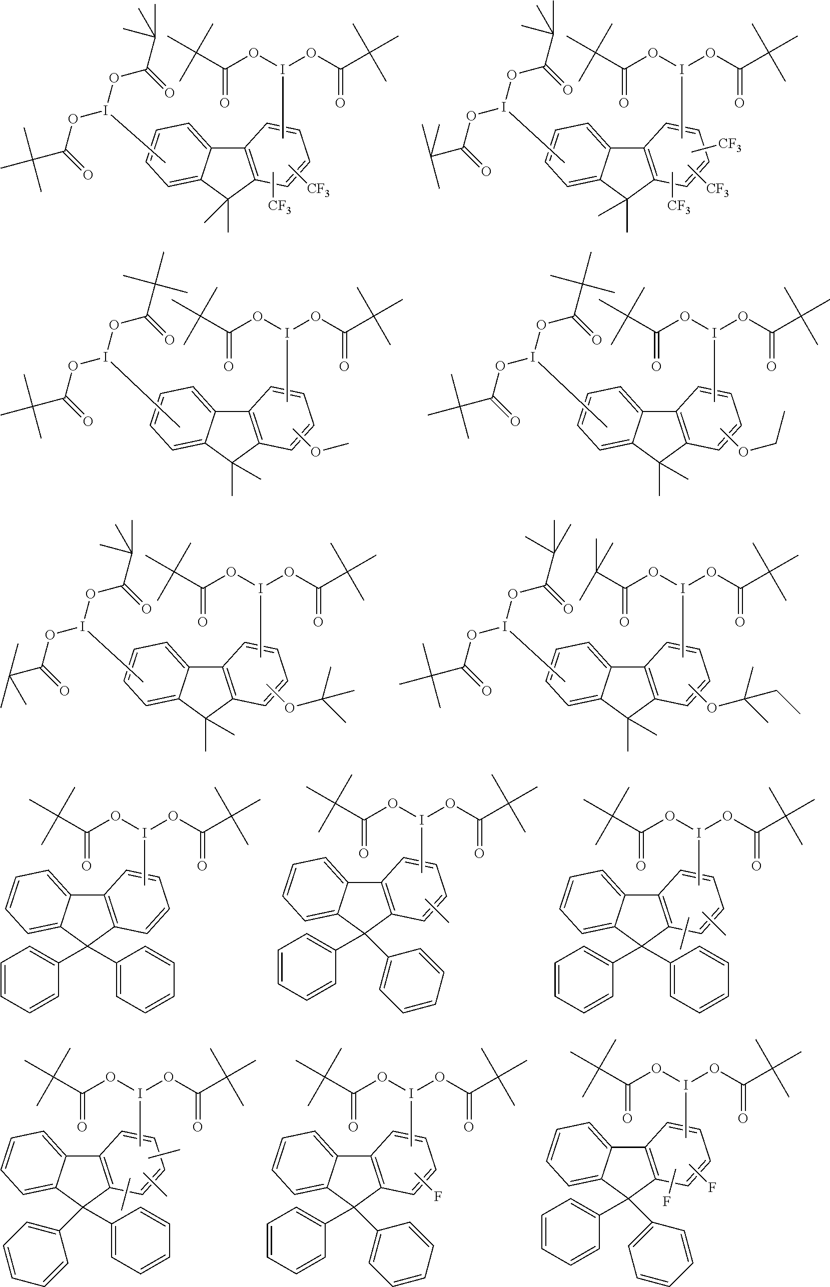

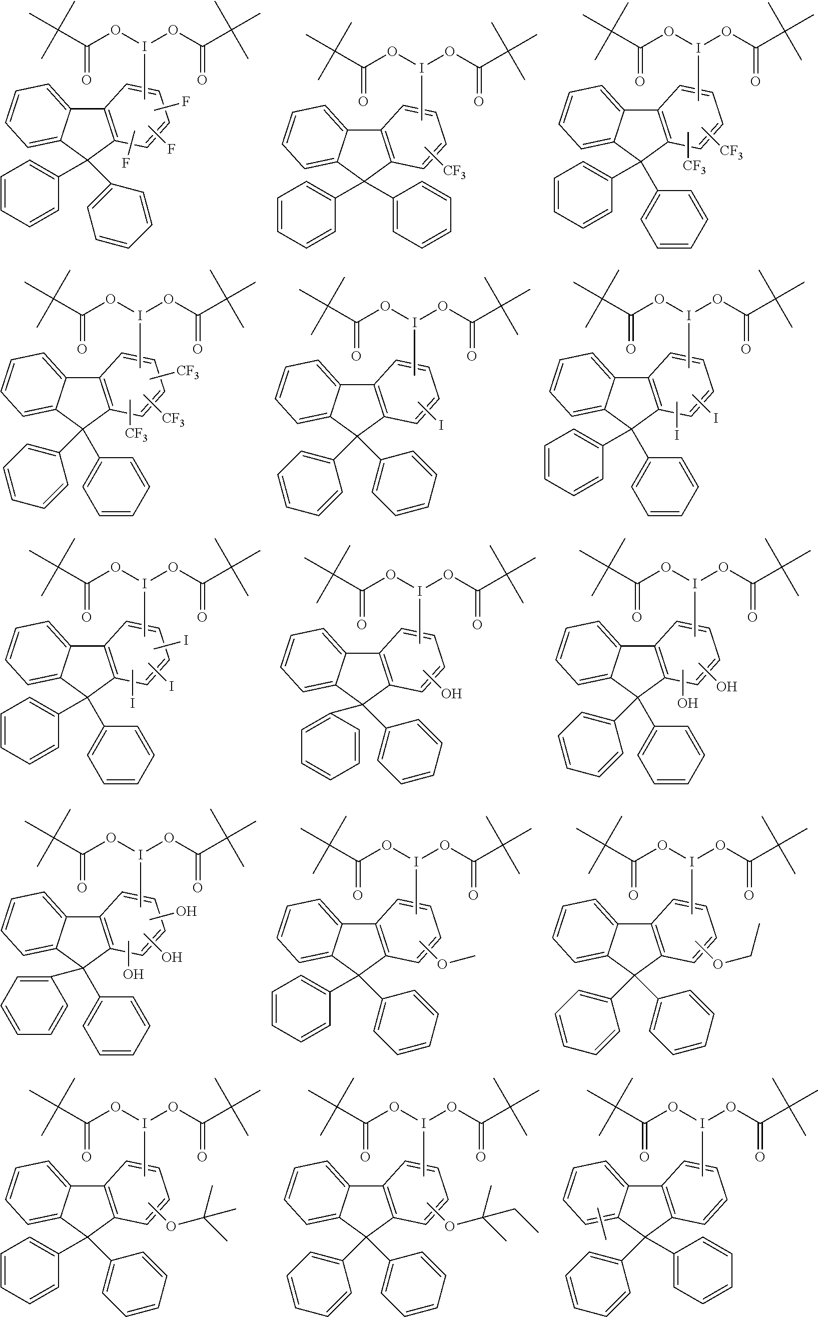

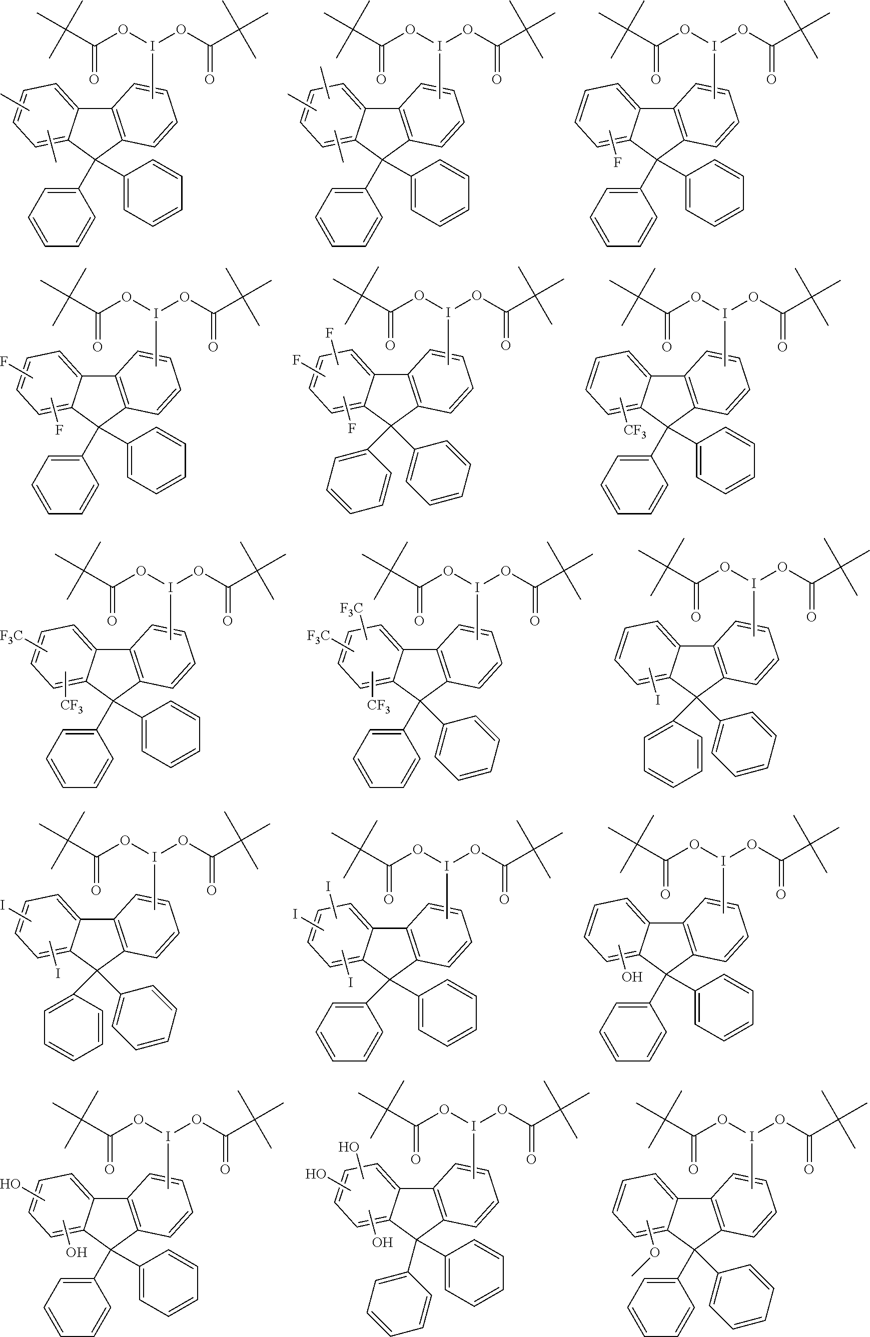

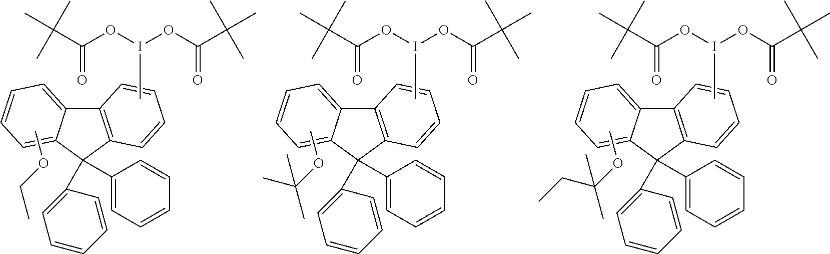

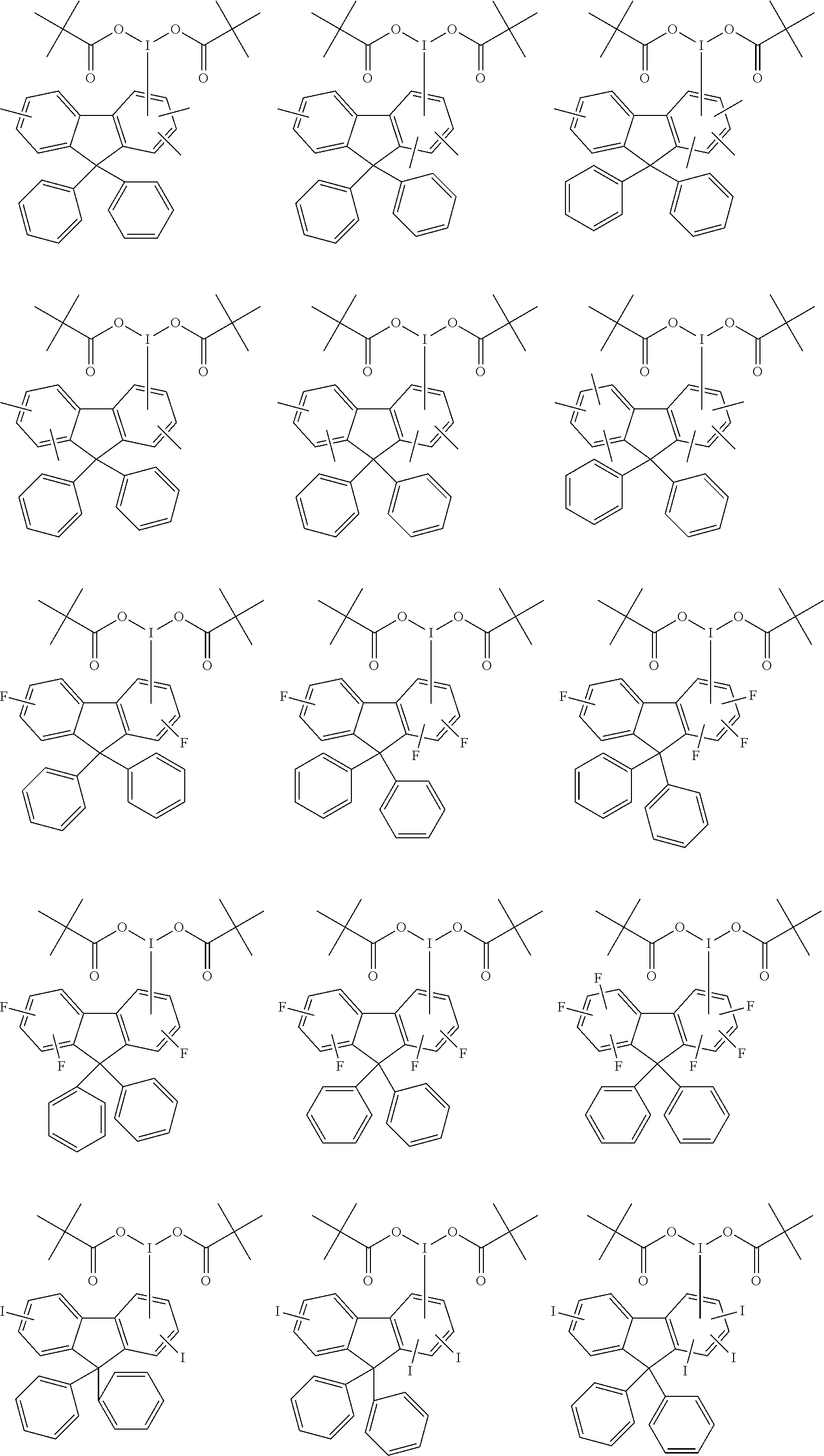

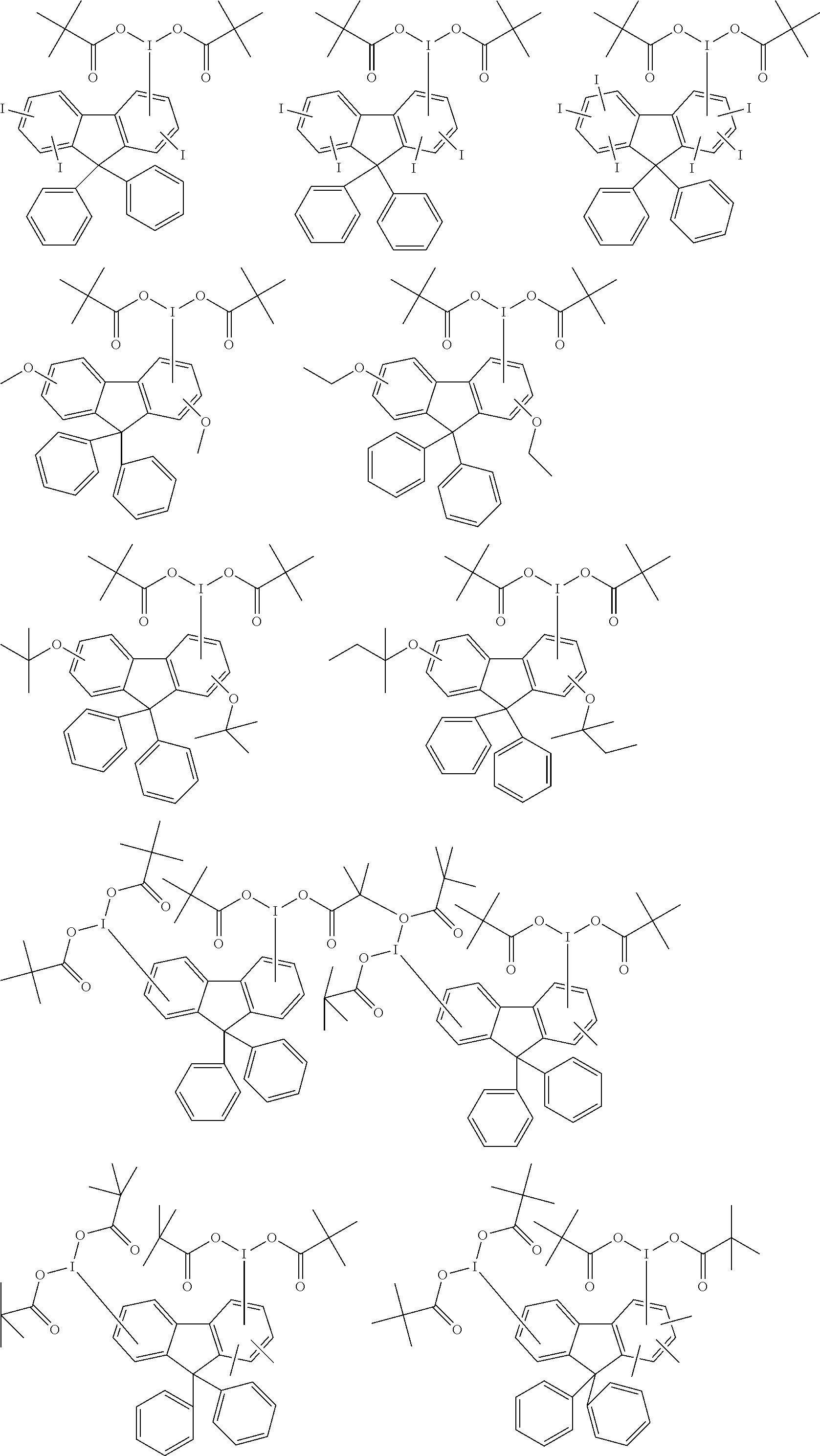

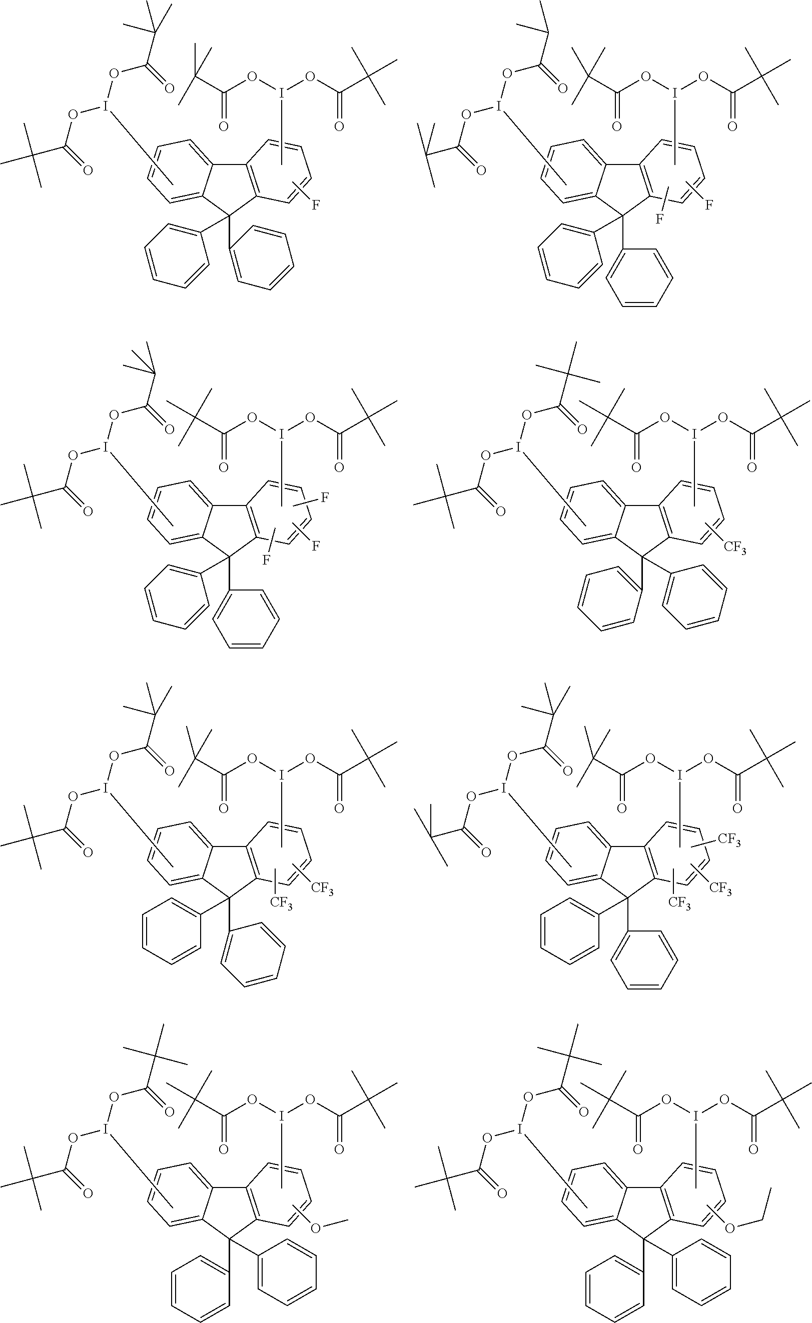

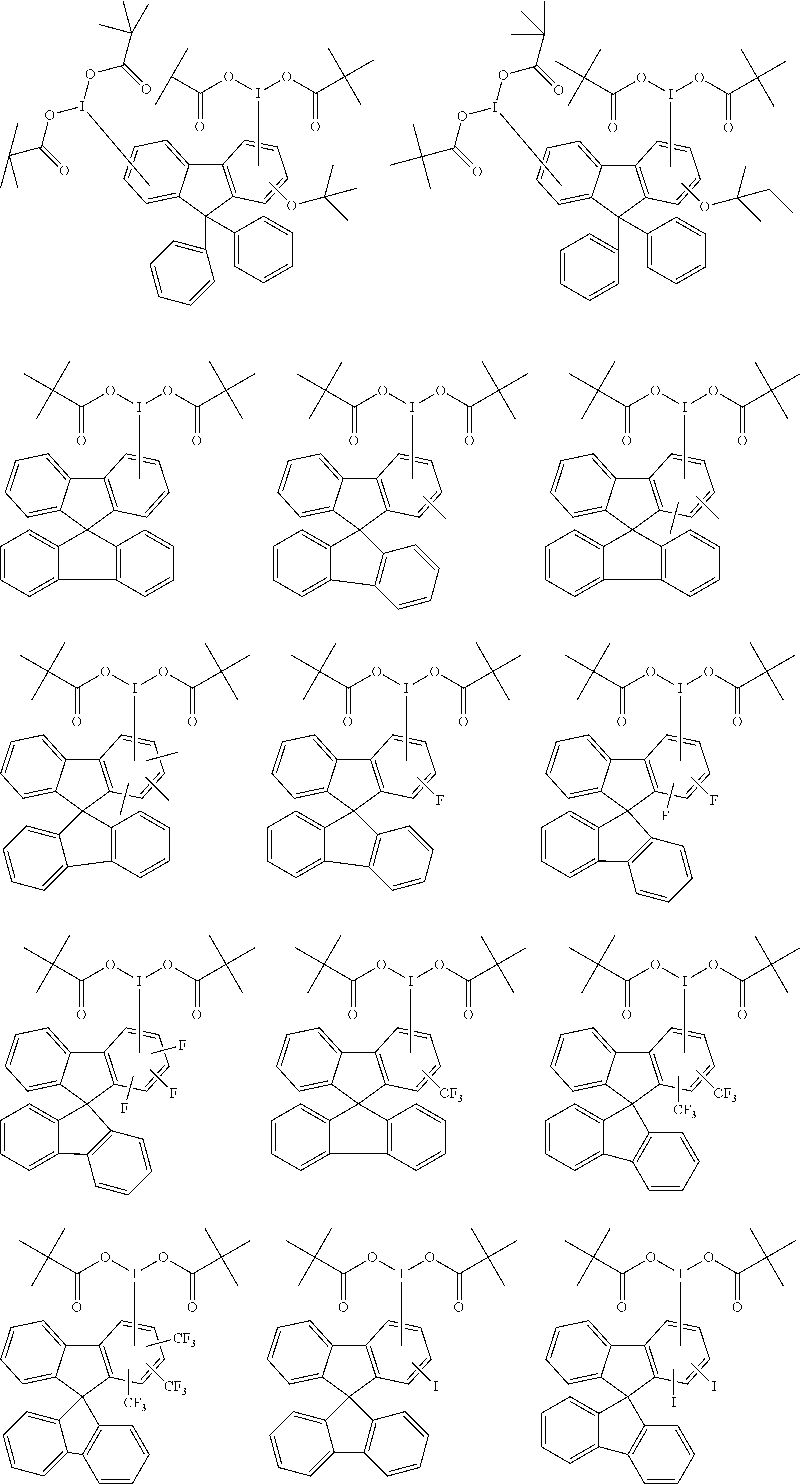

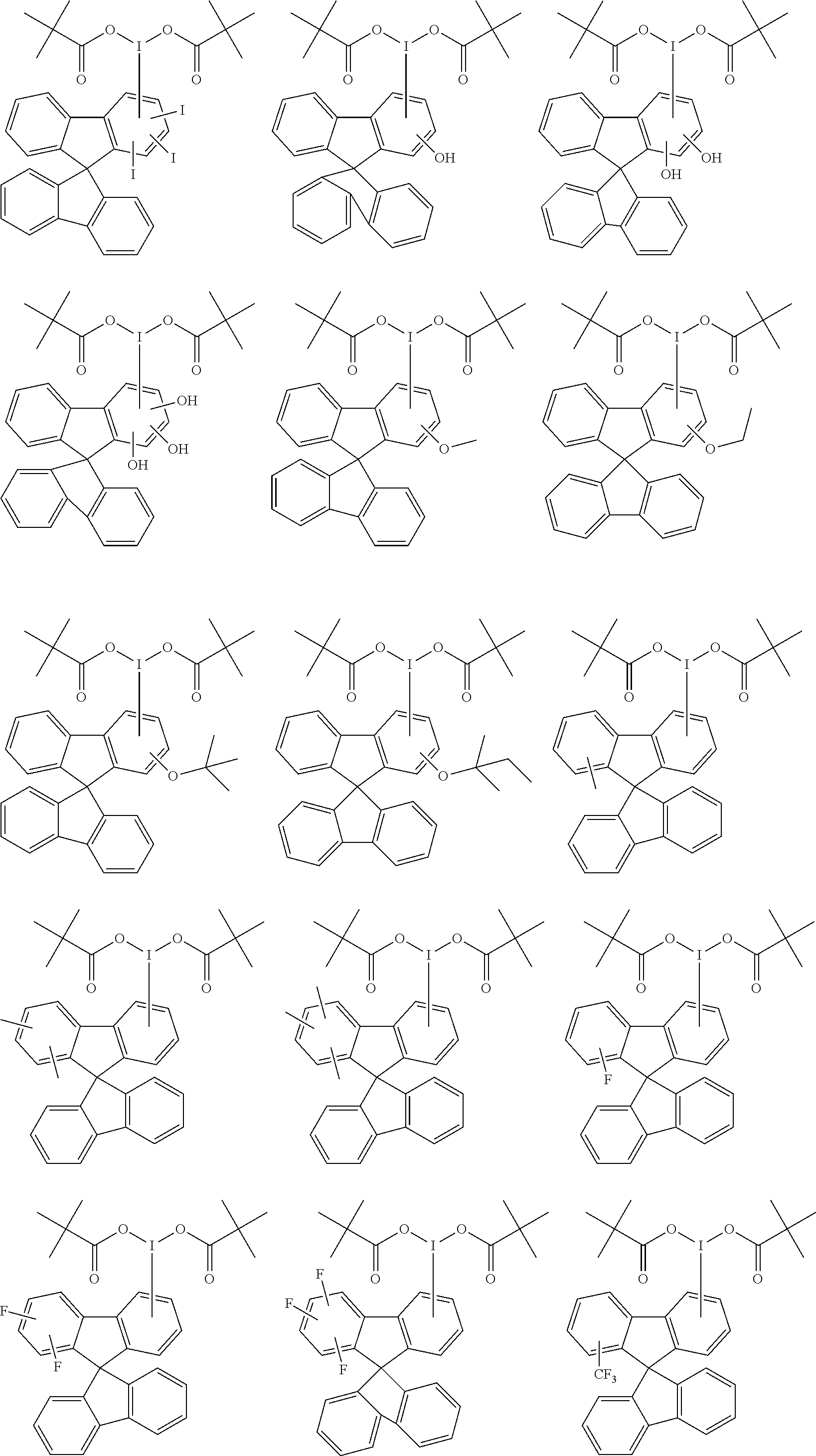

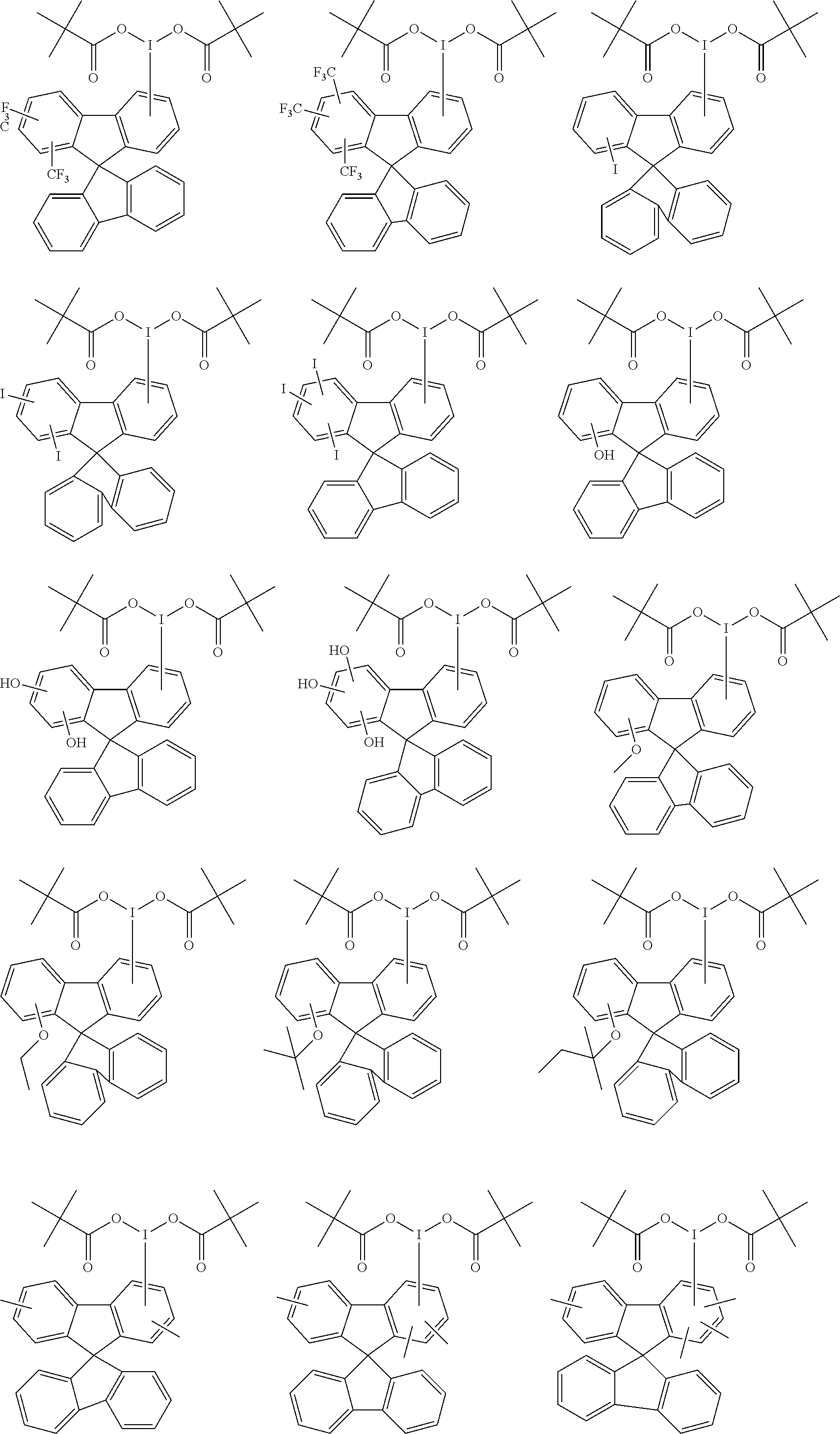

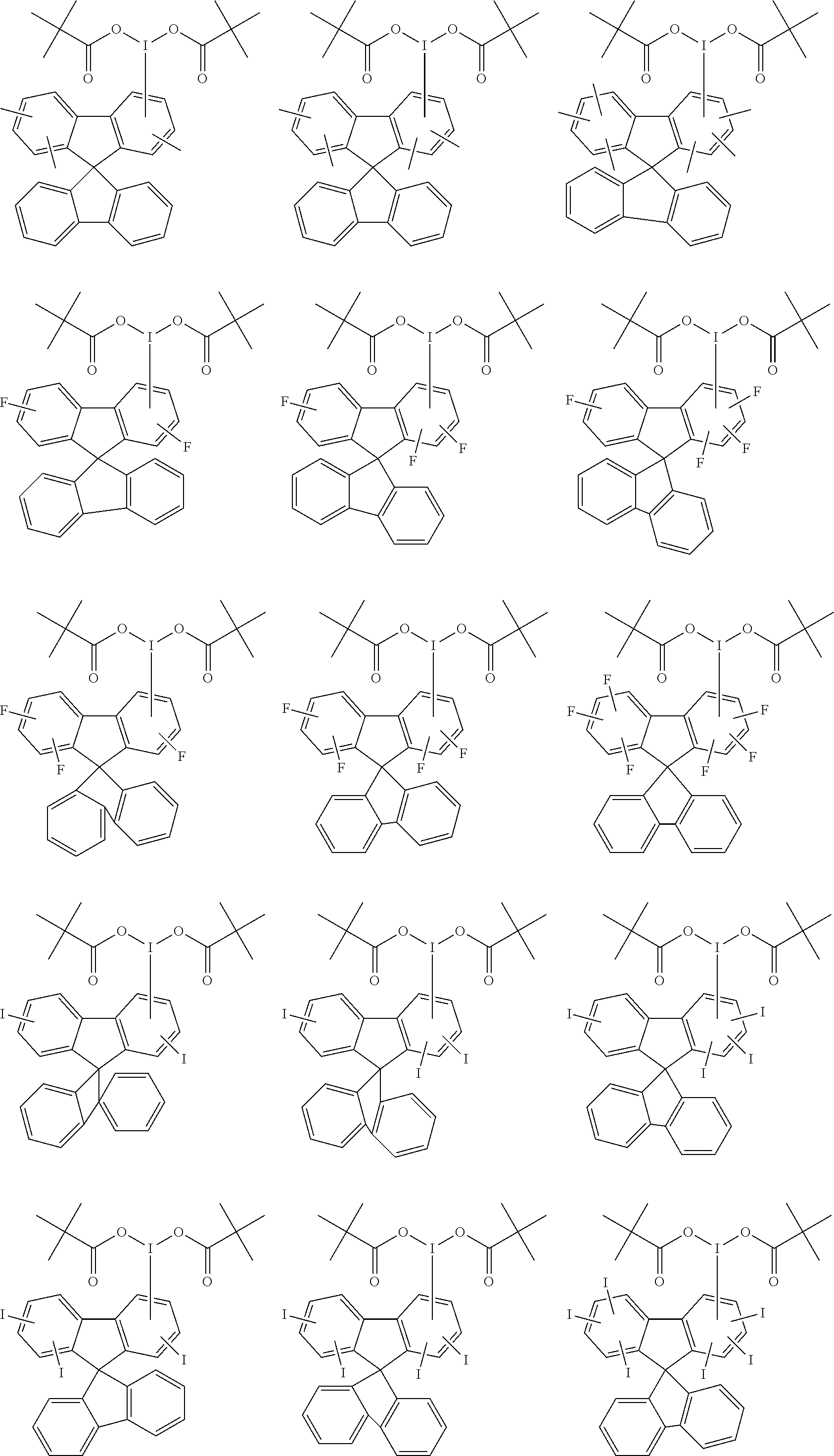

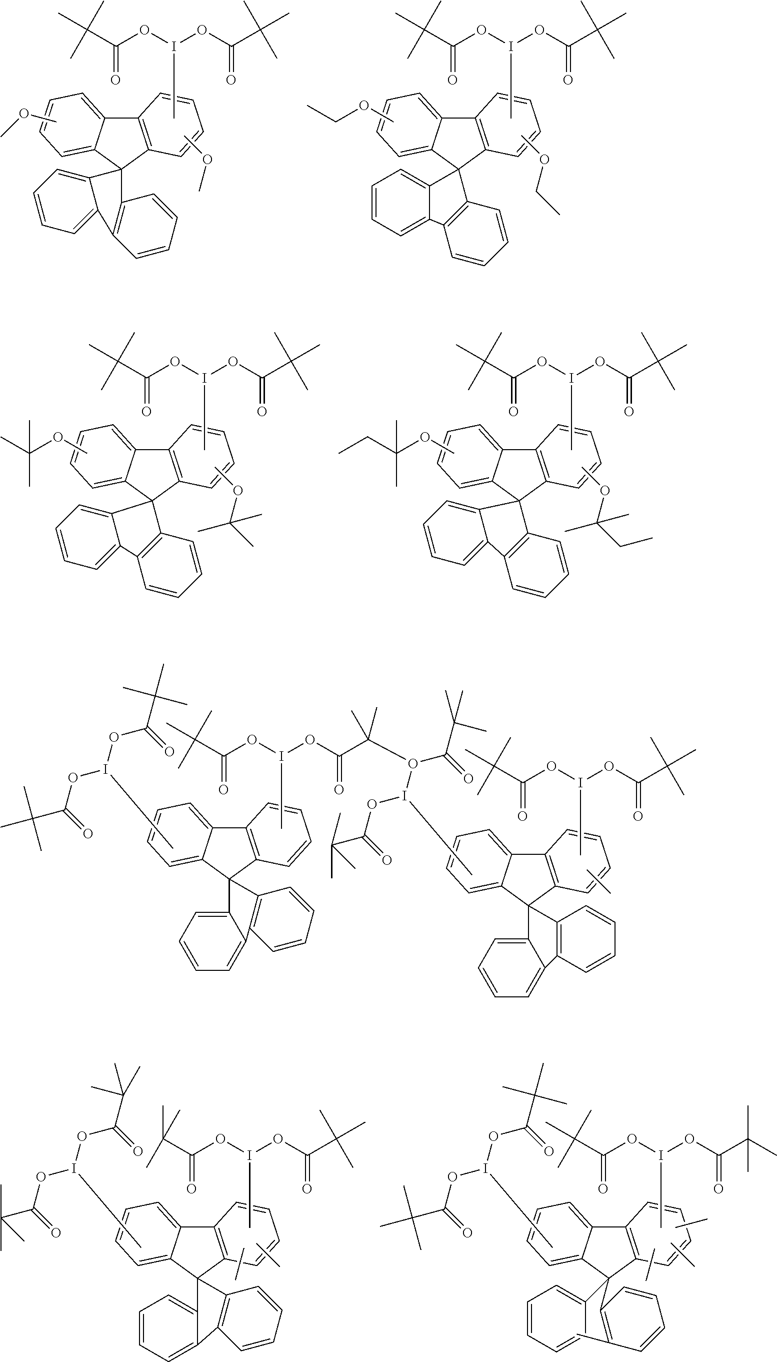

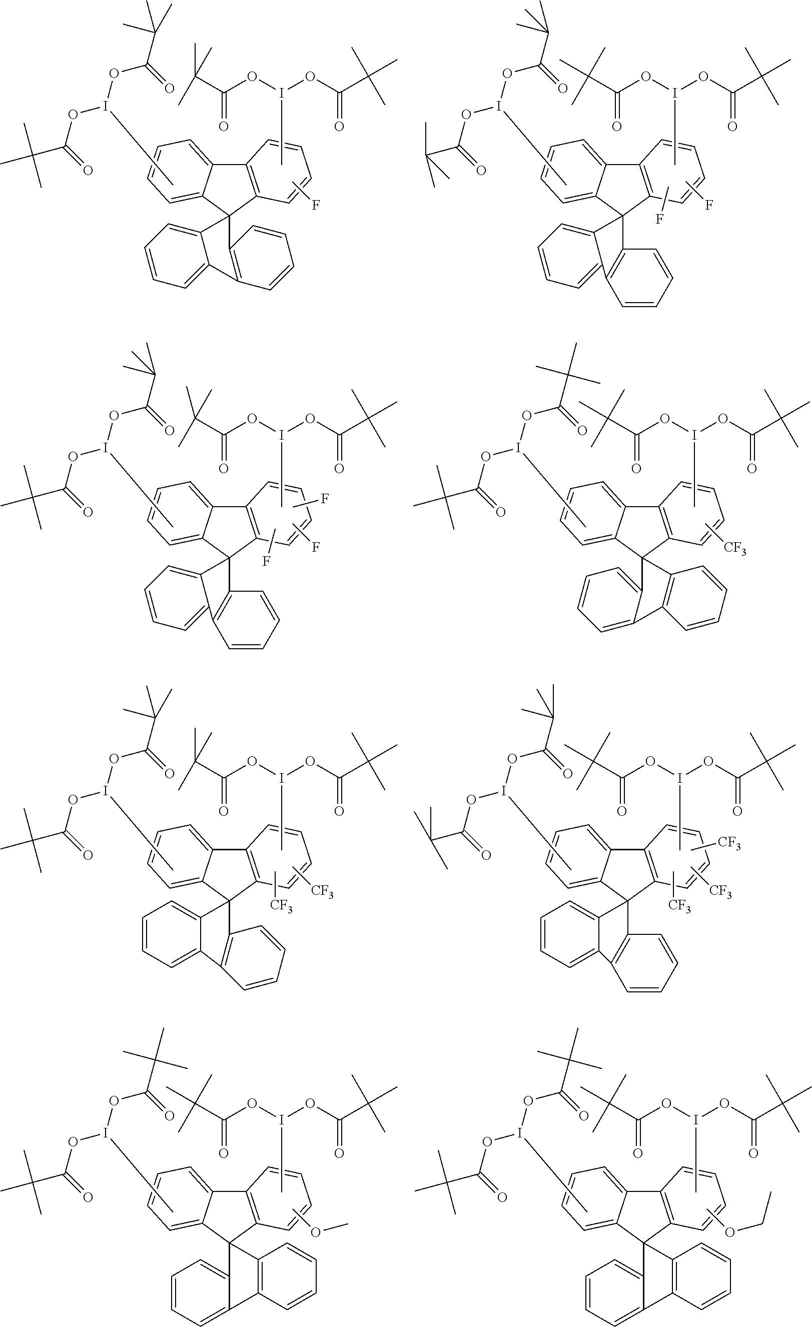

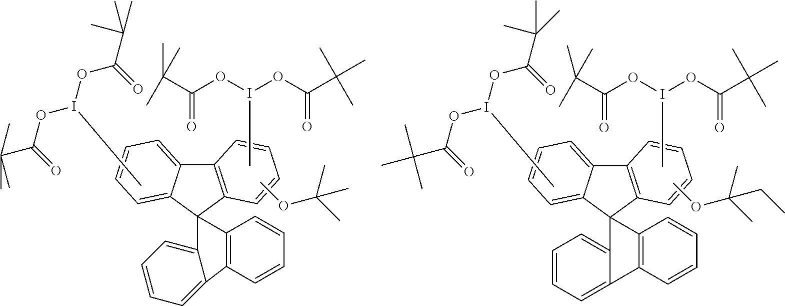

### [Carboxy Group-Containing Compound]

The carboxy group-containing compound to be used is preferably a polymer having a repeating unit represented by the following general formula (11) or a compound represented by the following general formula (12).

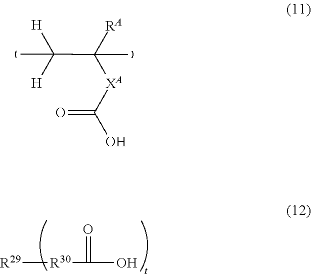

In the formula, R^{A} represents a hydrogen atom, a halogen atom, a methyl group, or a trifluoromethyl group;
X^{A} represents a single bond, a phenylene group, a naphthylene group, or *—C(═O)—O—X^{A1}—, wherein X^{A1} is a saturated hydrocarbylene group having 1 to 10 carbon atoms, a phenylene group, or a naphthylene group, the saturated hydrocarbylene group may have a hydroxy group, an ether bond, an ester bond, or a lactone ring, and “*” represents an attachment point to a carbon atom in the main chain;
“t” represents 1, 2, 3, or 4;
R²⁹ represents a t-valent hydrocarbon group having 1 to 40 carbon atoms or a t-valent heterocyclic group having 2 to 40 carbon atoms, when “t” is 2, R²⁹ may be an ether bond, a carbonyl group, an azo group, a thioether bond, a carbonate bond, a carbamate bond, a sulfinyl group, or a sulfonyl group, part or all of the hydrogen atoms of the t-valent hydrocarbon group or the t-valent heterocyclic group may be substituted with a group having a heteroatom, and part of the —CH₂— groups of the t-valent hydrocarbon group may be substituted with a group having a heteroatom;
and R³⁰ represents a single bond or a hydrocarbylene group having 1 to 10 carbon atoms, part or all of the hydrogen atoms of the hydrocarbylene group may be substituted with a group having a heteroatom, part of the —CH₂— of the hydrocarbylene group may be substituted with a group having a heteroatom, and when “t” is 2 to 4, R³⁰s may be identical to or different from each other.

In the general formula (11), R^{A} represents a hydrogen atom, a halogen atom, a methyl group, or a trifluoromethyl group. X^{A} represents a single bond, a phenylene group, a naphthylene group, or *—C(═O)—O—X^{A1}—. X^{A1} is a saturated hydrocarbylene group having 1 to 10 carbon atoms, a phenylene group, or a naphthylene group. The saturated hydrocarbylene group may have a hydroxy group, an ether bond, an ester bond, or a lactone ring. “*” represents an attachment point to a carbon atom in the main chain.

In the general formula (11), “t” represents 1, 2, 3, or 4.

In the general formula (12), R²⁹ represents a t-valent hydrocarbon group having 1 to 40 carbon atoms or a t-valent heterocyclic group having 2 to 40 carbon atoms, when “t” is 2, R²⁹ may be an ether bond, a carbonyl group, an azo group, a thioether bond, a carbonate bond, a carbamate bond, a sulfinyl group, or a sulfonyl group, part or all of the hydrogen atoms of the t-valent hydrocarbon group or the t-valent heterocyclic group may be substituted with a group having a heteroatom, and part of the —CH₂— groups of the t-valent hydrocarbon group may be substituted with a group having a heteroatom.

In the general formula (12), R³⁰ represents a single bond or a hydrocarbylene group having 1 to 10 carbon atoms, part or all of the hydrogen atoms of the hydrocarbylene group may be substituted with a group having a heteroatom, and part of the —CH₂— of the hydrocarbylene group may be substituted with a group having a heteroatom. When “t” is 2 to 4, R³⁰s may be identical to or different from each other.

The t-valent hydrocarbon group represented by R²⁹ may be saturated or unsaturated, and may be linear, branched, or cyclic. The t-valent hydrocarbon group is a group obtained by eliminating t hydrogen atoms from a hydrocarbon. Examples of the hydrocarbon include alkanes having 1 to 40 carbon atoms, alkenes having 2 to 40 carbon atoms, alkynes having 2 to 40 carbon atoms, cyclic saturated hydrocarbons having 3 to 40 carbon atoms, cyclic unsaturated hydrocarbons having 3 to 40 carbon atoms, and aromatic hydrocarbons having 6 to 40 carbon atoms.

Examples of the alkanes having 1 to 40 carbon atoms include methane, ethane, propane, butane, pentane, hexane, heptane, octane, nonane, decane, and structural isomers thereof.

Examples of the alkenes having 2 to 40 carbon atoms include ethylene, propylene, butene, pentene, hexene, heptene, octene, nonene, decene, and structural isomers thereof.

Examples of the alkyne having 2 to 40 carbon atoms include acetylene, propyne, butyne, pentyne, hexyne, heptyne, octyne, nonyne, decyne, and structural isomers thereof.

Examples of the cyclic saturated hydrocarbon having 3 to 40 carbon atoms include cyclopropane, cyclobutane, cyclohexane, cycloheptane, cyclooctane, adamantane, and norbornane.

Examples of the cyclic unsaturated hydrocarbon having 3 to 40 carbon atoms include cyclopropene, cyclobutene, cyclopentene, cyclohexene, cycloheptene, cyclooctene, and norbornene.

Examples of the aromatic hydrocarbons having 6 to 40 carbon atoms include benzene, naphthalene, and biphenyl.

The t-valent heterocyclic group represented by R²⁹ is a group obtained by eliminating t hydrogen atoms from a heterocyclic compound. Examples of the heterocyclic compound include furan, pyridine, pyrazole, and thiazolidine.

In the t-valent hydrocarbon group or t-valent heterocyclic group, part or all of its hydrogen atoms may be substituted with a group having a heteroatom, such as an oxygen atom, a sulfur atom, a nitrogen atom, or a halogen atom, and as a result, the t-valent hydrocarbon group and the t-valent heterocyclic group may contain a hydroxy group, a cyano group, a fluorine atom, a chlorine atom, a bromine atom, an iodine atom, etc. Furthermore, part of —CH₂— groups constituting the t-valent hydrocarbon group may be substituted with a group having a heteroatom, such as an oxygen atom, a sulfur atom, or a nitrogen atom, and the resulting t-valent hydrocarbon group may have a carbonyl group, an ether bond, a thioether bond, an ester bond, a sulfonate ester bond, a carbonate bond, a carbamate bond, a lactone ring, a sultone ring, a carboxylic acid anhydride (—C(═O)—O—C(═O)—), etc.

The hydrocarbylene group represented by R³⁰ may be saturated or unsaturated, and may be linear, branched, or cyclic. Specific examples thereof include: alkanediyl groups having 1 to 20 carbon atoms, such as a methanediyl group, an ethane-1,1-diyl group, an ethane-1,2-diyl group, propane-1,2-diyl group, a propane-1,3-diyl group, a butane-1,4-diyl group, a pentane-1,5-diyl group, a hexane-1,6-diyl group, a heptane-1,7-diyl group, an octane-1,8-diyl group, a nonane-1,9-diyl group, a decane-1,10-diyl group, an undecane-1,11-diyl group, and a dodecane-1,12-diyl group; cyclic saturated hydrocarbylene groups having 3 to 20 carbon atoms, such as a cyclopentanediyl group, a cyclohexanediyl group, a norbornanediyl group, and an adamantanediyl group; unsaturated aliphatic hydrocarbylene groups having 2 to 20 carbon atoms, such as a vinylene group and a propene-1,3-diyl group; arylene groups having 6 to 20 carbon atoms, such as a phenylene group and a naphthylene group; and groups obtained by combining these groups. Furthermore, part or all of the hydrogen atoms of the hydrocarbylene group may be substituted with a group having a heteroatom, such as an oxygen atom, a sulfur atom, a nitrogen atom, or a halogen atom, or part of the —CH₂— groups constituting the hydrocarbylene group may be substituted with a group having a heteroatom, such as an oxygen atom, a sulfur atom, or a nitrogen atom, and the resulting hydrocarbylene group may contain a hydroxy group, a cyano group, a fluorine atom, a chlorine atom, a bromine atom, an iodine atom, a carbonyl group, an ether bond, a thioether bond, an ester bond, a sulfonate ester bond, a carbonate bond, a carbamate bond, a lactone ring, a sultone ring, a carboxylic acid anhydride, etc.

Among the carboxylic acid compounds represented by the formula (12), those in which “t” is 2, 3, or 4 are preferable. In these cases, when mixed with a hypervalent iodine compound, a strong resist film with high-molecular-weight is easily formed, which is preferable from the viewpoints of etching resistance and developer resistance.

Specific examples of the carboxy group-containing repeating unit represented by the formula (11) include, but are not limited to, those shown below. In the following formulae, R^{A} is the same as defined above.

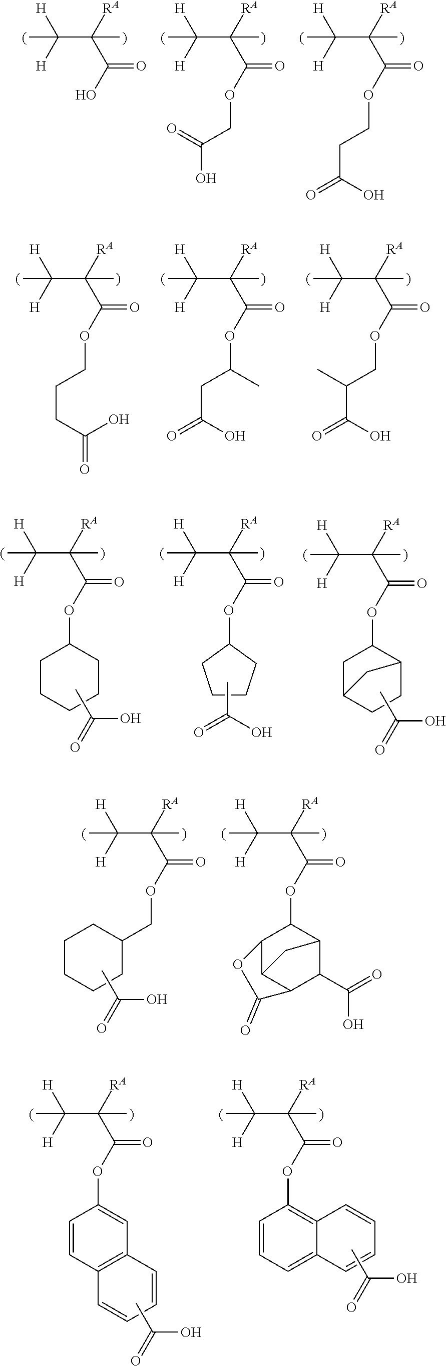

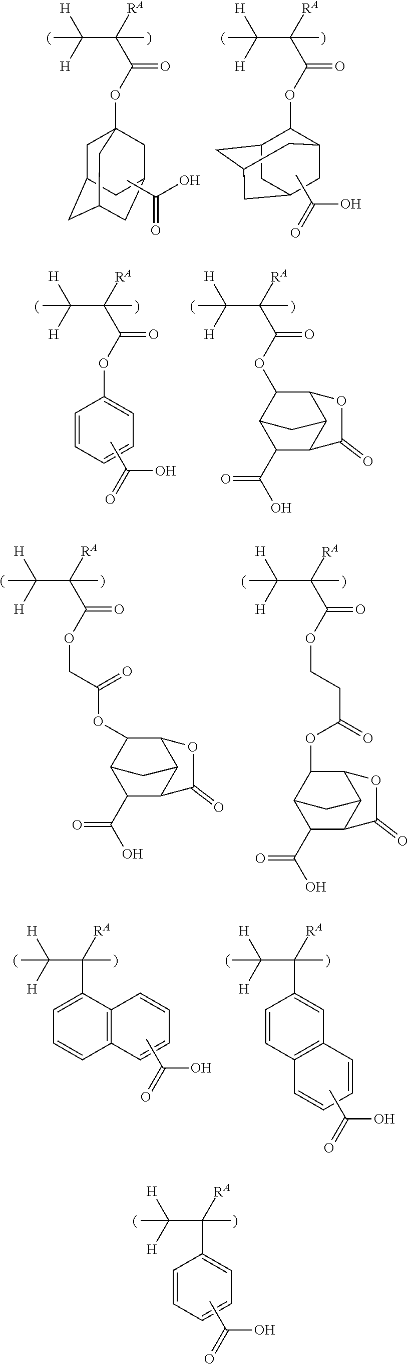

Examples of the carboxylic acid compound represented by the general formula (12) include, but are not limited to, the following.

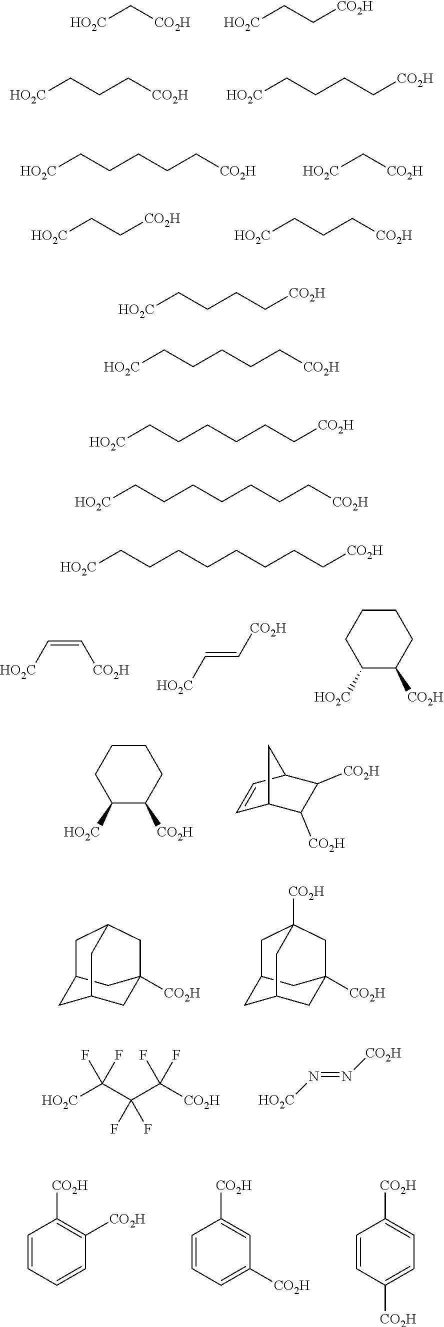

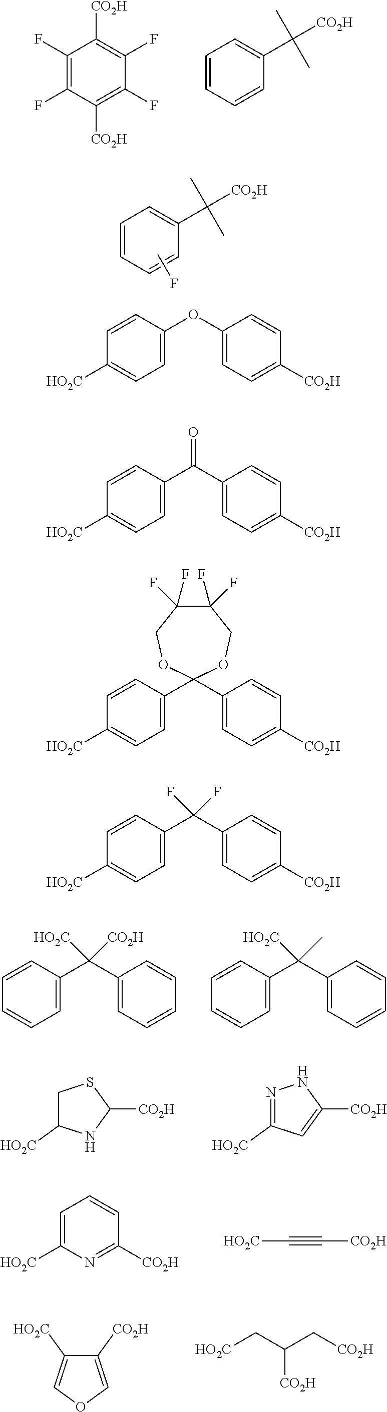

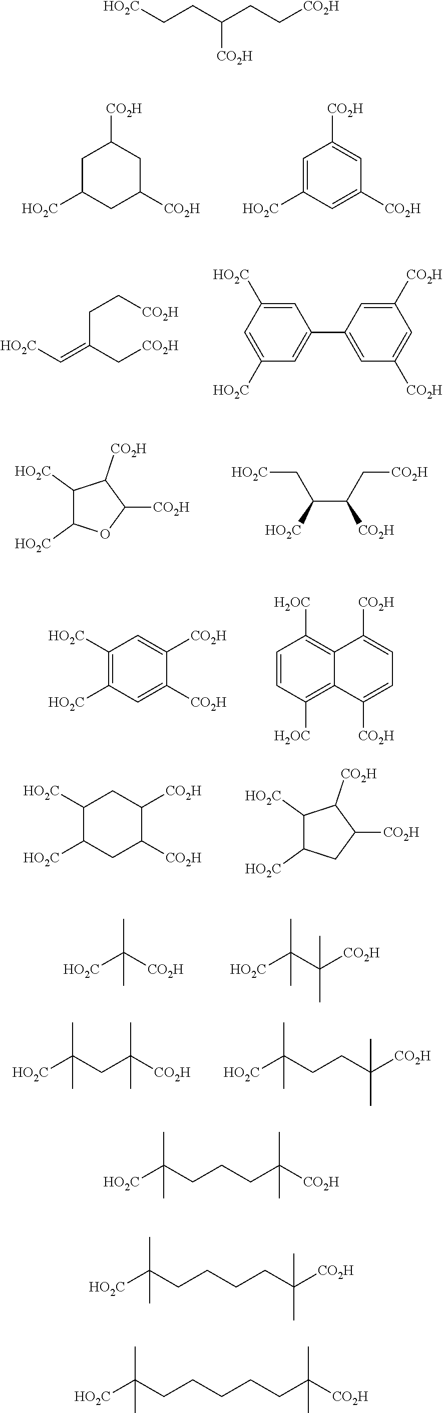

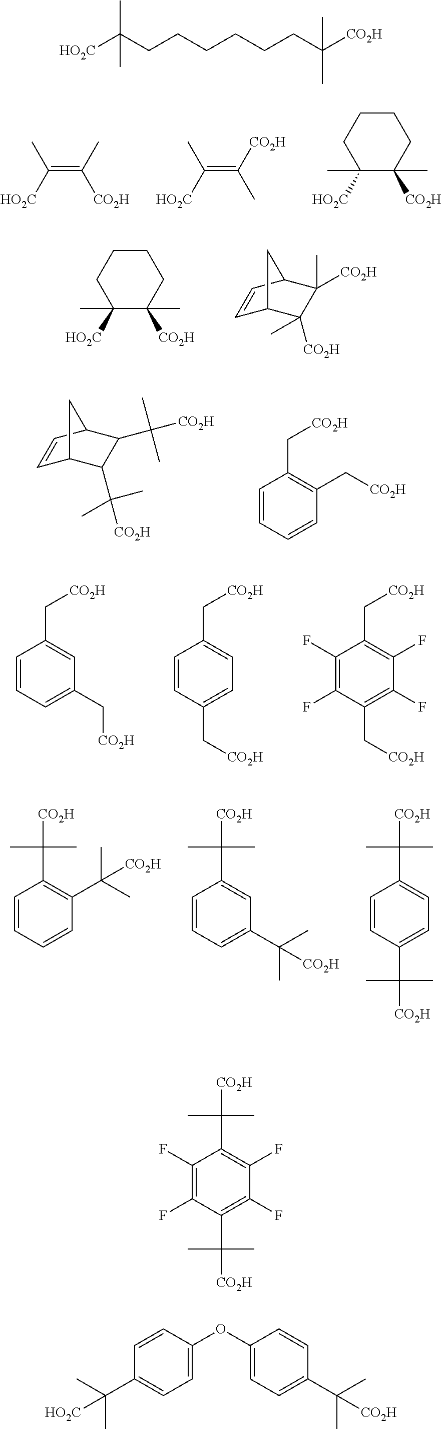

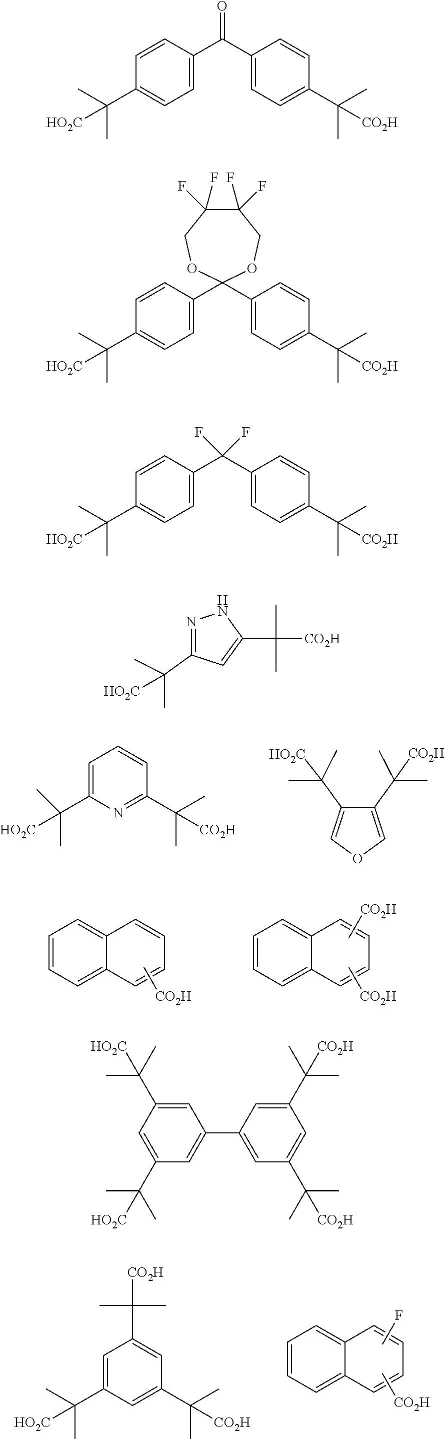

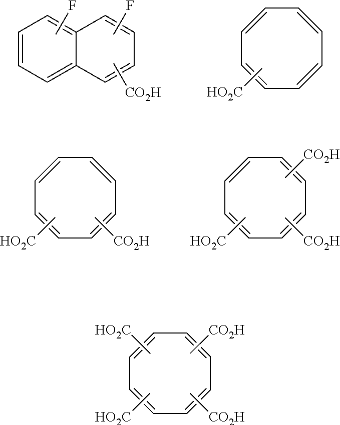

The carboxyl group-containing polymer having the repeating unit represented by the general formula (11) may further have a repeating unit other than the repeating unit represented by the formula (11) (hereinafter also referred to as “other repeating unit”). The other repeating unit is not particularly limited, but is preferably one that can improve the solubility in a solvent of a polymer that is poorly soluble in the solvent in the case that the polymer contains only a repeating unit having a carboxyl group. As the other repeating units, repeating units with a rigid skeleton having a cyclic structure that is expected to have high etching resistance, and repeating units having a styrene skeleton are preferable.

Specific examples of the other repeating units include, but are not limited to, those shown below. In the following formulae, R^{A} is the same as defined above, and X^{B} represents each independently —CH₂— or —O—.

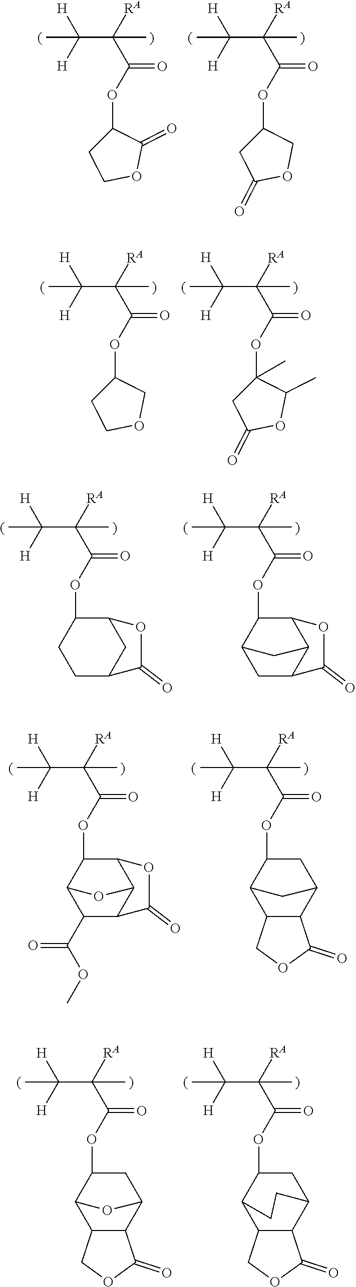

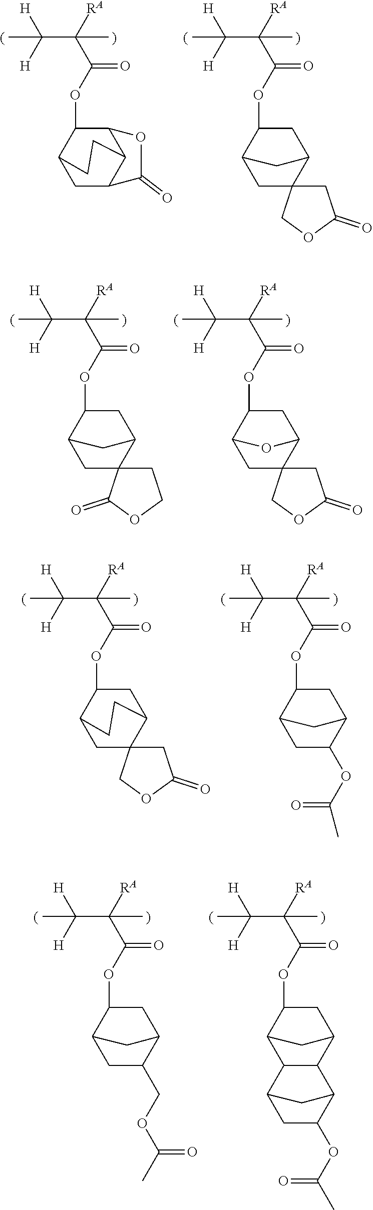

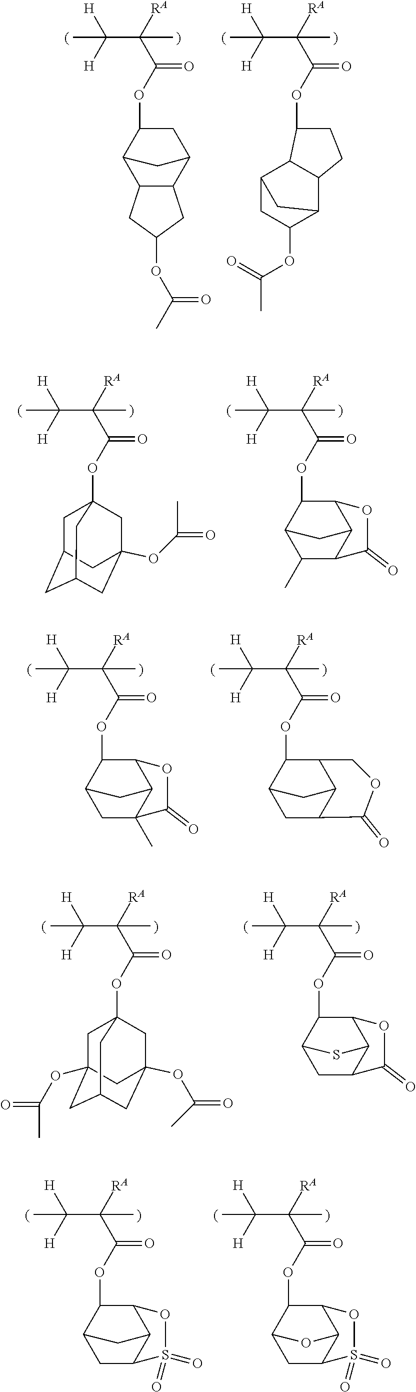

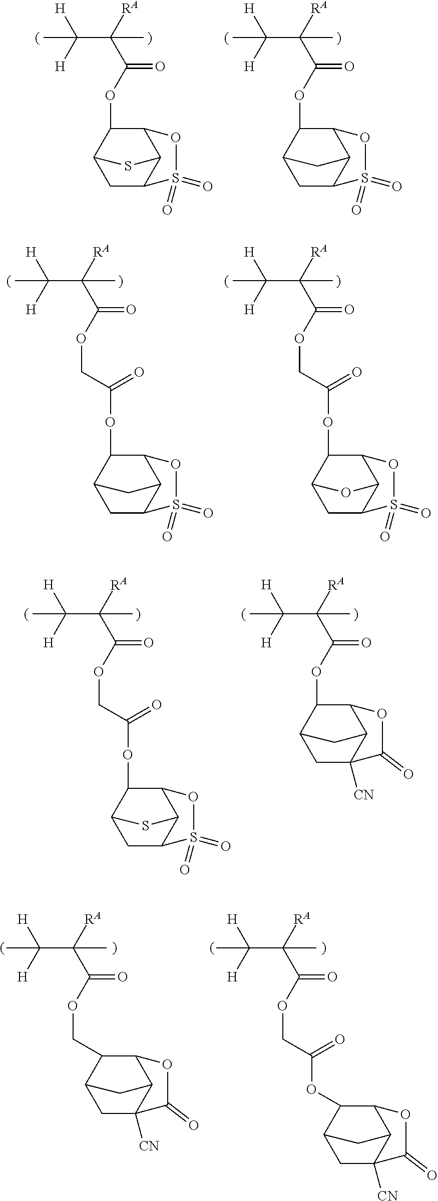

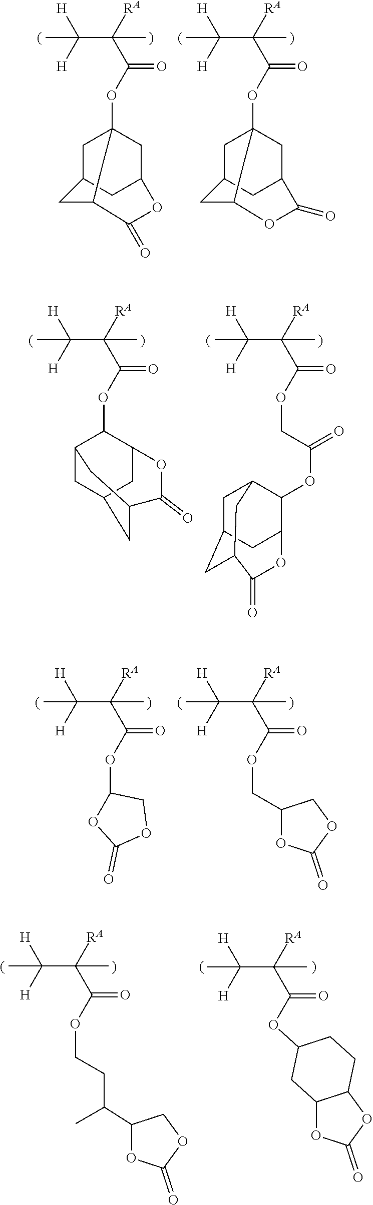

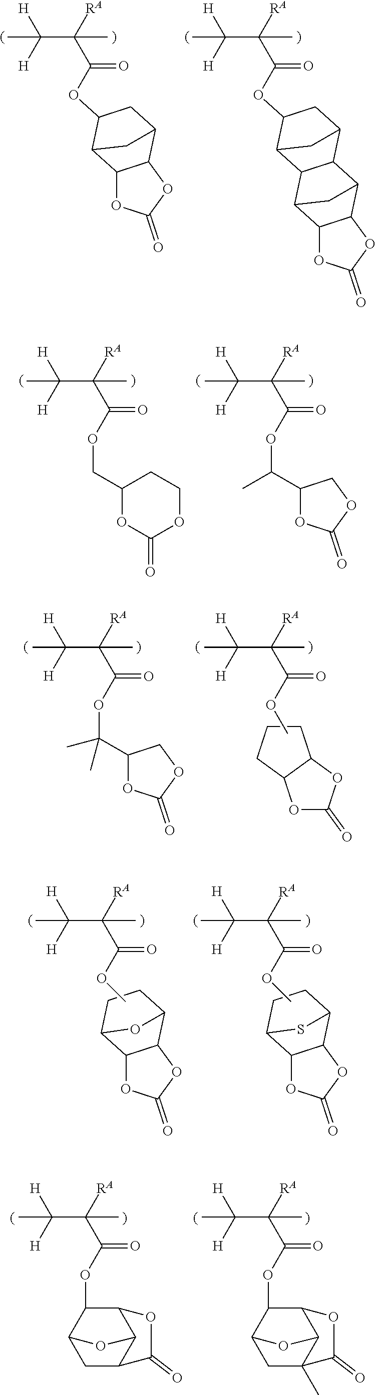

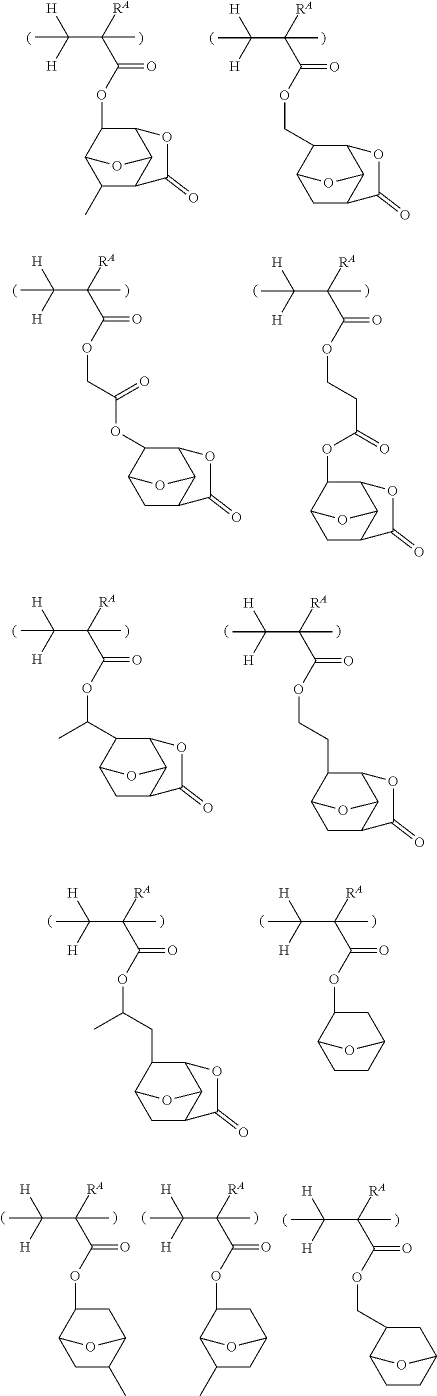

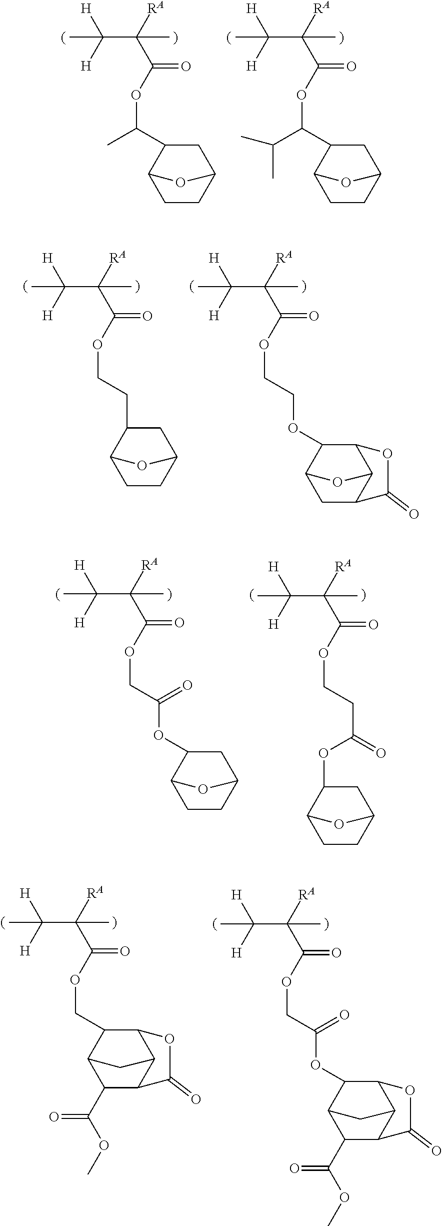

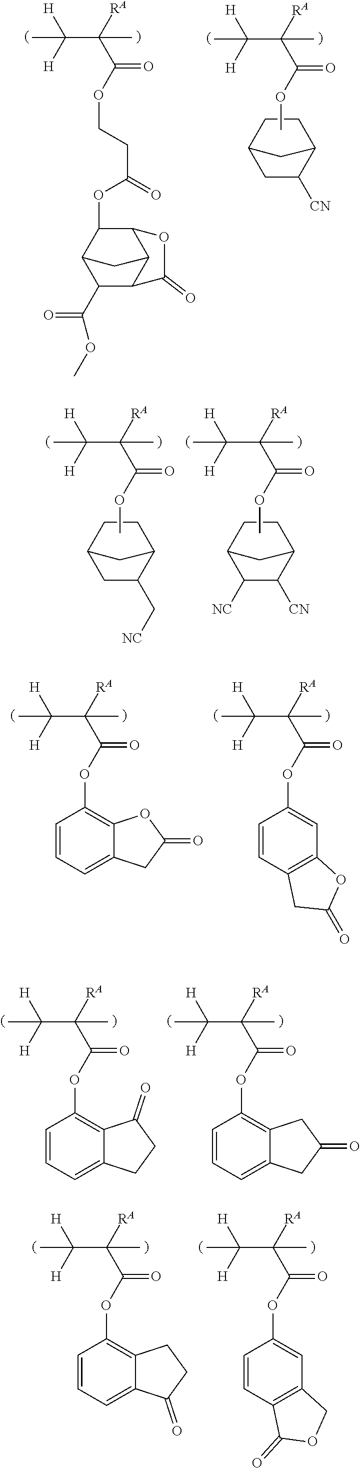

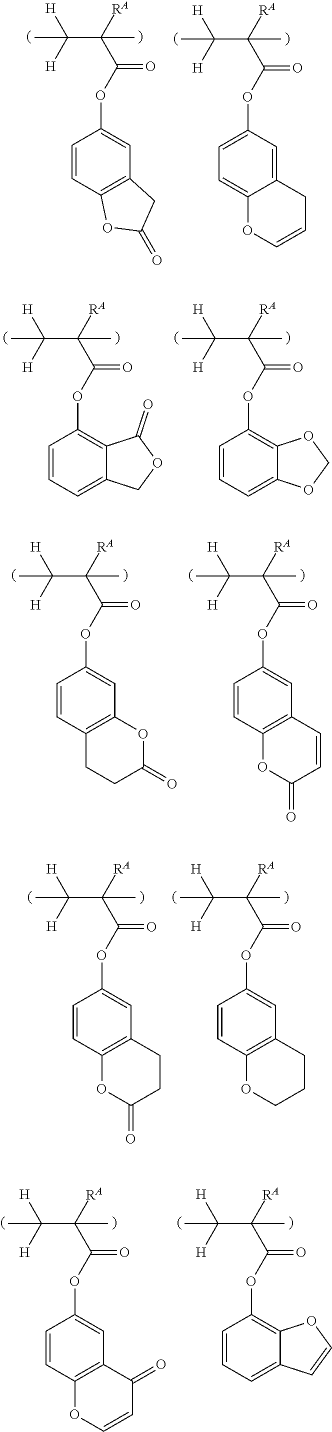

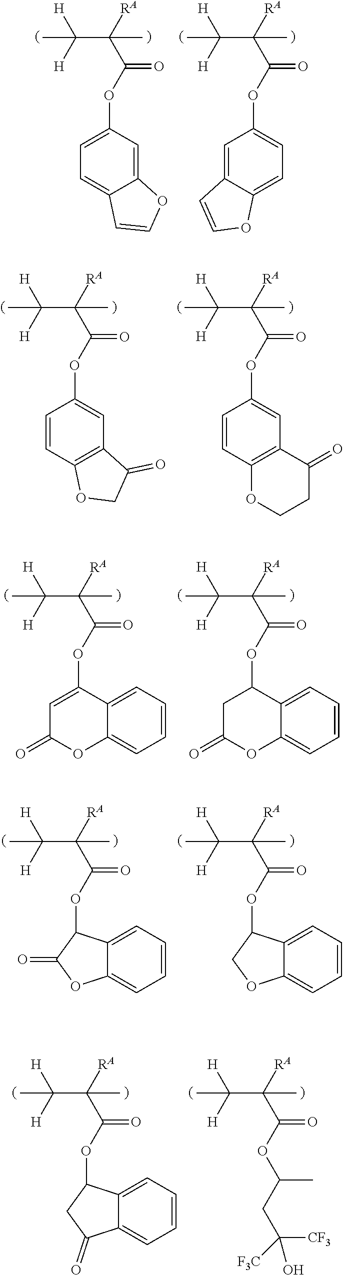

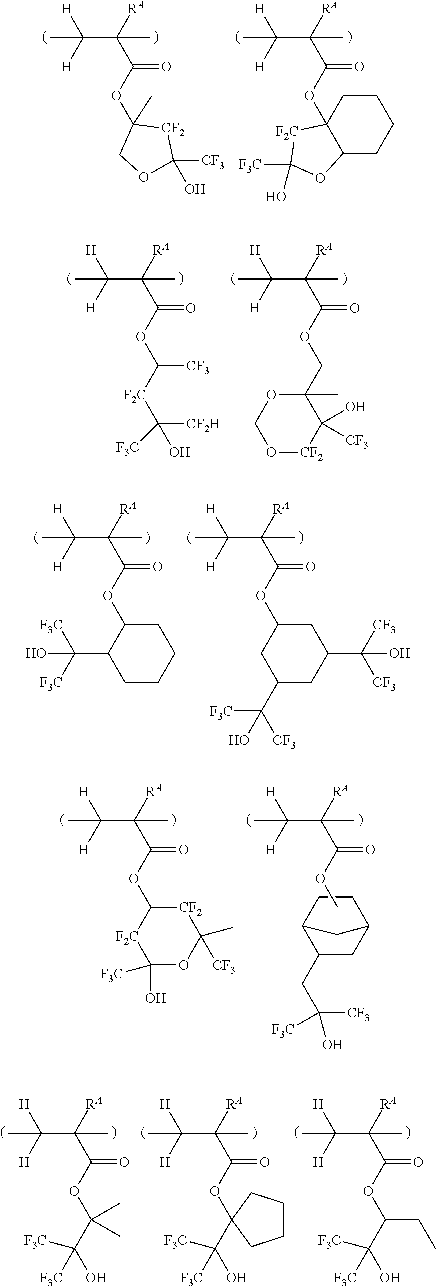

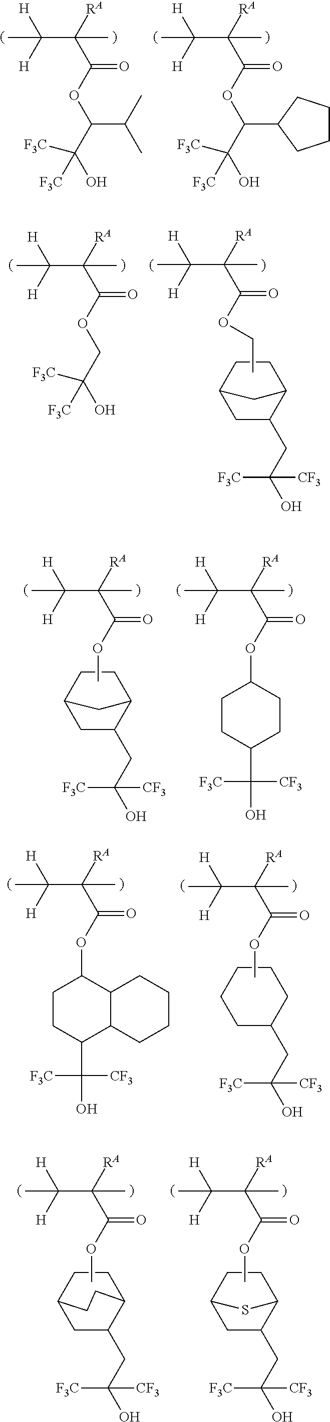

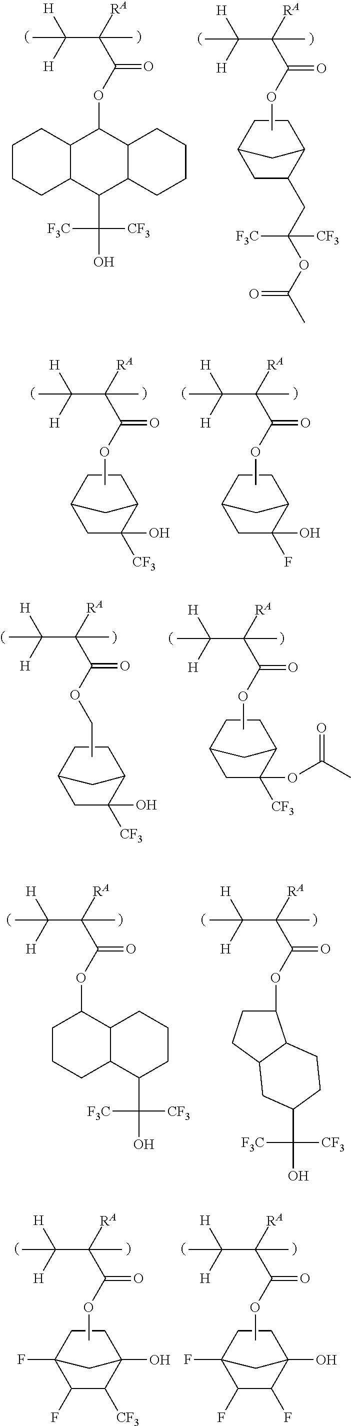

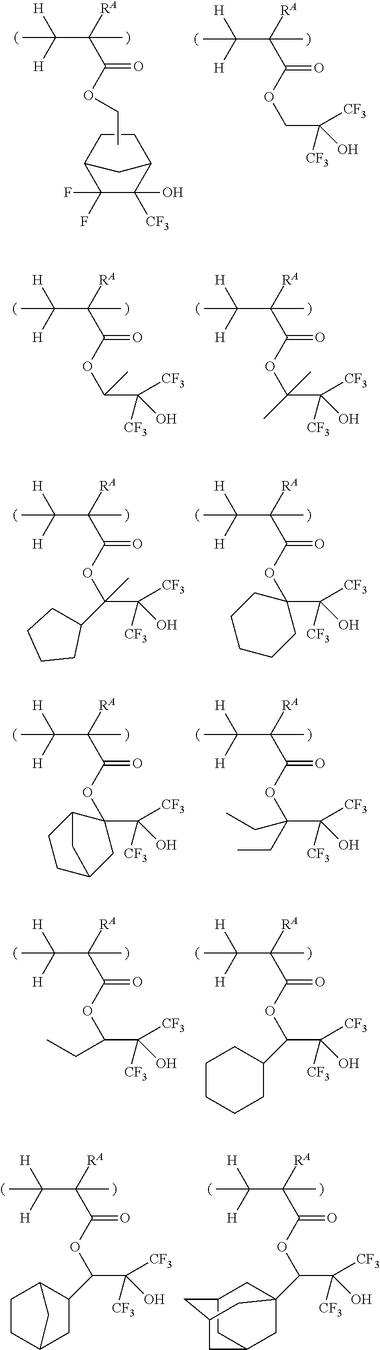

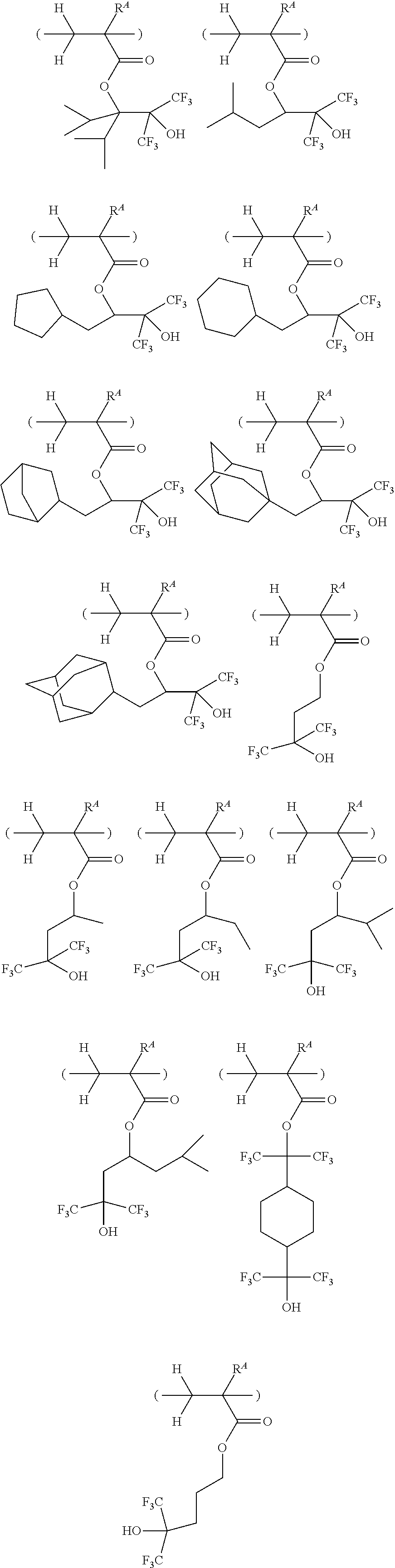

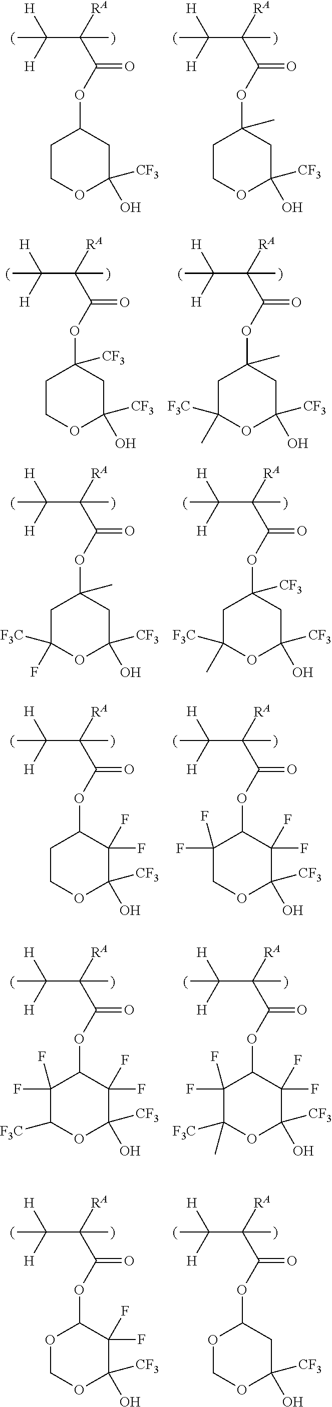

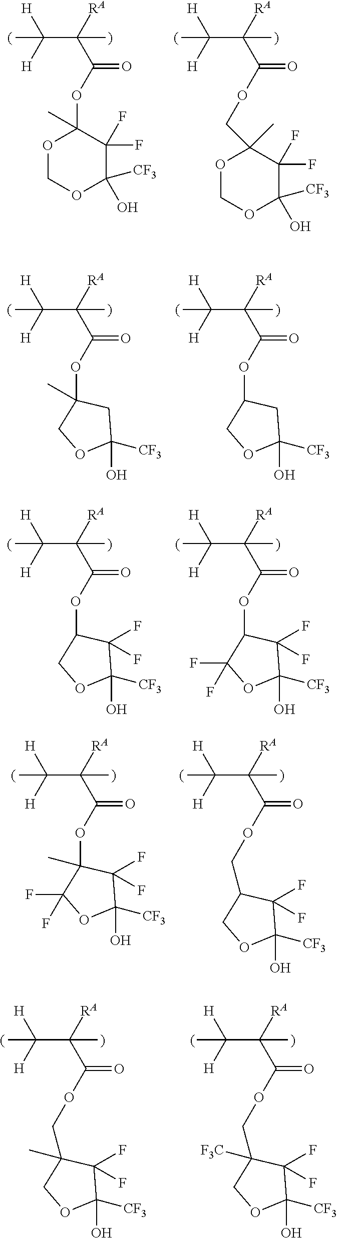

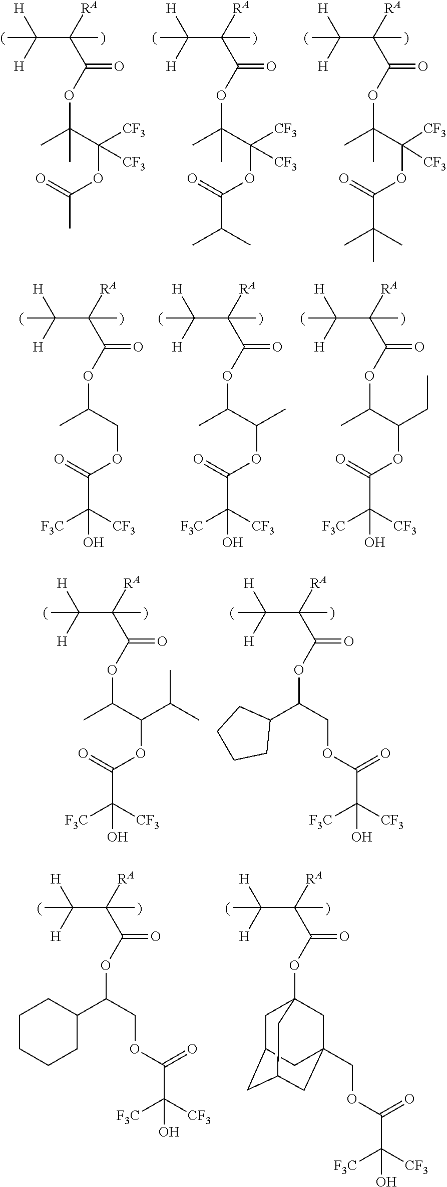

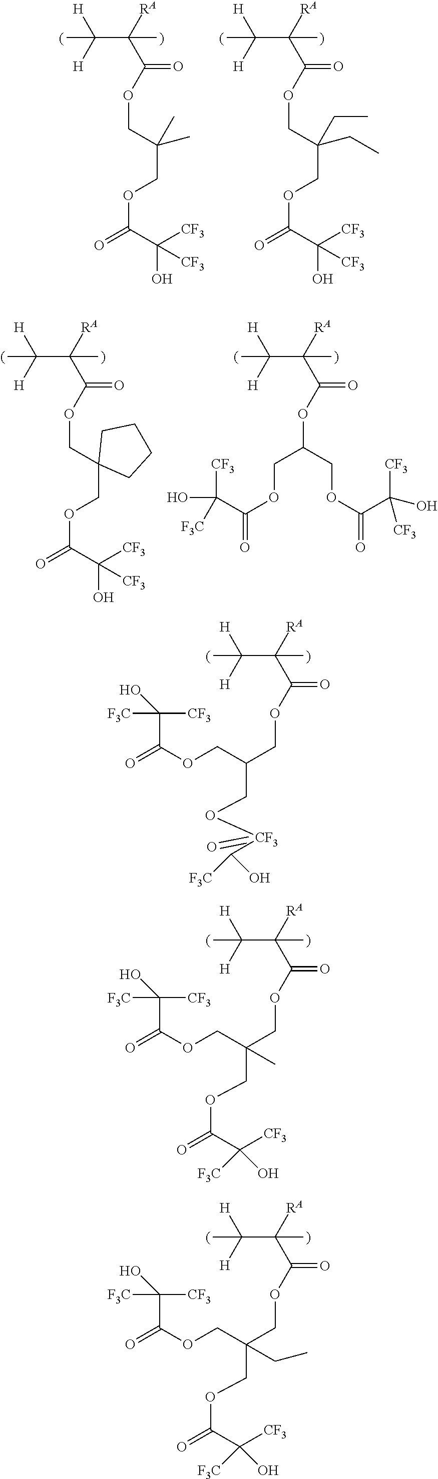

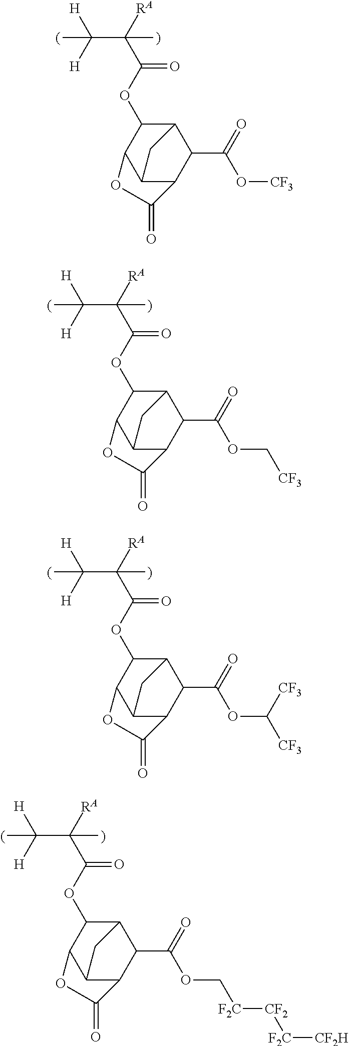

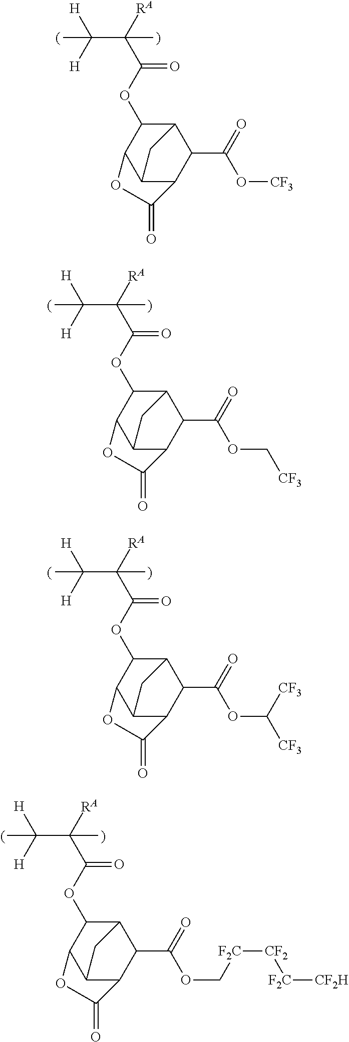

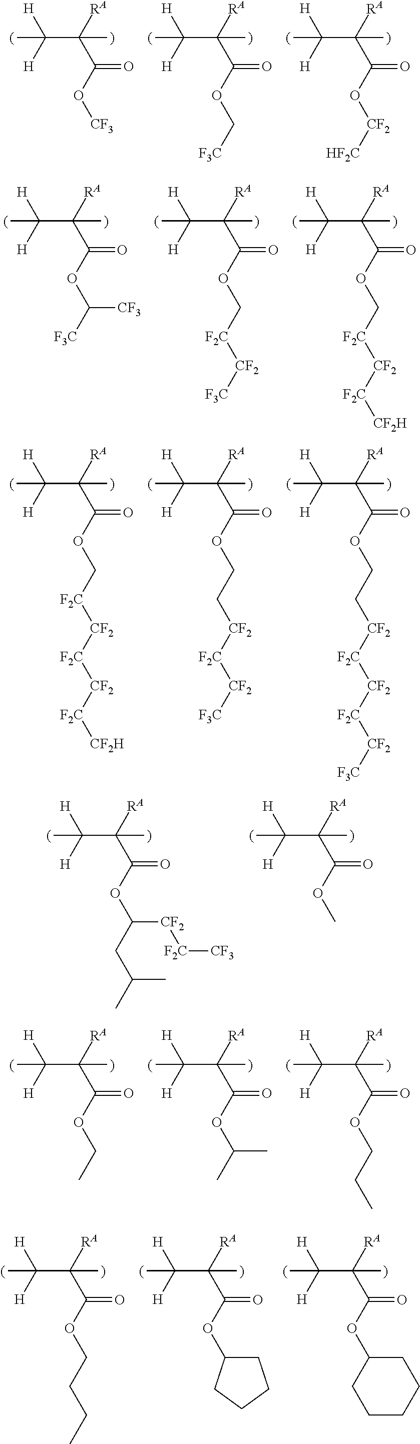

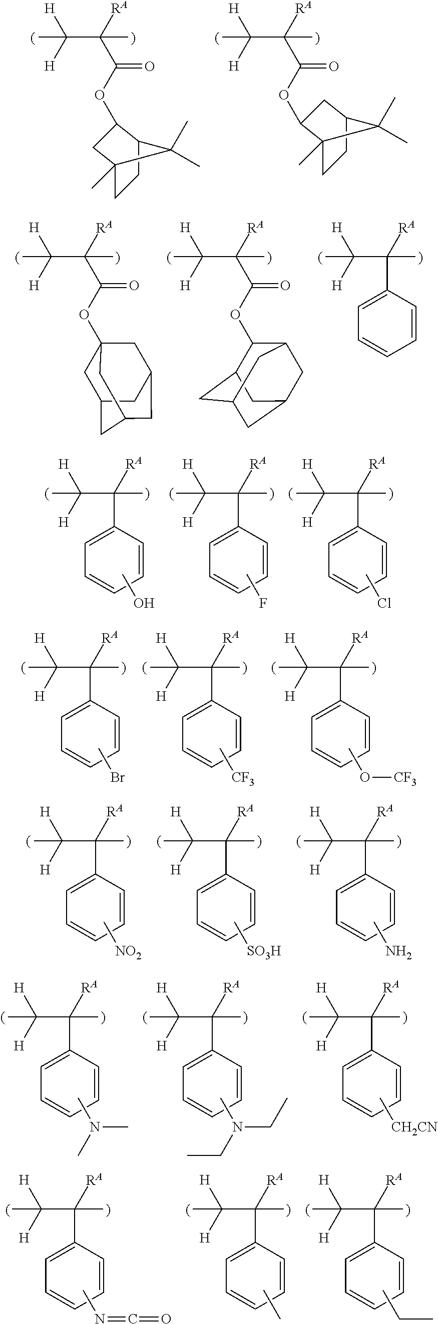

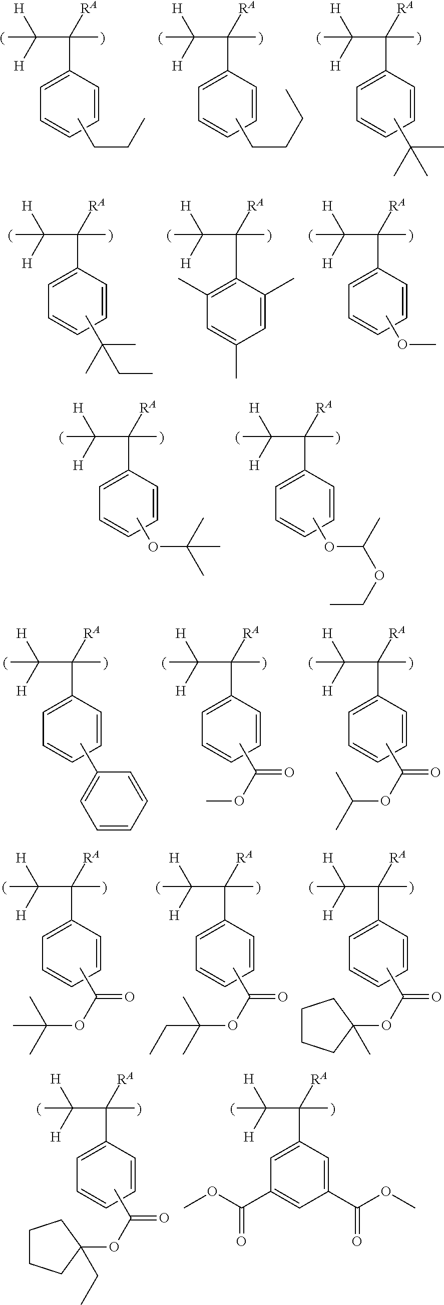

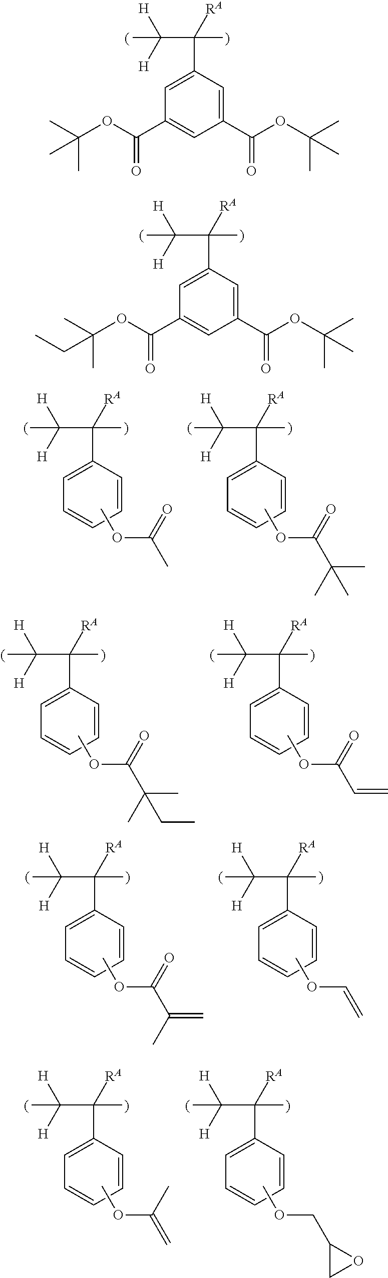

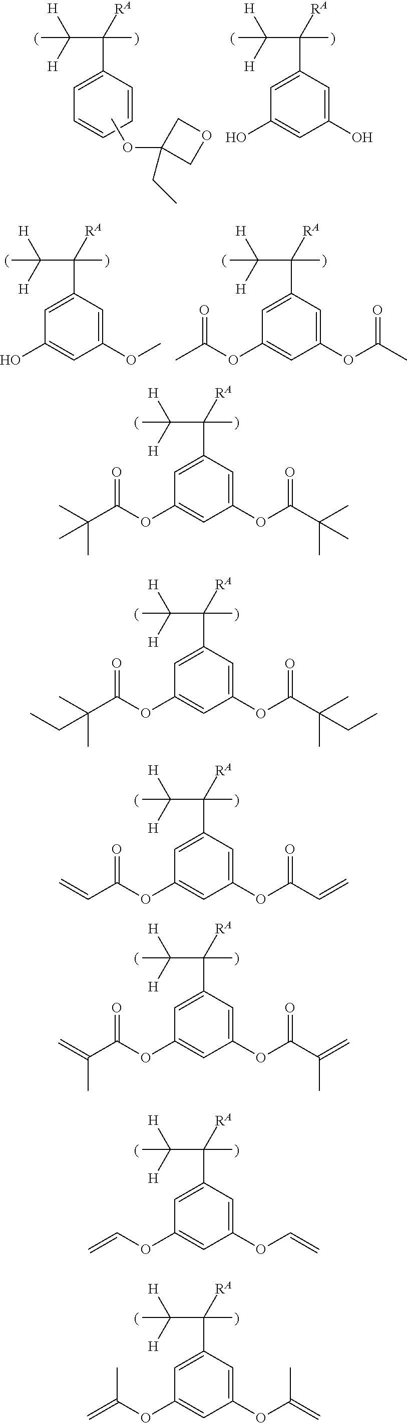

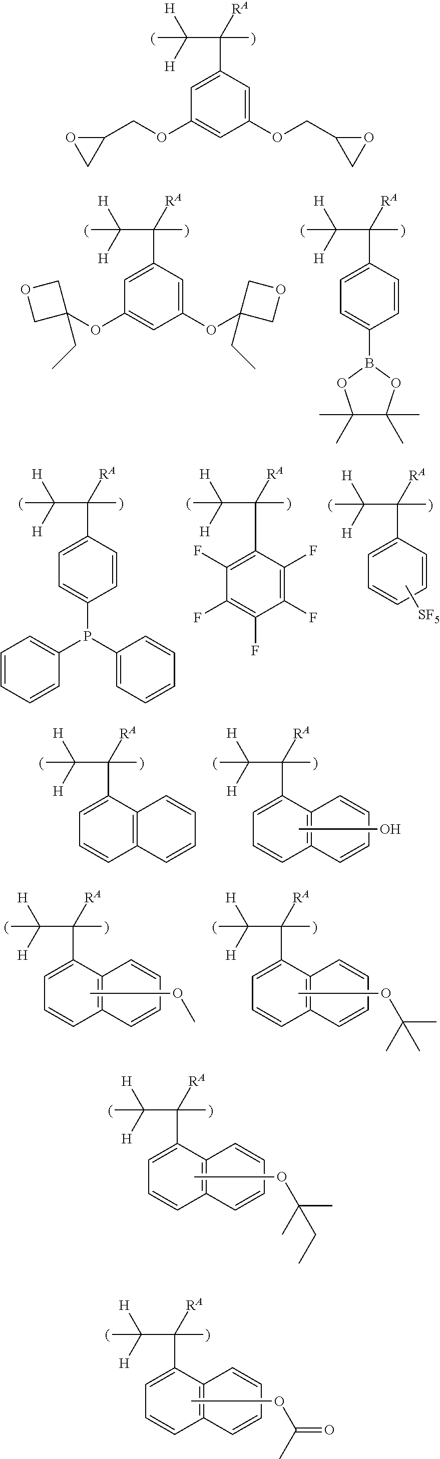

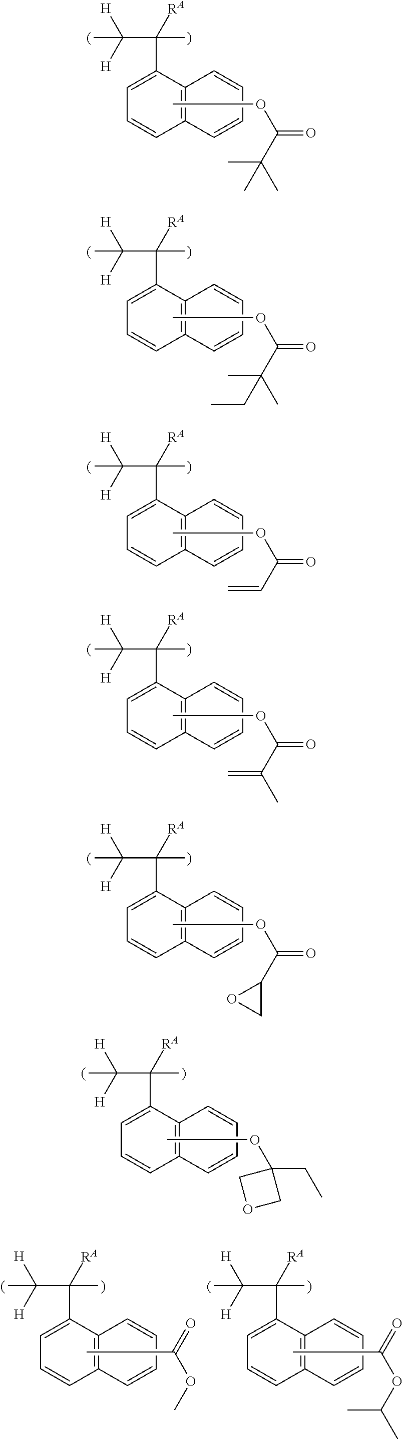

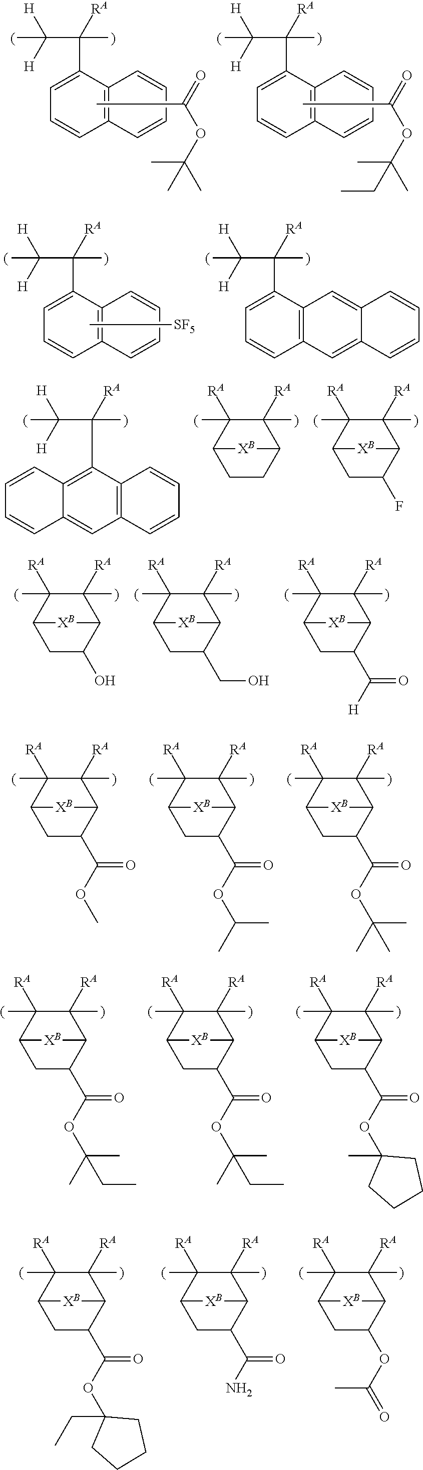

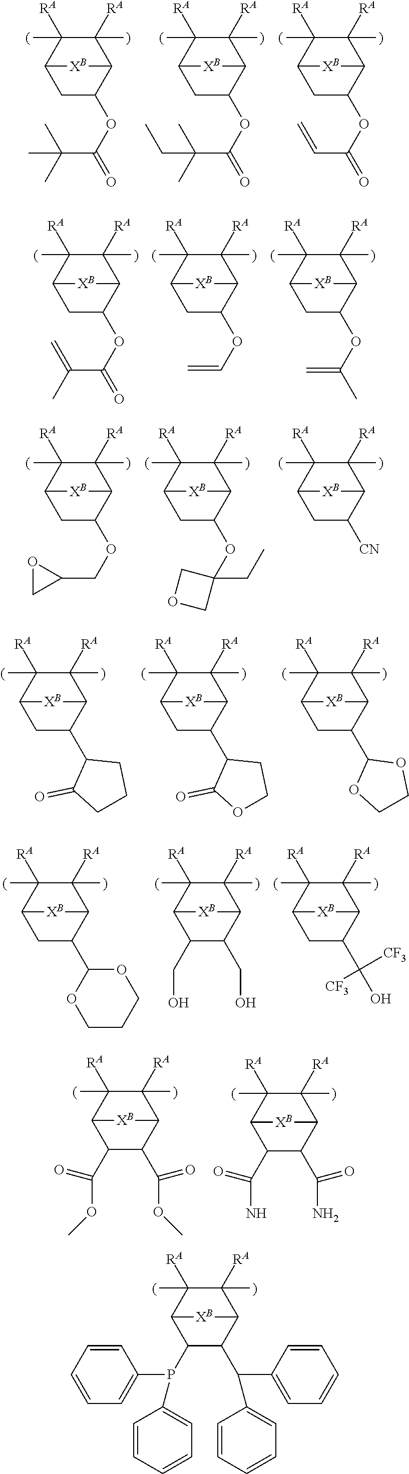

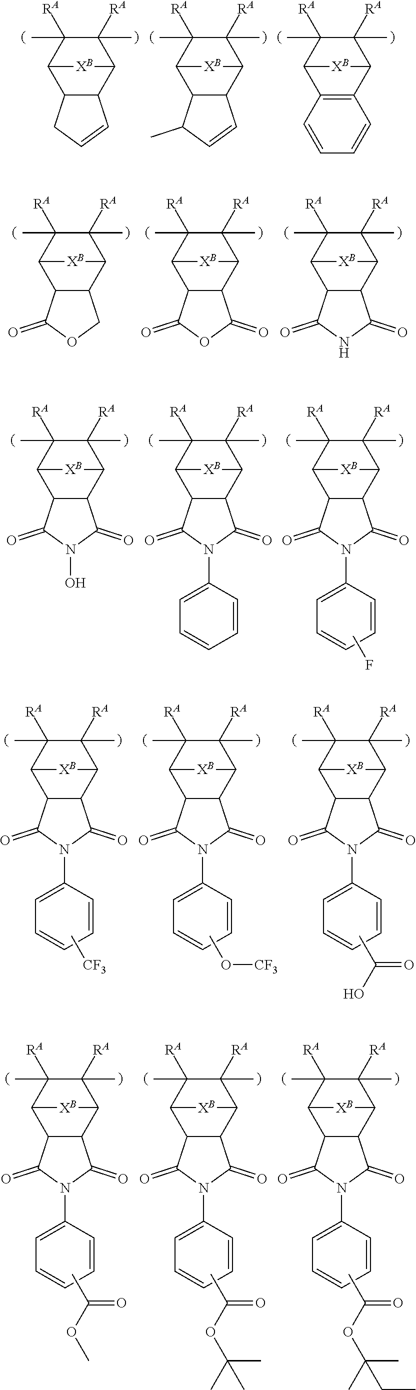

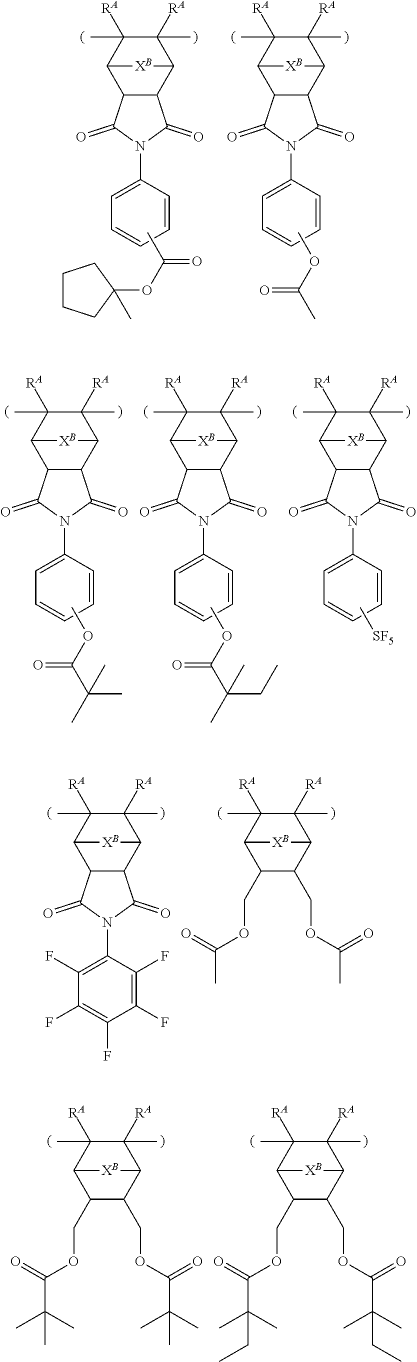

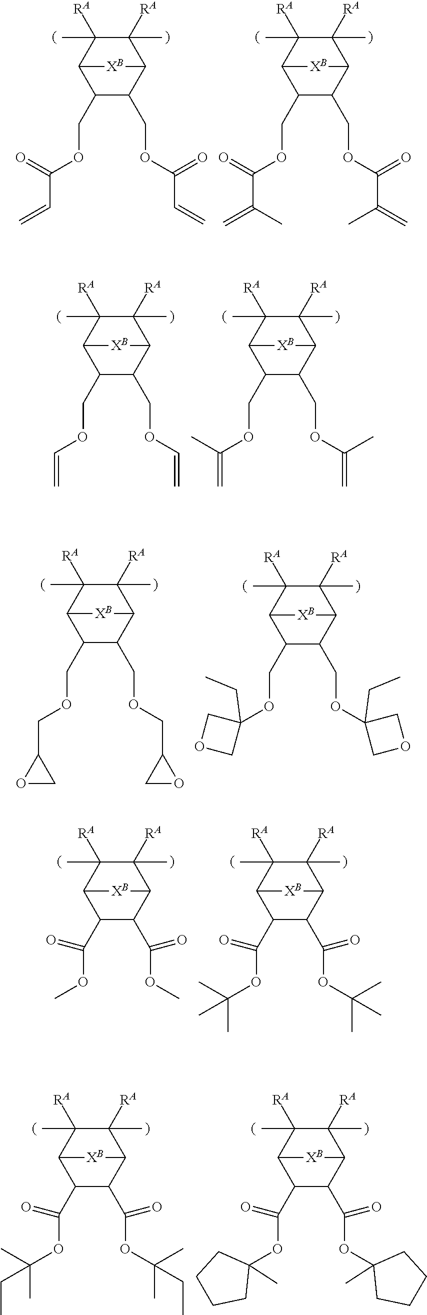

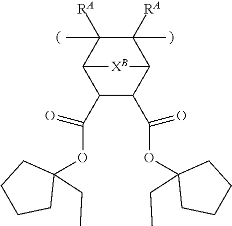

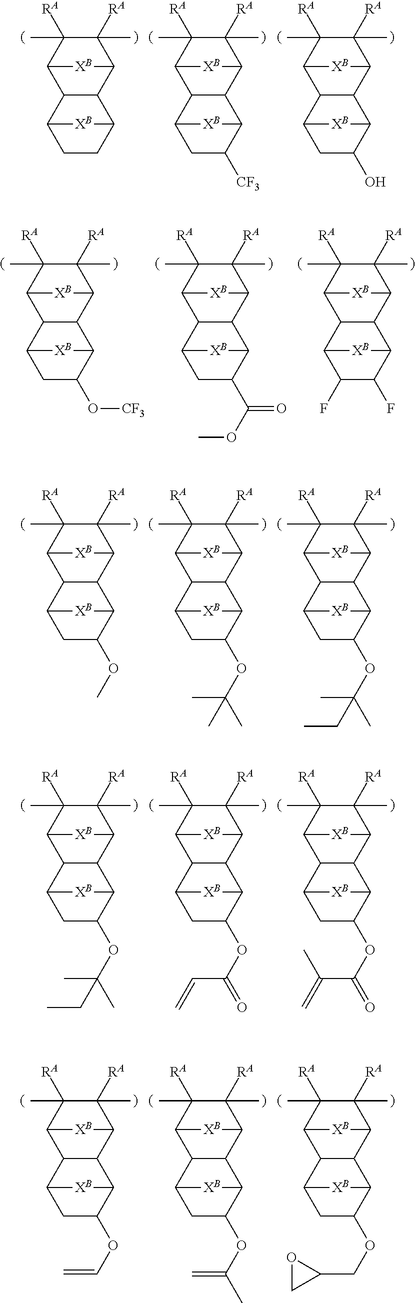

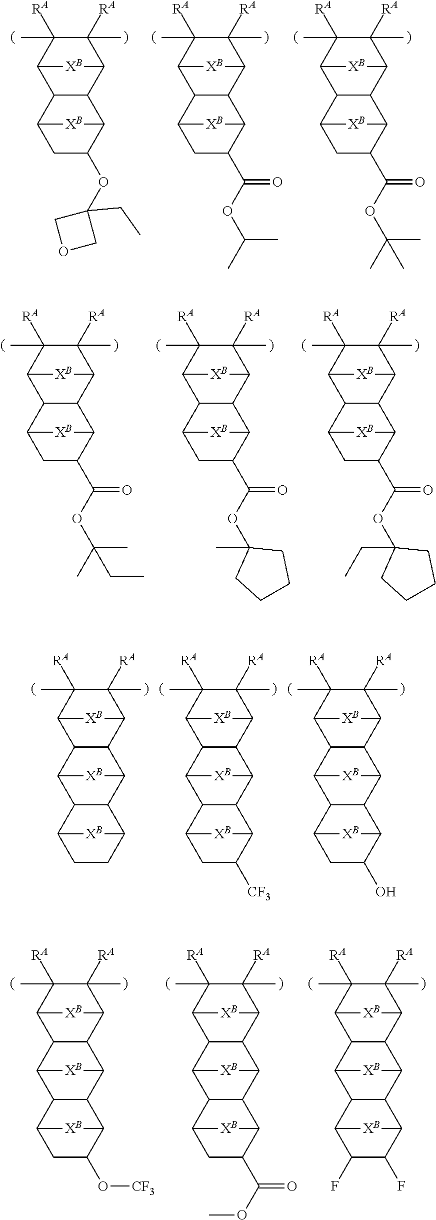

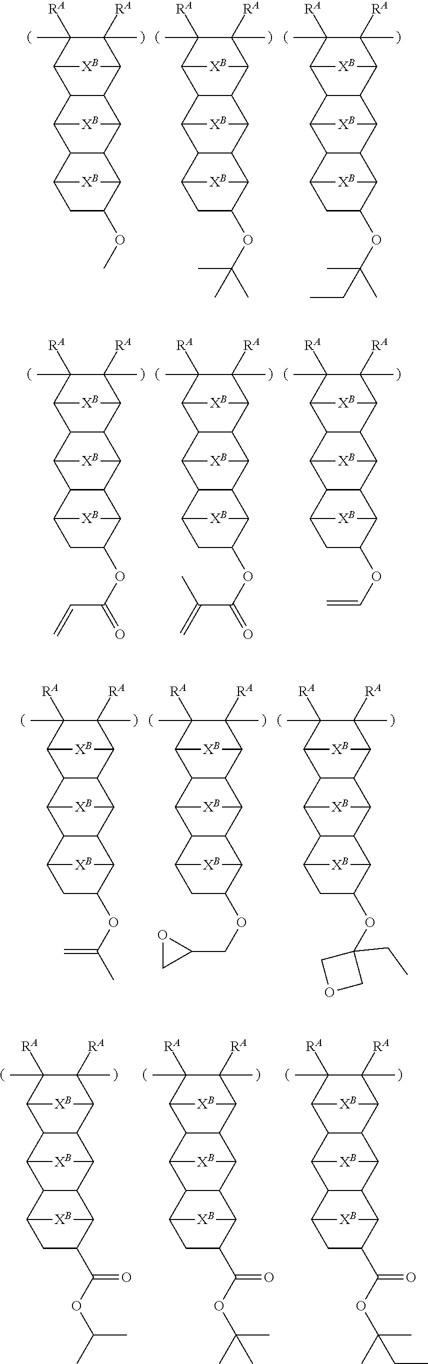

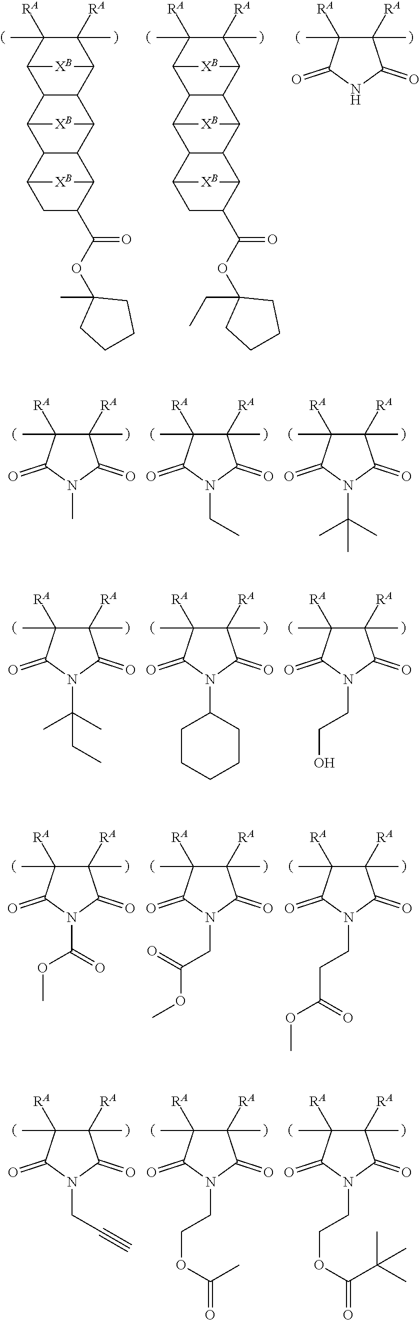

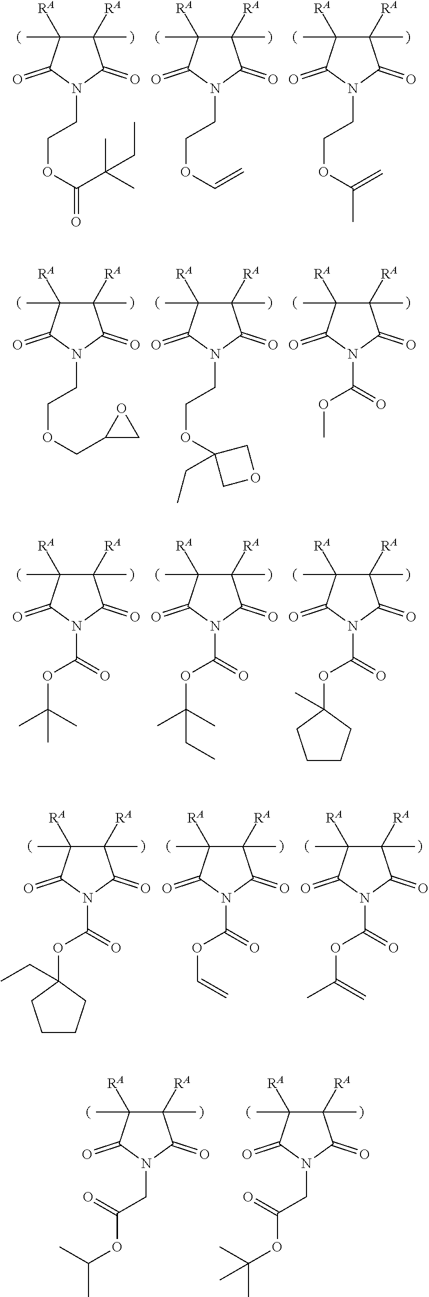

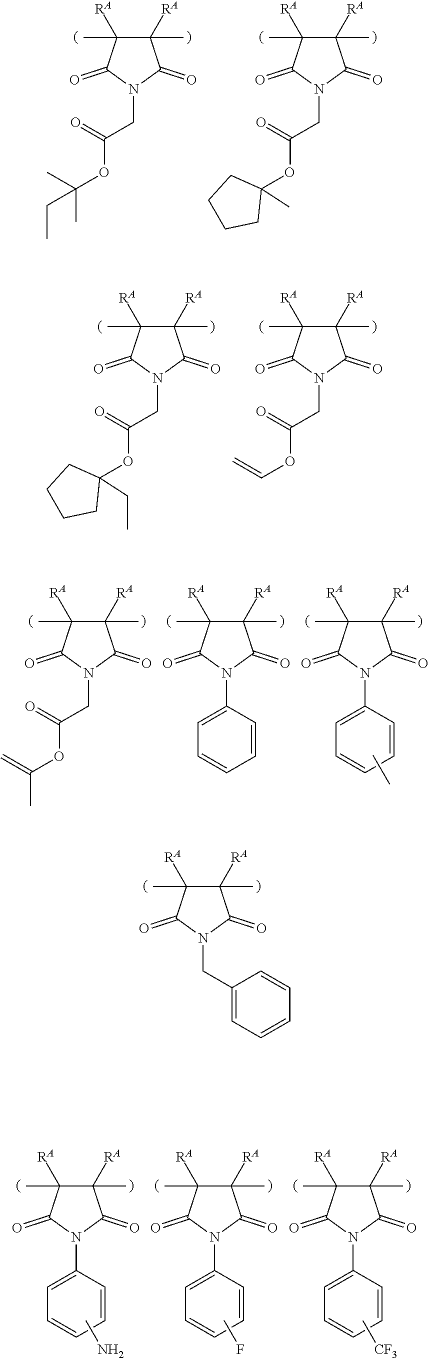

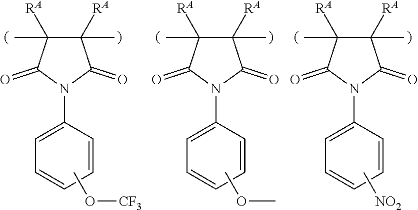

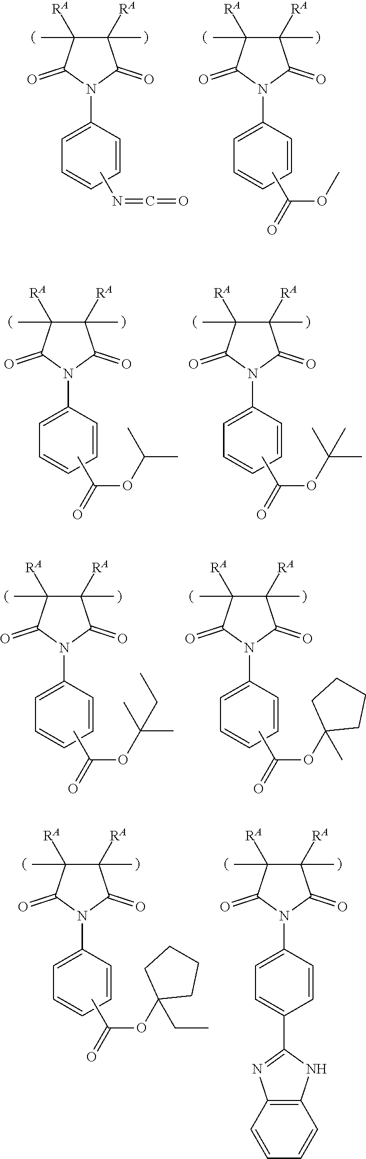

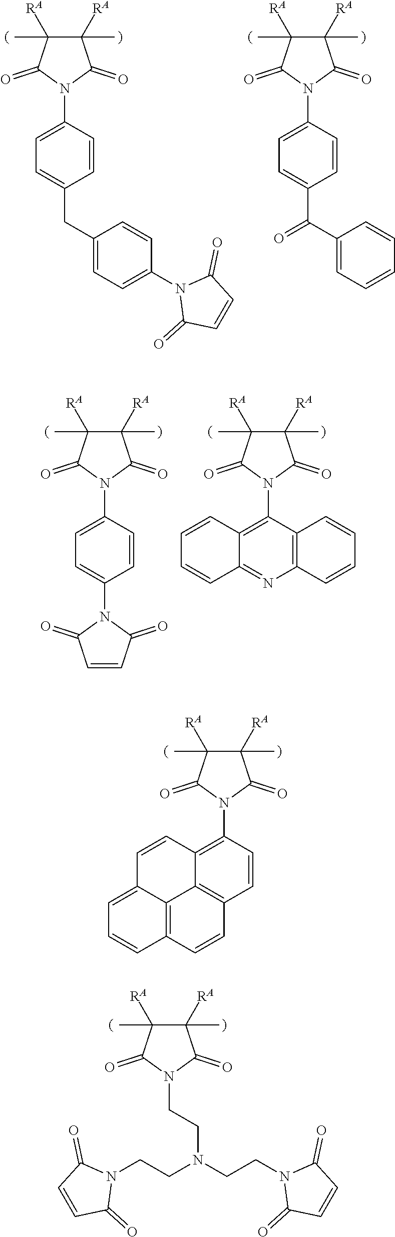

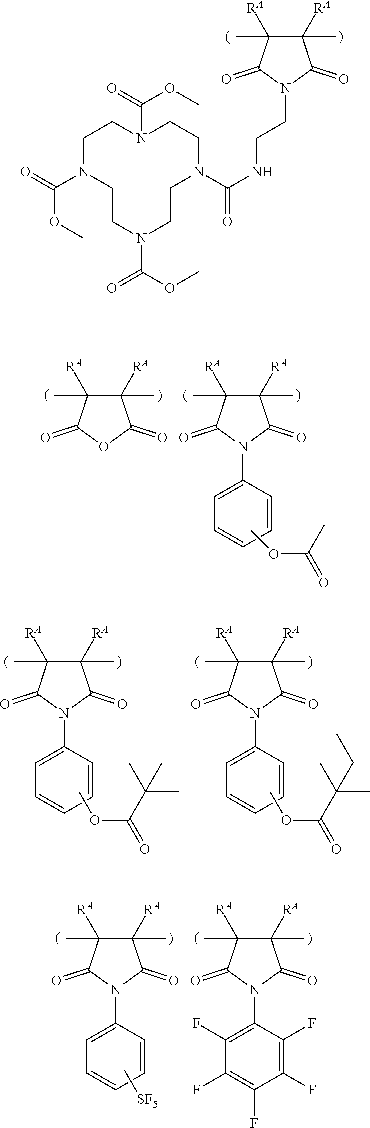

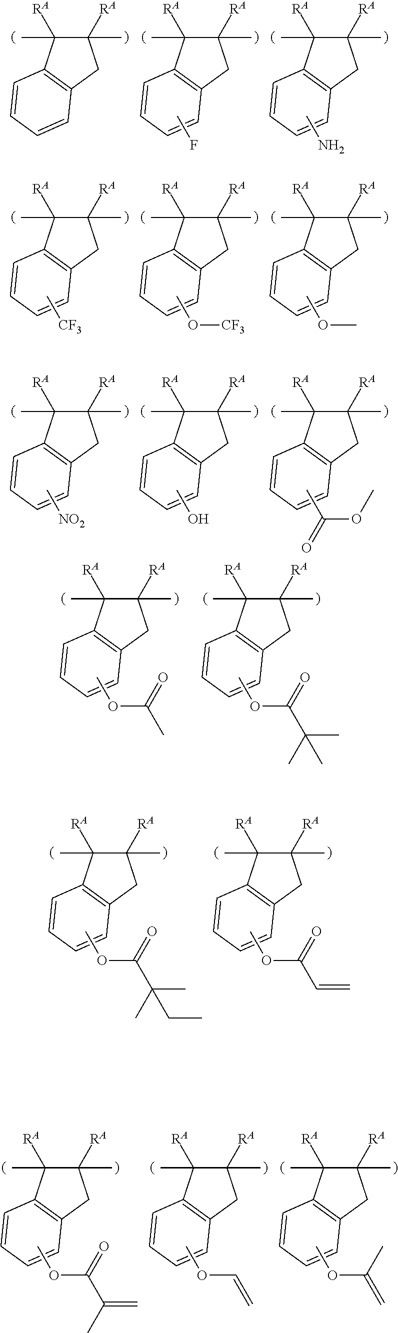

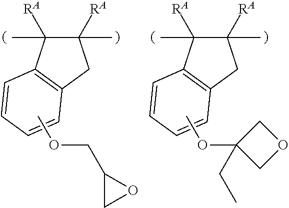

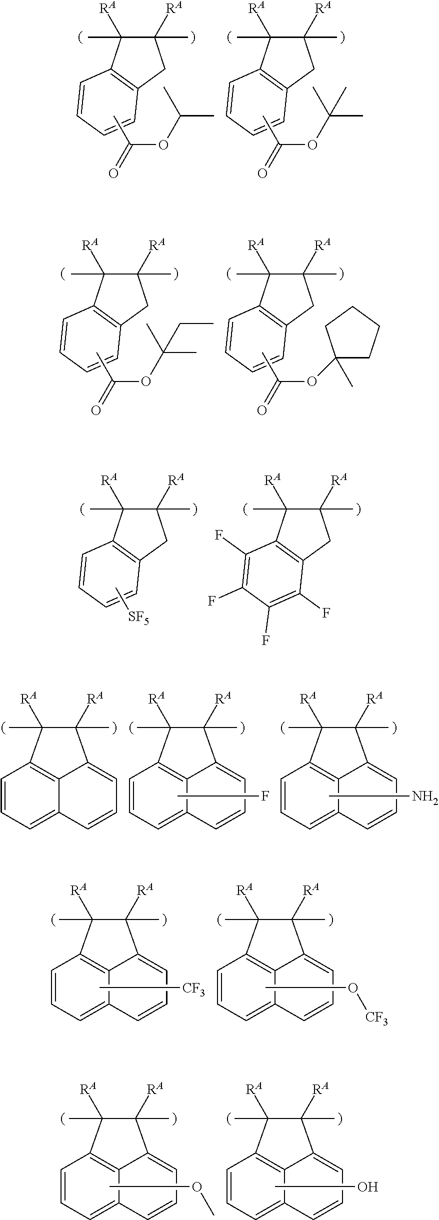

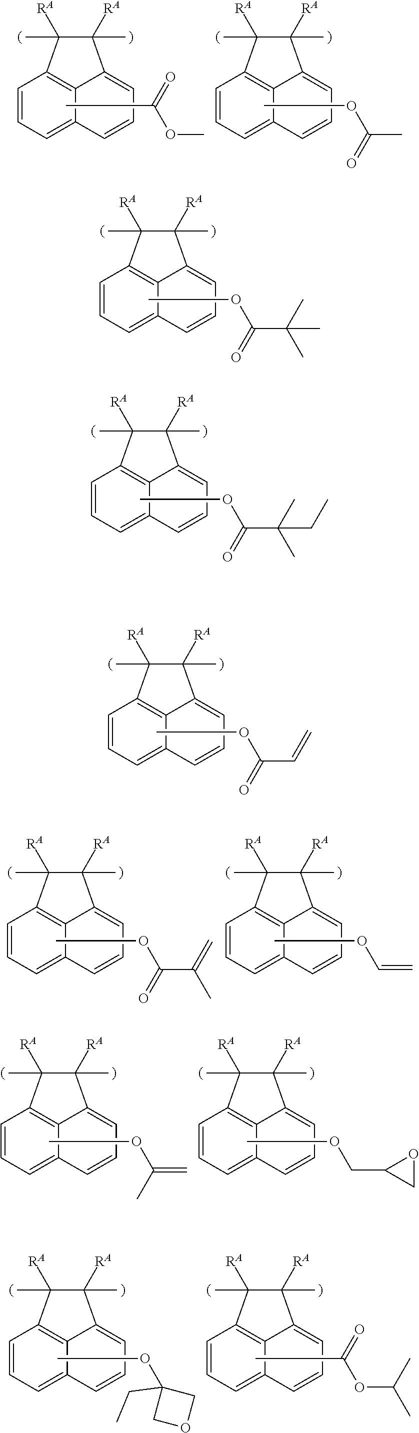

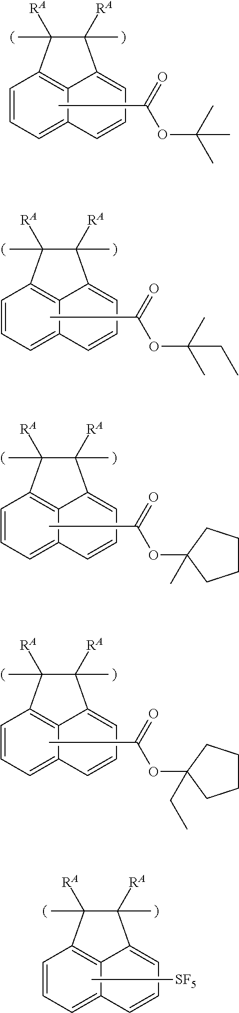

In the resist composition, the content ratio of the hypervalent iodine compound relative to the carboxy group-containing compound (when the carboxy group-containing compound is a carboxy group-containing polymer, this is the content ratio of the hypervalent iodine compound to the carboxylic acid-containing repeating units in the polymer) is preferably 10:90 to 90:10, more preferably 20:80 to 80:20, further preferably 30:70 to 70:30 in terms of a mole ratio. One kind of the hypervalent iodine compound may be used, or two or more kinds thereof having different composition ratios, Mw, and/or Mw/Mn may be used in combination. One kind of the carboxyl group-containing polymer may be used, or two or more kinds thereof having different composition ratios, Mw, and/or Mw/Mn may be used in combination.

In the carboxy group-containing polymer, the content ratio (mole ratio) of the carboxy group-containing repeating unit to the other repeating unit is preferably 10:90 to 90:10, more preferably 15:85 to 85:15, and further preferably 20:80 to 80:20.

The weight-average molecular weight (Mw) of the carboxy group-containing polymer is preferably 1,000 to 500,000, and more preferably 3,000 to 100,000. In the present invention, Mw is a value measured in terms of polystyrene by gel permeation chromatography (GPC) using tetrahydrofuran (THF) as a solvent.

Furthermore, when the carboxyl group-containing polymer has a broad molecular weight distribution (Mw/Mn), due to the presence of low-molecular-weight polymers and high-molecular-weight polymers, there is a risk of appearance of foreign matters on a pattern after exposure, and degradation of a pattern shape. Therefore, since the influence of Mw and Mw/Mn tends to become greater as patterning rules become finer, it is preferable that the carboxyl group-containing polymer has a narrow Mw/Mn distribution of 1.0 to 2.0, in order to obtain a resist composition that can be used suitably for fine pattern dimensions.

Examples of methods for synthesizing the carboxyl group-containing polymer include heating monomers that can provide the repeating unit mentioned above after adding a radical polymerization initiator in an organic solvent to polymerize the monomers.

Specific examples of the organic solvent used for the polymerization reaction include toluene, benzene, THF, diethyl ether, dioxane, cyclohexane, cyclopentane, cyclopentanone, cyclohexanone, methyl ethyl ketone (MEK), propylene glycol monomethyl ether (PGME), propylene glycol monomethyl ether acetate (PGMEA), and γ-butyrolactone (GBL). Specific examples of the polymerization initiator include 2,2′-azobisisobutyronitrile (AIBN), 2,2′-azobis(2,4-dimethylvaleronitrile), dimethyl-2,2-azobis(2-methylpropionate), 1,1′-azobis(1-acetoxy-1-phenylethane), benzoyl peroxide, and lauroyl peroxide. The blending amount of the polymerization initiator is preferably 0.01 to 25 mol % based on the total amount of monomers to be polymerized. The reaction temperature is preferably 50 to 150° C., more preferably 60 to 100° C. The reaction time is preferably 2 to 24 hours, and more preferably 2 to 12 hours from the viewpoint of production efficiency.

The polymerization initiator may be added to the monomer solution mentioned above and then supplied to the reaction vessel, or an initiator solution may be prepared separately from the monomer solution mentioned above and then the solutions each may be supplied to the reaction vessel independently. From the viewpoint of quality control, it is preferable to prepare the monomer solution and the initiator solution independently and then add them dropwise, since the polymerization reaction may proceed due to radicals generated from the initiator during the waiting time, resulting in the formation of an ultra-high molecular weight polymer. In order to adjust the molecular weight, publicly known chain transfer agents such as dodecyl mercaptan and 2-mercaptoethanol may be used in combination. In this case, the blending amount of the chain transfer agent is preferably 0.01 to 20 mol % based on the total amount of the monomers to be polymerized.

The amount of each monomer in the monomer solution, for example, may be appropriately set so as to achieve the desired content ratio of the repeating units described above.

### [Solvent]

The resist composition contains a solvent. The solvent is not particularly limited as long as the solvent dissolves the hypervalent iodine compound, the carboxy-group-containing compound, and other components described later and allows film formation. As such a solvent, organic solvents are preferable. Specific examples thereof include: ketones, such as cyclohexanone, methyl-2-n-pentyl ketone, and methyl isoamyl ketone; alcohols, such as 3-methoxybutanol, 3-methyl-3-methoxybutanol, 1-methoxy-2-propanol, 1-ethoxy-2-propanol, diacetone alcohol, 4-methyl-2-pentanol, and methyl 2-hydroxyisobutyrate; ethers, such as propylene glycol monomethyl ether, ethylene glycol monomethyl ether, propylene glycol monoethyl ether, ethylene glycol monoethyl ether, propylene glycol dimethyl ether, and diethylene glycol dimethyl ether; esters, such as propylene glycol monomethyl ether acetate, propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; carboxylic acids, such as formic acid, acetic acid, and propionic acid; lactones, such as γ-butyrolactone; and mixed solvents thereof.

In the resist composition, the contained amount of the solvent is preferably such an amount that the concentration of the solid contents in the resist composition is preferably 0.1 to 20 mass %, more preferably 0.1 to 15 mass %, and further preferably 0.1 to 10 mass %. Note that in the present invention, the solid contents is a general term used to refer to the components other than the solvents out of all the components of the resist composition. One kind of the solvent may be used, or two or more kinds thereof may be used in mixture.

The resist composition may further contain a surfactant. As the surfactant, a fluorine-based and/or silicone-based surfactant is preferable. Specific examples of such a surfactant include surfactants disclosed in paragraph [0276] of the description of US2008/0248425A1. Furthermore, it is also possible to use surfactants other than the fluorine-based and/or silicone-based surfactants disclosed in paragraph [0280] of the description of US2008/0248425A1.

When the resist composition contains the surfactant described above, the contained amount is preferably 0.0001 to 2 mass % of all the solid contents. One kind of the surfactant may be used, or two or more kinds thereof may be used in combination.

The resist composition may further contain at least one selected from radical scavengers, which makes it possible to control the photoreaction during photolithography and adjust the sensitivity.

Specific examples of the radical scavenger include hindered phenols, quinones, hindered amines, and thiol compounds. Specific examples of the hindered phenols include dibutylhydroxytoluene (BHT) and 2,2′-methylenebis(4-methyl-6-tert-butylphenol). Specific examples of the quinones include 4-methoxyphenol (methoquinone) and hydroquinone. Specific examples of the hindered amines include 2,2,6,6-tetramethylpiperidine and 2,2,6,6-tetramethylpiperidine-N-oxy radical. Specific examples of the thiol compounds include dodecanethiol and hexadecanethiol.

When the resist composition contains the radical scavenger, the contained amount is preferably 0.01 to 10 mass % of all the solid contents. One kind of the radical scavenger may be used, or two or more kinds thereof may be used in combination.

The resist composition may further contain a crosslinking agent. The addition of a crosslinking agent promotes the crosslinking reaction during photolithography, improves the glass transition temperature of the pattern, and allows formation of a pattern with excellent resolution in fine lines.

Specific examples of the crosslinking agent include compounds having a carbon-carbon unsaturated bond as a functional group, such as a vinyl group, a (meth)acrylate group, an allyl group, an alkynyl group, and an aromatic ring. Specific examples of the compounds having a vinyl group include linear alkenes, branched alkenes, and cyclic alkenes, each optionally having a substituent. Specific examples of the compounds having a (meth)acrylate group include acrylic acid, methacrylic acid, acrylic acid ester, and methacrylic acid ester, each optionally having a substituent. Specific examples of the compounds having an allyl group include allyl alcohol, allyl ether, allyl ester, allyl amide, allylamine, and allyl-group-containing isocyanurates, each optionally having a substituent. Specific examples of the compounds having an alkynyl group include linear alkynes, branched alkynes, cyclic alkynes, alkynyl alcohols, alkynyl ethers, alkynyl esters, alkynyl amides, alkynyl amines, and alkynyl-group-containing isocyanurates, each optionally having a substituent. Specific examples of the compounds having an aromatic ring include arenes, heteroarenes, styrene, stilbene, phenylacetylene, acenaphthylene, and chalcone, each optionally having a substituent. The crosslinking agent may have only one of the functional groups, or may have a plurality of the functional groups. The number of the functional groups contained in the crosslinking agent is preferably 1 or more and 10 or less, more preferably 2 or more and 8 or less.

When the resist composition contains the crosslinking agent, the contained amount is preferably 0.01 to 50 mass % of all the solid contents. One kind of the crosslinking agent may be used, or two or more kinds thereof may be used in combination.

When the resist composition contains the crosslinking agent, it may further contain a photopolymerization initiator. The photopolymerization initiator generates radicals when irradiated with a high-energy beam, and can promote crosslinking of the crosslinking agent.

Specific examples of the photopolymerization initiator include: benzophenone derivatives, such as benzophenone, methyl 0-benzoylbenzoate, 4-benzoyl-4′-methyldiphenyl ketone, dibenzyl ketone, and fluorenone; acetophenone derivatives, such as 2,2′-diethoxyacetophenone, 2-hydroxy-2-methylpropiophenone, 2,2-dimethoxy-1,2-diphenylethan-1-one, 1-hydroxycyclohexyl phenyl ketone, 2-methyl-1-[4-(methylthio)phenyl]-2-morpholinopropan-1-one, 2-hydroxy-1-{4-[4-(2-hydroxy-2-methylpropionyl)-benzyl]-phenyl}-2-methylpropan-1-one, and methyl phenylglyoxylate; thioxanthone derivatives, such as thioxanthone, 2-methylthioxanthone, 2-isopropylthioxanthone, 4-isopropylthioxanthone, 2-chlorothioxanthone, and diethylthioxanthone; benzyl derivatives, such as benzil, benzil dimethyl ketal, and benzyl-β-methoxyethyl acetal; benzoin derivatives, such as benzoin, benzoin methyl ether, and 2-hydroxy-2-methyl-1-phenylpropan-1-one; oxime compounds, such as 1-phenyl-1,2-butanedione-2-(O-methoxycarbonyl)oxime, 1-phenyl-1,2-propanedione-2-(O-methoxycarbonyl)oxime, 1-phenyl-1,2-propanedione-2-(O-ethoxycarbonyl)oxime, 1-phenyl-1,2-propanedione-2-(O-benzoyl)oxime, 1,3-diphenylpropanetrione-2-(O-ethoxycarbonyl)oxime, 1-phenyl-3-ethoxypropanetrione-2-(O-benzoyl)oxime-1,2-octanedione, 1-[4-(phenylthio)-2-(O-benzoyloxime)]ethanone, and 1-[9-ethyl-6-(2-methylbenzoyl)-9H-carbazol-3-yl]-1-(O-acetyloxime); α-hydroxyketone compounds, such as 2-hydroxy-2-methyl-1-phenylpropan-1-one, 1-[4-(2-hydroxyethoxy)phenyl]-2-hydroxy-2-methyl-1-propan-1-one, and 2-hydroxy-1-{4-[4-(2-hydroxy-2-methylpropionyl)-benzyl]phenyl}-2-methylpropane; α-aminoalkylphenone compounds, such as 2-benzyl-2-dimethylamino-1-(4-morpholinophenyl)-butanone-1 and 2-dimethylamino-2-(4-methylbenzyl)-1-(4-morpholin-4-yl-phenyl)butan-1-one; phosphine oxide compounds, such as bis(2,4,6-trimethylbenzoyl)-phenylphosphine oxide, bis(2,6-dimethoxybenzoyl)-2,4,4-trimethyl-pentylphosphine oxide, and 2,4,6-trimethylbenzoyldiphenylphosphine oxide; titanocene compounds, such as bis(η5-2,4-cyclopentadien-1-yl)-bis(2,6-difluoro-3-(1H-pyrrol-1-yl)phenyl)titanium; etc.

When the resist composition contains the photopolymerization initiator, the contained amount thereof is preferably 0.1 to 10 mass %, more preferably 0.1 to 5 mass %, and most preferably 0.1 to 1 mass %, of all the solid contents. When it is 0.1 mass % or more, a sufficient blending effect can be obtained.

As described above, the resist composition contains a hypervalent iodine compound and a carboxyl group-containing compound as its main components, but does not contain an acid-labile group-containing polymer or a photo-acid generator, which are contained in conventional chemically amplified resist compositions. However, the inventive resist composition, particularly upon exposure by EB or EUV, enabling the formation of a positive pattern in which an exposed area is soluble in a developer or a negative pattern in which an exposed area is insoluble in a developer. The mechanism behind this is not completely clear, but it is speculated to be as follows.

The hypervalent iodine compound is a tricoordinate compound having an aryl group and a carboxylate ligand. When such a tricoordinate iodine compound is mixed with a carboxy group-containing compound, an exchange of the carboxylate ligands is thought to occur in an equilibrium reaction. In this event, if the original carboxylate ligand can be removed by some method, a hypervalent iodine compound having a new ligand is generated. For example, by mixing 1-iodonaphthylene diacetate as a hypervalent iodine compound with a carboxyl group-containing compound and removing the resulting low-boiling acetic acid, ligand-exchanging is completed. In this event, the carboxy group-containing compound becomes a polymer crosslinked with the hypervalent iodine compound.

The polymer crosslinked with the hypervalent iodine compound is generated at the time of film formation. It is because, even if the crosslinked compound is synthesized beforehand, such a crosslinked polymer is insoluble in most organic solvents, resulting in impossibility of preparing a solution. About this, it is speculated that the solvent solubility of the hypervalent iodine compound, originally having low solvent solubility due to its high polarization, is further reduced due to having the carboxy-group-containing compound as a ligand. Accordingly, it is desirable, as a step, to remove the original low-molecular-weight carboxylic acid component at the time of film formation and in the subsequent baking process, thereby forming a resist film while completing the ligand exchange reaction.

The resist film obtained from the inventive resist composition changes in polarity through decomposition of the hypervalent iodine compound, being the main component of the resist film, by light, and thus a pattern is formed in a development step. The mechanism behind this is not completely clear, but it is speculated to be as follows.

The inventive resist composition can be either a positive pattern or a negative pattern depending on the selection of components. In the case of a positive pattern, the composition contains a polymer bonded with a hypervalent iodine compound during film formation. This polymer is decomposed by light to become a monovalent iodine compound. At the same time, the bond between the carboxy group-containing compound and the hypervalent iodine compound is released, resulting in a decrease in molecular weight. This is speculated to result in the formation of a positive pattern in which exposed areas are removed by an organic solvent.

On the other hand, in the case of the negative patterns, the composition contains a polymer crosslinked by hypervalent iodine compounds generated during film formation. When the polymer is decomposed by light, a change of crosslinking or bonding occurs, resulting in an increase in molecular weight and a change in polarity. This is speculated to result in the formation of a negative-tone pattern in which unexposed areas are removed by an alkali aqueous solution.

Based on the above speculation, it can be said that the resist composition is a non-chemically amplified resist composition. Unlike conventional chemically amplified resist compositions, the resist composition does not require an acid-labile group-containing polymer or a photo-acid generator, and therefore does not suffer from adverse effects (e.g., image blurring) due to acid diffusion, making it possible to resolve fine patterns.

The resist composition is effective particularly in EUV lithography. This is because the resist composition has iodine atoms having high absorbing capability for EUV light. That is, shot noise is reduced, and the resist composition can achieve higher resolution and lower LWR.

As an EUV resist composition capable of forming a fine pattern, a metal resist containing a metal tin compound as a main component, which has a high absorbing capability for EUV light similar to an iodine atom, has been reported (e.g., Patent Document 2). However, as mentioned above, such metal resists have many problems, such as insufficient solubility in a solvent, storage stability, and defects due to etching residues caused by inclusion of a metal element. On the other hand, the inventive resist composition does not contain a metal element, and therefore is more advantageous than metal resist in terms of defects and has no problem also in light of solubility in a solvent. Furthermore, the inventive resist composition can be applied for a positive pattern, and therefore has a wide range of uses. For example, in a contact hole formation process, a metal resist used in negative-type development requires a reversing process after formation of a pillar pattern. On the other hand, a positive-type resist does not require such a process. Therefore, from the viewpoint of process simplicity, the inventive resist composition can be said to be more useful than a metal resist.

The resist film preferably has a thickness of 10 to 70 nm, more preferably 20 to 50 nm.

The resist composition may contain a photo-acid generator. By including a photo-acid generator in the resist composition of the present invention, a positive pattern can be formed with higher sensitivity than in a resist composition that does not contain a photo-acid generator. The mechanism behind this is not completely clear, but it is speculated to be as follows.

The inventive resist composition contains a photo-acid generator, which allows the acid generated from the photo-acid generator during the resist exposure process to be exchanged with the ligands of the hypervalent iodine compound, forming a new ligand and thereby releasing the bond between the carboxy group-containing compound and the hypervalent iodine compound. Therefore, in addition to cutting of an I—O bond by light, the acid generated from the photo-acid generator causes a polarity change due to new ligand exchange, or a molecular weight reduction (when the carboxy group-containing compound is a polymer), which is presumably why a positive pattern can be formed with high sensitivity by development using an organic solvent.

Based on the above speculation, the inventive resist composition is a non-chemically amplified resist composition that contains a photo-acid generator and does not require an acid-labile group-containing polymer, such as a conventional chemically amplified resist composition. Therefore, the acid generated from the photo-acid generator reacts with the ligands of the hypervalent iodine compound in the exposed area to form a new hypervalent iodine ligands. In other words, unlike a chemically amplified resist composition, the resist composition does not have an amplification mechanism that reacts with acid-labile groups to regenerate acid, so it is possible to resolve a fine pattern without the adverse effects (e.g., image blurring) due to acid diffusion.

Specific examples of the photo-acid generator include the following onium salt compounds.

### [Onium Salt Compound]

The onium salt compound contains, as a cation, a sulfonium cation represented by the following formula (5-1) or an iodonium cation represented by the following formula (5-2).

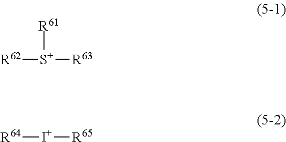

In the formulae (5-1) and (5-2), R⁶¹ to R⁶⁵ each independently represent a halogen atom or a hydrocarbyl group having 1 to 30 carbon atoms and optionally having a heteroatom.

Specific examples of the halogen atom represented by R⁶¹ to R⁶⁵ include a fluorine atom, a chlorine atom, a bromine atom, and an iodine atom.

The hydrocarbyl groups represented by R⁶¹ to R⁶⁵ may be saturated or unsaturated, and may be linear, branched, or cyclic. Specific examples thereof include: alkyl groups having 1 to 30 carbon atoms, such as a methyl group, an ethyl group, an n-propyl group, an isopropyl group, an n-butyl group, an isobutyl group, a sec-butyl group, and a tert-butyl group; cyclic saturated hydrocarbyl groups having 3 to 30 carbon atoms, such as a cyclopropyl group, a cyclopentyl group, a cyclohexyl group, a cyclopropylmethyl group, a 4-methylcyclohexyl group, a cyclohexylmethyl group, a norbornyl group, and an adamantyl group; alkenyl groups having 2 to 30 carbon atoms, such as a vinyl group, an allyl group, a propenyl group, a butenyl group, and a hexenyl group; cyclic unsaturated hydrocarbyl groups having 3 to 30 carbon atoms, such as a cyclohexenyl group; aryl groups having 6 to 30 carbon atoms, such as a phenyl group, a naphthyl group, and a thienyl group; aralkyl groups having 7 to 30 carbon atoms, such as a benzyl group, a 1-phenylethyl group, and 2-phenylethyl group; and groups obtained by combining these groups. The hydrocarbyl group is preferably an aryl group. Part or all of the hydrogen atoms of the hydrocarbyl group may be substituted with a group containing a heteroatom such as an oxygen atom, a sulfur atom, a nitrogen atom, or a halogen atom, or part of the —CH₂— groups of the hydrocarbyl group may be substituted with a group containing a heteroatom such as an oxygen atom, a sulfur atom, or a nitrogen atom, and the resulting hydrocarbyl group may contain a hydroxy group, a fluorine atom, a chlorine atom, a bromine atom, an iodine atom, a cyano group, a nitro group, a carbonyl group, an ether bond, an ester bond, a sulfonate ester bond, a carbonate bond, a lactone ring, a sultone ring, a carboxylic anhydride (—C(═O)—O—C(═O)—), a haloalkyl group, or the like.

Furthermore, R⁶¹ and R⁶² may be bonded to each other to form a ring together with the sulfur atom to which they are bonded. In this case, specific examples of the ring structure include those represented by the following formulae.

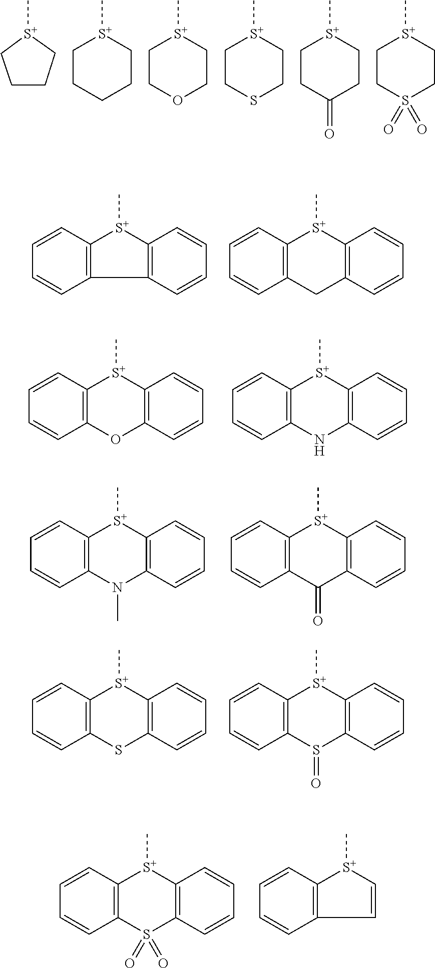

In the formulae, the dashed line indicates an attachment point to R⁶³.

Specific examples of the sulfonium cation represented by the formula (5-1) include, but are not limited to, those shown below.

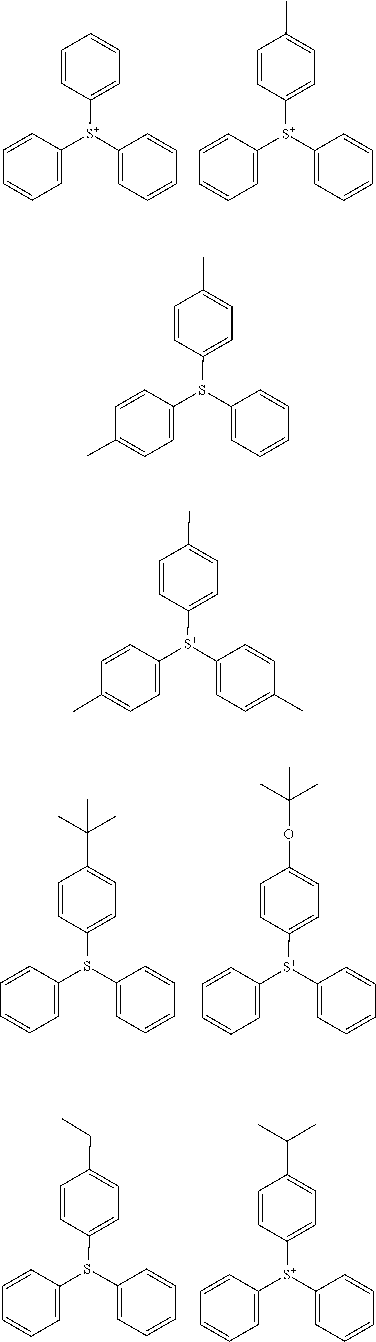

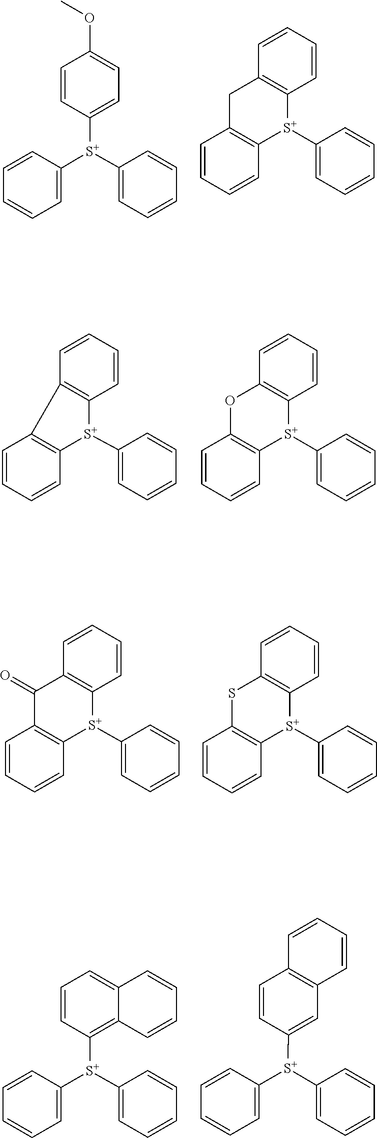

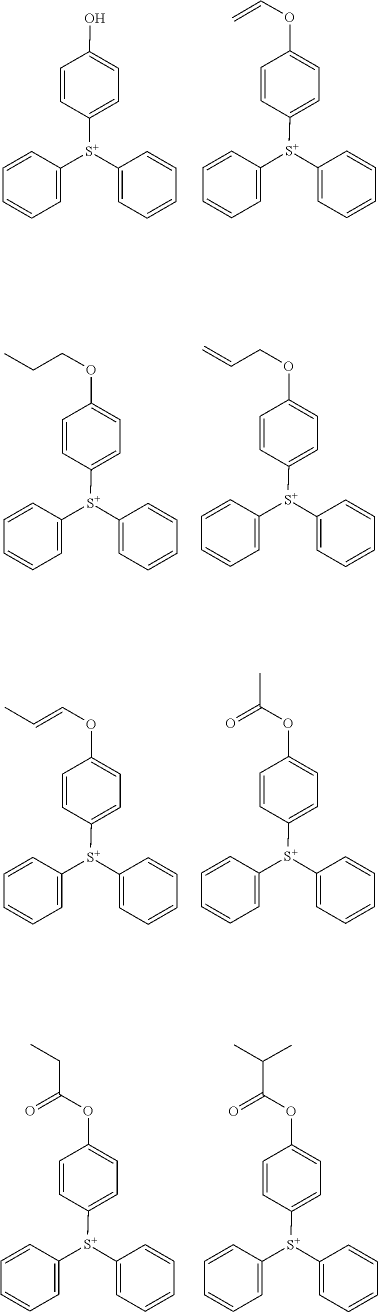

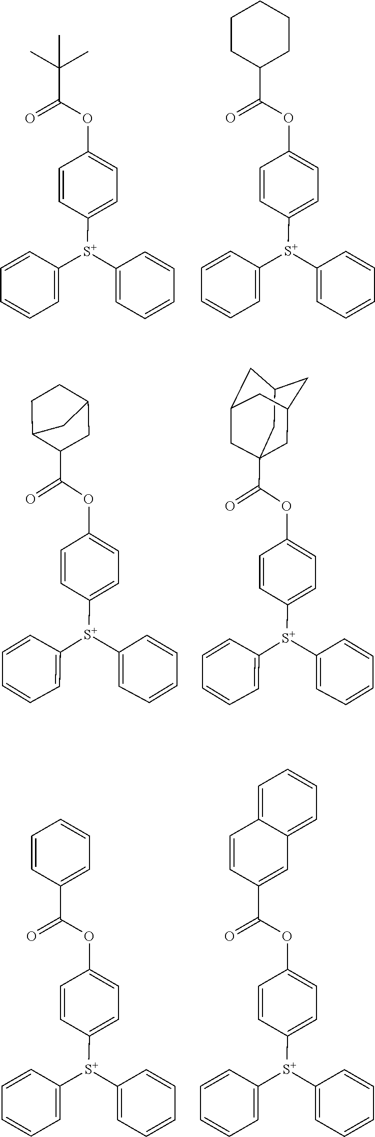 [SMILES: CC(C)(C)C(=O)Oc1ccc([S+](c2ccccc2)c2ccccc2)cc1 ; O=C(Oc1ccc([S+](c2ccccc2)c2ccccc2)cc1)C1CCCCC1 ; O=C(Oc1ccc([S+](c2ccccc2)c2ccccc2)cc1)C1CC2CCC1C2 ; O=C(Oc1ccc([S+](c2ccccc2)c2ccccc2)cc1)C12CC3CC(CC(C3)C1)C2 ; O=C(Oc1ccc([S+](c2ccccc2)c2ccccc2)cc1)c1ccccc1 ; O=C(Oc1ccc([S+](c2ccccc2)c2ccccc2)cc1)c1ccc2ccccc2c1]

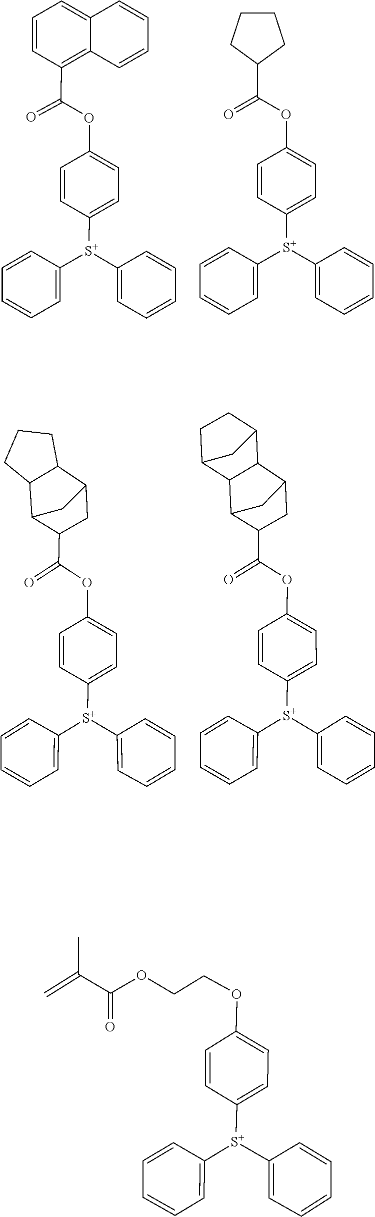 [SMILES: O=C(Oc1ccc([S+](c2ccccc2)c2ccccc2)cc1)c1cccc2ccccc12 ; O=C(Oc1ccc([S+](c2ccccc2)c2ccccc2)cc1)C1CCCC1 ; O=C(Oc1ccc([S+](c2ccccc2)c2ccccc2)cc1)C1CC2CC1C1CCCC21 ; O=C(Oc1ccc([S+](c2ccccc2)c2ccccc2)cc1)C1CC2CC1C1C3CCC(C3)C21 ; C=C(C)C(=O)OCCOc1ccc([S+](c2ccccc2)c2ccccc2)cc1]

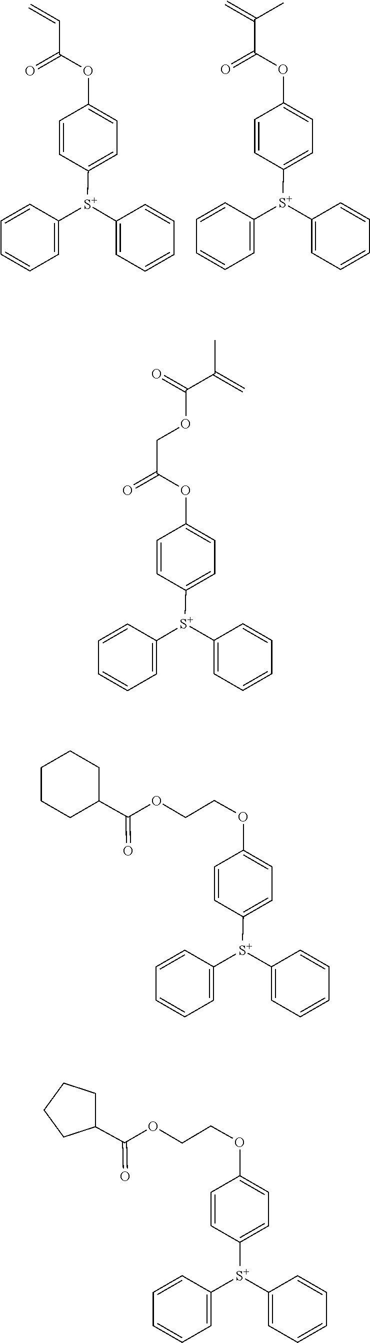 [SMILES: C=CC(=O)Oc1ccc([S+](c2ccccc2)c2ccccc2)cc1 ; C=C(C)C(=O)Oc1ccc([S+](c2ccccc2)c2ccccc2)cc1 ; C=C(C)C(=O)OCC(=O)Oc1ccc([S+](c2ccccc2)c2ccccc2)cc1 ; O=C(OCCOc1ccc([S+](c2ccccc2)c2ccccc2)cc1)C1CCCCC1 ; O=C(OCCOc1ccc([S+](c2ccccc2)c2ccccc2)cc1)C1CCCC1]

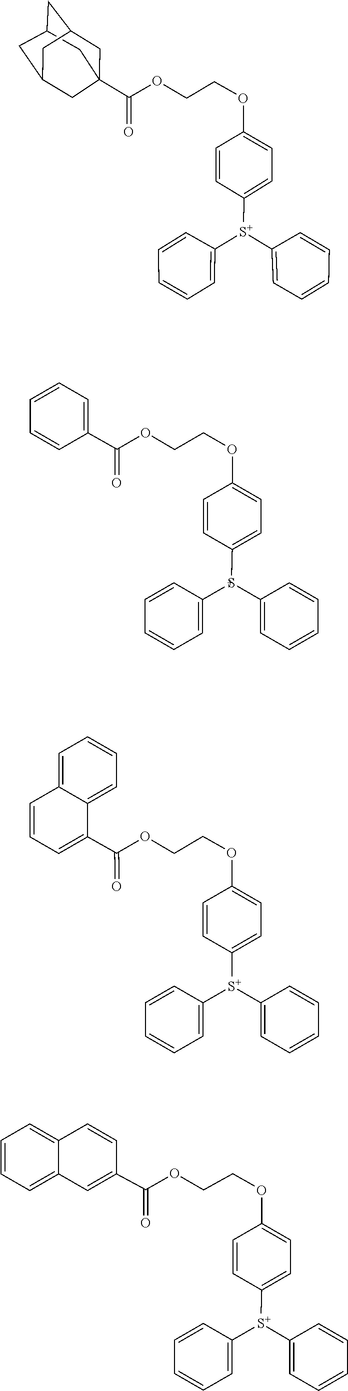 [SMILES: O=C(OCCOc1ccc([S+](c2ccccc2)c2ccccc2)cc1)C12CC3CC(CC(C3)C1)C2 ; O=C(OCCOc1ccc([S+](c2ccccc2)c2ccccc2)cc1)c1ccccc1 ; O=C(OCCOc1ccc([S+](c2ccccc2)c2ccccc2)cc1)c1cccc2ccccc12 ; O=C(OCCOc1ccc([S+](c2ccccc2)c2ccccc2)cc1)c1ccc2ccccc2c1]

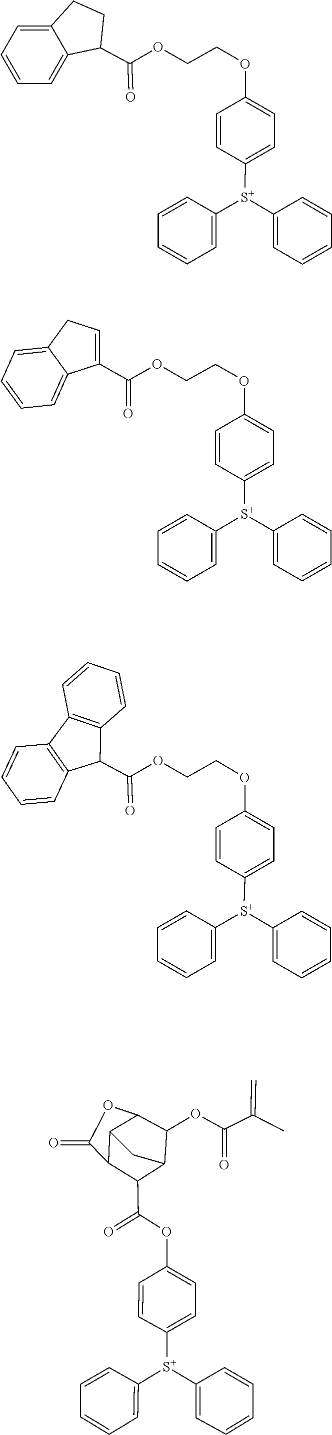 [SMILES: O=C(OCCOc1ccc([S+](c2ccccc2)c2ccccc2)cc1)C1CCc2ccccc21 ; O=C(OCCOc1ccc([S+](c2ccccc2)c2ccccc2)cc1)C1=CCc2ccccc21 ; O=C(OCCOc1ccc([S+](c2ccccc2)c2ccccc2)cc1)C1c2ccccc2-c2ccccc21 ; C=C(C)C(=O)OC1C2CC3C1OC(=O)C3C2C(=O)Oc1ccc([S+](c2ccccc2)c2ccccc2)cc1]

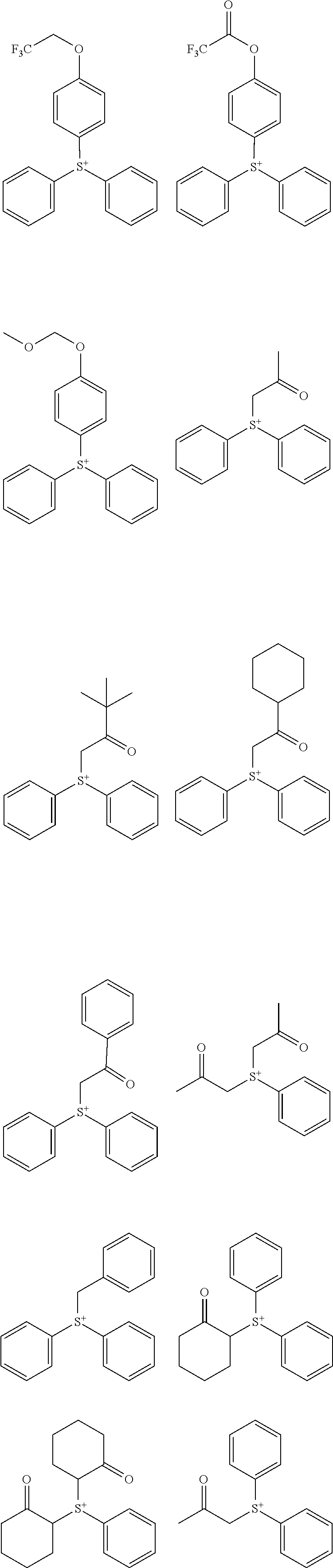

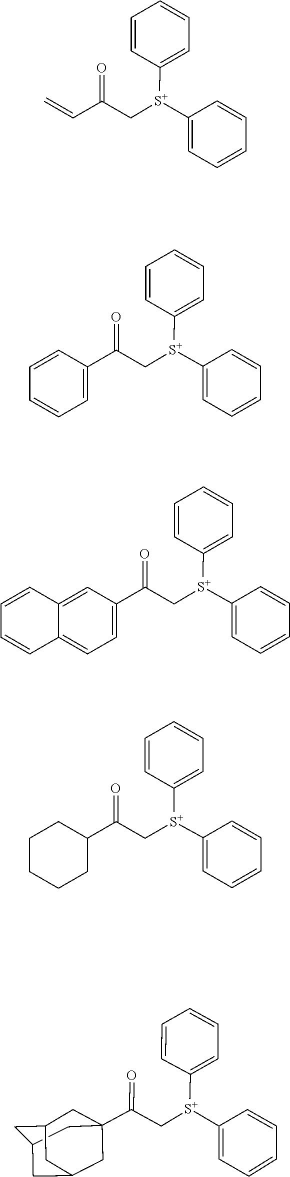 [SMILES: C=CC(=O)C[S+](c1ccccc1)c1ccccc1 ; O=C(C[S+](c1ccccc1)c1ccccc1)c1ccccc1 ; O=C(C[S+](c1ccccc1)c1ccccc1)c1ccc2ccccc2c1 ; O=C(C[S+](c1ccccc1)c1ccccc1)C1CCCCC1 ; O=C(C[S+](c1ccccc1)c1ccccc1)C12CC3CC(CC(C3)C1)C2]

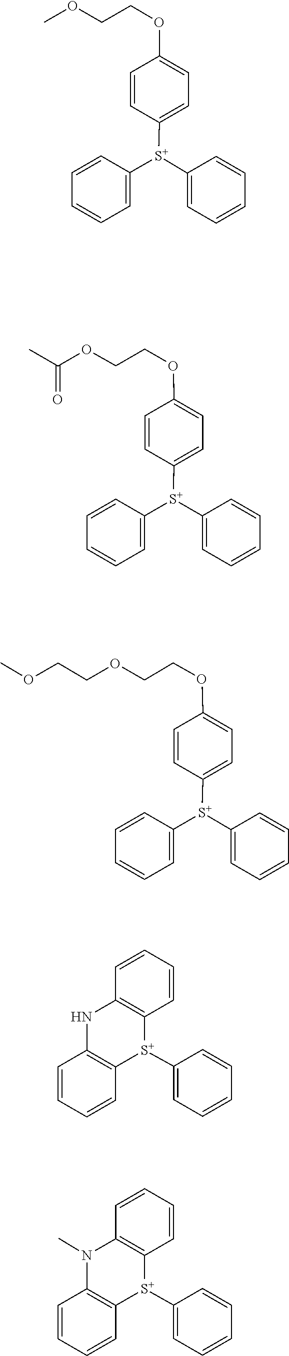 [SMILES: COCCOc1ccc([S+](c2ccccc2)c2ccccc2)cc1 ; CC(=O)OCCOc1ccc([S+](c2ccccc2)c2ccccc2)cc1 ; COCCOCCOc1ccc([S+](c2ccccc2)c2ccccc2)cc1 ; c1ccc([S+]2c3ccccc3Nc3ccccc32)cc1 ; CN1c2ccccc2[S+](c2ccccc2)c2ccccc21]

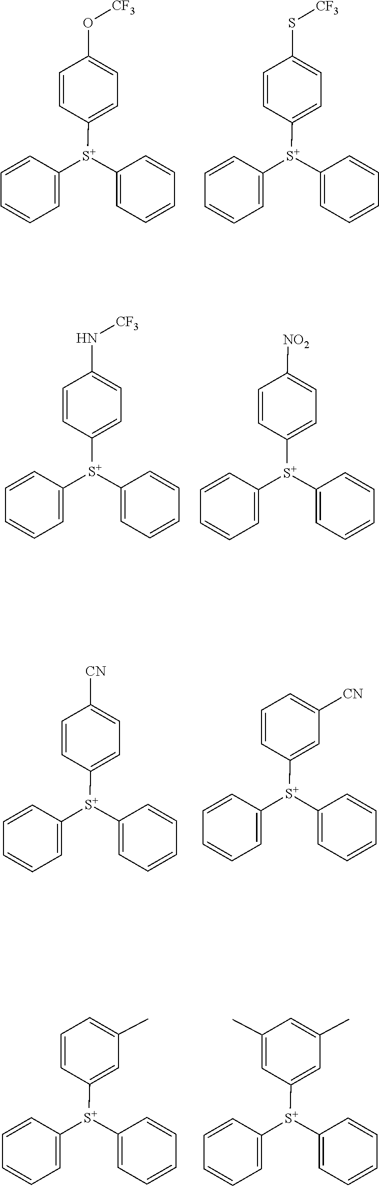

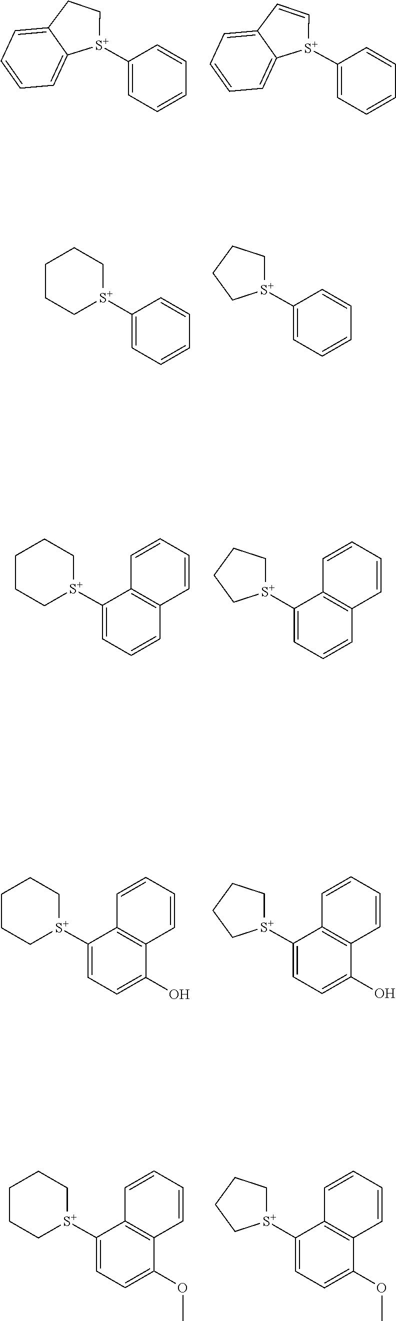

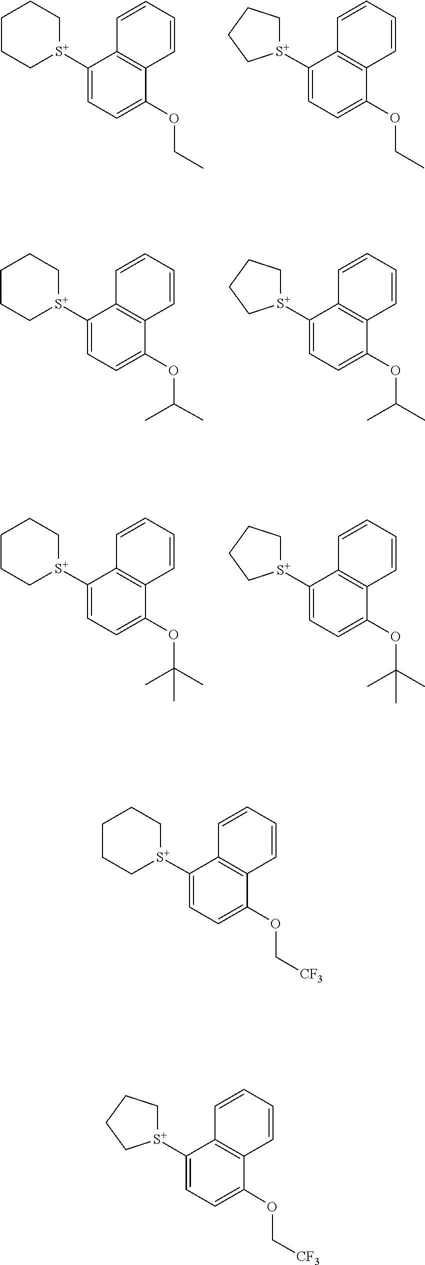

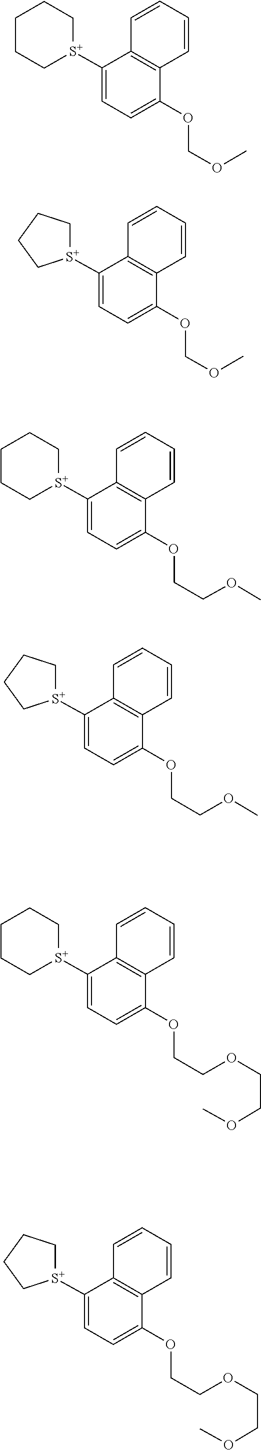 [SMILES: COCOc1ccc([S+]2CCCCC2)c2ccccc12 ; COCOc1ccc([S+]2CCCC2)c2ccccc12 ; COCCOc1ccc([S+]2CCCCC2)c2ccccc12 ; COCCOc1ccc([S+]2CCCC2)c2ccccc12 ; COCCOCCOc1ccc([S+]2CCCCC2)c2ccccc12 ; COCCOCCOc1ccc([S+]2CCCC2)c2ccccc12]

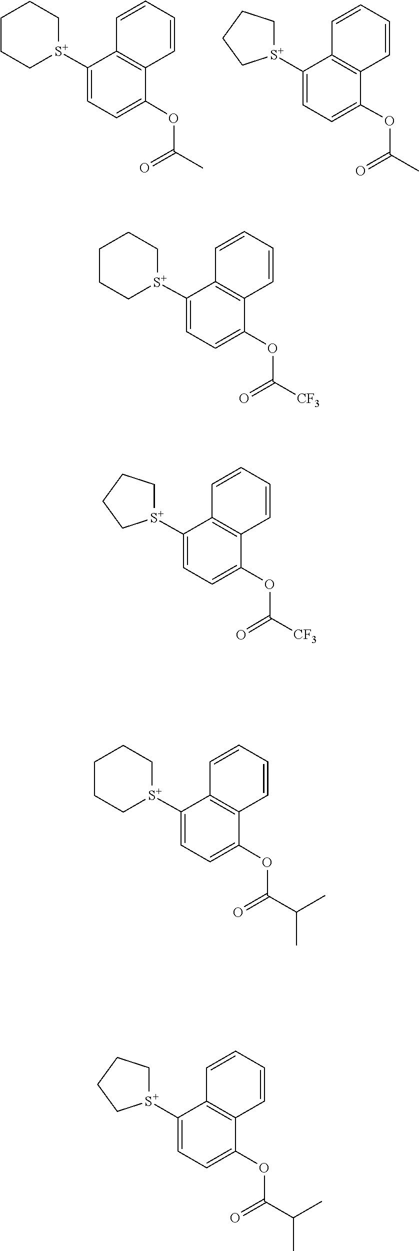 [SMILES: CC(=O)Oc1ccc([S+]2CCCCC2)c2ccccc12 ; CC(=O)Oc1ccc([S+]2CCCC2)c2ccccc12 ; O=C(Oc1ccc([S+]2CCCCC2)c2ccccc12)C(F)(F)F ; O=C(Oc1ccc([S+]2CCCC2)c2ccccc12)C(F)(F)F ; CC(C)C(=O)Oc1ccc([S+]2CCCCC2)c2ccccc12 ; CC(C)C(=O)Oc1ccc([S+]2CCCC2)c2ccccc12]

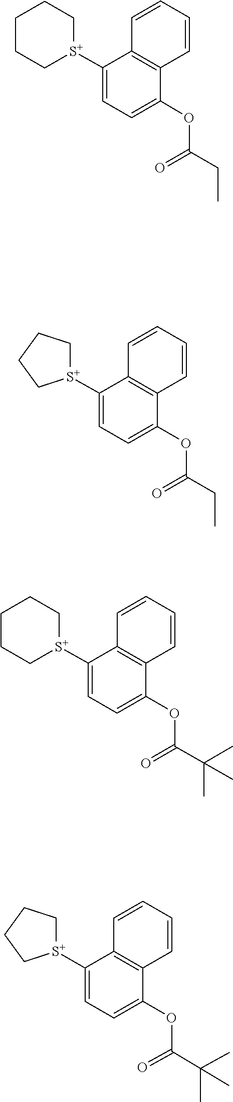 [SMILES: CCC(=O)Oc1ccc([S+]2CCCCC2)c2ccccc12 ; CCC(=O)Oc1ccc([S+]2CCCC2)c2ccccc12 ; CC(C)(C)C(=O)Oc1ccc([S+]2CCCCC2)c2ccccc12 ; CC(C)(C)C(=O)Oc1ccc([S+]2CCCC2)c2ccccc12]

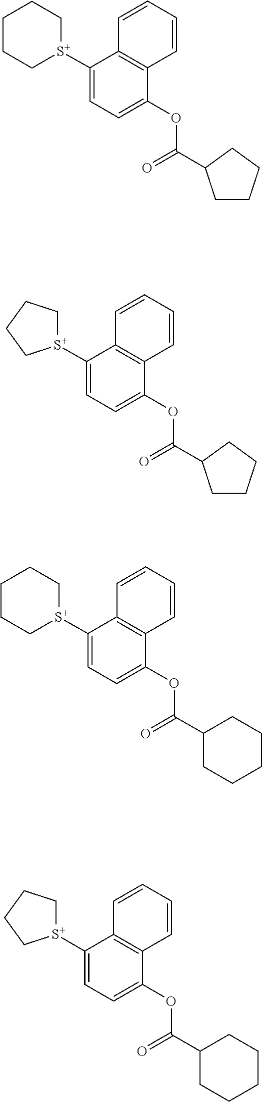 [SMILES: O=C(Oc1ccc([S+]2CCCCC2)c2ccccc12)C1CCCC1 ; O=C(Oc1ccc([S+]2CCCC2)c2ccccc12)C1CCCC1 ; O=C(Oc1ccc([S+]2CCCCC2)c2ccccc12)C1CCCCC1 ; O=C(Oc1ccc([S+]2CCCC2)c2ccccc12)C1CCCCC1]

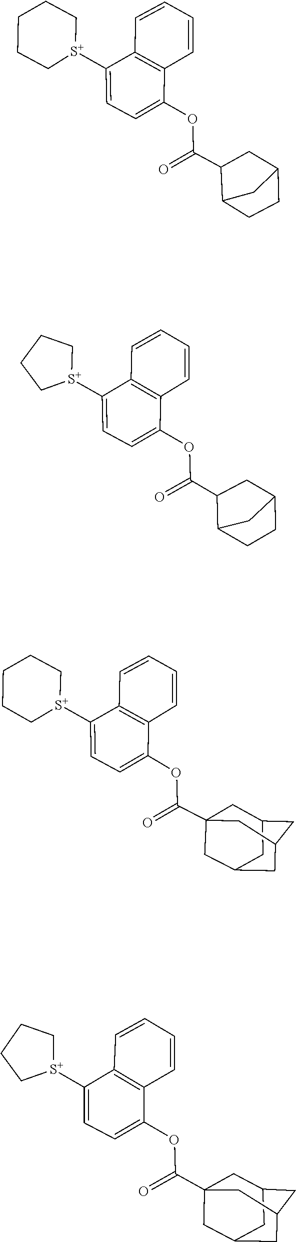 [SMILES: O=C(Oc1ccc([S+]2CCCCC2)c2ccccc12)C1CC2CCC1C2 ; O=C(Oc1ccc([S+]2CCCC2)c2ccccc12)C1CC2CCC1C2 ; O=C(Oc1ccc([S+]2CCCCC2)c2ccccc12)C12CC3CC(CC(C3)C1)C2 ; O=C(Oc1ccc([S+]2CCCC2)c2ccccc12)C12CC3CC(CC(C3)C1)C2]

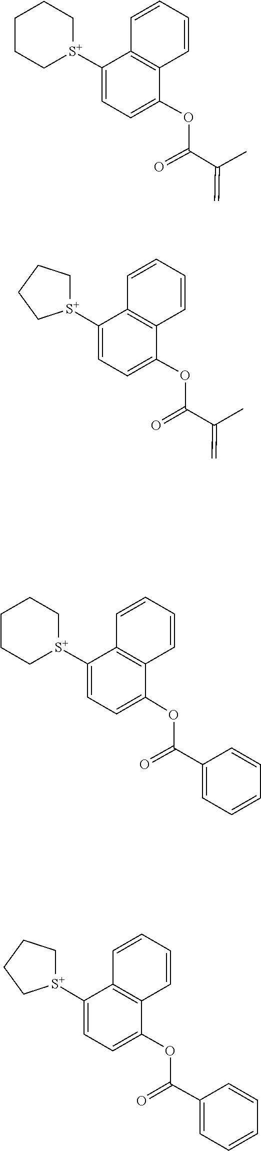 [SMILES: C=C(C)C(=O)Oc1ccc([S+]2CCCCC2)c2ccccc12 ; C=C(C)C(=O)Oc1ccc([S+]2CCCC2)c2ccccc12 ; O=C(Oc1ccc([S+]2CCCCC2)c2ccccc12)c1ccccc1 ; O=C(Oc1ccc([S+]2CCCC2)c2ccccc12)c1ccccc1]

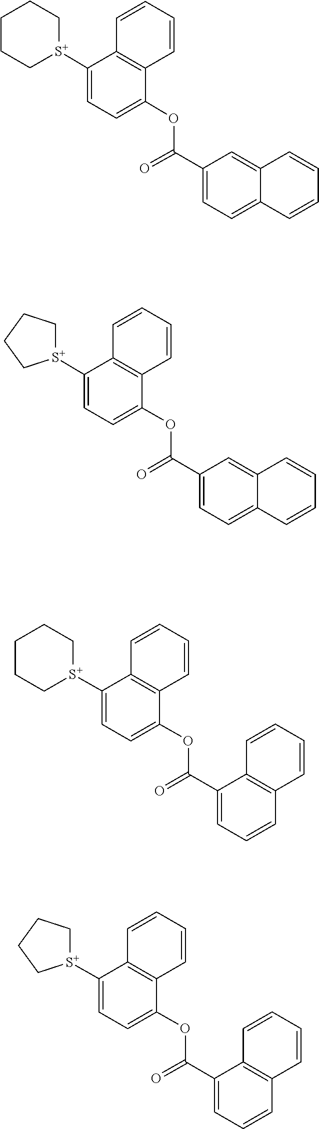 [SMILES: O=C(Oc1ccc([S+]2CCCCC2)c2ccccc12)c1ccc2ccccc2c1 ; O=C(Oc1ccc([S+]2CCCC2)c2ccccc12)c1ccc2ccccc2c1 ; O=C(Oc1ccc([S+]2CCCCC2)c2ccccc12)c1cccc2ccccc12 ; O=C(Oc1ccc([S+]2CCCC2)c2ccccc12)c1cccc2ccccc12]

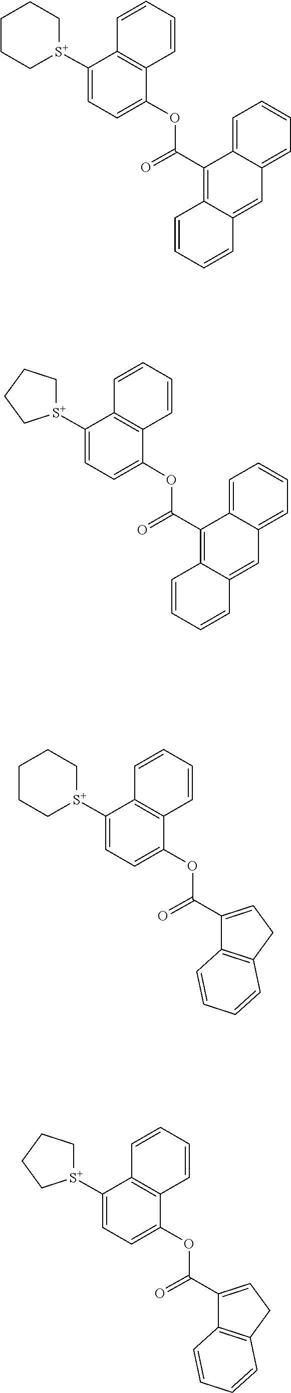 [SMILES: O=C(Oc1ccc([S+]2CCCCC2)c2ccccc12)c1c2ccccc2cc2ccccc12 ; O=C(Oc1ccc([S+]2CCCC2)c2ccccc12)c1c2ccccc2cc2ccccc12 ; O=C(Oc1ccc([S+]2CCCCC2)c2ccccc12)C1=CCc2ccccc21 ; O=C(Oc1ccc([S+]2CCCC2)c2ccccc12)C1=CCc2ccccc21]

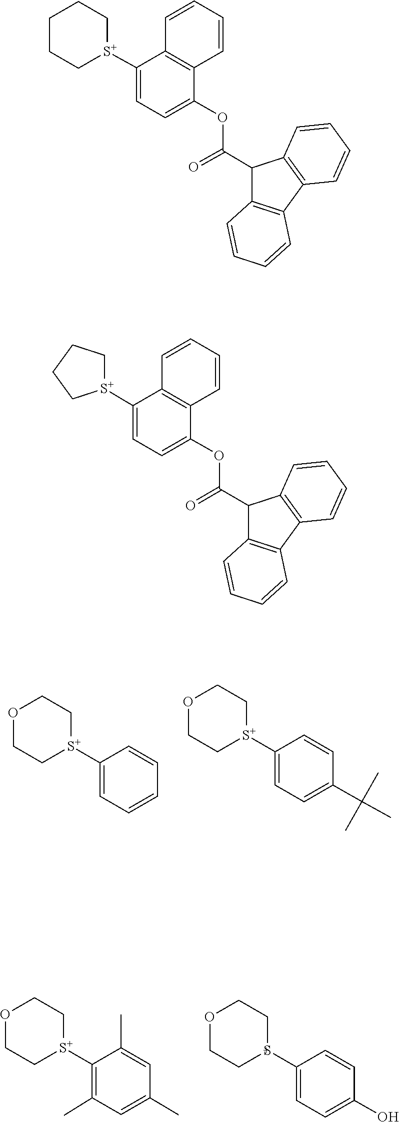 [SMILES: O=C(Oc1ccc([S+]2CCCCC2)c2ccccc12)C1c2ccccc2-c2ccccc21 ; O=C(Oc1ccc([S+]2CCCC2)c2ccccc12)C1c2ccccc2-c2ccccc21 ; c1ccc([S+]2CCOCC2)cc1 ; CC(C)(C)c1ccc([S+]2CCOCC2)cc1 ; Cc1cc(C)c([S+]2CCOCC2)c(C)c1 ; Oc1ccc([S+]2CCOCC2)cc1]

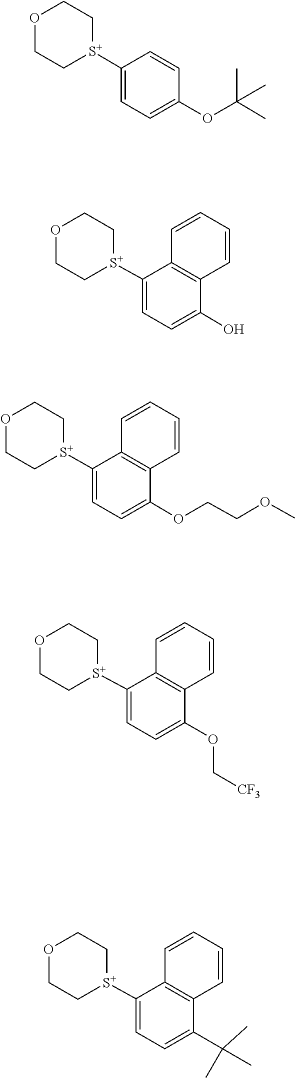 [SMILES: CC(C)(C)Oc1ccc([S+]2CCOCC2)cc1 ; Oc1ccc([S+]2CCOCC2)c2ccccc12 ; COCCOc1ccc([S+]2CCOCC2)c2ccccc12 ; FC(F)(F)COc1ccc([S+]2CCOCC2)c2ccccc12 ; CC(C)(C)c1ccc([S+]2CCOCC2)c2ccccc12]

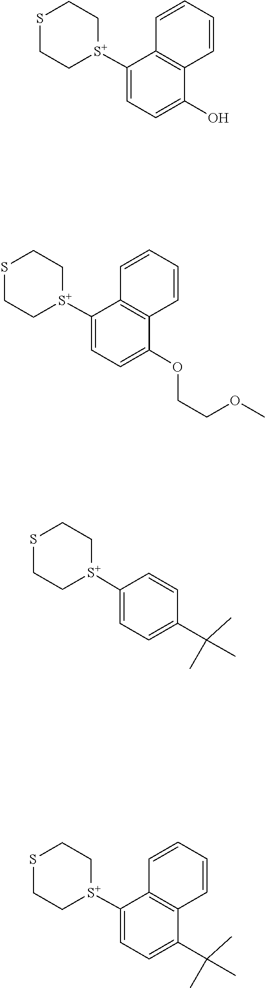 [SMILES: Oc1ccc([S+]2CCSCC2)c2ccccc12 ; COCCOc1ccc([S+]2CCSCC2)c2ccccc12 ; CC(C)(C)c1ccc([S+]2CCSCC2)cc1 ; CC(C)(C)c1ccc([S+]2CCSCC2)c2ccccc12]

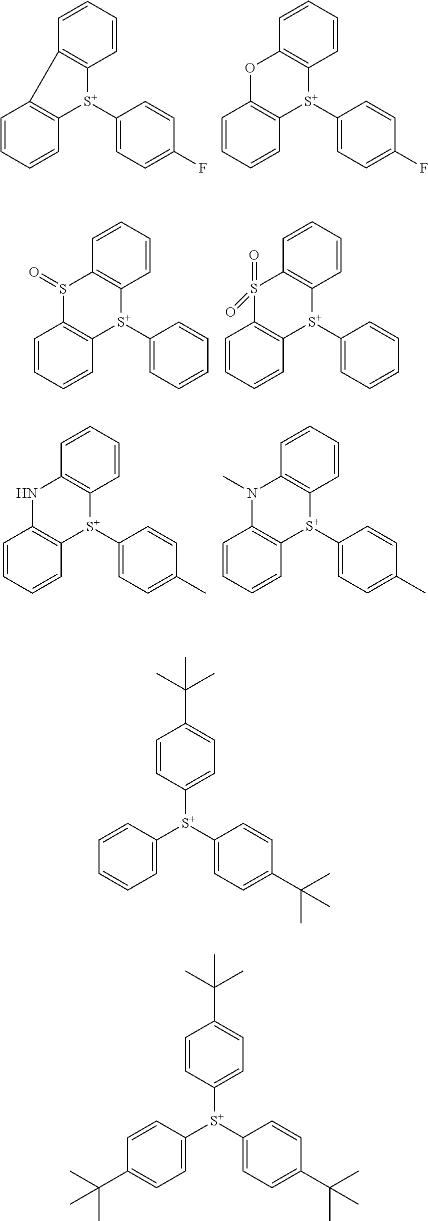

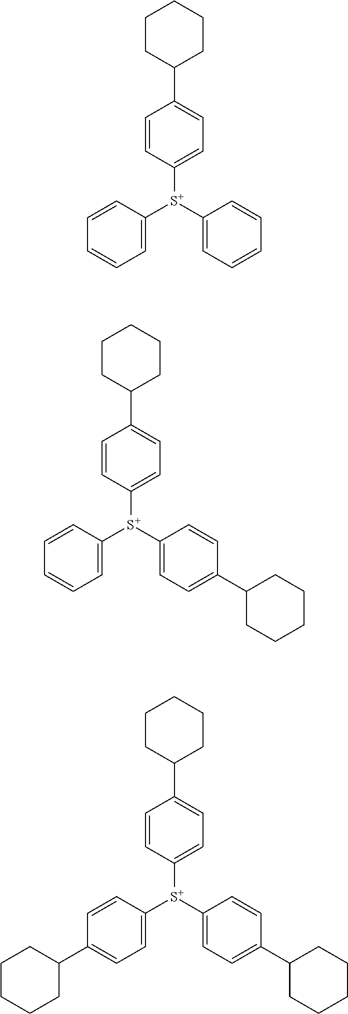 [SMILES: c1ccc([S+](c2ccccc2)c2ccc(C3CCCCC3)cc2)cc1 ; c1ccc([S+](c2ccc(C3CCCCC3)cc2)c2ccc(C3CCCCC3)cc2)cc1 ; c1cc([S+](c2ccc(C3CCCCC3)cc2)c2ccc(C3CCCCC3)cc2)ccc1C1CCCCC1]

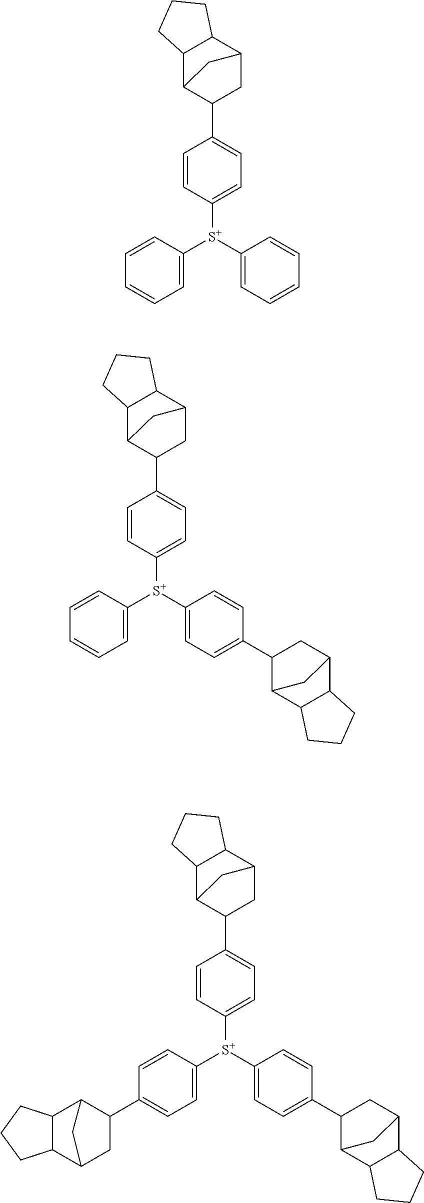 [SMILES: c1ccc([S+](c2ccccc2)c2ccc(C3CC4CC3C3CCCC43)cc2)cc1 ; c1ccc([S+](c2ccc(C3CC4CC3C3CCCC43)cc2)c2ccc(C3CC4CC3C3CCCC43)cc2)cc1 ; c1cc([S+](c2ccc(C3CC4CC3C3CCCC43)cc2)c2ccc(C3CC4CC3C3CCCC43)cc2)ccc1C1CC2CC1C1CCCC21]

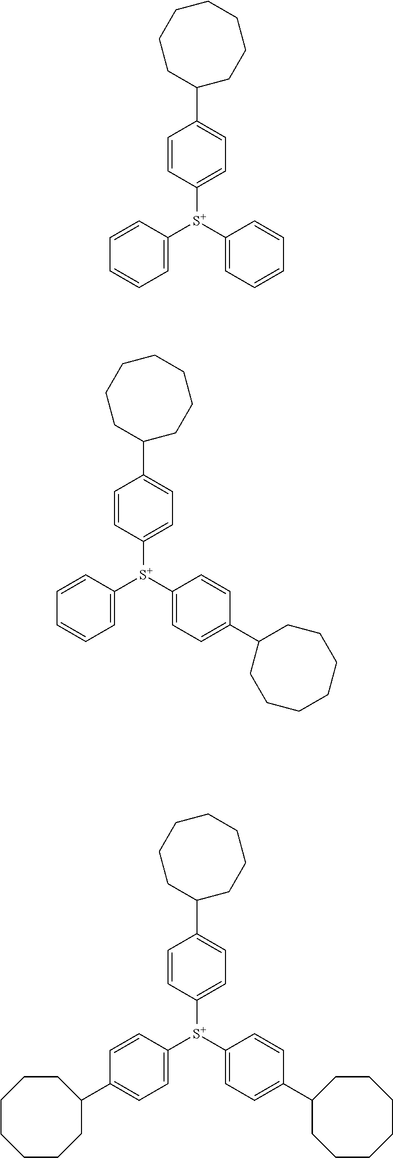 [SMILES: c1ccc([S+](c2ccccc2)c2ccc(C3CCCCCCC3)cc2)cc1 ; c1ccc([S+](c2ccc(C3CCCCCCC3)cc2)c2ccc(C3CCCCCCC3)cc2)cc1 ; c1cc([S+](c2ccc(C3CCCCCCC3)cc2)c2ccc(C3CCCCCCC3)cc2)ccc1C1CCCCCCC1]

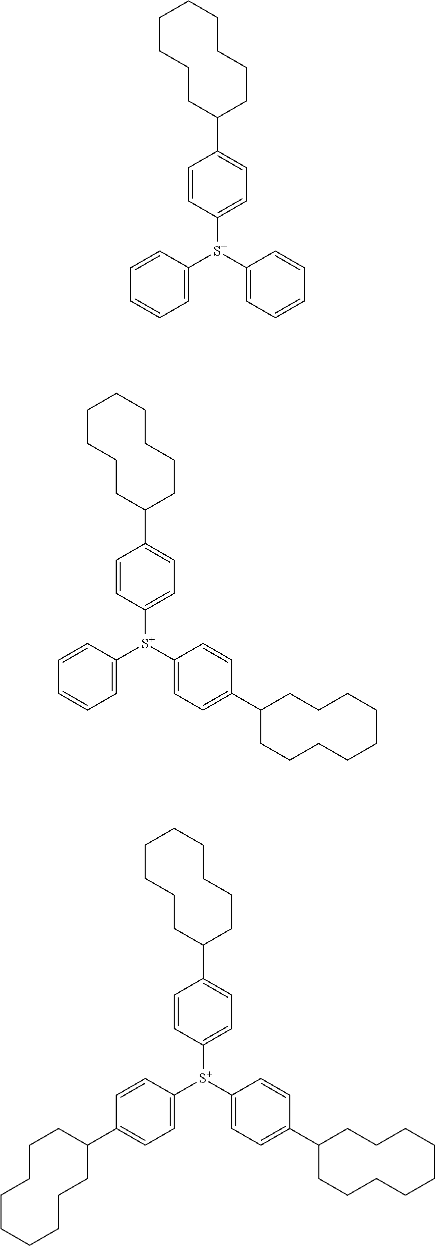 [SMILES: c1ccc([S+](c2ccccc2)c2ccc(C3CCCCCCCCC3)cc2)cc1 ; c1ccc([S+](c2ccc(C3CCCCCCCCC3)cc2)c2ccc(C3CCCCCCCCC3)cc2)cc1 ; c1cc([S+](c2ccc(C3CCCCCCCCC3)cc2)c2ccc(C3CCCCCCCCC3)cc2)ccc1C1CCCCCCCCC1]

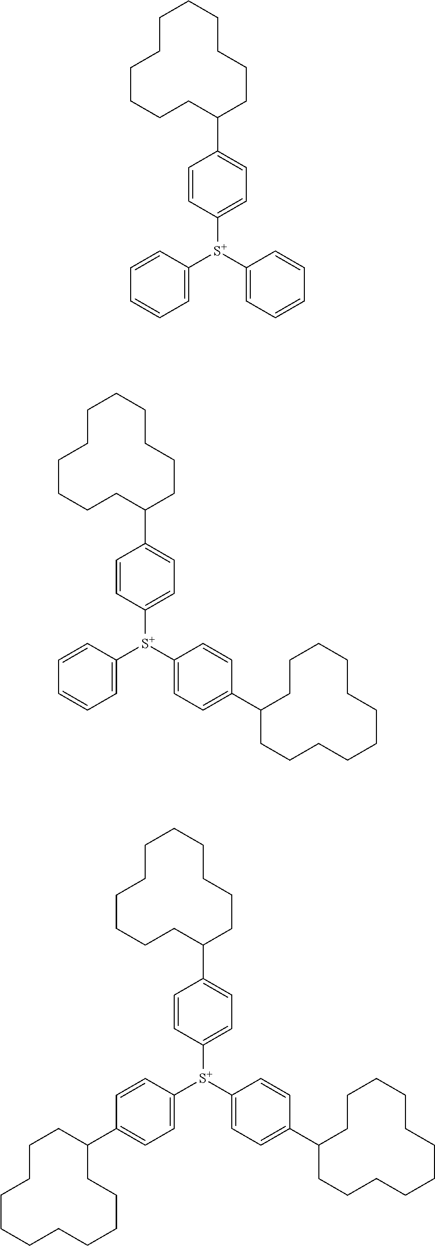 [SMILES: c1ccc([S+](c2ccccc2)c2ccc(C3CCCCCCCCCCC3)cc2)cc1 ; c1ccc([S+](c2ccc(C3CCCCCCCCCCC3)cc2)c2ccc(C3CCCCCCCCCCC3)cc2)cc1 ; c1cc([S+](c2ccc(C3CCCCCCCCCCC3)cc2)c2ccc(C3CCCCCCCCCCC3)cc2)ccc1C1CCCCCCCCCCC1]

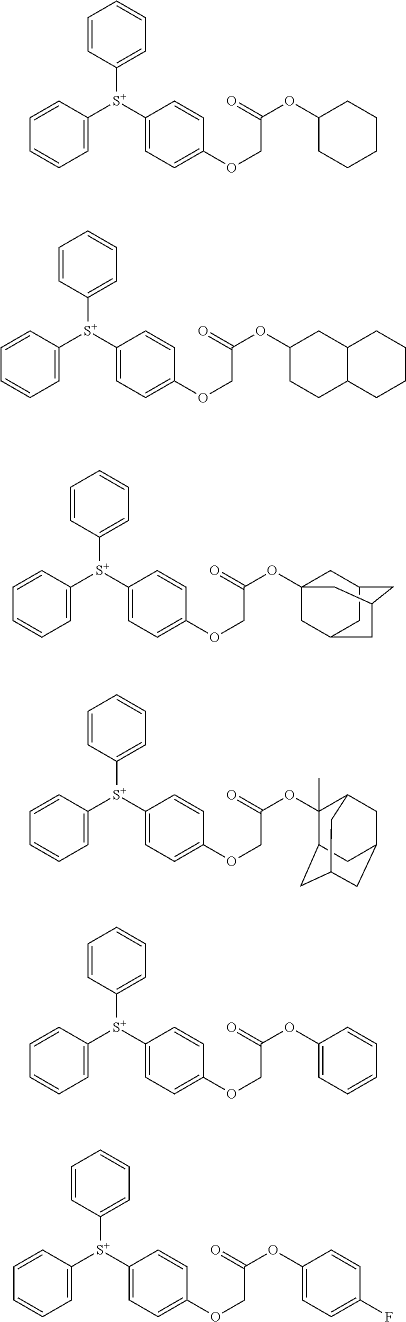 [SMILES: O=C(COc1ccc([S+](c2ccccc2)c2ccccc2)cc1)OC1CCCCC1 ; O=C(COc1ccc([S+](c2ccccc2)c2ccccc2)cc1)OC1CCC2CCCCC2C1 ; O=C(COc1ccc([S+](c2ccccc2)c2ccccc2)cc1)OC12CC3CC(CC(C3)C1)C2 ; CC1(OC(=O)COc2ccc([S+](c3ccccc3)c3ccccc3)cc2)C2CC3CC(C2)CC1C3 ; O=C(COc1ccc([S+](c2ccccc2)c2ccccc2)cc1)Oc1ccccc1 ; O=C(COc1ccc([S+](c2ccccc2)c2ccccc2)cc1)Oc1ccc(F)cc1]

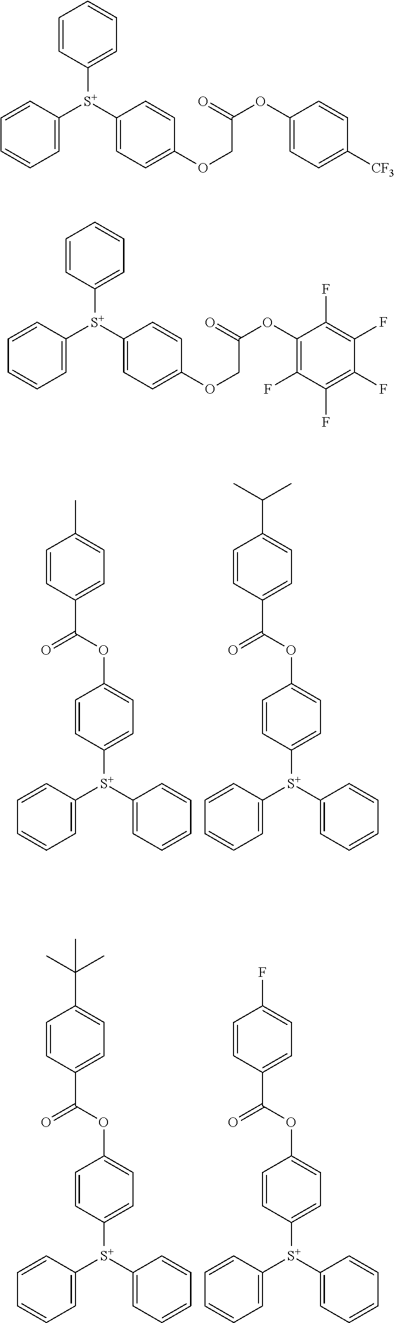 [SMILES: O=C(COc1ccc([S+](c2ccccc2)c2ccccc2)cc1)Oc1ccc(C(F)(F)F)cc1 ; O=C(COc1ccc([S+](c2ccccc2)c2ccccc2)cc1)Oc1c(F)c(F)c(F)c(F)c1F ; Cc1ccc(C(=O)Oc2ccc([S+](c3ccccc3)c3ccccc3)cc2)cc1 ; CC(C)c1ccc(C(=O)Oc2ccc([S+](c3ccccc3)c3ccccc3)cc2)cc1 ; CC(C)(C)c1ccc(C(=O)Oc2ccc([S+](c3ccccc3)c3ccccc3)cc2)cc1 ; O=C(Oc1ccc([S+](c2ccccc2)c2ccccc2)cc1)c1ccc(F)cc1]

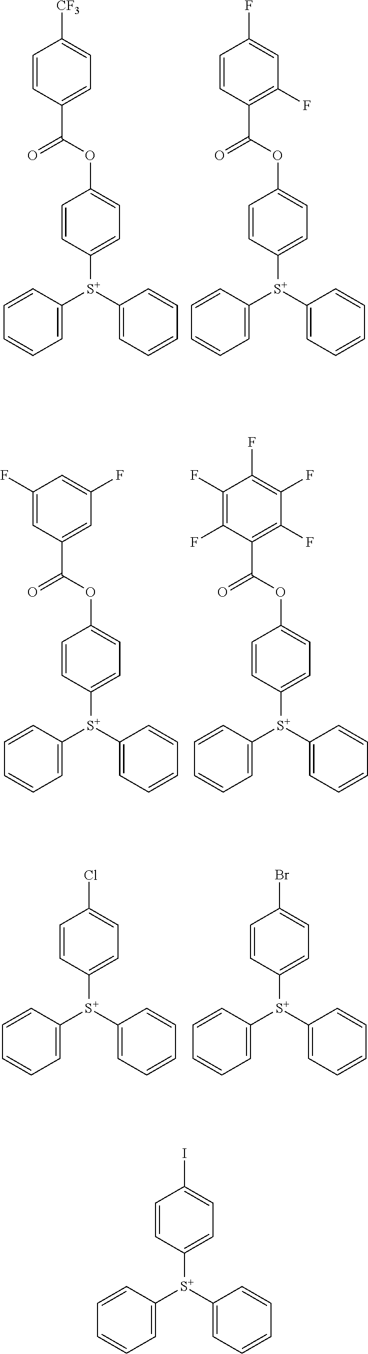

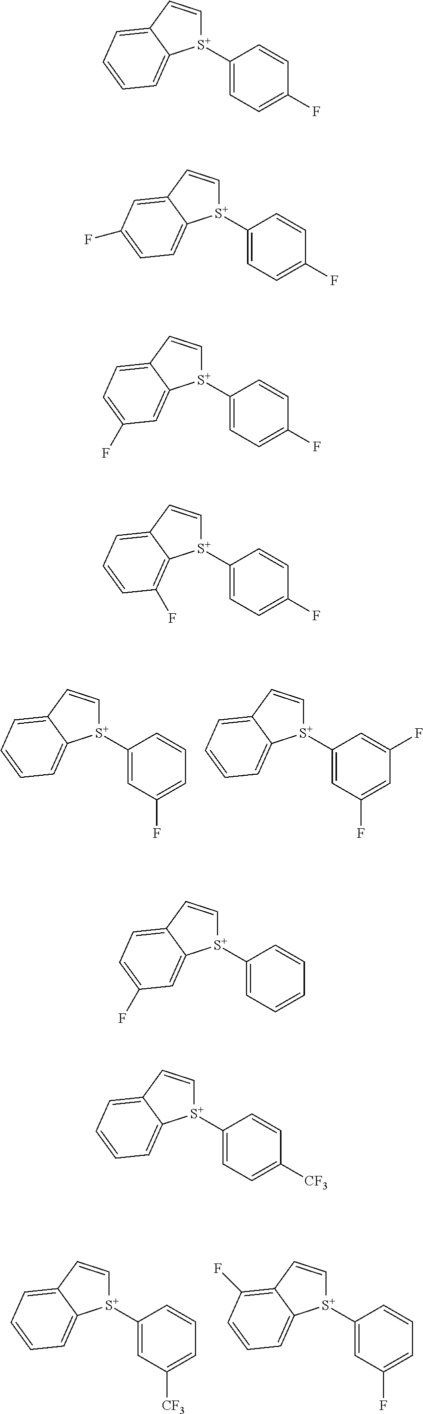

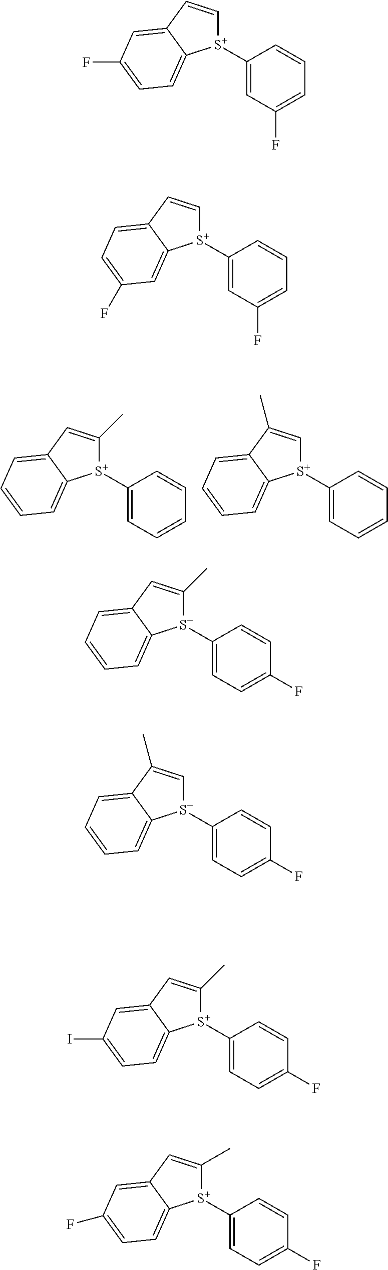

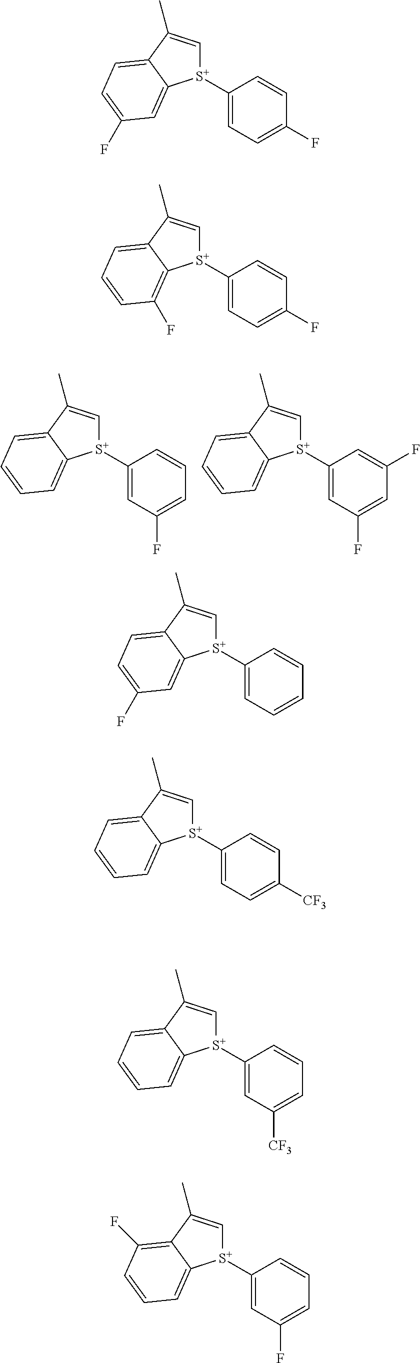

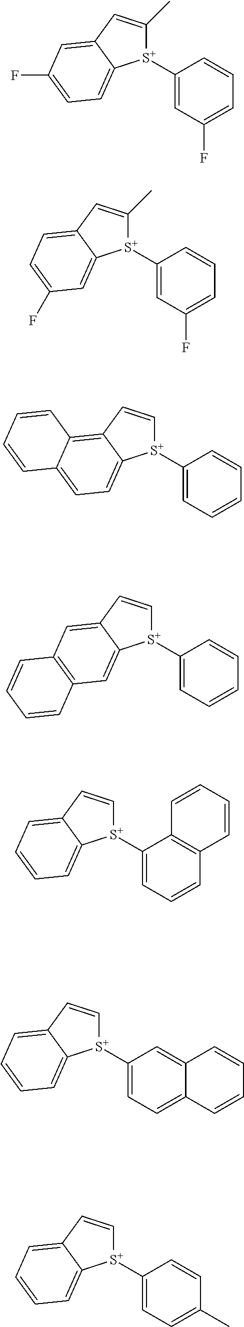

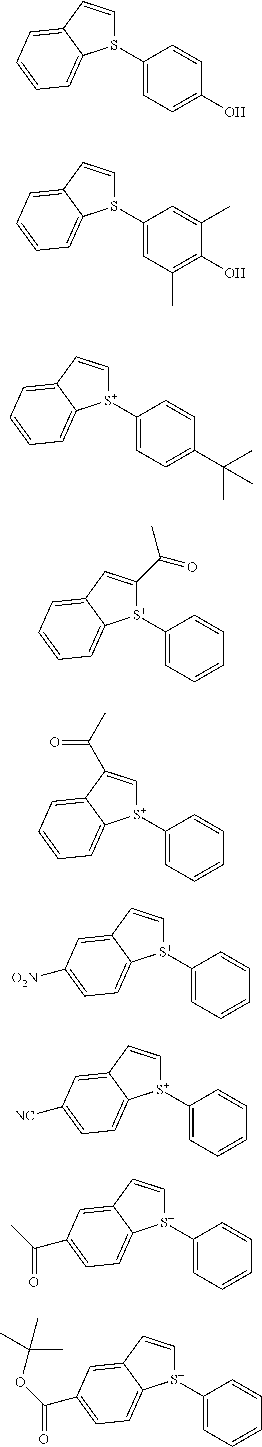

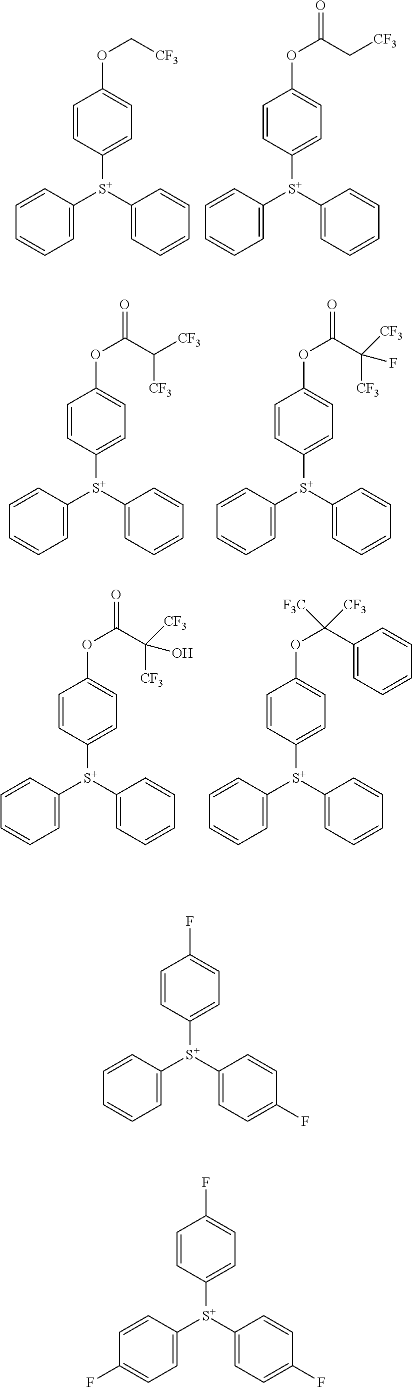

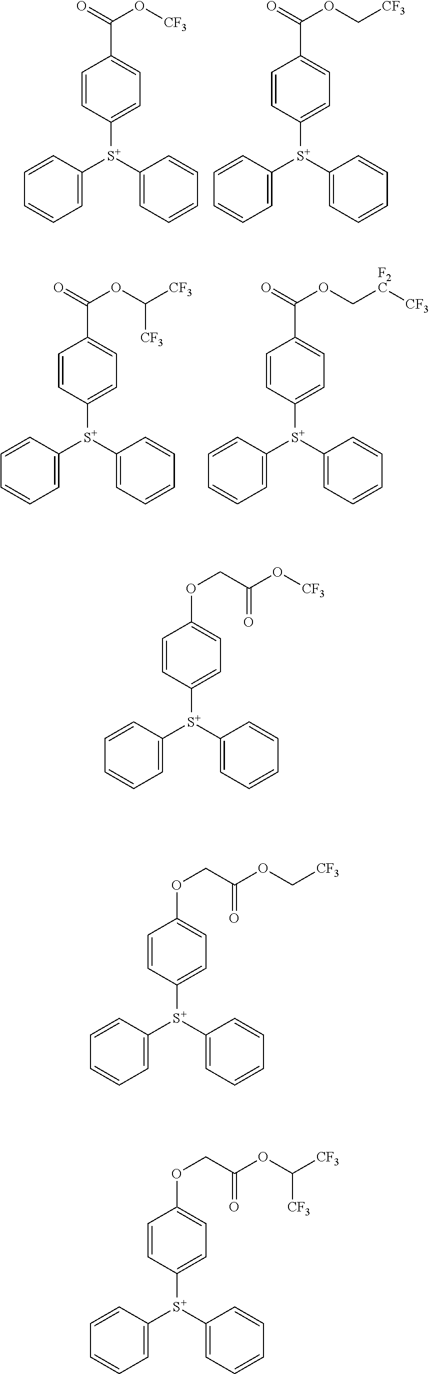

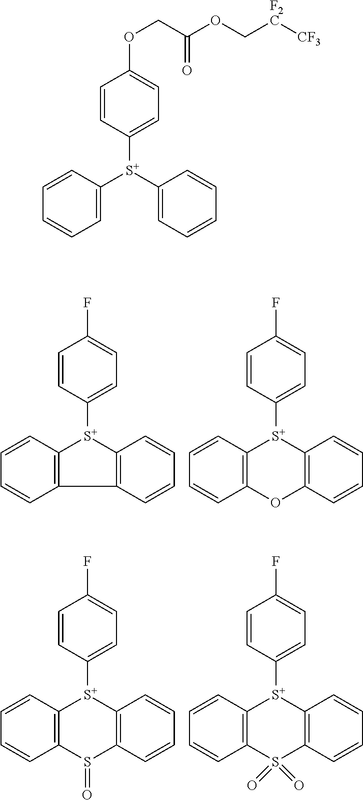 [SMILES: O=C(COc1ccc([S+](c2ccccc2)c2ccccc2)cc1)OCC(F)(F)C(F)(F)F ; Fc1ccc(-[s+]2c3ccccc3c3ccccc32)cc1 ; Fc1ccc([S+]2c3ccccc3Oc3ccccc32)cc1 ; O=S1c2ccccc2[S+](c2ccc(F)cc2)c2ccccc21 ; O=S1(=O)c2ccccc2[S+](c2ccc(F)cc2)c2ccccc21]

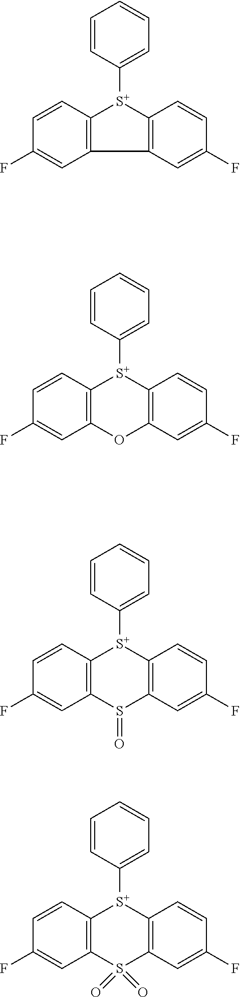 [SMILES: Fc1ccc2c(c1)c1cc(F)ccc1[s+]2-c1ccccc1 ; Fc1ccc2c(c1)Oc1cc(F)ccc1[S+]2c1ccccc1 ; O=S1c2cc(F)ccc2[S+](c2ccccc2)c2ccc(F)cc21 ; O=S1(=O)c2cc(F)ccc2[S+](c2ccccc2)c2ccc(F)cc21]

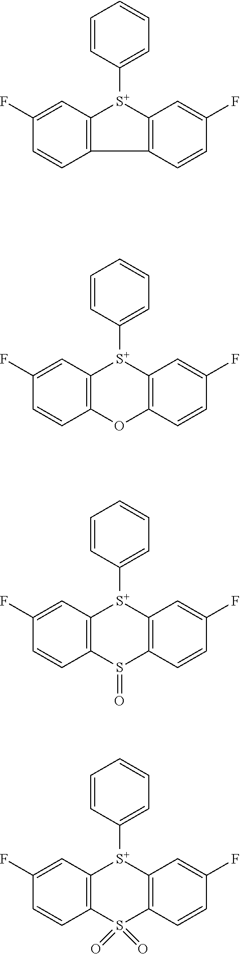 [SMILES: Fc1ccc2c3ccc(F)cc3[s+](-c3ccccc3)c2c1 ; Fc1ccc2c(c1)[S+](c1ccccc1)c1cc(F)ccc1O2 ; O=S1c2ccc(F)cc2[S+](c2ccccc2)c2cc(F)ccc21 ; O=S1(=O)c2ccc(F)cc2[S+](c2ccccc2)c2cc(F)ccc21]

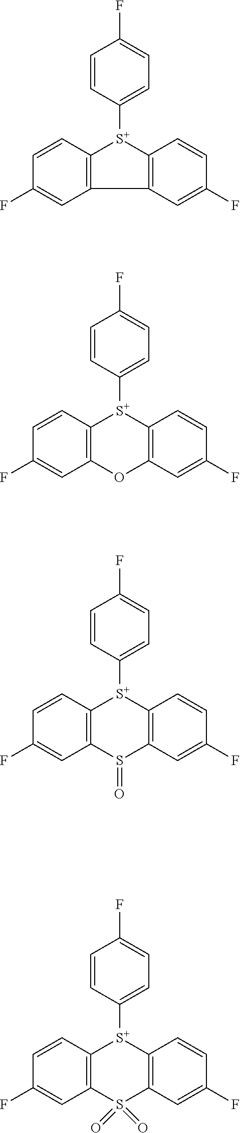 [SMILES: Fc1ccc(-[s+]2c3ccc(F)cc3c3cc(F)ccc32)cc1 ; Fc1ccc([S+]2c3ccc(F)cc3Oc3cc(F)ccc32)cc1 ; O=S1c2cc(F)ccc2[S+](c2ccc(F)cc2)c2ccc(F)cc21 ; O=S1(=O)c2cc(F)ccc2[S+](c2ccc(F)cc2)c2ccc(F)cc21]

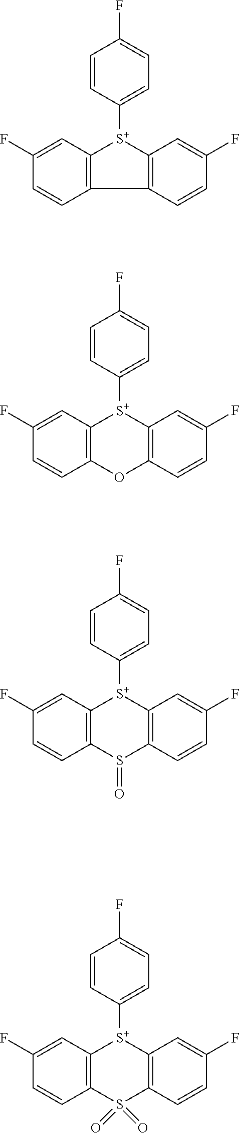 [SMILES: Fc1ccc(-[s+]2c3cc(F)ccc3c3ccc(F)cc32)cc1 ; Fc1ccc([S+]2c3cc(F)ccc3Oc3ccc(F)cc32)cc1 ; O=S1c2ccc(F)cc2[S+](c2ccc(F)cc2)c2cc(F)ccc21 ; O=S1(=O)c2ccc(F)cc2[S+](c2ccc(F)cc2)c2cc(F)ccc21]

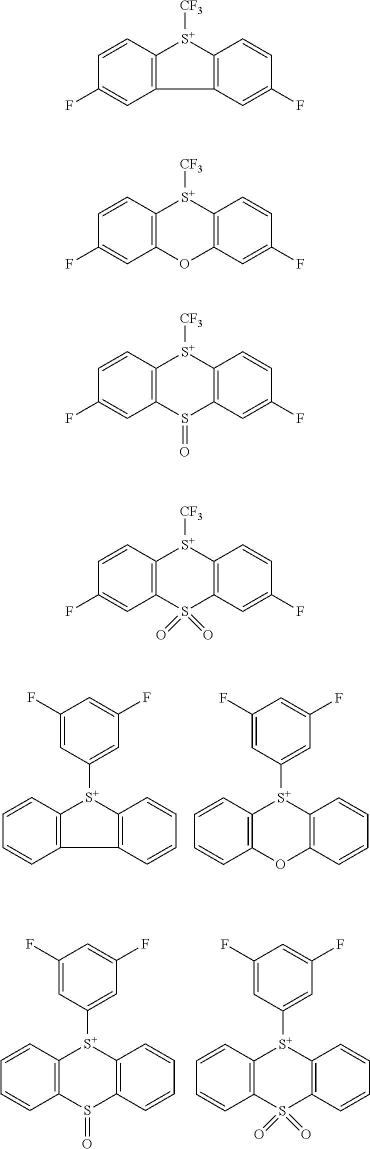

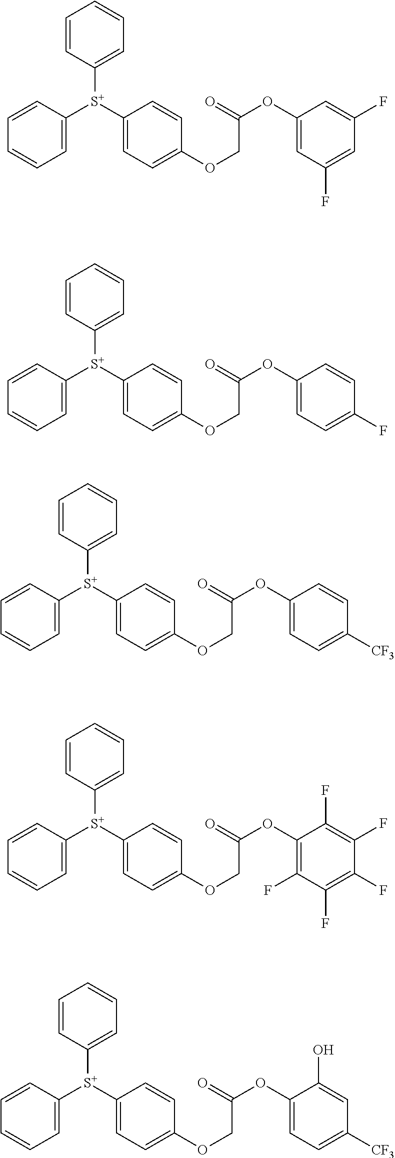 [SMILES: O=C(COc1ccc([S+](c2ccccc2)c2ccccc2)cc1)Oc1cc(F)cc(F)c1 ; O=C(COc1ccc([S+](c2ccccc2)c2ccccc2)cc1)Oc1ccc(F)cc1 ; O=C(COc1ccc([S+](c2ccccc2)c2ccccc2)cc1)Oc1ccc(C(F)(F)F)cc1 ; O=C(COc1ccc([S+](c2ccccc2)c2ccccc2)cc1)Oc1c(F)c(F)c(F)c(F)c1F ; O=C(COc1ccc([S+](c2ccccc2)c2ccccc2)cc1)Oc1ccc(C(F)(F)F)cc1O]

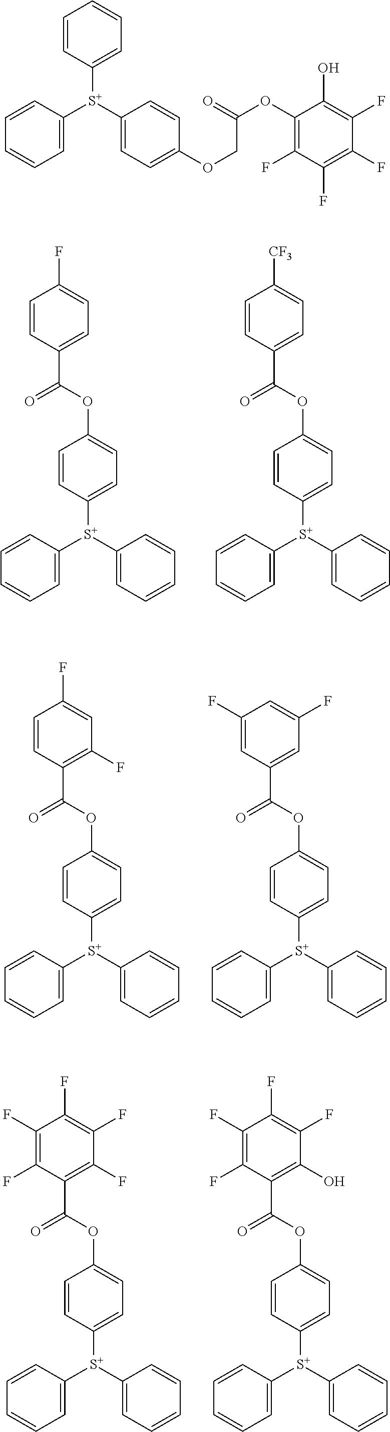

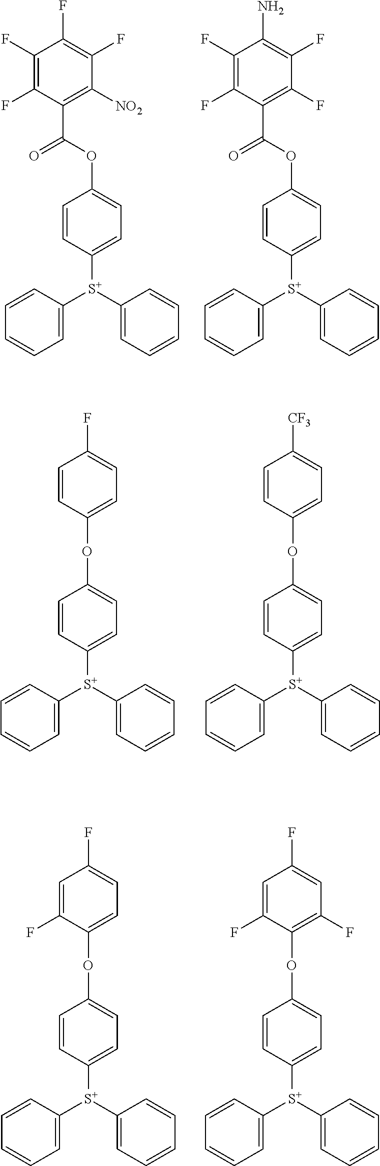 [SMILES: O=C(Oc1ccc([S+](c2ccccc2)c2ccccc2)cc1)c1c(F)c(F)c(F)c(F)c1[N+](=O)[O-] ; Nc1c(F)c(F)c(C(=O)Oc2ccc([S+](c3ccccc3)c3ccccc3)cc2)c(F)c1F ; Fc1ccc(Oc2ccc([S+](c3ccccc3)c3ccccc3)cc2)cc1 ; FC(F)(F)c1ccc(Oc2ccc([S+](c3ccccc3)c3ccccc3)cc2)cc1 ; Fc1ccc(Oc2ccc([S+](c3ccccc3)c3ccccc3)cc2)c(F)c1 ; Fc1cc(F)c(Oc2ccc([S+](c3ccccc3)c3ccccc3)cc2)c(F)c1]

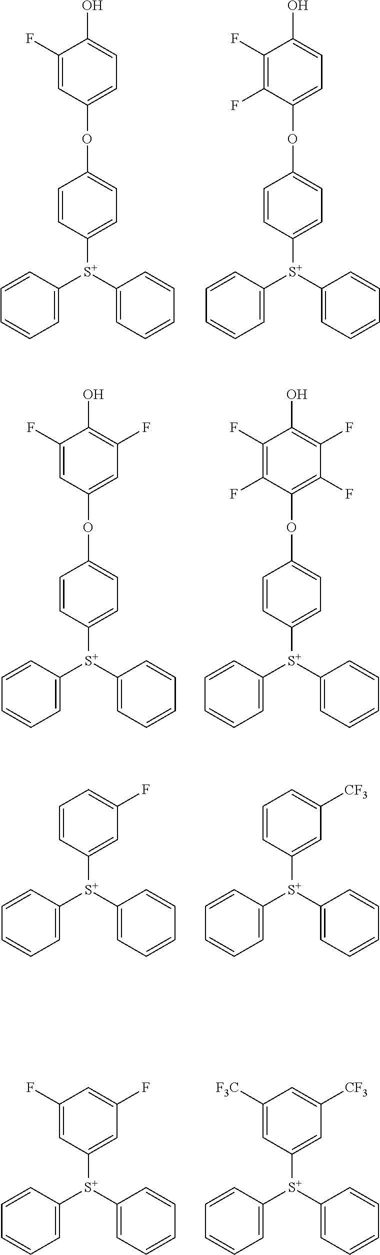

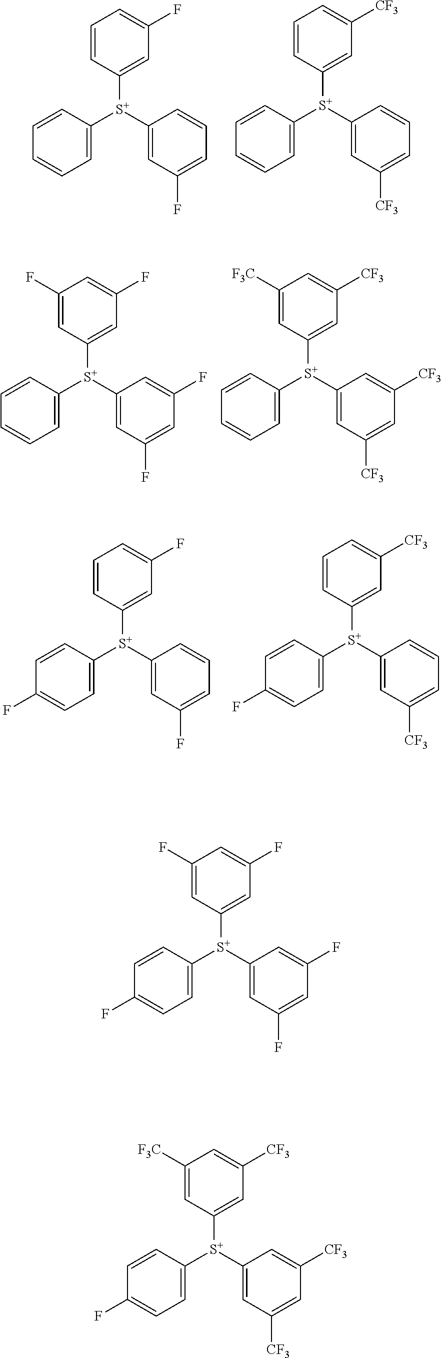

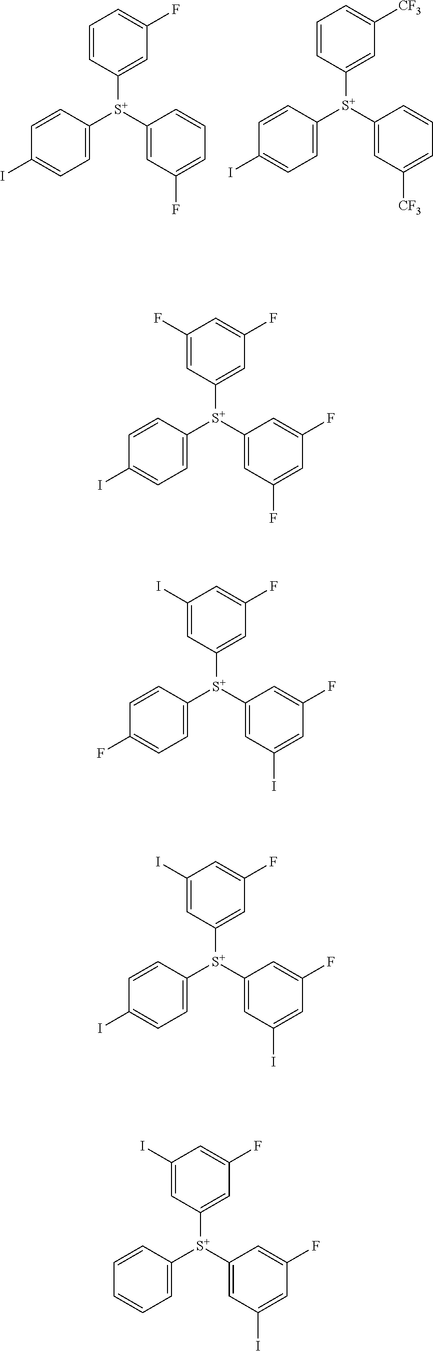 [SMILES: Fc1cccc([S+](c2ccc(I)cc2)c2cccc(F)c2)c1 ; FC(F)(F)c1cccc([S+](c2ccc(I)cc2)c2cccc(C(F)(F)F)c2)c1 ; Fc1cc(F)cc([S+](c2ccc(I)cc2)c2cc(F)cc(F)c2)c1 ; Fc1ccc([S+](c2cc(F)cc(I)c2)c2cc(F)cc(I)c2)cc1 ; Fc1cc(I)cc([S+](c2ccc(I)cc2)c2cc(F)cc(I)c2)c1 ; Fc1cc(I)cc([S+](c2ccccc2)c2cc(F)cc(I)c2)c1]

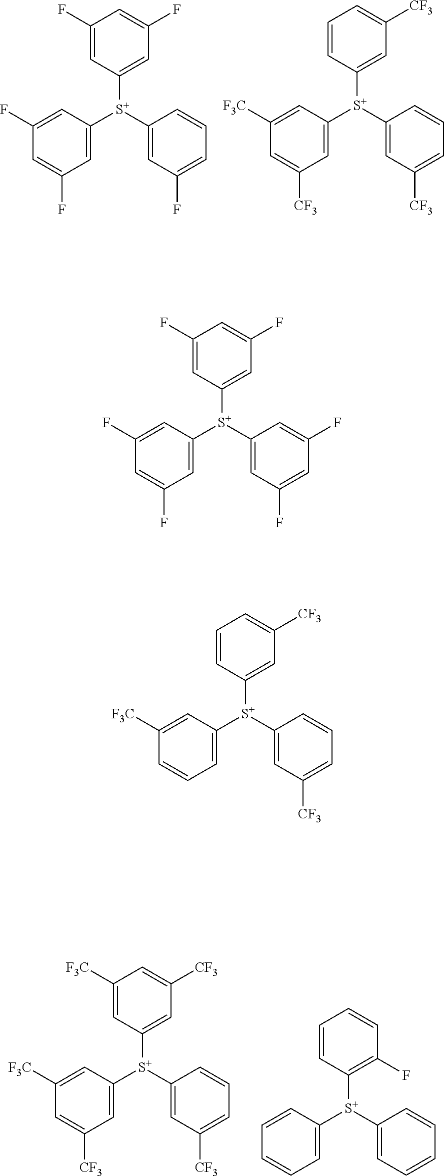 [SMILES: Fc1cccc([S+](c2cc(F)cc(F)c2)c2cc(F)cc(F)c2)c1 ; FC(F)(F)c1cccc([S+](c2cccc(C(F)(F)F)c2)c2cc(C(F)(F)F)cc(C(F)(F)F)c2)c1 ; Fc1cc(F)cc([S+](c2cc(F)cc(F)c2)c2cc(F)cc(F)c2)c1 ; FC(F)(F)c1cccc([S+](c2cccc(C(F)(F)F)c2)c2cccc(C(F)(F)F)c2)c1 ; FC(F)(F)c1cccc([S+](c2cc(C(F)(F)F)cc(C(F)(F)F)c2)c2cc(C(F)(F)F)cc(C(F)(F)F)c2)c1 ; Fc1ccccc1[S+](c1ccccc1)c1ccccc1]

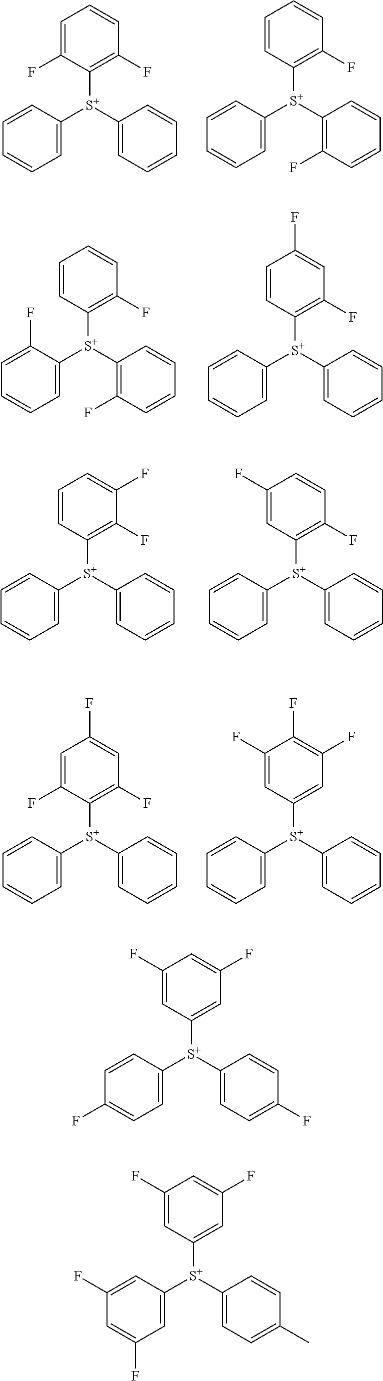

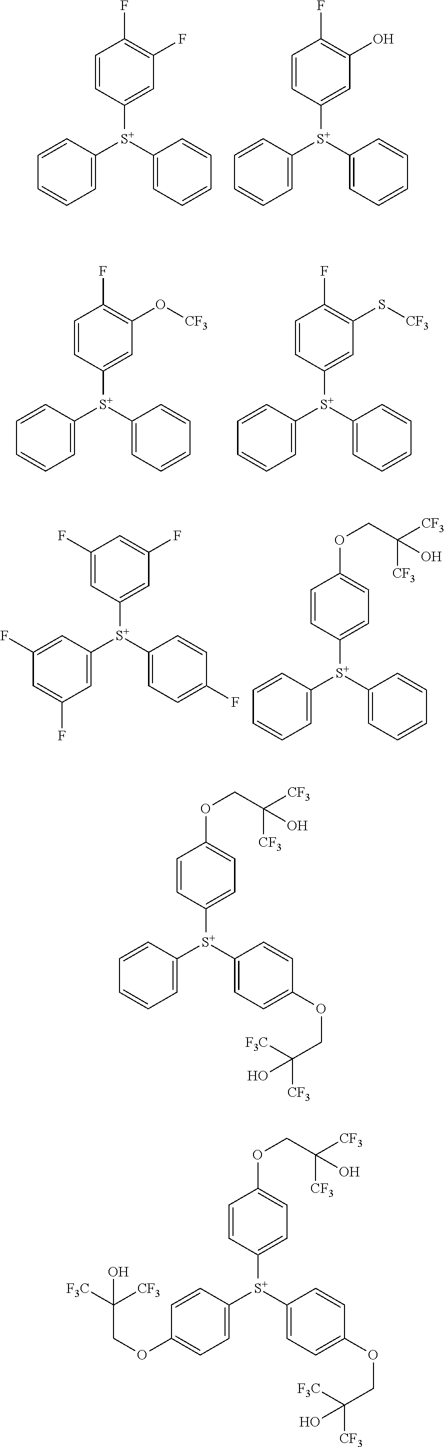

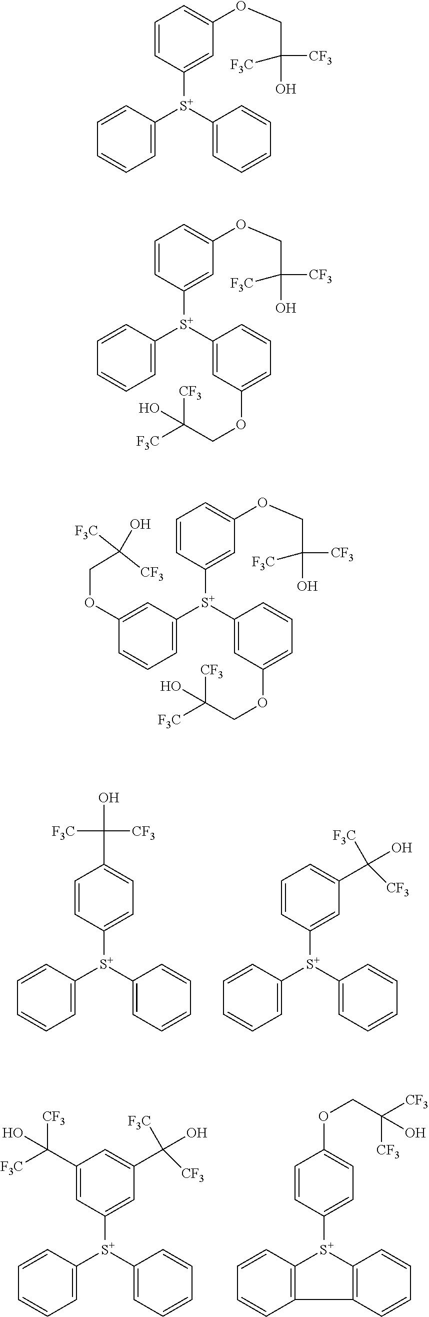

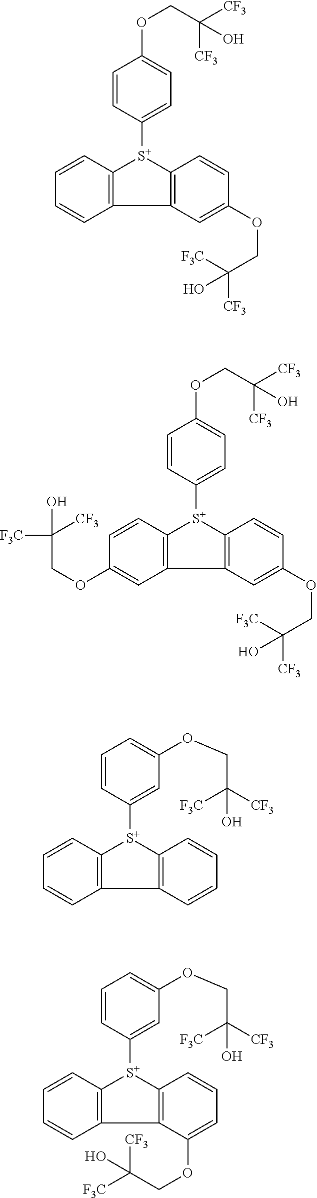 [SMILES: OC(COc1ccc(-[s+]2c3ccccc3c3cc(OCC(O)(C(F)(F)F)C(F)(F)F)ccc32)cc1)(C(F)(F)F)C(F)(F)F ; OC(COc1ccc(-[s+]2c3ccc(OCC(O)(C(F)(F)F)C(F)(F)F)cc3c3cc(OCC(O)(C(F)(F)F)C(F)(F)F)ccc32)cc1)(C(F)(F)F)C(F)(F)F ; OC(COc1cccc(-[s+]2c3ccccc3c3ccccc32)c1)(C(F)(F)F)C(F)(F)F ; OC(COc1cccc(-[s+]2c3ccccc3c3c(OCC(O)(C(F)(F)F)C(F)(F)F)cccc32)c1)(C(F)(F)F)C(F)(F)F]

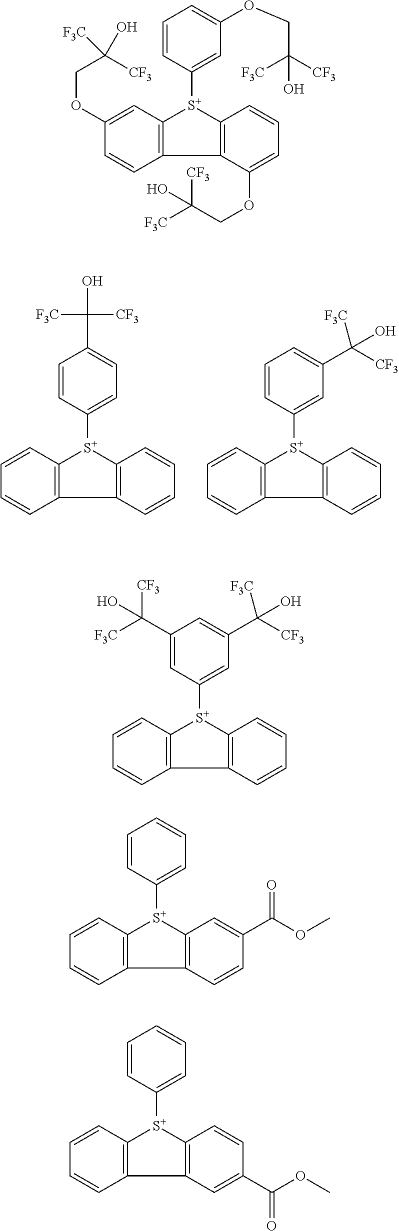 [SMILES: OC(COc1cccc(-[s+]2c3cc(OCC(O)(C(F)(F)F)C(F)(F)F)ccc3c3c(OCC(O)(C(F)(F)F)C(F)(F)F)cccc32)c1)(C(F)(F)F)C(F)(F)F ; OC(c1ccc(-[s+]2c3ccccc3c3ccccc32)cc1)(C(F)(F)F)C(F)(F)F ; OC(c1cccc(-[s+]2c3ccccc3c3ccccc32)c1)(C(F)(F)F)C(F)(F)F ; OC(c1cc(-[s+]2c3ccccc3c3ccccc32)cc(C(O)(C(F)(F)F)C(F)(F)F)c1)(C(F)(F)F)C(F)(F)F ; COC(=O)c1ccc2c3ccccc3[s+](-c3ccccc3)c2c1 ; COC(=O)c1ccc2c(c1)c1ccccc1[s+]2-c1ccccc1]

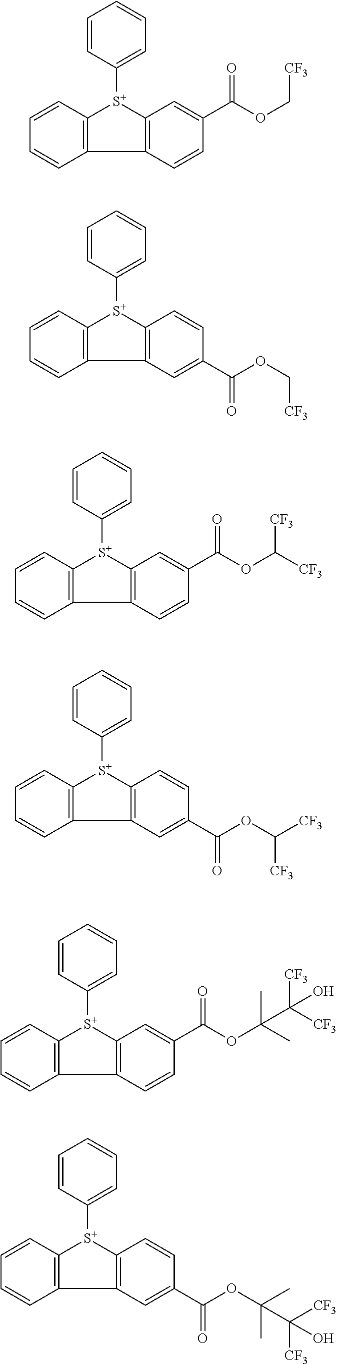 [SMILES: O=C(OCC(F)(F)F)c1ccc2c3ccccc3[s+](-c3ccccc3)c2c1 ; O=C(OCC(F)(F)F)c1ccc2c(c1)c1ccccc1[s+]2-c1ccccc1 ; O=C(OC(C(F)(F)F)C(F)(F)F)c1ccc2c3ccccc3[s+](-c3ccccc3)c2c1 ; O=C(OC(C(F)(F)F)C(F)(F)F)c1ccc2c(c1)c1ccccc1[s+]2-c1ccccc1 ; CC(C)(OC(=O)c1ccc2c3ccccc3[s+](-c3ccccc3)c2c1)C(O)(C(F)(F)F)C(F)(F)F ; CC(C)(OC(=O)c1ccc2c(c1)c1ccccc1[s+]2-c1ccccc1)C(O)(C(F)(F)F)C(F)(F)F]

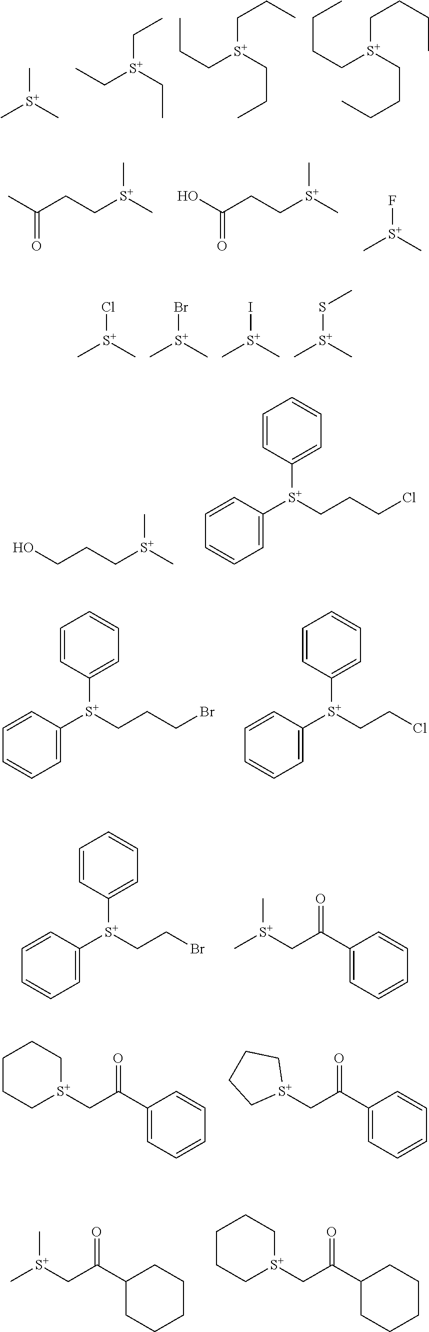

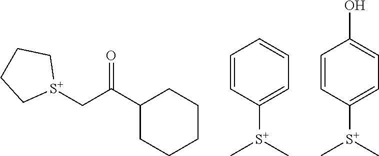

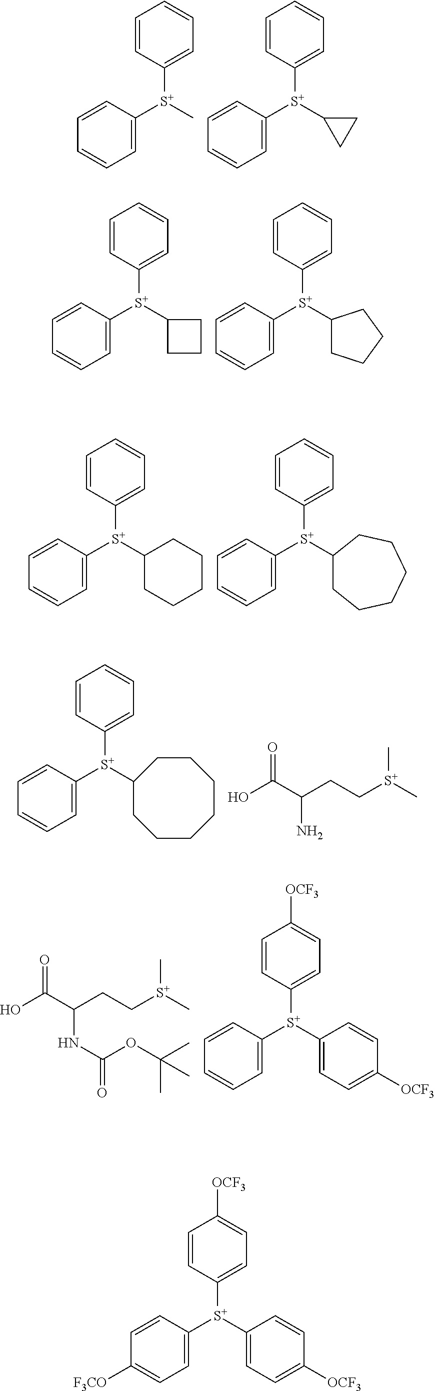

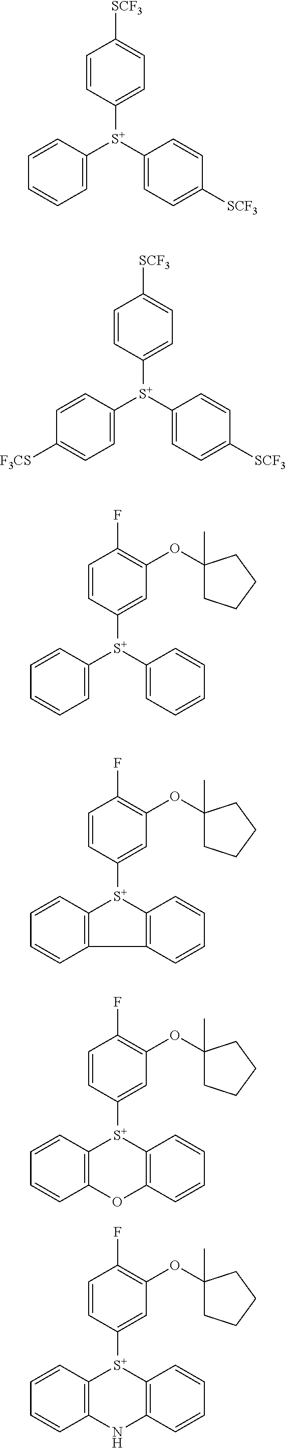

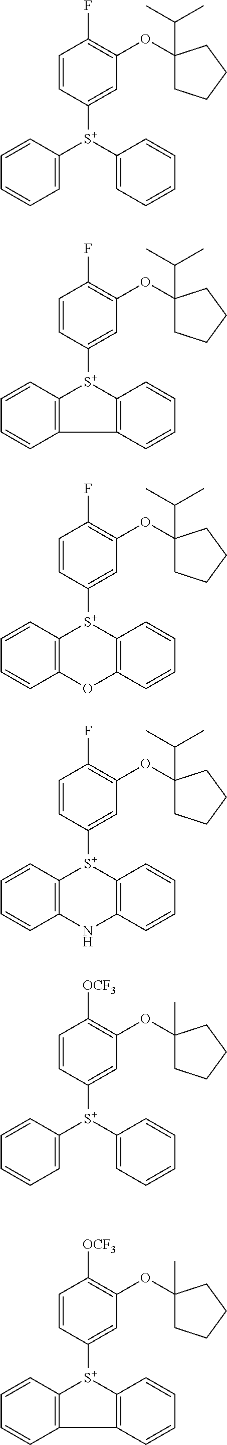 [SMILES: CC(C)C1(Oc2cc([S+](c3ccccc3)c3ccccc3)ccc2F)CCCC1 ; CC(C)C1(Oc2cc(-[s+]3c4ccccc4c4ccccc43)ccc2F)CCCC1 ; CC(C)C1(Oc2cc([S+]3c4ccccc4Oc4ccccc43)ccc2F)CCCC1 ; CC(C)C1(Oc2cc([S+]3c4ccccc4Nc4ccccc43)ccc2F)CCCC1 ; CC1(Oc2cc([S+](c3ccccc3)c3ccccc3)ccc2OC(F)(F)F)CCCC1 ; CC1(Oc2cc(-[s+]3c4ccccc4c4ccccc43)ccc2OC(F)(F)F)CCCC1]

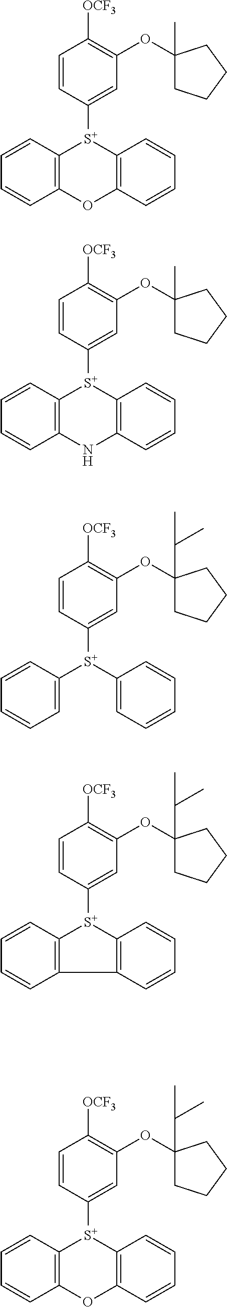 [SMILES: CC1(Oc2cc([S+]3c4ccccc4Oc4ccccc43)ccc2OC(F)(F)F)CCCC1 ; CC1(Oc2cc([S+]3c4ccccc4Nc4ccccc43)ccc2OC(F)(F)F)CCCC1 ; CC(C)C1(Oc2cc([S+](c3ccccc3)c3ccccc3)ccc2OC(F)(F)F)CCCC1 ; CC(C)C1(Oc2cc(-[s+]3c4ccccc4c4ccccc43)ccc2OC(F)(F)F)CCCC1 ; CC(C)C1(Oc2cc([S+]3c4ccccc4Oc4ccccc43)ccc2OC(F)(F)F)CCCC1]

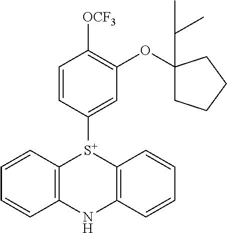 [SMILES: CC(C)C1(Oc2cc([S+]3c4ccccc4Nc4ccccc43)ccc2OC(F)(F)F)CCCC1]

Specific examples of the iodonium cation represented by formula (5-2) include, but are not limited to, those shown below.

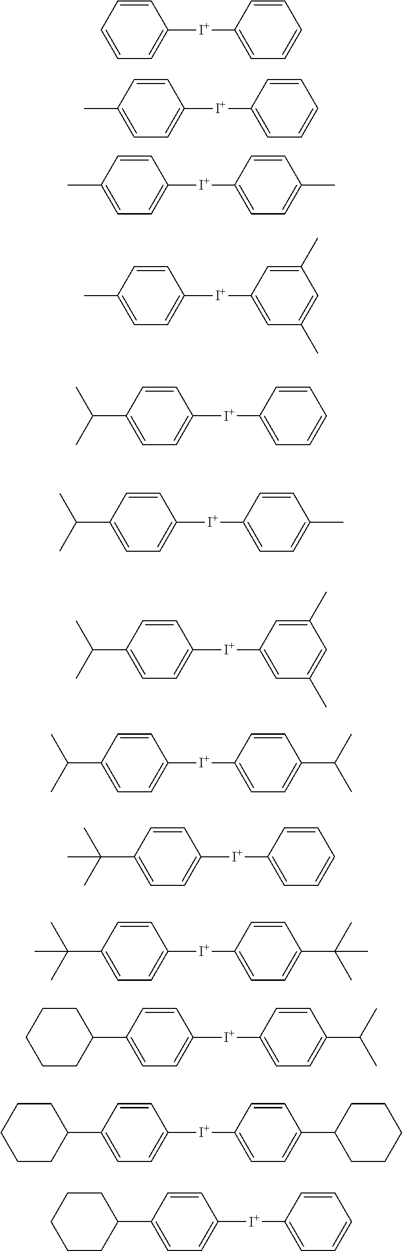

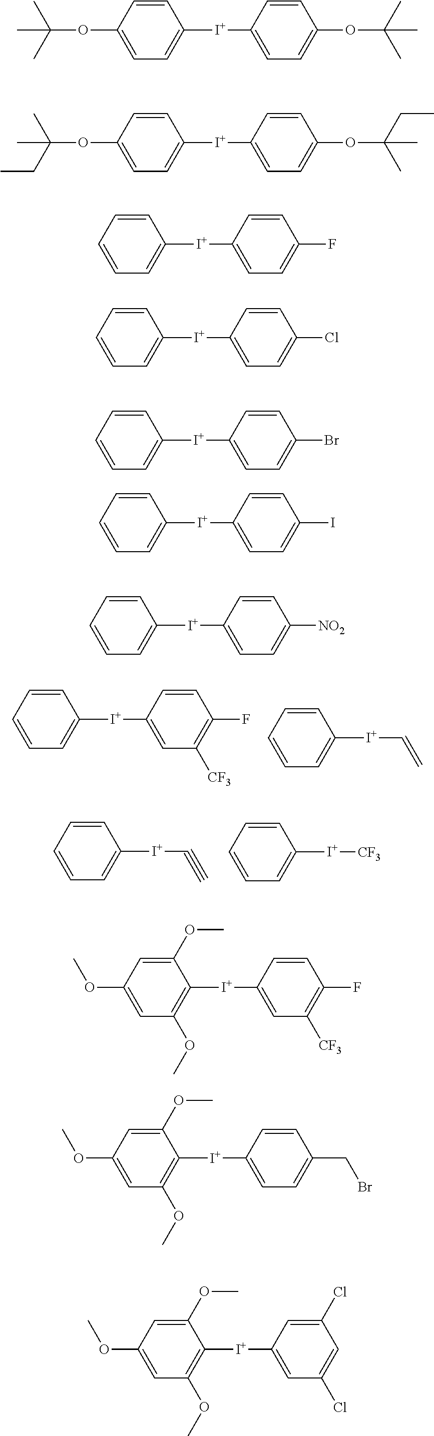

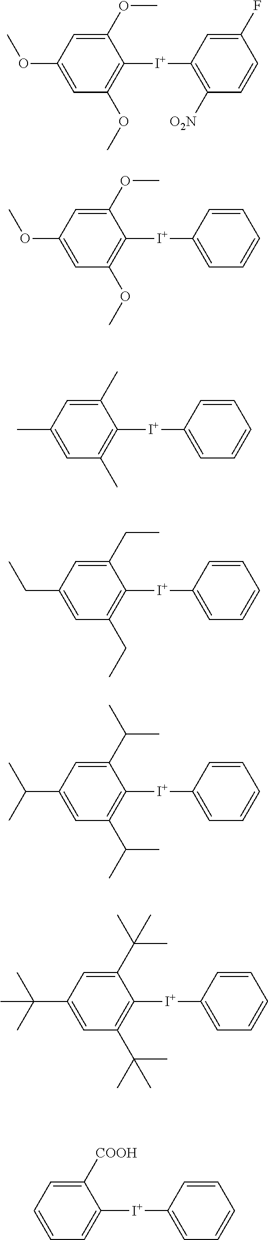

The onium salt compound has, as an anion, a halide ion, a nitrate ion, a hydrogen sulfate ion, a hydrogen carbonate ion, a tetraphenylborate ion, or those represented by any one of the following formulae (5-3) to (5-9).

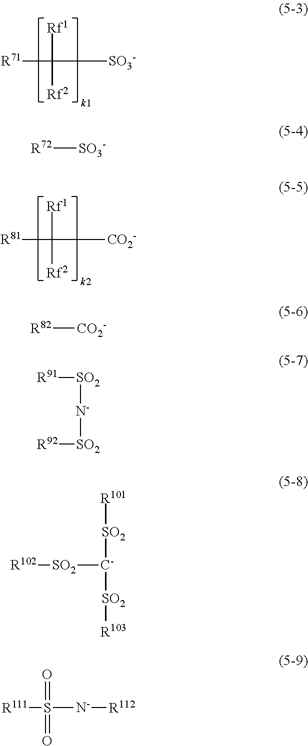

In the formulae (5-3) and (5-5), k1 and k2 each independently represent 1, 2, 3, or 4. Rf¹ and Rf² each independently represent a hydrogen atom, a fluorine atom, or a fluorine-containing alkyl group having 1 to 6 carbon atoms, but all of Rf¹ and Rf² cannot simultaneously represent hydrogen atoms.

In the formula (5-3), R⁷¹ represents a hydrogen atom, a halogen atom, a hydroxy group, or a hydrocarbyl group having 1 to 50 carbon atoms and optionally having a heteroatom.

In the formula (5-4), R⁷² is a hydrogen atom, a halogen atom, a hydroxy group, or a hydrocarbyl group having 1 to 50 carbon atoms and optionally having a heteroatom, provided that this does not include those in which the hydrogen atoms on the carbon atoms at α-position and β position of a sulfo group are substituted with a fluorine atom or a fluoroalkyl group.

In the formula (5-5), R⁸¹ represents a hydrogen atom, a halogen atom, a hydroxy group, or a hydrocarbyl group having 1 to 50 carbon atoms and optionally having a heteroatom.

In the formula (5-6), R⁸² represents a hydrogen atom, a halogen atom, a hydroxy group, or a hydrocarbyl group having 1 to 50 carbon atoms which may contain a heteroatom, provided that this does not include those in which the hydrogen atoms on the carbon atoms at α-position and β position of a carboxy group are substituted with a fluorine atom or a fluoroalkyl group.

In the formula (5-7), R⁹¹ and R⁹² each independently represent a hydrocarbyl group having 1 to 50 carbon atoms and optionally having a heteroatom.

In the formula (5-8), R¹⁰¹ to R¹⁰³ each independently represent a hydrocarbyl group having 1 to 50 carbon atoms and optionally having a heteroatom.

In the formula (5-9), R¹¹¹ is a fluorine atom or a fluorinated hydrocarbyl group having 1 to 10 carbon atoms, which may contain a hydroxy group, an ether bond, or an ester bond. R¹¹² is a hydrogen atom or a hydrocarbyl group having 1 to 20 carbon atoms and optionally having a hydroxy group, an ether bond, or an ester bond. R¹¹¹ and R¹¹² may be bonded to each other to form a ring together with the atoms to which they are bonded.

The anion of the onium salt compound is preferably a halide ion, a nitrate ion, or an anion represented by any one of the formulae (5-3) to (5-9), and more preferably a halide ion, a nitrate ion, or an anion represented by the formula (5-4), (5-6), or (5-8).

The hydrocarbyl groups having 1 to 50 carbon atoms and represented by R⁷¹, R⁷², R⁸¹, R⁸², R⁹¹, R⁹², R¹⁰¹, R¹⁰² and R¹⁰³ may be saturated or unsaturated, and may be linear, branched or cyclic. Specific examples thereof include alkyl groups having 1 to 50 carbon atoms, such as a methyl group, an ethyl group, a propyl group, an isopropyl group, an n-butyl group, a sec-butyl group, a tert-butyl group, a tert-pentyl group, an n-pentyl group, an n-hexyl group, an n-octyl group, a 2-ethylhexyl group, an n-nonyl group, and an n-decyl; cyclic saturated hydrocarbyl group having 3 to 50 carbon atoms, such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decyl group, an adamantyl group, and an adamantylmethyl group; alkenyl groups having 2 to 30 carbon atoms, such as a vinyl group, a 1-propenyl group, a 2-propenyl group, a butenyl group, and a hexenyl groups; cyclic unsaturated hydrocarbyl groups having 3 to 30 carbon atoms, such as a cyclohexenyl group; aryl groups having 6 to 50 carbon atoms, such as a phenyl group, a naphthyl group, and an anthracenyl group; and groups obtained by combining these groups. Furthermore, part or all of the hydrogen atoms of the hydrocarbyl group may be substituted with a group containing a heteroatom such as an oxygen atom, a sulfur atom, a nitrogen atom or a halogen atom, or part of the —CH₂— constituting the hydrocarbyl group may be substituted with a group containing a heteroatom, such as an oxygen atom, a sulfur atom, or a nitrogen atom, and the resulting hydrocarbyl group may have a hydroxy group, a cyano group, a halogen atom, a carbonyl group, an ether bond, a thioether bond, an ester bond, a sulfonate ester bond, a carbonate bond, a carbamate bond, a lactone ring, a sultone ring, a carboxylic acid anhydride (—C(═O)—O—C(═O)—), or the like.

The fluorinated hydrocarbyl group having 1 to 10 carbon atoms and represented by R¹¹¹ is a group in which part or all of the hydrogen atoms of a hydrocarbyl group having 1 to 10 carbon atoms are substituted with a fluorine atom. The hydrocarbyl group having 1 to 10 carbon atoms may be saturated or unsaturated and may be linear, branched, or cyclic. Specific examples thereof include those having 1 to 10 carbon atoms among the examples of the hydrocarbyl groups having 1 to 50 carbon atoms and represented by R⁷¹, R⁷², R⁸¹, R⁸², R⁹¹, R⁹², R¹⁰¹, R¹⁰², and R¹⁰³.

The hydrocarbyl group having 1 to 20 carbon atoms and represented by R¹¹² may be saturated or unsaturated and may be linear, branched or cyclic. Specific examples thereof include those having 1 to 20 carbon atoms among the examples of the hydrocarbyl groups having 1 to 50 carbon atoms and represented by R⁷¹, R⁷², R⁸¹, R⁸², R⁹¹, R⁹², R¹⁰¹, R¹⁰², and R¹⁰³.

The anion represented by any one of the formulae (5-3) to (5-9) has a polymerizable functional group in its structure and may have a hydrocarbyl group having 2 to 50 carbon atoms and optionally having a heteroatom. Specific examples thereof include, but are not limited to, those shown below.

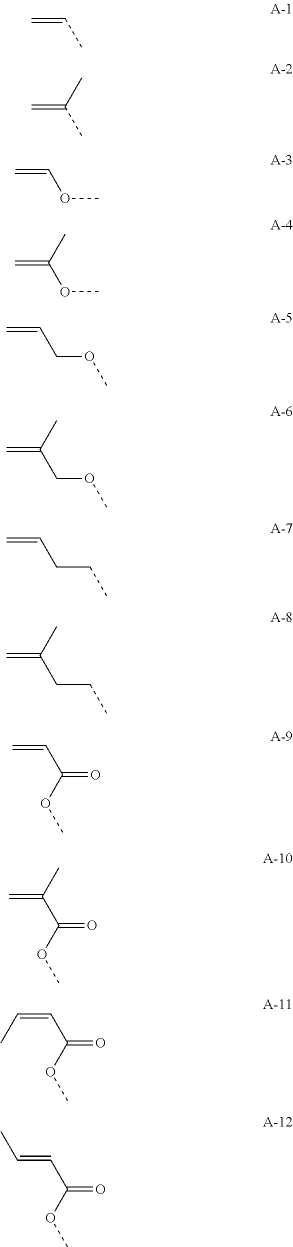

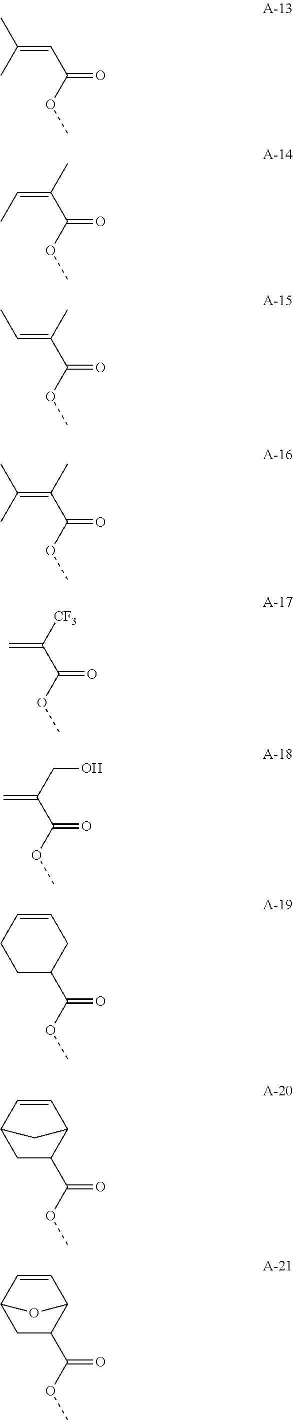

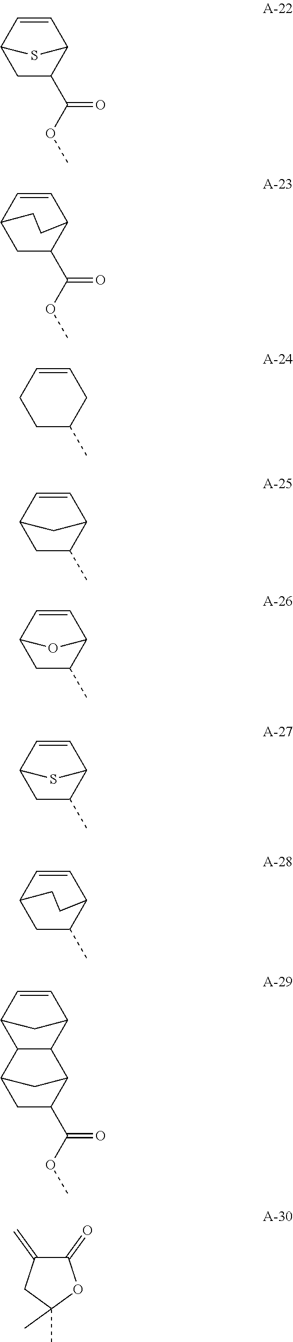

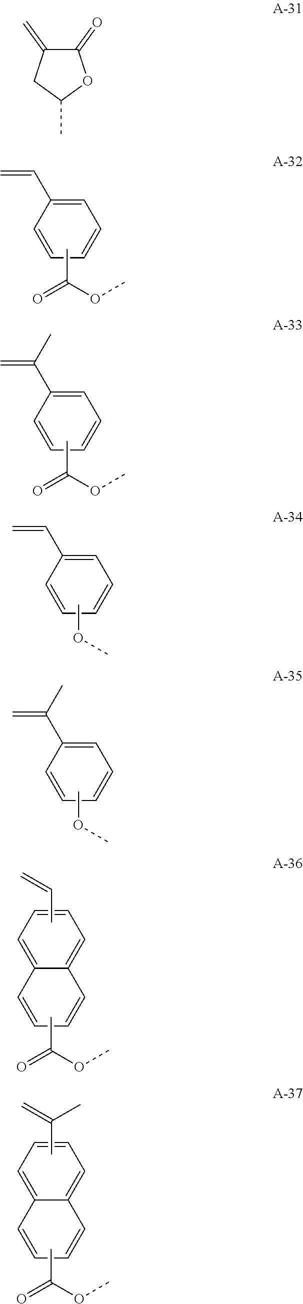

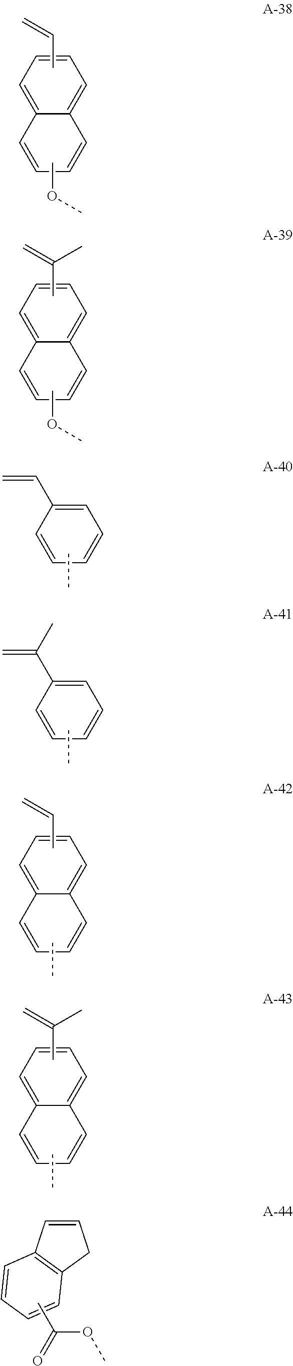

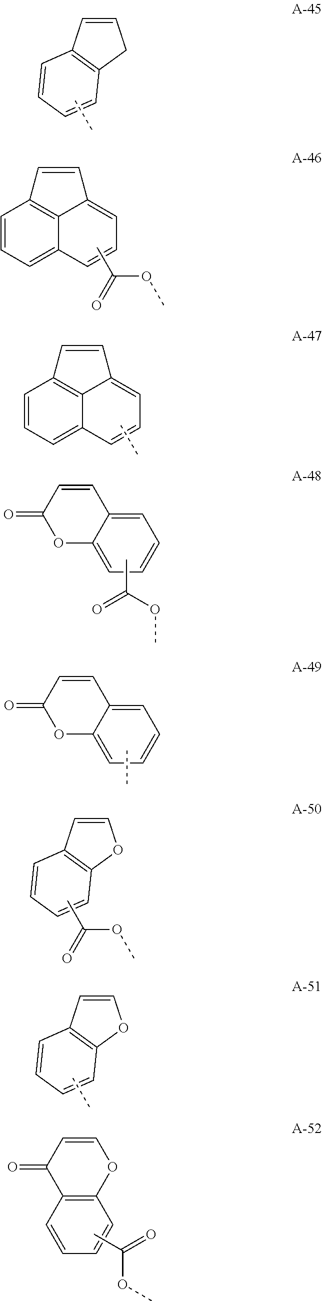

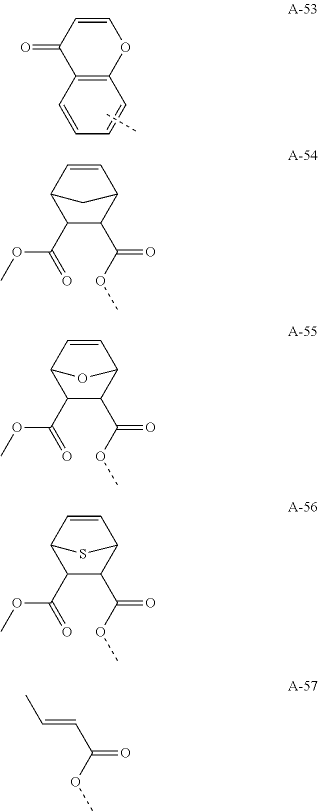

Specific examples of the anion represented by formula (5-3) include, but are not limited to, those shown below. In the following formulae, Ac represents an acetyl group, and Rf¹ represents the same as defined above.

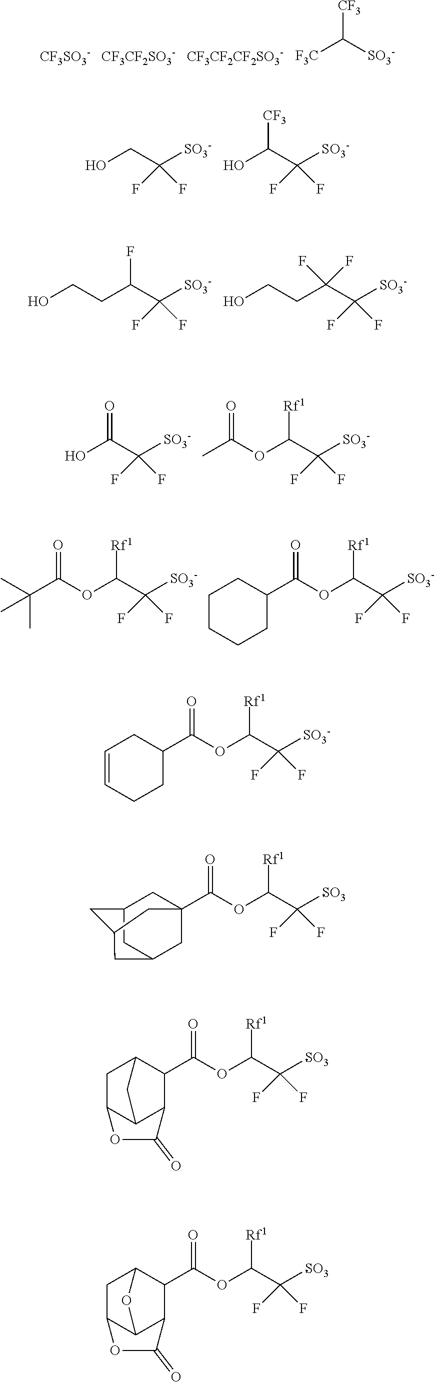

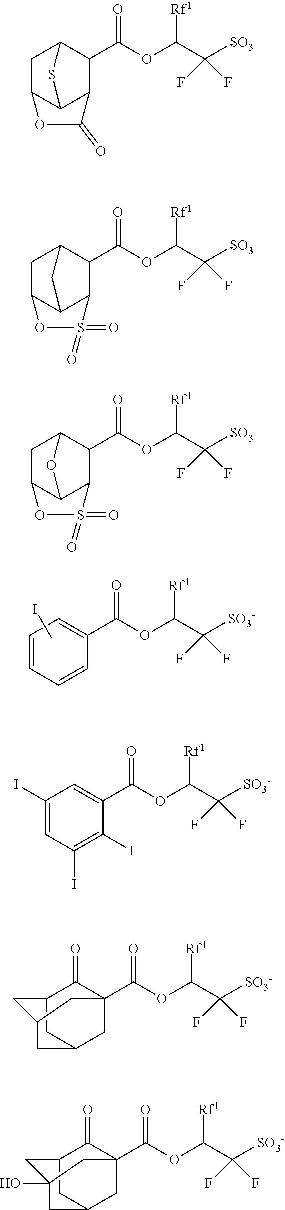

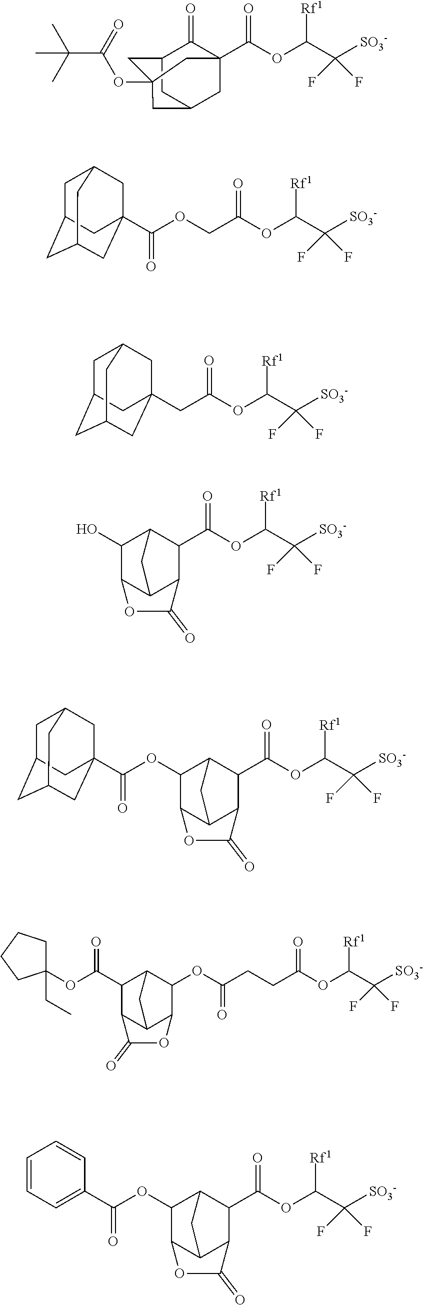

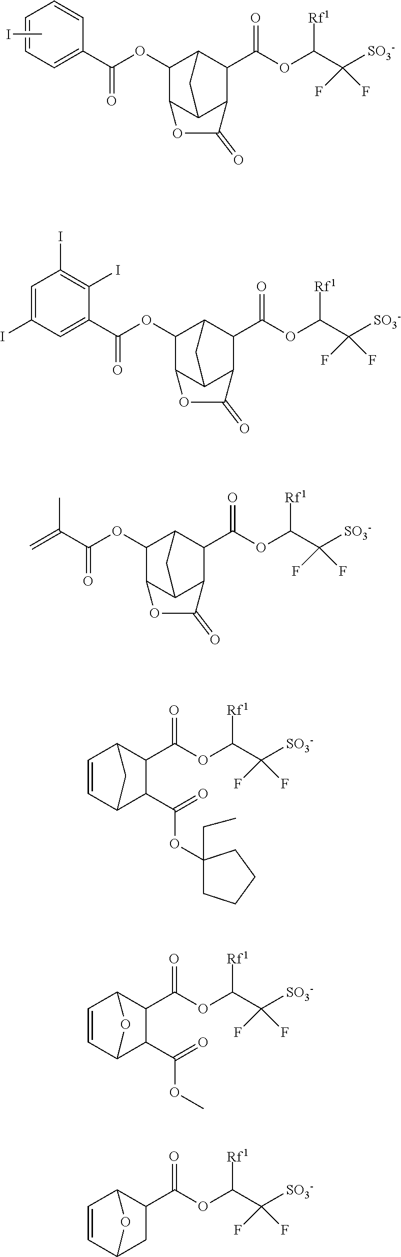

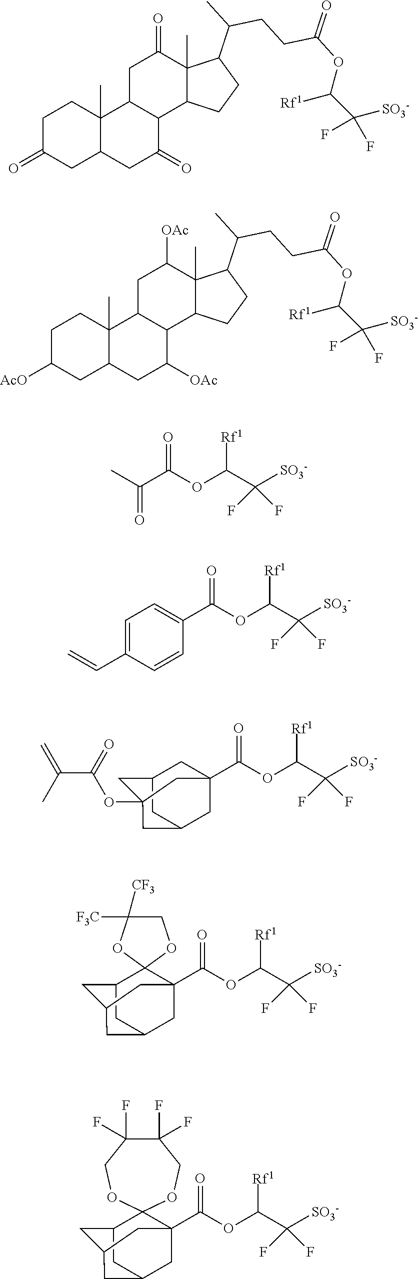

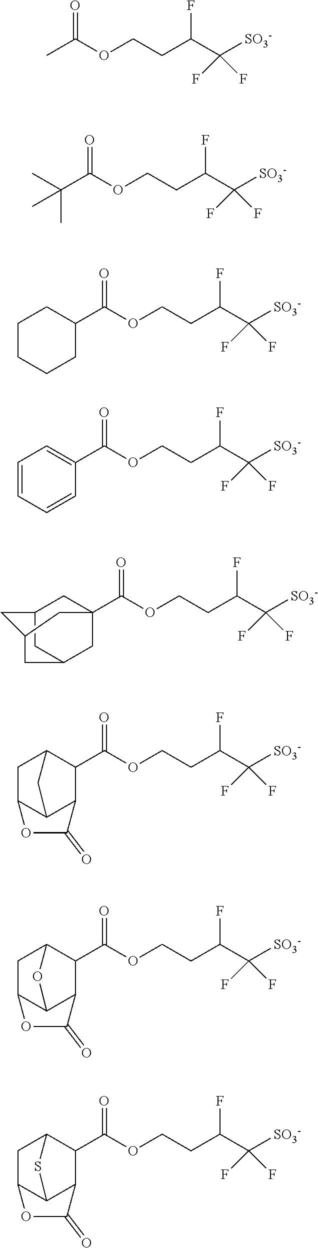

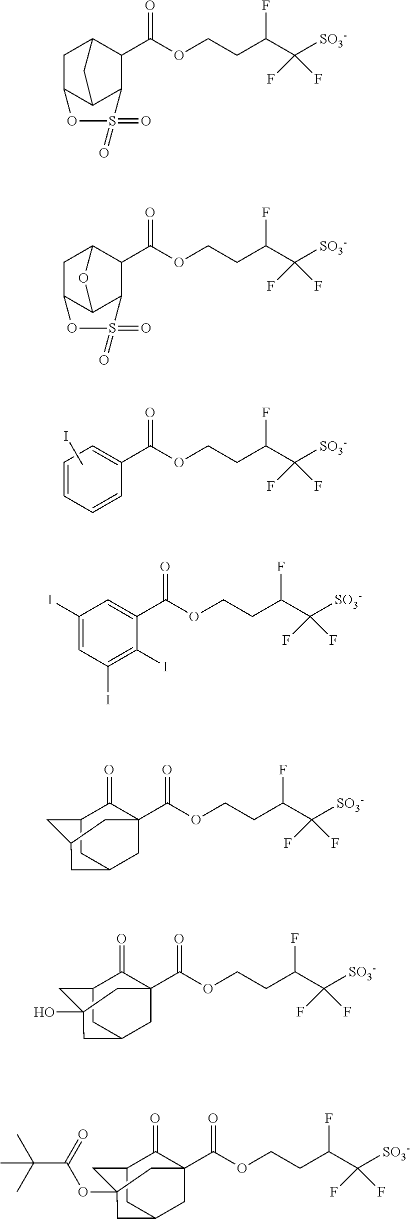

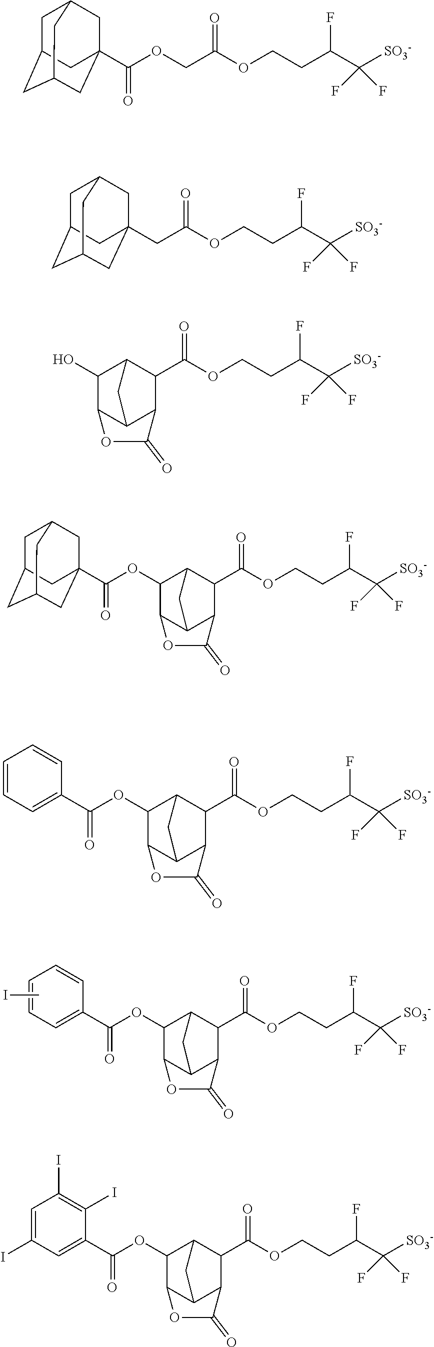

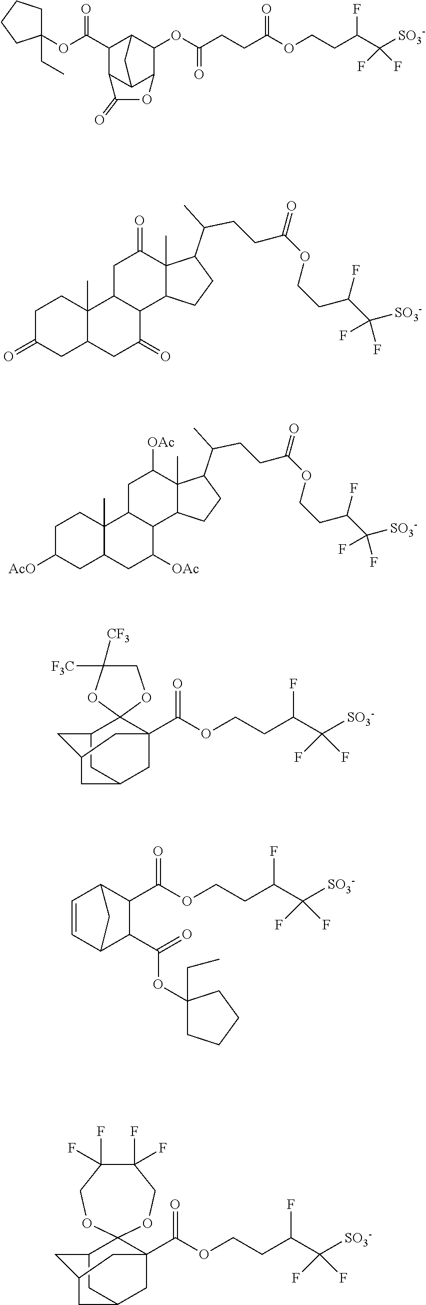

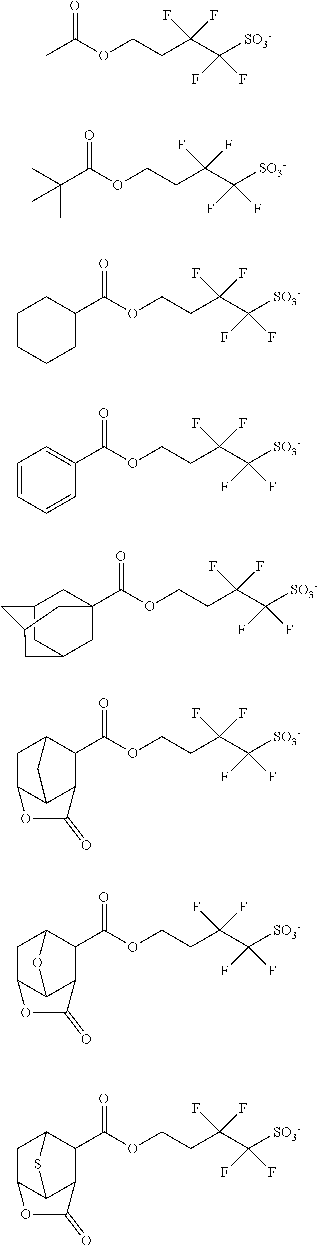

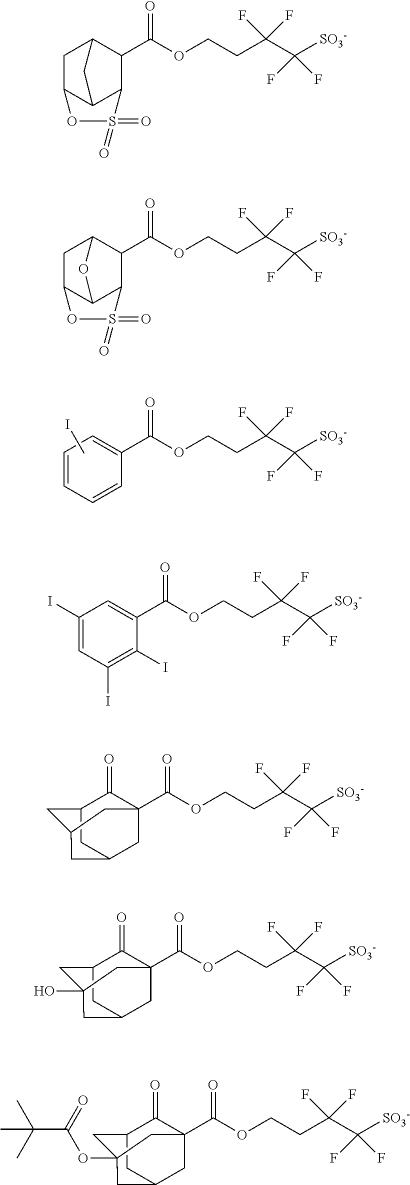

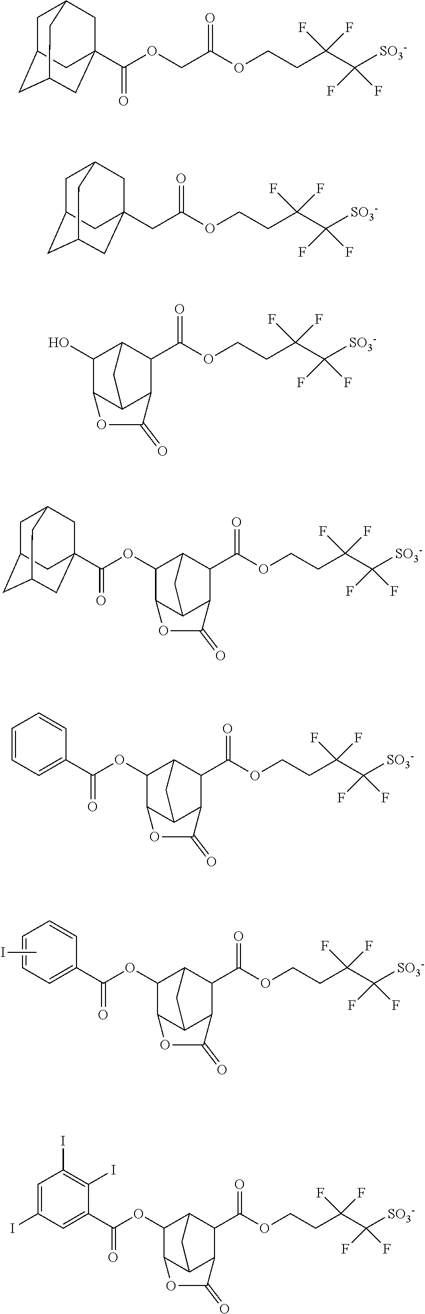

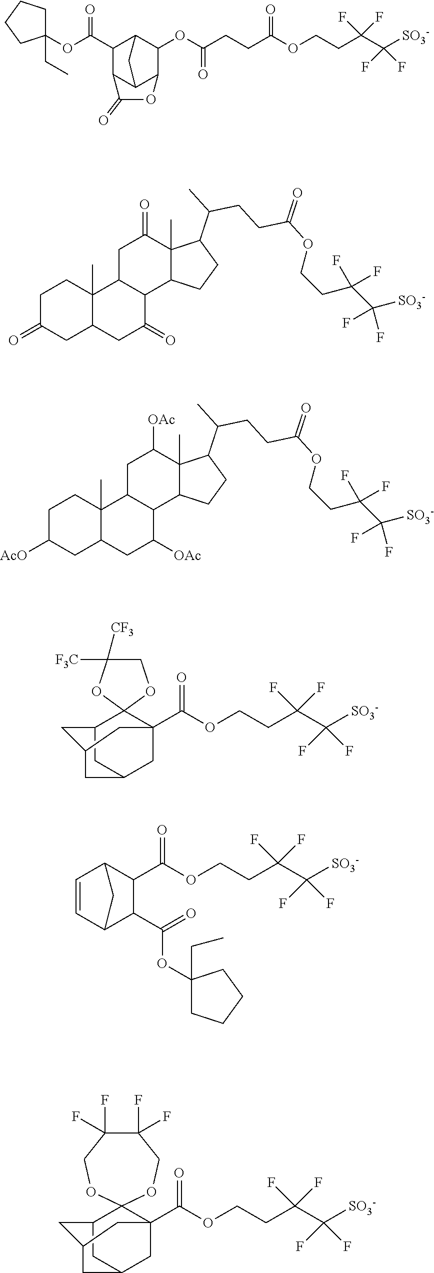

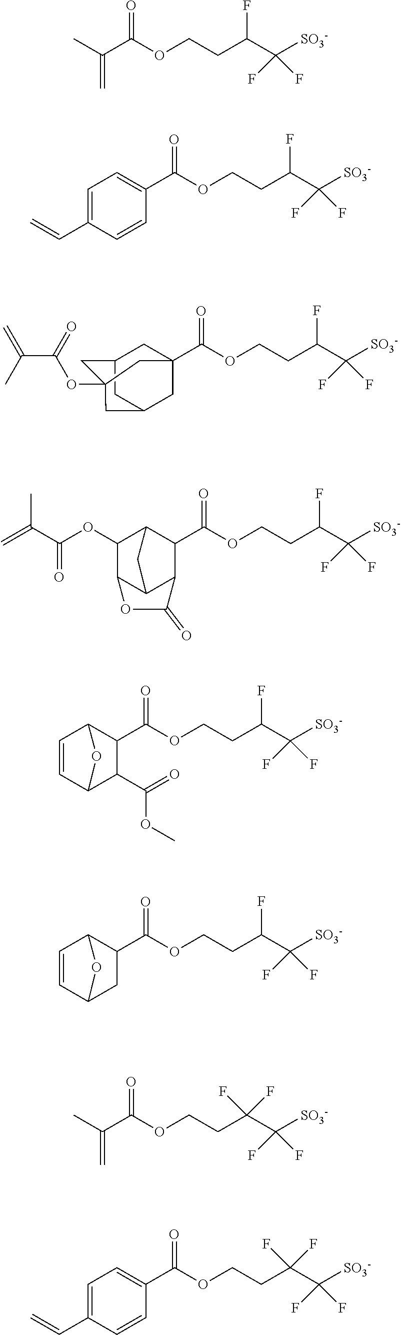

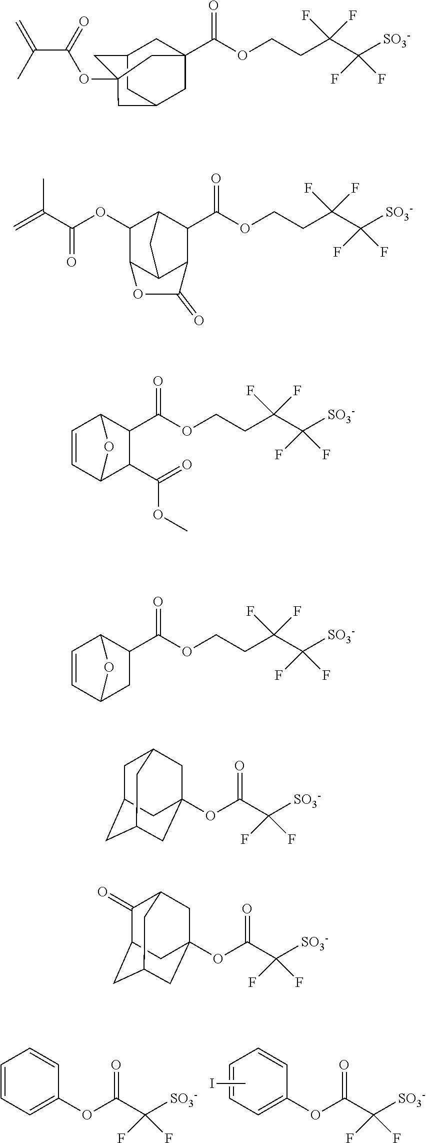

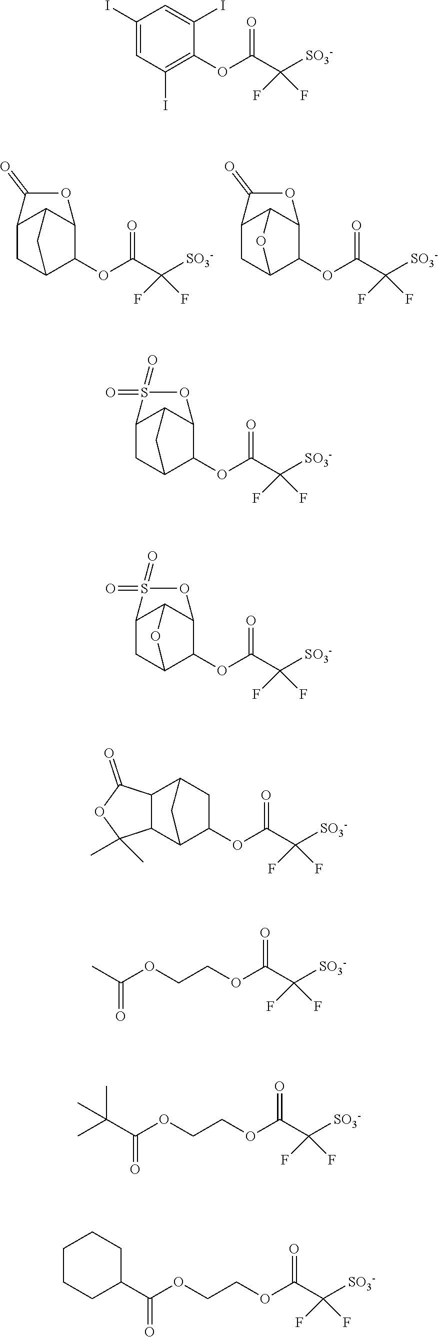

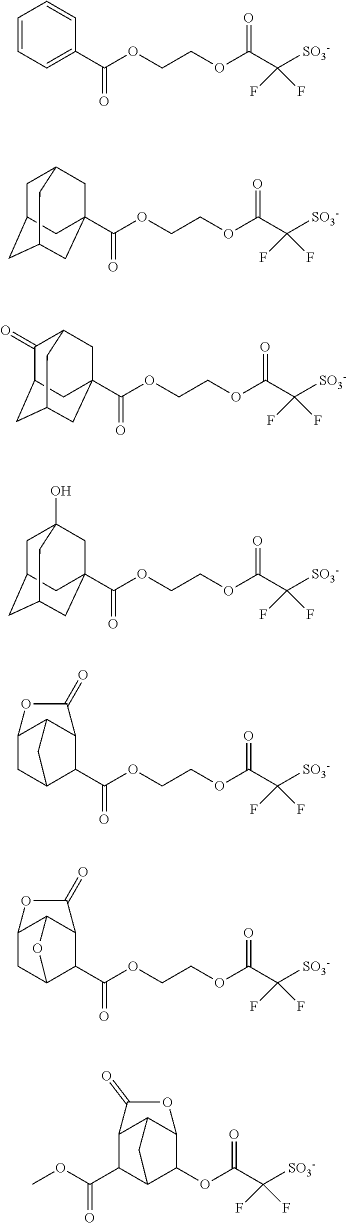

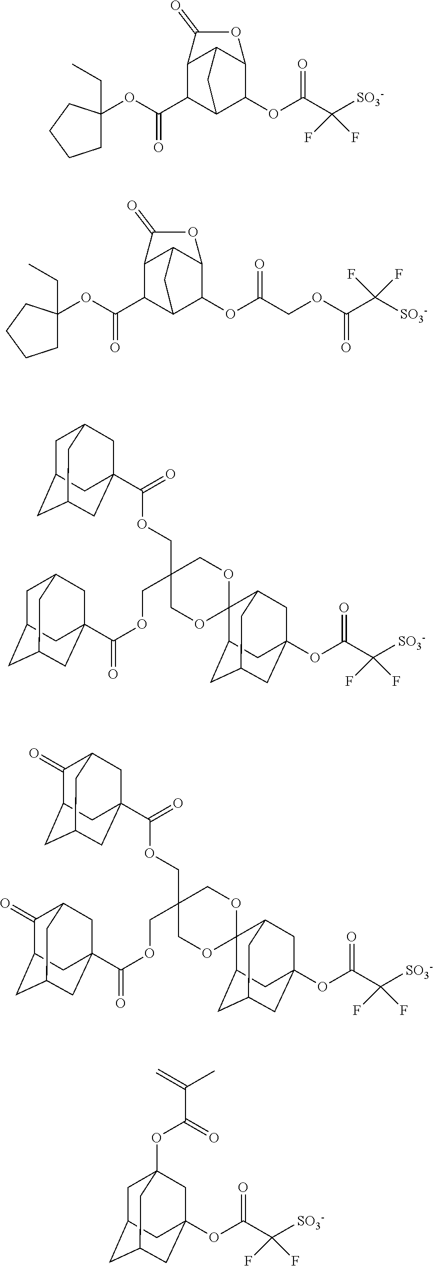

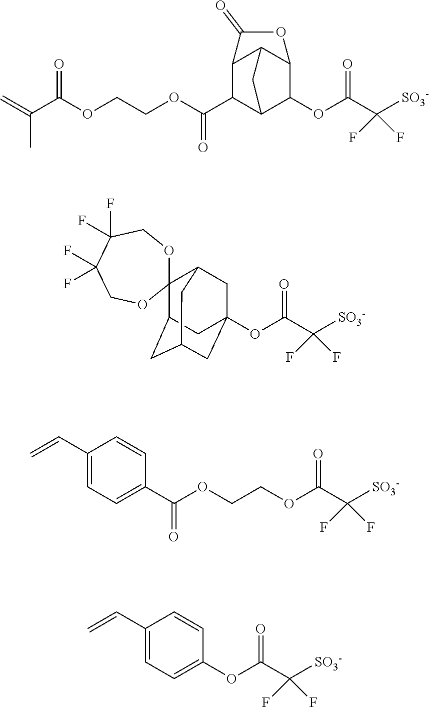

Specific examples of the anion represented by the formula (5-4) include, but are not limited to, those shown below.

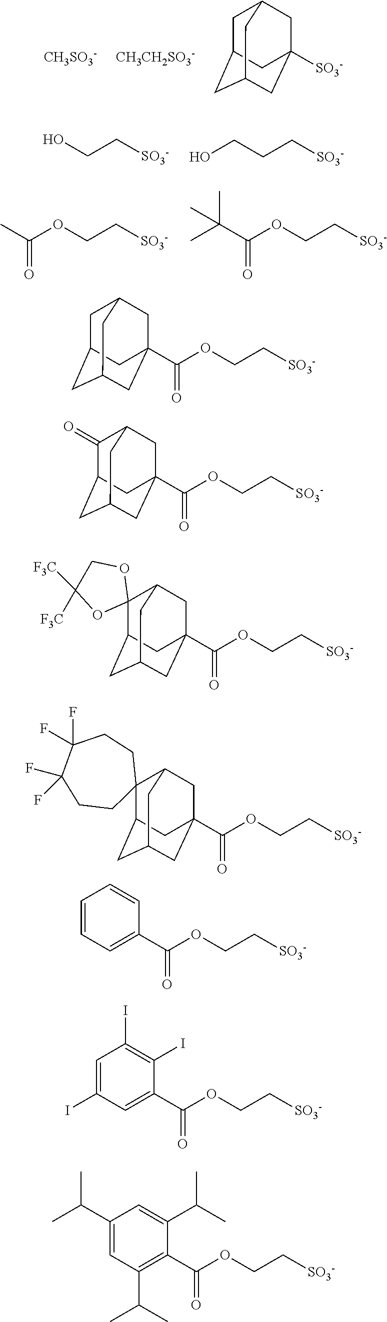

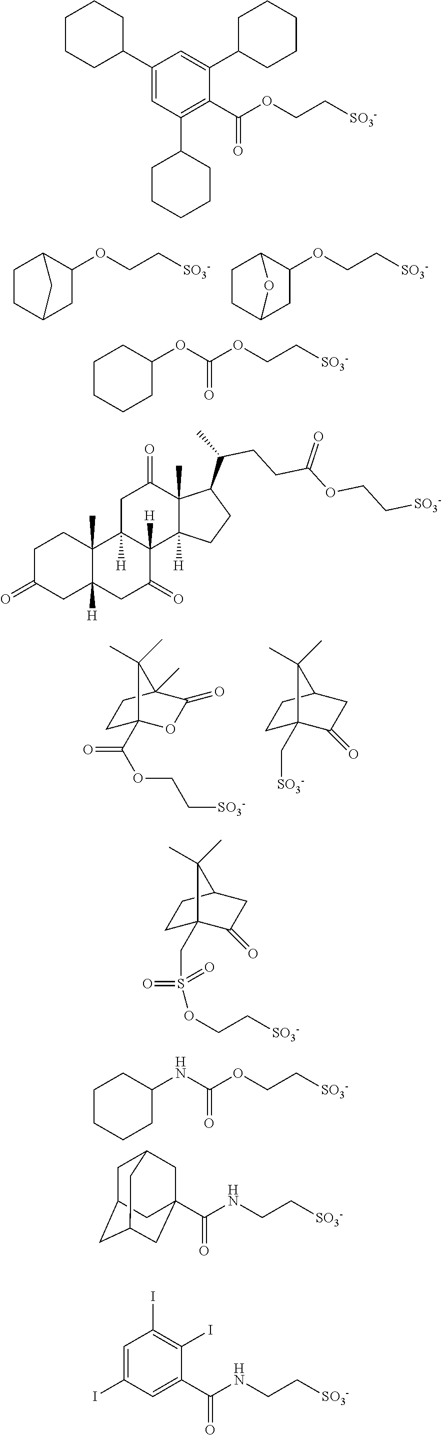

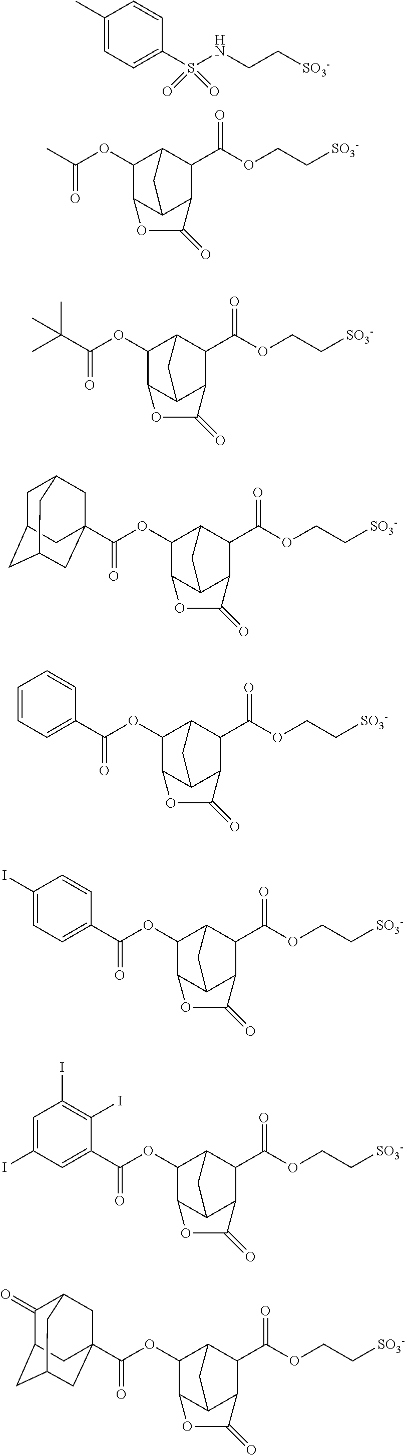

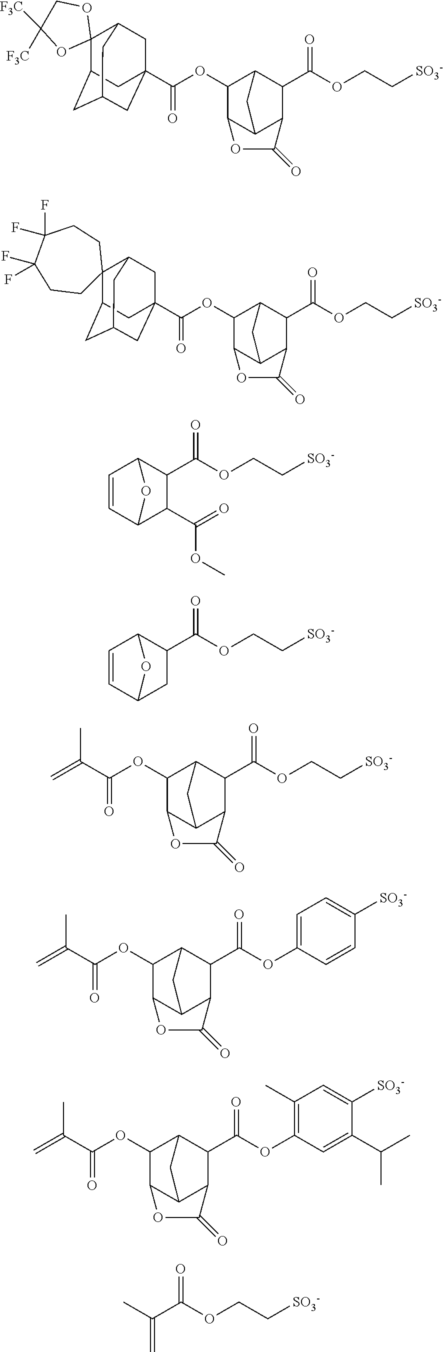

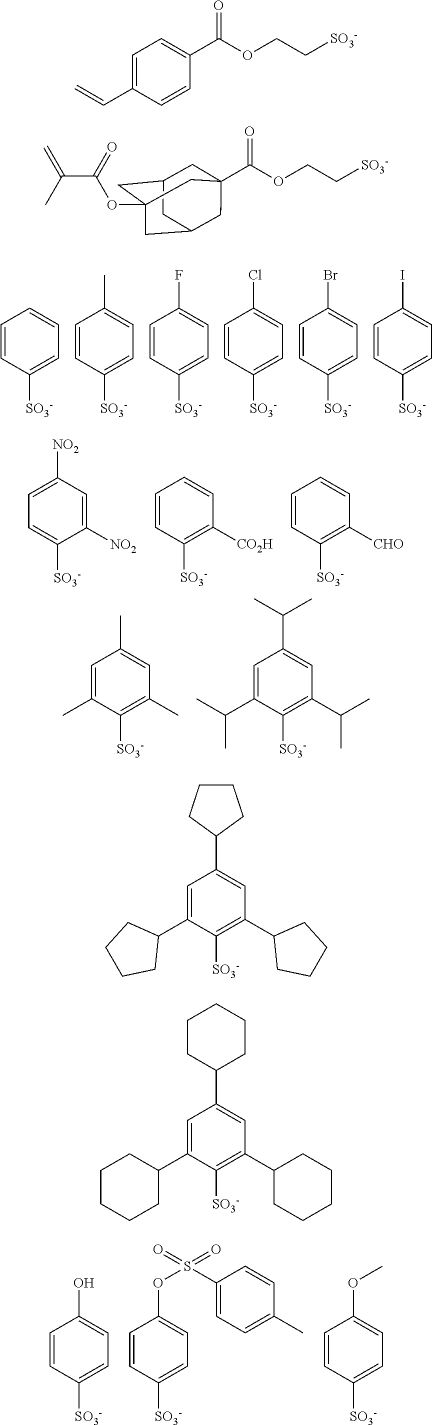

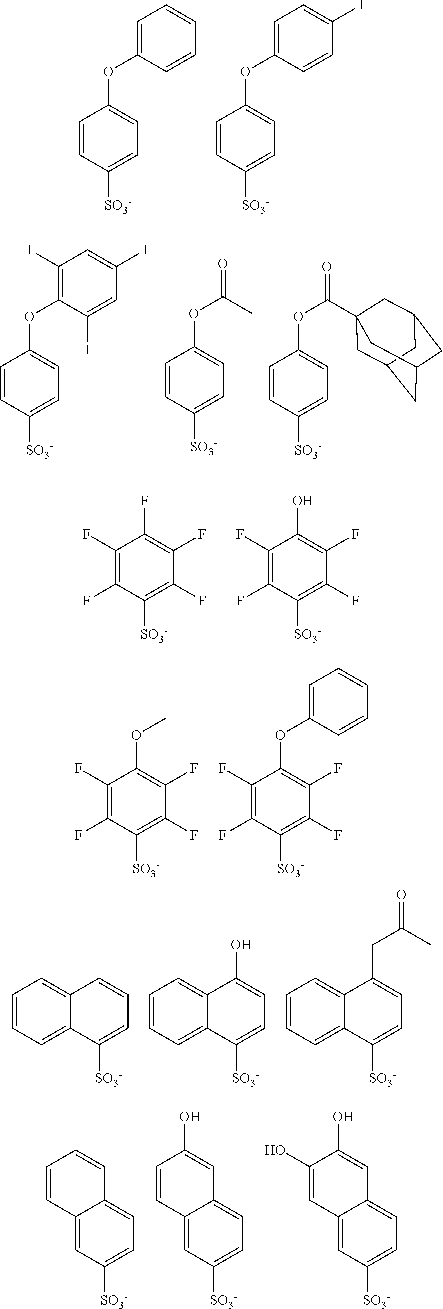

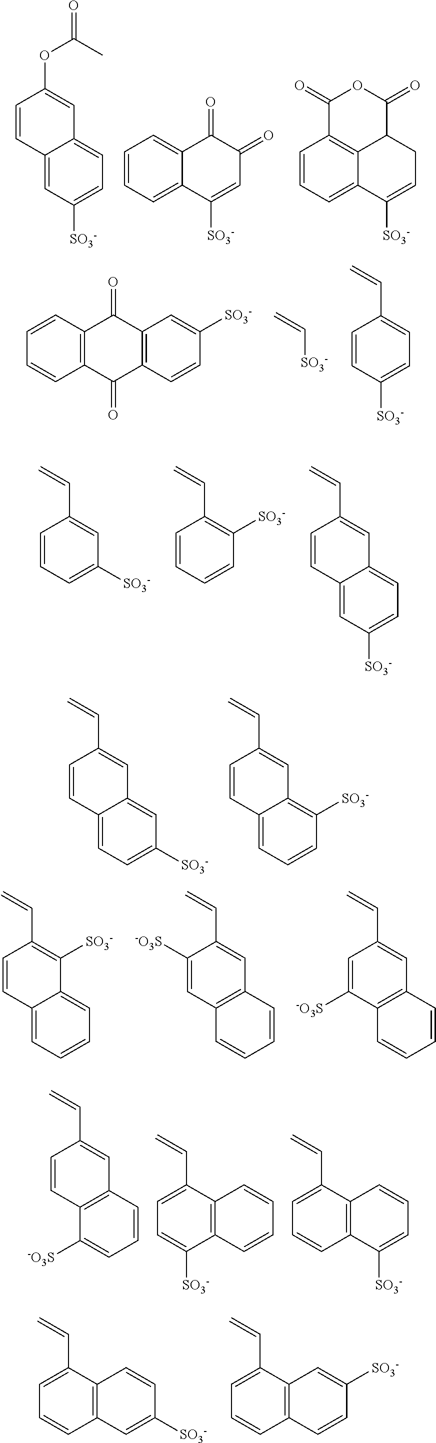

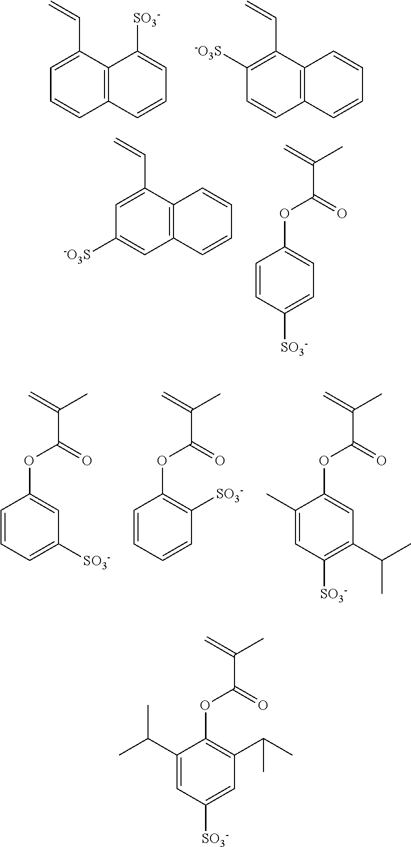

Specific examples of the anion represented by the formula (5-5) include, but are not limited to, those shown below.

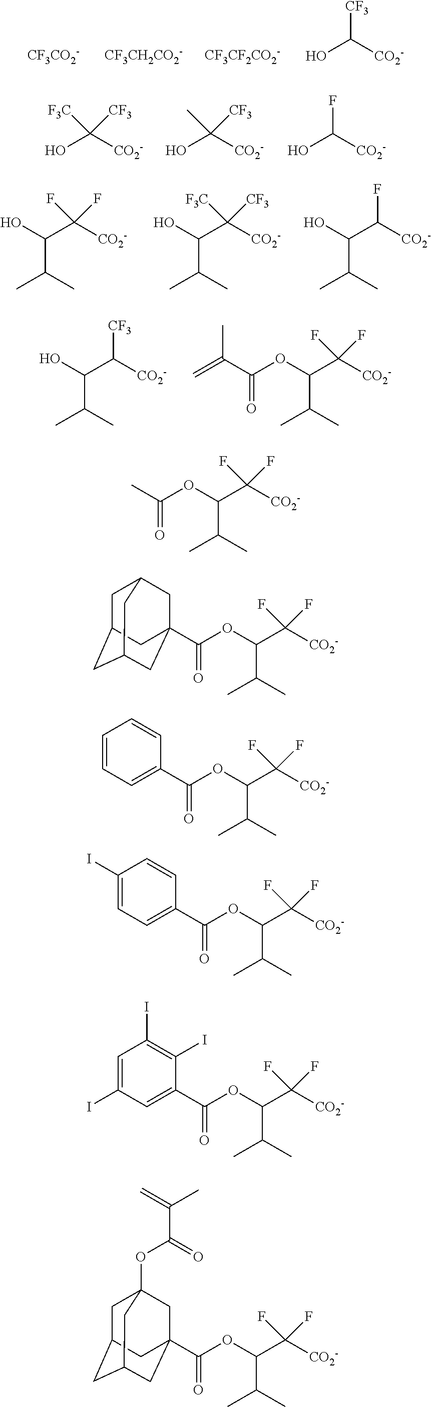

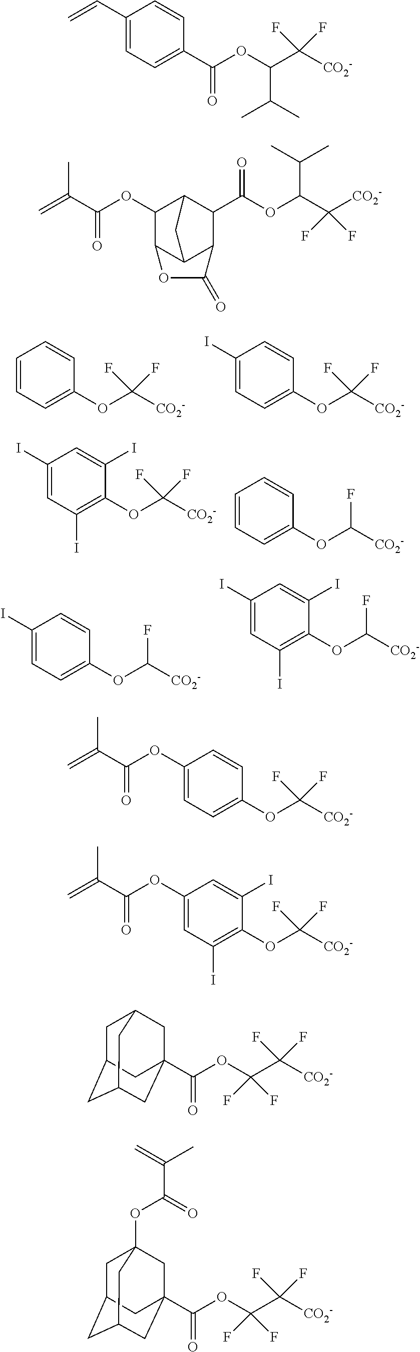

Specific examples of the anion represented by the formula (5-6) include, but are not limited to, those shown below.

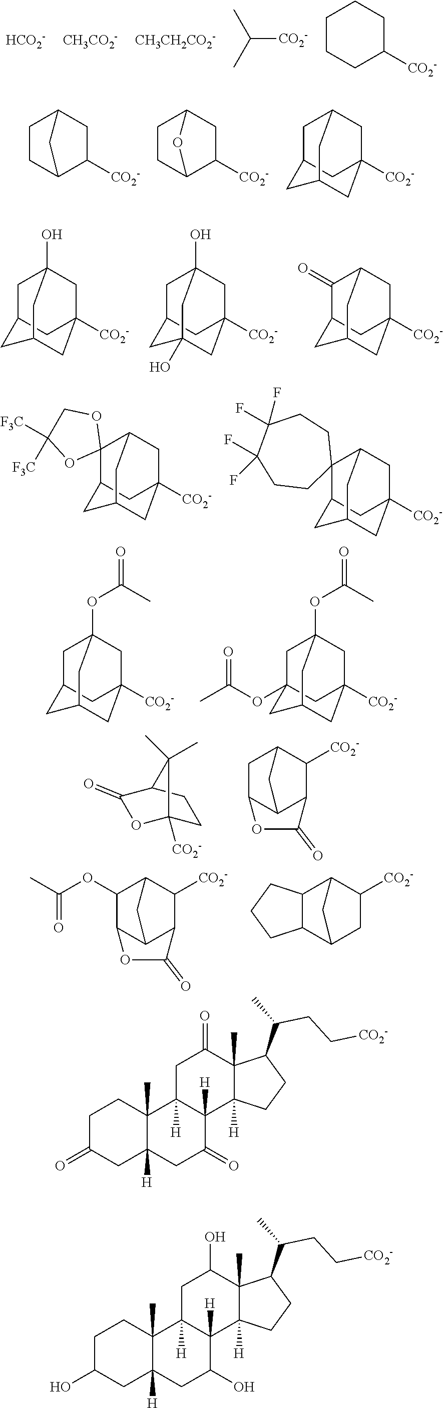

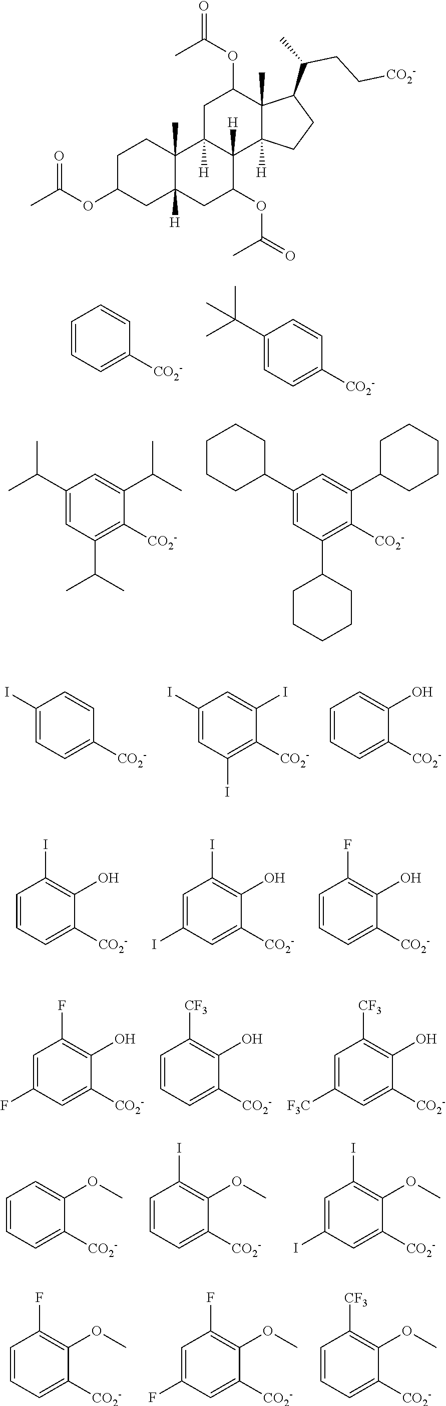

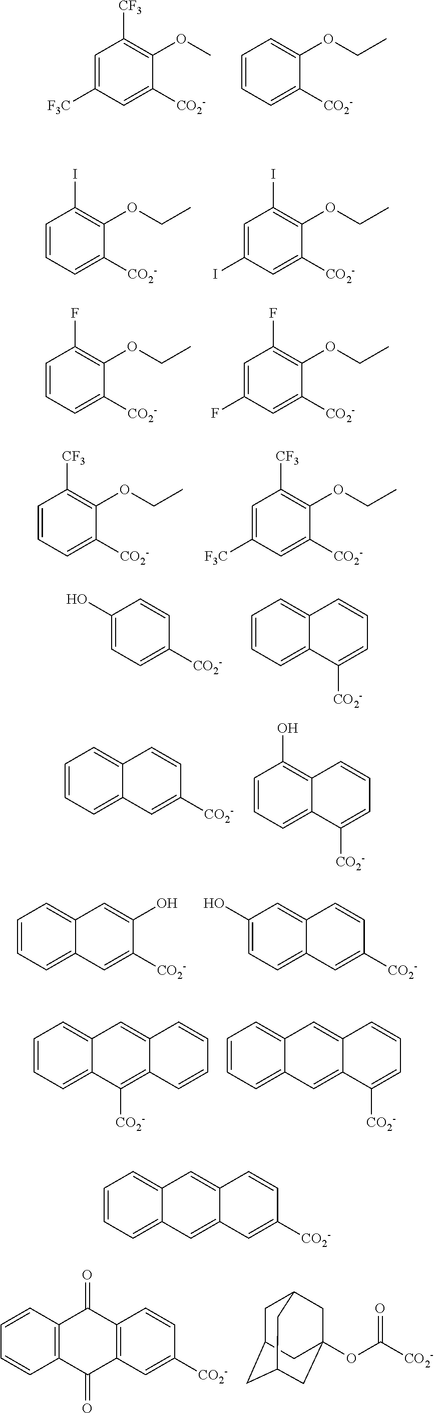

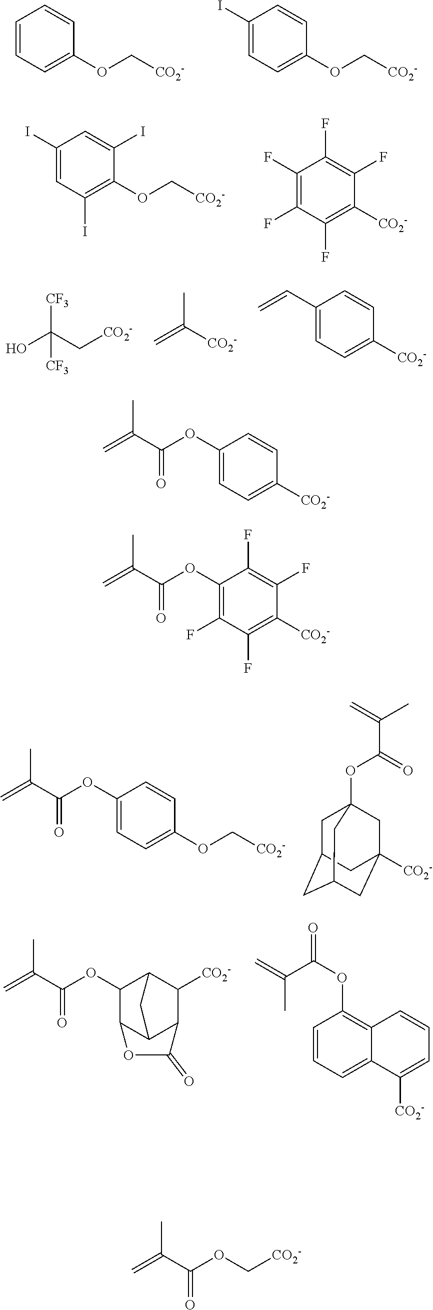

Specific examples of the anion represented by the formula (5-7) include, but are not limited to, those shown below.

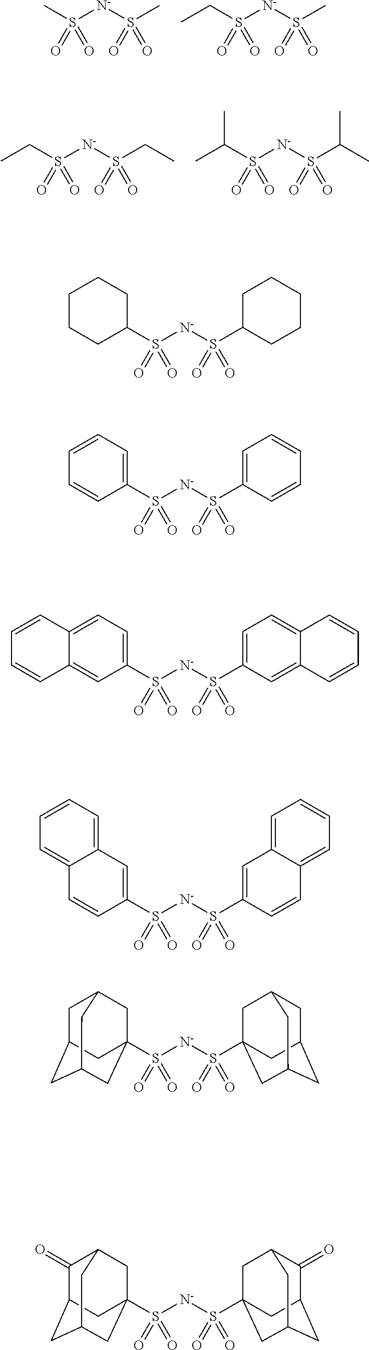

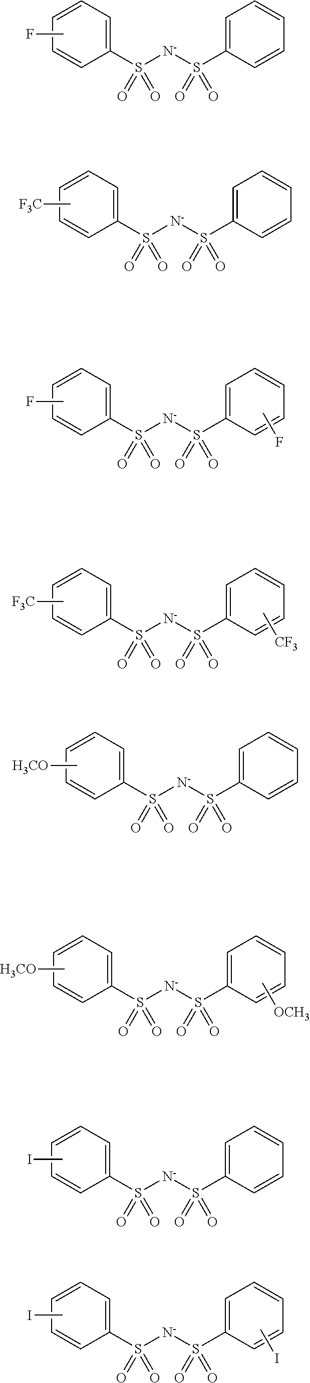

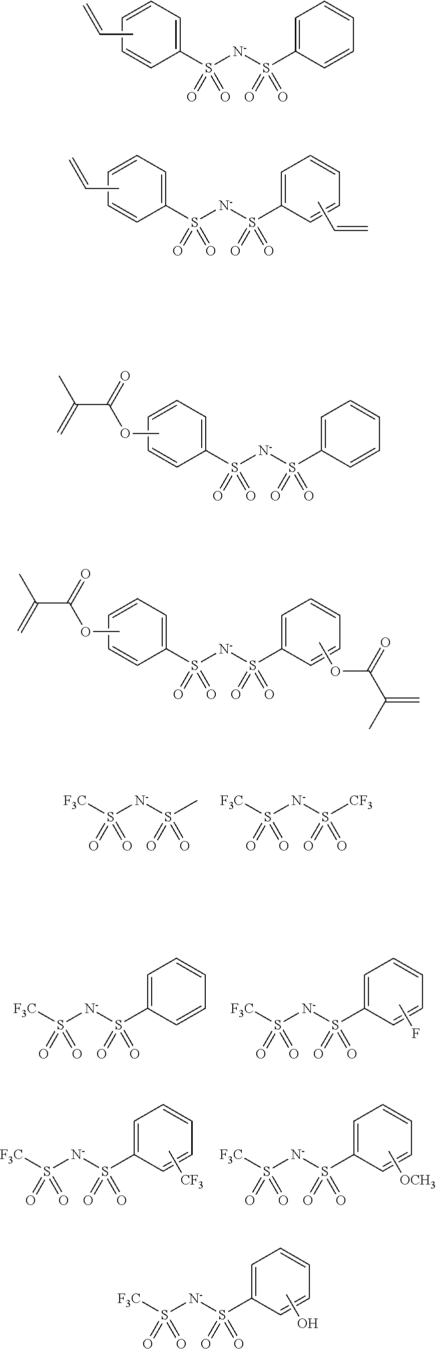

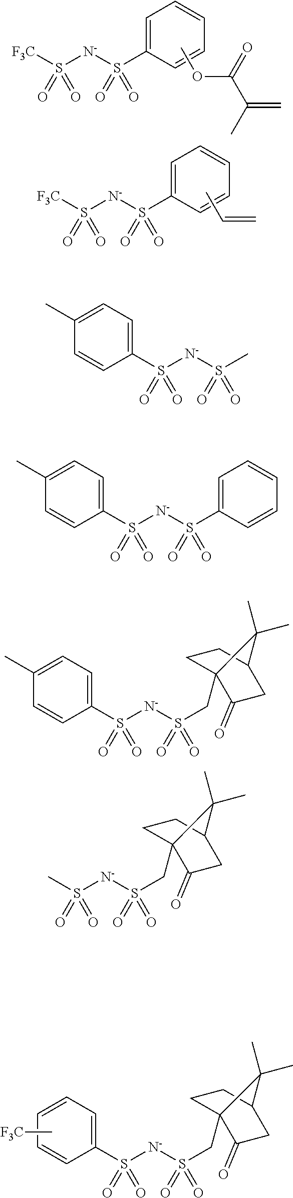

Specific examples of the anion represented by the formula (5-8) include, but are not limited to, those shown below.

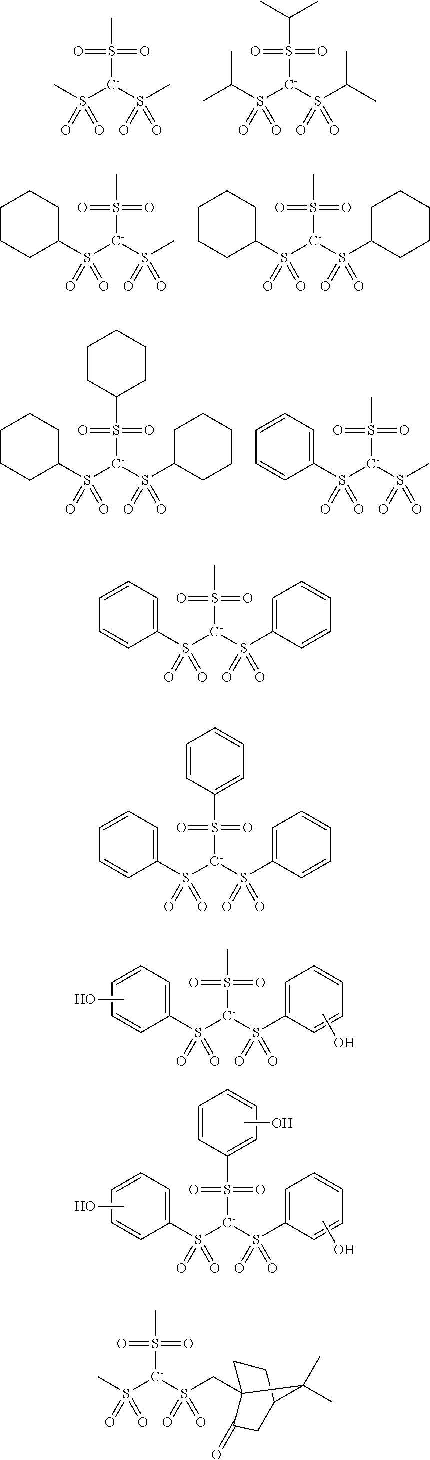

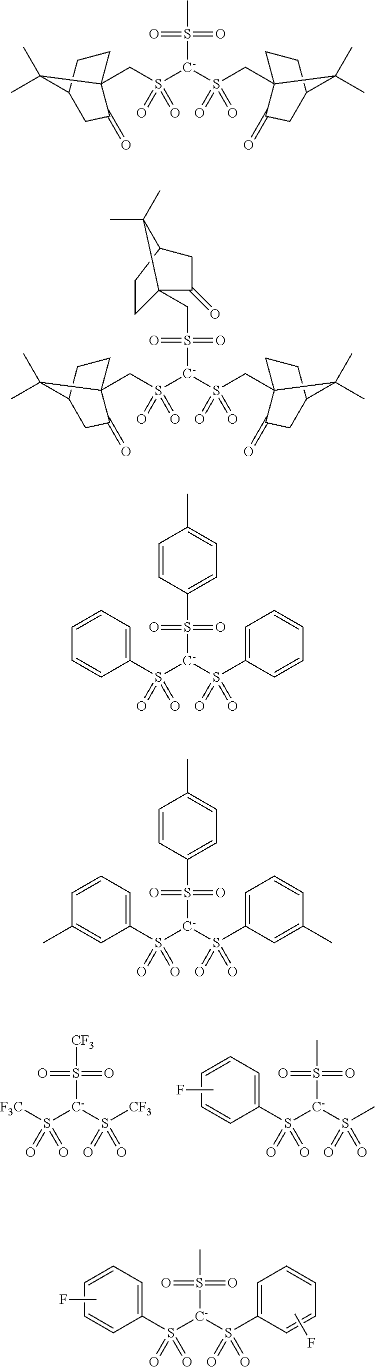

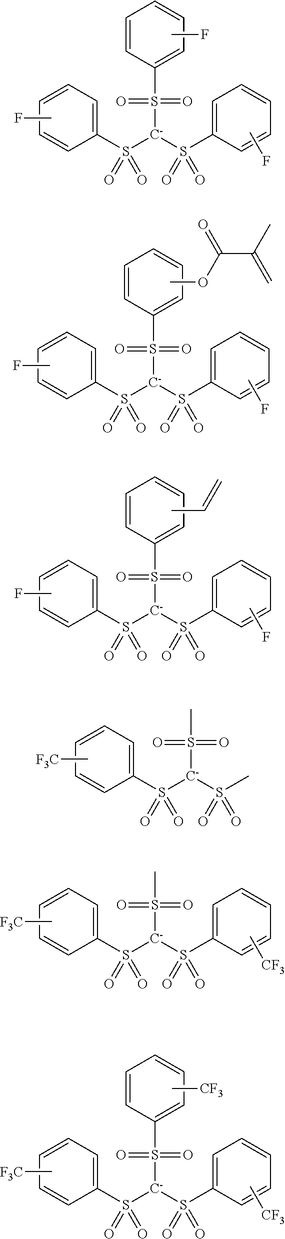

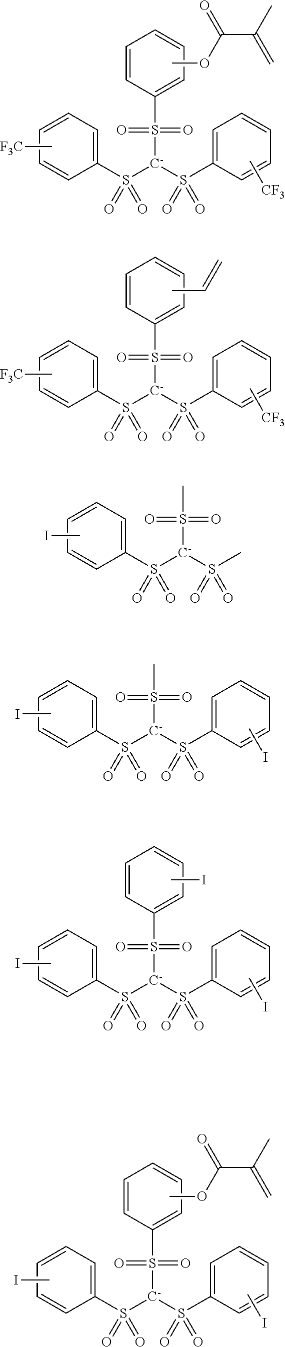

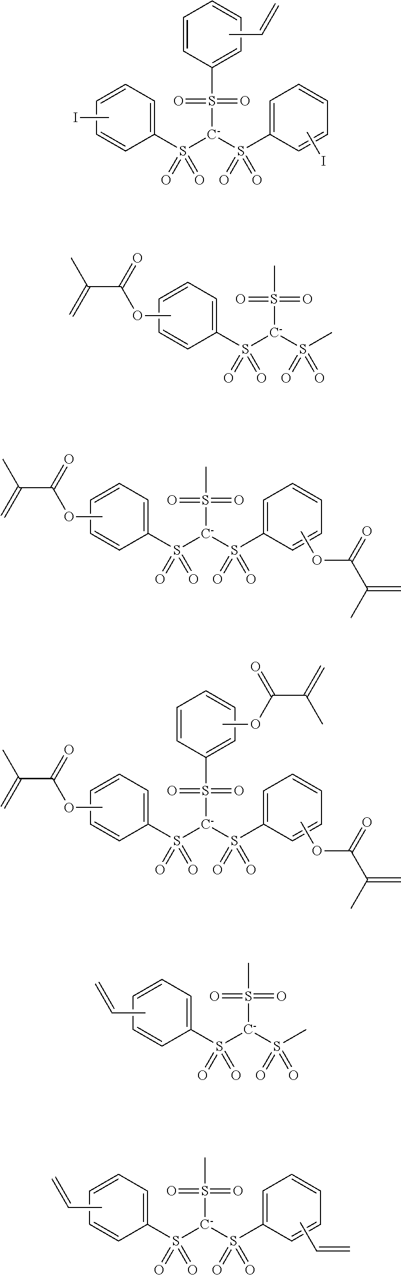

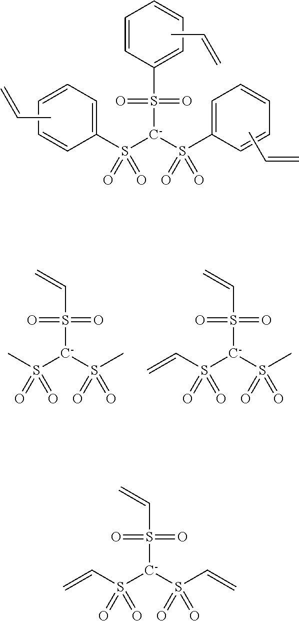

Specific examples of the anion represented by the formula (5-9) include, but are not limited to, those shown below.

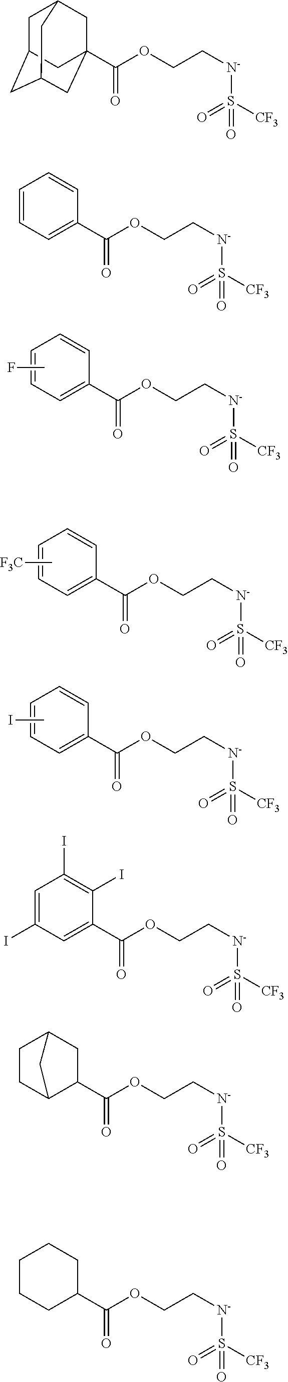

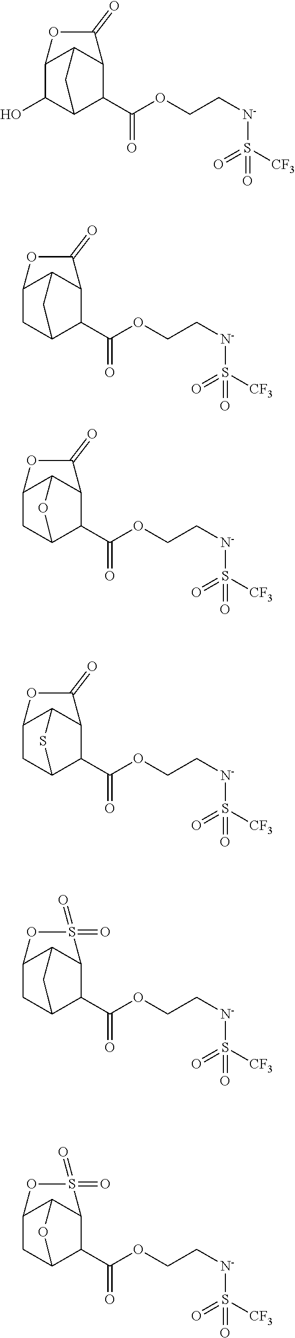 [SMILES: O=C(OCC[N-]S(=O)(=O)C(F)(F)F)C1C2CC3C(OC(=O)C31)C2O ; O=C(OCC[N-]S(=O)(=O)C(F)(F)F)C1C2CC3OC(=O)C1C3C2 ; O=C(OCC[N-]S(=O)(=O)C(F)(F)F)C1C2CC3OC(=O)C1C3O2 ; O=C(OCC[N-]S(=O)(=O)C(F)(F)F)C1C2CC3OC(=O)C1C3S2 ; O=C(OCC[N-]S(=O)(=O)C(F)(F)F)C1C2CC3OS(=O)(=O)C1C3C2 ; O=C(OCC[N-]S(=O)(=O)C(F)(F)F)C1C2CC3OS(=O)(=O)C1C3O2]

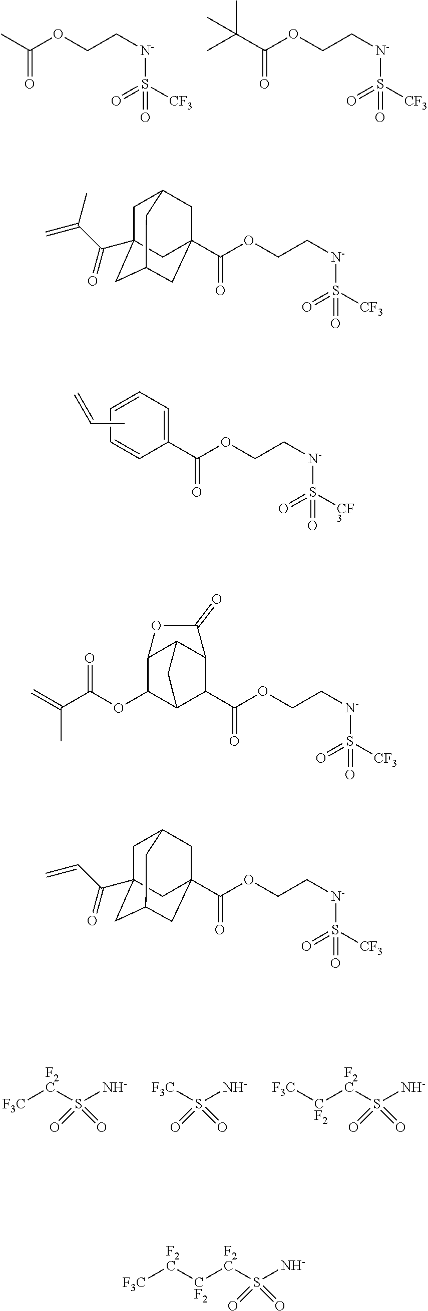

Specific examples of the onium salt include any combination of the above-mentioned anions and cations.

One kind of the onium salt may be used, and two or more kinds thereof may be used in combination. When two or more kinds of onium salts are used in combination, it is preferable to use photo-acid generators that generate acids with different acidities. The photo-acid generator that generates an acid with a lower acidity quenches the diffusion of the acid generated in the exposed area of the resist to the unexposed area, thereby suppressing the diffusion and allowing formation of a high-resolution pattern.

In the inventive resist composition, the content ratio of the hypervalent iodine compound to the photo-acid generator is preferably 1:1000 to 1000:1, more preferably 1:500 to 500:1 in mole ratio.

When the onium salt has a large molecular weight and a bulky substituent introduced therein, it has large excluded volume and highly suppresses the diffusion of the generated acid, making it suitable for forming a fine pattern.

When the onium salt has an element that has a high absorption effect for EUV light, such as a fluorine atom or an iodine atom, the amount of secondary electrons to be generated increases and the decomposition of cations is promoted, making the salt suitable for forming a highly sensitive fine pattern.

### [Reversing Patterning Process]

The inventive patterning process includes the steps of:
(i) forming a resist pattern on a support using a resist film obtained from a resist composition including a hypervalent iodine compound, a carboxy group-containing compound, and a solvent;
(ii) applying a material for forming a reversed pattern onto the support having the resist pattern formed to form a coating film for pattern-reversing; and
(iii) removing the resist pattern by etching to form a reversed pattern.

In the present invention, it is particularly preferable that in the step (ii), the coating film for pattern-reversing is formed to have a film thickness greater than the height of the resist pattern, and then, before removing the resist pattern by etching in the step (iii), the upper part of the coating film for pattern-reversing is removed to expose the resist pattern. This allows the coating film for pattern-reversing to have the same height as that of the resist pattern, thereby improving etching selectivity. In the present invention, the etching in the step (iii) is preferably dry etching, from the viewpoint of ease of controlling etching selectivity, etc.

In the inventive patterning process, a resist underlayer film can be formed between the support and the resist film.

The inventive patterning process may include the steps of: exposing the resist film by an i-line, a KrF excimer laser beam, an ArF excimer laser beam, an electron beam, or an extreme ultraviolet ray; and developing the exposed resist film with a developer.

In the patterning process used in the present invention, the resist underlayer film laminate between the substrate and the resist layer, and the type of etching gas, etc. differ depending on the type of reversing material. These will be explained below.

### [Case of Material for Forming Reversed Pattern Containing Only Organic Material]

In the present invention, when a material for forming a reversed pattern containing only organic materials is used, a three-layer resist process is used. First, a support is prepared in which a first underlayer film is laminated on the support, and a laminate is prepared in which a second underlayer film is laminated on the first underlayer film. On the second underlayer film, a plurality of resist patterns are formed (Step of Forming Resist Pattern).

Next, a material for forming a reversal pattern containing only the organic material is applied onto the second underlayer film to form a coating film for pattern-reversing that fills the gaps between a plurality of resist patterns (Step of Forming Coating Film for Pattern-Reversing). In this embodiment, the coating film for pattern-reversing is formed to have a thickness greater than the height of the resist patterns, and the upper surface of the resist patterns is also covered with the coating film for pattern-reversing.

Next, the upper part of the coating film for pattern-reversing is removed to expose the resist patterns to the atmosphere (Step of Exposing Resist Pattern to Atmosphere).

Next, the resist patterns are etched from above the coating film for pattern-reversing to remove the resist patterns (First Etching Step). As a result, a pattern (reversed pattern 1) that is an inverted image of the resist pattern is formed on the coating film for pattern-reversing. For example, when the resist pattern is a line pattern, a space pattern with the same width as the line pattern is formed as its reversed pattern 1, and when the resist pattern is a dot pattern, a hole pattern with the same diameter as the dot pattern is formed as its reversed pattern 1.

Next, the second underlayer film is etched from above the coating film for pattern-reversing (Second Etching Step). In this case, the coating film for pattern-reversing on which the reversed pattern 1 is formed functions as an etching mask, and the second underlayer film below the reversed pattern 1 is removed, thereby forming a pattern (reversed pattern 2) in which a reversed pattern 1 is transferred to the second underlayer film.

Subsequently, the first underlayer film is etched from above the reversed pattern 2 (Third Etching Step). In this case, the coating film for pattern-reversing by which the reversed pattern 2 is formed functions as the etching mask, and the first underlayer film below the reversed pattern 2 is removed. As a result, a pattern (reverse pattern 3) in which the reversed pattern 2 is transferred to the first underlayer film is formed.

Hereinafter, each of the step is described in detail.

The substrate is not particularly limited, and conventionally publicly known substrates can be used. For example, the substrate is preferably a substrate for manufacturing an integrated circuit (Si, SiO, SiN, SiON, TiN, WSi, BPSG, SOG, etc.) or a substrate for manufacturing a mask circuit (Cr, CrO, CrON, MoSi, SiO, etc.).

The first underlayer film is not particularly limited, and it is possible to use any publicly known film that is provided as an underlayer of a resist film. It may be an inorganic film, an organic film, or a combination of these. Examples of inorganic films include an inorganic anti-reflective coating (inorganic BARC). Examples of organic films include an organic anti-reflective coating (organic BARC) and an underlayer film in a multilayer resist method.

Here, the multilayer resist method is a method in which at least one layer of an organic film and at least one layer of a resist film are provided on a substrate, and the resist pattern formed on the upper resist film is used as a mask to pattern the lower layer, and it is said that this method can form a pattern with a high aspect ratio.

The inorganic film can be formed by coating an inorganic anti-reflective coating composition, such as a silicon-based material on a substrate and baking it.

As the organic film, for example, it is possible to use a publicly known film used in a fine patterning process using a multilayer resist method. Examples thereof include spin-on carbon ODL-301 (carbon content 88 mass %) manufactured by Shin-Etsu Chemical Co., Ltd.

The organic film preferably has a thickness of 40 to 200 nm, more preferably 40 to 150 nm.

The organic film is preferably a resist underlayer film obtained by using a solution-state composition for forming a resist underlayer film, or a resist underlayer film formed by a CVD method or an ALD method.

Material for forming the organic film is preferably a material capable of forming an organic film that can be etched, particularly dry-etched, so that the reversed pattern can be transferred to the organic film by etching using a coating film for pattern-reversing on which a reversed pattern has been formed. In particular, the material is preferably a material capable of forming an organic film that can be etched by oxygen plasma etching or the like.

The first underlayer film is preferably an organic film because it has an excellent etching selection ratio with respect to the reversed pattern 2. When an organic film is provided as the first underlayer film, it is easy to form a pattern with a high aspect ratio on a substrate as described above, which is useful in manufacturing a semiconductor, and therefore preferable.

The second underlayer film is not particularly limited, and it is possible to use any publicly known underlayer film, as those can be provided under a resist film. Examples thereof include a silicon-containing middle layer film. The silicon-containing middle layer film may be a silicon-containing resist middle layer film or an inorganic hard mask middle layer film. The inorganic hard mask middle layer film is preferably selected from a silicon oxide film, a silicon nitride film, and a silicon oxynitride film.

As the silicon-containing resist middle layer film, a polysilsesquioxane-based intermediate layer film is also preferably used. By imparting an antireflection effect to the silicon-containing resist middle layer film, reflection can be reduced. In particular, for 193 nm exposure, when a material containing many aromatic groups and having high substrate etching resistance is used as the resist underlayer film, the k value becomes high, and the substrate reflection becomes high. However, by suppressing the reflection with a silicon-containing resist middle layer film, the substrate reflection can be reduced to 0.5% or less. Preferably used as the silicon-containing resist middle layer film having an antireflective effect is a polysiloxane, which has a pendant anthracene for exposure at 248 nm or 157 nm, or a pendant phenyl group or a pendant light-absorbing group having a silicon-silicon bond for exposure at 193 nm, and which is cross-linked by an acid or heat.

When forming an inorganic hard mask middle layer film, a silicon oxide film, a silicon nitride film, or a silicon oxynitride film (SiON film) can be formed by a CVD method, an ALD method, or the like. For example, methods for forming a silicon nitride film are described in JP2002-334869A and WO2004/066377A1. The thickness of the inorganic hard mask middle layer film is preferably 5 to 200 nm, and more preferably 10 to 100 nm. As the inorganic hard mask middle layer film, an SiON film, which is highly effective as an antireflective coating, is most preferably used. Since the substrate temperature during the formation of the SiON film is 300 to 500° C., the resist underlayer film must be able to withstand temperatures of 300 to 500° C.

### (Step of Forming Resist Pattern)

When the inventive resist composition is used for manufacturing various integrated circuits, known lithography techniques can be applied. Examples of a patterning process include a method including a step of forming a resist film on a substrate using the resist composition, or on an underlayer film of a substrate having an underlayer film laminated thereon, a step of exposing the resist film to a high-energy beam, and a step of developing the exposed resist film using a developer if necessary.

First, the inventive resist composition is applied onto the second underlayer film by a suitable coating method, such as spin coating, roll coating, flow coating, dip coating, spray coating, or doctor coating, so that the coating has a thickness of 0.01 to 2 μm, and then pre-baked on a hot plate preferably at 60 to 200° C. for 10 seconds to 30 minutes, more preferably at 80 to 180° C. for 30 seconds to 20 minutes, to form a resist film.

The resist film is then exposed to a high-energy beam. The high-energy beam includes ultraviolet light, far ultraviolet light, EB, EUV, X-rays, soft X-rays, excimer laser beam, gamma rays, and synchrotron radiation. When ultraviolet light, far ultraviolet light, EUV, X-rays, soft X-rays, excimer laser beam, gamma rays, synchrotron radiation, or the like is used as the high-energy beam, irradiation is performed directly or using a mask for forming a desired pattern so that the exposure dose is preferably about 1 to 300 mJ/cm², more preferably about 10 to 200 mJ/cm². When EB is used as the high-energy beam, drawing is performed directly or using a mask for forming a desired pattern, with an exposure dose of preferably about 0.1 to 8000 μC/cm², more preferably about 0.5 to 5000 μC/cm². The inventive resist composition is particularly suitable for fine patterning particularly using an i-line, a KrF excimer laser beam, an ArF excimer laser beam, an EB (electron beam), or EUV (extreme ultraviolet light) among high-energy beams.

After the exposure, PEB is performed as necessary. In this event, the PEB is performed on a hot plate or in an oven preferably at 30 to 200° C. for 10 seconds to 30 minutes, more preferably at 60 to 120° C. for 30 seconds to 20 minutes.

After exposure or PEB, the film is developed with a developer as needed to perform patterning. The developer used in this case include: alkali aqueous solutions, such as a tetramethylammonium hydroxide aqueous solution and a tetrabutylammonium hydroxide aqueous solution; and organic solvents, such as 2-octanone, 2-nonanone, 2-heptanone, 3-heptanone, 4-heptanone, 2-hexanone, 3-hexanone, diisobutyl ketone, 5-methyl-2-hexanone, methylcyclohexanone, acetophenone, methylacetophenone, isopropyl alcohol, isoamyl alcohol, n-butanol, tert-butyl alcohol, tert-pentyl alcohol, n-pentanol, cyclohexanol, formic acid, acetic acid, propionic acid, propyl acetate, butyl acetate, isobutyl acetate, pentyl acetate, butenyl acetate, isopentyl acetate, cyclohexyl acetate, 4-tert-butylcyclohexyl acetate, octyl acetate, isobornyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, ethyl phenylacetate, benzyl formate, phenylethyl formate, methyl 3-phenylpropionate, benzyl propionate, 2-phenylethyl acetate, 2-propanol, 3-methoxybutanol, 3-methyl-3-methoxybutanol, 1-methoxy-2-propanol, 1-ethoxy-2-propanol, 3-methyl-1-butanol, diacetone alcohol, 4-methyl-2-pentanol, 3-methylcyclohexanol, 3,5,5-trimethylhexyl alcohol, 2,6-dimethyl-4-heptanol, toluene, anisole, and ε-caprolactone. One kind of these developers may be used, or two or more kinds thereof may be used in mixture.

After the development, rinsing is performed as necessary. The rinsing solution is preferably a solvent that is miscible with the developer but does not dissolve the resist film. Examples of such solvents to be used preferably include: alcohols having 3 to 10 carbon atoms; ether compounds having 8 to 12 carbon atoms; and solvents based on alkanes, alkenes, alkynes, or aromatic, each having 6 to 12 carbon atoms.

The rinsing can reduce occurrence of resist pattern collapse and defects. The rinsing is not always necessary, and not performing the rinsing can reduce the amount of solvent used.

### (Step of Forming Coating Film for Pattern-Reversing)

The method for applying the material for forming a reverse pattern onto the second underlayer film is not particularly limited, and publicly known means such as a spinner, a coater, and a dispenser can be used. The application may be performed so as to form a coating film for pattern-reversing having a desired film thickness. The application is performed so that at least the resist pattern in the region where the reversed pattern 1 is to be formed is covered with the coating film for pattern-reversing. In this event, the coating film for pattern-reversing may be applied so as to cover the entire second underlayer film, or so as to cover a portion of the second underlayer film. For example, application to areas where no resist pattern is formed may be omitted. In this event, the difference between the film thickness of the coating film for pattern-reversing and the height of the resist pattern is preferably 1 to 20 nm, more preferably 1 to 10 nm, taking into consideration of the subsequent step of exposing a resist pattern to the atmosphere.

After the application, it is preferable to perform a baking treatment at a temperature in the range of 80 to 250° C. for the purpose of drying the coating film (volatilizing the organic solvent) and the like.

The coating film for pattern-reversing preferably has a certain thickness so as to have sufficient etching resistance when etching the resist pattern in (First Etching Step). From this viewpoint, the thickness of the coating film for pattern-reversing is preferably 5 nm or more, more preferably 10 nm or more.

Furthermore, considering the ease of exposing the resist patterns in the subsequent step of exposing a resist pattern to the atmosphere, the upper limit of the film thickness of the coating film for pattern-reversing is preferably “the height of the resist pattern+20 nm”, more preferably “the height of the resist pattern+10 nm”. The film thickness of the coating film for pattern-reversing is preferably within the range of 5 nm to “the height of the resist pattern+20 nm”, particularly preferably within the range of 10 nm to “the height of the resist pattern+10 nm”.

### (Step of Exposing Resist Pattern to Atmosphere)

In the step of exposing a resist pattern to the atmosphere, the upper part of the coating film for pattern-reversing is removed to expose the upper surface of the resist patterns to the atmosphere. The method for removing the upper part of the coating film for pattern-reversing is not particularly limited, and the removal may be performed, for example, by etching (etch-back), or by a publicly known smoothing method. Examples of the smoothing methods include chemical mechanical polishing (CMP).

In the step of exposing a resist pattern to the atmosphere, the upper part of the coating film for pattern-reversing is removed preferably by etch-back, and any publicly known etching method can be used as the etch-back method.

In the present invention, the etch-back of the coating film for pattern-reversing is preferably performed by dry etching from the viewpoint of ease of processing, and the like. As the dry etching method, publicly known methods can be used, which include: chemical etching, such as downflow etching and chemical dry etching; physical etching, such as sputter etching and ion beam etching; and chemical/physical etching, such as RIE (reactive ion etching).

The most common dry etching is parallel plate RIE. In this method, first a multilayer laminate is placed in a chamber of the RIE system, and necessary etching gas is introduced therein. In the chamber, when a high frequency voltage is applied to a holder in which the multilayer laminate is places in parallel to upper electrodes, the etching gas is converted into plasma. Plasma contains etching species such as charged particles including positive and negative ions and electrons, and neutral active species. When these etching species are adsorbed onto the lower resist layer, a chemical reaction occurs; the reaction products are released from the surface and exhausted to the outside; and thereby the etching proceeds.

When the material for forming a reversed pattern contains organic materials only, examples of the etching gas to be used for the etch-back include oxygen (O₂) gas, sulfur dioxide gas. One of these etching gases may be used, and two or more kinds thereof may be used in mixture. Nitrogen gas, rare gas (e.g., argon gas), etc. may also be mixed with the etching gas.

### (First Etching Step)

In the first etching step, etching is performed under conditions where material constituting a resist pattern is removed but it is difficult to remove a coating film for pattern-reversing, until the surface of a second underlayer film is exposed to the atmosphere. Thereby the resist patterns are removed to form a reversed pattern 1 in the coating film for pattern-reversing.

The etching of the resist pattern can be performed by a publicly known etching method. In the present invention, the etching of the resist pattern is preferably performed by dry etching. As the dry etching method, the same publicly known methods as those described above can be used. The type of etching gas used in this event may be any gas that provides an etching selection ratio between the coating film for pattern-reversing, which serves as an etching mask, and the resist pattern. Examples of such gas include oxygen (O₂) gas, sulfur dioxide gas, and the above-mentioned halogen-based gases. One kind of these etching gases may be used, or two or more kinds thereof may be used in mixture. The etching gas may also be mixed with nitrogen gas, rare gas (argon gas, etc.), etc.

As the etching method in the first etching step, oxygen plasma etching (dry etching using plasma obtained from O₂ gas) is preferable, since it has a high etching selection ratio with respect to the coating film for pattern-reversing.

### (Second Etching Step)

In the second etching step, etching is performed under conditions where material constituting the second underlayer film is removed but it is difficult to remove the coating film for pattern-reversing, until the surface of the first underlayer film is exposed to the atmosphere. Thereby the second underlayer film below the reversed pattern 1 is removed while the coating film for pattern-reversing having the reversed pattern 1 formed functions as an etching mask, and then the reversed pattern 1 is transferred to the second underlayer film to form a reversed pattern 2.

The etching of the reversed pattern 1 can be performed by a publicly known etching method. In the present invention, the etching of the second underlayer film is preferably performed by dry etching. As the dry etching method, the same publicly known methods as those described above can be used.

The type of etching gas used in this event may be any gas that provides an etching selectivity between the reversed pattern 1 serving as the etching mask and the second underlayer film, and may be appropriately selected in consideration of the material properties of the two. For example, the second underlayer film is a silicon-containing middle layer film as described above, and particularly for giving an etching selection ratio with respect to the reversed pattern 1, a halogen-based gas is preferable. Examples of halogen-based gases include hydrocarbon gases in which part or all of the hydrogen atoms are substituted with halogen atoms, such as a fluorine atom and a chlorine atoms, and specific examples thereof include fluorocarbon-base gases and carbon chloride-based gases. Examples of fluorocarbon-based gases include CF-based gases, such as tetrafluoromethane (CF₄) gas, and CHF-based gases, such as trifluoromethane (CHF₃) gas.

Examples of carbon chloride-based gases include tetrachloromethane (CCl₄) gas. One of these etching gases may be used, or two or more kinds thereof may be used in mixture. Furthermore, the etching gas may be mixed with nitrogen gas, a rare gas (argon gas, etc.), or the like.

The etching gas used in the second etching step is preferably a fluorocarbon-based gas, particularly preferably CF₄ gas and/or CHF₃ gas.

The second etching step may be performed successively after the first etching step. When the same type of gas as that used in the second etching step is used in the first etching step, the etching steps can be performed successively under the same conditions.

### (Third Etching Step)

In the third etching step, etching is performed under conditions where material constituting the first underlayer film is removed but it is difficult to remove the reversed pattern 2, until the surface of the substrate is exposed to the atmosphere. Thereby the first underlayer film below the reversed pattern 2 is removed while the reversed pattern 2 functions as an etching mask, and then the reversed pattern 2 is transferred to the first underlayer film to form a reversed pattern 3.

The etching of the reverse pattern 2 can be performed by a publicly known etching method. In the present invention, the etching of the reverse pattern 2 is preferably performed by dry etching. As the dry etching method, the same publicly known methods as those described above can be used.

The type of etching gas used in this step may be any gas that provides an etching selection ratio between the reversed pattern 2 serving as the etching mask and the first underlayer film, and may be appropriately selected in consideration of the material properties of each. For example, oxygen plasma etching is preferable because it provides a high etching selection ratio with respect to the reversed pattern 2. The process is similar to the first etching step, and after etching, it is possible to perform processes such as removing residues and cleaning the substrate as necessary.

### [Case of Material for Forming Reversed Pattern Containing Metal Material]

In the present invention, when a material for forming a reversed pattern containing a metal material is used, a two-layer resist process or a three-layer resist process is used, which will be described below.

### In the Case of a Two-Layer Resist Process

First, a support is prepared in which a third underlayer film is laminated on a substrate, and a plurality of resist patterns are formed on the third underlayer film (Step of Forming Resist Pattern).

Next, a material for forming a reversed pattern containing the metal material is applied onto the third underlayer film to form a coating film for pattern-reversing that fills the gaps between the plurality of resist patterns (Step of Forming Coating Film for Pattern-Reversing). In this embodiment, the coating film for pattern-reversing is formed to have a film thickness greater than the height of the resist pattern, and the upper surface of the resist patterns is also covered with the coating film for pattern-reversing.

Next, the upper part of the coating film for pattern-reversing is removed to expose the resist patterns to the atmosphere (Step of Exposing Resist Pattern to Atmosphere).

Next, the resist patterns are etched from above the coating film for pattern-reversing to remove the resist patterns (First Etching Step), thereby forming a pattern (reversed pattern 4) on the coating film for pattern-reversing, which is an inverted image of the resist patterns. For example, when the resist pattern is a line pattern, a space pattern of the same width as the line pattern is formed as the reversed pattern 4, and when the resist pattern is a dot pattern, a hole pattern of the same diameter as the dot pattern is formed as the reversed pattern 4.

Next, the third underlayer film is etched from above the coating film for pattern-reversing (Second Etching Step). In this event, the coating film for pattern-reversing on which the reversed pattern 4 is formed functions as an etching mask, and the third underlayer film below the reversed pattern 4 is removed. As a result, a pattern in which the reversed pattern 4 is transferred to the third underlayer film is formed (reverse pattern 5).

Each step will be described in more detail below.

### (Step of Forming Resist Pattern)

The substrate may be the same as those described above for [Case of Material for Forming Reversed Pattern Containing Only Organic Material]. The step of forming a resist pattern may be the same as those described above for [Case of Material for Forming Reversed Pattern Containing Only Organic Material] except that the resist patterns are formed on the third underlayer film. Furthermore, the third underlayer film may be the same as those described above for the first underlayer film.

### (Step of Forming Coating Film for Pattern-Reversing)

The method for applying the material for forming a reversed pattern onto the third underlayer film is not particularly limited, and the publicly known means, such as a spinner, a coater, and a dispenser, can be used. The application is performed so as to form a coating film for pattern-reversing with a desired film thickness. The application is performed so that at least the resist patterns in the region where the reversed pattern 4 is to be formed are covered with the coating film for pattern-reversing. In this event, the coating film for pattern-reversing may be applied so that the entire third underlayer film is covered, or so that only a portion of the third underlayer film is covered. For example, application to areas where no resist pattern is formed may be omitted. In this event, the difference between the film thickness of the coating film for pattern-reversing and the height of the resist pattern is preferably 1 to 20 nm, more preferably 1 to 10 nm, taking into consideration of the subsequent step of exposing a resist pattern to the atmosphere.

After the coating, it is preferable to perform a baking treatment in the range of 80 to 500° C. for the purpose of drying the coating film (volatilizing the organic solvent) and the like.

### (Step of Exposing Resist Pattern to Atmosphere)

The step of exposing a resist pattern to the atmosphere may be similar to that of [Case of Material for Forming Reversed Pattern Containing Only Organic Material]. The etching gas used for the etch-back is preferably, for example, a halogen-based gas. Examples of the halogen-based gases include tetrachloromethane (CCl₄) gas, hydrogen chloride (HCl) gas, hydrogen bromide (HBr) gas, boron trichloride (BCl₃) gas, and hydrocarbon gases in which part or all of the hydrogen atoms have been substituted with halogen atoms, such as a fluorine atom and a chlorine atom. Specific examples thereof include fluorocarbon-based gases and carbon chloride-based gases. Examples of the fluorocarbon-based gases include CF-based gases, such as tetrafluoromethane (CF₄) gas, and CHF-based gases, such as trifluoromethane (CHF₃) gas.

One kind of these etching gases may be used, and two or more kinds thereof maybe used in mixture. The etching gas may also be mixed with nitrogen gas, rare gas (argon gas, etc.), etc.

### (First Etching Step)

In the first etching step, the etching is performed under conditions where material constituting the resist pattern is removed but it is difficult to remove the coating film for pattern-reversing, until the surface of the third underlayer film is exposed to the atmosphere. Thereby the resist patterns are removed to form a reversed pattern 4 in the coating film for pattern-reversing.

The etching of the resist patterns can be performed by a known etching method. In the present invention, the etching of the resist patterns is preferably performed by dry etching. As the dry etching method, the same publicly known methods as described above can be used. As the etching gas, for example, a halogen-based gases are preferable. Examples of the halogen-based gases include tetrachloromethane (CCl₄) gas, hydrogen chloride (HCl) gas, hydrogen bromide (HBr) gas, boron trichloride (BCl₃) gas, and hydrocarbon gases in which part or all of the hydrogen atoms are substituted with halogen atoms, such as a fluorine atom and a chlorine atom. Specific examples thereof include fluorocarbon-based gases and carbon chloride-based gases. Examples of fluorocarbon-based gases include CF-based gases, such as tetrafluoromethane (CF₄) gas, and CHF-based gases such as trifluoromethane (CHF₃) gas.

One of these etching gases may be used, or two or more kinds thereof may be used in mixture. The etching gas may also be mixed with nitrogen gas, rare gas (argon gas, etc.), etc.

### (Second Etching Step)

In the second etching step, etching is performed under conditions where material constituting the third underlayer film is removed but it is difficult to remove the coating film for pattern-reversing, until the surface of the substrate is exposed to the atmosphere. Thereby the third underlayer film below the reversed pattern 4 is removed while the coating film for pattern-reversing having the reversed pattern 4 formed functions as an etching mask, and then the reversed pattern 4 is transferred to the third underlayer film to form a reversed pattern 5.

The etching of the reversed pattern 4 can be performed by a publicly known etching method. In the present invention, the etching of the reversed pattern 4 is preferably performed by dry etching. As the dry etching method, the same publicly known methods as those described above can be used. As the etching gas, for example, a halogen-based gas is preferable. Examples of halogen-based gases include tetrachloromethane (CCl₄) gas, hydrogen chloride (HCl) gas, hydrogen bromide (HBr) gas, boron trichloride (BCl₃) gas, and hydrocarbon gases in which part or all of the hydrogen atoms is substituted with halogen atoms, such as a fluorine atom and a chlorine atom. Specific examples of the fluorocarbon gas include a fluorocarbon gas and a carbon chloride gas. Examples of the fluorocarbon gas include a CF-based gas, such as tetrafluoromethane (CF₄) gas, and a CHF gas, such as trifluoromethane (CHF₃) gas.

One of these etching gases may be used, or two or more kinds thereof may be used in a mixture. The etching gas may also be mixed with nitrogen gas, rare gas (argon gas, etc.), etc.

The second etching step may be performed successively after the first etching step. When the same gas species as that used in the second etching step is used in the first etching step, the etching steps can be performed successively under the same conditions.

### In the Case of a Three-Layer Resist Process

In the present invention, when a material for forming a reversed pattern containing a metal material is used, a three-layer resist process is used. First, a support is prepared in which a fourth underlayer film is laminated on a substrate, and a fifth underlayer film is laminated on the fourth underlayer film. Multiple resist patterns are formed on the fifth underlayer film (Step of Forming Resist Pattern).

Next, the above-mentioned material for forming a reversed pattern containing the metal material is applied onto the fifth underlayer film to form a coating film for pattern-reversing that fills the gaps between the multiple resist patterns (Step of Forming Coating Film for Pattern-Reversing). In this embodiment, the coating film for pattern-reversing is formed to have a film thickness greater than the height of the resist pattern, and the upper surface of the resist patterns is also covered with the coating film for pattern-reversing.

Next, the upper part of the coating film for pattern-reversing is removed to expose the resist patterns to the atmosphere (Step of Exposing Resist Pattern to Atmosphere).

Next, the resist patterns are etched from above the coating film for pattern-reversing to remove the resist patterns (First Etching Step), thereby forming a pattern (reversed pattern 6) that is an inverse image of the resist patterns on the coating film for pattern-reversing. For example, when the resist pattern is a line pattern, a space pattern having the same width as the line pattern is formed as the reversed pattern 6, and when the resist pattern is a dot pattern, a hole pattern having the same diameter as the dot pattern is formed as the reversed pattern 6.

Next, the fifth underlayer film is etched from above the coating film for pattern-reversing (Second Etching Step). In this event, the coating film for pattern-reversing on which the reversed pattern 6 is formed functions as an etching mask, and the fifth underlayer film below the reversed pattern 6 is removed. As a result, a pattern (reverse pattern 7) in which the reversed pattern 6 is transferred to the fifth underlayer film is formed.

Subsequently, the fourth lower layer film is etched from above the reversed pattern 7 (Third Etching Step). In this event, the reversed pattern 7 functions as an etching mask, and the fourth underlayer film below the reversed pattern 7 is removed. As a result, a pattern (reverse pattern 8) in which the reversed pattern 7 is transferred to the fourth underlayer film is formed.

Each step will be described in more detail below.

### (Step of Forming Resist Pattern)

The substrate may be the same as that described in [Case of Material for Forming Reversed Pattern Containing Only Organic Material] above, and the step of forming a resist pattern may be the same as that described in [Case of Material for Forming Reversed Pattern Containing Only Organic Material] above, except that the resist patterns are formed on the fifth underlayer film. The fourth underlayer film may be the same as that described above for the first underlayer film, and the fifth underlayer film may be the same as that described above for the second underlayer film.

### (Step of Forming Coating Film for Pattern-Reversing)

The step of forming a coating film for pattern-reversing is the same as that for the two-layer resist process using a material for forming a reversed pattern containing a metal material.

### (Step of Exposing Resist Pattern to Atmosphere)

The step of exposing a resist pattern to the atmosphere is the same as that for the two-layer resist process using a material for forming a reversed pattern containing a metal material.

### (First Etching Step)

In the first etching step, the etching is performed under conditions where material constituting the resist pattern is removed but it is difficult to remove the coating film for pattern-reversing, until the surface of the fifth underlayer film is exposed to the atmosphere. Thereby the resist patterns are removed to form a reversed pattern 6 in the coating film for pattern-reversing.

The etching of the resist pattern can be performed by a publicly known etching method. In the present invention, the etching of the resist pattern is preferably performed by dry etching. As the dry etching method, the same publicly known methods as those described above can be used. The type of etching gas used in this case may be any gas that provides an etching selection ratio between the coating film for pattern-reversing, which serves as an etching mask, and the resist pattern. Examples of the etching gas include oxygen (O₂) gas, sulfur dioxide gas, carbon monoxide gas, carbon dioxide gas, and the above-mentioned halogen-based gases. One of these etching gases may be used, or two or more kinds thereof may be used in mixture. The etching gas may also be mixed with nitrogen gas, rare gas (argon gas, etc.), etc.

As the etching method in the first etching step, oxygen plasma etching (dry etching using plasma obtained from O₂ gas) is particularly preferable.

### (Second Etching Step)

In the second etching step, etching is performed under conditions where material constituting the fifth underlayer film is removed but it is difficult to remove the coating film for pattern-reversing, until the surface of the fourth underlayer film is exposed to the atmosphere. Thereby the fifth underlayer film below the reversed pattern 6 is removed while the coating film for pattern-reversing having the reversed pattern 6 formed functions as an etching mask, and then the reversed pattern 6 is transferred to the fifth underlayer film to form a reversed pattern 7.

The etching of the reverse pattern 6 can be performed by a publicly known etching method. In the present invention, the etching of the fifth underlayer film is preferably performed by dry etching. Publicly As the dry etching method, the same known methods as those described above can be used.

As the type of the etching gases used here, examples include oxygen (O₂) gas, sulfur dioxide gas, carbon monoxide gas, carbon dioxide gas, and the above-mentioned halogen-based gases. One of these etching gases may be used, or two or more kinds thereof may be used in mixture. Furthermore, the etching gas may be mixed with nitrogen gas, a rare gas (such as argon gas), or the like.

The second etching step may be performed consecutively after the first etching step. When the same gas species as those used in the second etching step are used in the first etching step, the etching steps can be performed consecutively under the same conditions.

### (Third Etching Step)

In the third etching step, etching is performed under conditions where material constituting the fourth underlayer film is removed but it is difficult to remove the reversed pattern 7, until the surface of the substrate is exposed to the atmosphere. Thereby the fourth underlayer film below the reversed pattern 7 is removed while the reversed pattern 7 functions as an etching mask, and then the reversed pattern 7 is transferred to the forth underlayer film to form a reversed pattern 8.

The etching of the reverse pattern 8 can be performed by a publicly known etching method. In the present invention, the etching of the reverse pattern 8 is preferably performed by dry etching. As the dry etching method, the same publicly known methods as those described above can be used.

As the etching gas used here, examples include oxygen (O₂) gas, sulfur dioxide gas, or the above-mentioned halogen-based gases. One of these etching gases may be used, or two or more kinds thereof may be used in mixture. Furthermore, the etching gas may be mixed with nitrogen gas, a rare gas (such as argon gas), or the like.

The third etching step may be performed successively following the first and second etching steps. When the same gas species as those in the first and second etching steps are used in the third etching step, the etching steps can be performed successively under the same conditions.

### [Case of Material for Forming Silicon-Containing Reversed Pattern]

In the present invention, when material for forming a silicon-containing reversed pattern is used, a two-layer resist process is used, each of which is described below.

First, a support is prepared in which a sixth underlayer film is laminated on a substrate, and a plurality of resist patterns are formed on the sixth underlayer film (Step of Forming Coating Film for Pattern-Reversing).

Next, the material for forming a silicon-containing reversed pattern is applied onto the sixth underlayer film to form a coating film for pattern-reversing that fills the gaps between the multiple resist patterns (Step of Forming Coating Film for Pattern-Reversing). In this embodiment, the coating film for pattern-reversing is formed to have a film thickness greater than the height of the resist pattern, and the upper surface of the resist patterns is also covered with the coating film for pattern-reversing.

Next, the upper part of the coating film for pattern-reversing is removed to expose the resist pattern to the atmosphere (Step of Exposing Resist Pattern to Atmosphere).

Next, the resist patterns are etched from above the coating film for pattern-reversing to remove the resist pattern (First Etching Step). As a result, a pattern (reversed pattern 9) that is an inverted image of the resist patterns is formed on the coating film for pattern-reversing. For example, when the resist pattern is a line pattern, a space pattern with the same width as the line pattern is formed as the reversed pattern 9, and when the resist pattern is a dot pattern, a hole pattern with the same diameter as the dot pattern is formed as the reversed pattern 9.

Next, the sixth underlayer film is etched from above the coating film for pattern-reversing (Second Etching Step). At this event, the coating film for pattern-reversing on which the reversed pattern 9 is formed functions as an etching mask, and the sixth underlayer film below the reversed pattern 9 is removed. As a result, a pattern (reverse pattern 10) in which the reversed pattern 9 is transferred to the sixth underlayer film is formed.

Each step will be described in more detail below.

### (Step of Forming Resist Pattern), (Step of Forming Coating Film for Pattern-Reversing), and (Step of Exposing Resist Pattern to Atmosphere)

Examples of the substrate include the same as those described above in [Case of Material for Forming Reversed Pattern Containing Only Organic Material] above, and Examples of the step of forming a resist pattern include the same as those described in [Case of Material for Forming Reversed Pattern Containing Only Organic Material] above, except that the resist patterns are formed on the sixth underlayer film. Examples of the sixth underlayer film include the same as those for the first underlayer film, and examples of the step of forming a coating film for pattern-reversing include those similar to those described in [Case of Material for Forming Reversed Pattern Containing Only Organic Material] above except that the material is applied to the resist pattern on the sixth underlayer film, and examples of the step of exposing a resist pattern to the atmosphere also include the same described in Case of Material for Forming Reversed Pattern Containing Only Organic Material] above.

### (First Etching Step)

In the first etching step, etching is performed under conditions where material constituting the resist pattern is removed but it is difficult to remove the coating film for pattern-reversing, until the surface of the sixth under layer is exposed to the atmosphere. Thereby the resist pattern is removed, and then the reversed pattern 9 is formed in the coating film for pattern-reversing.

The etching of the resist pattern can be performed by a publicly known etching method. In the present invention, the etching of the resist pattern is preferably performed by dry etching. As the dry etching method, the same publicly known methods as those described above can be used. The etching gas is preferably, for example, a halogen-based gas. Examples of halogen-based gases include hydrocarbon gases in which part or all of the hydrogen atoms are substituted with halogen atoms such as a fluorine atom and a chlorine atom, and specific examples thereof include fluorocarbon gases and carbon chloride gases. Examples of fluorocarbon gases include CF-based gases, such as tetrafluoromethane (CF₄) gas, and CHF-based gases, such as trifluoromethane (CHF₃) gas.

Examples of carbon chloride-based gases include tetrachloromethane (CCl₄) gas. One of these etching gases may be used, or two or more kinds thereof may be used in mixture. Furthermore, the etching gas may be mixed with nitrogen gas, a rare gas (argon gas, etc.), or the like.

### (Second Etching Step)

In the second etching step, etching is performed under conditions where material constituting the sixth underlayer film is removed but it is difficult to remove the coating film for pattern-reversing, until the surface of the substrate is exposed to the atmosphere. Thereby the sixth underlayer film below the reversed pattern 9 is removed while the coating film for pattern-reversing having the reversed pattern 9 formed functions as an etching mask, and then the reversed pattern 9 is transferred to the sixth underlayer film to form a reversed pattern 10.

The etching of the reversed pattern 9 can be performed by a publicly known etching method. In the present invention, the etching of the reversed pattern 9 is preferably performed by dry etching. As the dry etching method, the same publicly known methods as those described above can be used. Examples of etching gases include oxygen (O₂) gas, sulfur dioxide gas, carbon monoxide gas, carbon dioxide gas, and the above-mentioned halogen-based gases. One of these etching gases may be used, or two or more kinds thereof may be used in mixture. Nitrogen gas, rare gas (argon gas, etc.), etc. may also be mixed with the etching gas.

As the etching method in the second etching step, oxygen plasma etching (dry etching using plasma obtained from O₂ gas) is particularly preferable.

The laminated pattern formed using the various materials for forming a reversed pattern, as described above, can be used for various purposes. For example, it is considered to use it directly as a structure on a substrate (e.g., a circuit, etc.) as it is or as a mask for transferring the same pattern as the laminated pattern onto a substrate.

Alternatively, the upper layer pattern may be removed from the laminated pattern, leaving only the underlayer pattern. The underlayer pattern can be used for various purposes, similar to the laminated pattern described above. For example, a semiconductor device or the like can be manufactured by etching a substrate while using the underlayer pattern as a mask.

As described above, the laminated pattern formed using various materials for forming a reversed pattern makes it possible to obtain a space pattern or a hole pattern as a reverse pattern, and therefore the resist pattern is preferably a line pattern and/or a dot pattern.

Such a reversed pattern is superior in pattern formability in terms of resolution, shape, and lithography margin (for example, margins (EL margin and DOF margin) for exposure dose and depth of focus, perpendicularity of pattern shape, etc.) when compared to directly forming an isolated space pattern (trench pattern), a space and line pattern, a hole pattern, etc. That is, since these patterns require removal of a tiny portion or a finely formed area from the resist film, the pattern formation is forced to be performed under a weak incident light intensity, as described above, and the pattern formability is greatly limited. However, since the pattern formability when forming the above-mentioned reversed pattern depends on the pattern formability when forming a resist pattern (an isolated line pattern, a line and space pattern, a dot pattern, or the like), the pattern formability is less limited when compared to directly forming a trench pattern, a space and line pattern, or a hole pattern, resulting in forming a preferable resist pattern.

### [Resist Patterning Process]

When the inventive resist composition is used for manufacturing various integrated circuits, publicly known lithography techniques can be applied. Examples of the patterning process includes a method including steps of: forming a resist film using the resist composition described above on a substrate, or on an underlayer film of a substrate having the underlayer film laminated thereon; exposing the resist film to a high-energy beam; and developing the exposed resist film, using a developer if necessary.

Firstly, the inventive resist composition is applied onto a substrate for manufacturing an integrated circuit, onto an underlayer film of a substrate (Si, SiO₂, SiN, SiON, TiN, WSi, BPSG, SOG, organic antireflective film, etc.) on which the underlayer film is laminated, onto a substrate for manufacturing a mask circuit, or onto an underlayer film of a substrate (Cr, CrO, CrON, MoSi₂, SiO₂, etc.) on which the underlayer film is laminated, by an appropriate applying method, such as spin coating, roll coating, flow coating, dip coating, spray coating, or doctor coating, so that the thickness of the coating film is 0.01 to 2 μm. The resultant is prebaked on a hot plate preferably at 60 to 200° C. for 10 seconds to 30 minutes, more preferably 80 to 180° C. for 30 seconds to 20 minutes, thus a resist film is formed. Note that an underlayer film means a film formed between a substrate and a resist film in a multilayer resist process. The underlayer film is not particularly limited, and a conventionally publicly known film can be used.

Subsequently, the resist film is exposed to a high-energy beam. Examples of the high-energy beam include an i-line, an ultraviolet ray, a deep ultraviolet ray, an electron beam (EB), an extreme ultraviolet ray (EUV), X-rays, soft X-rays, an excimer laser beam, a γ-ray, and a synchrotron radiation. When an i-line, an ultraviolet ray, a deep ultraviolet ray, an EUV, X-rays, soft X-rays, an excimer laser beam, a γ-ray, a synchrotron radiation, or the like is used as the high-energy beam, the irradiation is performed directly or while using a mask for forming a target pattern at an exposure dose of preferably about 1 to 300 mJ/cm², more preferably about 10 to 200 mJ/cm². When EB is used as the high-energy beam, drawing is performed directly or while using a mask for forming a target pattern at an exposure dose of preferably about 0.1 to 8000 μC/cm², more preferably about 0.5 to 5000 μC/cm². Note that the inventive resist composition is suitable for fine patterning particularly with an i-line, a KrF excimer laser beam, an ArF excimer laser beam, an EB, or an EUV, among the high-energy beams.

After the exposure, PEB is performed as necessary. In this event, the PEB is performed after the exposure on a hot plate or in an oven preferably under the conditions of 30 to 200° C. for 10 seconds to 30 minutes, more preferably 60 to 120° C. for 30 seconds to 20 minutes.

After the exposure or after the PEB, development is performed by using a developer as necessary to perform patterning. Examples of the developer used in this event include: alkali aqueous solutions, such as an aqueous solution of tetramethylammonium hydroxide and an aqueous solution of tetrabutylammonium hydroxide; and organic solvents, such as 2-octanone, 2-nonanone, 2-heptanone, 3-heptanone, 4-heptanone, 2-hexanone, 3-hexanone, diisobutyl ketone, 5-methyl-2-hexanone, methylcyclohexanone, acetophenone, methylacetophenone, isopropyl alcohol, isoamyl alcohol, n-butanol, tert-butyl alcohol, tert-pentyl alcohol, n-pentanol, cyclohexanol, formic acid, acetic acid, propionic acid, propyl acetate, butyl acetate, isobutyl acetate, pentyl acetate, butenyl acetate, isopentyl acetate, cyclohexyl acetate, 4-tert-butylcyclohexyl acetate, octyl acetate, isobornyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, phenylmethyl acetate, phenylethyl acetate, benzyl formate, phenylethyl formate, methyl 3-phenylpropionate, benzyl propionate, 2-phenylethyl acetate, 2-propanol, 3-methoxybutanol, 3-methyl-3-methoxybutanol, 1-methoxy-2-propanol, 1-ethoxy-2-propanol, 3-methyl-1-butanol, diacetone alcohol, 4-methyl-2-pentanol, 3-methylcyclohexanol, 3,5,5-trimethylhexyl alcohol, 2,6-dimethyl-4-heptanol, toluene, anisole, and s-caprolactone. One kind of these developers may be used, or two or more kinds thereof may be used in mixture.

After the development, rinsing is performed as necessary. The rinsing solution is preferably a solvent that is miscible with the developer but does not dissolve the resist film. Examples of such solvents to be used preferably include: alcohols having 3 to 10 carbon atoms; ether compounds having 8 to 12 carbon atoms; and solvents based on alkanes, alkenes, alkynes, or aromatic, each having 6 to 12 carbon atoms.

The rinsing can reduce occurrence of resist pattern collapse and defects. The rinsing is not always necessary, and not performing the rinsing can reduce the amount of solvent used.

### Example

Hereinafter, the present invention will be specifically described with reference to Synthesis Example, Preparation Example, Comparative Preparation Example, Examples, and Comparative Examples. However, the present invention is not limited thereto.

### [1] Synthesis of Polymer for Resist Composition

The compounds shown below were used to synthesize the polymers (P-1 to P-3) for the resist compositions.

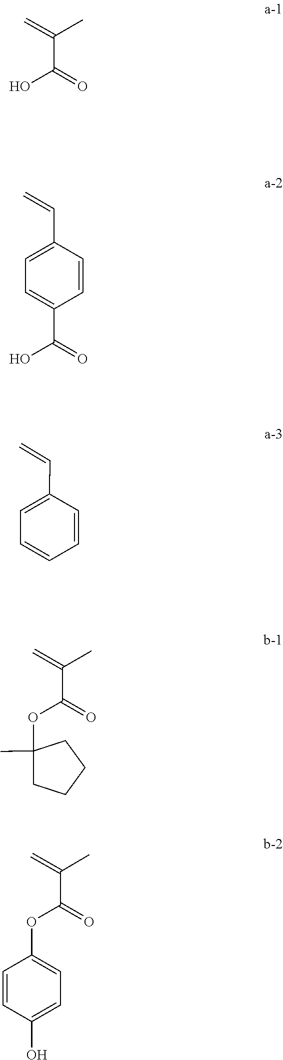

### [Synthesis Example 1-1] Synthesis of Polymer (P-1)

Under a nitrogen atmosphere, a flask was charged with 56 g of monomer (a-1), 36 g of monomer (a-3), 5.4 g of V-601 (manufactured by FUJIFILM Wako Pure Chemical Corporation), and 180 g of MEK to prepare a monomer-polymerization initiator solution. 55 g of MEK was charged to a separate flask under a nitrogen atmosphere and heated to 80° C. with stirring, and the monomer-polymerization initiator solution was then added thereto dropwise over 4 hours. After the dropwise addition was completed, stirring was continued for 2 hours while maintaining the temperature of the polymerization solution at 80° C., and then the solution was cooled to room temperature. The obtained polymerization solution was added dropwise to 4,000 g of hexane that was being vigorously stirred, and the precipitated polymer was separated by filtration. The obtained polymer was washed twice with hexane (1,200 g) and then vacuum-dried at 50° C. for 20 hours to obtain a white powdery polymer (P-1) (yield: 90 g, 98%). The polymer (P-1) had an Mw of 8,000 and an Mw/Mn of 1.42. Note that the Mw was measured in terms of polystyrene by GPC using THF as a solvent.

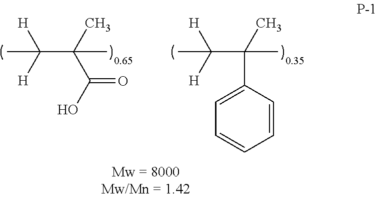

### [Synthesis Examples 1-2 and 1-3] Synthesis of Polymer (P-2 and P-3)

The polymers shown in Table 1 below were synthesized in the same manner as in Synthesis Example 1-1, except that the types and blending ratios of the respective monomers were changed.

TABLE 1

| | | Introduction | | Introduction | | |
|---|---|---|---|---|---|---|
| Base | | ratio | | ratio | | |
| Polymer | Unit 1 | (mol %) | Unit 2 | (mol %) | Mw | Mw/Mn |
| P-1 | a-1 | 65 | a-3 | 35 | 8000 | 1.42 |
| P-2 | a-2 | 65 | a-3 | 35 | 8000 | 1.44 |
| P-3 | b-1 | 60 | b-2 | 40 | 8500 | 1.45 |

### [2] Preparation of Resist Composition

### Preparation Examples 1-1 to 1-10 and Comparative Preparation Example 1-1

As preparation examples, a hypervalent iodine compound and a carboxy group-containing compound were dissolved in the composition ratio shown in Table 2 below in a solvent containing 0.01 mass % of a surfactant (PF-636, manufactured by OMNOVA Solutions Inc.), and the resulting solution was filtered through a 0.2 μm Teflon (registered trademark) filter to prepare resist compositions (R-01 to R-10). Furthermore, as a Comparative Preparation Example, a polymer, a photo-acid generator, and a sensitivity modifier were dissolved in the composition ratio shown in Table 3 below in a solvent containing 0.01 mass % of a surfactant (PF-636, manufactured by OMNOVA Solutions Inc.), and the resulting solution was filtered through a 0.2 μm Teflon (registered trademark) filter to prepare a resist composition (CR-01).

TABLE 2

| | | | Carboxy group- | | | | |
|---|---|---|---|---|---|---|---|
| | | | containing | | | | |
| | | Hypervalent | Compound | Solvent 1 | | Solvent 2 | |
| | | iodine compound | (parts by | (parts by | | (parts by | |
| | Resist | (parts by mass) | mass) | mass) | | mass) | |
| Preparation | R-01 | I-1 (10) | P-1 (9) | PGMEA | (800) | AcOH | (200) |
| Example | | | | | | | |
| 1-1 | | | | | | | |
| Preparation | R-02 | I-2 (19) | P-1 (9) | PGMEA | (800) | AcOH | (200) |
| Example | | | | | | | |
| 1-2 | | | | | | | |
| Preparation | R-03 | I-3 (10) | P-2 (12) | PGMEA | (800) | AcOH | (200) |
| Example | | | | | | | |
| 1-3 | | | | | | | |
| Preparation | R-04 | I-4 (19) | P-2 (12) | PGMEA | (800) | AcOH | (200) |
| Example | | | | | | | |
| 1-4 | | | | | | | |
| Preparation | R-05 | I-5 (10) | m-1 (7) | PGMEA | (800) | AcOH | (200) |
| Example | | | | | | | |
| 1-5 | | | | | | | |
| Preparation | R-06 | I-6 (19) | m-1 (7) | PGMEA | (800) | AcOH | (200) |
| Example | | | | | | | |
| 1-6 | | | | | | | |
| Preparation | R-07 | I-7 (10) | P-1 (9) | PGMEA | (800) | AcOH | (200) |
| Example | | | | | | | |
| 1-7 | | | | | | | |
| Preparation | R-08 | I-8 (19) | P-1 (9) | PGMEA | (800) | AcOH | (200) |
| Example | | | | | | | |
| 1-8 | | | | | | | |
| Preparation | R-09 | I-9 (10) | P-2 (12) | PGMEA | (800) | AcOH | (200) |
| Example | | | | | | | |
| 1-9 | | | | | | | |
| Preparation | R-10 | I-10 (19) | P-2 (12) | PGMEA | (800) | AcOH | (200) |
| Example | | | | | | | |
| 1-10 | | | | | | | |

TABLE 3

| | | | Photo-acid | Sensitivity | | |
|---|---|---|---|---|---|---|
| | | Polymer | generator | modifier | Solvent 1 | Solvent 2 |
| | Resist | (parts by | (parts by | (parts by | (parts by | (parts by |
| | composition | mass) | mass) | mass) | mass) | mass) |
| Comparative | CR-01 | P-3 (80) | PAG-1 (19) | Q-1 (6) | PGMEA | GBL |
| Preparation | | | | | (1890) | (210) |
| Example 1-1 | | | | | | |

In Tables 2 and 3, the hypervalent iodine compounds (I-1 to I-10), the carboxy group-containing compound (m-1), the photoacid generator (PAG-1), the sensitivity adjuster (Q-1), and the solvents are as follows.

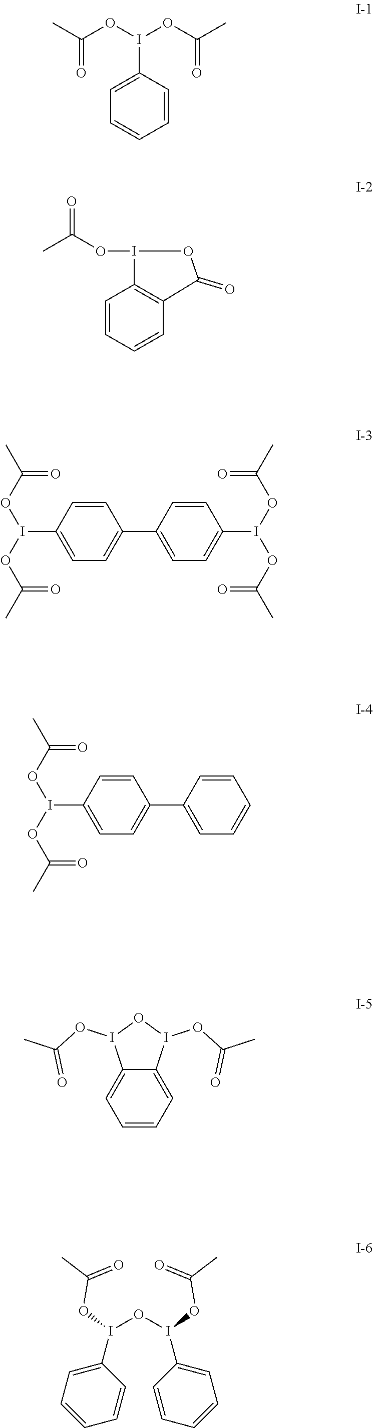

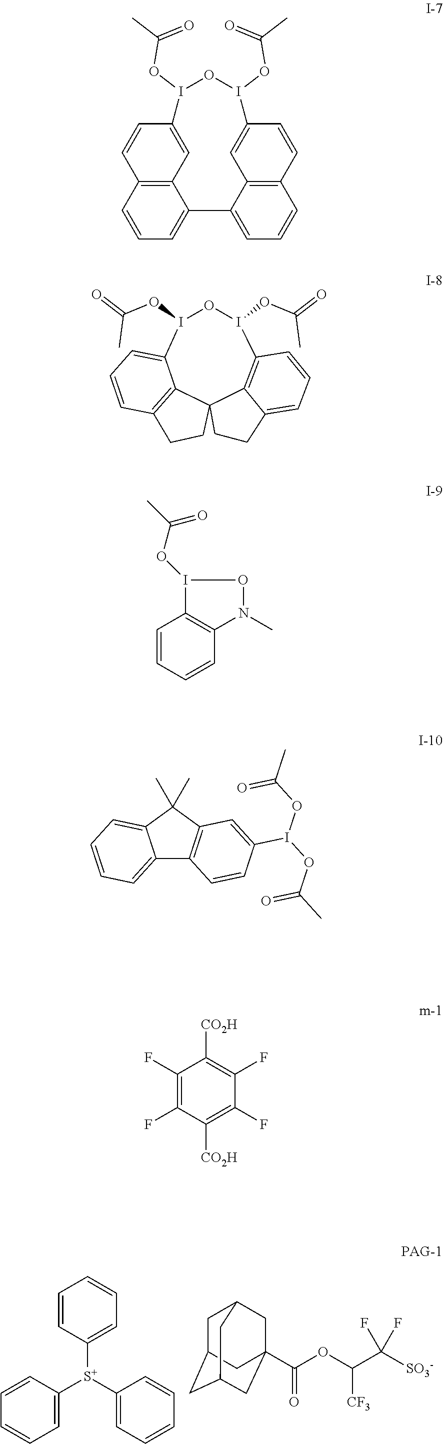

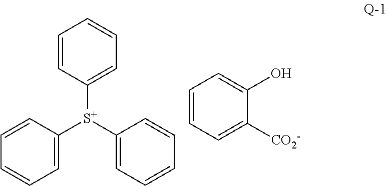

### Solvent: AcOH (Acetic Acid)

PGMEA (propylene glycol monomethyl ether acetate)
GBL (gamma-butyrolactone)

### [3] Synthesis of Material for Forming Silicon-containing Reversed Pattern

### Synthesis Example 2-1

A mixture of 35.2 g of compound 101 and 9.4 g of compound 102 was added to a mixture of 75 g of deionized water and 0.5 g of 7% nitric acid (mole ratio: 77/23), and the mixture was kept at 25° C. for 24 hours to allow hydrolytic condensation. After the reaction was completed, 450 g of propylene glycol monoethyl ether (PGEE) and 1.0 g of a 24% aqueous solution of maleic acid were added, and the water and by-produced alcohol used in the hydrolytic condensation were distilled off under reduced pressure to obtain 210 g of a PGEE solution of a polysiloxane compound (Compound 1) (compound concentration 10%). The polystyrene-equivalent molecular weight of the polysiloxane compound (Compound 1) was measured and found to be Mw=2750. The charging amounts of the monomer each are shown in Table 4.

### Synthesis Examples 2-2 to 2-4

Polysiloxane compounds (Compounds 2 to 4) were synthesized using the amounts of monomers each listed in Table 4 below, in the same manner as in Synthesis Example 2-1, except that the monomers used were changed.

TABLE 4

| | Charging amounts of monomers (mol %) | | | | | |
|---|---|---|---|---|---|---|
| | Compound 101 | Compound 102 | Compound 103 | Compound 104 | Compound 105 | Mw |
| Compound 1 | 77 | 23 | | | | 2750 |
| Compound 2 | 67 | 23 | 10 | | | 2650 |
| Compound 3 | 50 | | | 50 | | 3000 |
| Compound 4 | 50 | | | | 50 | 3200 |

Si(OMe)₄
Compound 101

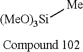

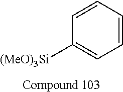

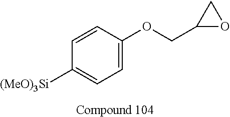

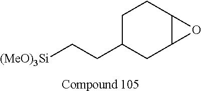

### [4] Preparation of Solution of Material Composition for Forming Silicon-Containing Reversed Pattern

Each of the polysiloxane compounds 1 to 4 obtained in Synthesis Examples 2-1 to 2-4 above, a crosslinking catalyst, an acid, a solvent, and water were mixed in the proportions shown in Table 5, and the mixture was filtered through a 0.1 μm fluororesin filter to prepare a solution of a material composition for forming a silicon-containing reversed pattern. The solutions are designated Sol. 1 to Sol. 4, respectively.

TABLE 5

| | | Crosslinking | | | |
|---|---|---|---|---|---|
| | Polysiloxane | catalyst | Acid | Solvent | Water |
| | (parts by | (parts by | (parts by | (parts by | (parts by |
| | mass) | mass) | mass) | mass) | mass) |
| Sol. 1 | Compound | QBANO₃ | Maleic acid | PGEE | Water |
| | 1 (1) | (0.03) | (0.01) | (100) | (10) |
| Sol. 2 | Compound | QBANO₃ | Maleic acid | PGEE | Water |
| | 2 (1) | (0.03) | (0.01) | (100) | (10) |
| Sol. 3 | Compound | TPSNf | Maleic acid | PGEE | |
| | 3 (1) | (0.03) | (0.01) | (110) | |
| Sol. 4 | Compound | TPSNf | Maleic acid | PGEE | |
| | 4 (1) | (0.03) | (0.01) | (110) | |

QBANO₃: Tetrabutylammonium nitrate
TPSNf: Triphenylsulfonium nonafluorobutanesulfonate
PGEE: Propylene glycol monoethyl ether

### [5] Evaluation of Filling Property

Spin-on carbon ODL-301 (carbon content: 88 mass %) manufactured by Shin-Etsu Chemical Co., Ltd. is applied onto a silicon substrate, and baked at 350° C. for 60 seconds to form a resist underlayer film with a thickness of 200 nm. Each of the resist compositions (R-01 to R-10, and CR-01) were applied thereon respectively using a spinner, prebaked (PAB) at 130° C. for 60 seconds, and dried to form a resist film with a thickness of 25 nm.

The resist film then underwent drawing using an ELS-F125 manufactured by ELIONIX INC. Next, a PEB treatment was performed at 90° C. for 60 seconds, and then R-01, R-02, and R-05 to R-08 were developed for 30 seconds with butyl acetate, and R-03, R-04, R-09, R-10, and CR-01 were developed for 30 seconds with a 2.38 mass % aqueous solution of tetramethylammonium hydroxide (TMAH).

As a result, a line-and-space resist pattern (L/S pattern) with a line width of 20 nm and a pitch of 40 nm was formed on the resist underlayer film. Note that R-01, R-02, and R-05 to R-08 were formed to positive patterns in which the exposed areas were removed by the development, while R-03, R-04, R-09, and R-10 were formed to negative patterns in which the unexposed areas were removed by the development.

The solutions (Sol. 1 to Sol. 4) of the material composition for forming a silicon-containing reversed pattern were applied onto the resist underlayer film in which the L/S pattern had been formed using a spinner at a rotation speed of 1500 rpm, baked at 250° C. for 60 seconds, and dried to form a coating film for pattern-reversing with a thickness of approximately 30 nm. The cross-section of the obtained coating film for pattern-reversing was observed using an SEM (scanning electron microscope). As a result, in the cases where the solutions Sol. 1 to Sol. 4 of the material composition for forming a silicon-containing reversed pattern were applied on the resist patterns R-01 to R-10, the cross-sections were homogeneous with no voids, and thus it was confirmed that each of the materials for forming a reversed pattern was embedded in the spaces of the L/S patterns without any gap. Furthermore, in the case where the solutions (Sol. 1 to Sol. 4) of the material composition for forming a silicon-containing reversed pattern were applied on CR-01, the cross-section showed that each material for forming a reversed pattern mixed with the resist pattern, making it impossible to find a boundary between the resist pattern and the reversing material.

### [6] Evaluation of Reversed Pattern Formation (Reversing of L/S Pattern)

Spin-on carbon ODL-301 (carbon content: 88 mass %) manufactured by Shin-Etsu Chemical Co., Ltd. is applied onto a silicon substrate, and baked at 350° C. for 60 seconds to form a resist underlayer film with a thickness of 150 nm. Each of the resist compositions (R-01 to R-10) was applied respectively thereon by spin coating, prebaked (PAB) on a hot plate at 130° C. for 60 seconds to form a resist film with a thickness of 25 nm. A 40 nm line and space (LS) 1:1 pattern was exposed on the resultant resist film by an EUV scanner NXE3400 (NA: 0.33, σ: 0.9, 90-degree dipole illumination) manufactured by ASML, and the resultant resist film was subjected to PEB treatment on a hot plate at 90° C. for 60 seconds. Subsequently, R-01, R-02, and R-05 to R-08 were developed with butyl acetate for 30 seconds, and R-03, R-04, R-09, and R-10 were developed with a 2.38 mass % aqueous solution of tetramethylammonium hydroxide (TMAH) for 30 seconds.

Each of the solutions (Sol. 1 to Sol. 4) of the material composition for forming a silicon-containing reversed pattern was applied onto the resist underlayer film in which the L/S pattern had been formed using a spinner at a rotation speed of 1500 rpm, followed by baking at 250° C. for 60 seconds and drying to form a coating film for pattern-reversing having a thickness of approximately 30 nm.

The substrates on which the coating film for pattern-reversing was formed were subjected to oxygen plasma etching treatment (pressure: 0.67 Pa, upper RF: 750 W, lower RF: 150 W, temperature: 0° C., treatment time: 70 seconds) using a plasma etching apparatus (Tokyo Electron Ltd., apparatus name: Telius) with a mixed gas of O₂ gas and N₂ gas (flow ratio: O₂/N₂=46/54). The cross-section of the substrates after the etching treatment were observed by SEM.

As a result, it was confirmed that the line patterns of the L/S pattern and the resist underlayer film under the line patterns were removed, and a pattern, in which space patterns with 20 nm width and approximately 200 nm height were equally arranged, was formed on the substrate. Furthermore, the pattern had a good shape with high rectangularity of the cross-section of the line top portion (portion of coating film for pattern-reversing).

### [7] Evaluation of Reversed Pattern Formation (Reversing of CH Pattern)

Spin-on carbon ODL-301 (carbon content: 88 mass %) manufactured by Shin-Etsu Chemical Co., Ltd. is applied onto a silicon substrate, and baked at 350° C. for 60 seconds to form a resist underlayer film with a thickness of 150 nm. Each of the resist compositions (R-01 to R-10) was applied respectively thereon by spin coating, prebaked (PAB) on a hot plate at 130° C. for 60 seconds to form a resist film with a thickness of 40 nm. A contact hole pattern (CH pattern) was exposed on the resultant resist film by an EUV scanner NXE3400 (NA: 0.33, σ: 0.9/0.6, quadrupole illumination, with a mask having a hole pattern with a pitch of 64 nm and +20% bias (on-wafer size)) manufactured by ASML, and the resultant resist film was subjected to PEB treatment on a hot plate at 90° C. for 60 seconds. Subsequently, R-01, R-02, and R-05 to R-08 were developed with butyl acetate for 30 seconds, and R-03, R-04, R-09, and R-10 were developed with a 2.38 mass % aqueous solution of tetramethylammonium hydroxide (TMAH) for 30 seconds, to obtain a hole pattern with a dimension of 32 nm.

Each of the solutions (Sol. 1 to Sol. 4) of the material composition for forming a silicon-containing reversed pattern was applied respectively onto the resist underlayer film in which the CH pattern had been formed using a spinner at a rotation speed of 800 rpm, followed by baking at 250° C. for 60 seconds and drying to form a coating film for pattern-reversing having a thickness of approximately 45 nm.

The substrate on which the coating film for pattern-reversing was formed was subjected to an etching treatment (pressure: 4 Pa; upper RF: 500 W, lower RF: 1800 W; temperature: 20° C.; treatment time: 2 seconds each) using a plasma etching apparatus (manufactured by Tokyo Electron Limited, apparatus name: Telius) with a mixed gas of CF₄ gas, Ar gas, and N₂ gas (flow ratio: CF₄/Ar/N₂=9/57/34).

The cross-section of the substrates after the etching treatment were observed by SEM, and the results showed that the thickness of the coating film for pattern-reversing was about 35 nm in all cases of R-01 to R-10.

The substrate after the etching process above was subjected to an oxygen plasma etching process (pressure: 0.67 Pa, upper RF: 750 W, lower RF: 150 W; temperature: 0° C., processing time: 65 seconds) using a plasma etching apparatus (manufactured by Tokyo Electron Limited, apparatus name: Telius) with a mixed gas of O₂ gas and N₂ gas (flow ratio: O₂/N₂=46/54). The cross-section of the substrates after the etching process were observed by SEM.

The SEM observation of the top surface and cross-section of the substrate after the etching treatment revealed that the initially formed dot pattern and the resist underlayer film under the dot pattern had been removed, forming a hole pattern having the same diameter with a depth of approximately 180 nm. Furthermore, the cross-sectional shape was excellent, with a high rectangularity at the top portion (portion of the coating film for pattern-reversing).

As is clear from the above results, the inventive material for forming a reversed pattern has good filling properties and can fill even fine resist patterns. Furthermore, it is revealed that the coating film for pattern-reversing formed using the inventive material for forming a reversed pattern had a large etching selection ratio in terms of the resist film and in terms of the resist underlayer film in O₂ plasma etching, and that the shape of the reversed pattern formed by removing the resist pattern by etching was also excellent.

The present description includes the following embodiments.
[1]: A patterning process for forming a pattern, comprising the steps of:
   (i) forming a resist pattern on a support using a resist film obtained from a resist composition comprising a hypervalent iodine compound, a carboxy group-containing compound, and a solvent;
   (ii) applying a material for forming a reversed pattern onto the support having the resist pattern formed to form a coating film for pattern-reversing; and
   (iii) removing the resist pattern by etching to form a reversed pattern.
[2]: The patterning process of the above [1], wherein one or more kinds selected from the hypervalent iodine compounds represented by the following formulae (1) to (10) are used as the hypervalent iodine compound,

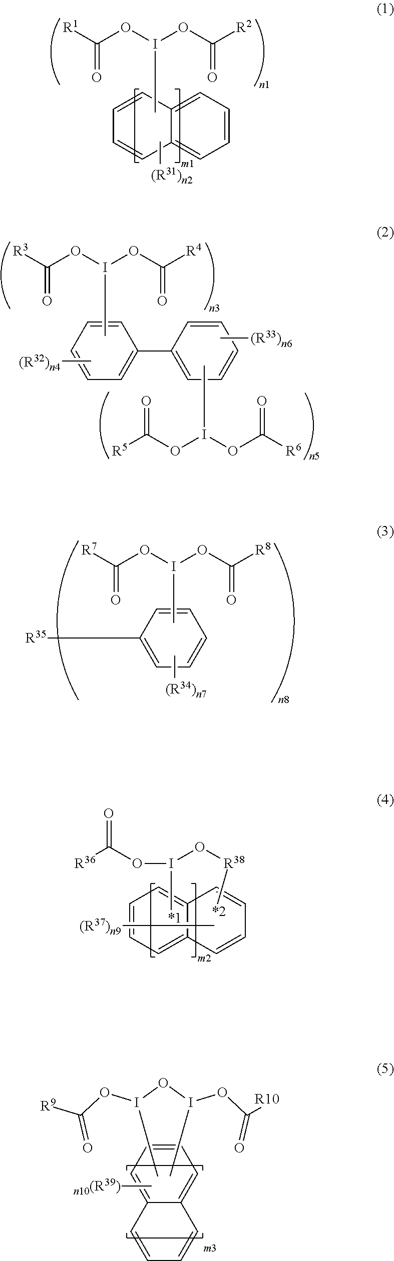

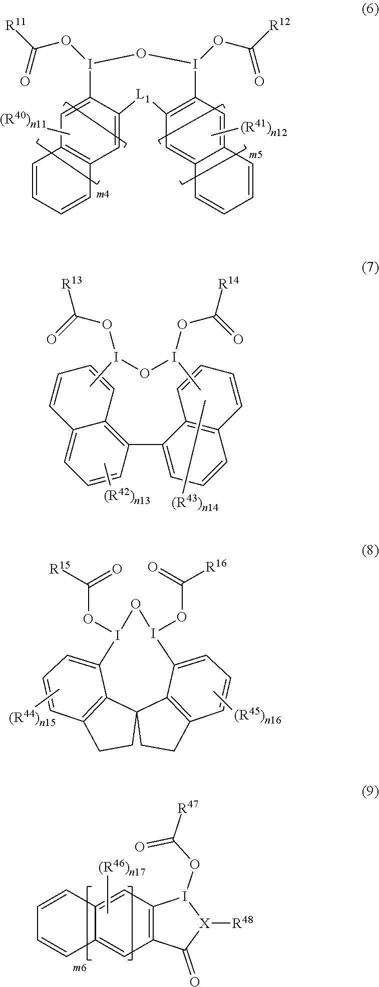

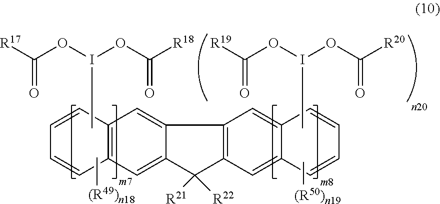

wherein m1 represents 0, 1, or 2, when m1 is 0, n1 represents 1, 2, or 3, n2 represents 0, 1, 2, 3, 4, or 5, and 1≤n1+n2≤6 is satisfied, when m1 is 1, n1 represents 1, 2, or 3, n2 represents 0, 1, 2, 3, 4, 5, 6, or 7, and 1≤n1+n2≤8 is satisfied, and when m1 is 2, n1 represents 1, 2, or 3, n2 represents 0, 1, 2, 3, 4, 5, 6, 7, 8, or 9, and 1≤n1+n2≤10 is satisfied;
n3 represents 1 or 2, n4 represents 0, 1, 2, 3, or 4, and 1≤n3+n4≤5 is satisfied; n5 represents 1 or 2, n6 represents 0, 1, 2, 3, or 4, and 1≤n5+n6≤5 is satisfied;
n7 represents 0, 1, 2, 3, or 4; n8 represents 1, 2, 3, or 4;
m2 represents 0, 1, or 2, when m2 is 0, n9 represents 0, 1, 2, 3, or 4, when m2 is 1, n9 is 0, 1, 2, 3, 4, 5, or 6, and when m2 is 2, n9 is 0, 1, 2, 3, 4, 5, 6, 7, or 8;
m3 represents 0, 1, or 2, when m3 is 0, n10 is 0, 1, 2, 3, or 4, when m3 is 1, n10 is 0, 1, 2, 3, 4, 5, or 6, and when m3 is 2, n10 is 0, 1, 2, 3, 4, 5, 6, 7, or 8;
m4 represents 0 or 1, when m4 is 0, n11 represents 0, 1, 2, 3, or 4, and when m4 is 1, n11 represents 0, 1, 2, 3, 4, 5, or 6;
m5 represents 0 or 1, when m5 is 0, n12 represents 0, 1, 2, 3, or 4, and when m5 is 1, n12 represents 0, 1, 2, 3, 4, 5, or 6;
n13 and n14 represent 0, 1, 2, 3, 4, 5, or 6;
n15 and n16 represent 0, 1, 2, or 3;
m6 represents 0, 1, or 2, when m6 is 0, n17 represents 0, 1, 2, 3, or 4, when m6 is 1, n17 represents 0, 1, 2, 3, 4, 5, or 6, and when m6 is 2, n17 represents 0, 1, 2, 3, 4, 5, 6, 6, 7, or 8;
m7 represents 0, 1, or 2, when m7 is 0, n18 represents 0, 1, 2, or 3, when m7 is 1, n18 represents 0, 1, 2, 3, 4, or 5, and when m7 is 2, n18 represents 0, 1, 2, 3, 4, 5, 6, or 7;
m8 represents 0, 1, or 2, when m8 is 0, n19 represents 0, 1, 2, or 3, and n20 represents 0 or 1, when m8 is 1, n19 represents 0, 1, 2, 3, 4, or 5, and n20 is 0 or 1, and when m8 is 2, n19 represents 0, 1, 2, 3, 4, 5, 6, or 7, and n20 represents 0 or 1;
R¹ to R²² each independently represent a halogen atom or a hydrocarbyl group having 1 to 10 carbon atoms and optionally having a heteroatom, R²¹ and R²² may be bonded to each other to form a ring together with the carbon atoms to which they are bonded and the atoms between the carbon atoms to which they are bonded;
R³¹ to R³⁴, R³⁷, R³⁹ to R⁴⁶, R⁴⁹, and R⁵⁰ each independently represent a halogen atom or a hydrocarbyl group having 1 to 40 carbon atoms and optionally having a heteroatom, when n2 is 2 or more, R³¹s may be identical to or different from each other, and a plurality of R³¹s may be bonded to each other to form a ring together with the carbon atoms of the aromatic ring to which they are bonded, when n4 is 2 or more, R³²s may be identical to or different from each other, and a plurality of R³²s may be bonded to each other to form a ring together with the carbon atoms of the aromatic ring to which they are bonded, when n6 is 2 or more, R³³s may be identical to or different from each other, and a plurality of R³³s may be bonded to each other to form a ring together with the carbon atoms of the aromatic ring to which they are bonded, when n7 is 2 or more, R³⁴s may be identical to or different from each other, and a plurality of R³⁴s may be bonded to each other to form a ring together with the carbon atoms of the aromatic ring to which they are bonded, when n9 is 2 or more, R³⁷s may be identical to or different from each other, and a plurality of R³⁷s may be bonded to each other to form a ring together with the carbon atoms of the aromatic ring to which they are bonded, when n10 is 2 or more, R³⁹s may be identical to or different from each other, and a plurality of R³⁹s may be bonded to each other to form a ring together with the carbon atoms of the aromatic ring to which they are bonded, when n11 is 2 or more, R⁴⁰s may be identical to or different from each other, and a plurality of R⁴⁰s may be bonded to each other to form a ring together with the carbon atoms of the aromatic ring to which they are bonded, when n12 is 2 or more, R⁴¹s may be identical to or different from each other, and a plurality of R⁴¹s may be bonded to each other to form a ring together with the carbon atoms of the aromatic ring to which they are bonded, when n13 is 2 or more, R⁴²s may be identical to or different from each other, and a plurality of R⁴²s may be bonded to each other to form a ring together with the carbon atoms of the aromatic ring to which they are bonded, when n14 is 2 or more, R⁴³s may be identical to or different from each other, and a plurality of R⁴³s may be bonded to each other to form a ring together with the carbon atoms of the aromatic ring to which they are bonded, when n15 is 2 or more, R⁴⁴s may be identical to or different from each other, and a plurality of R⁴⁴s may be bonded to each other to form a ring together with the carbon atoms of the aromatic ring to which they are bonded, when n16 is 2 or more, R⁴⁵s may be identical to or different from each other, and a plurality of R⁴⁵s may be bonded to each other to form a ring together with the carbon atoms of the aromatic ring to which they are bonded, when n17 is 2 or more, R⁴⁶s may be identical to or different from each other, and a plurality of R⁴⁶s may be bonded to each other to form a ring together with the carbon atoms of the aromatic ring to which they are bonded, when n18 is 2 or more, R⁴⁹s may be identical to or different from each other, and a plurality of R⁴⁹s may be bonded to each other to form a ring together with the carbon atoms of the aromatic ring to which they are bonded, and when n19 is 2 or more, R⁵⁰s may be identical to or different from each other, and a plurality of R⁵⁰s may be bonded to each other to form a ring together with the carbon atoms of the aromatic ring to which they are bonded;
R³⁵ represents an (n8)-valent hydrocarbon group having 1 to 40 carbon atoms or an (n8)-valent heterocyclic group having 2 to 40 carbon atoms, when n8 is 2, R³⁵ may be an ether bond, a carbonyl group, an azo group, a thioether bond, a carbonate bond, a carbamate bond, a sulfinyl group, a sulfonyl group, or a thioketone bond, part or all of the hydrogen atoms of the (n8)-valent hydrocarbon group or the (n8)-valent heterocyclic group may be substituted with a group having a heteroatom, part of the —CH₂— groups of the (n8)-valent hydrocarbon group may be substituted with a group having a heteroatom, and R³⁴ and R³⁵ may be bonded to each other to form a ring together with the carbon atoms to which they are bonded and the atoms between the carbon atoms to which they are bonded;
R³⁶ represents a halogen atom or a hydrocarbyl group having 1 to 10 carbon atoms and optionally having a heteroatom;
R³⁸ represents a carbonyl group or a hydrocarbylene group having 1 to 10 carbon atoms and optionally having a heteroatom;
*1 and *2 represent attachment points to carbon atoms of the aromatic ring in the formula, and *1 and *2 are bonded to adjacent carbon atoms of the aromatic ring;
L₁ represents no bond, a single bond, —O—, —S—, —NH—, or —CH₂—;
R⁴⁷ each independently represents a halogen atom or a hydrocarbyl group having 1 to 10 carbon atoms and optionally having a heteroatom;
“X” represents a nitrogen atom or a sulfur atom, and when it is a nitrogen atom, it may have R⁴⁸; and
R⁴⁸ represents a hydrogen atom, a halogen atom, or a hydrocarbyl group having 1 to 20 carbon atoms and optionally having a heteroatom.
[3]: The patterning process of the above [1] or [2], wherein a carboxy group-containing polymer having a repeating unit represented by the following general formula (11) or a carboxylic acid compound represented by the following general formula (12) is used as the carboxy group-containing compound,

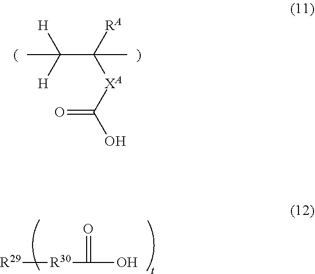

wherein R^{A} represents a hydrogen atom, a halogen atom, a methyl group, or a trifluoromethyl group;
X^{A} represents a single bond, a phenylene group, a naphthylene group, or *—C(═O)—O—X^{A1}—, wherein X^{A1} is a saturated hydrocarbylene group having 1 to 10 carbon atoms, a phenylene group, or a naphthylene group, the saturated hydrocarbylene group may have a hydroxy group, an ether bond, an ester bond, or a lactone ring, and “*” represents an attachment point to a carbon atom in the main chain;
“t” represents 1, 2, 3, or 4;
R²⁹ represents a t-valent hydrocarbon group having 1 to 40 carbon atoms or a t-valent heterocyclic group having 2 to 40 carbon atoms, when “t” is 2, R²⁹ may be an ether bond, a carbonyl group, an azo group, a thioether bond, a carbonate bond, a carbamate bond, a sulfinyl group, or a sulfonyl group, part or all of the hydrogen atoms of the t-valent hydrocarbon group or the t-valent heterocyclic group may be substituted with a group having a heteroatom, and part of the —CH₂— groups of the t-valent hydrocarbon group may be substituted with a group having a heteroatom;
and R³⁰ represents a single bond or a hydrocarbylene group having 1 to 10 carbon atoms, part or all of the hydrogen atoms of the hydrocarbylene group may be substituted with a group having a heteroatom, part of the —CH₂— of the hydrocarbylene group may be substituted with a group having a heteroatom, and when “t” is 2 to 4, R³⁰s may be identical to or different from each other.
[4] The patterning process of any one of the above [1] to [3], wherein a resist underlayer film is formed between the support and the resist film.
[5] The patterning process of any one of the above [1] to [4], wherein a material for forming a silicon-containing reversed pattern containing a thermally crosslinkable polysiloxane having any one or more of repeating units represented by the following formulae (13) to (15) as the material for forming a reversed pattern,

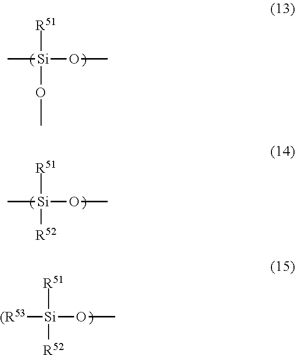

wherein R⁵¹, R⁵² and R⁵³ represent a monovalent organic group having 1 to 30 carbon atoms, which may be identical to or different from each other.
[6] The patterning process of the above [5], wherein a material containing an organic solvent that does not dissolve the resist pattern is used as the material for forming a silicon-containing reversed pattern.
[7] The patterning process of any one of the above [1] to [6], further comprising the steps of: exposing the resist film by an i-line, a KrF excimer laser beam, an ArF excimer laser beam, an electron beam, or an extreme ultraviolet ray; and developing the exposed resist film with a developer.

It should be noted that the present invention is not limited to the above-described embodiments. The embodiments are just examples, and any examples that have substantially the same feature and demonstrate the same functions and effects as those in the technical concept disclosed in claims of the present invention are included in the technical scope of the present invention.

1. A patterning process for forming a pattern, comprising the steps of:
(i) forming a resist pattern on a support using a resist film obtained from a resist composition comprising a hypervalent iodine compound, a carboxy group-containing compound, and a solvent;
(ii) applying a material for forming a reversed pattern onto the support having the resist pattern formed to form a coating film for pattern-reversing; and
(iii) removing the resist pattern by etching to form a reversed pattern.

2. The patterning process according to claim 1, wherein one or more kinds selected from the hypervalent iodine compounds represented by the following formulae (1) to (10) are used as the hypervalent iodine compound, 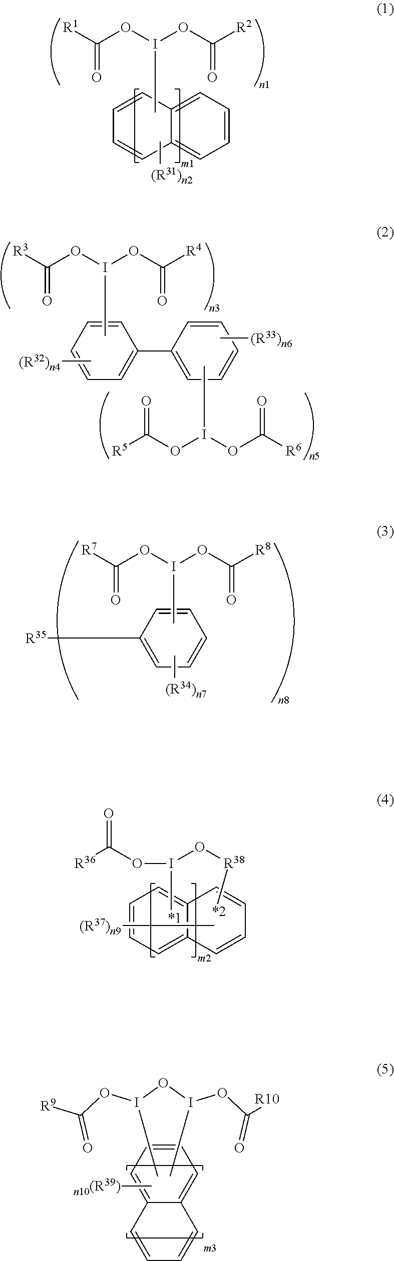 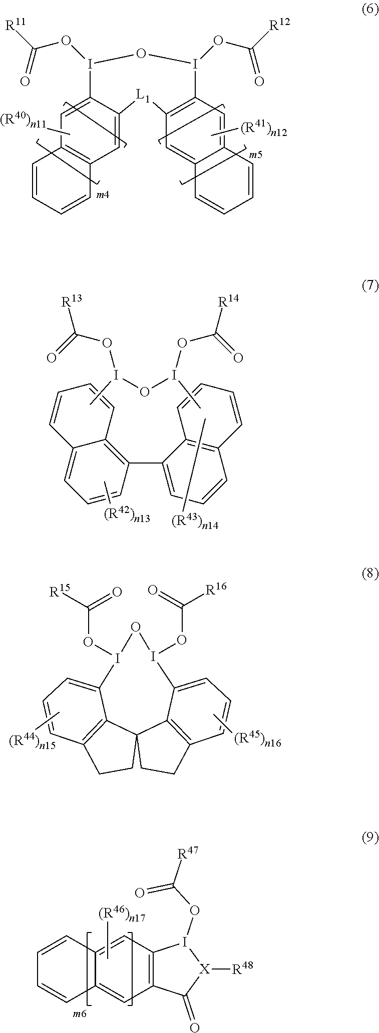 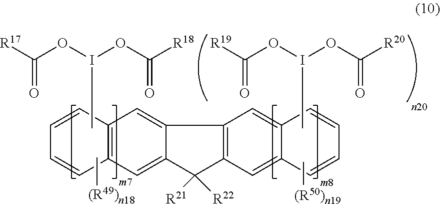
wherein m1 represents 0, 1, or 2, when m1 is 0, n1 represents 1, 2, or 3, n2 represents 0, 1, 2, 3, 4, or 5, and 1≤n1+n2≤6 is satisfied, when m1 is 1, n1 represents 1, 2, or 3, n2 represents 0, 1, 2, 3, 4, 5, 6, or 7, and 1≤n1+n2≤8 is satisfied, and when m1 is 2, n1 represents 1, 2, or 3, n2 represents 0, 1, 2, 3, 4, 5, 6, 7, 8, or 9, and 1≤n1+n2≤10 is satisfied;
n3 represents 1 or 2, n4 represents 0, 1, 2, 3, or 4, and 1≤n3+n4≤5 is satisfied; n5 represents 1 or 2, n6 represents 0, 1, 2, 3, or 4, and 1≤n5+n6≤5 is satisfied;
n7 represents 0, 1, 2, 3, or 4; n8 represents 1, 2, 3, or 4;
m2 represents 0, 1, or 2, when m2 is 0, n9 represents 0, 1, 2, 3, or 4, when m2 is 1, n9 is 0, 1, 2, 3, 4, 5, or 6, and when m2 is 2, n9 is 0, 1, 2, 3, 4, 5, 6, 7, or 8;
m3 represents 0, 1, or 2, when m3 is 0, n10 is 0, 1, 2, 3, or 4, when m3 is 1, n10 is 0, 1, 2, 3, 4, 5, or 6, and when m3 is 2, n10 is 0, 1, 2, 3, 4, 5, 6, 7, or 8;
m4 represents 0 or 1, when m4 is 0, n11 represents 0, 1, 2, 3, or 4, and when m4 is 1, n11 represents 0, 1, 2, 3, 4, 5, or 6;
m5 represents 0 or 1, when m5 is 0, n12 represents 0, 1, 2, 3, or 4, and when m5 is 1, n12 represents 0, 1, 2, 3, 4, 5, or 6;
n13 and n14 represent 0, 1, 2, 3, 4, 5, or 6;
n15 and n16 represent 0, 1, 2, or 3;
m6 represents 0, 1, or 2, when m6 is 0, n17 represents 0, 1, 2, 3, or 4, when m6 is 1, n17 represents 0, 1, 2, 3, 4, 5, or 6, and when m6 is 2, n17 represents 0, 1, 2, 3, 4, 5, 6, 6, 7, or 8;
m7 represents 0, 1, or 2, when m7 is 0, n18 represents 0, 1, 2, or 3, when m7 is 1, n18 represents 0, 1, 2, 3, 4, or 5, and when m7 is 2, n18 represents 0, 1, 2, 3, 4, 5, 6, or 7;
m8 represents 0, 1, or 2, when m8 is 0, n19 represents 0, 1, 2, or 3, and n20 represents 0 or 1, when m8 is 1, n19 represents 0, 1, 2, 3, 4, or 5, and n20 is 0 or 1, and when m8 is 2, n19 represents 0, 1, 2, 3, 4, 5, 6, or 7, and n20 represents 0 or 1;
R¹ to R²² each independently represent a halogen atom or a hydrocarbyl group having 1 to 10 carbon atoms and optionally having a heteroatom, R²¹ and R²² may be bonded to each other to form a ring together with the carbon atoms to which they are bonded and the atoms between the carbon atoms to which they are bonded;
R³¹ to R³⁴, R³⁷, R³⁹ to R⁴⁶, R⁴⁹, and R⁵⁰ each independently represent a halogen atom or a hydrocarbyl group having 1 to 40 carbon atoms and optionally having a heteroatom, when n2 is 2 or more, R³¹s may be identical to or different from each other, and a plurality of R³¹s may be bonded to each other to form a ring together with the carbon atoms of the aromatic ring to which they are bonded, when n4 is 2 or more, R³²s may be identical to or different from each other, and a plurality of R³²s may be bonded to each other to form a ring together with the carbon atoms of the aromatic ring to which they are bonded, when n6 is 2 or more, R³³s may be identical to or different from each other, and a plurality of R³³s may be bonded to each other to form a ring together with the carbon atoms of the aromatic ring to which they are bonded, when n7 is 2 or more, R³⁴s may be identical to or different from each other, and a plurality of R³⁴s may be bonded to each other to form a ring together with the carbon atoms of the aromatic ring to which they are bonded, when n9 is 2 or more, R³⁷s may be identical to or different from each other, and a plurality of R³⁷s may be bonded to each other to form a ring together with the carbon atoms of the aromatic ring to which they are bonded, when n10 is 2 or more, R³¹s may be identical to or different from each other, and a plurality of R³⁹s may be bonded to each other to form a ring together with the carbon atoms of the aromatic ring to which they are bonded, when n11 is 2 or more, R⁴⁰s may be identical to or different from each other, and a plurality of R⁴⁰s may be bonded to each other to form a ring together with the carbon atoms of the aromatic ring to which they are bonded, when n12 is 2 or more, R⁴¹s may be identical to or different from each other, and a plurality of R⁴¹s may be bonded to each other to form a ring together with the carbon atoms of the aromatic ring to which they are bonded, when n13 is 2 or more, R⁴²s may be identical to or different from each other, and a plurality of R⁴²s may be bonded to each other to form a ring together with the carbon atoms of the aromatic ring to which they are bonded, when n14 is 2 or more, R⁴³s may be identical to or different from each other, and a plurality of R⁴³s may be bonded to each other to form a ring together with the carbon atoms of the aromatic ring to which they are bonded, when n15 is 2 or more, R⁴⁴s may be identical to or different from each other, and a plurality of R⁴⁴s may be bonded to each other to form a ring together with the carbon atoms of the aromatic ring to which they are bonded, when n16 is 2 or more, R⁴⁵s may be identical to or different from each other, and a plurality of R⁴⁵s may be bonded to each other to form a ring together with the carbon atoms of the aromatic ring to which they are bonded, when n17 is 2 or more, R⁴⁶s may be identical to or different from each other, and a plurality of R⁴⁶s may be bonded to each other to form a ring together with the carbon atoms of the aromatic ring to which they are bonded, when n18 is 2 or more, R⁴⁹s may be identical to or different from each other, and a plurality of R⁴⁹s may be bonded to each other to form a ring together with the carbon atoms of the aromatic ring to which they are bonded, and when n19 is 2 or more, R⁵⁰s may be identical to or different from each other, and a plurality of R⁵⁰s may be bonded to each other to form a ring together with the carbon atoms of the aromatic ring to which they are bonded;
R³⁵ represents an (n8)-valent hydrocarbon group having 1 to 40 carbon atoms or an (n8)-valent heterocyclic group having 2 to 40 carbon atoms, when n8 is 2, R³⁵ may be an ether bond, a carbonyl group, an azo group, a thioether bond, a carbonate bond, a carbamate bond, a sulfinyl group, a sulfonyl group, or a thioketone bond, part or all of the hydrogen atoms of the (n8)-valent hydrocarbon group or the (n8)-valent heterocyclic group may be substituted with a group having a heteroatom, part of the —CH₂— groups of the (n8)-valent hydrocarbon group may be substituted with a group having a heteroatom, and R³⁴ and R³⁵ may be bonded to each other to form a ring together with the carbon atoms to which they are bonded and the atoms between the carbon atoms to which they are bonded;
R³⁶ represents a halogen atom or a hydrocarbyl group having 1 to 10 carbon atoms and optionally having a heteroatom;
R³⁸ represents a carbonyl group or a hydrocarbylene group having 1 to 10 carbon atoms and optionally having a heteroatom;
*1 and *2 represent attachment points to carbon atoms of the aromatic ring in the formula, and *1 and *2 are bonded to adjacent carbon atoms of the aromatic ring;
L₁ represents no bond, a single bond, —O—, —S—, —NH—, or —CH₂—;
R⁴⁷ each independently represents a halogen atom or a hydrocarbyl group having 1 to 10 carbon atoms and optionally having a heteroatom;
“X” represents a nitrogen atom or a sulfur atom, and when it is a nitrogen atom, it may have R⁴⁸; and
R⁴⁸ represents a hydrogen atom, a halogen atom, or a hydrocarbyl group having 1 to 20 carbon atoms and optionally having a heteroatom.

3. The patterning process according to claim 1, wherein a carboxy group-containing polymer having a repeating unit represented by the following general formula (11) or a carboxylic acid compound represented by the following general formula (12) is used as the carboxy group-containing compound, 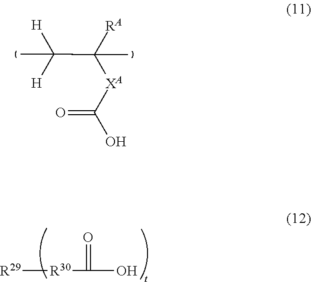
wherein R^{A} represents a hydrogen atom, a halogen atom, a methyl group, or a trifluoromethyl group;
X^{A} represents a single bond, a phenylene group, a naphthylene group, or *—C(═O)—O—X^{A1}—, wherein X^{A1} is a saturated hydrocarbylene group having 1 to 10 carbon atoms, a phenylene group, or a naphthylene group, the saturated hydrocarbylene group may have a hydroxy group, an ether bond, an ester bond, or a lactone ring, and “*” represents an attachment point to a carbon atom in the main chain;
“t” represents 1, 2, 3, or 4;
R²⁹ represents a t-valent hydrocarbon group having 1 to 40 carbon atoms or a t-valent heterocyclic group having 2 to 40 carbon atoms, when “t” is 2, R²⁹ may be an ether bond, a carbonyl group, an azo group, a thioether bond, a carbonate bond, a carbamate bond, a sulfinyl group, or a sulfonyl group, part or all of the hydrogen atoms of the t-valent hydrocarbon group or the t-valent heterocyclic group may be substituted with a group having a heteroatom, and part of the —CH₂— groups of the t-valent hydrocarbon group may be substituted with a group having a heteroatom;
and R³⁰ represents a single bond or a hydrocarbylene group having 1 to 10 carbon atoms, part or all of the hydrogen atoms of the hydrocarbylene group may be substituted with a group having a heteroatom, part of the —CH₂— of the hydrocarbylene group may be substituted with a group having a heteroatom, and when “t” is 2 to 4, R³⁰s may be identical to or different from each other.

4. The patterning process according to claim 1, wherein a resist underlayer film is formed between the support and the resist film.

5. The patterning process according to claim 2, wherein a resist underlayer film is formed between the support and the resist film.

6. The patterning process according to claim 3, wherein a resist underlayer film is formed between the support and the resist film.

7. The patterning process according to claim 1, wherein a material for forming a silicon-containing reversed pattern containing a thermally crosslinkable polysiloxane having any one or more of repeating units represented by the following formulae (13) to (15) as the material for forming a reversed pattern, 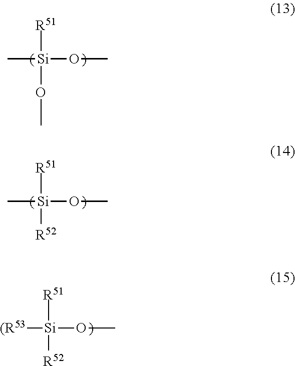
wherein R⁵¹, R⁵² and R⁵³ represent a monovalent organic group having 1 to 30 carbon atoms, which may be identical to or different from each other.

8. The patterning process according to claim 7, wherein a material containing an organic solvent that does not dissolve the resist pattern is used as the material for forming a silicon-containing reversed pattern.

9. The patterning process according to claim 1, further comprising the steps of: exposing the resist film by an i-line, a KrF excimer laser beam, an ArF excimer laser beam, an electron beam, or an extreme ultraviolet ray; and developing the exposed resist film with a developer.
